(19) United States
(12) Patent Application Publication
(10) Pub. No.: US 2025/0268095 A1
(43) Pub. Date: Aug. 21, 2025

(54) ORGANIC ELECTROLUMINESCENT MATERIALS AND DEVICES

(71) Applicant: Universal Display Corporation, Ewing, NJ (US)

(72) Inventors: Zhiqiang JI, Chalfont, PA (US); Pierre-Luc T. BOUDREAULT, Pennington, NJ (US)

(73) Assignee: Universal Display Corporation, Ewing, NJ (US)

(21) Appl. No.: 18/938,531

(22) Filed: Nov. 6, 2024

Related U.S. Application Data
(60) Provisional application No. 63/553,959, filed on Feb. 15, 2024.

(51) Int. Cl. H10K 85/30; C07F 15/00; H10K 50/12; H10K 101/20

(52) U.S. Cl. CPC H10K 85/342; C07F 15/0033; C07F 15/006; C07F 15/0086; H10K 85/346; H10K 50/121; H10K 2101/20

(57) ABSTRACT

A compound having a first ligand L_{A} comprising a structure of Formula I,

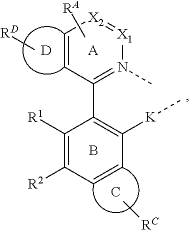

is provided. In Formula I, moiety C is a monocyclic ring or a polycyclic fused ring system; ring D is a carbocyclic or heterocyclic ring; each of X¹ and X² is C or N; K is a direct bond or a linking group; R¹ and R² are H, D, or T; each R^{α}, R^{β}, R^{A}, R^{C}, and R^{D} is hydrogen or a General Substituent defined herein; and L_{A} is coordinated to a metal M. Formulations, OLEDs, and consumer products comprising the compound are also provided.

### CROSS-REFERENCE TO RELATED APPLICATIONS

This application claims priority under 35 U.S.C. § 119(e) to U.S. Provisional Application No. 63/553,959, filed on Feb. 15, 2024, the entire contents of which are incorporated herein by reference.

### FIELD

The present disclosure generally relates to organic or metal coordination compounds and formulations and their various uses including as emitters, sensitizers, charge transporters, or exciton transporters in devices such as organic light emitting diodes and related electronic devices and consumer products.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound having a first ligand L_{A} comprising a structure of Formula I:

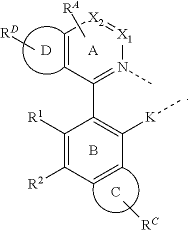

### In Formula I:

moiety C is a monocyclic ring or a polycyclic fused ring system, wherein the monocyclic ring or each ring of the polycyclic fused ring system is independently a 5-membered to 10-membered carbocyclic or heterocyclic ring;
ring D is a 5-membered to 10-membered carbocyclic or heterocyclic ring;
each of X¹ and X² is independently C or N;
K is selected from the group consisting of a direct bond, O, S, N(R^{α}), P(R^{α}), B(R^{α}), C(R^{α})(R^{β}), and Si(R^{α})(R^{β});
R¹ and R² are each independently H, D, or T;
each R^{A}, R^{C}, and R^{D} independently represents mono to the maximum allowable substitution, or no substitution;
each R^{α}, R^{β}, R^{A}, R^{C}, and R^{D} are each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M;
metal M is selected from the group consisting of Os, Ir, Rh, Re, Ru, Pd, Pt, Cu, Ag, and Au;
metal M may be coordinated to other ligands;
L_{A} may join with other ligands to form a tridentate, tetradentate, pentadentate, or hexadentate ligand; and
any two substituents may be joined or fused to form a ring.

In another aspect, the present disclosure provides a formulation comprising a compound having a first ligand L_{A} comprising a structure of Formula I as described herein.

In yet another aspect, the present disclosure provides an OLED having an organic layer comprising a compound having a first ligand L_{A} comprising a structure of Formula I as described herein.

In yet another aspect, the present disclosure provides a consumer product comprising an OLED with an organic layer comprising a compound having a first ligand L_{A} comprising a structure of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

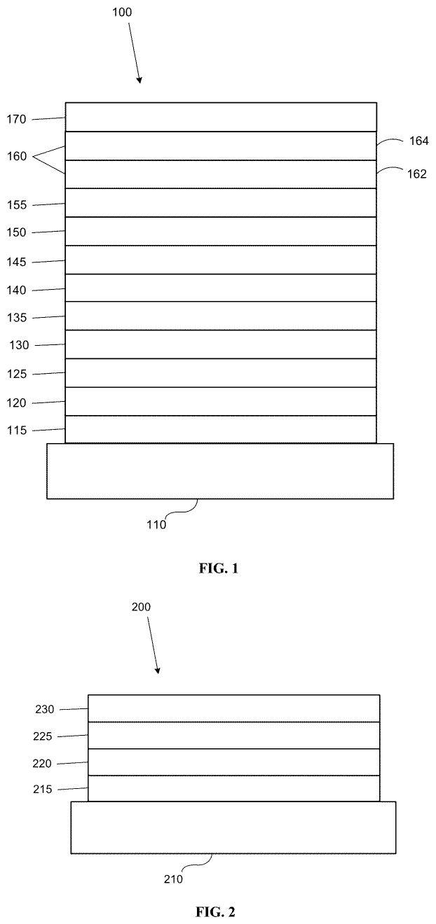

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373l, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SRₛ group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen or a substituent selected from the group consisting of the general substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ′-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5λ²,9λ′-diaza-13b-boranaphtho[2,3,4-de]anthracene, 5λ′-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of

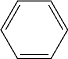

implies to include CH₆, C₆D₆, C₆H₃D₃, and any other partially deuterated variants thereof. Some common basic partially or fully deuterated group include, without limitation, CD₃, CD₂C(CH₃)₃, C(CD₃)₃, and C₆D₅.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be optionally joined or fused into a ring. The preferred ring is a five to nine-membered carbocyclic or heterocyclic ring, includes both instances where the portion of the ring formed by the pair of substituents is saturated and where the portion of the ring formed by the pair of substituents is unsaturated. In yet other instances, a pair of adjacent substituents can be optionally joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

In one aspect, the present disclosure provides a compound having a first ligand L_{A} comprising a structure of Formula I:

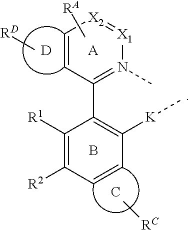

### In Formula I:

moiety C is a monocyclic ring or a polycyclic fused ring system, wherein the monocyclic ring or each ring of the polycyclic fused ring system is independently a 5-membered to 10-membered carbocyclic or heterocyclic ring;
ring D is a 5-membered to 10-membered carbocyclic or heterocyclic ring;
each of X¹ and X² is independently C or N;
K is selected from the group consisting of a direct bond, O, S, N(R^{α}), P(R^{α}), B(R^{α}), C(R^{α})(R^{β}), and Si(R^{α})(R^{β});
R¹ and R² are each independently H, D, or T;
each R^{A}, R^{C}, and R^{D} independently represents mono to the maximum allowable substitution, or no substitution;
each R^{α}, R^{β}, R^{A}, R^{C}, and R^{D} are each independently hydrogen or a substituent selected from the group consisting of the General Substituents defined herein;
L_{A} is coordinated to a metal M;
metal M is selected from the group consisting of Os, Ir, Rh, Re, Ru, Pd, Pt, Cu, Ag, and Au;
metal M can be coordinated to other ligands;
L_{A} can join with other ligands to form a tridentate, tetradentate, pentadentate, or hexadentate ligand; and
any two substituents can be joined or fused to form a ring.

In some embodiments, if M is Ir, R¹ and R² are each H, and moiety C is a benzene ring, then one of the following conditions is true:
(1) X¹ and X² are C, ring D is a 5-membered monocyclic ring, and no two R^{A} substituents are joined or fused to form a ring; or
(2) X² is N and (a) moiety D is a 6-membered monocyclic ring, and no two R^{D} substituents are joined or fused to form a 5-membered ring; or (b) moiety D is a 5-membered monocyclic ring, and the 5-membered ring comprises at least four carbon ring atoms.

In some embodiments, L_{A} consists essentially Formula I. In some embodiments, L_{A} has a structure of Formula I.

In some embodiments of Formula I, at least one R^{A}, R^{C}, or R^{D} is selected from the group consisting of the General Substituents defined herein. In some embodiments, at least one R^{A} is selected from the group consisting of the General Substituents defined herein. In some embodiments, at least one R^{C} is selected from the group consisting of the General Substituents defined herein. In some embodiments, at least one R^{D} is selected from the group consisting of the General Substituents defined herein. In some embodiments of Formula I, at least one R^{α}, R^{β}, R^{A}, R^{C}, or R^{D} is partially or fully deuterated. In some embodiments, at least one of R^{α} or R^{β} is partially or fully deuterated. In some embodiments, R¹ is D. In some embodiments, R² is D. In some embodiments, at least one R^{A} is partially or fully deuterated. In some embodiments, at least one R^{C} is partially or fully deuterated. In some embodiments, at least one R^{D} is partially or fully deuterated.

In some embodiments, moiety C is a monocyclic ring or a polycyclic fused ring system, wherein the monocyclic ring or each ring of the polycyclic fused ring system is independently a 5-membered or 6-membered carbocyclic or heterocyclic ring.

In some embodiments, moiety C is a monocyclic ring or a polycyclic fused ring system, wherein the monocyclic ring or each ring of the polycyclic fused ring system is independently a 5-membered or 6-membered aryl or heteroaryl ring.

In some embodiments, Ring D is a 5-membered or 6-membered carbocyclic or heterocyclic ring. In some embodiments, Ring D is a 5-membered or 6-membered aryl or heteroaryl ring.

In some embodiments, each R^{α}, R^{β}, R^{A}, R^{C}, and R^{D} are each independently hydrogen or a substituent selected from the group consisting of the Preferred General Substituents defined herein. In some embodiments, each R^{α}, R^{β}, R^{A}, R^{C}, and R^{D} are each independently hydrogen or a substituent selected from the group consisting of the More Preferred General Substituents defined herein. In some embodiments, each R^{α}, R^{β}, R^{A}, R^{C}, and R^{D} are each independently hydrogen or a substituent selected from the group consisting of the Even More Preferred General Substituents defined herein. In some embodiments, each R^{α}, R^{β}, R^{A}, R^{C}, and R^{D} are each independently hydrogen or a substituent selected from the group consisting of the Most Preferred General Substituents defined herein.

In some embodiments, metal M is Ir. In some embodiments, metal M is Pt or Pd.

In some embodiments, moiety C is selected from the group consisting of the following Cyclic Moiety List: benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, quinoxaline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-anthracene, phenanthridine, fluorene, and aza-fluorene. In some embodiments, the aza variant includes one N on a benzo ring.

In some embodiments, moiety C is a monocyclic ring. In some embodiments, moiety C is selected from the group consisting of benzene, pyridine, pyrimidine, pyridazine, pyrazine, triazine, imidazole, pyrazole, pyrrole, oxazole, furan, thiophene, thiazole, and triazole. In some embodiments, moiety C is benzene.

In some embodiments, moiety C is a polycyclic fused ring system. In some embodiments, moiety C is selected from the group consisting of naphthalene, quinoline, isoquinoline, quinazoline, quinoxaline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-anthracene, phenanthridine, fluorene, and aza-fluorene. In some embodiments, moiety C is naphthalene.

In some embodiments, moiety D is a monocyclic ring. In some embodiments, moiety D is selected from the group consisting of benzene, pyridine, pyrimidine, pyridazine, pyrazine, triazine, imidazole, pyrazole, pyrrole, oxazole, furan, thiophene, thiazole, and triazole. In some embodiments, moiety D is benzene, thiophene, furan, or selenophene. In some embodiments, moiety D is benzene. In some embodiments, moiety D is thiophene. In some embodiments, moiety D is furan. In some embodiments, moiety D is selenophene.

In some embodiments, X¹ and X² are C. In some embodiments, X¹ is C, and X² is N. In some embodiments, X¹ is N, and X² is C.

In some embodiments, K is a direct bond.

In some embodiments, K is O or S. In some embodiments, K is N(R^{α}), P(R^{α}), or B(R^{α}). In some embodiments, K is C(R^{α})(R^{β}) or Si(R^{α})(R^{β}).

In some embodiments, at least one of R¹ or R² is D. In some embodiments, exactly one of R¹ or R² is D. In some embodiments, both R¹ and R² are D. In some embodiments, R¹ is D. In some embodiments, R² is D.

In some embodiments, at least one of R¹ or R² is T. In some embodiments, exactly one of R¹ or R² is T. In some embodiments, both R¹ and R² are T. In some embodiments, R¹ is T. In some embodiments, R² is T.

In some embodiments, at least one of R¹ or R² is H. In some embodiments, exactly one of R¹ or R² is H. In some embodiments, both R¹ and R² are H. In some embodiments, R¹ is H. In some embodiments, R² is H.

In some embodiments, the first ligand L_{A} comprises an electron-withdrawing group selected from the group consisting of the following EWG1 LIST: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

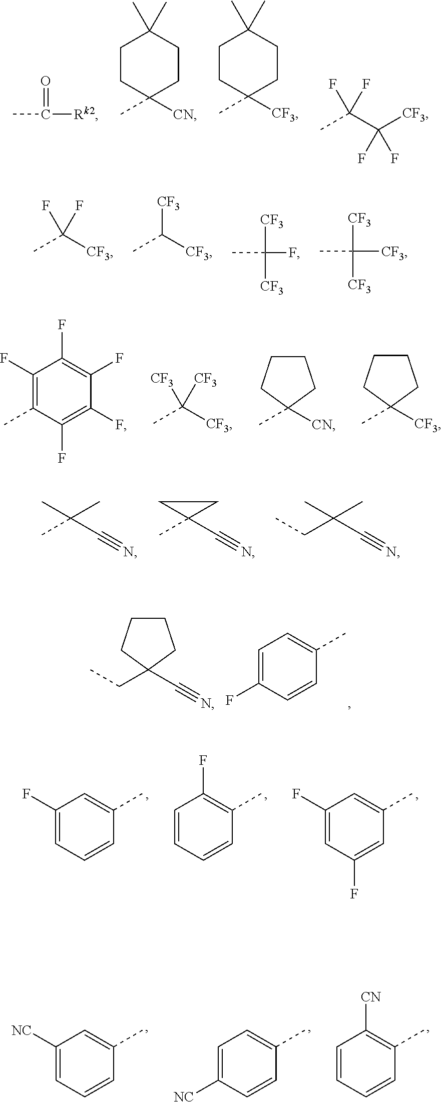

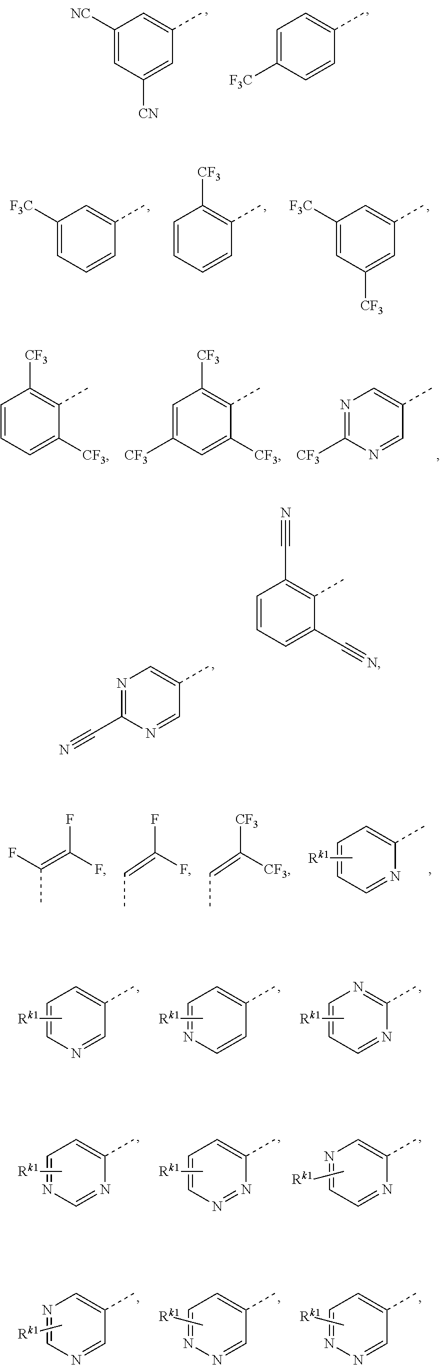

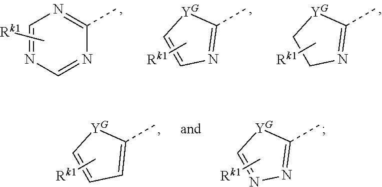

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen or a substituent selected from the group consisting of the General Substituents defined herein.

In some embodiments, the first ligand L_{A} comprises an electron-withdrawing group selected from the group consisting of the structures of the following EWG2 List:

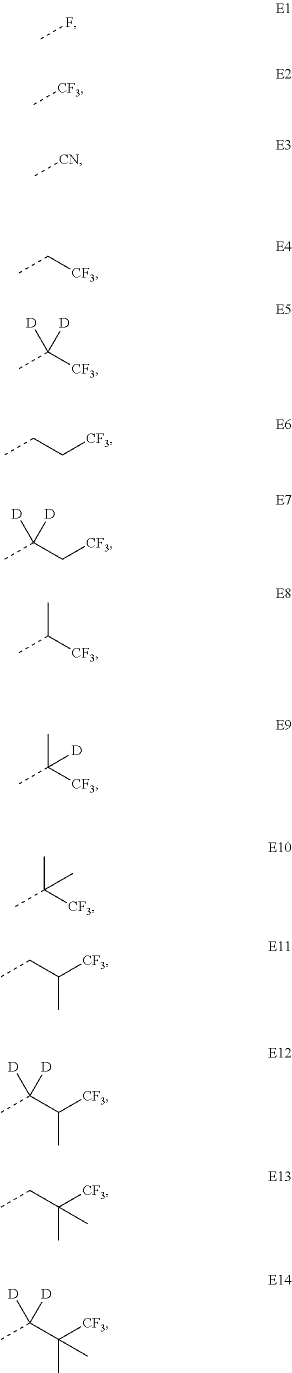

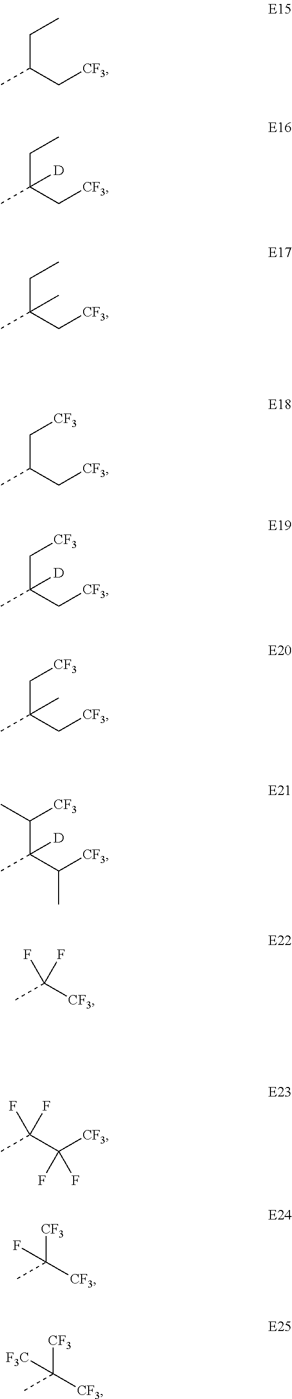

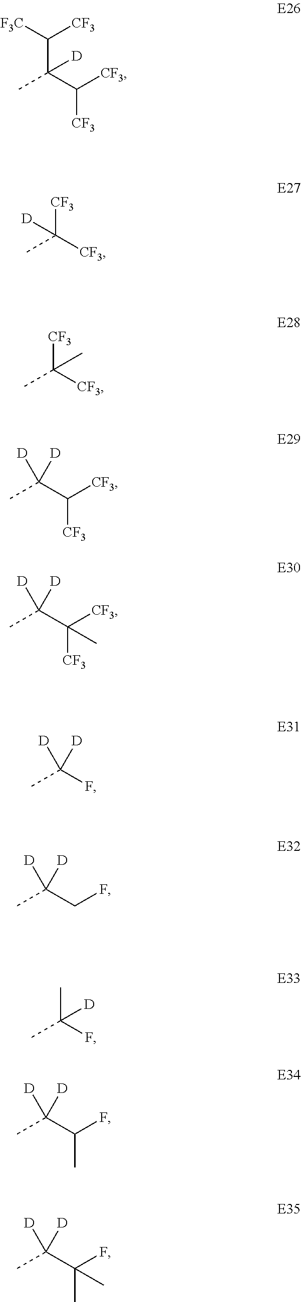

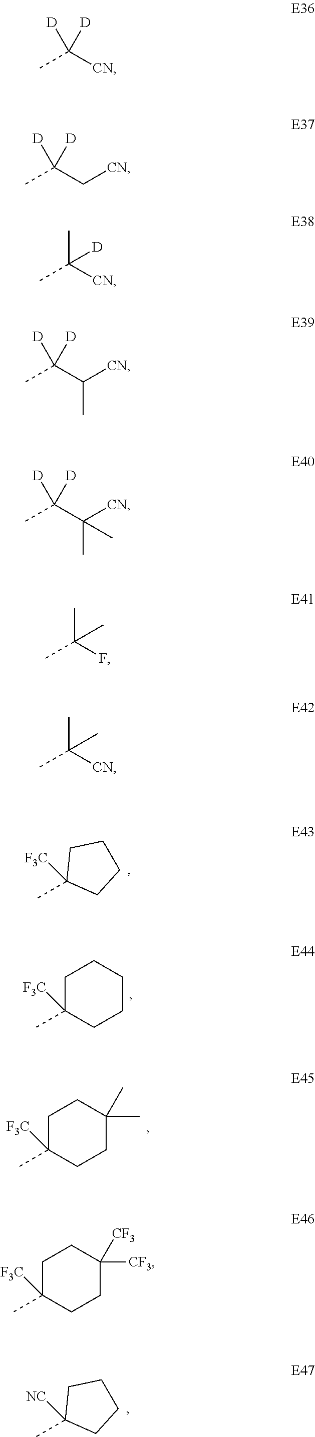

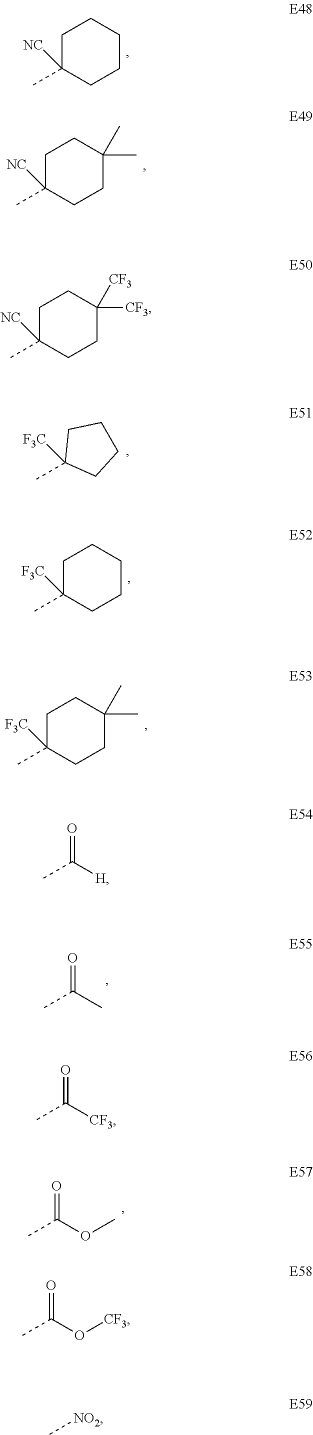

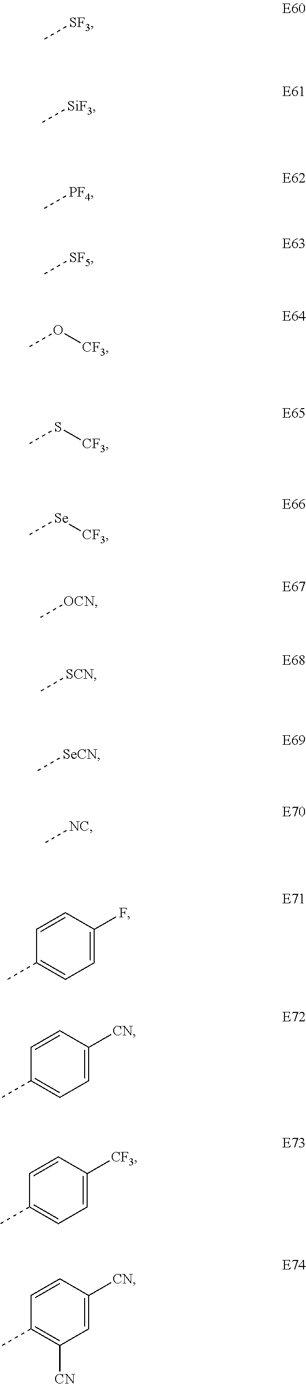

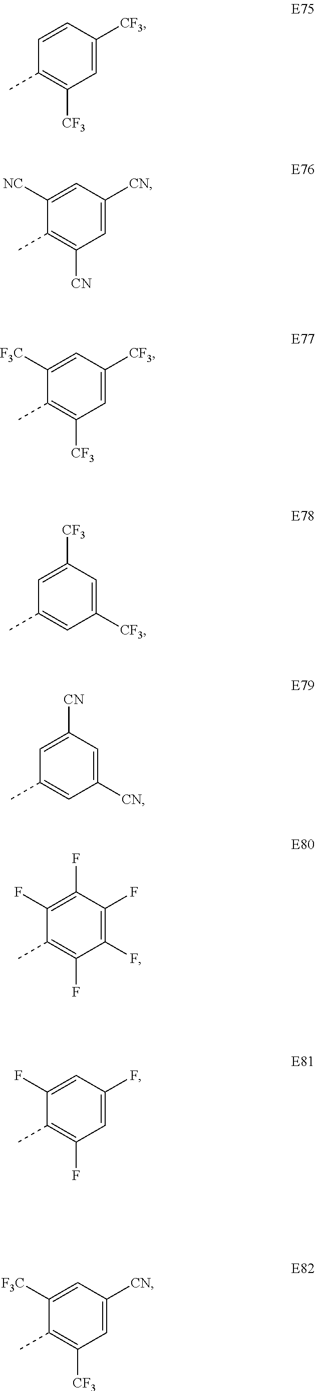

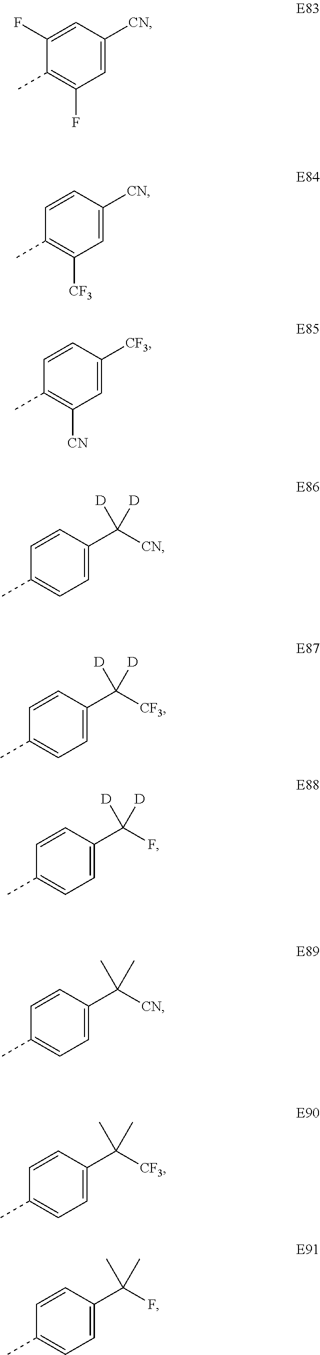

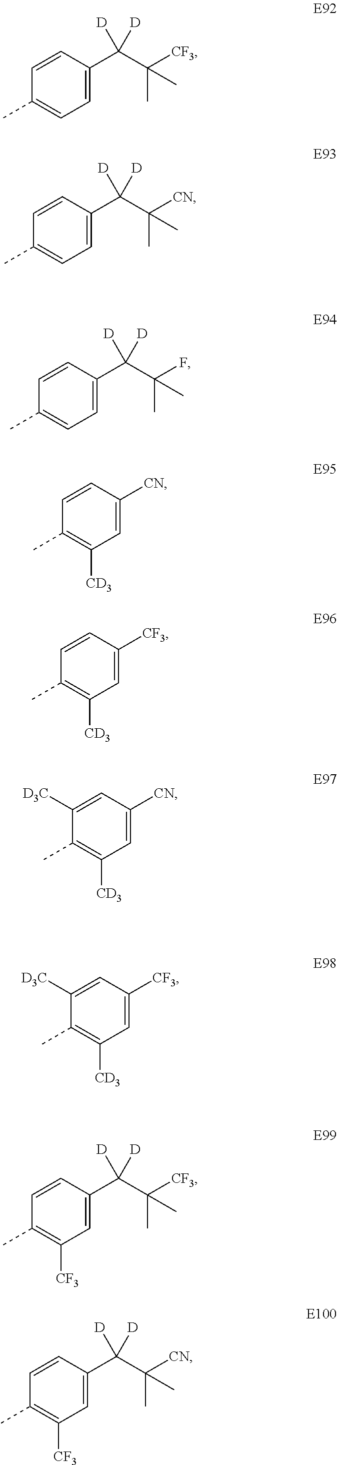

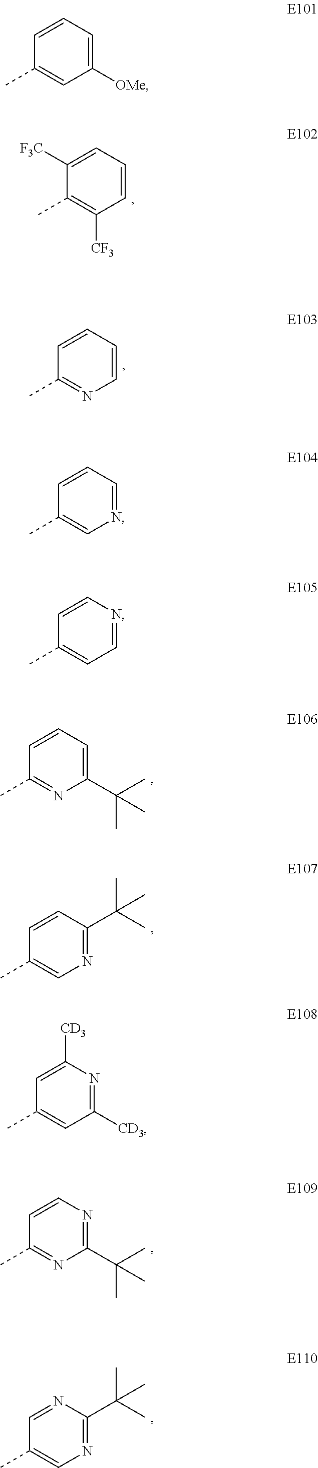

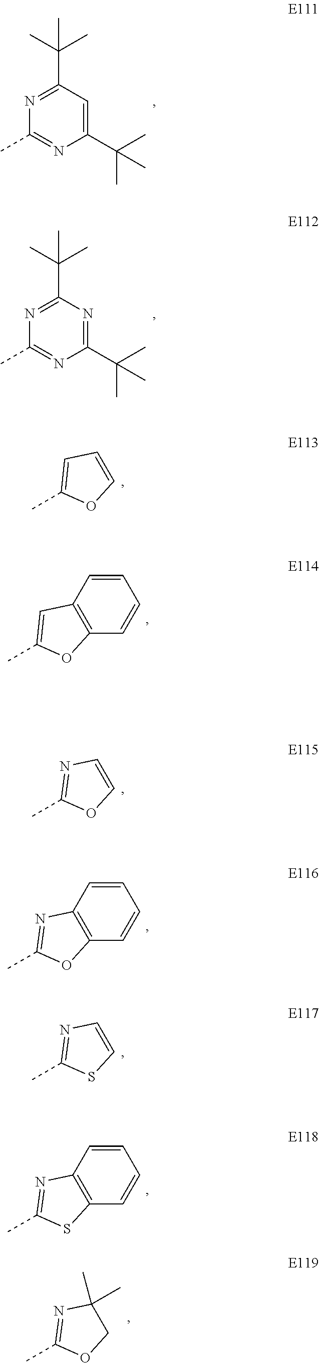

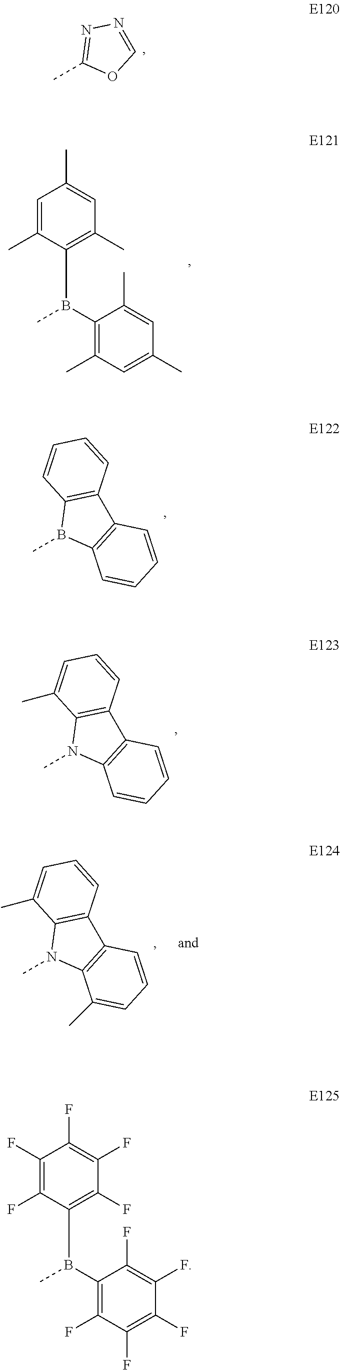

In some embodiments, the first ligand L_{A} comprises an electron-withdrawing group selected from the group consisting of the structures of the following EWG3 LIST:

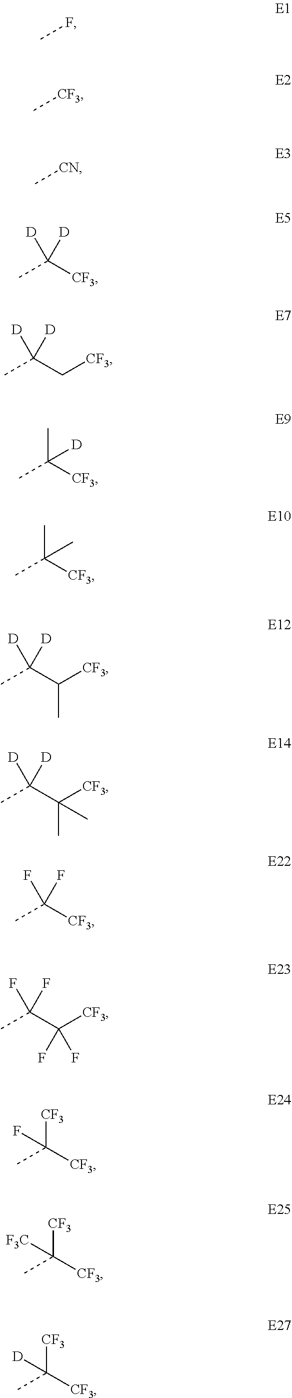

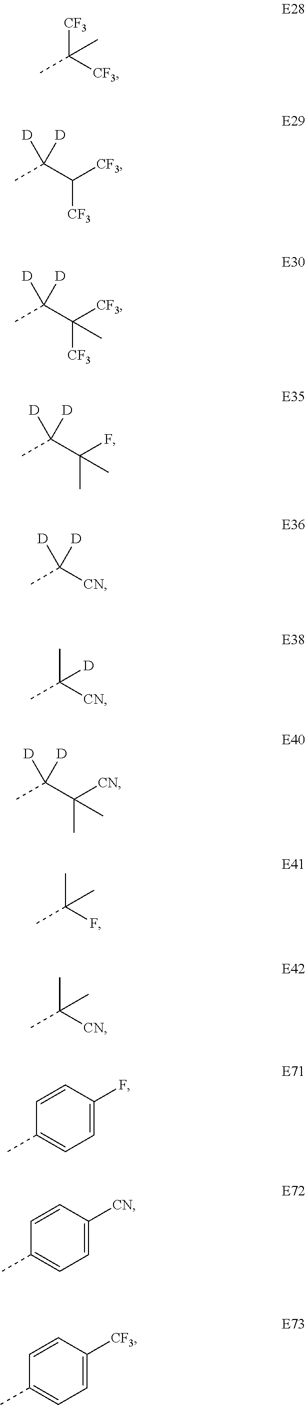

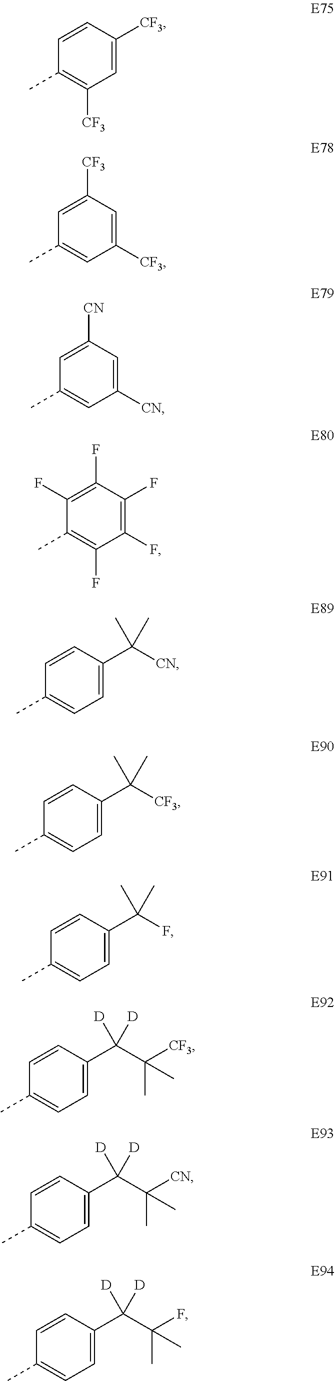

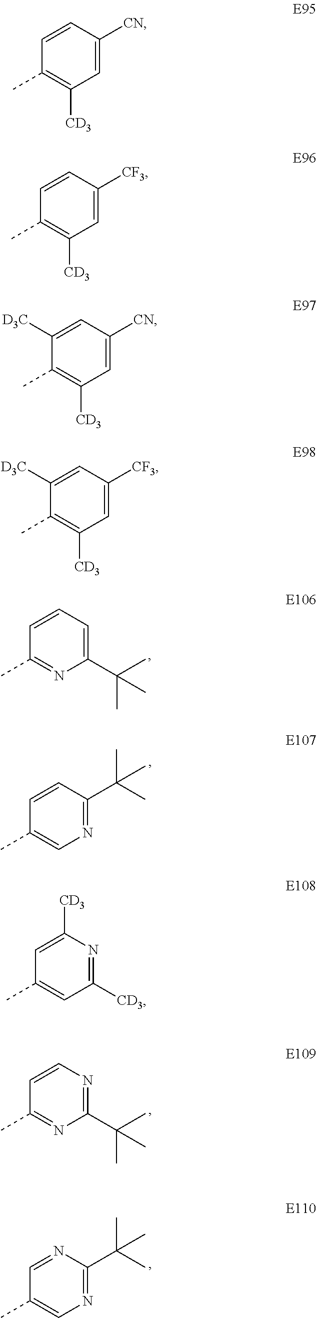

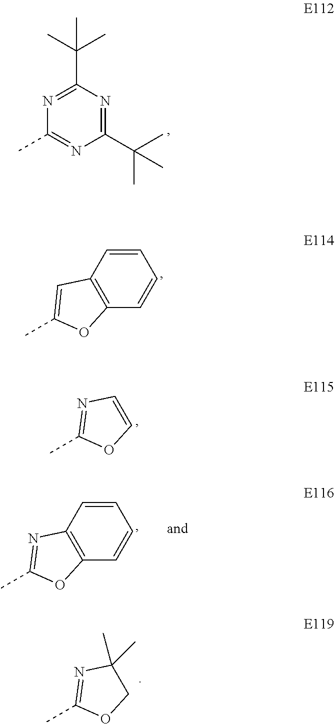

In some embodiments, the first ligand L_{A} comprises an electron-withdrawing group selected from the group consisting of the structures of the following EWG4 LIST:

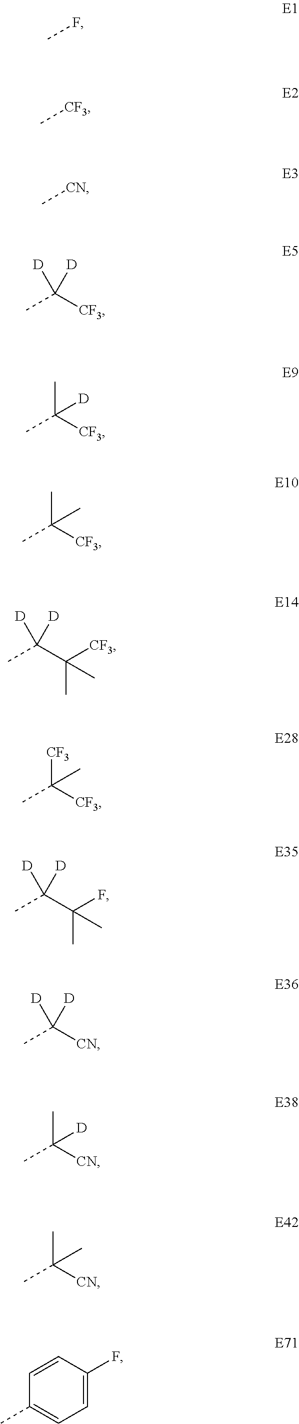

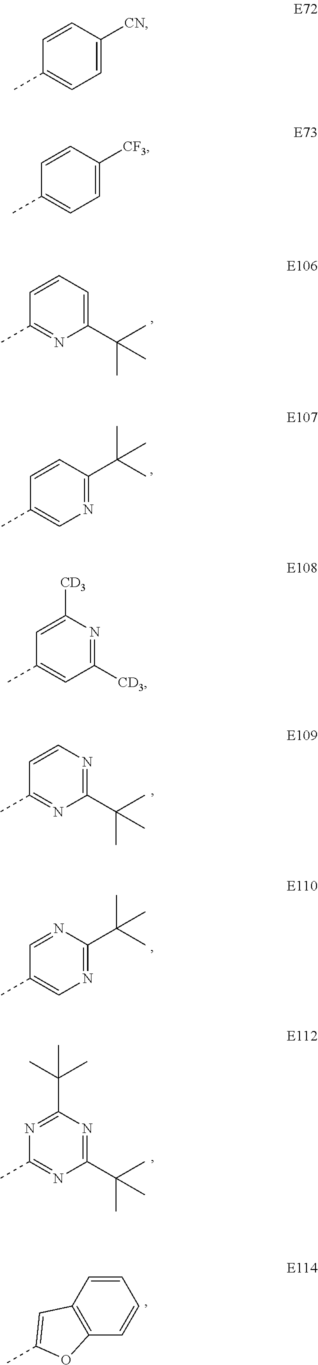

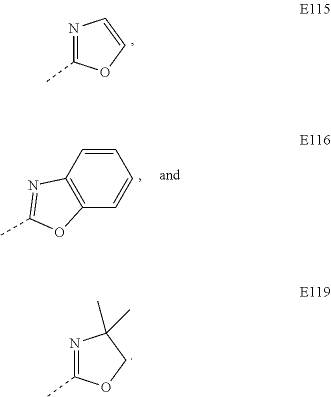

In some embodiments, the first ligand L_{A} comprises a π-electron deficient electron-withdrawing group selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

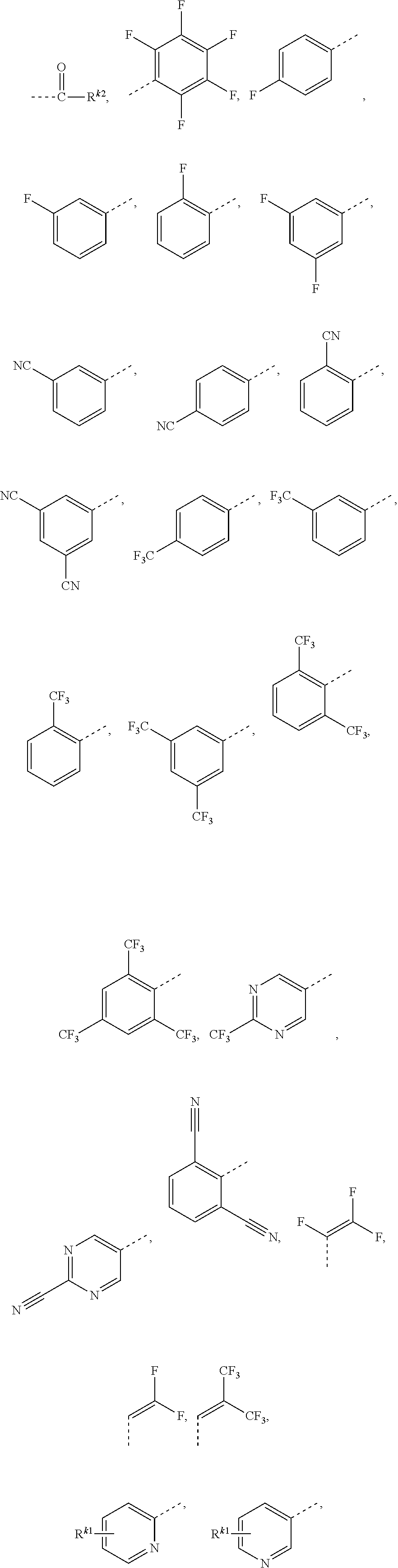

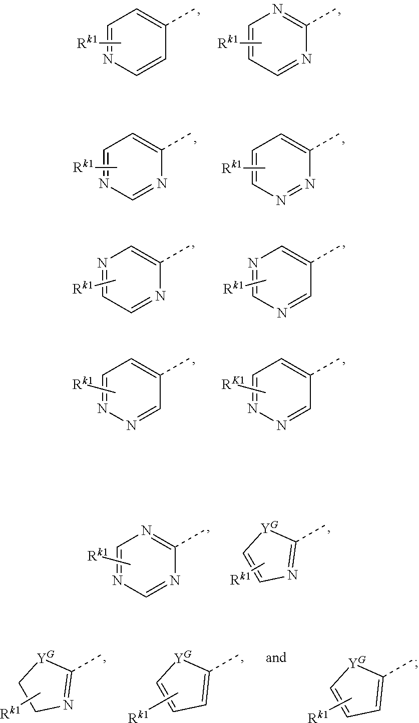

wherein the variables are the same as previously defined.

In some embodiments of Formula I, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments of Formula I, at least one R^{C} is or comprises an electron-withdrawing group from the EWG1 LIST as defined herein. In some embodiments, at least one R^{C} is or comprises an electron-withdrawing group from the EWG2 LIST as defined herein. In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined herein.

In some embodiments of Formula I, at least one R^{D} is or comprises an electron-withdrawing group from the EWG1 LIST as defined herein. In some embodiments, at least one R^{D} is or comprises an electron-withdrawing group from the EWG2 LIST as defined herein. In some embodiments, at least one R^{D} is or comprises an electron-withdrawing group from the EWG3 LIST as defined herein. In some embodiments, at least one R^{D} is or comprises an electron-withdrawing group from the EWG4 LIST as defined herein. In some embodiments, at least one R^{D} is or comprises an electron-withdrawing group from the Pi-EWG LIST as defined herein.

In some embodiments of Formula I, at least one of R^{α} or R^{β} is or comprises an electron-withdrawing group from the EWG1 LIST as defined herein. In some embodiments, at least one of R^{α} or R^{β} is or comprises an electron-withdrawing group from the EWG2 LIST as defined herein. In some embodiments, at least one of R^{α} or R^{β} is or comprises an electron-withdrawing group from the EWG3 LIST as defined herein. In some embodiments, at least one of R^{α} or R^{β} is or comprises an electron-withdrawing group from the EWG4 LIST as defined herein. In some embodiments, at least one of R^{α} or R^{β} is or comprises an electron-withdrawing group from the Pi-EWG LIST as defined herein.

In some embodiments, M is Ir, R¹ and R² are both H, and moiety C is benzene.

In some embodiments, X¹ and X² are C, ring D is a 5-membered ring and no two R^{A} substituents are joined or fused to form a ring.

In some embodiments, X² is N, ring D is a 6-membered ring, and no two R^{A} substituents are joined or fused to form a ring.

In some embodiments, X² is N, ring D is a 5-membered ring, and ring D comprises at least four carbon ring atoms.

In some embodiments, at least one R^{A} is not hydrogen. In some embodiments, each R^{A} is hydrogen.

In some embodiments, at least one R^{A} comprises at least one C atom. In some embodiments, at least one R^{A} comprises a substituent selected from the group consisting of alkyl, cycloalkyl, aryl, heteroaryl, and combinations thereof.

In some embodiments, two R^{A} are joined or fused to form a moiety A1. In some embodiments, moiety A1 is selected from the group consisting of the Cyclic Moiety List defined herein. In some embodiments, moiety A1 is benzene, pyridine, or pyrimidine. In some embodiments, moiety A1 is benzene.

In some embodiments, at least one R^{C} is not hydrogen. In some embodiments, each R^{C} is hydrogen.

In some embodiments, at least one R^{C} comprises at least one C atom. In some embodiments, at least one R^{C} comprises at least two C atoms. In some embodiments, at least one R^{C} comprises at least three C atoms. In some embodiments, at least one R^{C} comprises at least four C atoms.

In some embodiments, at least one R^{C} comprises a substituent selected from the group consisting of alkyl, cycloalkyl, aryl, heteroaryl, and combinations thereof.

In some embodiments, at least one R^{D} is not hydrogen. In some embodiments, each R^{D} is hydrogen.

In some embodiments, at least one R^{D} comprises at least one C atom. In some embodiments, at least one R^{D} comprises a substituent selected from the group consisting of alkyl, cycloalkyl, silyl, germyl, aryl, heteroaryl, and combinations thereof.

In some embodiments, two R^{D} are joined or fused to form a moiety D1. In some embodiments, moiety D1 is a monocyclic ring or a polycyclic fused ring system, wherein the monocyclic ring or each ring of the polycyclic fused ring system is independently a 5-membered to 10-membered carbocyclic or heterocyclic ring.

In some embodiments, moiety D1 is selected from the group consisting of the Cyclic Moiety List defined herein. In some embodiments, moiety D1 is monocyclic.

In some embodiments, moiety D1 is polycyclic. In some embodiments, moiety D1 is heterocyclic. In some embodiments, moiety D1 comprises one heteroatom. In some embodiments, moiety D1 comprises at least one heteroatom other than N. In some embodiments, moiety D1 comprises at least one heteroatom selected from the group consisting of S, O, and Se. In some embodiments, moiety D1 comprises more than one heteroatom.

In some embodiments, moiety D1 is benzene.

In some embodiments, moiety D1 is further substituted by at least one substituent R^{D′}, wherein each R^{D′} is independently selected from the group consisting of alkyl, cycloalkyl, silyl, germyl, aryl, heteroaryl, and combinations thereof.

In some embodiments, at least one R^{D′} comprises at least three C atoms. In some embodiments, at least one R^{D′} comprises at least four C atoms. In some embodiments, at least one R^{D′} comprises at least five C atoms.

In some embodiments, at least one R^{D′} comprises silyl or germyl. In some embodiments, at least one R^{D′} comprises silyl. In some embodiments, at least one R^{D′} comprises germyl. In some embodiments, at least one R^{D′} comprises at least one moiety selected from the group consisting of trimethylsilyl, triphenylsilyl, trimethylgermyl, and triphenylgermyl.

In some embodiments, the first ligand L_{A} is selected from the group consisting of the structures of the following LIST 1:

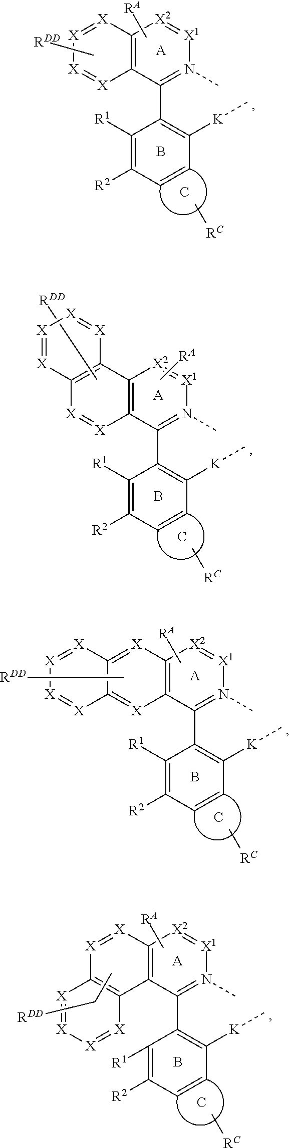

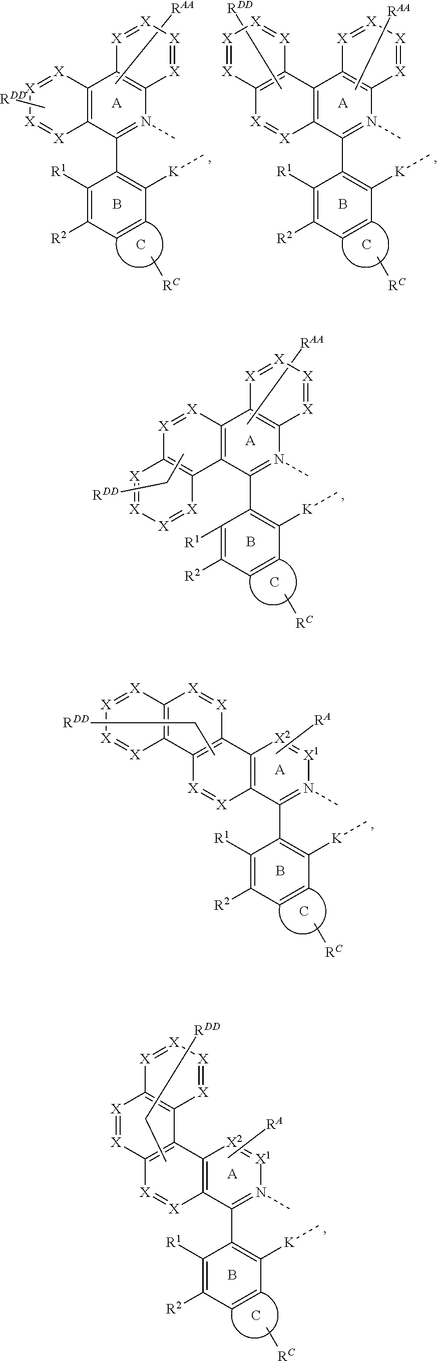

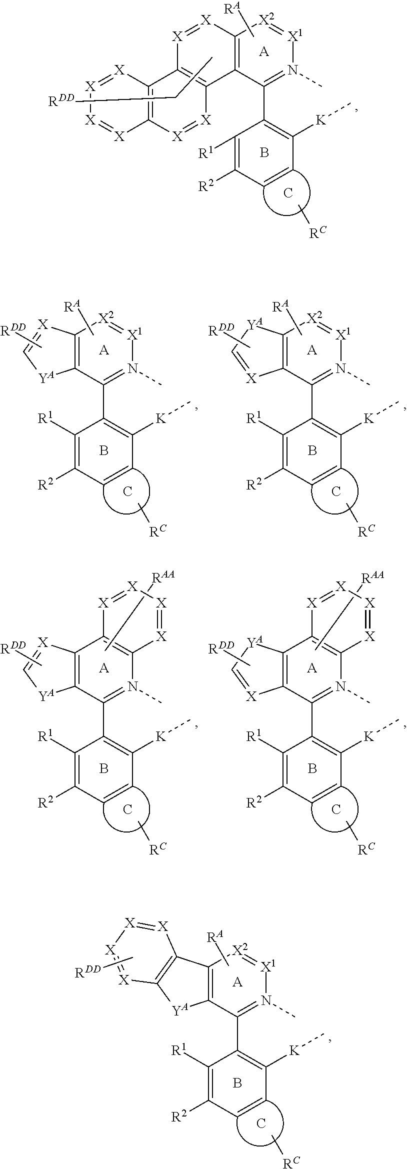

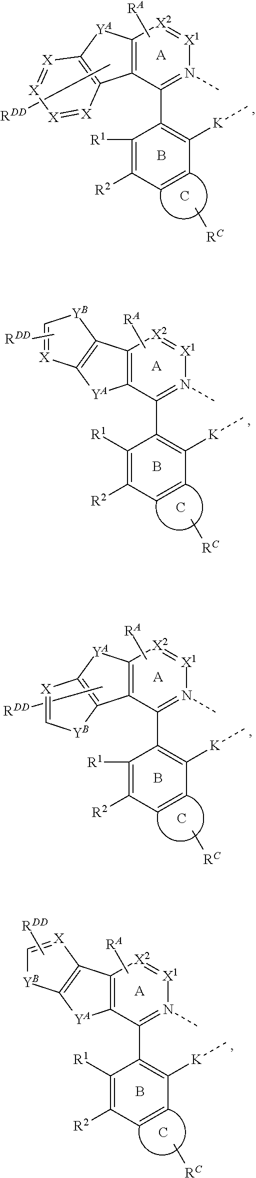

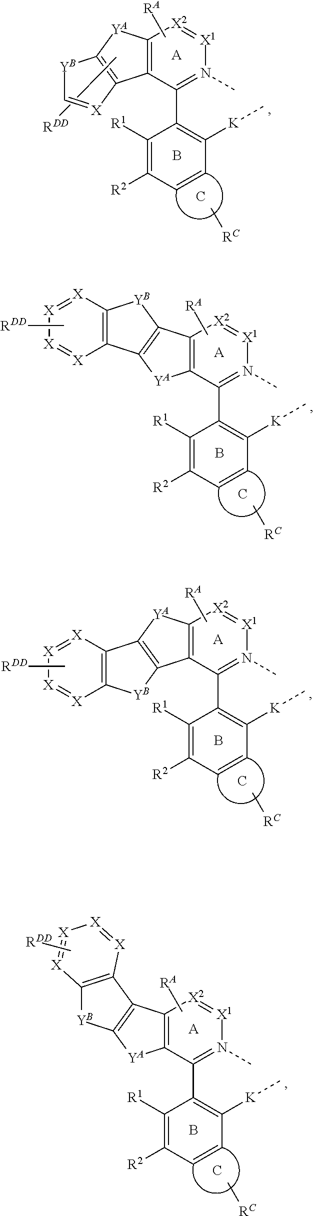

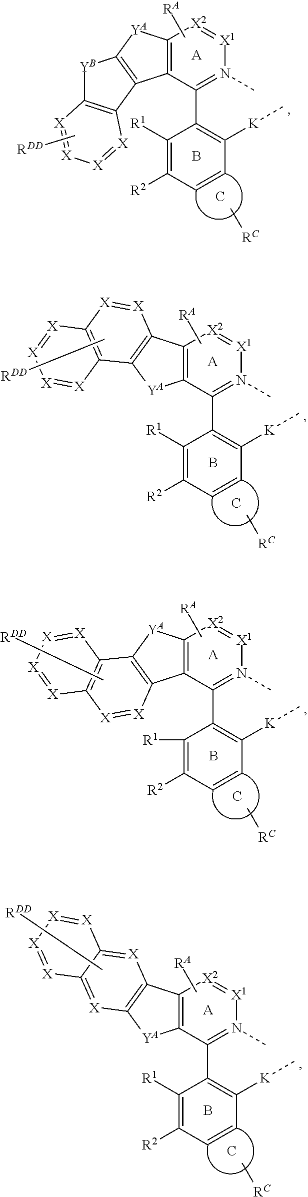

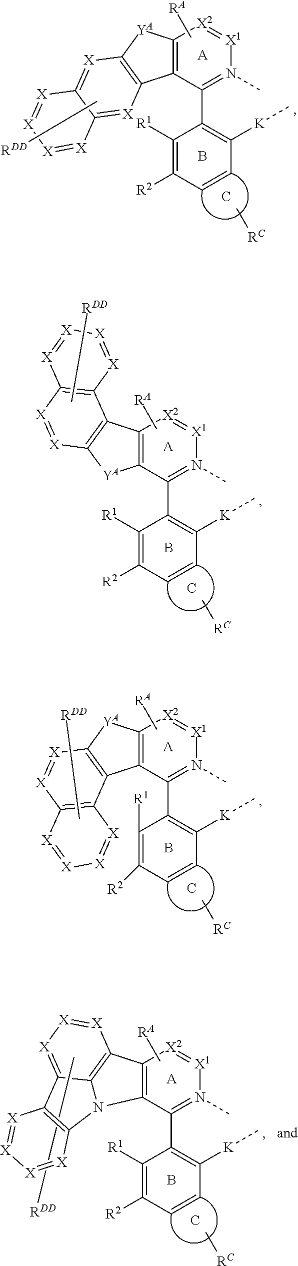

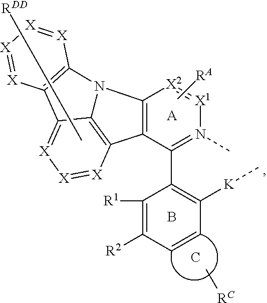

wherein:
for each occurrence, X is independently C or N;
each of Y^{A} and Y^{B} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
each of R^{AA} and R^{DD} independently represents mono to the maximum allowable substitution, or no substitution;
each R, R′, R^{AA}, and R^{DD} is independently hydrogen or a substituent selected from the group consisting of the General Substituents defined herein; and
any two substituents may be optionally joined or fused to form a ring.

In some embodiments where ligand L_{A} is selected from LIST 1, at least one R^{A}, R^{AA}, R^{C}, or R^{DD} is selected from the group consisting of the General Substituents defined herein. In some embodiments, at least one R^{A} is selected from the group consisting of the General Substituents defined herein. In some embodiments, at least one R^{AA} is selected from the group consisting of the General Substituents defined herein. In some embodiments, at least one R^{C} is selected from the group consisting of the General Substituents defined herein. In some embodiments, at least one R^{DD} is selected from the group consisting of the General Substituents defined herein. In some embodiments, where ligand L_{A} is selected from LIST 1, at least one R, R′, R¹, R², R^{A}, R^{AA}, R^{C}, or R^{DD} is partially or fully deuterated. In some embodiments, at least one R^{A} is partially or fully deuterated. In some embodiments, at least one R^{AA} is partially or fully deuterated. In some embodiments, at least one R^{DD} is partially or fully deuterated. In some embodiments, at least one R^{C} is partially or fully deuterated. In some embodiments, at least one R¹ or R² is partially or fully deuterated. In some embodiments, at least one R or R′ is partially or fully deuterated.

In some embodiments where ligand L_{A} is selected from LIST 1, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments where ligand L_{A} is selected from LIST 1, at least one R^{A} is or comprises an electron-withdrawing group from the EWG1 LIST as defined herein. In some embodiments, at least one R^{AA} is or comprises an electron-withdrawing group from the EWG2 LIST as defined herein. In some embodiments, at least one R^{AA} is or comprises an electron-withdrawing group from the EWG3 LIST as defined herein. In some embodiments, at least one R^{AA} is or comprises an electron-withdrawing group from the EWG4 LIST as defined herein. In some embodiments, at least one R^{AA} is or comprises an electron-withdrawing group from the Pi-EWG LIST as defined herein.

In some embodiments where ligand L_{A} is selected from LIST 1, at least one R^{C} is or comprises an electron-withdrawing group from the EWG1 LIST as defined herein. In some embodiments, at least one R^{C} is or comprises an electron-withdrawing group from the EWG2 LIST as defined herein. In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined.

In some embodiments where ligand L_{A} is selected from LIST 1, at least one R^{DD} is or comprises an electron-withdrawing group from the EWG1 LIST as defined herein. In some embodiments, at least one R^{DD} is or comprises an electron-withdrawing group from the EWG2 LIST as defined herein. In some embodiments, at least one R^{DD} is or comprises an electron-withdrawing group from the EWG3 LIST as defined herein. In some embodiments, at least one R^{DD} is or comprises an electron-withdrawing group from the EWG4 LIST as defined herein. In some embodiments, at least one R^{DD} is or comprises an electron-withdrawing group from the Pi-EWG LIST as defined herein.

In some embodiments where ligand L_{A} is selected from LIST 1, at least one R¹ or R² is or comprises an electron-withdrawing group from the EWG1 LIST as defined herein. In some embodiments, at least one R¹ or R² is or comprises an electron-withdrawing group from the EWG2 LIST as defined herein. In some embodiments, at least one R¹ or R² is or comprises an electron-withdrawing group from the EWG3 LIST as defined herein. In some embodiments, at least one R¹ or R² is or comprises an electron-withdrawing group from the EWG4 LIST as defined herein. In some embodiments, at least one R¹ or R² is or comprises an electron-withdrawing group from the Pi-EWG LIST as defined.

In some embodiments, the ligand L_{A} is selected from the group consisting of the structures of the following LIST 2:

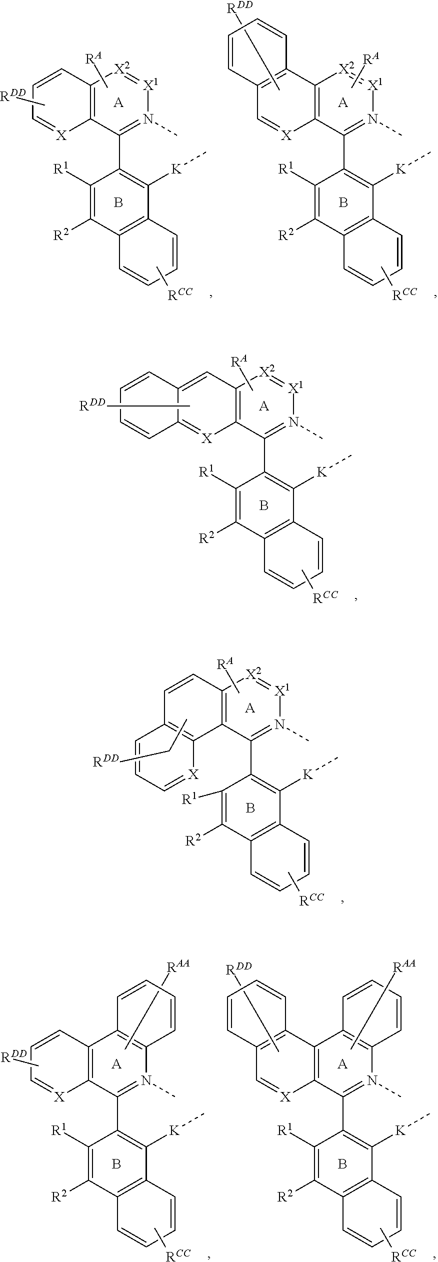

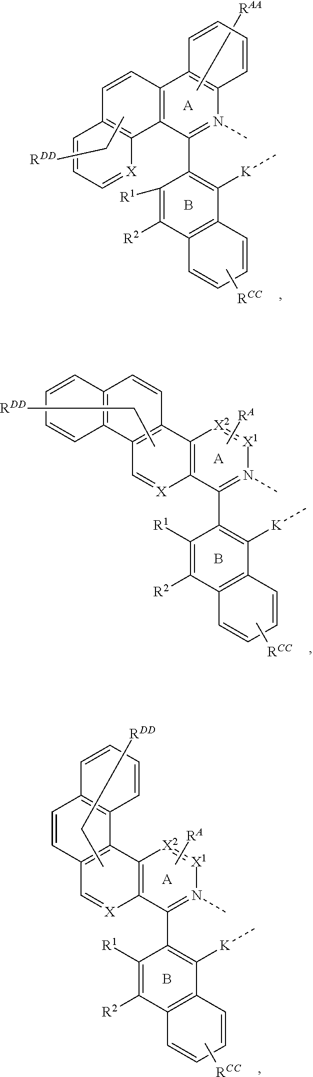

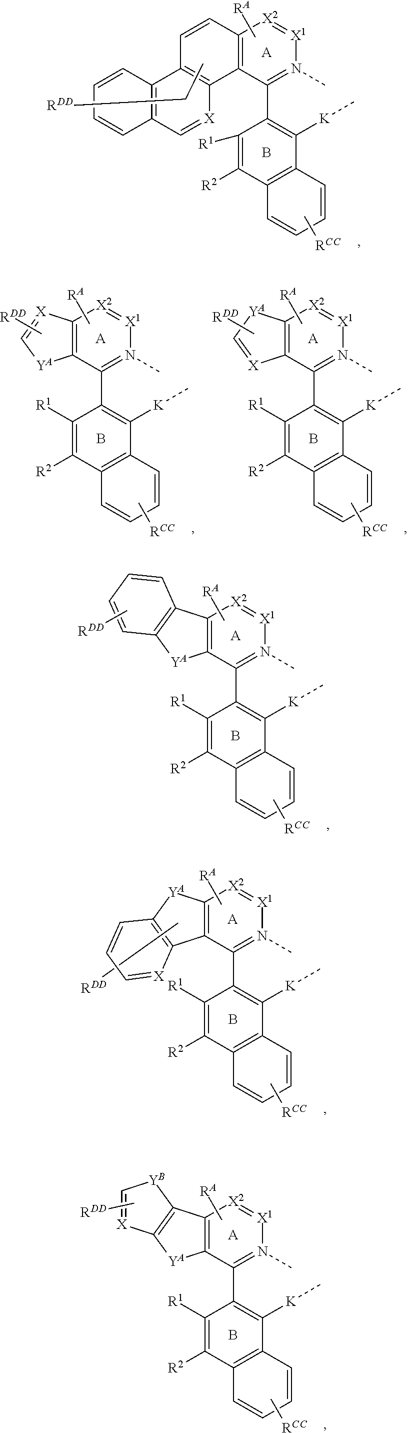

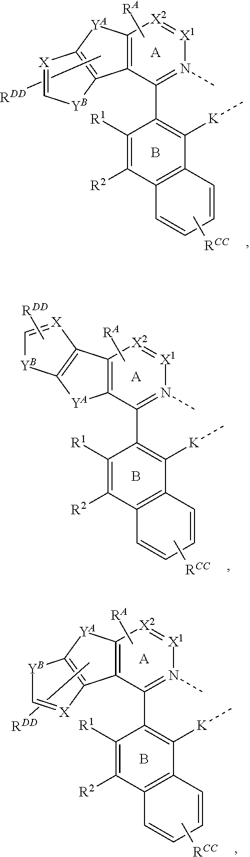

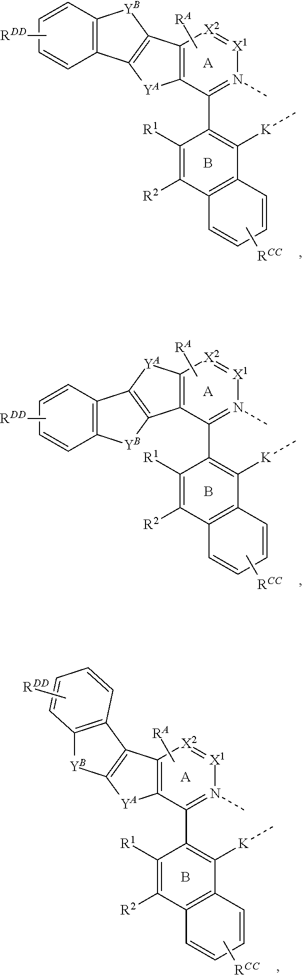

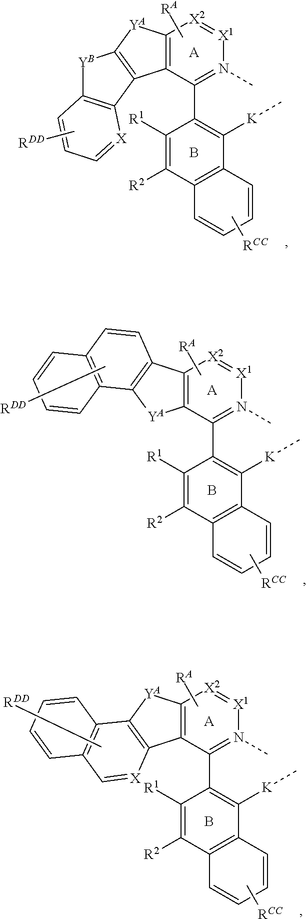

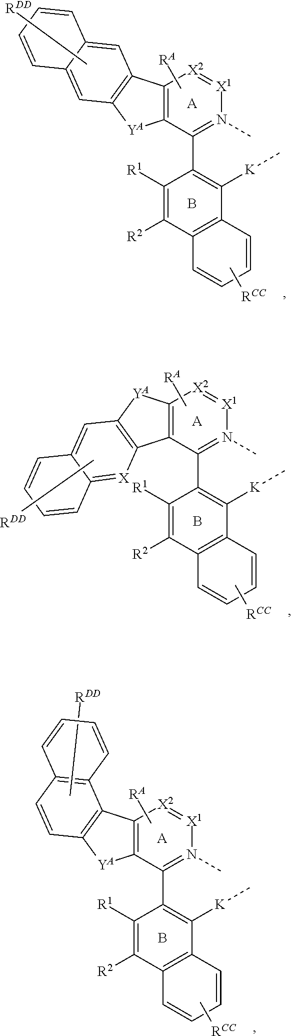

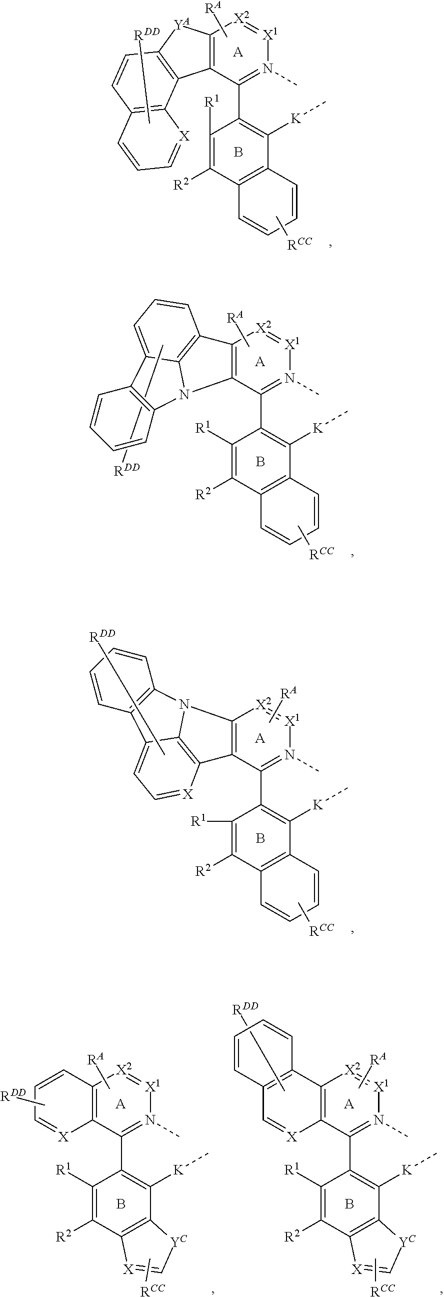

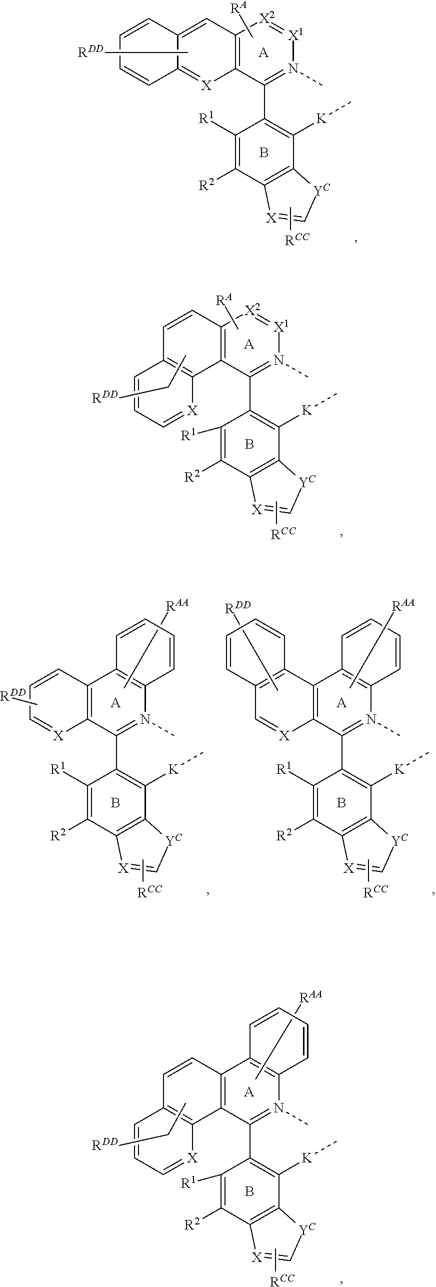

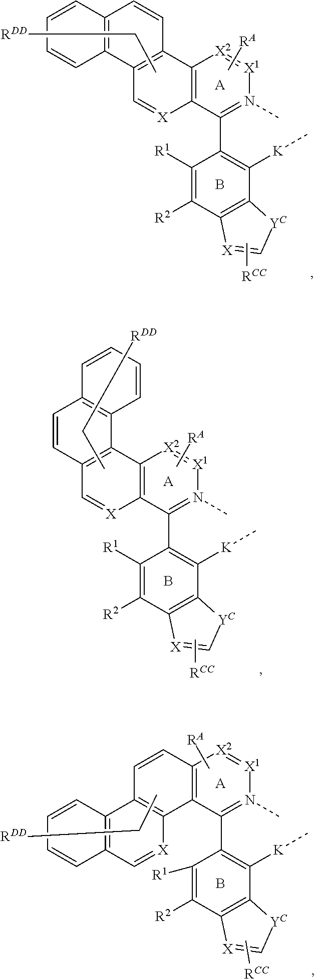

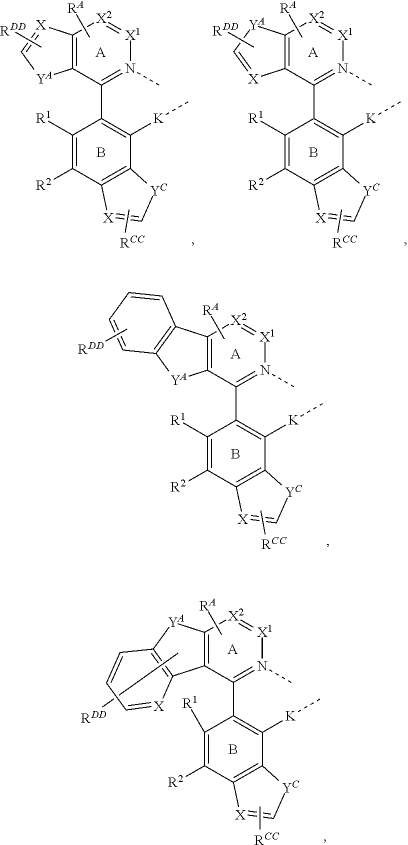

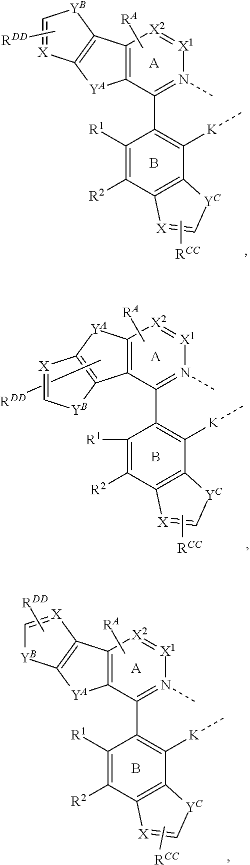

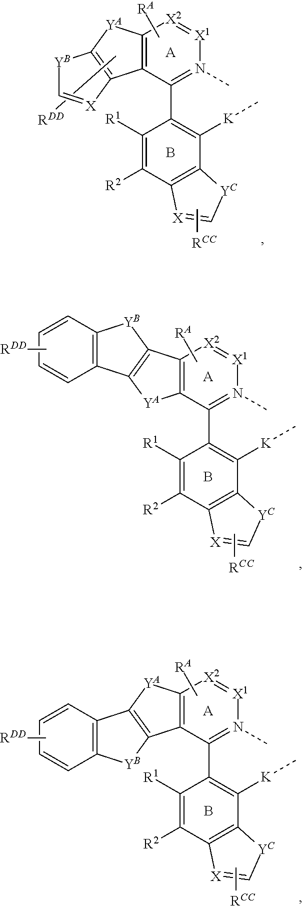

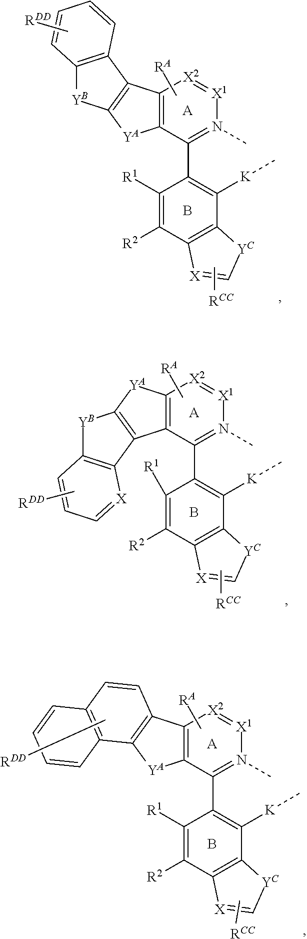

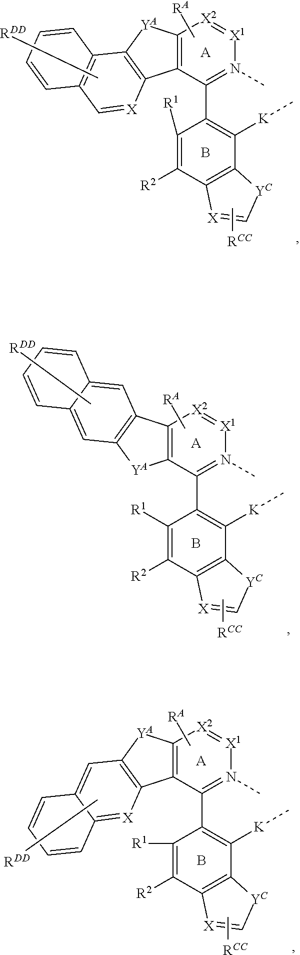

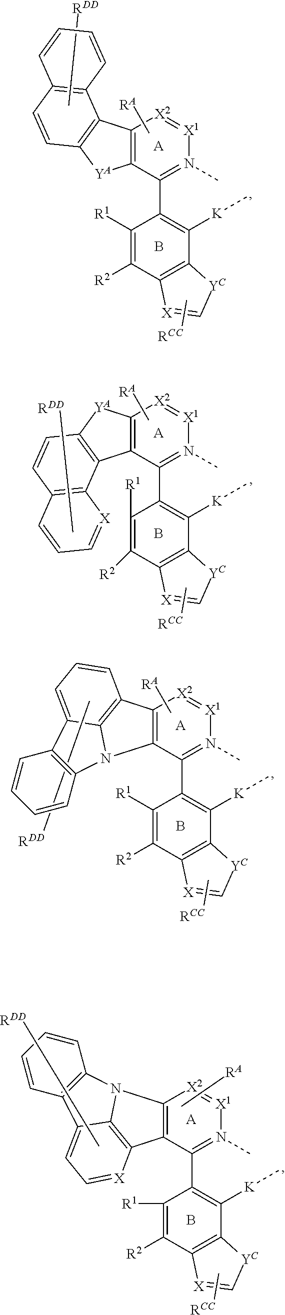

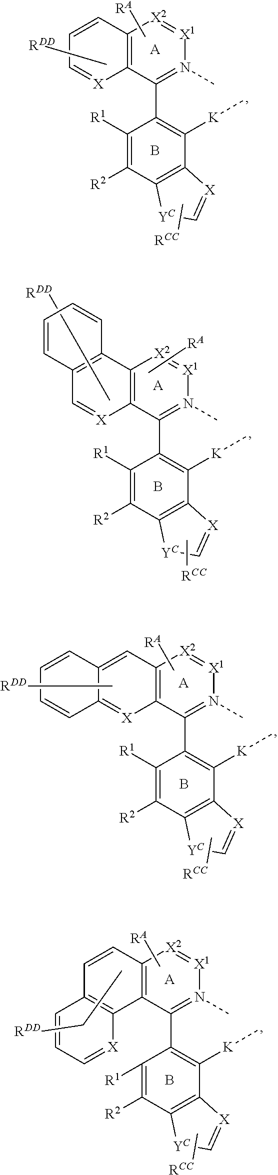

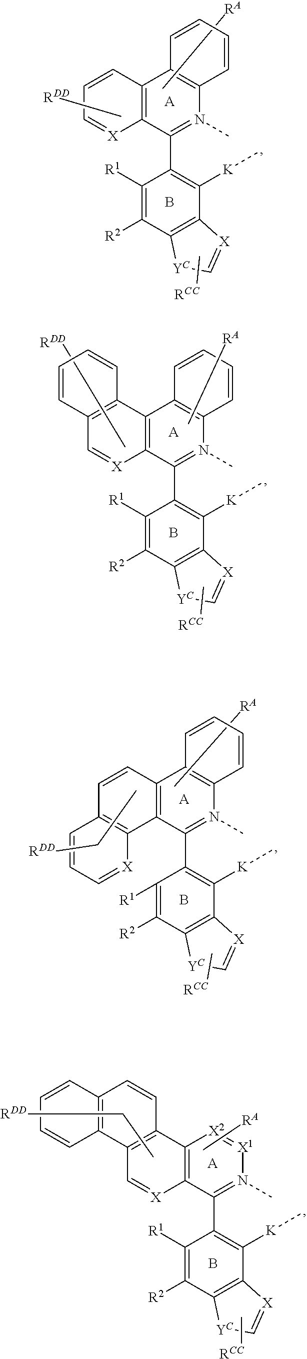

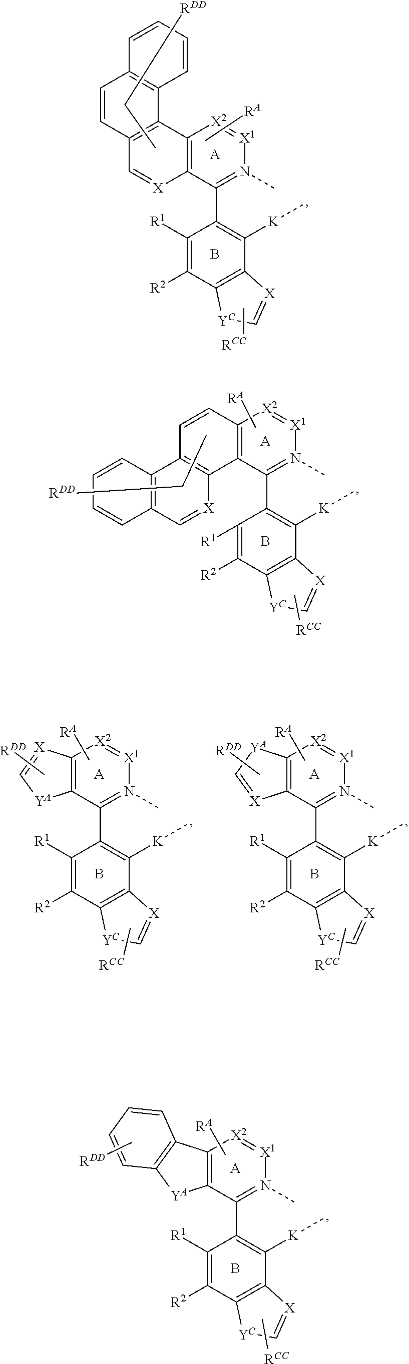

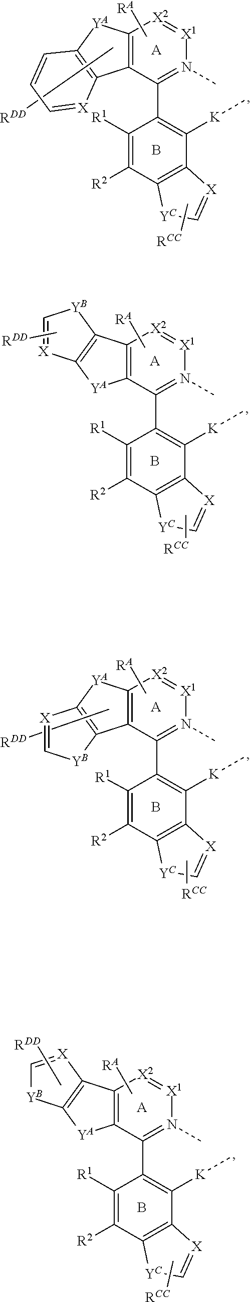

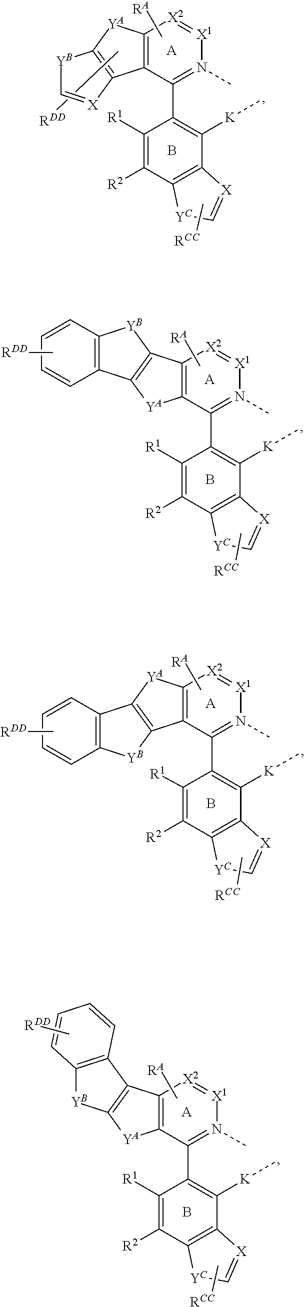

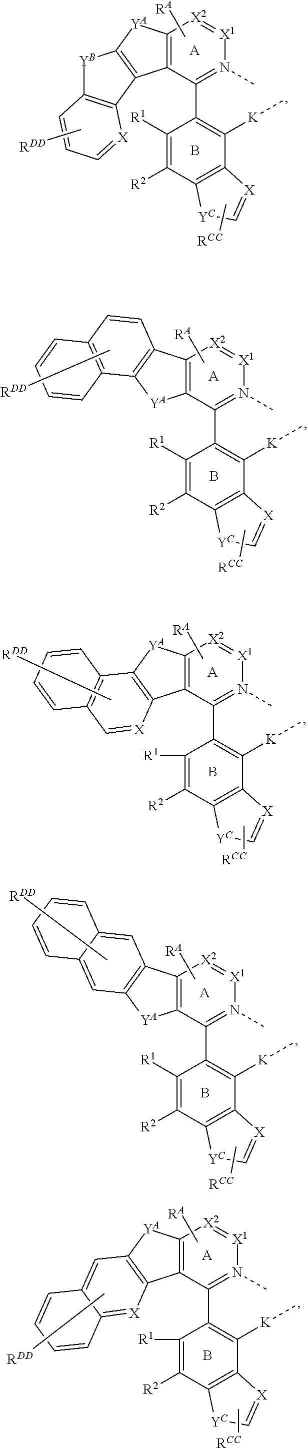

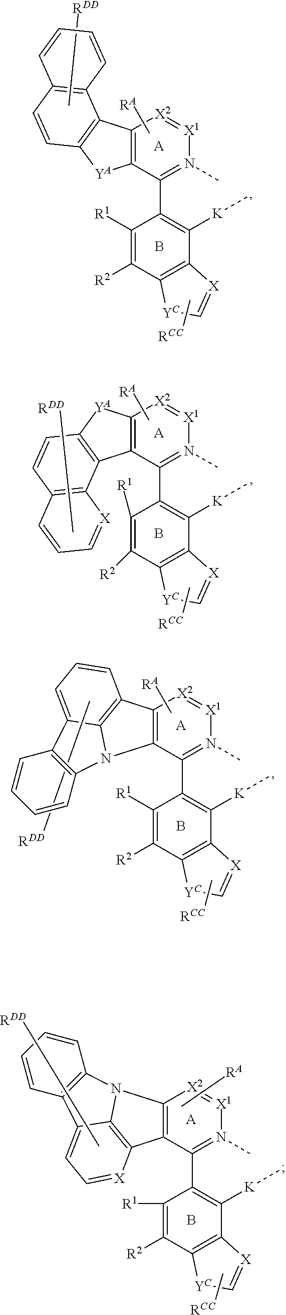

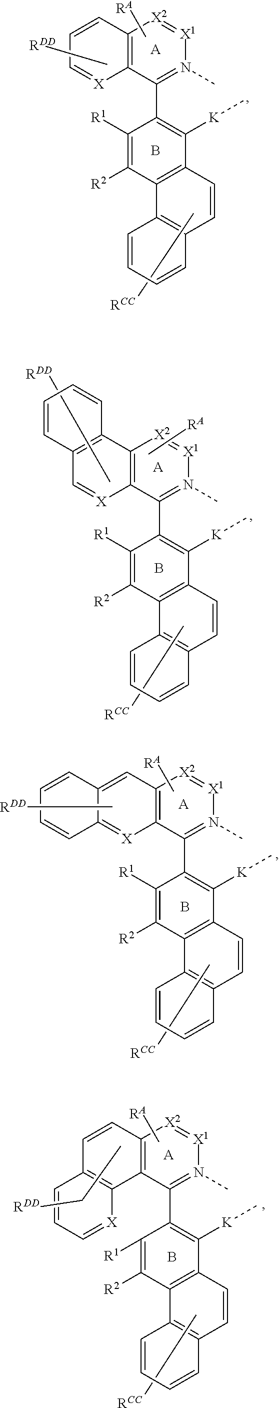

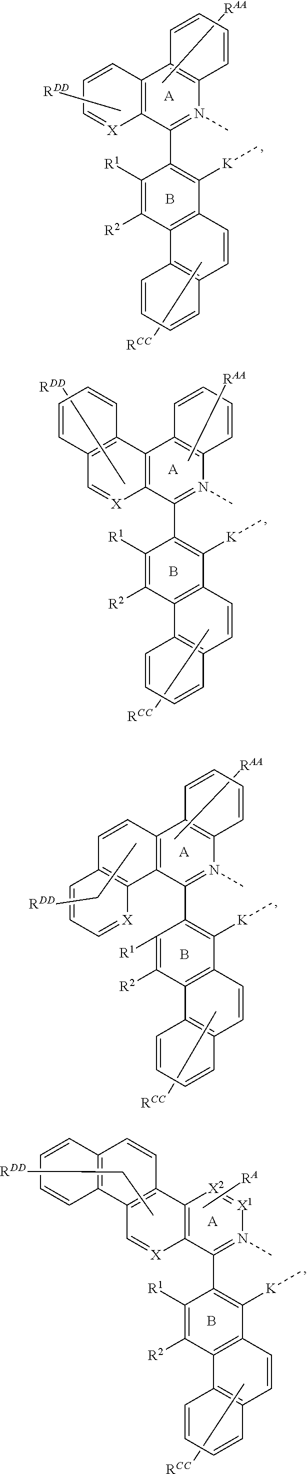

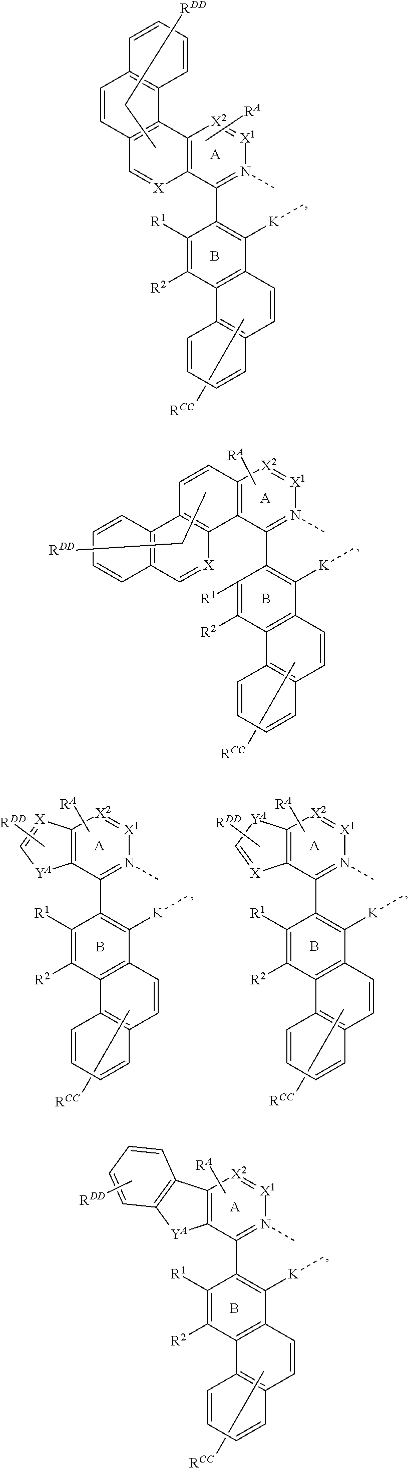

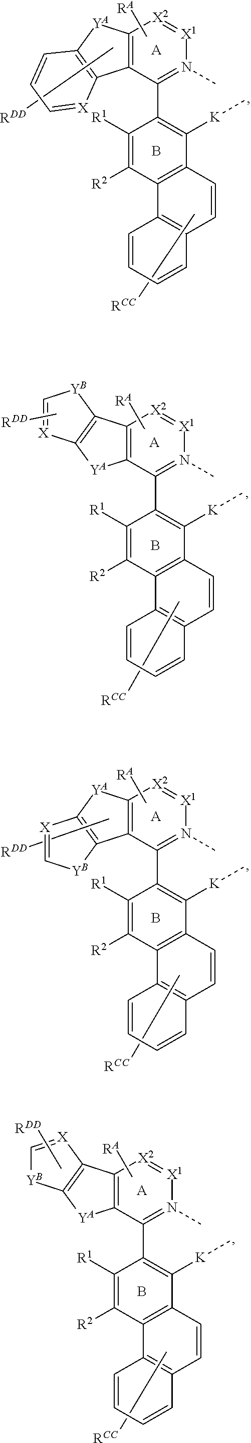

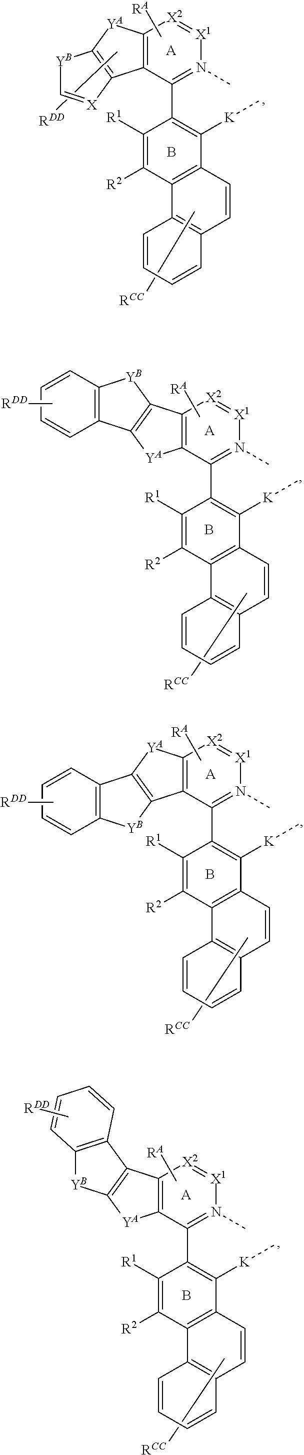

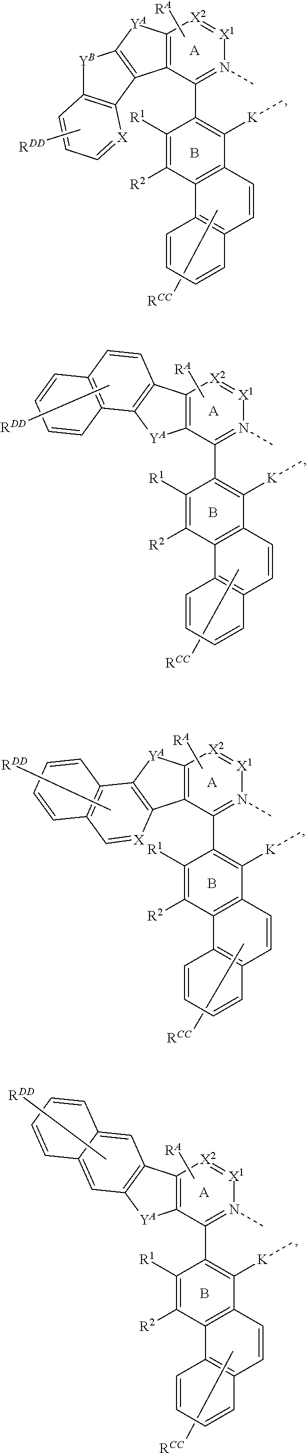

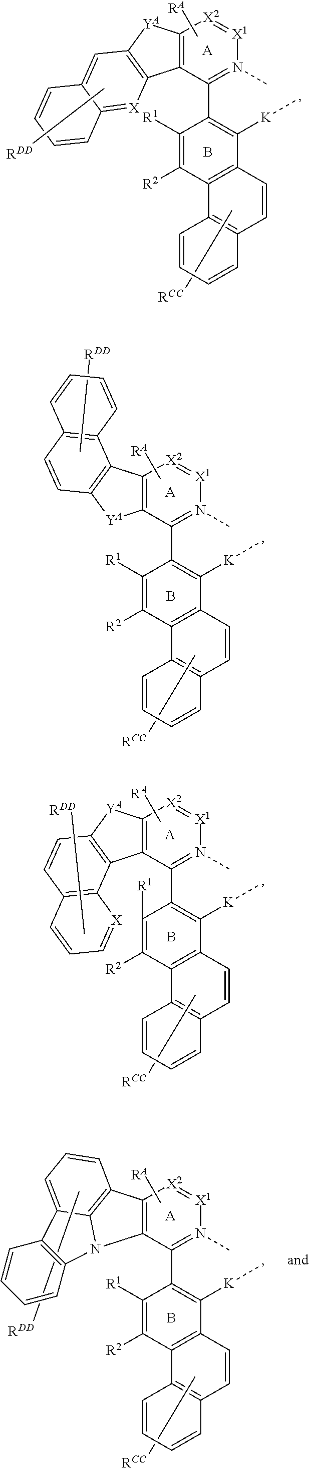

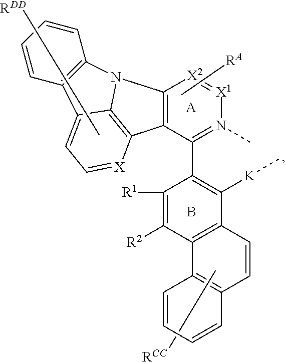

wherein:
each of Y^{A}, Y^{B}, and Y^{C} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
each of R^{AA}, R^{CC}, and R^{DD} independently represents mono to the maximum allowable substitution, or no substitution;
each R, R′, R^{A}, R^{AA}, R^{CC}, and R^{DD} is independently hydrogen or a substituent selected from the group consisting of the General Substituents defined herein; and
any two substituents may be optionally joined or fused to form a ring.

In some embodiments where ligand L_{A} is selected from LIST 2, at least one R^{A}, R^{AA}, R^{CC}, or R^{DD} is selected from the group consisting of the General Substituents defined herein. In some embodiments, at least one R^{A} is selected from the group consisting of the General Substituents defined herein. In some embodiments, at least one R′ is selected from the group consisting of the General Substituents defined herein. In some embodiments, at least one R^{CC} is selected from the group consisting of the General Substituents defined herein. In some embodiments, at least one R^{DD} is selected from the group consisting of the General Substituents defined herein. In some embodiments where ligand L_{A} is selected from LIST 2, at least one of R, R′, R¹, R², R^{A}, R^{AA}, R^{CC}, or R^{DD} is partially or fully deuterated. In some embodiments, at least one R^{A} is partially or fully deuterated. In some embodiments, at least one R^{AA} is partially or fully deuterated. In some embodiments, at least one R^{CC} is partially or fully deuterated. In some embodiments, at least one R^{DD} is partially or fully deuterated. In some embodiments, at least one R¹ or R² is partially or fully deuterated. In some embodiments, at least one R or R′ is partially or fully deuterated.

In some embodiments where ligand L_{A} is selected from LIST 2, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments where ligand L_{A} is selected from LIST 2, at least one R^{A} is or comprises an electron-withdrawing group from the EWG1 LIST as defined herein. In some embodiments, at least one R^{AA} is or comprises an electron-withdrawing group from the EWG2 LIST as defined herein. In some embodiments, at least one R′ is or comprises an electron-withdrawing group from the EWG3 LIST as defined herein. In some embodiments, at least one R^{AA} is or comprises an electron-withdrawing group from the EWG4 LIST as defined herein. In some embodiments, at least one R^{AA} is or comprises an electron-withdrawing group from the Pi-EWG LIST as defined herein.

In some embodiments where ligand L_{A} is selected from LIST 2, at least one R^{CC} is or comprises an electron-withdrawing group from the EWG1 LIST as defined herein. In some embodiments, at least one R^{CC} is or comprises an electron-withdrawing group from the EWG2 LIST as defined herein. In some embodiments, at least one R^{CC} is or comprises an electron-withdrawing group from the EWG3 LIST as defined herein. In some embodiments, at least one R^{CC} is or comprises an electron-withdrawing group from the EWG4 LIST as defined herein. In some embodiments, at least one R^{CC} is or comprises an electron-withdrawing group from the Pi-EWG LIST as defined.

In some embodiments where ligand L_{A} is selected from LIST 2, at least one R^{DD} is or comprises an electron-withdrawing group from the EWG1 LIST as defined herein. In some embodiments, at least one R^{DD} is or comprises an electron-withdrawing group from the EWG2 LIST as defined herein. In some embodiments, at least one R^{DD} is or comprises an electron-withdrawing group from the EWG3 LIST as defined herein. In some embodiments, at least one R^{DD} is or comprises an electron-withdrawing group from the EWG4 LIST as defined herein. In some embodiments, at least one R^{DD} is or comprises an electron-withdrawing group from the Pi-EWG LIST as defined herein.

In some embodiments where ligand L_{A} is selected from LIST 2, at least one R¹ or R² is or comprises an electron-withdrawing group from the EWG1 LIST as defined herein. In some embodiments, at least one R¹ or R² is or comprises an electron-withdrawing group from the EWG2 LIST as defined herein. In some embodiments, at least one R¹ or R² is or comprises an electron-withdrawing group from the EWG3 LIST as defined herein. In some embodiments, at least one R¹ or R² is or comprises an electron-withdrawing group from the EWG4 LIST as defined herein. In some embodiments, at least one R¹ or R² is or comprises an electron-withdrawing group from the Pi-EWG LIST as defined.

In some embodiments where ligand L_{A} is Selected from LIST 2, at least one R or R′ is or comprises an electron-withdrawing group from the EWG1 LIST as defined herein. In some embodiments, at least one R or R′ is or comprises an electron-withdrawing group from the EWG2 LIST as defined herein. In some embodiments, at least one R or R′ is or comprises an electron-withdrawing group from the EWG3 LIST as defined herein. In some embodiments, at least one R or R′ is or comprises an electron-withdrawing group from the EWG4 LIST as defined herein. In some embodiments, at least one R or R′ is or comprises an electron-withdrawing group from the Pi-EWG LIST as defined.

In some embodiments, the ligand L_{A} is Selected from L_{Ai}(R^{EA})(R^{EB})(R^{EC})(R^{ED})(R^{EE}); wherein i is an integer from 1 to 148, and each of R^{EA}, R^{EB}, R^{EC}, R^{ED}, and R^{EE}, is independently selected from the group consisting of R¹ to R¹⁵⁰; wherein each of L_{A1}(R¹)(R¹)(R¹)(R¹)(R¹) to L_{A148}(R¹⁵⁰)(R¹⁵⁰)(R¹⁵⁰)(R¹⁵⁰)(R¹⁵⁰) is defined in the following LIST 3:

| L_{A} | Structure of L_{A} |
|---|---|
| L_{A1}(R^{EA})(R^{EB}) (R^{EC})(R^{ED}) (R^{EE}), wherein L_{A1}(R¹)(R¹) (R¹)(R¹)(R¹) to L_{A1}(R¹⁵⁰)(R¹⁵⁰) (R¹⁵⁰)(R¹⁵⁰) (R¹⁵⁰) have the structure | 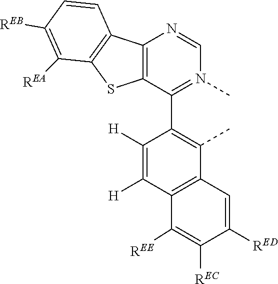 |
| L_{A2}(R^{EA})(R^{EB}) (R^{EC})(R^{ED}) (R^{EE}), wherein L_{A2}(R¹)(R¹) (R¹)(R¹)(R¹) to L_{A2}(R¹⁵⁰)(R¹⁵⁰) (R¹⁵⁰)(R¹⁵⁰) (R¹⁵⁰) have the structure | 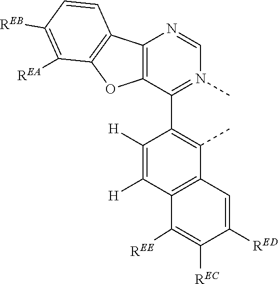 |
| L_{A3}(R^{EA})(R^{EB}) (R^{EC})(R^{ED}) (R^{EE}), wherein L_{A3}(R¹)(R¹) (R¹)(R¹)(R¹) to L_{A3}(R¹⁵⁰)(R¹⁵⁰) (R¹⁵⁰)(R¹⁵⁰) (R¹⁵⁰) have the structure | 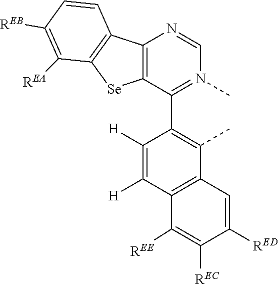 |
| L_{A4}(R^{EA})(R^{EB}) (R^{EC})(R^{ED}) (R^{EE}), wherein L_{A4}(R¹)(R¹) (R¹)(R¹)(R¹) to L_{A4}(R¹⁵⁰)(R¹⁵⁰) (R¹⁵⁰)(R¹⁵⁰) (R¹⁵⁰) have the structure | 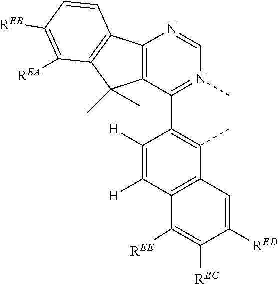 |
| L_{A5}(R^{EA})(R^{EB}) (R^{EC})(R^{ED}) (R^{EE}), wherein L_{A5}(R¹)(R¹) (R¹)(R¹)(R¹) to L_{A5}(R¹⁵⁰)(R¹⁵⁰) (R¹⁵⁰)(R¹⁵⁰) (R¹⁵⁰) have the structure | 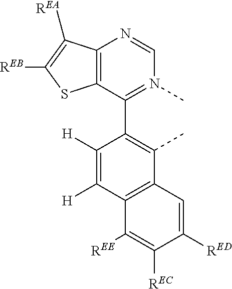 |
| L_{A6}(R^{EA})(R^{EB}) (R^{EC})(R^{ED}) (R^{EE}), wherein L_{A6}(R¹)(R¹) (R¹)(R¹)(R¹) to L_{A6}(R¹⁵⁰)(R¹⁵⁰) (R¹⁵⁰)(R¹⁵⁰) (R¹⁵⁰) have the structure | 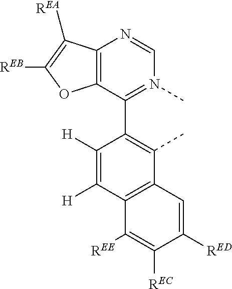 |
| L_{A7}(R^{EA})(R^{EB}) (R^{EC})(R^{ED}) (R^{EE}), wherein L_{A7}(R¹)(R¹) (R¹)(R¹)(R¹) to L_{A7}(R¹⁵⁰)(R¹⁵⁰) (R¹⁵⁰)(R¹⁵⁰) (R¹⁵⁰) have the structure | 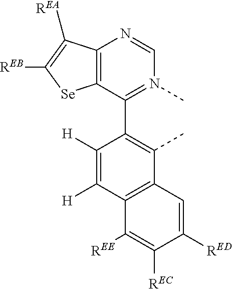 |
| L_{A8}(R^{EA})(R^{EB}) (R^{EC})(R^{ED}) (R^{EE}), wherein L_{A8}(R¹)(R¹) (R¹)(R¹)(R¹) to L_{A8}(R¹⁵⁰)(R¹⁵⁰) (R¹⁵⁰)(R¹⁵⁰) (R¹⁵⁰) have the structure | 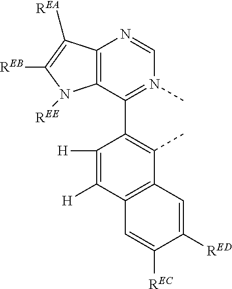 |
| L_{A9}(R^{EA})(R^{EB}) (R^{EC})(R^{ED}) (R^{EE}), wherein L_{A9}(R¹)(R¹) (R¹)(R¹)(R¹) to L_{A9}(R¹⁵⁰)(R¹⁵⁰) (R¹⁵⁰)(R¹⁵⁰) (R¹⁵⁰) have the structure | 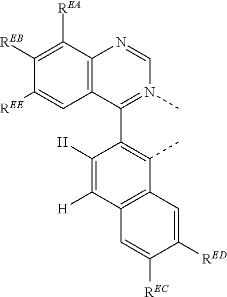 |
| L_{A10}(R^{EA})(R^{EB}) (R^{EC})(R^{ED}) (R^{EE}), wherein L_{A10}(R¹)(R¹) (R¹)(R¹)(R¹) to L_{A10}(R¹⁵⁰)(R¹⁵⁰) (R¹⁵⁰)(R¹⁵⁰) (R¹⁵⁰) have the structure | 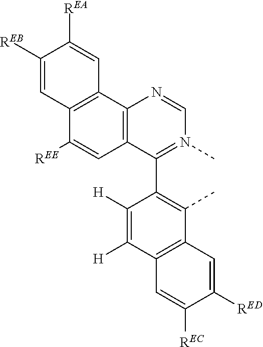 |
| L_{A11}(R^{EA})(R^{EB}) (R^{EC})(R^{ED}) (R^{EE}), wherein L_{A11}(R¹)(R¹) (R¹)(R¹)(R¹) to L_{A11}(R¹⁵⁰)(R¹⁵⁰) (R¹⁵⁰)(R¹⁵⁰) (R¹⁵⁰) have the structure | 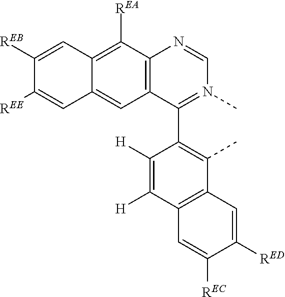 |
| L_{A12}(R^{EA})(R^{EB}) (R^{EC})(R^{ED}) (R^{EE}), wherein L_{A12}(R¹)(R¹) (R¹)(R¹)(R¹) to L_{A12}(R¹⁵⁰)(R¹⁵⁰) (R¹⁵⁰)(R¹⁵⁰) (R¹⁵⁰) have the structure | 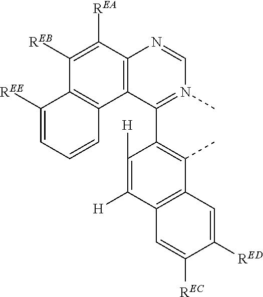 |
| L_{A13}(R^{EA})(R^{EB}) (R^{EC})(R^{ED}) (R^{EE}), wherein L_{A13}(R¹)(R¹) (R¹)(R¹)(R¹) to L_{A13}(R¹⁵⁰)(R¹⁵⁰) (R¹⁵⁰)(R¹⁵⁰) (R¹⁵⁰) have the structure | 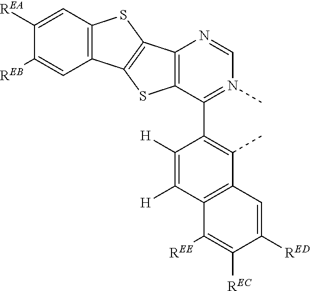 |
| L_{A14}(R^{EA})(R^{EB}) (R^{EC})(R^{ED}) (R^{EE}), wherein L_{A14}(R¹)(R¹) (R¹)(R¹)(R¹) to L_{A14}(R¹⁵⁰)(R¹⁵⁰) (R¹⁵⁰)(R¹⁵⁰) (R¹⁵⁰) have the structure | 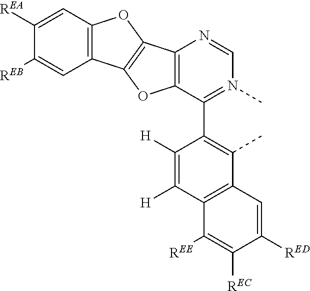 |
| L_{A15}(R^{EA})(R^{EB}) (R^{EC})(R^{ED}) (R^{EE}), wherein L_{A15}(R¹)(R¹) (R¹)(R¹)(R¹) to L_{A15}(R¹⁵⁰)(R¹⁵⁰) (R¹⁵⁰)(R¹⁵⁰) (R¹⁵⁰) have the structure | 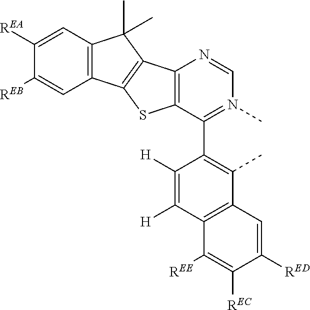 |
| L_{A16}(R^{EA})(R^{EB}) (R^{EC})(R^{ED}) (R^{EE}), wherein L_{A16}(R¹)(R¹) (R¹)(R¹)(R¹) to L_{A16}(R¹⁵⁰)(R¹⁵⁰) (R¹⁵⁰)(R¹⁵⁰) (R¹⁵⁰) have the structure | 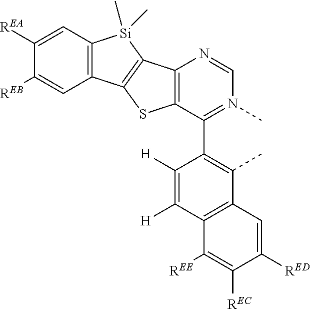 |
| L_{A17}(R^{EA})(R^{EB}) (R^{EC})(R^{ED}) (R^{EE}), wherein L_{A17}(R¹)(R¹) (R¹)(R¹)(R¹) to L_{A17}(R¹⁵⁰)(R¹⁵⁰) (R¹⁵⁰)(R¹⁵⁰) (R¹⁵⁰) have the structure | 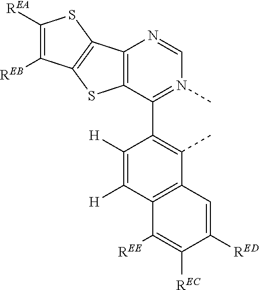 |
| L_{A18}(R^{EA})(R^{EB}) (R^{EC})(R^{ED}) (R^{EE}), wherein L_{A18}(R¹)(R¹) (R¹)(R¹)(R¹) to L_{A18}(R¹⁵⁰)(R¹⁵⁰) (R¹⁵⁰)(R¹⁵⁰) (R¹⁵⁰) have the structure | 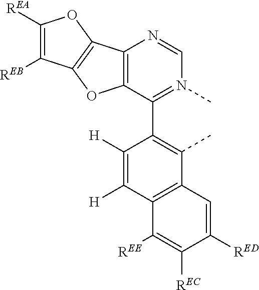 |
| L_{A19}(R^{EA})(R^{EB}) (R^{EC})(R^{ED}) (R^{EE}), wherein L_{A19}(R¹)(R¹) (R¹)(R¹)(R¹) to L_{A19}(R¹⁵⁰)(R¹⁵⁰) (R¹⁵⁰)(R¹⁵⁰) (R¹⁵⁰) have the structure | 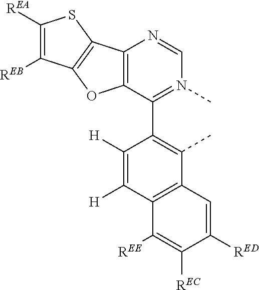 |
| L_{A20}(R^{EA})(R^{EB}) (R^{EC})(R^{ED}) (R^{EE}), wherein L_{A20}(R¹)(R¹) (R¹)(R¹)(R¹) to L_{A20}(R¹⁵⁰)(R¹⁵⁰) (R¹⁵⁰)(R¹⁵⁰) (R¹⁵⁰) have the structure | 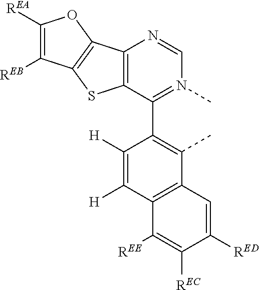 |
| L_{A21}(R^{EA})(R^{EB}) (R^{EC})(R^{ED}) (R^{EE}), wherein L_{A21}(R¹)(R¹) (R¹)(R¹)(R¹) to L_{A21}(R¹⁵⁰)(R¹⁵⁰) (R¹⁵⁰)(R¹⁵⁰) (R¹⁵⁰) have the structure | 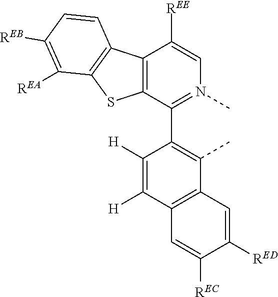 |
| L_{A22}(R^{EA})(R^{EB}) (R^{EC})(R^{ED}) (R^{EE}), wherein L_{A22}(R¹)(R¹) (R¹)(R¹)(R¹) to L_{A22}(R¹⁵⁰)(R¹⁵⁰) (R¹⁵⁰)(R¹⁵⁰) (R¹⁵⁰) have the structure | 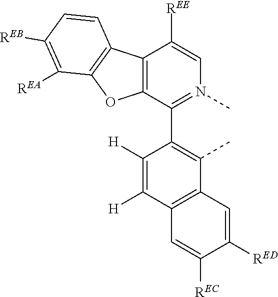 |
| L_{A23}(R^{EA})(R^{EB}) (R^{EC})(R^{ED}) (R^{EE}), wherein L_{A23}(R¹)(R¹) (R¹)(R¹)(R¹) to L_{A23}(R¹⁵⁰)(R¹⁵⁰) (R¹⁵⁰)(R¹⁵⁰) (R¹⁵⁰) have the structure | 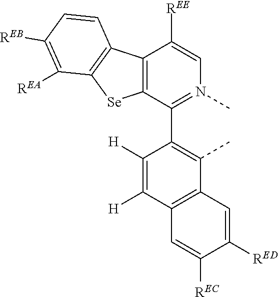 |
| L_{A24}(R^{EA})(R^{EB}) (R^{EC})(R^{ED}) (R^{EE}), wherein L_{A24}(R¹)(R¹) (R¹)(R¹)(R¹) to L_{A24}(R¹⁵⁰)(R¹⁵⁰) (R¹⁵⁰)(R¹⁵⁰) (R¹⁵⁰) have the structure | 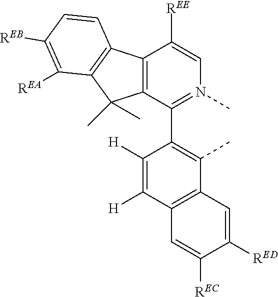 |
| L_{A25}(R^{EA})(R^{EB}) (R^{EC})(R^{ED}) (R^{EE}), wherein L_{A25}(R¹)(R¹) (R¹)(R¹)(R¹) to L_{A25}(R¹⁵⁰)(R¹⁵⁰) (R¹⁵⁰)(R¹⁵⁰) (R¹⁵⁰) have the structure | 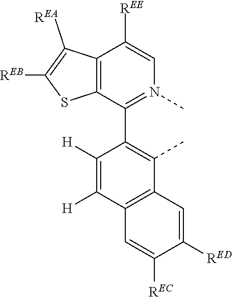 |
| L_{A26}(R^{EA})(R^{EB}) (R^{EC})(R^{ED}) (R^{EE}), wherein L_{A26}(R¹)(R¹) (R¹)(R¹)(R¹) to L_{A26}(R¹⁵⁰)(R¹⁵⁰) (R¹⁵⁰)(R¹⁵⁰) (R¹⁵⁰) have the structure | 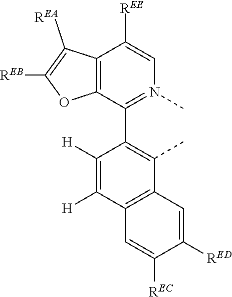 |
| L_{A27}(R^{EA})(R^{EB}) (R^{EC})(R^{ED}) (R^{EE}), wherein L_{A27}(R¹)(R¹) (R¹)(R¹)(R¹) to L_{A27}(R¹⁵⁰)(R¹⁵⁰) (R¹⁵⁰)(R¹⁵⁰) (R¹⁵⁰) have the structure | 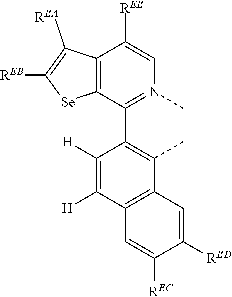 |
| L_{A28}(R^{EA})(R^{EB}) (R^{EC})(R^{ED}) (R^{EE}), wherein L_{A28}(R¹)(R¹) (R¹)(R¹)(R¹) to L_{A28}(R¹⁵⁰)(R¹⁵⁰) (R¹⁵⁰)(R¹⁵⁰) (R¹⁵⁰) have the structure | 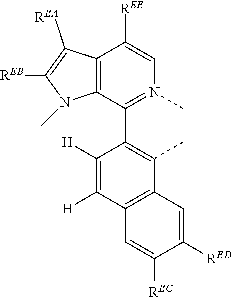 |
| L_{A29}(R^{EA})(R^{EB}) (R^{EC})(R^{ED}) (R^{EE}), wherein L_{A29}(R¹)(R¹) (R¹)(R¹)(R¹) to L_{A29}(R¹⁵⁰)(R¹⁵⁰) (R¹⁵⁰)(R¹⁵⁰) (R¹⁵⁰) have the structure | 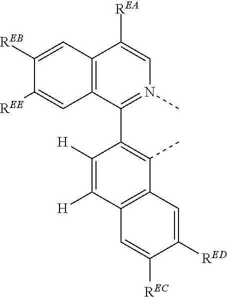 |
| L_{A30}(R^{EA})(R^{EB}) (R^{EC})(R^{ED}) (R^{EE}), wherein L_{A30}(R¹)(R¹) (R¹)(R¹)(R¹) to L_{A30}(R¹⁵⁰)(R¹⁵⁰) (R¹⁵⁰)(R¹⁵⁰) (R¹⁵⁰) have the structure | 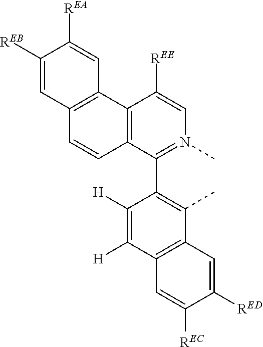 |
| L_{A31}(R^{EA})(R^{EB}) (R^{EC})(R^{ED}) (R^{EE}), wherein L_{A31}(R¹)(R¹) (R¹)(R¹)(R¹) to L_{A31}(R¹⁵⁰)(R¹⁵⁰) (R¹⁵⁰)(R¹⁵⁰) (R¹⁵⁰) have the structure | 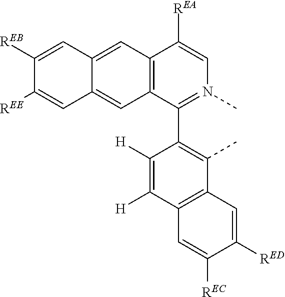 |
| L_{A32}(R^{EA})(R^{EB}) (R^{EC})(R^{ED}) (R^{EE}), wherein L_{A32}(R¹)(R¹) (R¹)(R¹)(R¹) to L_{A32}(R¹⁵⁰)(R¹⁵⁰) (R¹⁵⁰)(R¹⁵⁰) (R¹⁵⁰) have the structure | 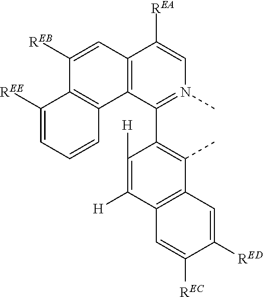 |
| L_{A33}(R^{EA})(R^{EB}) (R^{EC})(R^{ED}) (R^{EE}), wherein L_{A33}(R¹)(R¹) (R¹)(R¹)(R¹) to L_{A33}(R¹⁵⁰)(R¹⁵⁰) (R¹⁵⁰)(R¹⁵⁰) (R¹⁵⁰) have the structure | 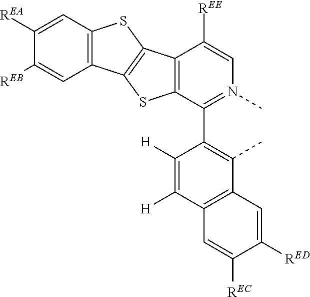 |
| L_{A34}(R^{EA})(R^{EB}) (R^{EC})(R^{ED}) (R^{EE}), wherein L_{A34}(R¹)(R¹) (R¹)(R¹)(R¹) to L_{A34}(R¹⁵⁰)(R¹⁵⁰) (R¹⁵⁰)(R¹⁵⁰) (R¹⁵⁰) have the structure | 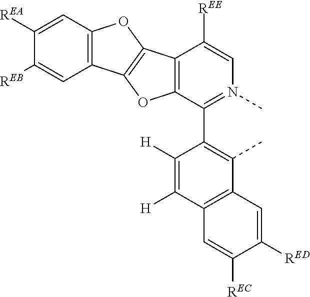 |
| L_{A35}(R^{EA})(R^{EB}) (R^{EC})(R^{ED}) (R^{EE}), wherein L_{A35}(R¹)(R¹) (R¹)(R¹)(R¹) to L_{A35}(R¹⁵⁰)(R¹⁵⁰) (R¹⁵⁰)(R¹⁵⁰) (R¹⁵⁰) have the structure | 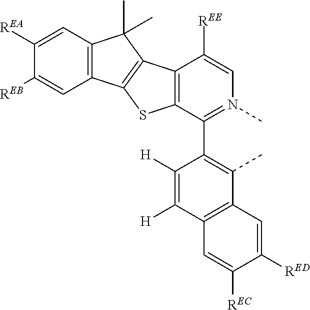 |
| L_{A36}(R^{EA})(R^{EB}) (R^{EC})(R^{ED}) (R^{EE}), wherein L_{A36}(R¹)(R¹) (R¹)(R¹)(R¹) to L_{A36}(R¹⁵⁰)(R¹⁵⁰) (R¹⁵⁰)(R¹⁵⁰) (R¹⁵⁰) have the structure | 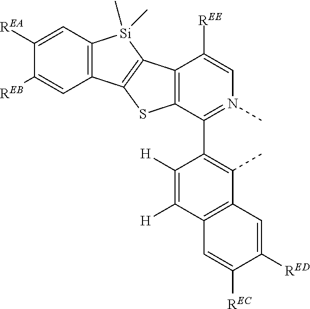 |
| L_{A37}(R^{EA})(R^{EB}) (R^{EC})(R^{ED}) (R^{EE}), wherein L_{A37}(R¹)(R¹) (R¹)(R¹)(R¹) to L_{A37}(R¹⁵⁰)(R¹⁵⁰) (R¹⁵⁰)(R¹⁵⁰) (R¹⁵⁰) have the structure | 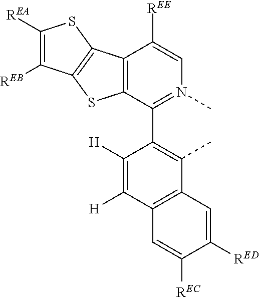 |
| L_{A38}(R^{EA})(R^{EB}) (R^{EC})(R^{ED}) (R^{EE}), wherein L_{A38}(R¹)(R¹) (R¹)(R¹)(R¹) to L_{A38}(R¹⁵⁰)(R¹⁵⁰) (R¹⁵⁰)(R¹⁵⁰) (R¹⁵⁰) have the structure | 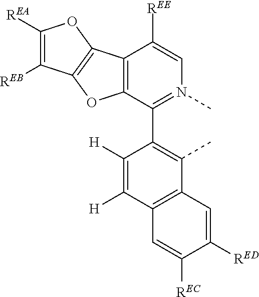 |
| L_{A39}(R^{EA})(R^{EB}) (R^{EC})(R^{ED}) (R^{EE}), wherein L_{A39}(R¹)(R¹) (R¹)(R¹)(R¹) to L_{A39}(R¹⁵⁰)(R¹⁵⁰) (R¹⁵⁰)(R¹⁵⁰) (R¹⁵⁰) have the structure | 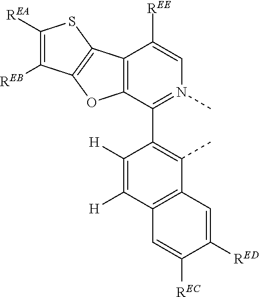 |
| L_{A40}(R^{EA})(R^{EB}) (R^{EC})(R^{ED}) (R^{EE}), wherein L_{A40}(R¹)(R¹) (R¹)(R¹)(R¹) to L_{A40}(R¹⁵⁰)(R¹⁵⁰) (R¹⁵⁰)(R¹⁵⁰) (R¹⁵⁰) have the structure | 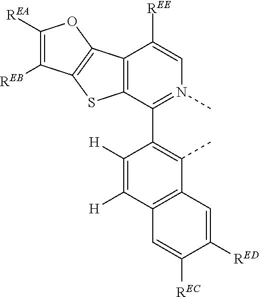 |
| L_{A41}(R^{EA})(R^{EB}) (R^{EC})(R^{ED}) (R^{EE}), wherein L_{A41}(R¹)(R¹) (R¹)(R¹)(R¹) to L_{A41}(R¹⁵⁰)(R¹⁵⁰) (R¹⁵⁰)(R¹⁵⁰) (R¹⁵⁰) have the structure | 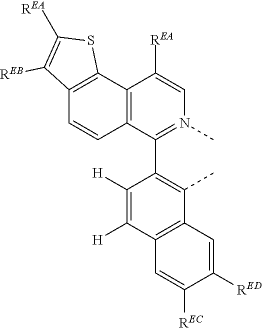 |
| L_{A42}(R^{EA})(R^{EB}) (R^{EC})(R^{ED}) (R^{EE}), wherein L_{A42}(R¹)(R¹) (R¹)(R¹)(R¹) to L_{A42}(R¹⁵⁰)(R¹⁵⁰) (R¹⁵⁰)(R¹⁵⁰) (R¹⁵⁰) have the structure | 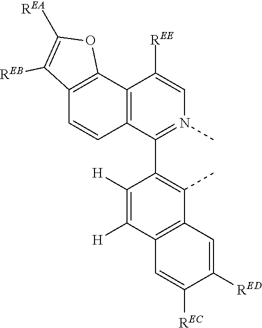 |
| L_{A43}(R^{EA})(R^{EB}) (R^{EC})(R^{ED}) (R^{EE}), wherein L_{A43}(R¹)(R¹) (R¹)(R¹)(R¹) to L_{A43}(R¹⁵⁰)(R¹⁵⁰) (R¹⁵⁰)(R¹⁵⁰) (R¹⁵⁰) have the structure | 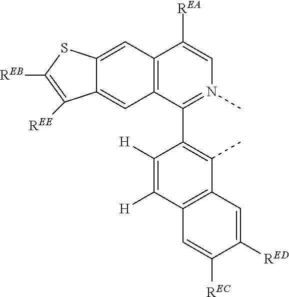 |
| L_{A44}(R^{EA})(R^{EB}) (R^{EC})(R^{ED}) (R^{EE}), wherein L_{A44}(R¹)(R¹) (R¹)(R¹)(R¹) to L_{A44}(R¹⁵⁰)(R¹⁵⁰) (R¹⁵⁰)(R¹⁵⁰) (R¹⁵⁰) have the structure | 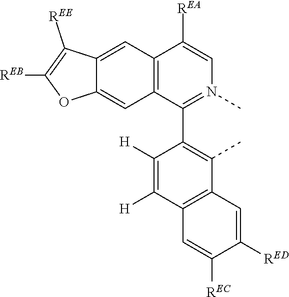 |
| L_{A45}(R^{EA})(R^{EB}) (R^{EC})(R^{ED}) (R^{EE}), wherein L_{A45}(R¹)(R¹) (R¹)(R¹)(R¹) to L_{A45}(R¹⁵⁰)(R¹⁵⁰) (R¹⁵⁰)(R¹⁵⁰) (R¹⁵⁰) have the structure | 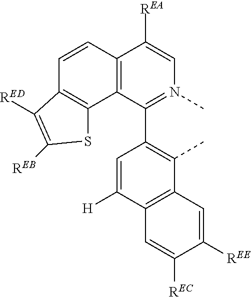 |
| L_{A46}(R^{EA})(R^{EB}) (R^{EC})(R^{ED}) (R^{EE}), wherein L_{A46}(R¹)(R¹) (R¹)(R¹)(R¹) to L_{A46}(R¹⁵⁰)(R¹⁵⁰) (R¹⁵⁰)(R¹⁵⁰) (R¹⁵⁰) have the structure | 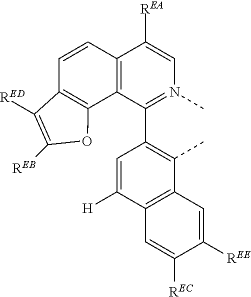 |
| L_{A47}(R^{EA})(R^{EB}) (R^{EC})(R^{ED}) (R^{EE}), wherein L_{A47}(R¹)(R¹) (R¹)(R¹)(R¹) to L_{A47}(R¹⁵⁰)(R¹⁵⁰) (R¹⁵⁰)(R¹⁵⁰) (R¹⁵⁰) have the structure | 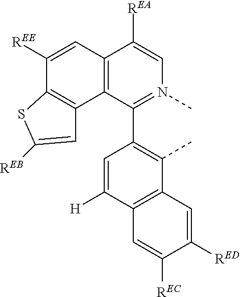 |
| L_{A48}(R^{EA})(R^{EB}) (R^{EC})(R^{ED}) (R^{EE}), wherein L_{A48}(R¹)(R¹) (R¹)(R¹)(R¹) to L_{A48}(R¹⁵⁰)(R¹⁵⁰) (R¹⁵⁰)(R¹⁵⁰) (R¹⁵⁰) have the structure | 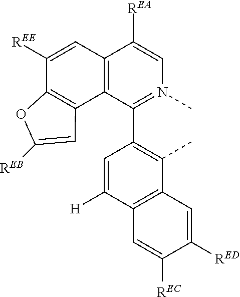 |
| L_{A49}(R^{EA})(R^{EB}) (R^{EC})(R^{ED}) (R^{EE}), wherein L_{A49}(R¹)(R¹) (R¹)(R¹)(R¹) to L_{A49}(R¹⁵⁰)(R¹⁵⁰) (R¹⁵⁰)(R¹⁵⁰) (R¹⁵⁰) have the structure | 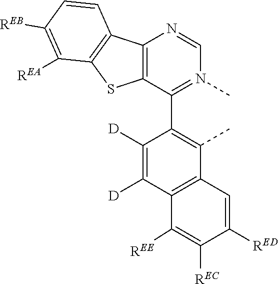 |
| L_{A50}(R^{EA})(R^{EB}) (R^{EC})(R^{ED}) (R^{EE}), wherein L_{A50}(R¹)(R¹) (R¹)(R¹)(R¹) to L_{A50}(R¹⁵⁰)(R¹⁵⁰) (R¹⁵⁰)(R¹⁵⁰) (R¹⁵⁰) have the structure | 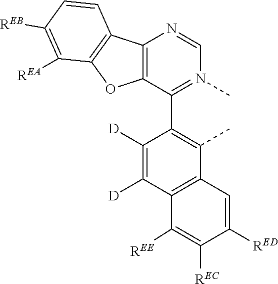 |
| L_{A51}(R^{EA})(R^{EB}) (R^{EC})(R^{ED}) (R^{EE}), wherein L_{A51}(R¹)(R¹) (R¹)(R¹)(R¹) to L_{A51}(R¹⁵⁰)(R¹⁵⁰) (R¹⁵⁰)(R¹⁵⁰) (R¹⁵⁰) have the structure | 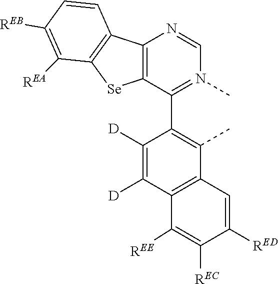 |
| L_{A52}(R^{EA})(R^{EB}) (R^{EC})(R^{ED}) (R^{EE}), wherein L_{A52}(R¹)(R¹) (R¹)(R¹)(R¹) to L_{A52}(R¹⁵⁰)(R¹⁵⁰) (R¹⁵⁰)(R¹⁵⁰) (R¹⁵⁰) have the structure | 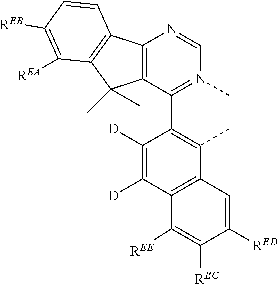 |
| L_{A53}(R^{EA})(R^{EB}) (R^{EC})(R^{ED}) (R^{EE}), wherein L_{A53}(R¹)(R¹) (R¹)(R¹)(R¹) to L_{A53}(R¹⁵⁰)(R¹⁵⁰) (R¹⁵⁰)(R¹⁵⁰) (R¹⁵⁰) have the structure | 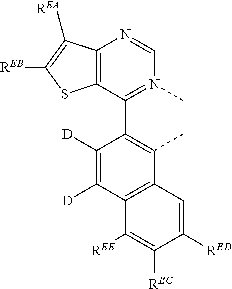 |
| L_{A54}(R^{EA})(R^{EB}) (R^{EC})(R^{ED}) (R^{EE}), wherein L_{A54}(R¹)(R¹) (R¹)(R¹)(R¹) to L_{A54}(R¹⁵⁰)(R¹⁵⁰) (R¹⁵⁰)(R¹⁵⁰) (R¹⁵⁰) have the structure | 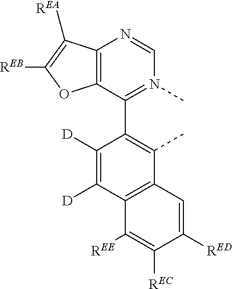 |
| L_{A55}(R^{EA})(R^{EB}) (R^{EC})(R^{ED}) (R^{EE}), wherein L_{A55}(R¹)(R¹) (R¹)(R¹)(R¹) to L_{A55}(R¹⁵⁰)(R¹⁵⁰) (R¹⁵⁰)(R¹⁵⁰) (R¹⁵⁰) have the structure | 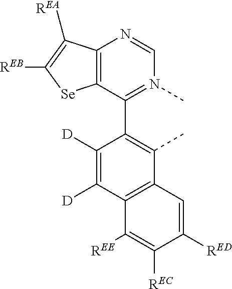 |
| L_{A56}(R^{EA})(R^{EB}) (R^{EC})(R^{ED}) (R^{EE}), wherein L_{A56}(R¹)(R¹) (R¹)(R¹)(R¹) to L_{A56}(R¹⁵⁰)(R¹⁵⁰) (R¹⁵⁰)(R¹⁵⁰) (R¹⁵⁰) have the structure | 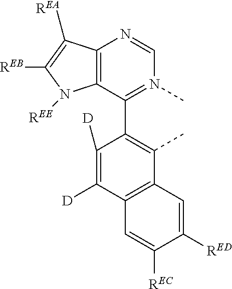 |
| L_{A57}(R^{EA})(R^{EB}) (R^{EC})(R^{ED}) (R^{EE}), wherein L_{A57}(R¹)(R¹) (R¹)(R¹)(R¹) to L_{A57}(R¹⁵⁰)(R¹⁵⁰) (R¹⁵⁰)(R¹⁵⁰) (R¹⁵⁰) have the structure | 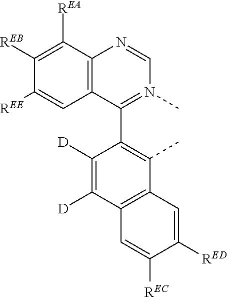 |
| L_{A58}(R^{EA})(R^{EB}) (R^{EC})(R^{ED}) (R^{EE}), wherein L_{A58}(R¹)(R¹) (R¹)(R¹)(R¹) to L_{A58}(R¹⁵⁰)(R¹⁵⁰) (R¹⁵⁰)(R¹⁵⁰) (R¹⁵⁰) have the structure | 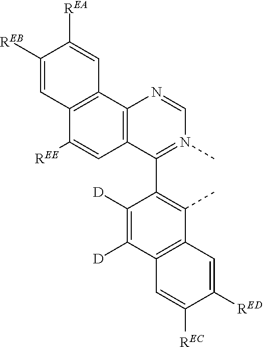 |
| L_{A59}(R^{EA})(R^{EB}) (R^{EC})(R^{ED}) (R^{EE}), wherein L_{A59}(R¹)(R¹) (R¹)(R¹)(R¹) to L_{A59}(R¹⁵⁰)(R¹⁵⁰) (R¹⁵⁰)(R¹⁵⁰) (R¹⁵⁰) have the structure | 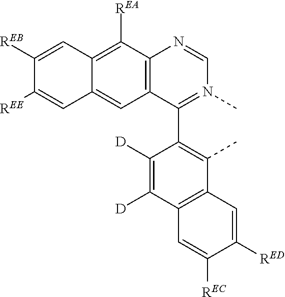 |
| L_{A60}(R^{EA})(R^{EB}) (R^{EC})(R^{ED}) (R^{EE}), wherein L_{A60}(R¹)(R¹) (R¹)(R¹)(R¹) to L_{A60}(R¹⁵⁰)(R¹⁵⁰) (R¹⁵⁰)(R¹⁵⁰) (R¹⁵⁰) have the structure | 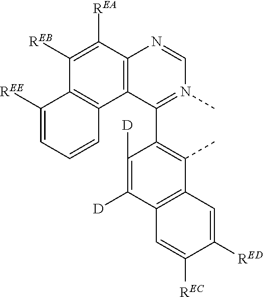 |
| L_{A61}(R^{EA})(R^{EB}) (R^{EC})(R^{ED}) (R^{EE}), wherein L_{A61}(R¹)(R¹) (R¹)(R¹)(R¹) to L_{A61}(R¹⁵⁰)(R¹⁵⁰) (R¹⁵⁰)(R¹⁵⁰) (R¹⁵⁰) have the structure | 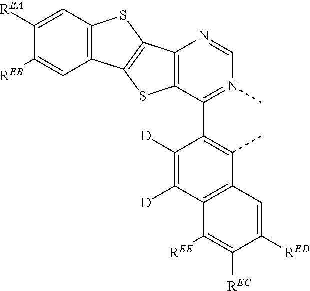 |
| L_{A62}(R^{EA})(R^{EB}) (R^{EC})(R^{ED}) (R^{EE}), wherein L_{A62}(R¹)(R¹) (R¹)(R¹)(R¹) to L_{A62}(R¹⁵⁰)(R¹⁵⁰) (R¹⁵⁰)(R¹⁵⁰) (R¹⁵⁰) have the structure | 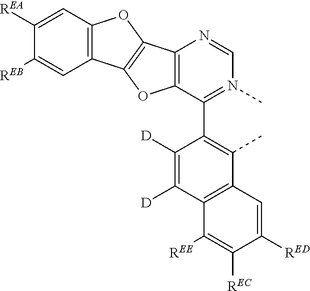 |
| L_{A63}(R^{EA})(R^{EB}) (R^{EC})(R^{ED}) (R^{EE}), wherein L_{A63}(R¹)(R¹) (R¹)(R¹)(R¹) to L_{A63}(R¹⁵⁰)(R¹⁵⁰) (R¹⁵⁰)(R¹⁵⁰) (R¹⁵⁰) have the structure | 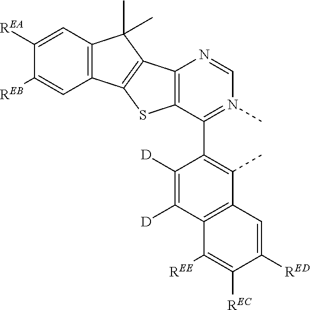 |
| L_{A64}(R^{EA})(R^{EB}) (R^{EC})(R^{ED}) (R^{EE}), wherein L_{A64}(R¹)(R¹) (R¹)(R¹)(R¹) to L_{A64}(R¹⁵⁰)(R¹⁵⁰) (R¹⁵⁰)(R¹⁵⁰) (R¹⁵⁰) have the structure | 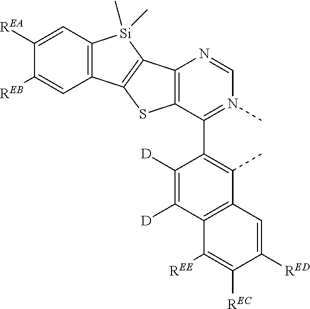 |
| L_{A65}(R^{EA})(R^{EB}) (R^{EC})(R^{ED}) (R^{EE}), wherein L_{A65}(R¹)(R¹) (R¹)(R¹)(R¹) to L_{A65}(R¹⁵⁰)(R¹⁵⁰) (R¹⁵⁰)(R¹⁵⁰) (R¹⁵⁰) have the structure | 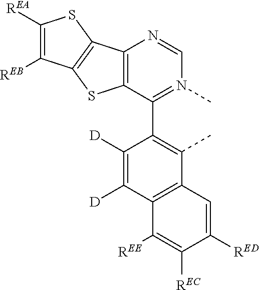 |
| L_{A66}(R^{EA})(R^{EB}) (R^{EC})(R^{ED}) (R^{EE}), wherein L_{A66}(R¹)(R¹) (R¹)(R¹)(R¹) to L_{A66}(R¹⁵⁰)(R¹⁵⁰) (R¹⁵⁰)(R¹⁵⁰) (R¹⁵⁰) have the structure | 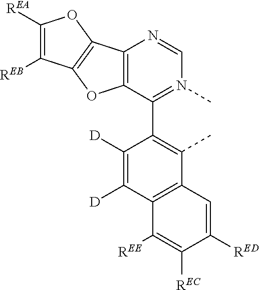 |
| L_{A67}(R^{EA})(R^{EB}) (R^{EC})(R^{ED}) (R^{EE}), wherein L_{A67}(R¹)(R¹) (R¹)(R¹)(R¹) to L_{A67}(R¹⁵⁰)(R¹⁵⁰) (R¹⁵⁰)(R¹⁵⁰) (R¹⁵⁰) have the structure | 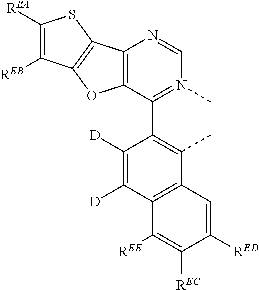 |
| L_{A68}(R^{EA})(R^{EB}) (R^{EC})(R^{ED}) (R^{EE}), wherein L_{A68}(R¹)(R¹) (R¹)(R¹)(R¹) to L_{A68}(R¹⁵⁰)(R¹⁵⁰) (R¹⁵⁰)(R¹⁵⁰) (R¹⁵⁰) have the structure | 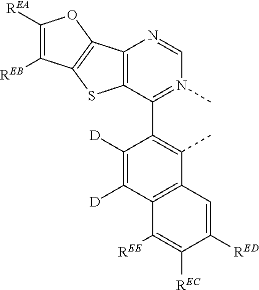 |
| L_{A69}(R^{EA})(R^{EB}) (R^{EC})(R^{ED}) (R^{EE}), wherein L_{A69}(R¹)(R¹) (R¹)(R¹)(R¹) to L_{A69}(R¹⁵⁰)(R¹⁵⁰) (R¹⁵⁰)(R¹⁵⁰) (R¹⁵⁰) have the structure | 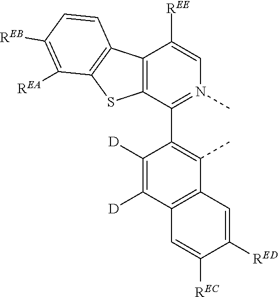 |
| L_{A70}(R^{EA})(R^{EB}) (R^{EC})(R^{ED}) (R^{EE}), wherein L_{A70}(R¹)(R¹) (R¹)(R¹)(R¹) to L_{A70}(R¹⁵⁰)(R¹⁵⁰) (R¹⁵⁰)(R¹⁵⁰) (R¹⁵⁰) have the structure | 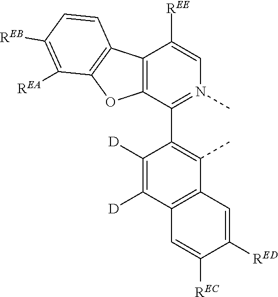 |
| L_{A71}(R^{EA})(R^{EB}) (R^{EC})(R^{ED}) (R^{EE}), wherein L_{A71}(R¹)(R¹) (R¹)(R¹)(R¹) to L_{A71}(R¹⁵⁰)(R¹⁵⁰) (R¹⁵⁰)(R¹⁵⁰) (R¹⁵⁰) have the structure | 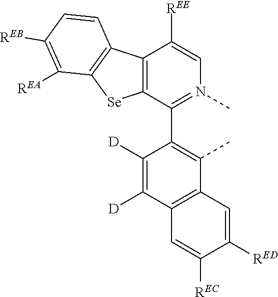 |
| L_{A72}(R^{EA})(R^{EB}) (R^{EC})(R^{ED}) (R^{EE}), wherein L_{A72}(R¹)(R¹) (R¹)(R¹)(R¹) to L_{A72}(R¹⁵⁰)(R¹⁵⁰) (R¹⁵⁰)(R¹⁵⁰) (R¹⁵⁰) have the structure | 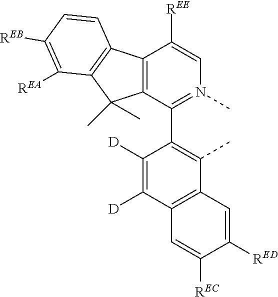 |
| L_{A73}(R^{EA})(R^{EB}) (R^{EC})(R^{ED}) (R^{EE}), wherein L_{A73}(R¹)(R¹) (R¹)(R¹)(R¹) to L_{A73}(R¹⁵⁰)(R¹⁵⁰) (R¹⁵⁰)(R¹⁵⁰) (R¹⁵⁰) have the structure | 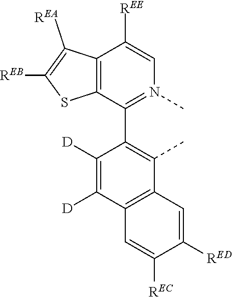 |
| L_{A74}(R^{EA})(R^{EB}) (R^{EC})(R^{ED}) (R^{EE}), wherein L_{A74}(R¹)(R¹) (R¹)(R¹)(R¹) to L_{A74}(R¹⁵⁰)(R¹⁵⁰) (R¹⁵⁰)(R¹⁵⁰) (R¹⁵⁰) have the structure | 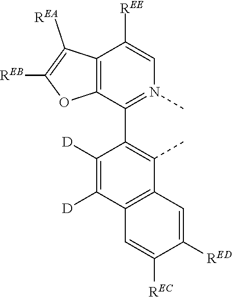 |
| L_{A75}(R^{EA})(R^{EB}) (R^{EC})(R^{ED}) (R^{EE}), wherein L_{A75}(R¹)(R¹) (R¹)(R¹)(R¹) to L_{A75}(R¹⁵⁰)(R¹⁵⁰) (R¹⁵⁰)(R¹⁵⁰) (R¹⁵⁰) have the structure | 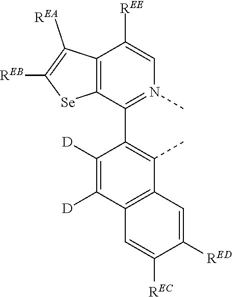 |
| L_{A76}(R^{EA})(R^{EB}) (R^{EC})(R^{ED}) (R^{EE}), wherein L_{A76}(R¹)(R¹) (R¹)(R¹)(R¹) to L_{A76}(R¹⁵⁰)(R¹⁵⁰) (R¹⁵⁰)(R¹⁵⁰) (R¹⁵⁰) have the structure | 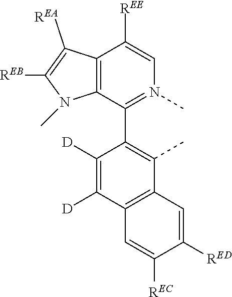 |
| L_{A77}(R^{EA})(R^{EB}) (R^{EC})(R^{ED}) (R^{EE}), wherein L_{A77}(R¹)(R¹) (R¹)(R¹)(R¹) to L_{A77}(R¹⁵⁰)(R¹⁵⁰) (R¹⁵⁰)(R¹⁵⁰) (R¹⁵⁰) have the structure | 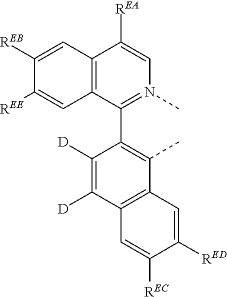 |
| L_{A78}(R^{EA})(R^{EB}) (R^{EC})(R^{ED}) (R^{EE}), wherein L_{A78}(R¹)(R¹) (R¹)(R¹)(R¹) to L_{A78}(R¹⁵⁰)(R¹⁵⁰) (R¹⁵⁰)(R¹⁵⁰) (R¹⁵⁰) have the structure | 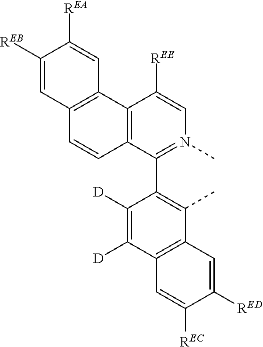 |
| L_{A79}(R^{EA})(R^{EB}) (R^{EC})(R^{ED}) (R^{EE}), wherein L_{A79}(R¹)(R¹) (R¹)(R¹)(R¹) to L_{A79}(R¹⁵⁰)(R¹⁵⁰) (R¹⁵⁰)(R¹⁵⁰) (R¹⁵⁰) have the structure | 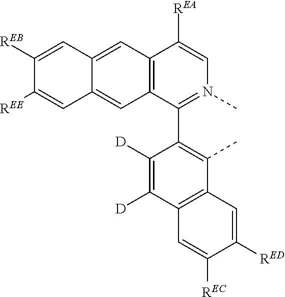 |
| L_{A80}(R^{EA})(R^{EB}) (R^{EC})(R^{ED}) (R^{EE}), wherein L_{A80}(R¹)(R¹) (R¹)(R¹)(R¹) to L_{A80}(R¹⁵⁰)(R¹⁵⁰) (R¹⁵⁰)(R¹⁵⁰) (R¹⁵⁰) have the structure | 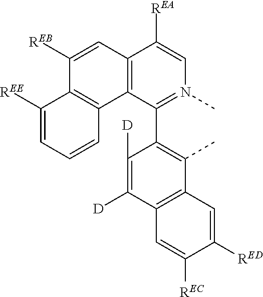 |
| L_{A81}(R^{EA})(R^{EB}) (R^{EC})(R^{ED}) (R^{EE}), wherein L_{A81}(R¹)(R¹) (R¹)(R¹)(R¹) to L_{A81}(R¹⁵⁰)(R¹⁵⁰) (R¹⁵⁰)(R¹⁵⁰) (R¹⁵⁰) have the structure | 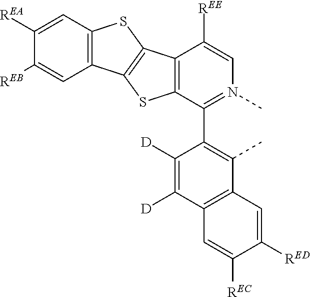 |
| L_{A82}(R^{EA})(R^{EB}) (R^{EC})(R^{ED}) (R^{EE}), wherein L_{A82}(R¹)(R¹) (R¹)(R¹)(R¹) to L_{A82}(R¹⁵⁰)(R¹⁵⁰) (R¹⁵⁰)(R¹⁵⁰) (R¹⁵⁰) have the structure | 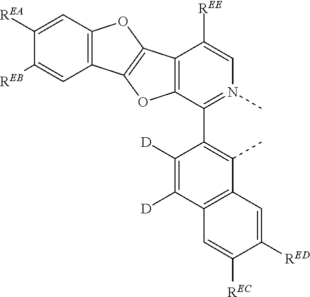 |
| L_{A83}(R^{EA})(R^{EB}) (R^{EC})(R^{ED}) (R^{EE}), wherein L_{A83}(R¹)(R¹) (R¹)(R¹)(R¹) to L_{A83}(R¹⁵⁰)(R¹⁵⁰) (R¹⁵⁰)(R¹⁵⁰) (R¹⁵⁰) have the structure | 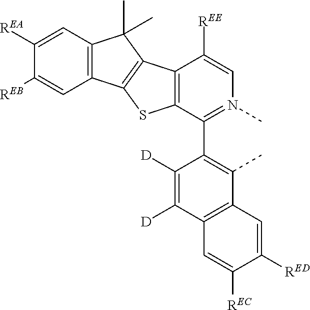 |
| L_{A84}(R^{EA})(R^{EB}) (R^{EC})(R^{ED}) (R^{EE}), wherein L_{A84}(R¹)(R¹) (R¹)(R¹)(R¹) to L_{A84}(R¹⁵⁰)(R¹⁵⁰) (R¹⁵⁰)(R¹⁵⁰) (R¹⁵⁰) have the structure | 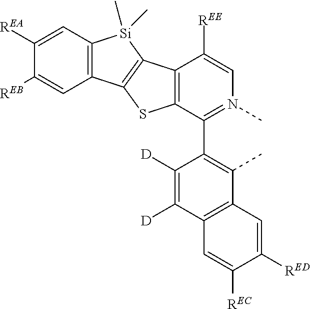 |
| L_{A85}(R^{EA})(R^{EB}) (R^{EC})(R^{ED}) (R^{EE}), wherein L_{A85}(R¹)(R¹) (R¹)(R¹)(R¹) to L_{A85}(R¹⁵⁰)(R¹⁵⁰) (R¹⁵⁰)(R¹⁵⁰) (R¹⁵⁰) have the structure | 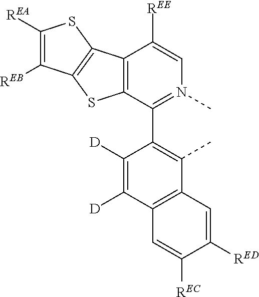 |
| L_{A86}(R^{EA})(R^{EB}) (R^{EC})(R^{ED}) (R^{EE}), wherein L_{A86}(R¹)(R¹) (R¹)(R¹)(R¹) to L_{A86}(R¹⁵⁰)(R¹⁵⁰) (R¹⁵⁰)(R¹⁵⁰) (R¹⁵⁰) have the structure | 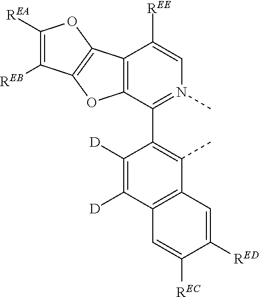 |
| L_{A87}(R^{EA})(R^{EB}) (R^{EC})(R^{ED}) (R^{EE}), wherein L_{A87}(R¹)(R¹) (R¹)(R¹)(R¹) to L_{A87}(R¹⁵⁰)(R¹⁵⁰) (R¹⁵⁰)(R¹⁵⁰) (R¹⁵⁰) have the structure | 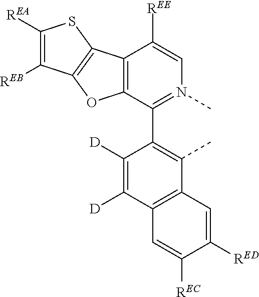 |
| L_{A88}(R^{EA})(R^{EB}) (R^{EC})(R^{ED}) (R^{EE}), wherein L_{A88}(R¹)(R¹) (R¹)(R¹)(R¹) to L_{A88}(R¹⁵⁰)(R¹⁵⁰) (R¹⁵⁰)(R¹⁵⁰) (R¹⁵⁰) have the structure | 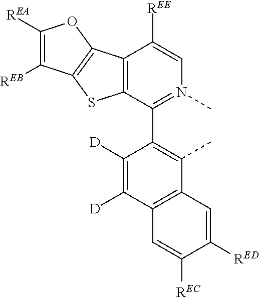 |
| L_{A89}(R^{EA})(R^{EB}) (R^{EC})(R^{ED}) (R^{EE}), wherein L_{A89}(R¹)(R¹) (R¹)(R¹)(R¹) to L_{A89}(R¹⁵⁰)(R¹⁵⁰) (R¹⁵⁰)(R¹⁵⁰) (R¹⁵⁰) have the structure | 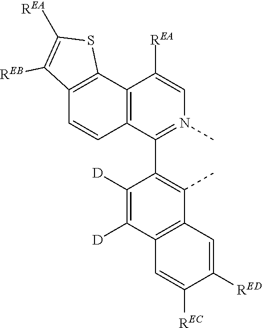 |
| L_{A90}(R^{EA})(R^{EB}) (R^{EC})(R^{ED}) (R^{EE}), wherein L_{A90}(R¹)(R¹) (R¹)(R¹)(R¹) to L_{A90}(R¹⁵⁰)(R¹⁵⁰) (R¹⁵⁰)(R¹⁵⁰) (R¹⁵⁰) have the structure | 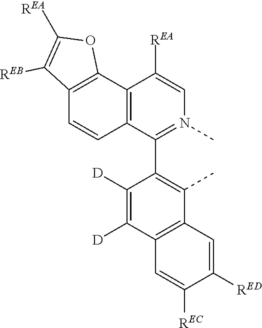 |
| L_{A91}(R^{EA})(R^{EB}) (R^{EC})(R^{ED}) (R^{EE}), wherein L_{A91}(R¹)(R¹) (R¹)(R¹)(R¹) to L_{A91}(R¹⁵⁰)(R¹⁵⁰) (R¹⁵⁰)(R¹⁵⁰) (R¹⁵⁰) have the structure | 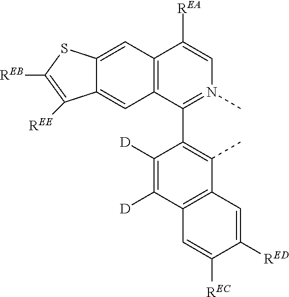 |
| L_{A92}(R^{EA})(R^{EB}) (R^{EC})(R^{ED}) (R^{EE}), wherein L_{A92}(R¹)(R¹) (R¹)(R¹)(R¹) to L_{A92}(R¹⁵⁰)(R¹⁵⁰) (R¹⁵⁰)(R¹⁵⁰) (R¹⁵⁰) have the structure | 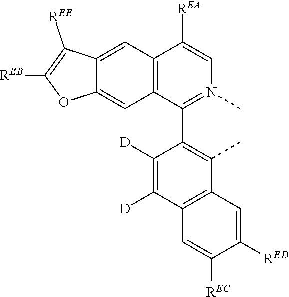 |
| L_{A93}(R^{EA})(R^{EB}) (R^{EC})(R^{ED}) (R^{EE}), wherein L_{A93}(R¹)(R¹) (R¹)(R¹)(R¹) to L_{A93}(R¹⁵⁰)(R¹⁵⁰) (R¹⁵⁰)(R¹⁵⁰) (R¹⁵⁰) have the structure | 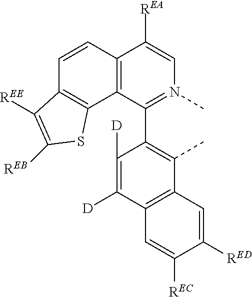 |
| L_{A94}(R^{EA})(R^{EB}) (R^{EC})(R^{ED}) (R^{EE}), wherein L_{A94}(R¹)(R¹) (R¹)(R¹)(R¹) to L_{A94}(R¹⁵⁰)(R¹⁵⁰) (R¹⁵⁰)(R¹⁵⁰) (R¹⁵⁰) have the structure | 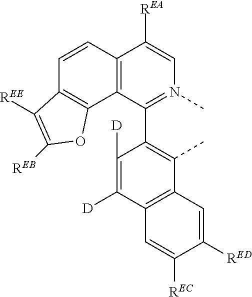 |
| L_{A95}(R^{EA})(R^{EB}) (R^{EC})(R^{ED}) (R^{EE}), wherein L_{A95}(R¹)(R¹) (R¹)(R¹)(R¹) to L_{A95}(R¹⁵⁰)(R¹⁵⁰) (R¹⁵⁰)(R¹⁵⁰) (R¹⁵⁰) have the structure | 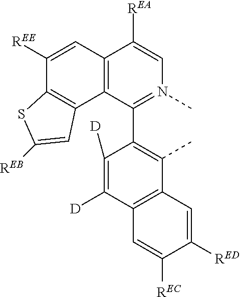 |
| L_{A96}(R^{EA})(R^{EB}) (R^{EC})(R^{ED}) (R^{EE}), wherein L_{A96}(R¹)(R¹) (R¹)(R¹)(R¹) to L_{A96}(R¹⁵⁰)(R¹⁵⁰) (R¹⁵⁰)(R¹⁵⁰) (R¹⁵⁰) have the structure | 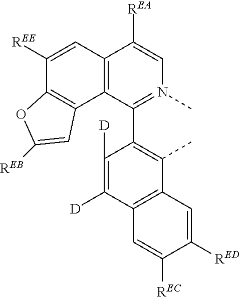 |
| L_{A97}(R^{EA})(R^{EB}) (R^{EC})(R^{ED}) (R^{EE}), wherein L_{A97}(R¹)(R¹) (R¹)(R¹)(R¹) to L_{A97}(R¹⁵⁰)(R¹⁵⁰) (R¹⁵⁰)(R¹⁵⁰) (R¹⁵⁰) have the structure | 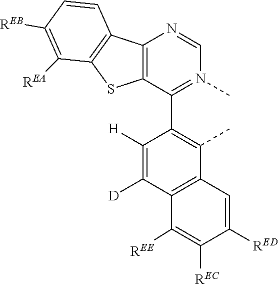 |
| L_{A98}(R^{EA})(R^{EB}) (R^{EC})(R^{ED}) (R^{EE}), wherein L_{A98}(R¹)(R¹) (R¹)(R¹)(R¹) to L_{A98}(R¹⁵⁰)(R¹⁵⁰) (R¹⁵⁰)(R¹⁵⁰) (R¹⁵⁰) have the structure | 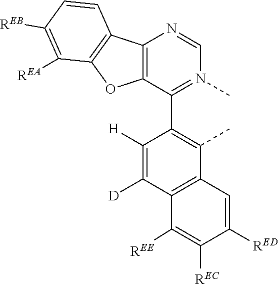 |
| L_{A99}(R^{EA})(R^{EB}) (R^{EC})(R^{ED}) (R^{EE}), wherein L_{A99}(R¹)(R¹) (R¹)(R¹)(R¹) to L_{A99}(R¹⁵⁰)(R¹⁵⁰) (R¹⁵⁰)(R¹⁵⁰) (R¹⁵⁰) have the structure | 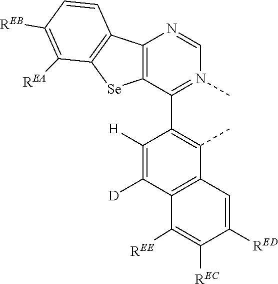 |
| L_{A100}(R^{EA})(R^{EB}) (R^{EC})(R^{ED}) (R^{EE}), wherein L_{A100}(R¹)(R¹) (R¹)(R¹)(R¹) to L_{A100}(R¹⁵⁰)(R¹⁵⁰) (R¹⁵⁰)(R¹⁵⁰) (R¹⁵⁰) have the structure | 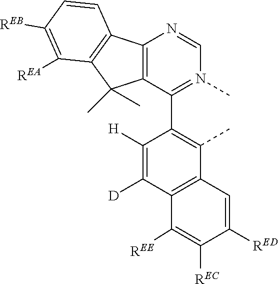 |
| L_{A101}(R^{EA})(R^{EB}) (R^{EC})(R^{ED}) (R^{EE}), wherein L_{A101}(R¹)(R¹) (R¹)(R¹)(R¹) to L_{A101}(R¹⁵⁰)(R¹⁵⁰) (R¹⁵⁰)(R¹⁵⁰) (R¹⁵⁰) have the structure | 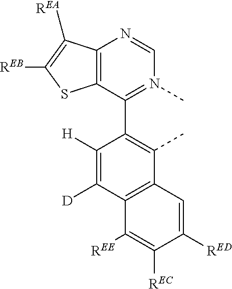 |
| L_{A102}(R^{EA})(R^{EB}) (R^{EC})(R^{ED}) (R^{EE}), wherein L_{A102}(R¹)(R¹) (R¹)(R¹)(R¹) to L_{A102}(R¹⁵⁰)(R¹⁵⁰) (R¹⁵⁰)(R¹⁵⁰) (R¹⁵⁰) have the structure | 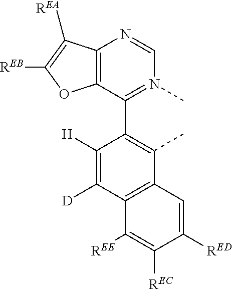 |
| L_{A103}(R^{EA})(R^{EB}) (R^{EC})(R^{ED}) (R^{EE}), wherein L_{A103}(R¹)(R¹) (R¹)(R¹)(R¹) to L_{A103}(R¹⁵⁰)(R¹⁵⁰) (R¹⁵⁰)(R¹⁵⁰) (R¹⁵⁰) have the structure | 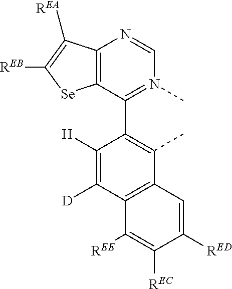 |
| L_{A104}(R^{EA})(R^{EB}) (R^{EC})(R^{ED}) (R^{EE}), wherein L_{A104}(R¹)(R¹) (R¹)(R¹)(R¹) to L_{A104}(R¹⁵⁰)(R¹⁵⁰) (R¹⁵⁰)(R¹⁵⁰) (R¹⁵⁰) have the structure | 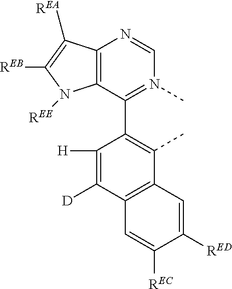 |
| L_{A105}(R^{EA})(R^{EB}) (R^{EC})(R^{ED}) (R^{EE}), wherein L_{A105}(R¹)(R¹) (R¹)(R¹)(R¹) to L_{A105}(R¹⁵⁰)(R¹⁵⁰) (R¹⁵⁰)(R¹⁵⁰) (R¹⁵⁰) have the structure | 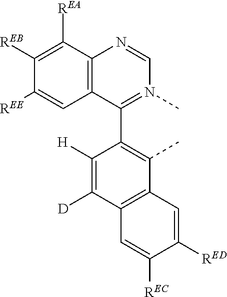 |
| L_{A106}(R^{EA})(R^{EB}) (R^{EC})(R^{ED}) (R^{EE}), wherein L_{A106}(R¹)(R¹) (R¹)(R¹)(R¹) to L_{A106}(R¹⁵⁰)(R¹⁵⁰) (R¹⁵⁰)(R¹⁵⁰) (R¹⁵⁰) have the structure | 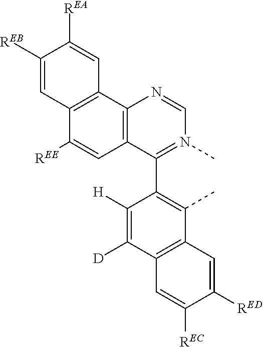 |
| L_{A107}(R^{EA})(R^{EB}) (R^{EC})(R^{ED}) (R^{EE}), wherein L_{A107}(R¹)(R¹) (R¹)(R¹)(R¹) to L_{A107}(R¹⁵⁰)(R¹⁵⁰) (R¹⁵⁰)(R¹⁵⁰) (R¹⁵⁰) have the structure | 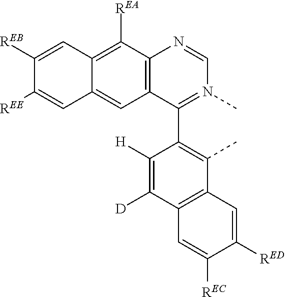 |
| L_{A108}(R^{EA})(R^{EB}) (R^{EC})(R^{ED}) (R^{EE}), wherein L_{A108}(R¹)(R¹) (R¹)(R¹)(R¹) to L_{A108}(R¹⁵⁰)(R¹⁵⁰) (R¹⁵⁰)(R¹⁵⁰) (R¹⁵⁰) have the structure | 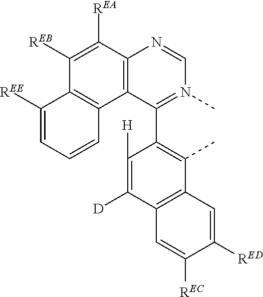 |
| L_{A109}(R^{EA})(R^{EB}) (R^{EC})(R^{ED}) (R^{EE}), wherein L_{A109}(R¹)(R¹) (R¹)(R¹)(R¹) to L_{A109}(R¹⁵⁰)(R¹⁵⁰) (R¹⁵⁰)(R¹⁵⁰) (R¹⁵⁰) have the structure | 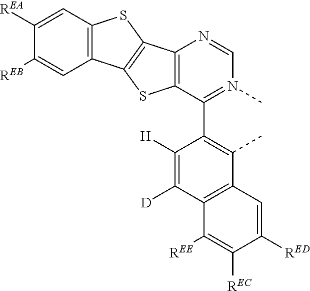 |
| L_{A110}(R^{EA})(R^{EB}) (R^{EC})(R^{ED}) (R^{EE}), wherein L_{A110}(R¹)(R¹) (R¹)(R¹)(R¹) to L_{A110}(R¹⁵⁰)(R¹⁵⁰) (R¹⁵⁰)(R¹⁵⁰) (R¹⁵⁰) have the structure | 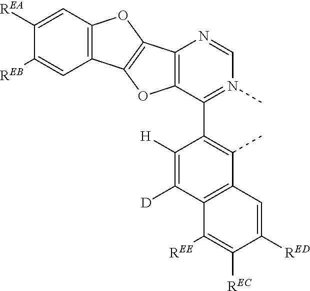 |
| L_{A111}(R^{EA})(R^{EB}) (R^{EC})(R^{ED}) (R^{EE}), wherein L_{A111}(R¹)(R¹) (R¹)(R¹)(R¹) to L_{A111}(R¹⁵⁰)(R¹⁵⁰) (R¹⁵⁰)(R¹⁵⁰) (R¹⁵⁰) have the structure | 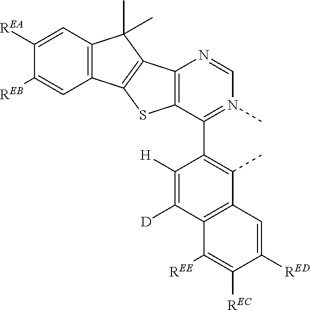 |
| L_{A112}(R^{EA})(R^{EB}) (R^{EC})(R^{ED}) (R^{EE}), wherein L_{A112}(R¹)(R¹) (R¹)(R¹)(R¹) to L_{A112}(R¹⁵⁰)(R¹⁵⁰) (R¹⁵⁰)(R¹⁵⁰) (R¹⁵⁰) have the structure | 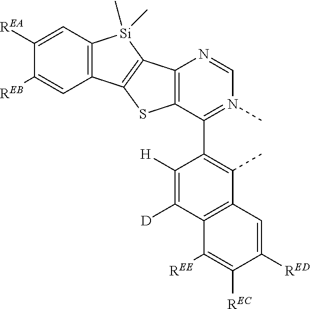 |
| L_{A113}(R^{EA})(R^{EB}) (R^{EC})(R^{ED}) (R^{EE}), wherein L_{A113}(R¹)(R¹) (R¹)(R¹)(R¹) to L_{A113}(R¹⁵⁰)(R¹⁵⁰) (R¹⁵⁰)(R¹⁵⁰) (R¹⁵⁰) have the structure | 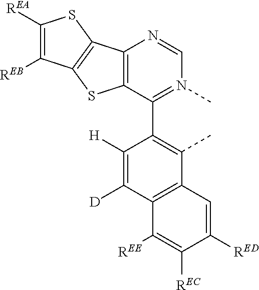 |
| L_{A114}(R^{EA})(R^{EB}) (R^{EC})(R^{ED}) (R^{EE}), wherein L_{A114}(R¹)(R¹) (R¹)(R¹)(R¹) to L_{A114}(R¹⁵⁰)(R¹⁵⁰) (R¹⁵⁰)(R¹⁵⁰) (R¹⁵⁰) have the structure | 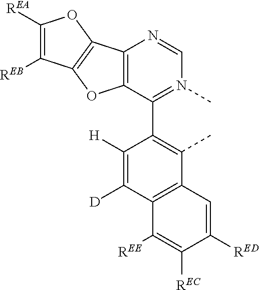 |
| L_{A115}(R^{EA})(R^{EB}) (R^{EC})(R^{ED}) (R^{EE}), wherein L_{A115}(R¹)(R¹) (R¹)(R¹)(R¹) to L_{A115}(R¹⁵⁰)(R¹⁵⁰) (R¹⁵⁰)(R¹⁵⁰) (R¹⁵⁰) have the structure | 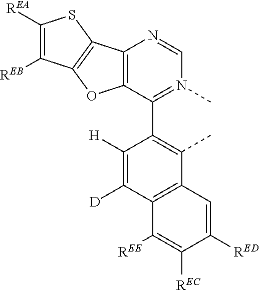 |
| L_{A116}(R^{EA})(R^{EB}) (R^{EC})(R^{ED}) (R^{EE}), wherein L_{A116}(R¹)(R¹) (R¹)(R¹)(R¹) to L_{A116}(R¹⁵⁰)(R¹⁵⁰) (R¹⁵⁰)(R¹⁵⁰) (R¹⁵⁰) have the structure | 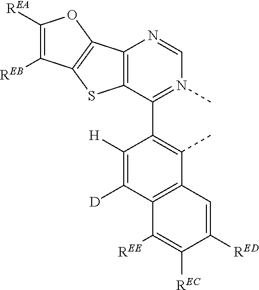 |
| L_{A117}(R^{EA})(R^{EB}) (R^{EC})(R^{ED}) (R^{EE}), wherein L_{A117}(R¹)(R¹) (R¹)(R¹)(R¹) to L_{A117}(R¹⁵⁰)(R¹⁵⁰) (R¹⁵⁰)(R¹⁵⁰) (R¹⁵⁰) have the structure | 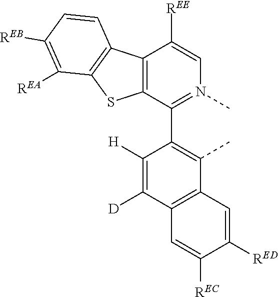 |
| L_{A118}(R^{EA})(R^{EB}) (R^{EC})(R^{ED}) (R^{EE}), wherein L_{A118}(R¹)(R¹) (R¹)(R¹)(R¹) to L_{A118}(R¹⁵⁰)(R¹⁵⁰) (R¹⁵⁰)(R¹⁵⁰) (R¹⁵⁰) have the structure | 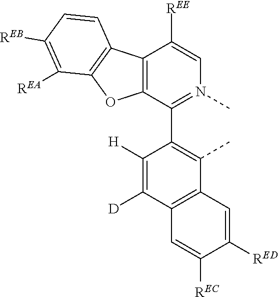 |
| L_{A119}(R^{EA})(R^{EB}) (R^{EC})(R^{ED}) (R^{EE}), wherein L_{A119}(R¹)(R¹) (R¹)(R¹)(R¹) to L_{A119}(R¹⁵⁰)(R¹⁵⁰) (R¹⁵⁰)(R¹⁵⁰) (R¹⁵⁰) have the structure | 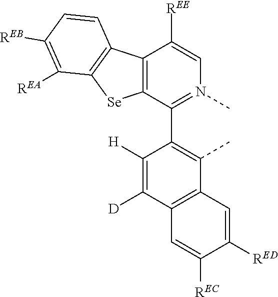 |
| L_{A120}(R^{EA})(R^{EB}) (R^{EC})(R^{ED}) (R^{EE}), wherein L_{A120}(R¹)(R¹) (R¹)(R¹)(R¹) to L_{A120}(R¹⁵⁰)(R¹⁵⁰) (R¹⁵⁰)(R¹⁵⁰) (R¹⁵⁰) have the structure | 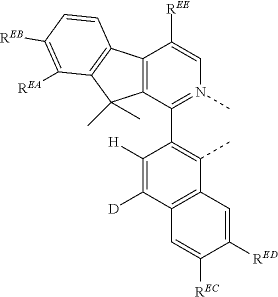 |
| L_{A121}(R^{EA})(R^{EB}) (R^{EC})(R^{ED}) (R^{EE}), wherein L_{A121}(R¹)(R¹) (R¹)(R¹)(R¹) to L_{A121}(R¹⁵⁰)(R¹⁵⁰) (R¹⁵⁰)(R¹⁵⁰) (R¹⁵⁰) have the structure | 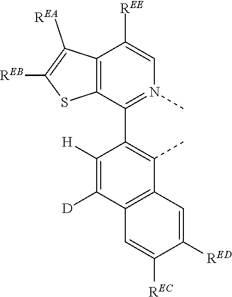 |
| L_{A122}(R^{EA})(R^{EB}) (R^{EC})(R^{ED}) (R^{EE}), wherein L_{A122}(R¹)(R¹) (R¹)(R¹)(R¹) to L_{A122}(R¹⁵⁰)(R¹⁵⁰) (R¹⁵⁰)(R¹⁵⁰) (R¹⁵⁰) have the structure | 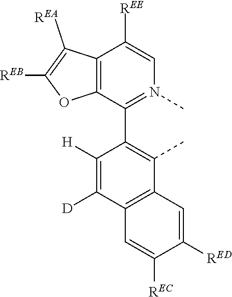 |
| L_{A123}(R^{EA})(R^{EB}) (R^{EC})(R^{ED}) (R^{EE}), wherein L_{A123}(R¹)(R¹) (R¹)(R¹)(R¹) to L_{A123}(R¹⁵⁰)(R¹⁵⁰) (R¹⁵⁰)(R¹⁵⁰) (R¹⁵⁰) have the structure | 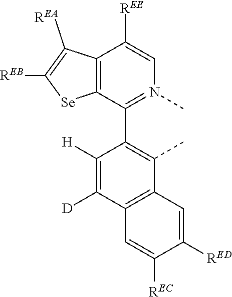 |
| L_{A124}(R^{EA})(R^{EB}) (R^{EC})(R^{ED}) (R^{EE}), wherein L_{A124}(R¹)(R¹) (R¹)(R¹)(R¹) to L_{A124}(R¹⁵⁰)(R¹⁵⁰) (R¹⁵⁰)(R¹⁵⁰) (R¹⁵⁰) have the structure | 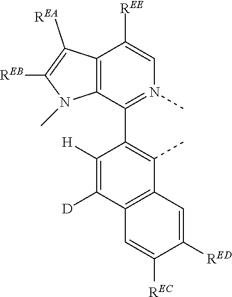 |
| L_{A125}(R^{EA})(R^{EB}) (R^{EC})(R^{ED}) (R^{EE}), wherein L_{A125}(R¹)(R¹) (R¹)(R¹)(R¹) to L_{A125}(R¹⁵⁰)(R¹⁵⁰) (R¹⁵⁰)(R¹⁵⁰) (R¹⁵⁰) have the structure | 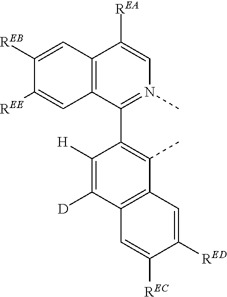 |
| L_{A126}(R^{EA})(R^{EB}) (R^{EC})(R^{ED}) (R^{EE}), wherein L_{A126}(R¹)(R¹) (R¹)(R¹)(R¹) to L_{A126}(R¹⁵⁰)(R¹⁵⁰) (R¹⁵⁰)(R¹⁵⁰) (R¹⁵⁰) have the structure | 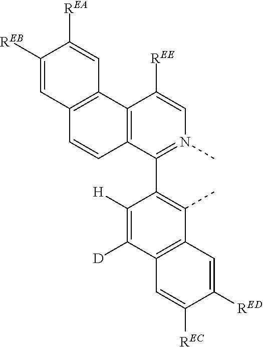 |
| L_{A127}(R^{EA})(R^{EB}) (R^{EC})(R^{ED}) (R^{EE}), wherein L_{A127}(R¹)(R¹) (R¹)(R¹)(R¹) to L_{A127}(R¹⁵⁰)(R¹⁵⁰) (R¹⁵⁰)(R¹⁵⁰) (R¹⁵⁰) have the structure | 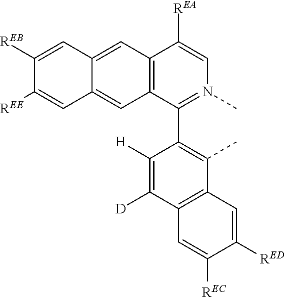 |
| L_{A128}(R^{EA})(R^{EB}) (R^{EC})(R^{ED}) (R^{EE}), wherein L_{A128}(R¹)(R¹) (R¹)(R¹)(R¹) to L_{A128}(R¹⁵⁰)(R¹⁵⁰) (R¹⁵⁰)(R¹⁵⁰) (R¹⁵⁰) have the structure | 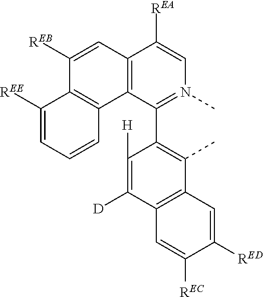 |
| L_{A129}(R^{EA})(R^{EB}) (R^{EC})(R^{ED}) (R^{EE}), wherein L_{A129}(R¹)(R¹) (R¹)(R¹)(R¹) to L_{A129}(R¹⁵⁰)(R¹⁵⁰) (R¹⁵⁰)(R¹⁵⁰) (R¹⁵⁰) have the structure | 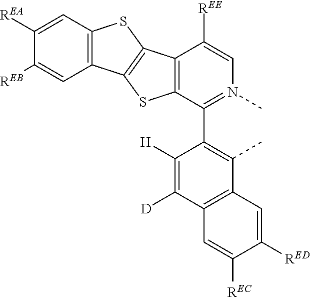 |
| L_{A130}(R^{EA})(R^{EB}) (R^{EC})(R^{ED}) (R^{EE}), wherein L_{A130}(R¹)(R¹) (R¹)(R¹)(R¹) to L_{A130}(R¹⁵⁰)(R¹⁵⁰) (R¹⁵⁰)(R¹⁵⁰) (R¹⁵⁰) have the structure | 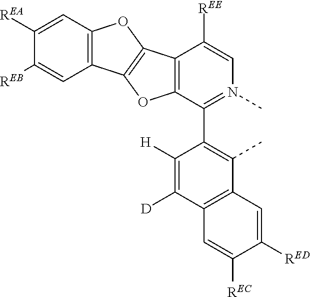 |
| L_{A131}(R^{EA})(R^{EB}) (R^{EC})(R^{ED}) (R^{EE}), wherein L_{A131}(R¹)(R¹) (R¹)(R¹)(R¹) to L_{A131}(R¹⁵⁰)(R¹⁵⁰) (R¹⁵⁰)(R¹⁵⁰) (R¹⁵⁰) have the structure | 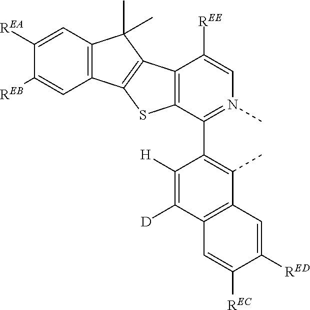 |
| L_{A132}(R^{EA})(R^{EB}) (R^{EC})(R^{ED}) (R^{EE}), wherein L_{A132}(R¹)(R¹) (R¹)(R¹)(R¹) to L_{A132}(R¹⁵⁰)(R¹⁵⁰) (R¹⁵⁰)(R¹⁵⁰) (R¹⁵⁰) have the structure | 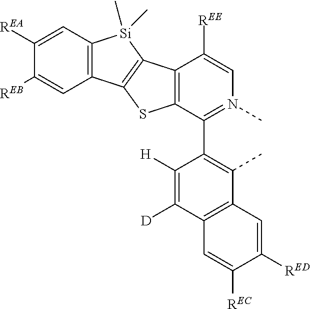 |
| L_{A133}(R^{EA})(R^{EB}) (R^{EC})(R^{ED}) (R^{EE}), wherein L_{A133}(R¹)(R¹) (R¹)(R¹)(R¹) to L_{A133}(R¹⁵⁰)(R¹⁵⁰) (R¹⁵⁰)(R¹⁵⁰) (R¹⁵⁰) have the structure | 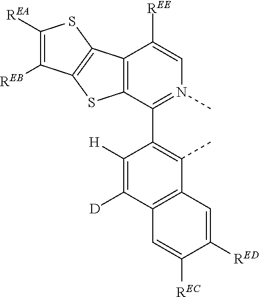 |
| L_{A134}(R^{EA})(R^{EB}) (R^{EC})(R^{ED}) (R^{EE}), wherein L_{A134}(R¹)(R¹) (R¹)(R¹)(R¹) to L_{A134}(R¹⁵⁰)(R¹⁵⁰) (R¹⁵⁰)(R¹⁵⁰) (R¹⁵⁰) have the structure | 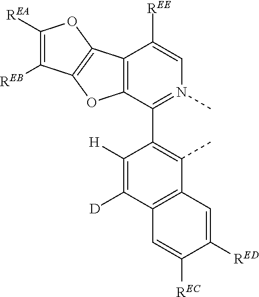 |
| L_{A135}(R^{EA})(R^{EB}) (R^{EC})(R^{ED}) (R^{EE}), wherein L_{A135}(R¹)(R¹) (R¹)(R¹)(R¹) to L_{A135}(R¹⁵⁰)(R¹⁵⁰) (R¹⁵⁰)(R¹⁵⁰) (R¹⁵⁰) have the structure | 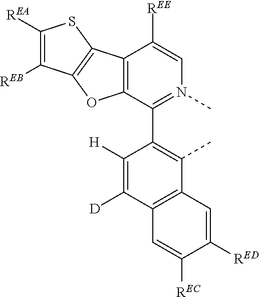 |
| L_{A136}(R^{EA})(R^{EB}) (R^{EC})(R^{ED}) (R^{EE}), wherein L_{A136}(R¹)(R¹) (R¹)(R¹)(R¹) to L_{A136}(R¹⁵⁰)(R¹⁵⁰) (R¹⁵⁰)(R¹⁵⁰) (R¹⁵⁰) have the structure | 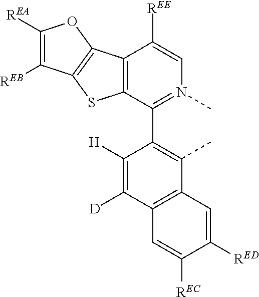 |
| L_{A137}(R^{EA})(R^{EB}) (R^{EC})(R^{ED}) (R^{EE}), wherein L_{A137}(R¹)(R¹) (R¹)(R¹)(R¹) to L_{A137}(R¹⁵⁰)(R¹⁵⁰) (R¹⁵⁰)(R¹⁵⁰) (R¹⁵⁰) have the structure | 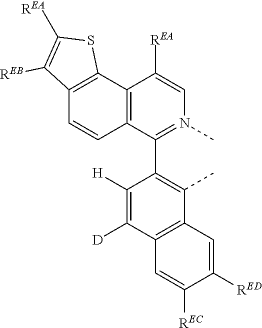 |
| L_{A138}(R^{EA})(R^{EB}) (R^{EC})(R^{ED}) (R^{EE}), wherein L_{A138}(R¹)(R¹) (R¹)(R¹)(R¹) to L_{A138}(R¹⁵⁰)(R¹⁵⁰) (R¹⁵⁰)(R¹⁵⁰) (R¹⁵⁰) have the structure | 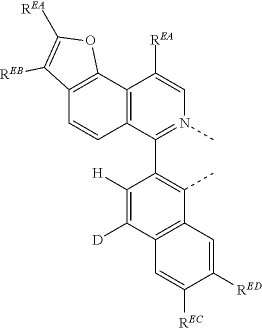 |
| L_{A139}(R^{EA})(R^{EB}) (R^{EC})(R^{ED}) (R^{EE}), wherein L_{A139}(R¹)(R¹) (R¹)(R¹)(R¹) to L_{A139}(R¹⁵⁰)(R¹⁵⁰) (R¹⁵⁰)(R¹⁵⁰) (R¹⁵⁰) have the structure | 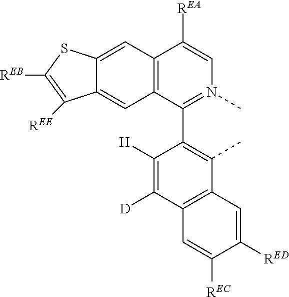 |
| L_{A140}(R^{EA})(R^{EB}) (R^{EC})(R^{ED}) (R^{EE}), wherein L_{A140}(R¹)(R¹) (R¹)(R¹)(R¹) to L_{A140}(R¹⁵⁰)(R¹⁵⁰) (R¹⁵⁰)(R¹⁵⁰) (R¹⁵⁰) have the structure | 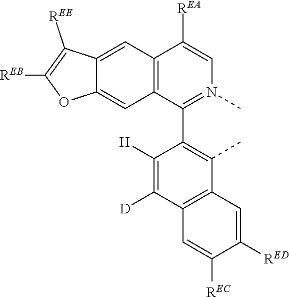 |
| L_{A141}(R^{EA})(R^{EB}) (R^{EC})(R^{ED}) (R^{EE}), wherein L_{A141}(R¹)(R¹) (R¹)(R¹)(R¹) to L_{A141}(R¹⁵⁰)(R¹⁵⁰) (R¹⁵⁰)(R¹⁵⁰) (R¹⁵⁰) have the structure | 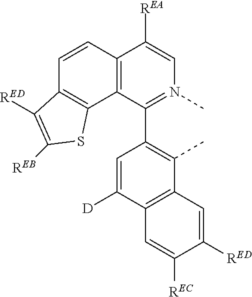 |
| L_{A142}(R^{EA})(R^{EB}) (R^{EC})(R^{ED}) (R^{EE}), wherein L_{A142}(R¹)(R¹) (R¹)(R¹)(R¹) to L_{A142}(R¹⁵⁰)(R¹⁵⁰) (R¹⁵⁰)(R¹⁵⁰) (R¹⁵⁰) have the structure | 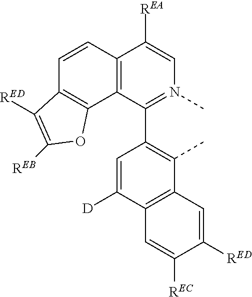 |
| L_{A143}(R^{EA})(R^{EB}) (R^{EC})(R^{ED}) (R^{EE}), wherein L_{A143}(R¹)(R¹) (R¹)(R¹)(R¹) to L_{A143}(R¹⁵⁰)(R¹⁵⁰) (R¹⁵⁰)(R¹⁵⁰) (R¹⁵⁰) have the structure | 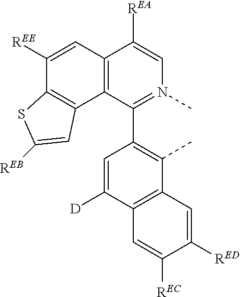 |
| L_{A144}(R^{EA})(R^{EB}) (R^{EC})(R^{ED}) (R^{EE}), wherein L_{A144}(R¹)(R¹) (R¹)(R¹)(R¹) to L_{A144}(R¹⁵⁰)(R¹⁵⁰) (R¹⁵⁰)(R¹⁵⁰) (R¹⁵⁰) have the structure | 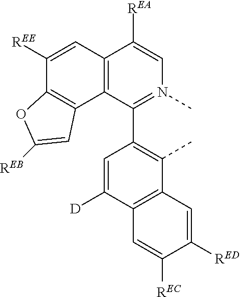 |
| L_{A145}(R^{EA})(R^{EB}) (R^{EC})(R^{ED}) (R^{EE}), wherein L_{A145}(R¹)(R¹) (R¹)(R¹)(R¹) to L_{A145}(R¹⁵⁰)(R¹⁵⁰) (R¹⁵⁰)(R¹⁵⁰) (R¹⁵⁰) have the structure | 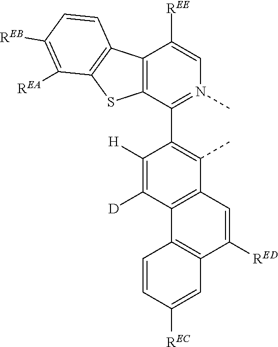 |
| L_{A146}(R^{EA})(R^{EB}) (R^{EC})(R^{ED}) (R^{EE}), wherein L_{A146}(R¹)(R¹) (R¹)(R¹)(R¹) to L_{A146}(R¹⁵⁰)(R¹⁵⁰) (R¹⁵⁰)(R¹⁵⁰) (R¹⁵⁰) have the structure | 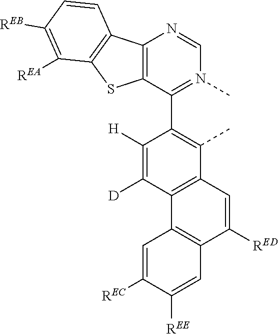 |
| L_{A147}(R^{EA})(R^{EB}) (R^{EC})(R^{ED}) (R^{EE}), wherein L_{A147}(R¹)(R¹) (R¹)(R¹)(R¹) to L_{A147}(R¹⁵⁰)(R¹⁵⁰) (R¹⁵⁰)(R¹⁵⁰) (R¹⁵⁰) have the structure | 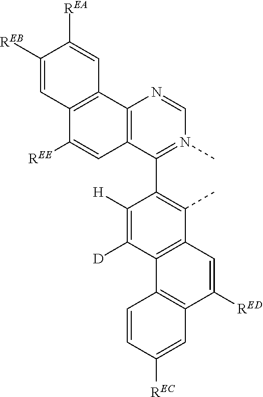 |
| L_{A148}(R^{EA})(R^{EB}) (R^{EC})(R^{ED}) (R^{EE}), wherein L_{A148}(R¹)(R¹) (R¹)(R¹)(R¹) to L_{A148}(R¹⁵⁰)(R¹⁵⁰) (R¹⁵⁰)(R¹⁵⁰) (R¹⁵⁰) have the structure | 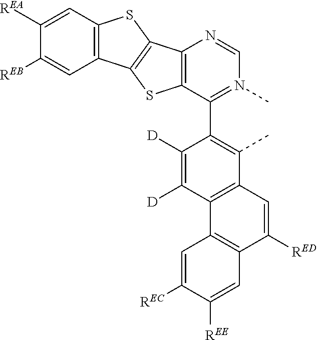 |

wherein R¹ to R¹⁵⁰ have the structures defined in the following LIST 4;

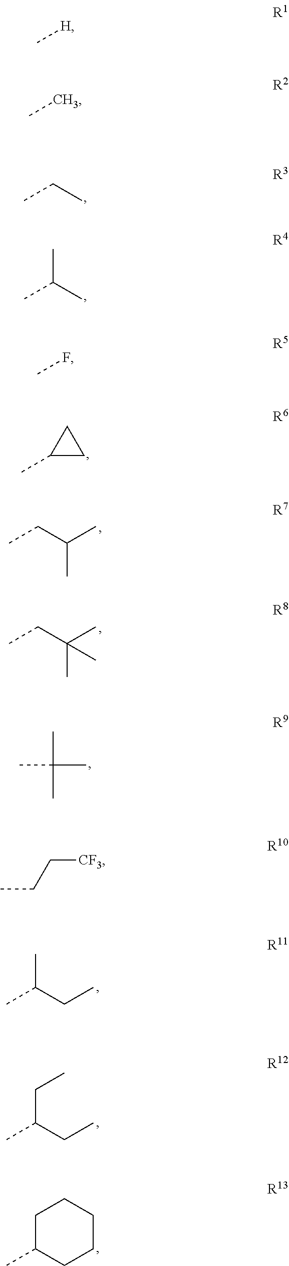

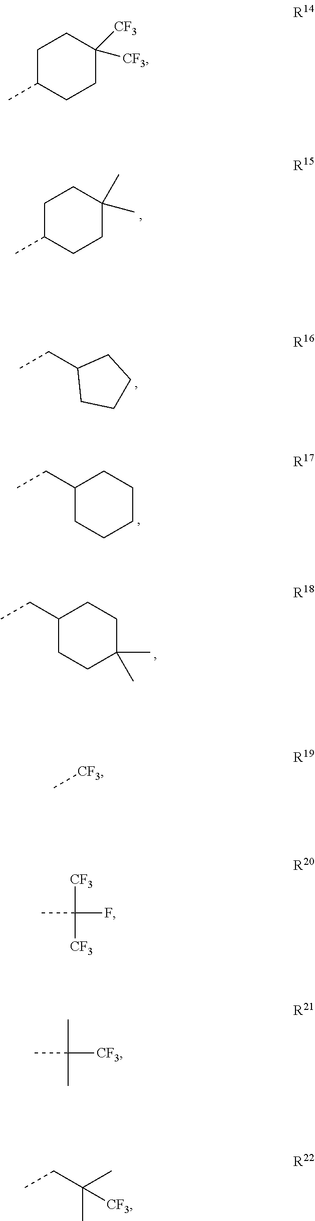

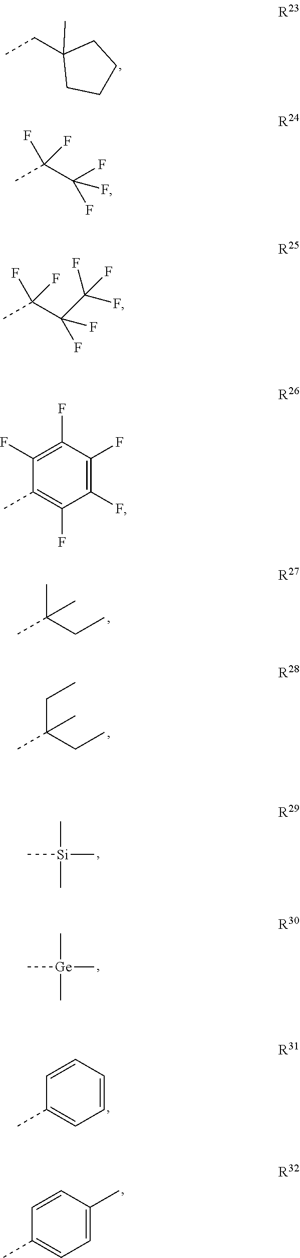

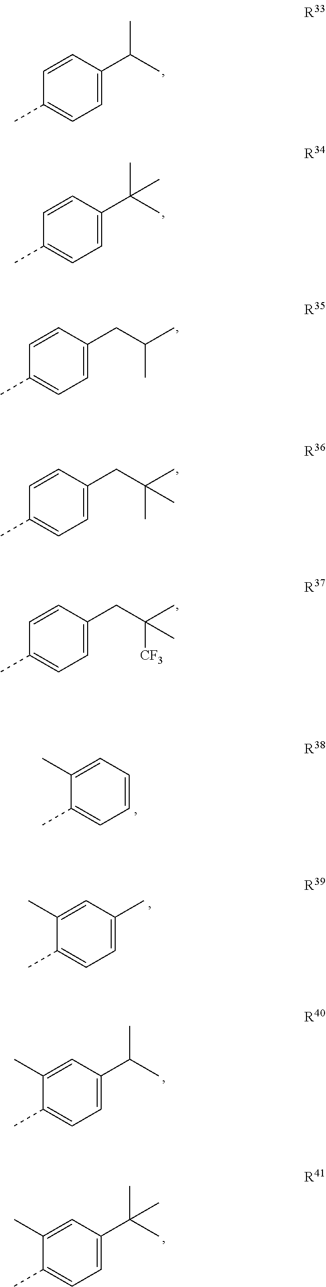

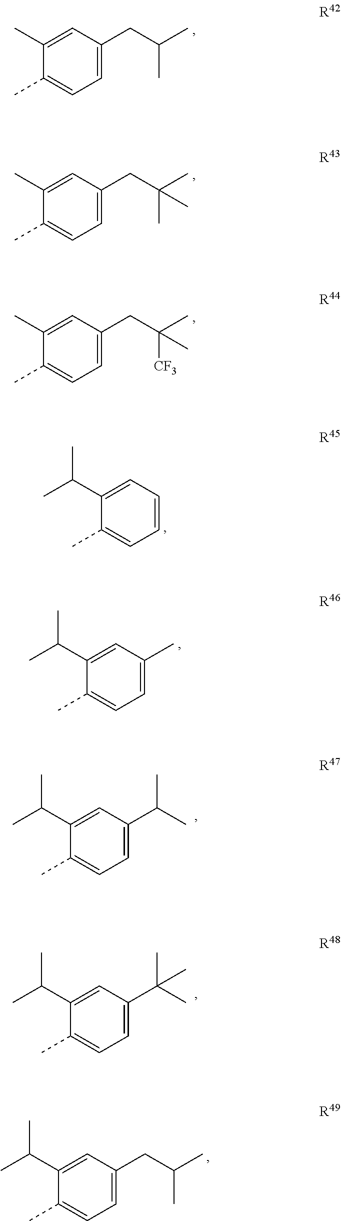

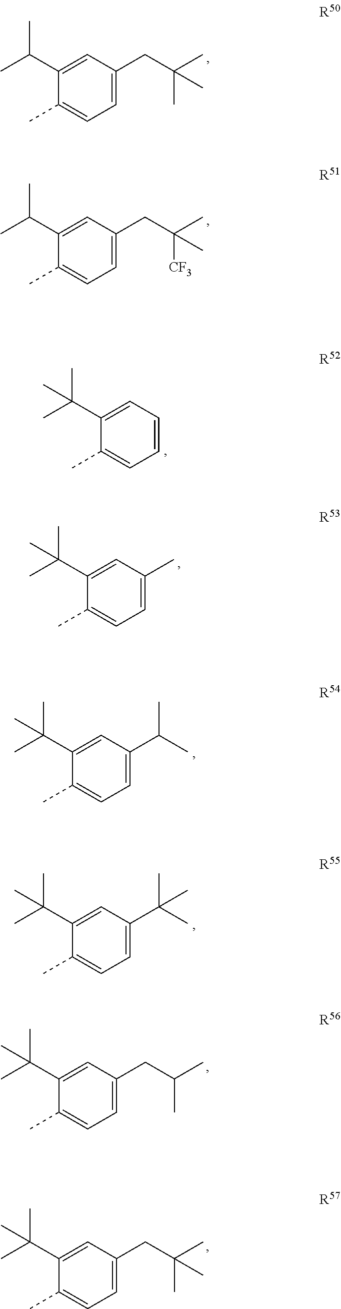

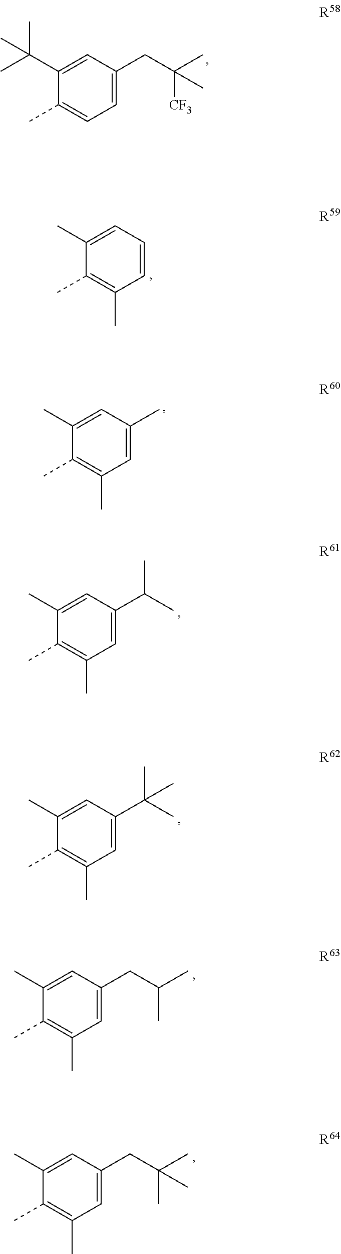

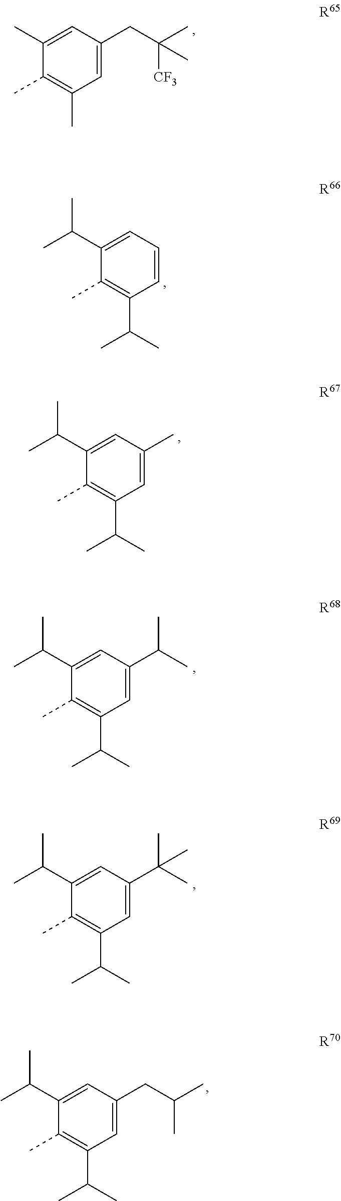

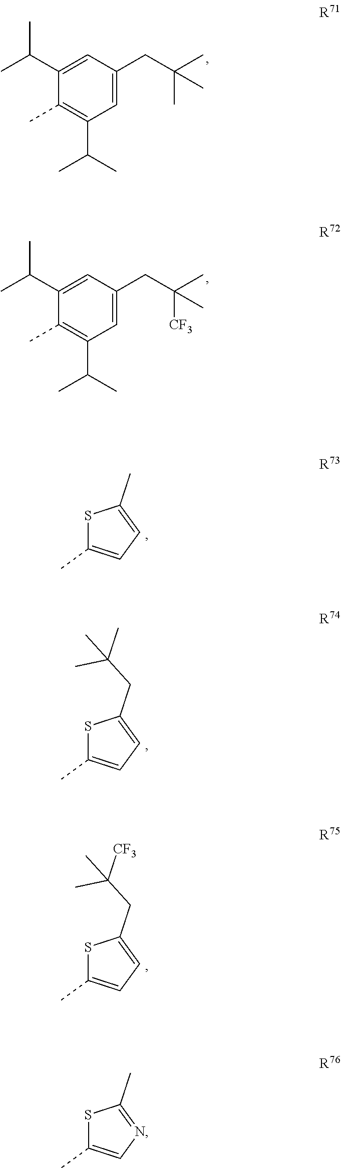

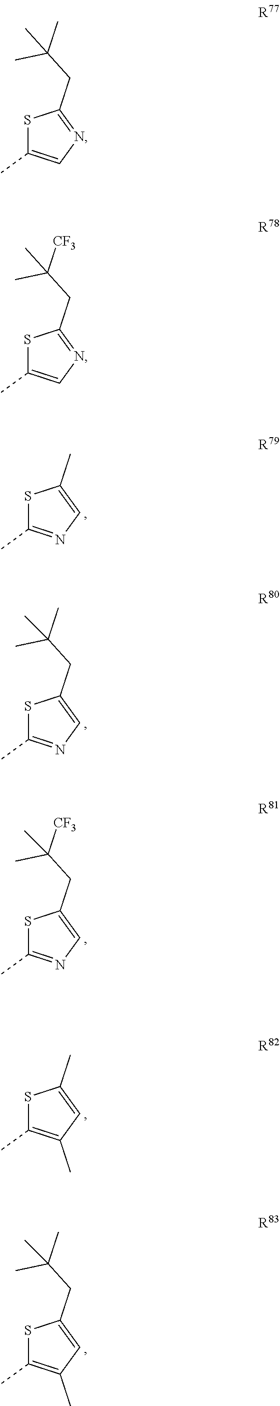

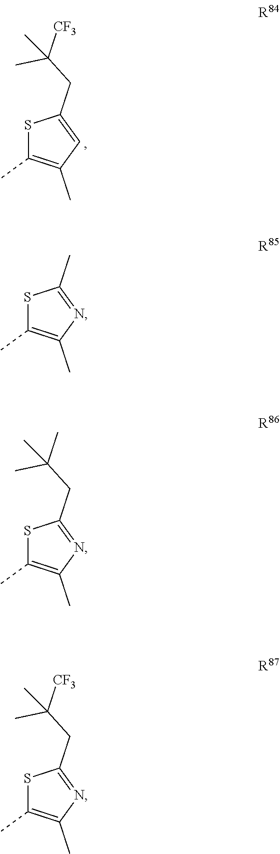

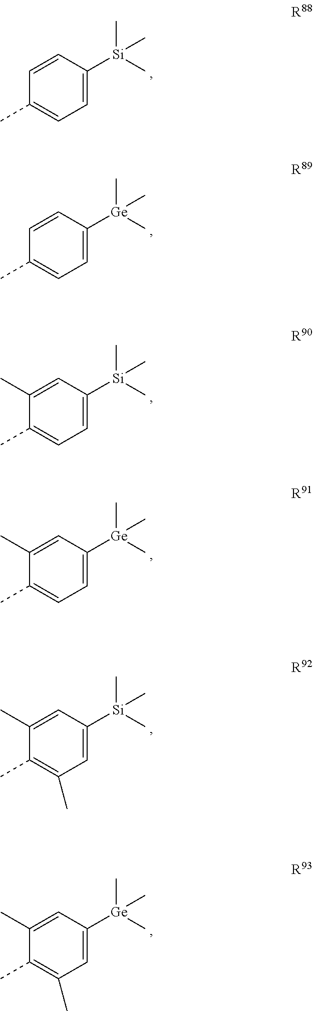

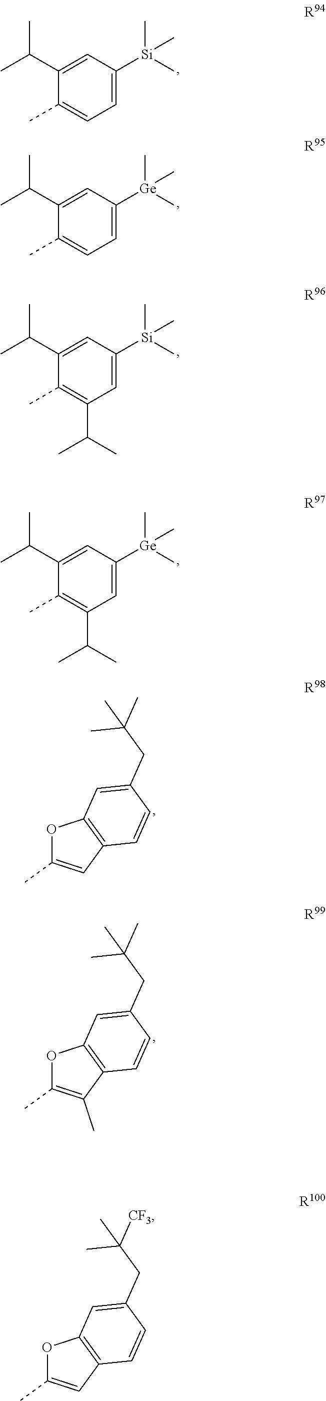

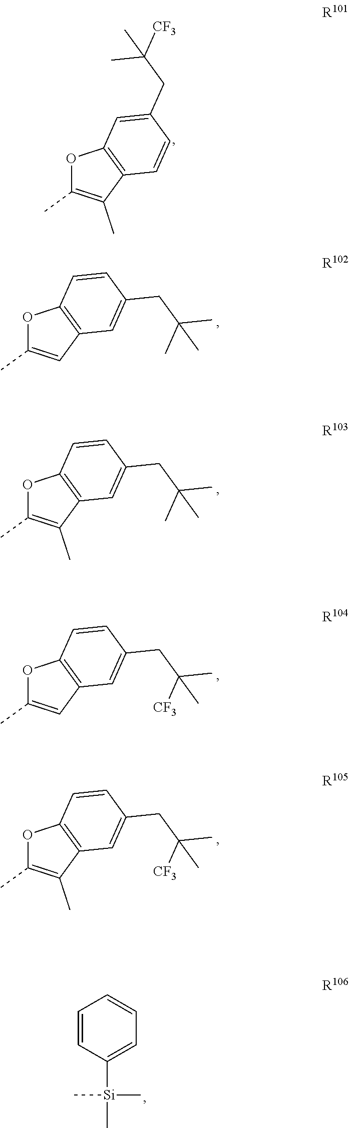

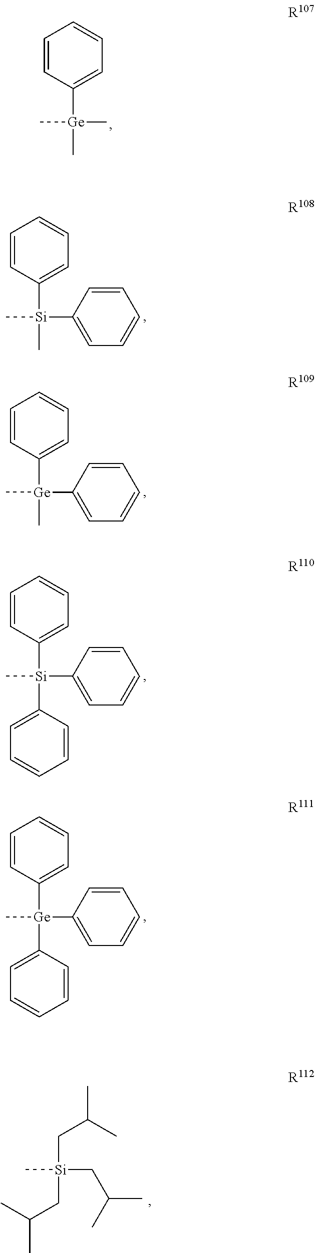

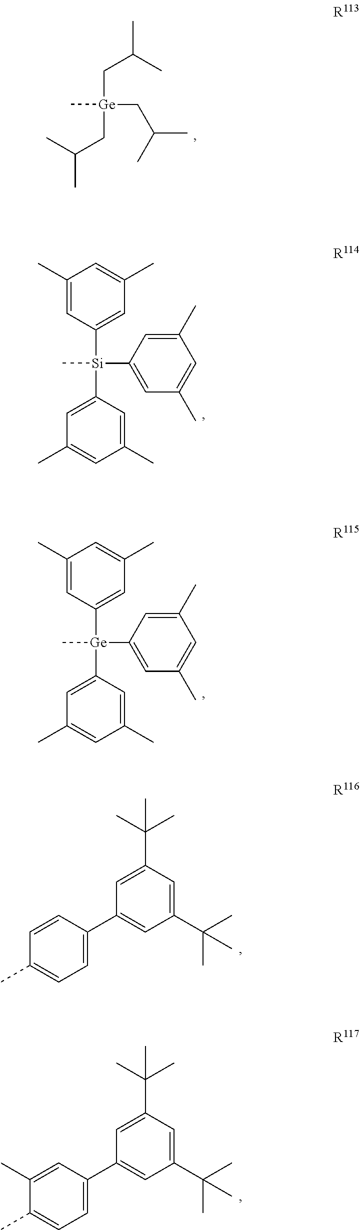

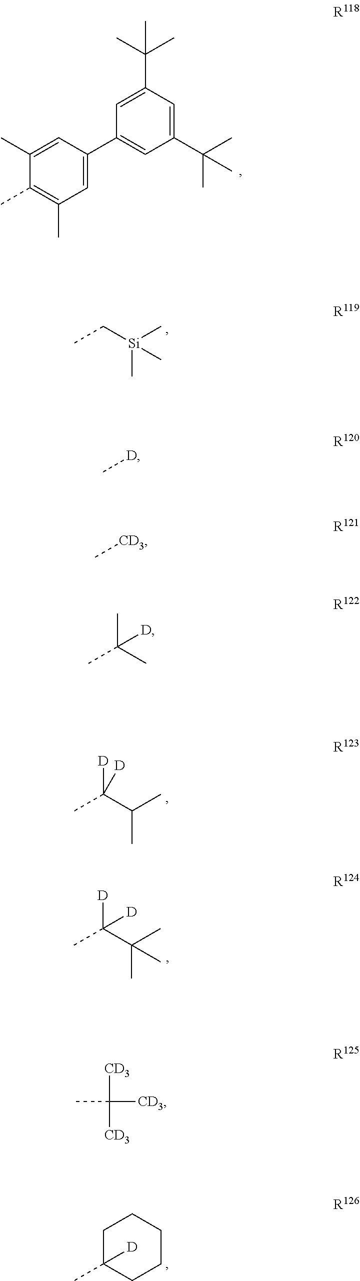

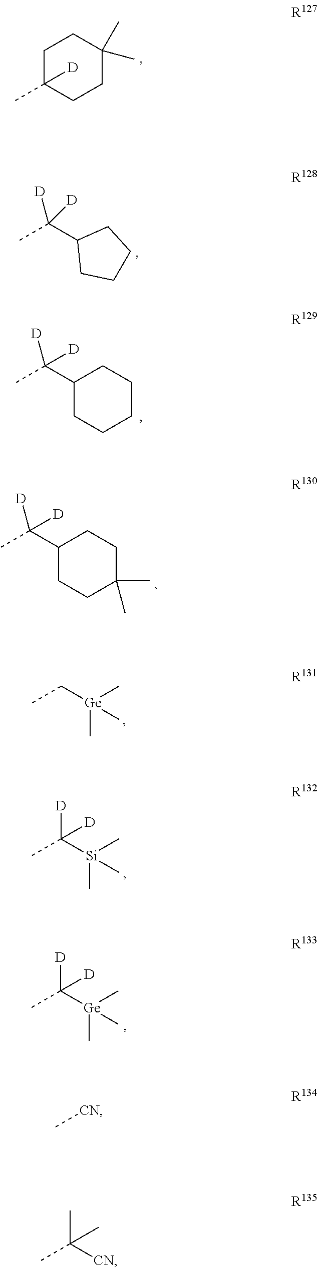

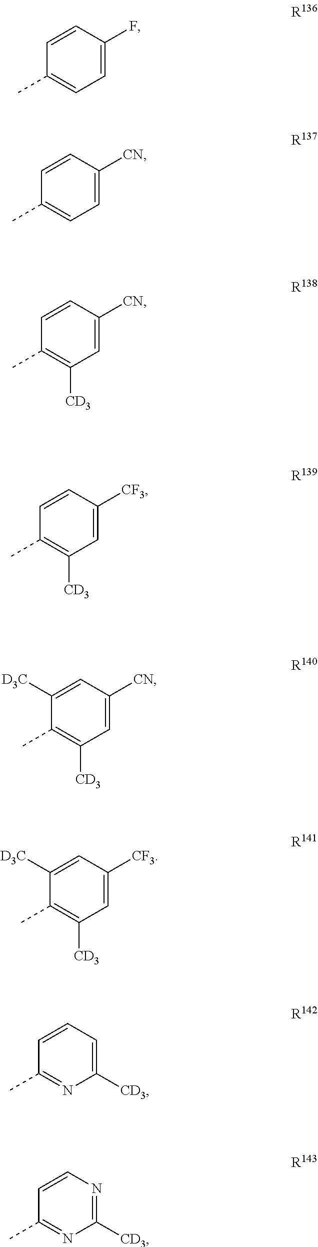

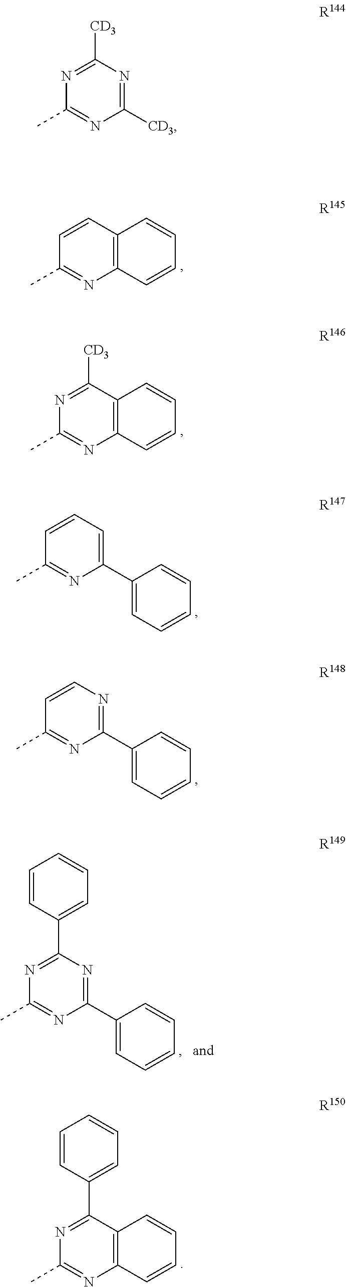

In some embodiments, the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, L_{B} comprises at least one electron-withdrawing group from the EWG1 LIST as defined herein. In some embodiments, L_{B} comprises at least one electron-withdrawing group from the EWG2 LIST as defined herein. In some embodiments, L_{B} comprises at least one electron-withdrawing group from the EWG3 LIST as defined herein. In some embodiments, L_{B} comprises at least one electron-withdrawing group from the EWG4 LIST as defined herein. In some embodiments, L_{B} comprises at least one electron-withdrawing group from the Pi-EWG LIST as defined herein.

In some embodiments, L_{C} comprises at least one electron-withdrawing group from the EWG1 LIST as defined herein. In some embodiments, L_{C} comprises at least one electron-withdrawing group from the EWG2 LIST as defined herein. In some embodiments, L_{C} comprises at least one electron-withdrawing group from the EWG3 LIST as defined herein. In some embodiments, L_{C} comprises at least one electron-withdrawing group from the EWG4 LIST as defined herein. In some embodiments, L_{C} comprises at least one electron-withdrawing group from the Pi-EWG LIST as defined herein.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound has a formula of Pt(L_{A})(L_{B}); and wherein L_{A} and L_{B} can be same or different. In some embodiments, L_{A} and L_{B} are connected to form a tetradentate ligand.

In some embodiments, L_{B} and L_{C} are each independently selected from the group consisting of the structures of the following LIST 5:

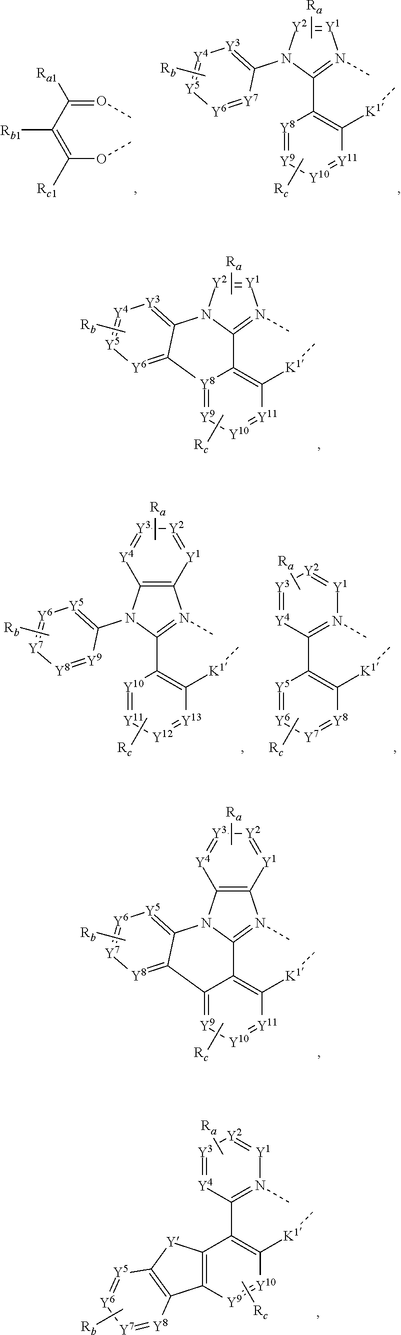

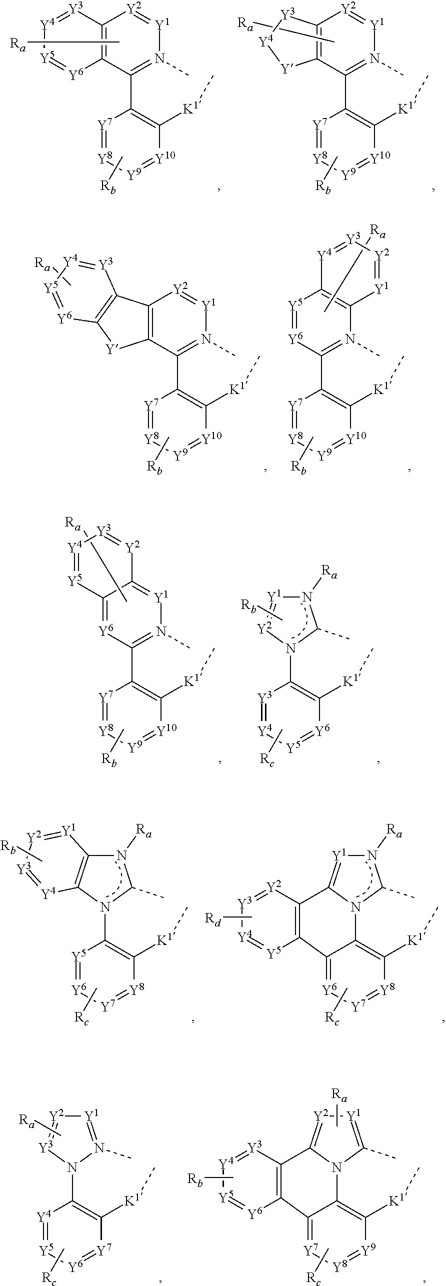

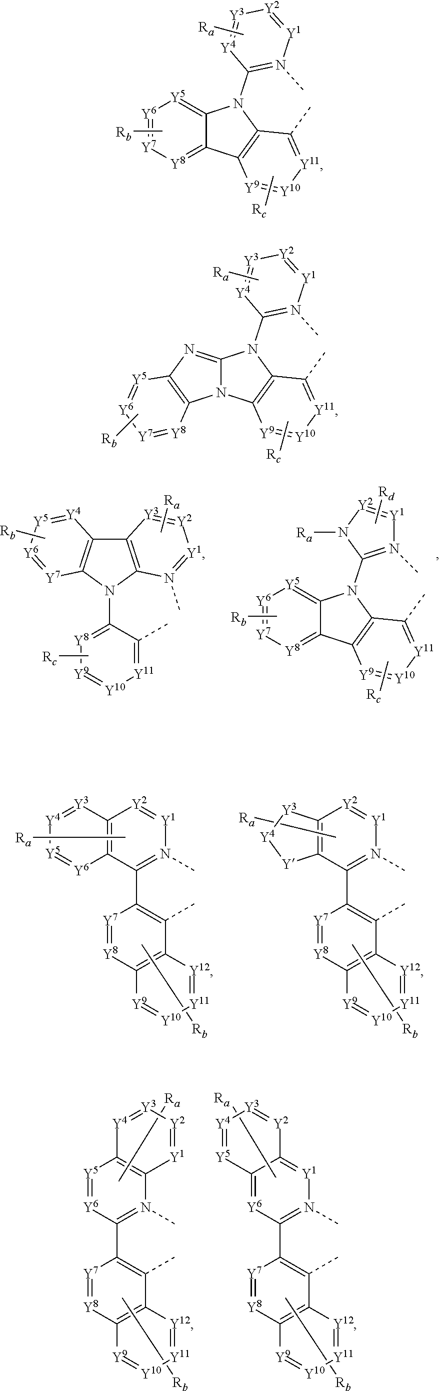

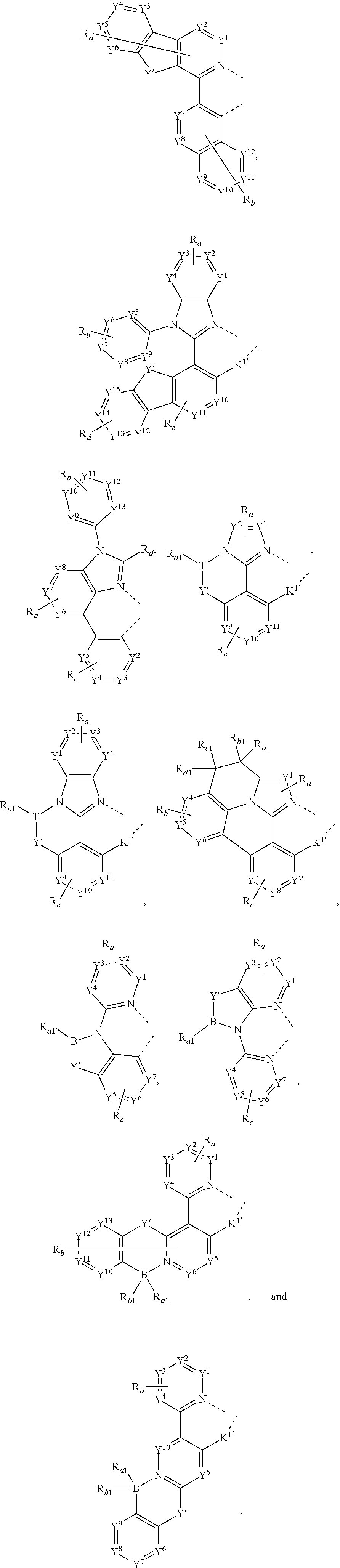

wherein:
T is selected from the group consisting of B, Al, Ga, and In;
   K^{1′} is selected from the group consisting of a single bond, O, S, NRₑ, PRₑ, BRₑ, CRₑR_{f}, and SiRₑR_{f};
   each of Y¹ to Y¹³ is independently selected from the group consisting of C and N;
   Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
   Rₑ and R_{f} can be fused or joined to form a ring;
   each Rₐ, R_{b}, R_{c}, and R_{d} independently represents from mono to the maximum allowed number of substitutions, or no substitution;
   each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of the General Substituents defined herein; and
any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, L_{B} and L_{C} are each independently selected from the group consisting of the structures of the following LIST 6:

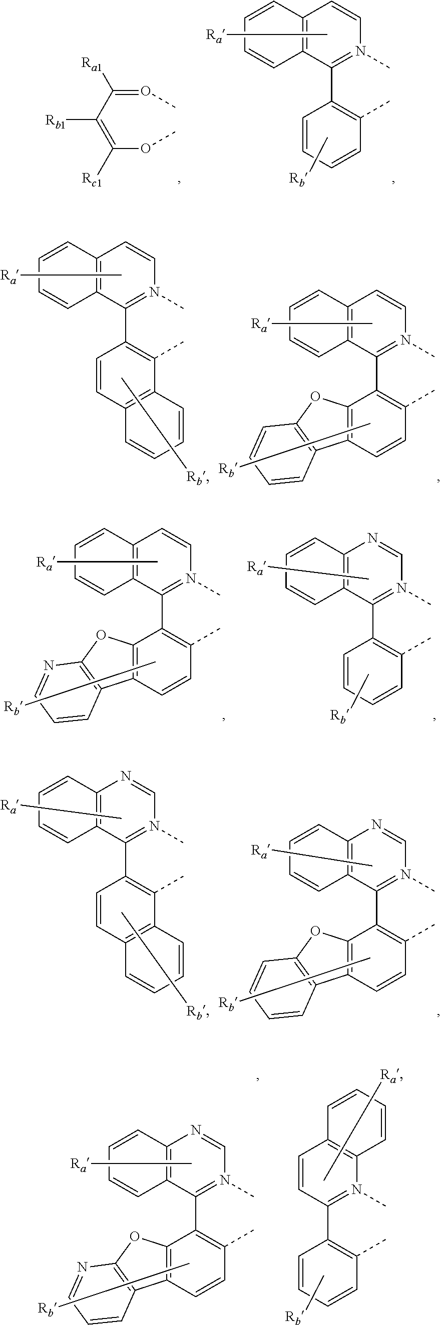

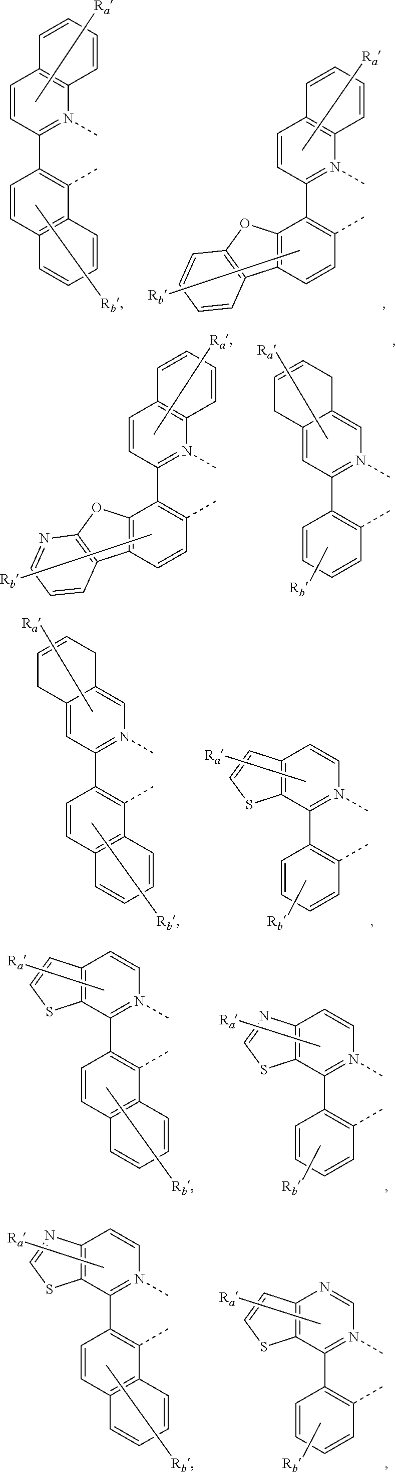

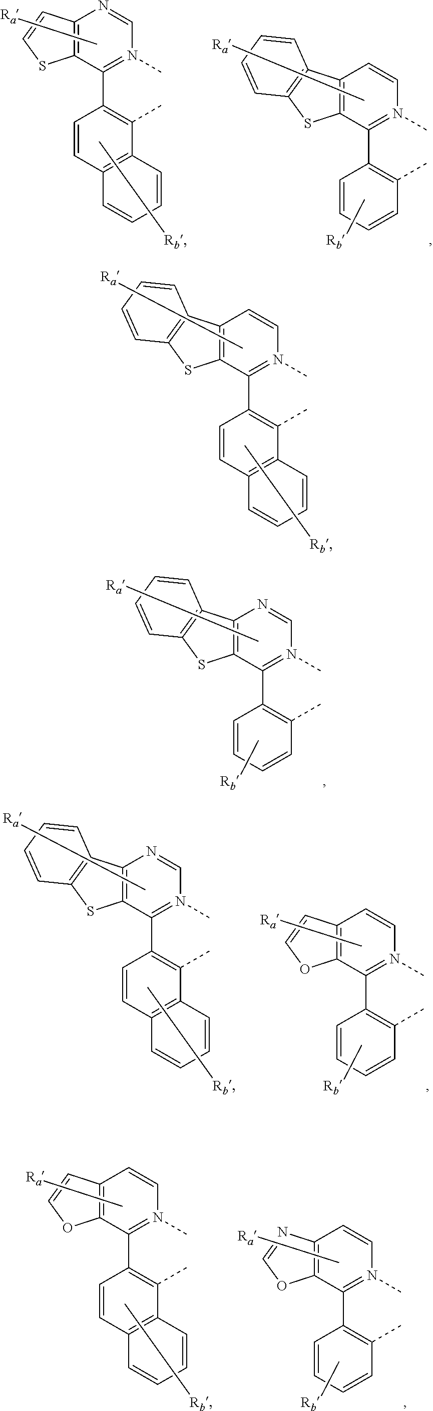

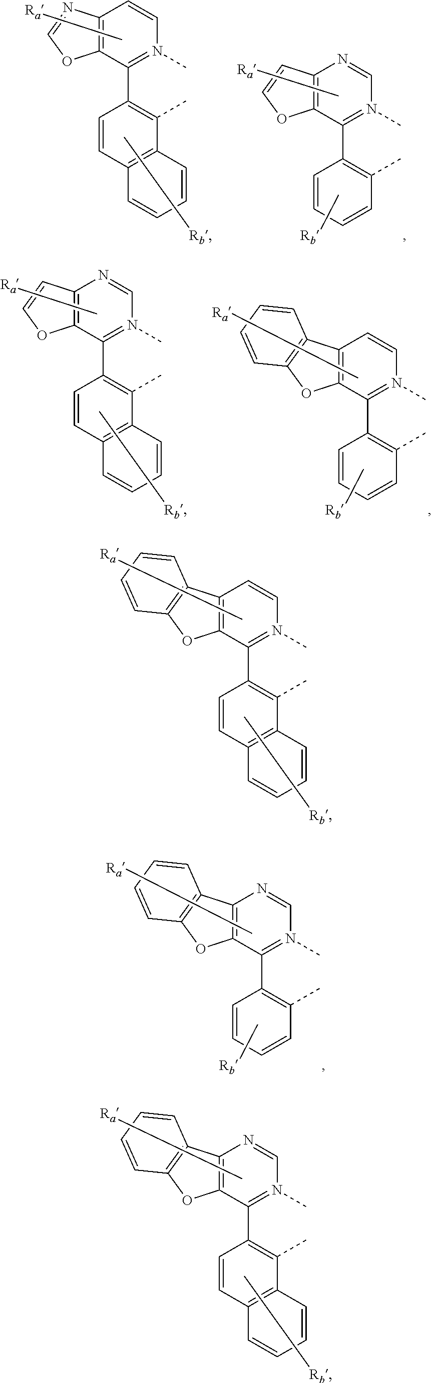

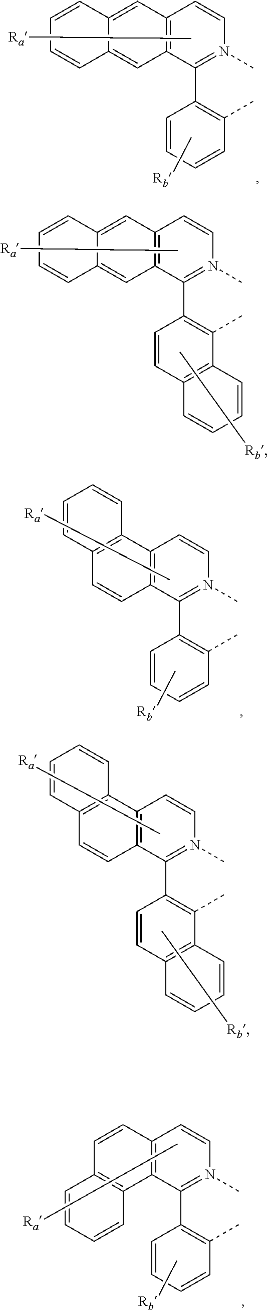

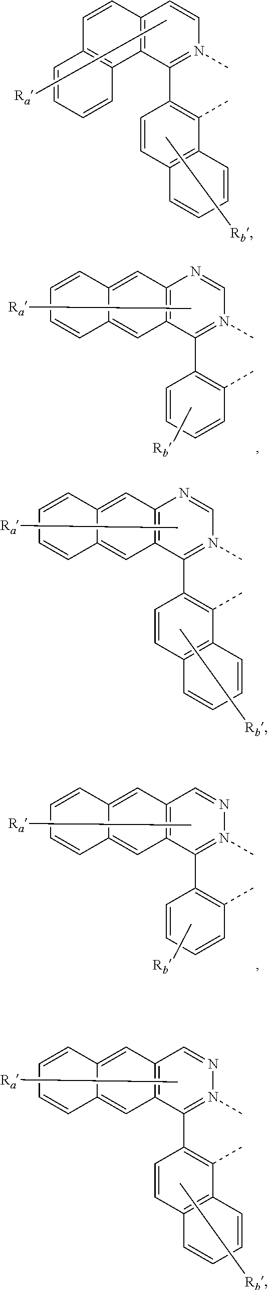

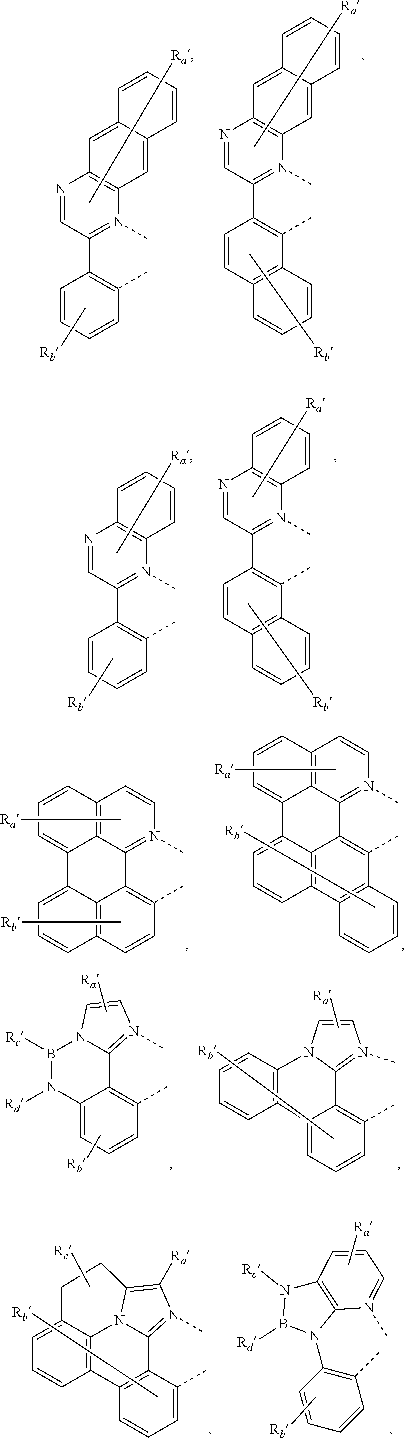

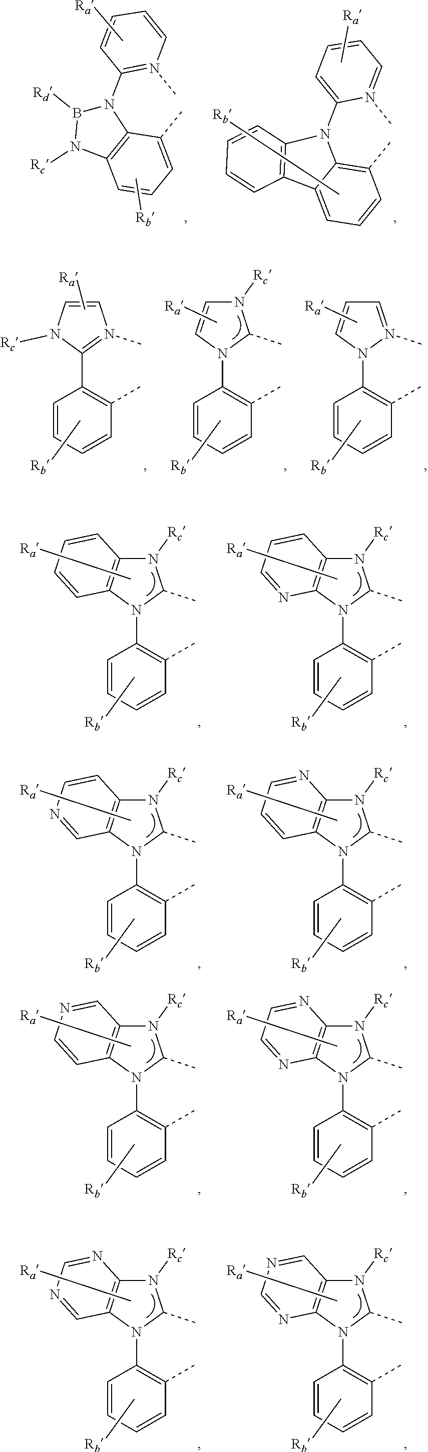

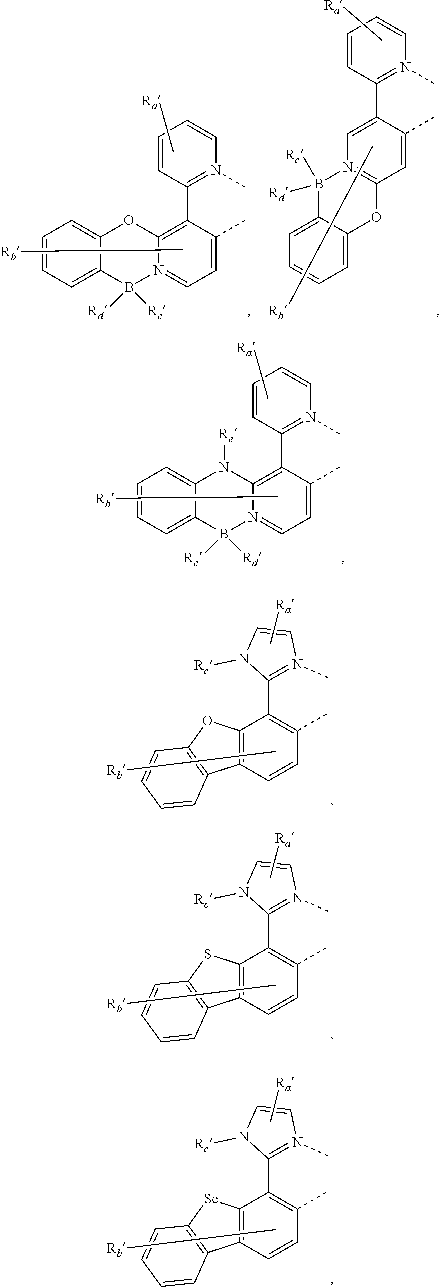

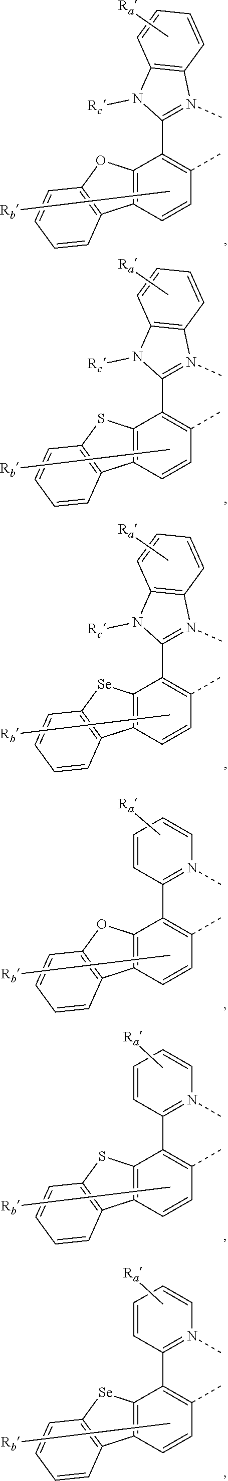

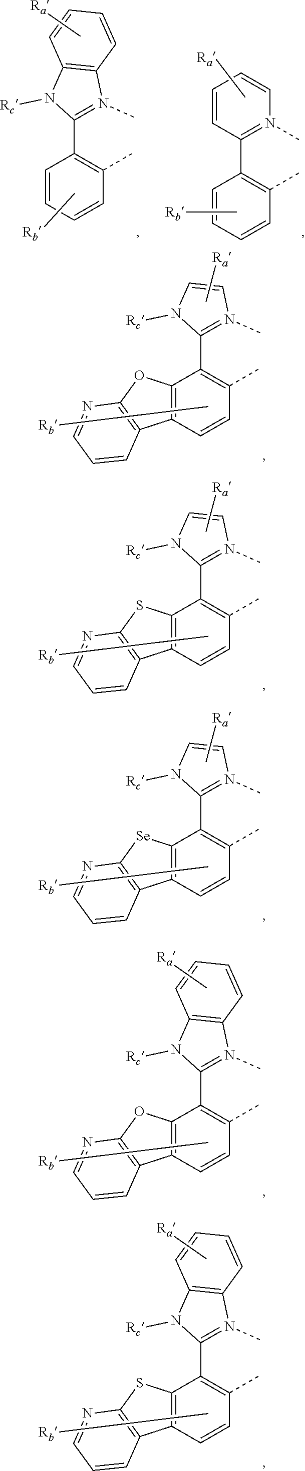

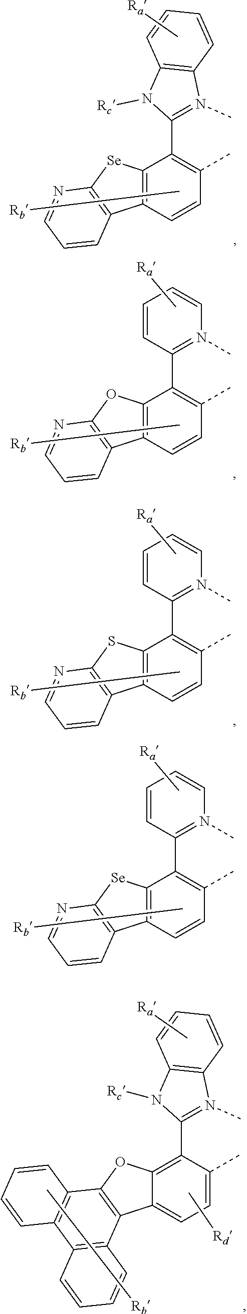

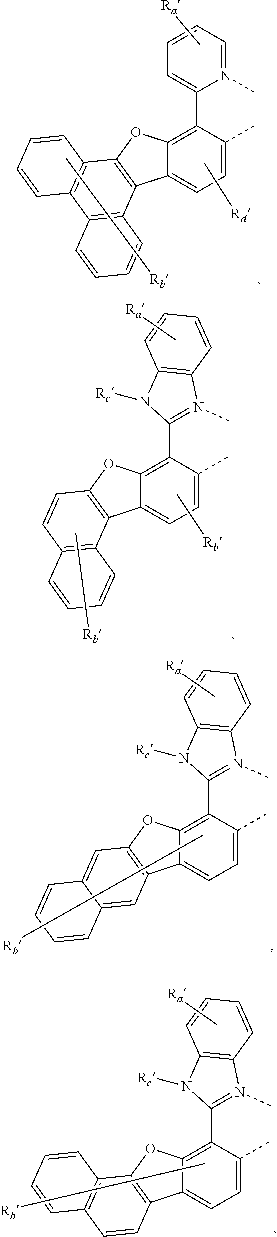

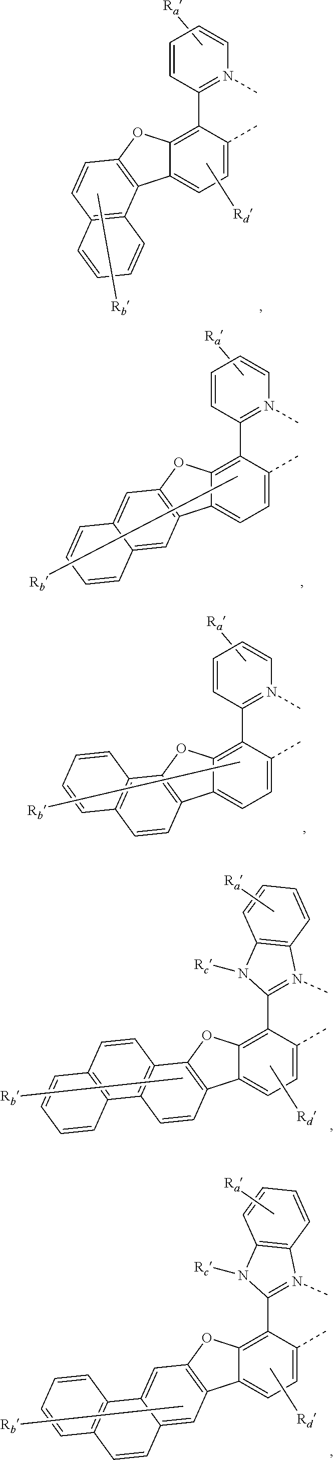

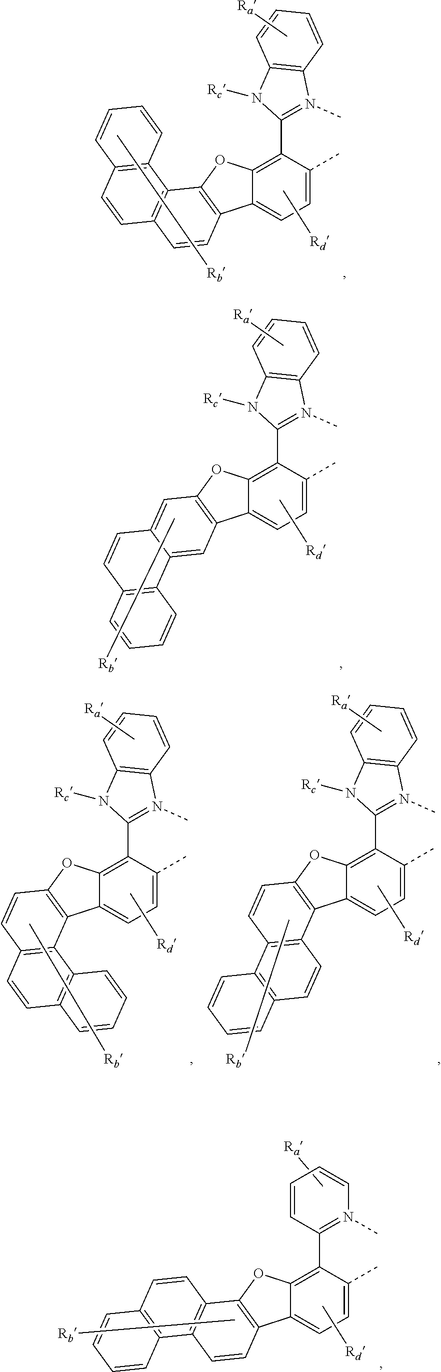

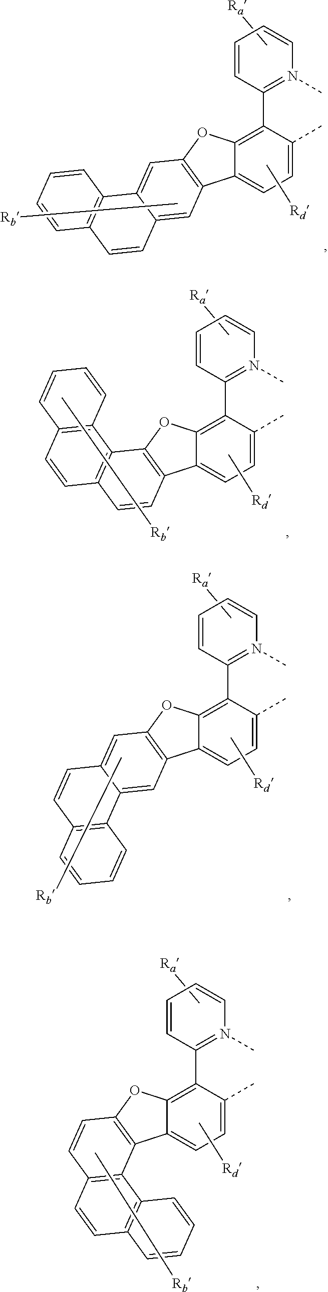

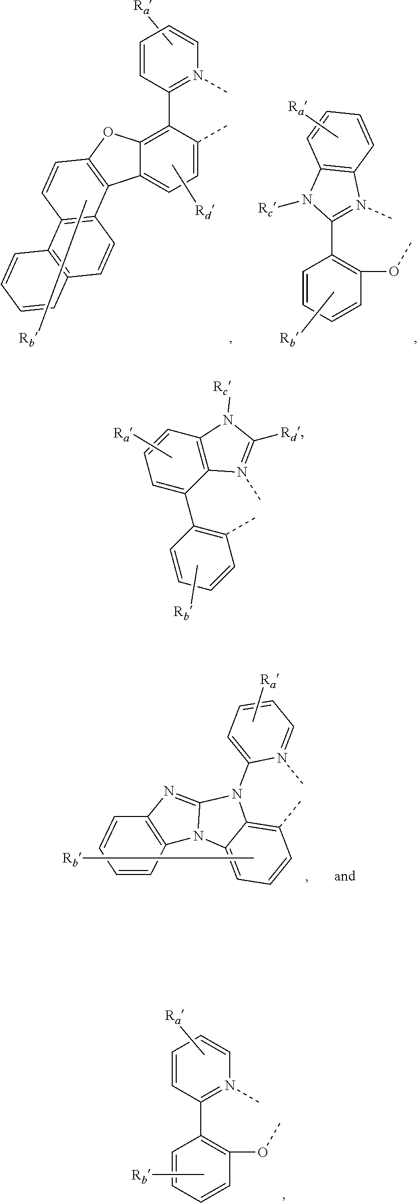

wherein:
Rₐ′, R_{b}′, R_{c}′, R_{d}′, and Rₑ′ each independently represents zero, mono, or up to a maximum allowed number of substitution to its associated ring;
Rₐ′, R_{b}′, R_{c}′, R_{d}′, and Rₑ′ each independently hydrogen or a substituent selected from the group consisting of the General substituents defined herein; and
two substituents of Rₐ′, R_{b}′, R_{c}′, R_{d}′, and Rₑ′ can be fused or joined to form a ring or form a multidentate ligand.

In some embodiments, L_{B} comprises a structure of

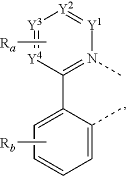

wherein the variables are the same as previously defined. In some embodiments, each of Y¹ to Y⁴ is independently carbon. In some embodiments, at least one of Y¹ to Y⁴ is N. In some embodiments, exactly one of Y¹ to Y⁴ is N. In some embodiments, Y¹ is N. In some embodiments, Y² is N. In some embodiments, Y³ is N. In some embodiments, Y⁴ is N. In some embodiments, at least one of Rₐ is a tertiary alkyl, silyl or germyl. In some embodiments, at least one of Rₐ is a tertiary alkyl. In some embodiments, Y³ is C and the Rₐ attached thereto is a tertiary alkyl, silyl or germyl. In some embodiments, Y¹ to Y³ is C, Y⁴ is N, and the Rₐ attached to Y³ is a tertiary alkyl, silyl or germyl. In some embodiments, Y¹ to Y³ is C, Y⁴ is N, and the Rₐ attached to Y² is a tertiary alkyl, silyl or germyl. In some embodiments, at least one of R_{b} is a tertiary alkyl, silyl, or germyl. In some embodiments, the tertiary alkyl is tert-butyl. In some embodiments, at least one pair of Rₐ, one pair of R_{b}, or one pair of Rₐ and R_{b} are joined or fused into a ring.

[PTO1] In some embodiments, the compound has formula Ir(L_{A})₃, formula Ir(L_{A})(L_{Bk})₂, formula Ir(L_{A})₂(L_{Bk}), formula Ir(L_{A})₂(L_{Cj-I}), or Ir(L_{A})₂(L_{Cj-II}), wherein L_{A} is according to any embodiments described herein, including L_{A1}(R¹)(R¹)(R¹)(R¹)(R¹) to L_{A141}(R¹⁵⁰)(R¹⁵⁰)(R¹⁵⁰)(R¹⁵⁰)(R¹⁵⁰);
wherein k is an integer from 1 to 530, and each L_{Bk} has the structure defined in the following LIST 7:

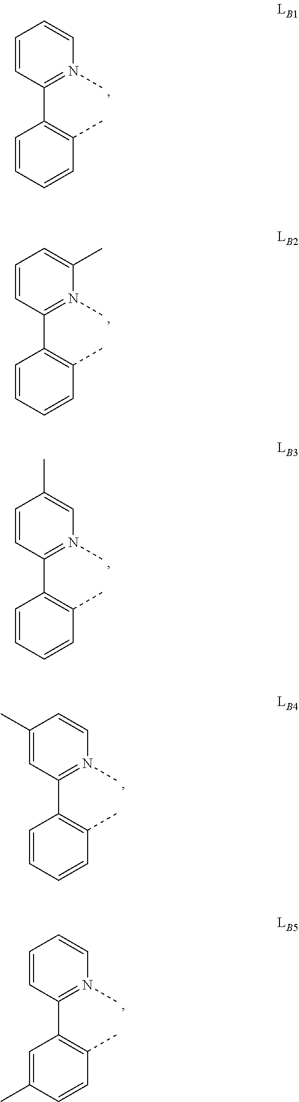

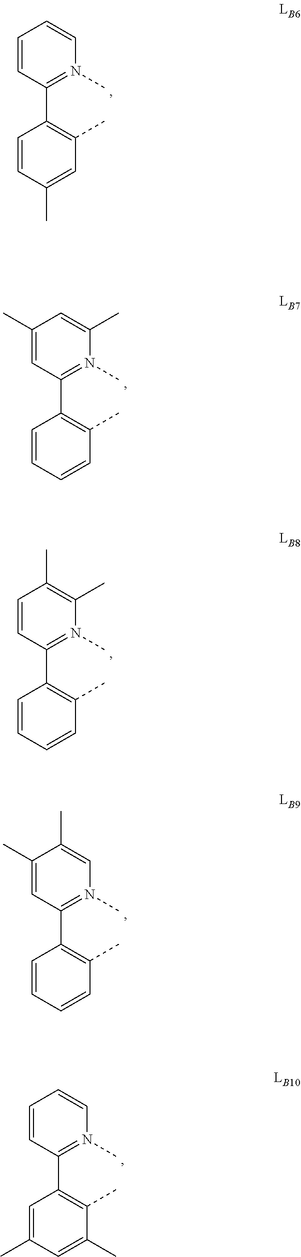

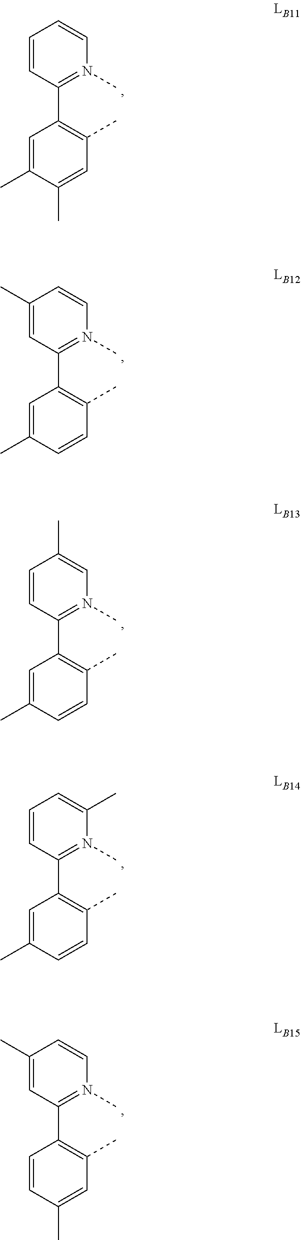

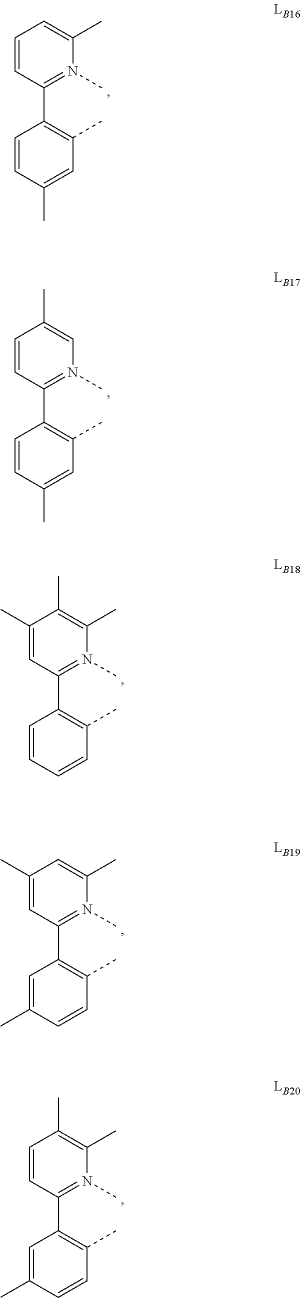

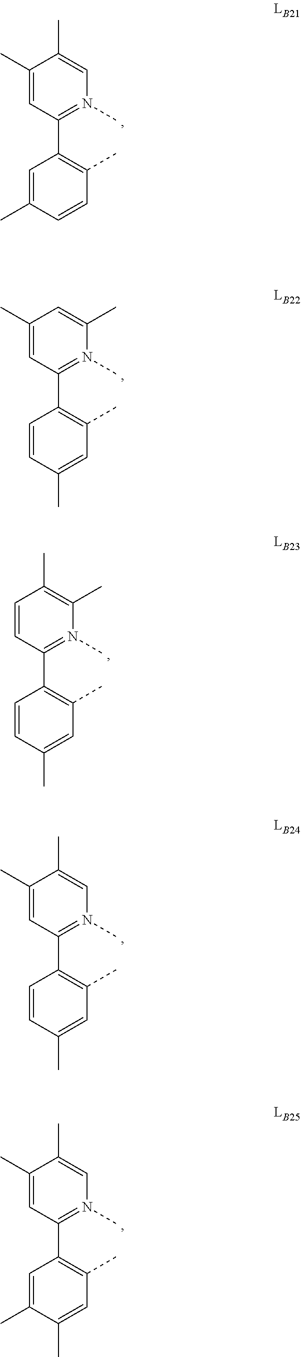

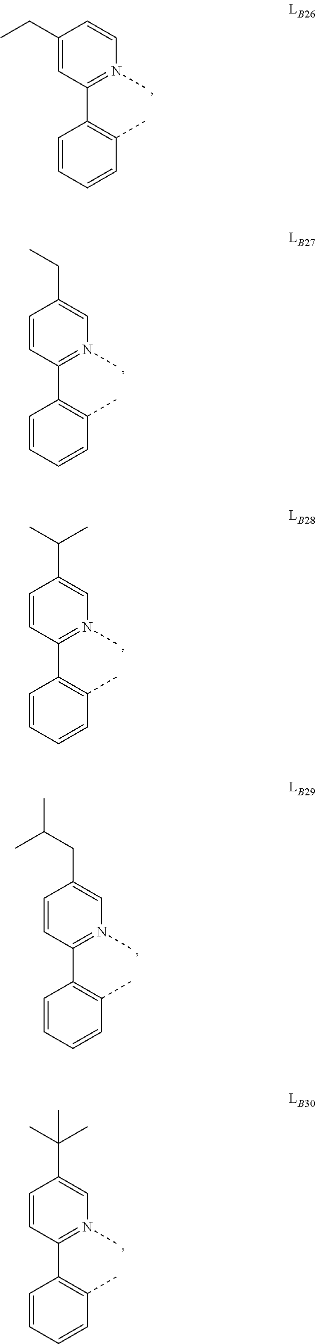

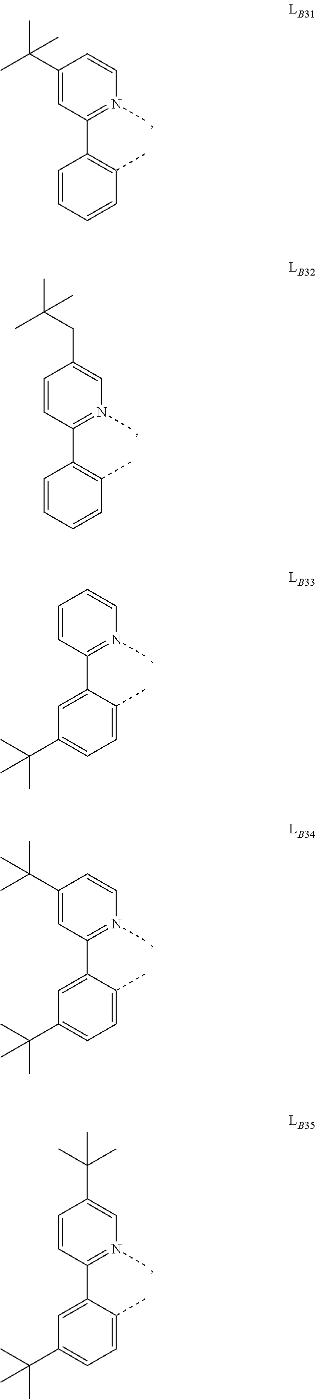

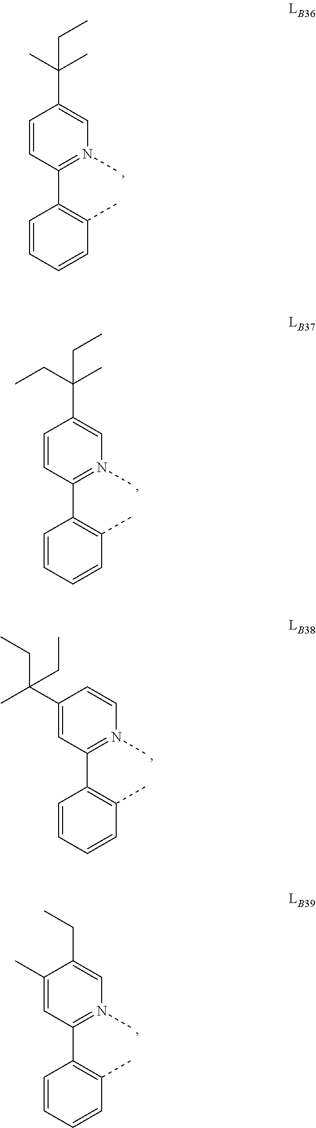

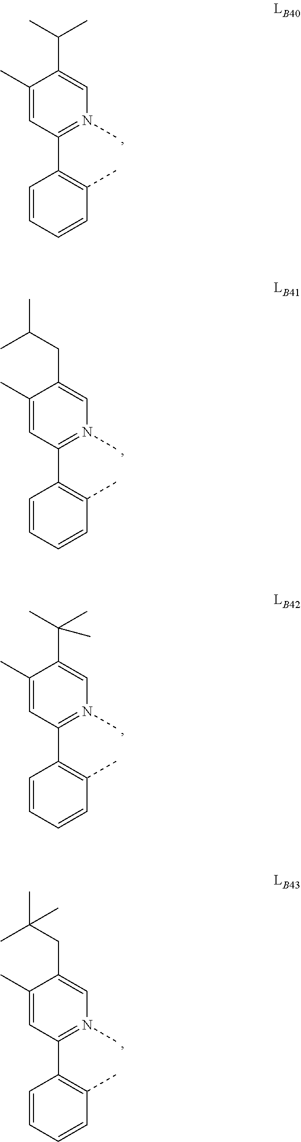

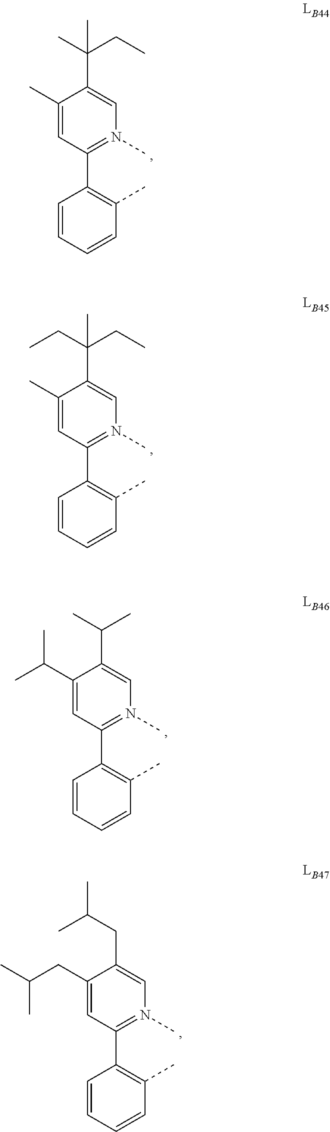

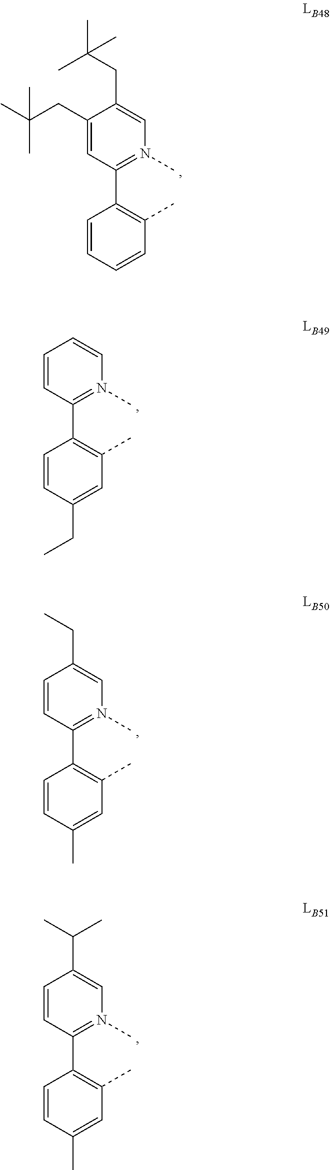

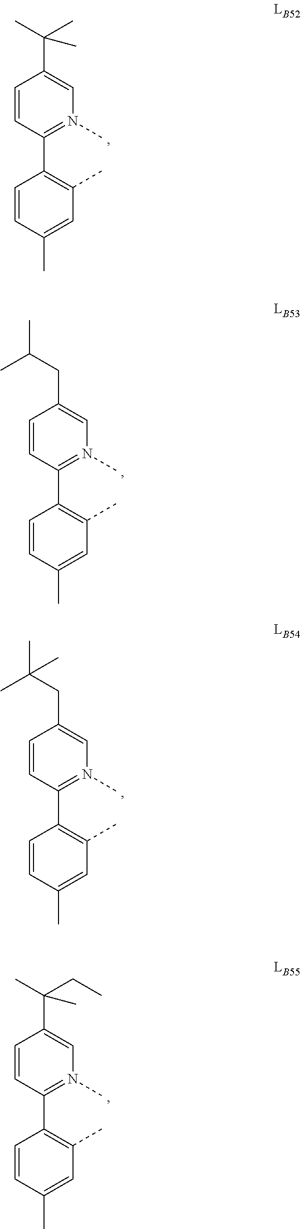

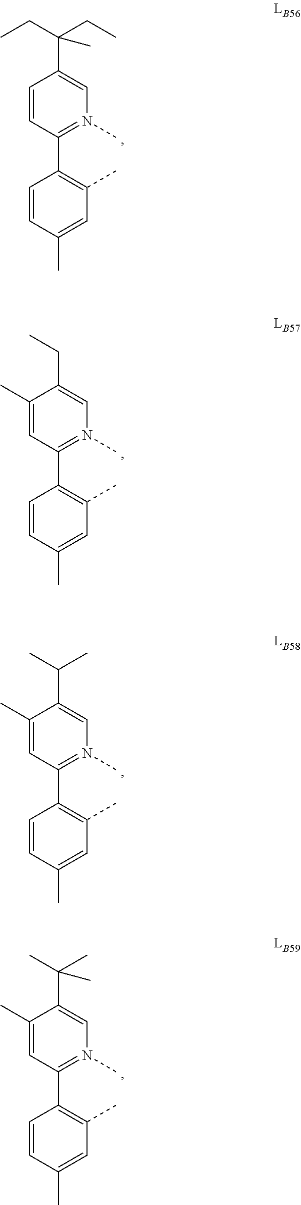

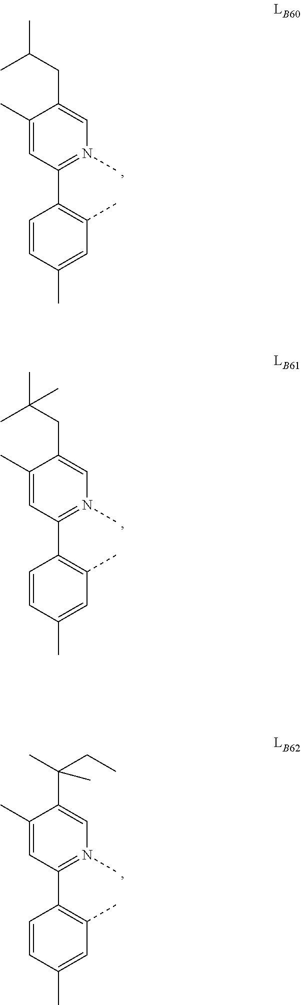

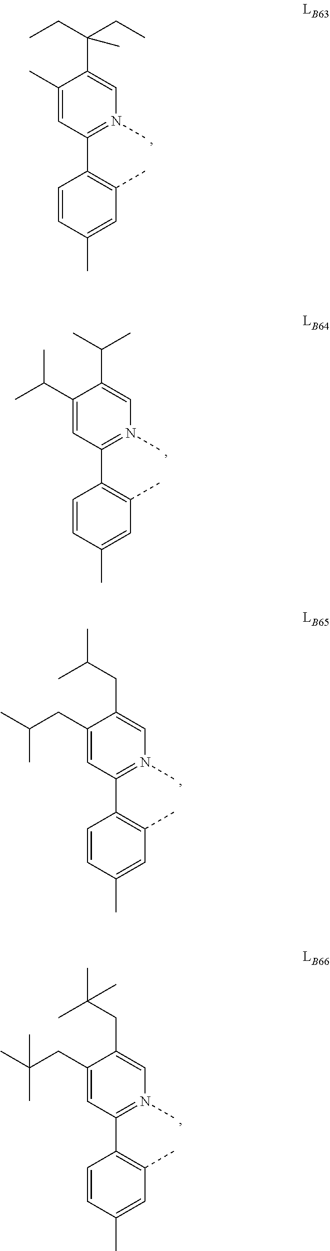

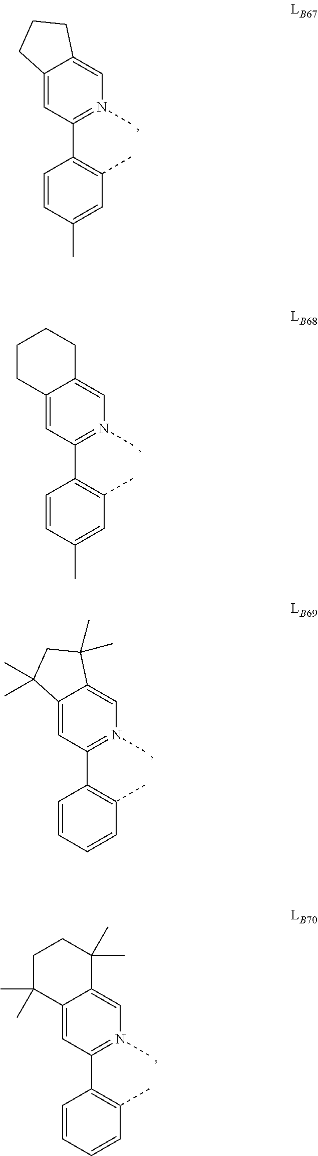

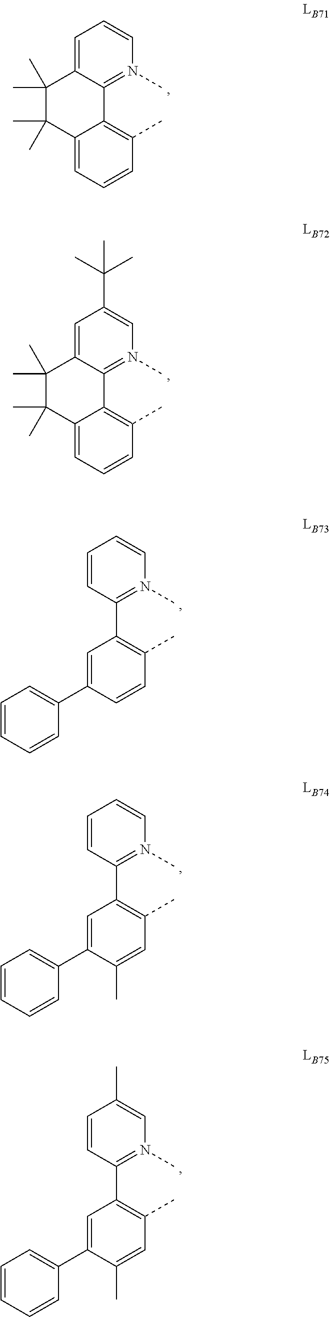

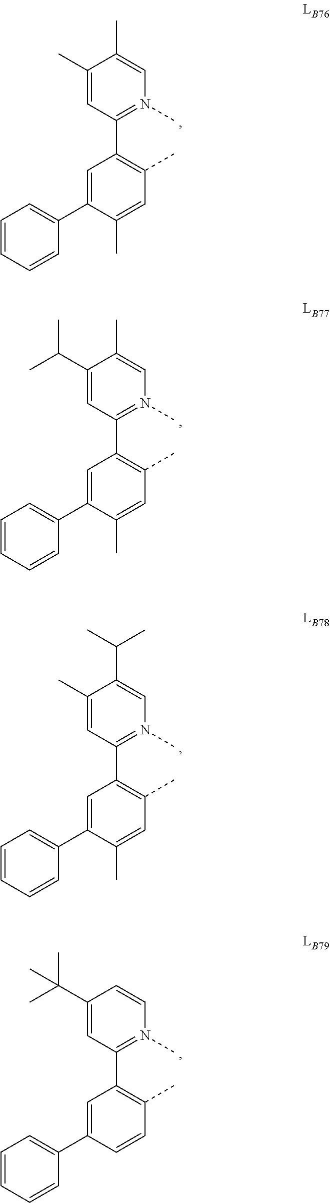

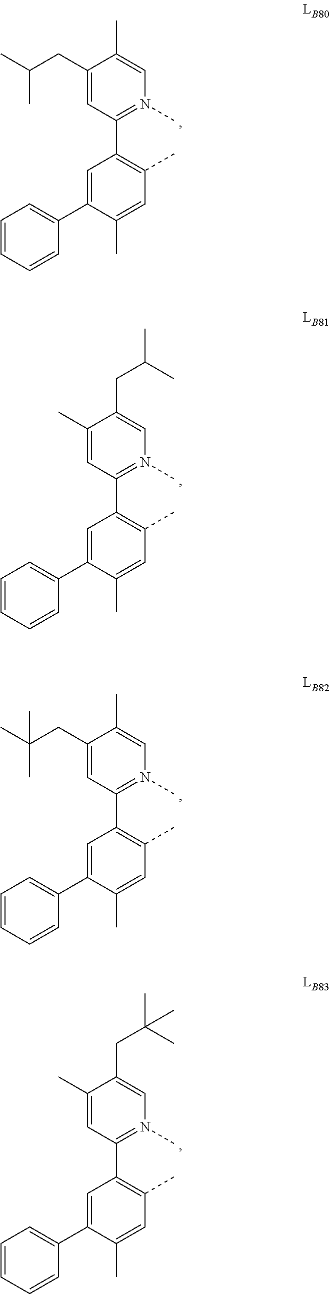

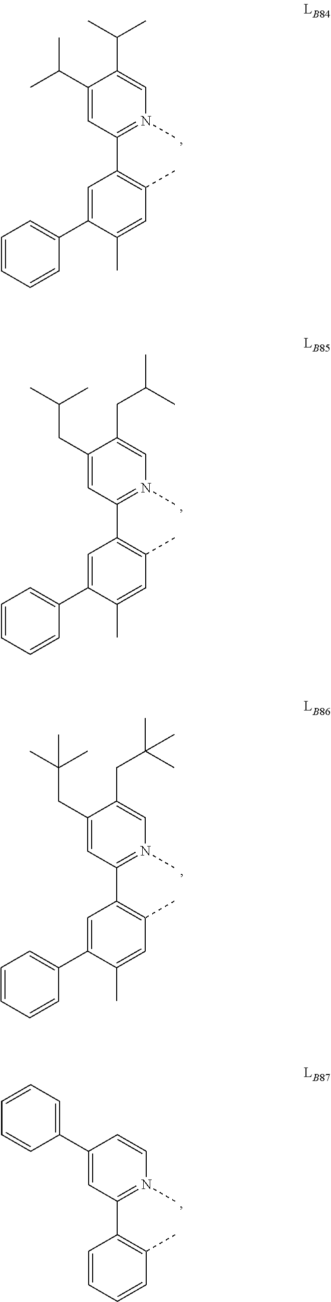

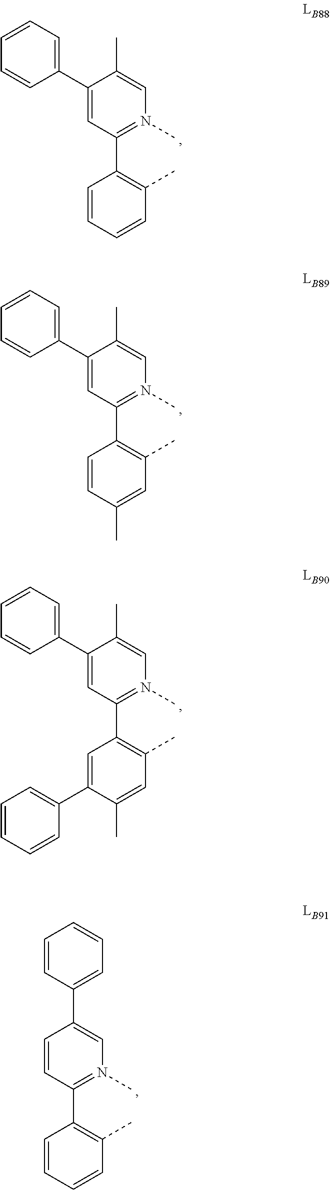

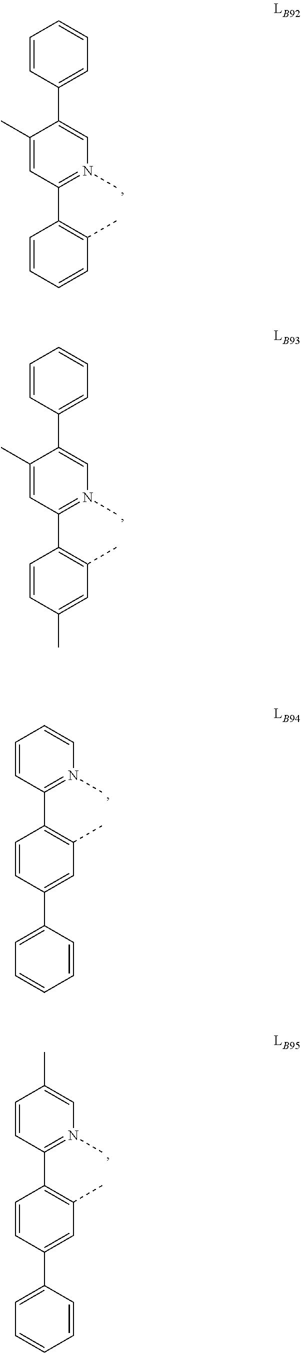

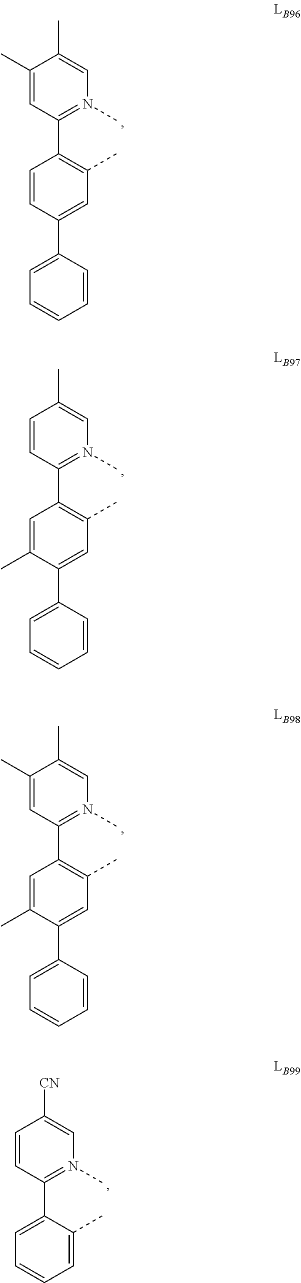

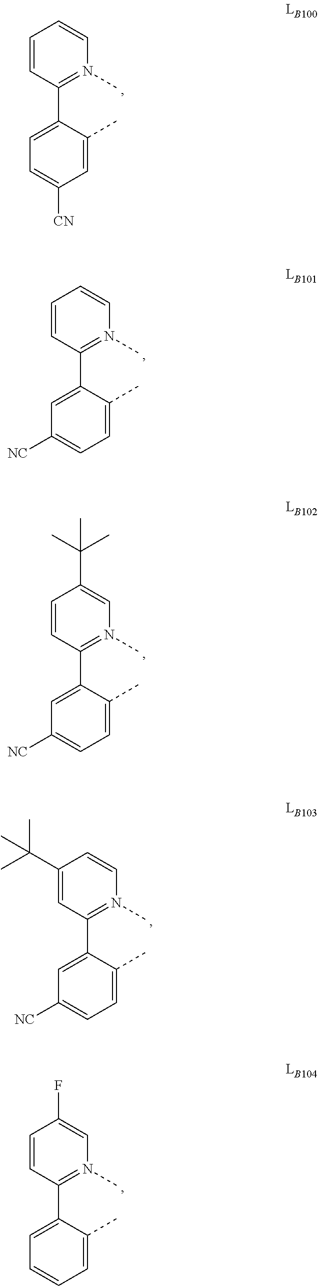

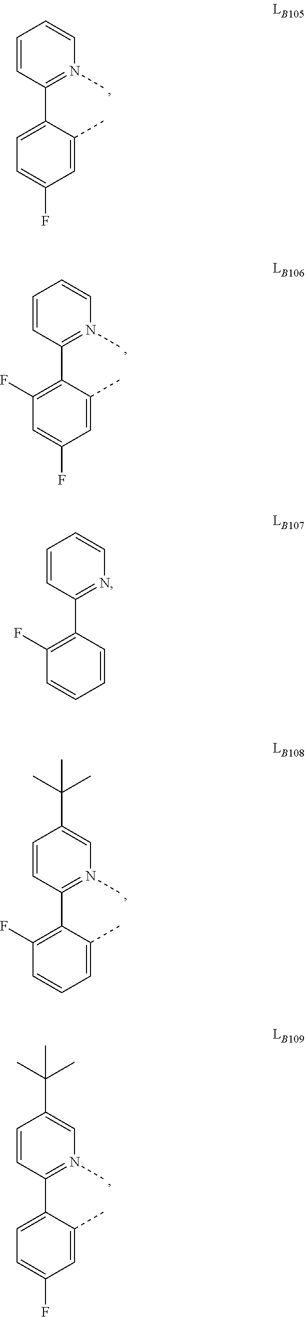

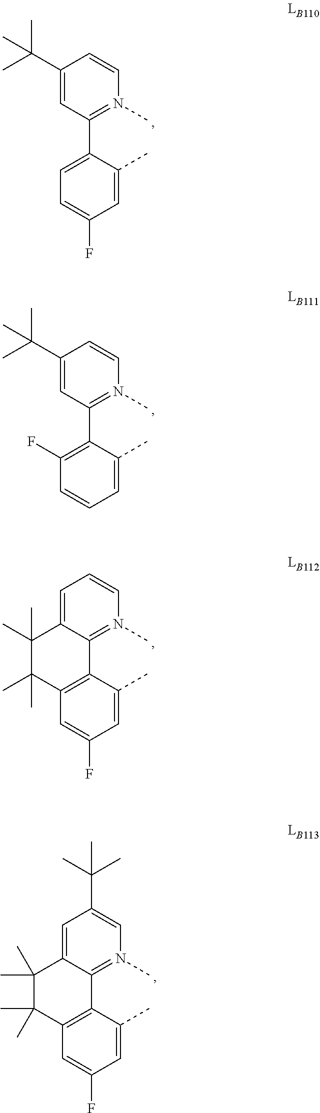

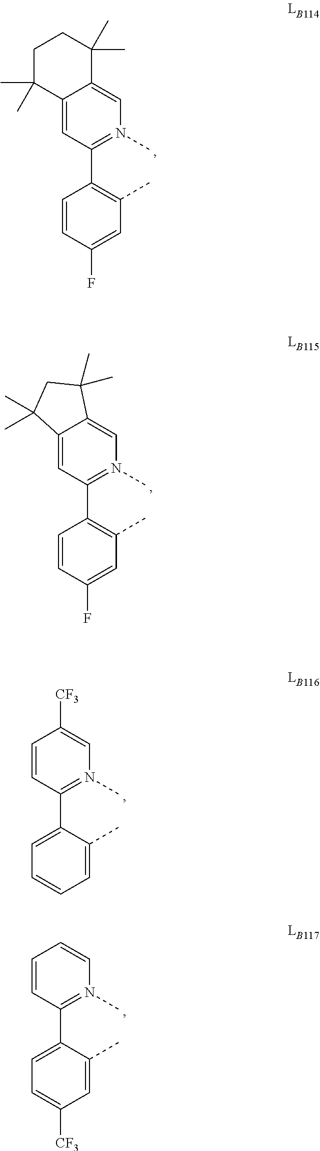

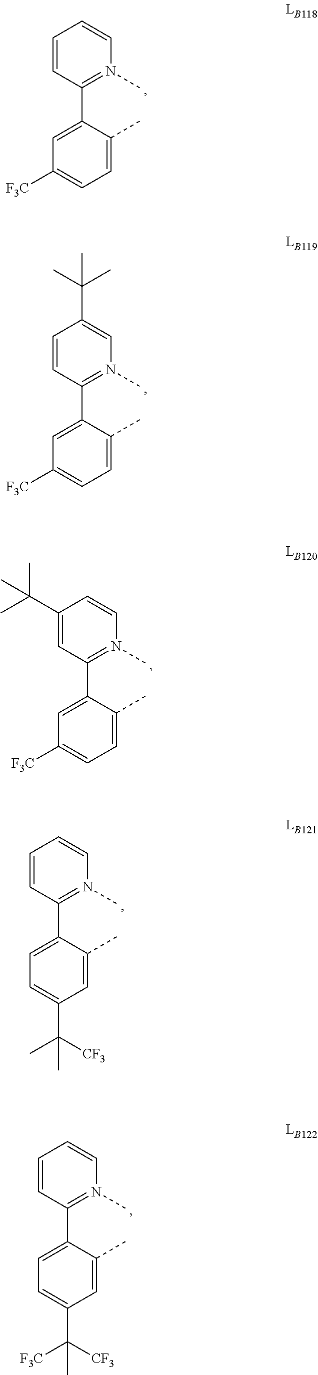

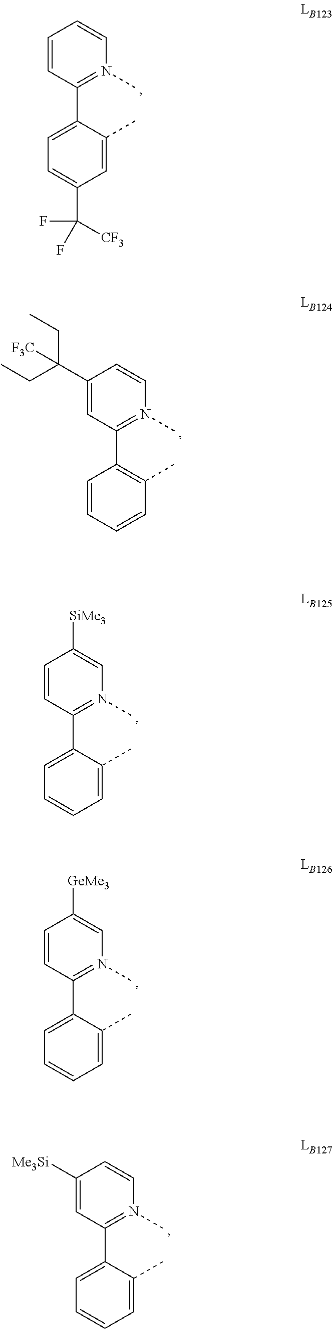

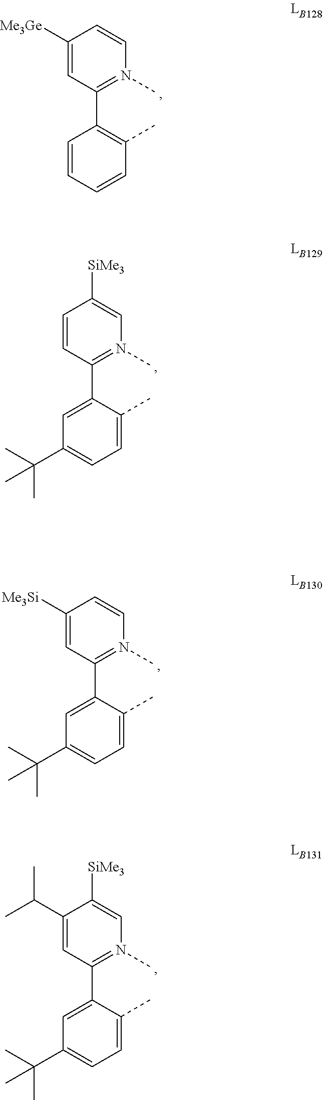

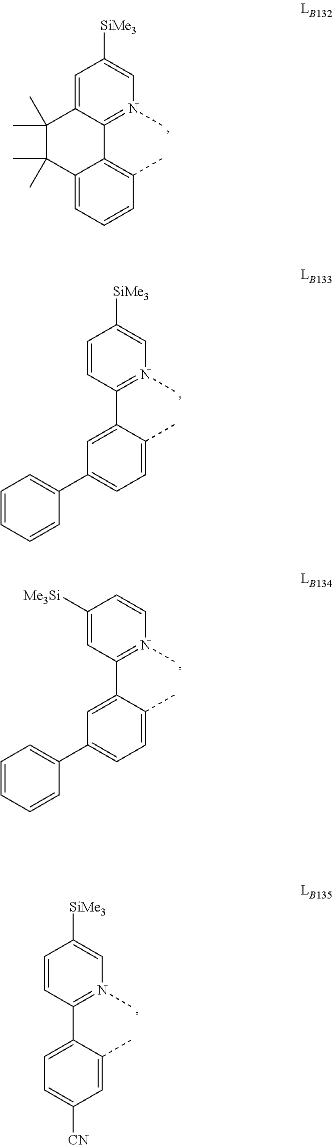

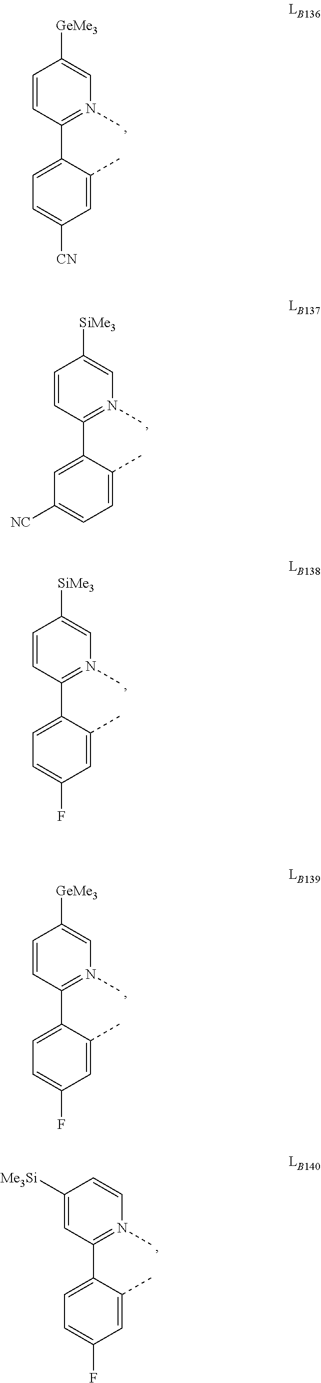

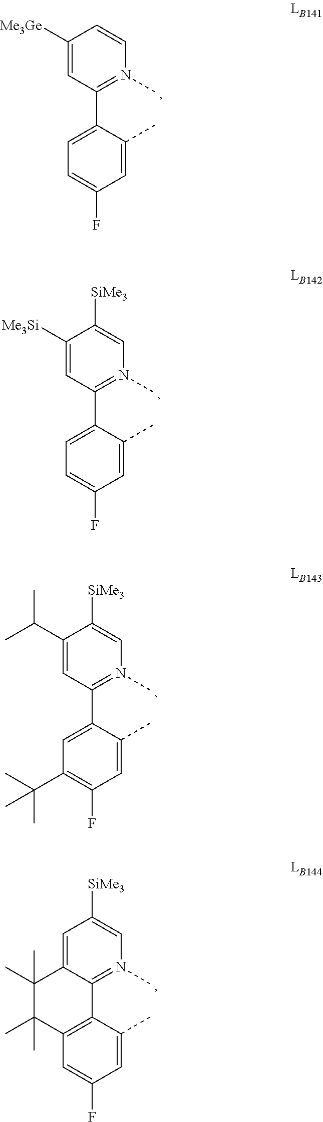

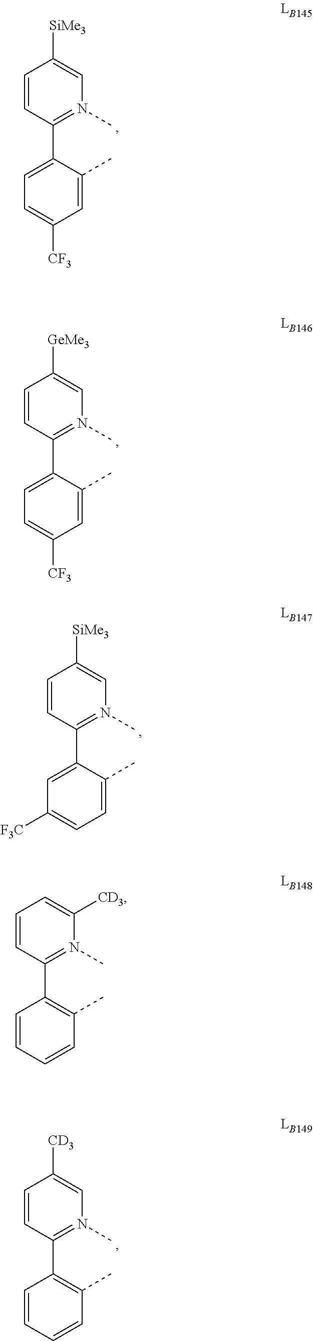

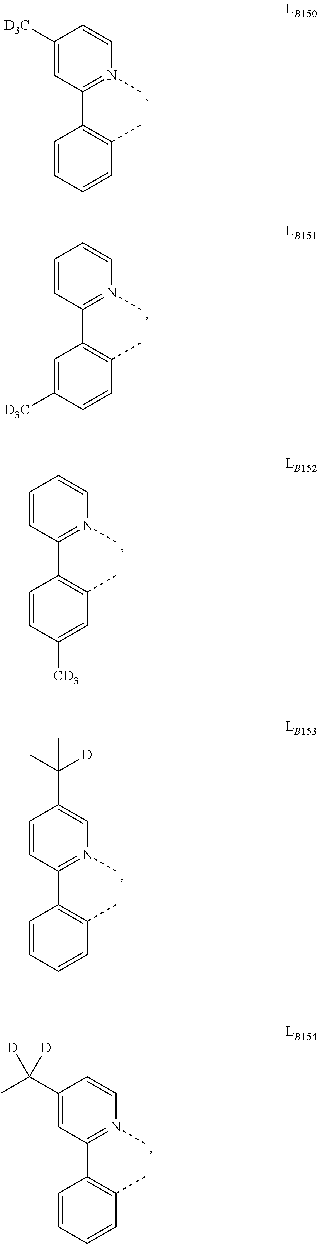

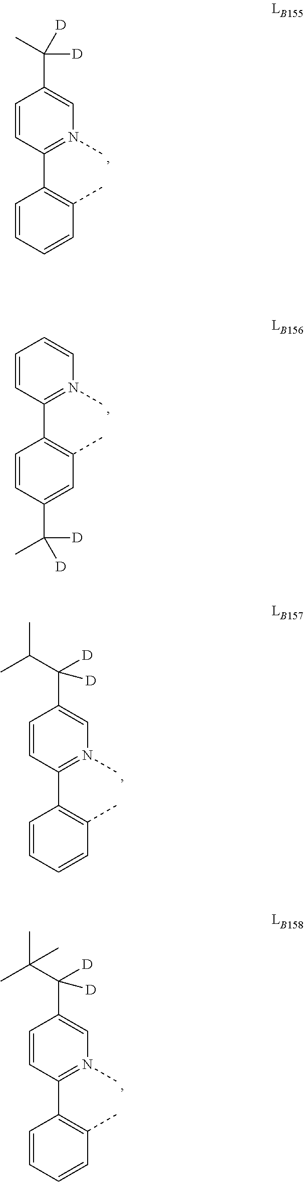

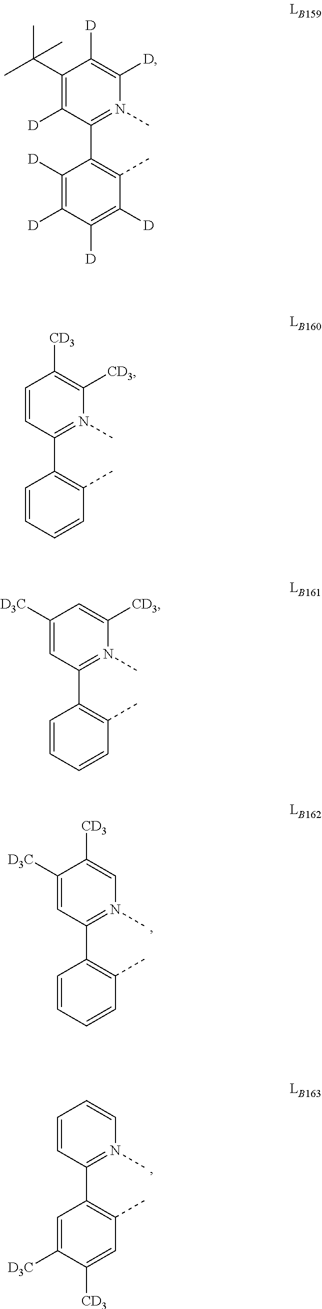

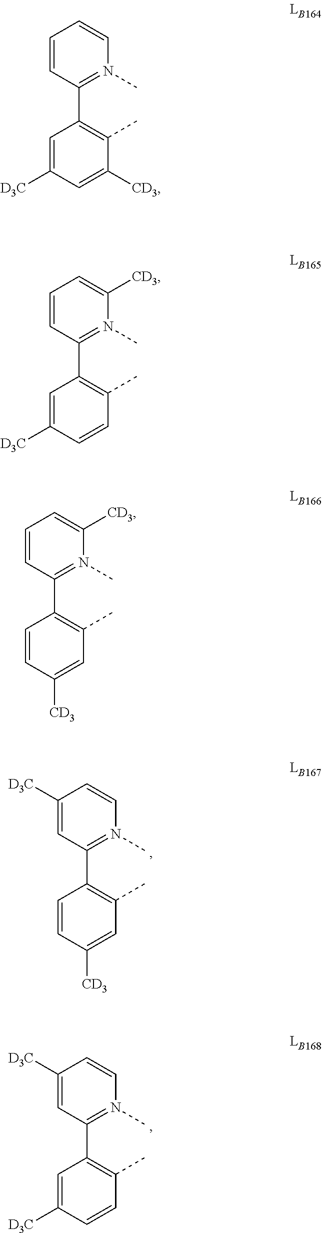

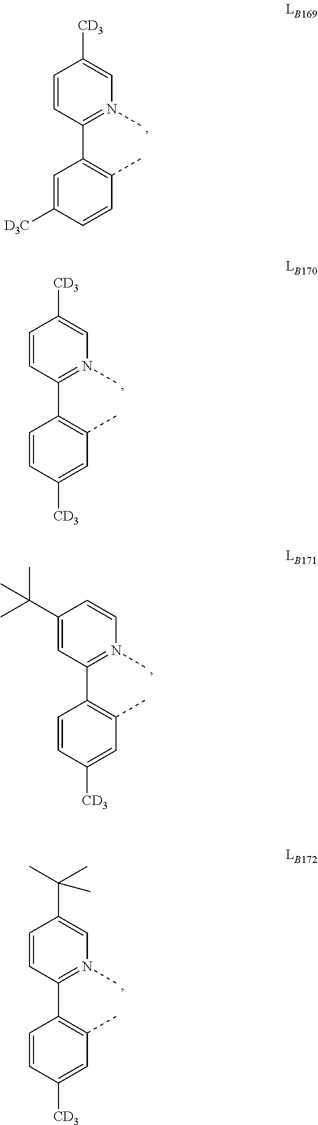

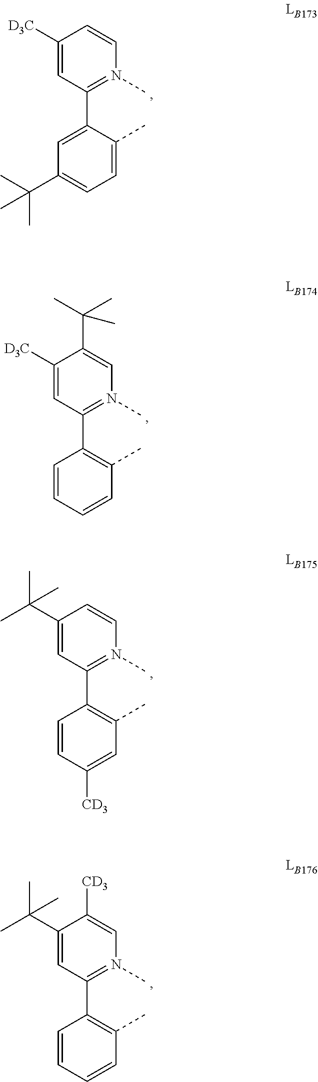

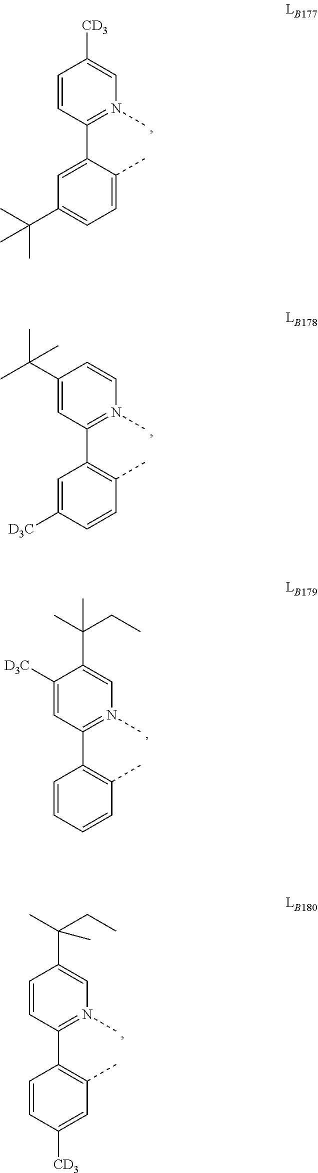

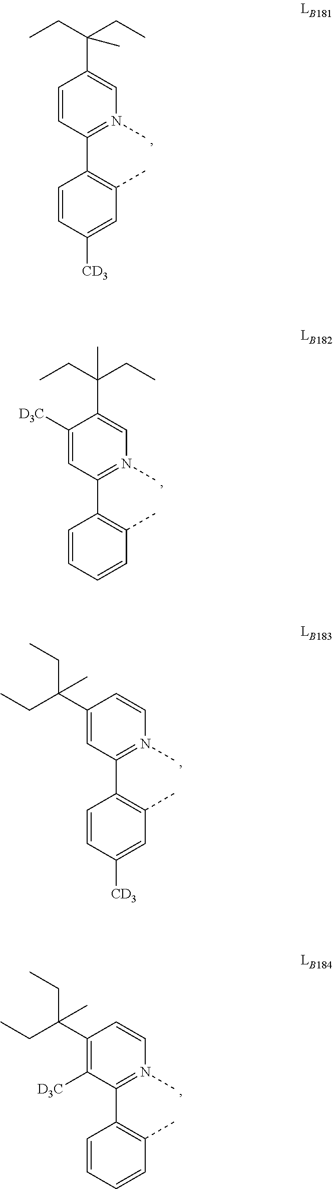

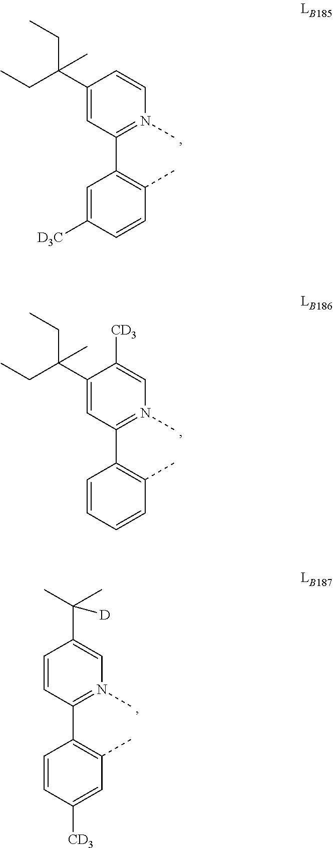

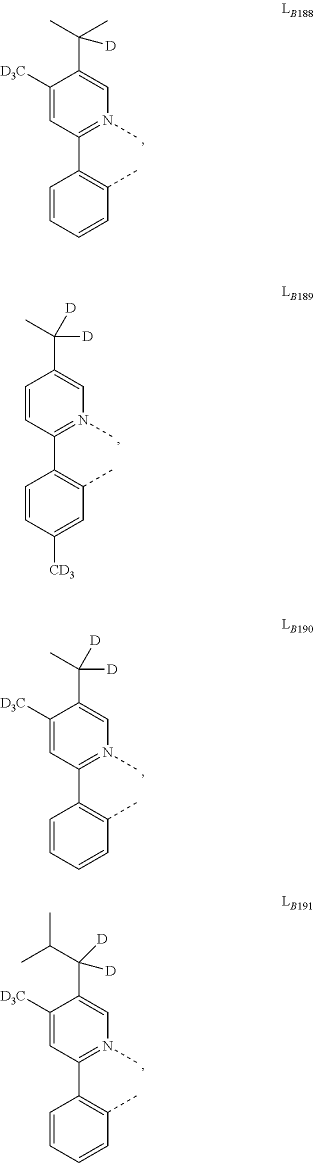

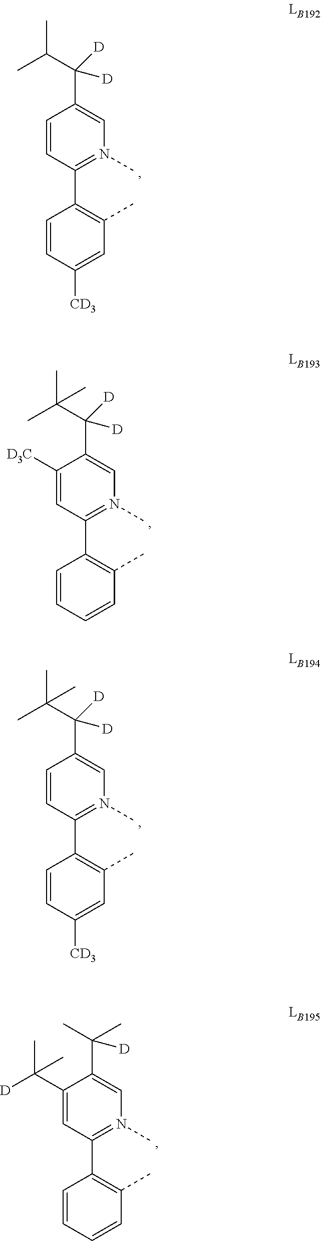

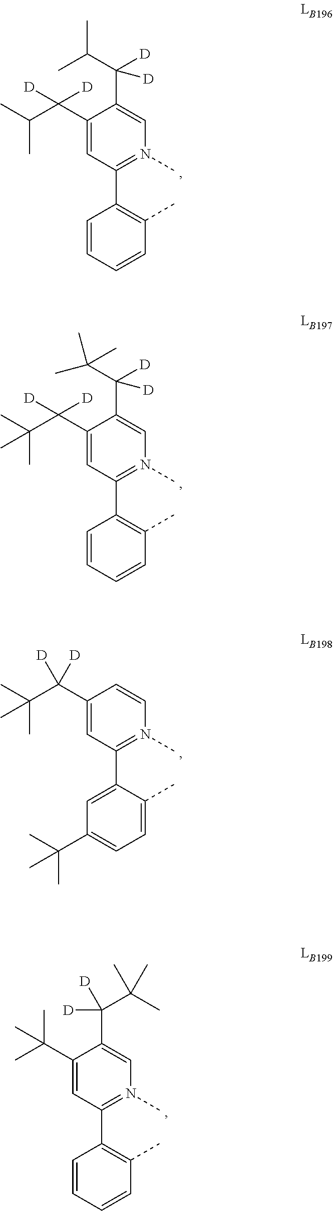

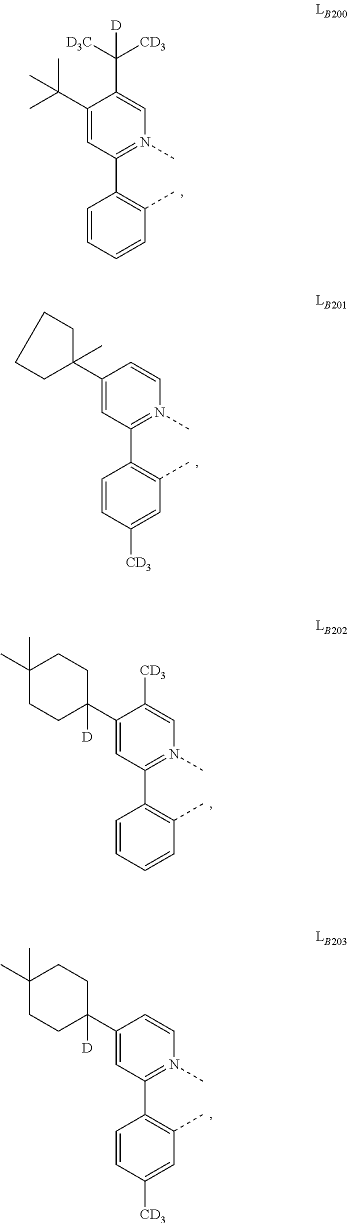

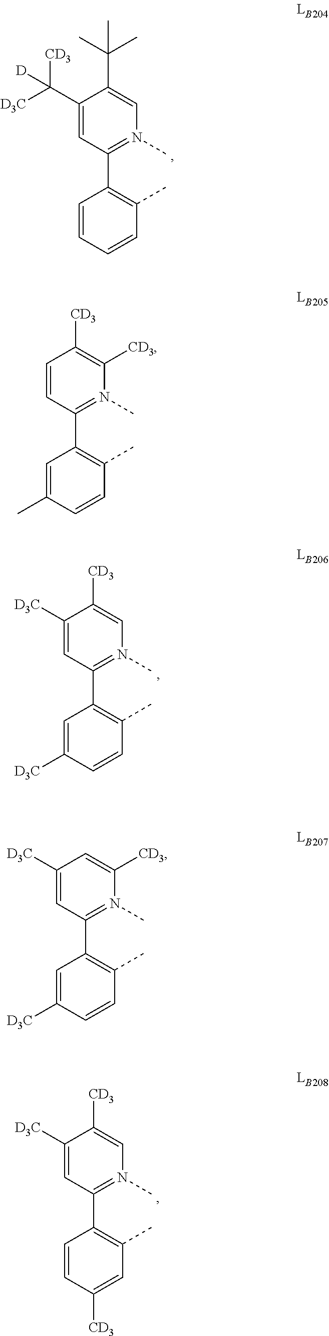

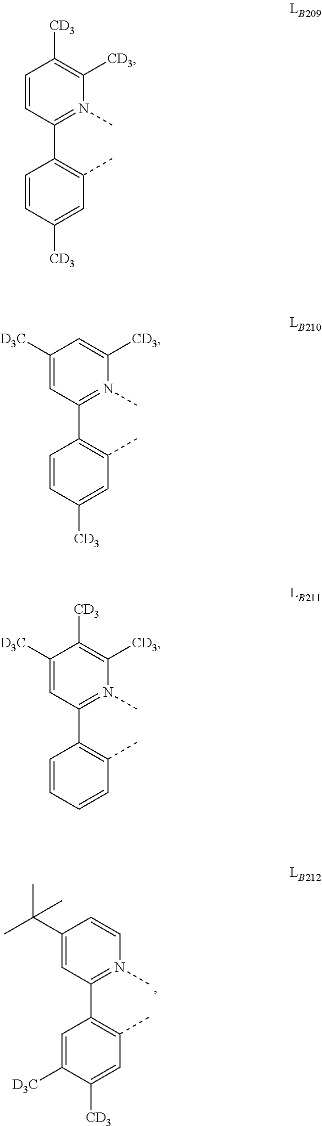

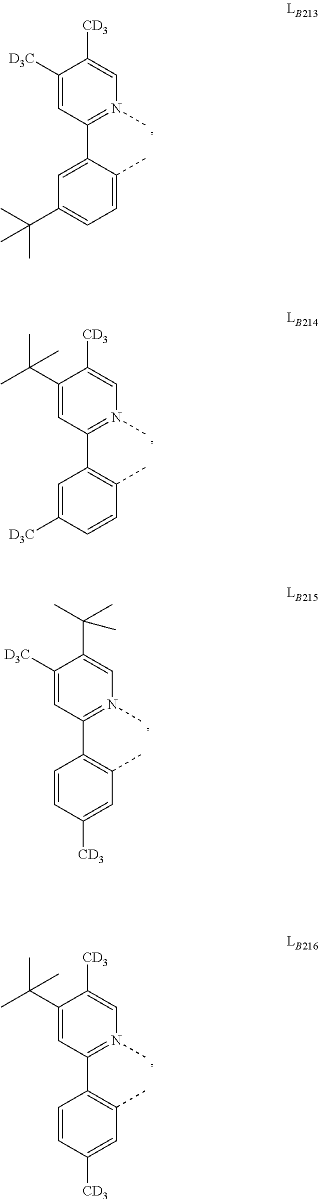

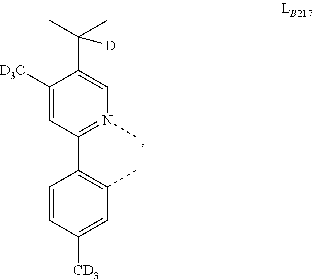

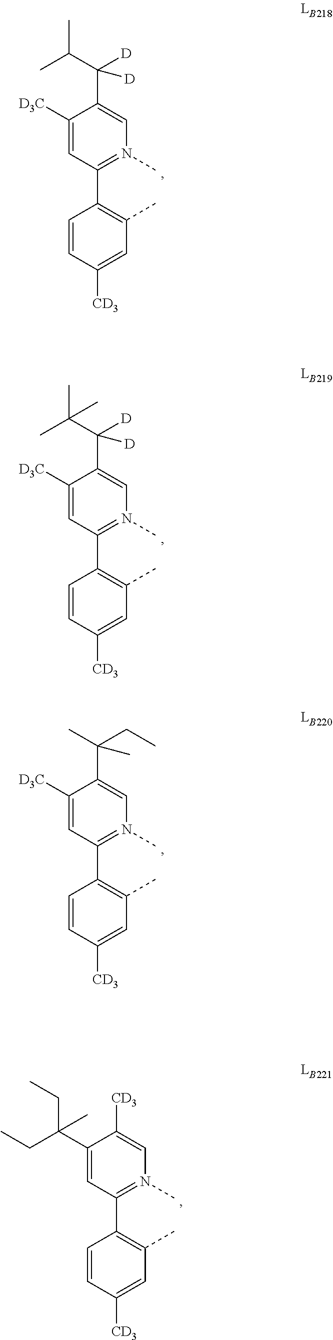

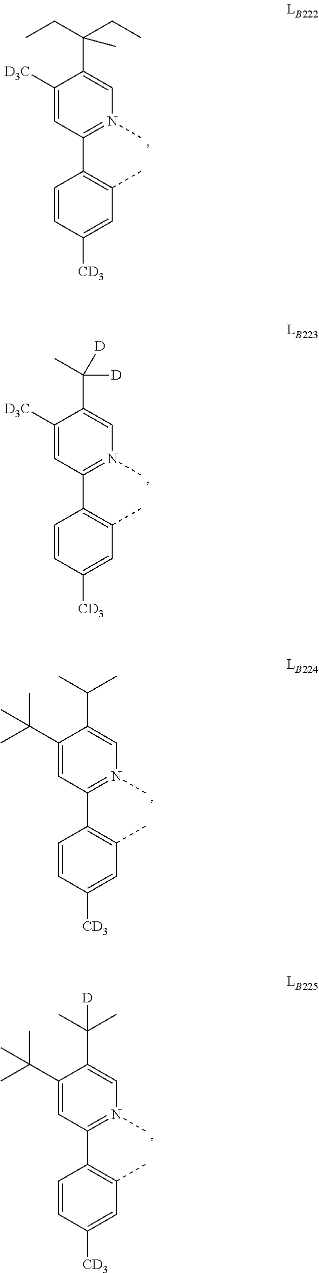

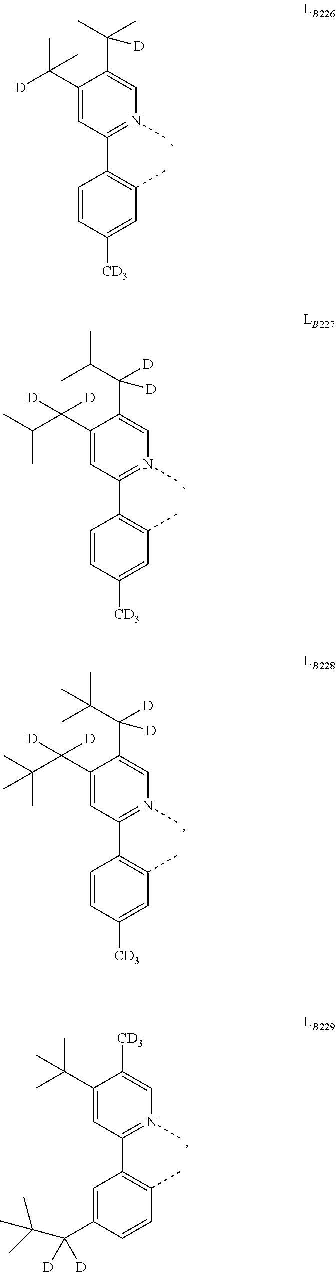

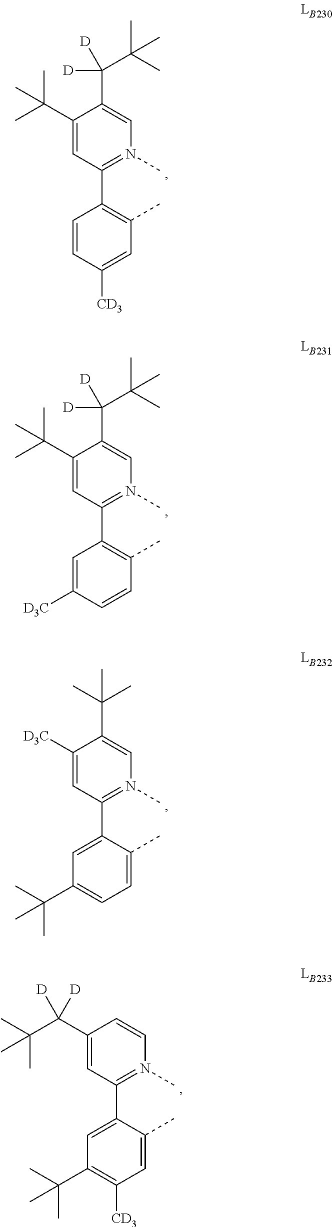

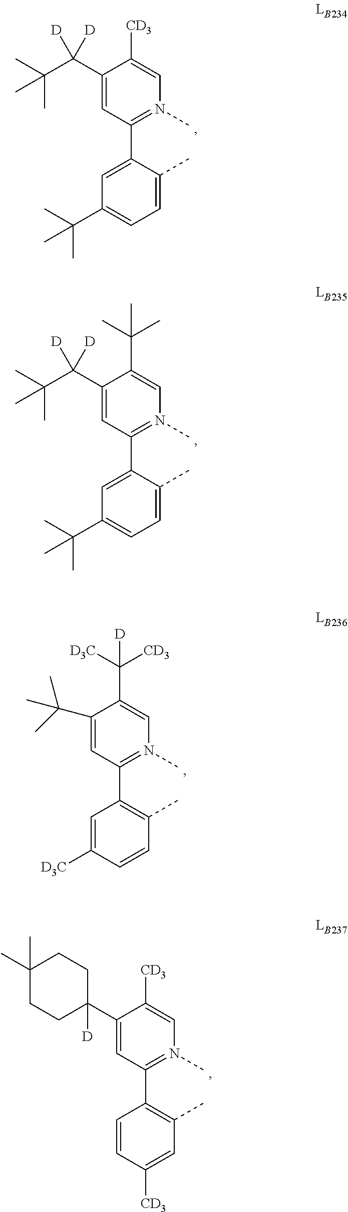

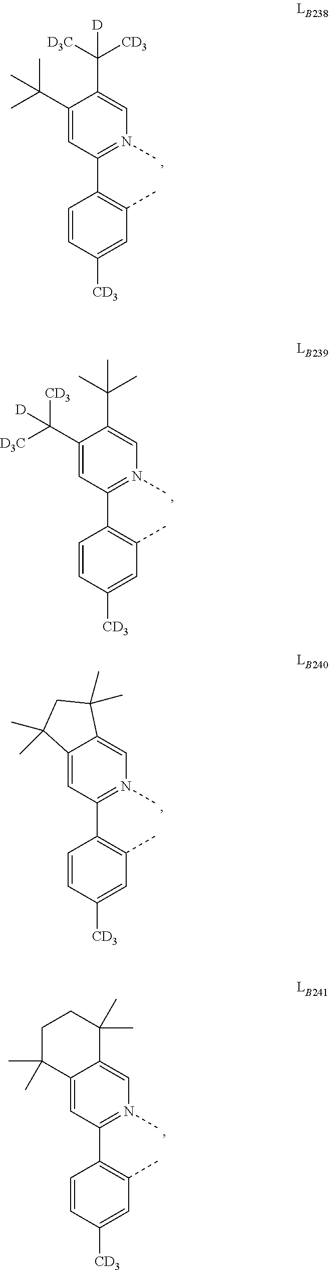

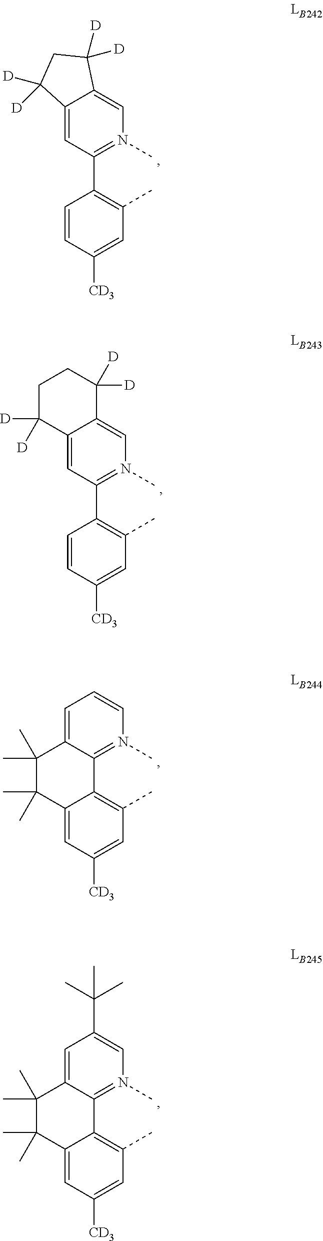

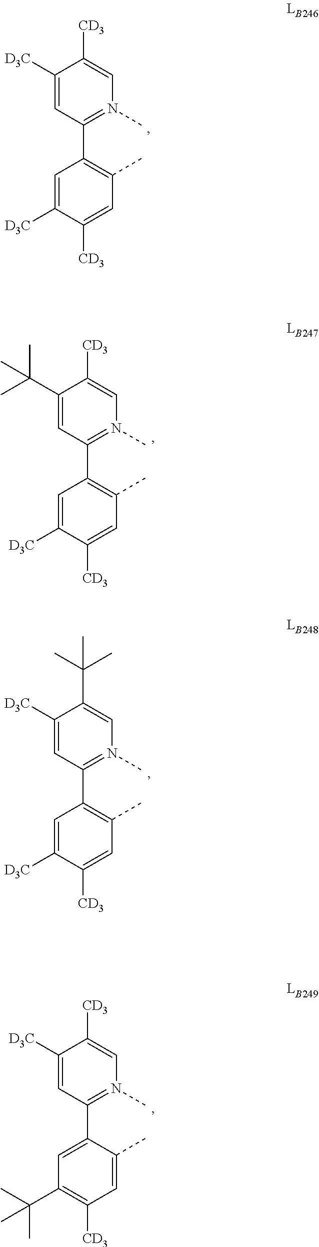

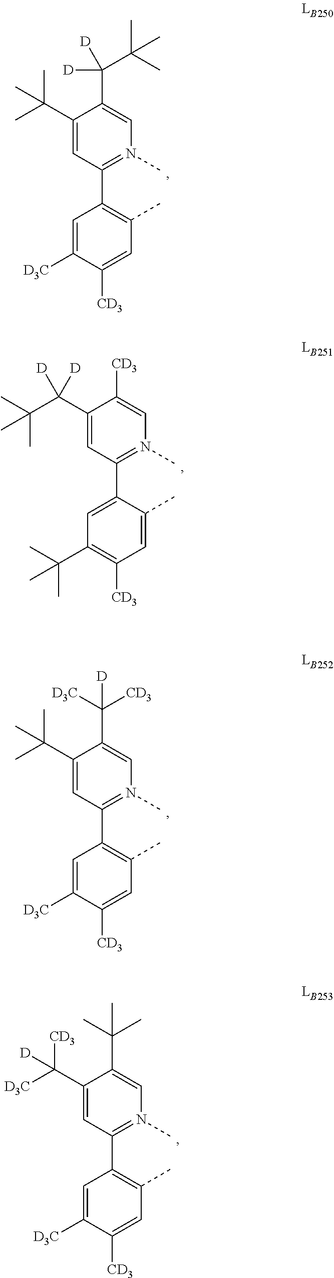

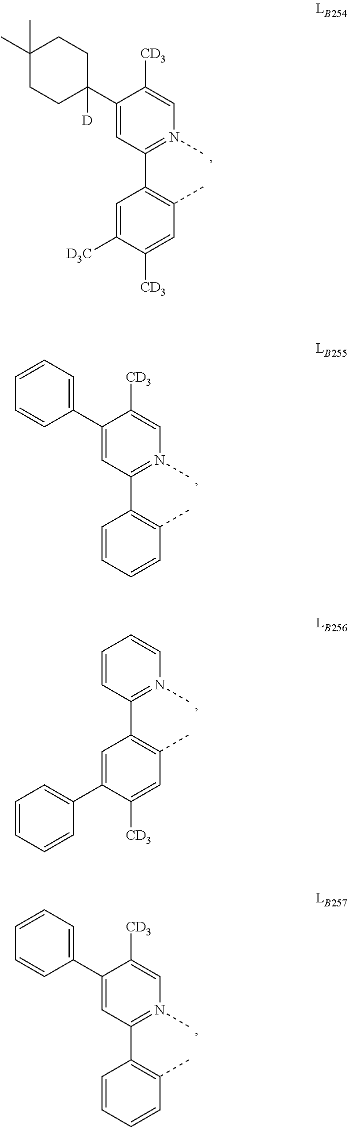

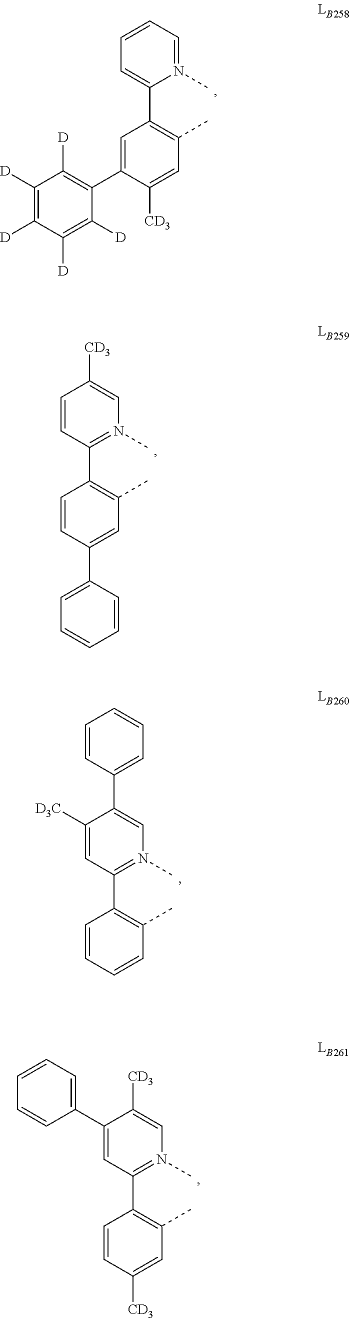

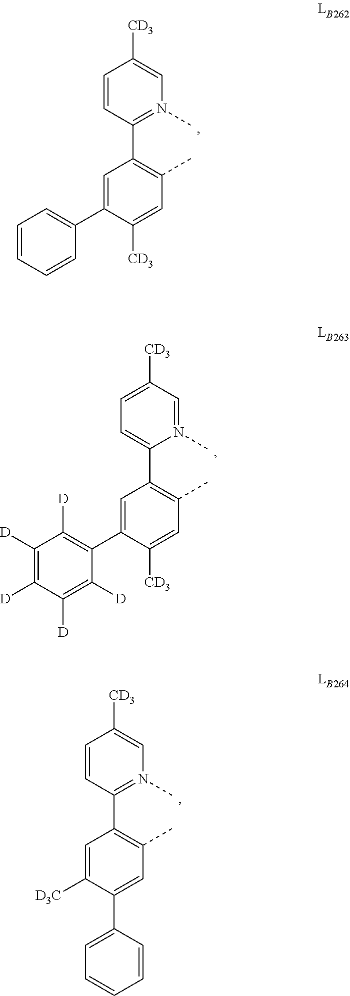

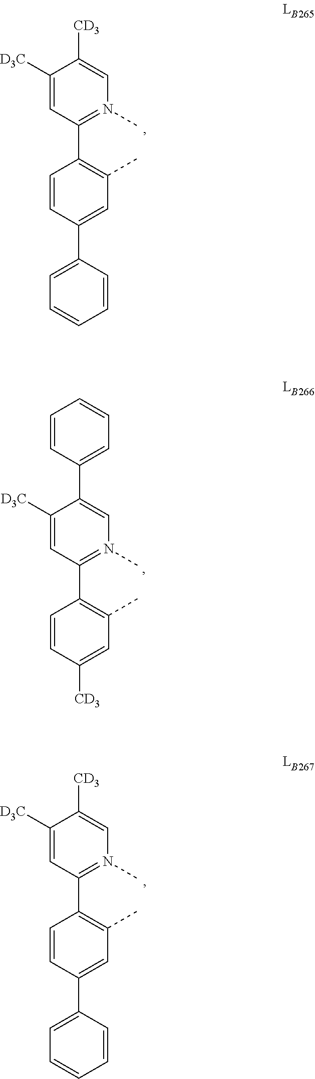

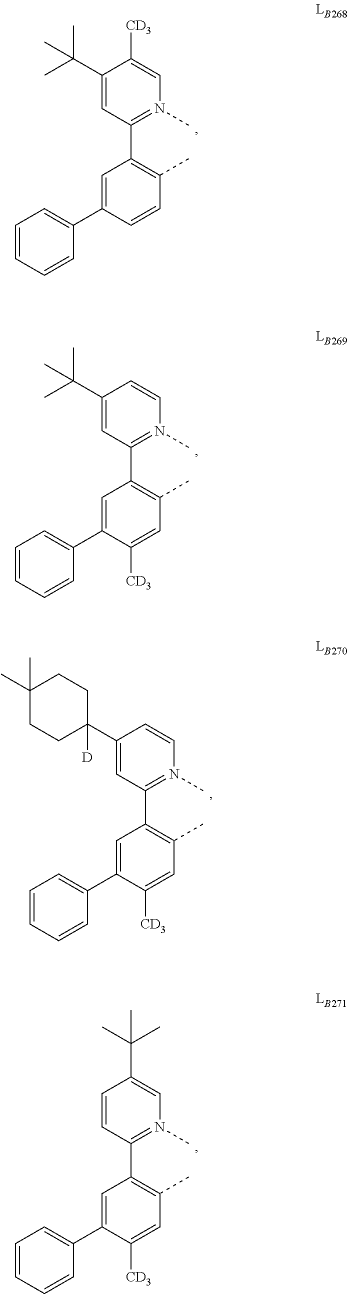

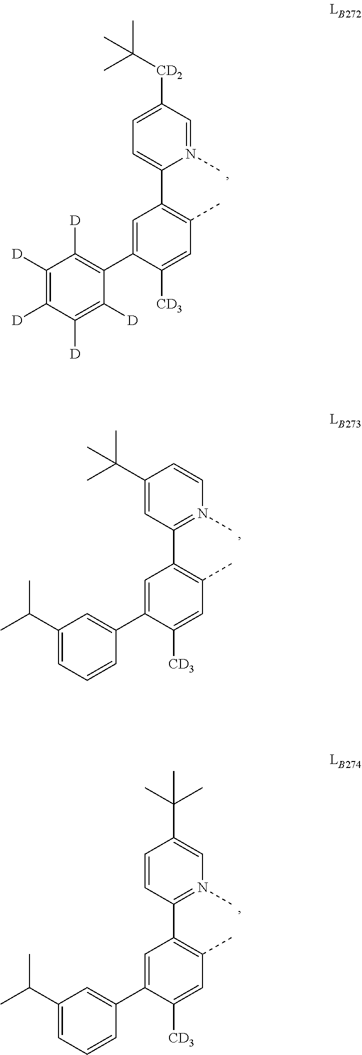

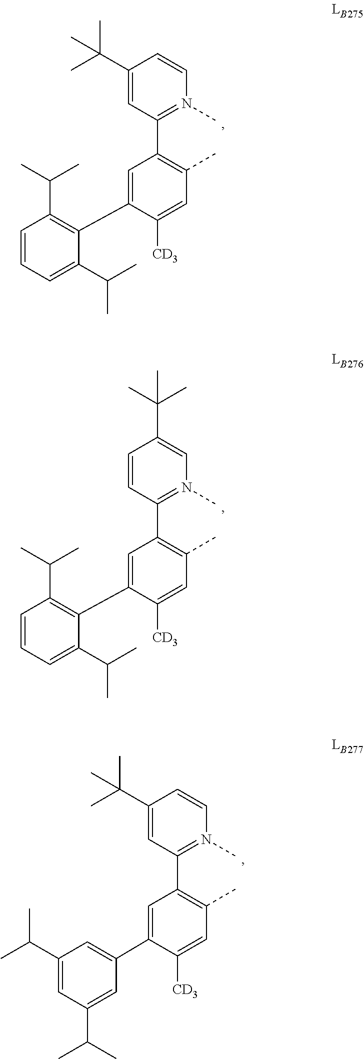

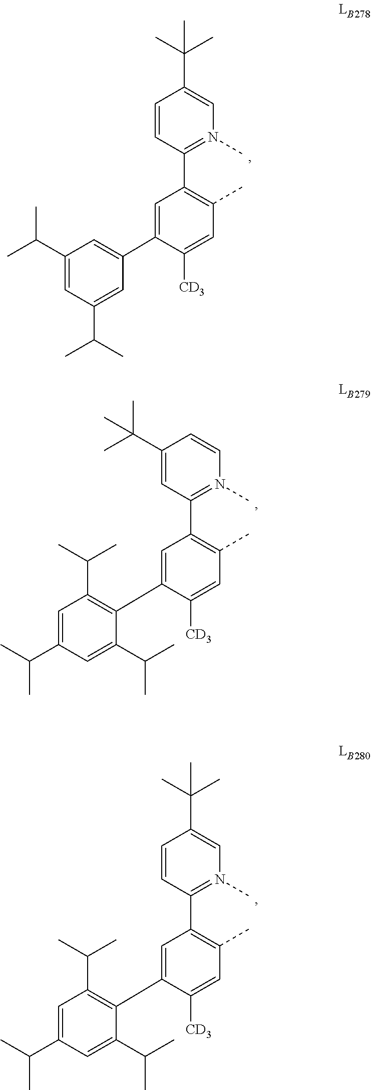

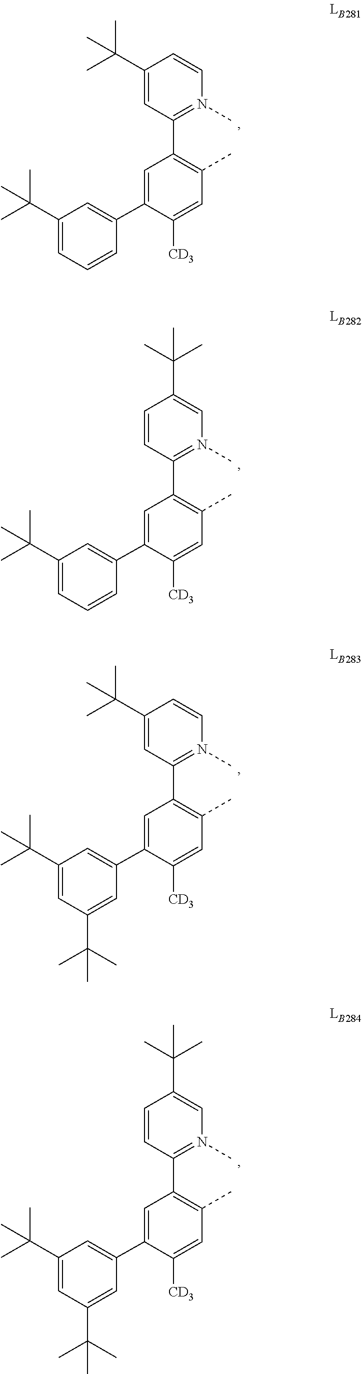

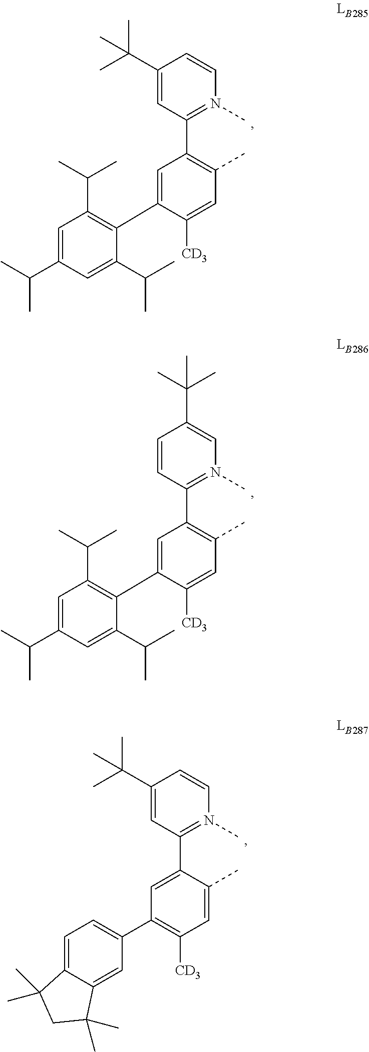

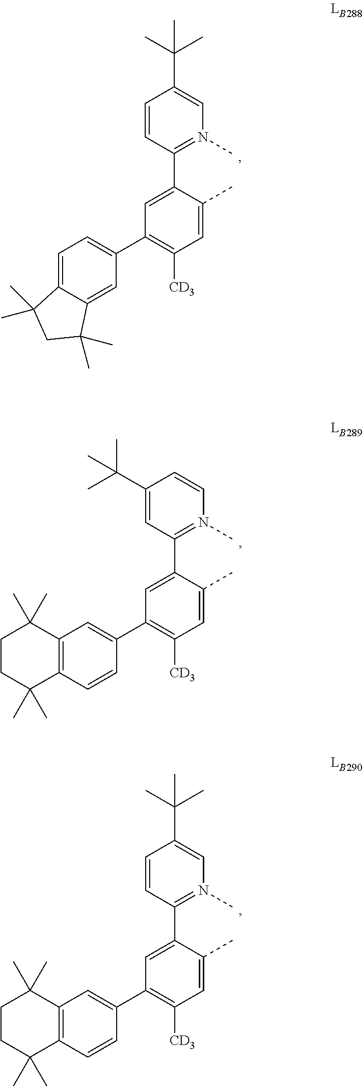

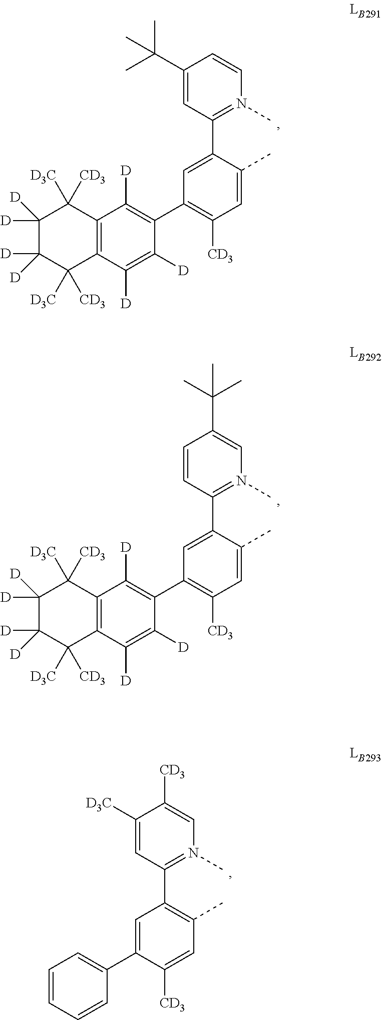

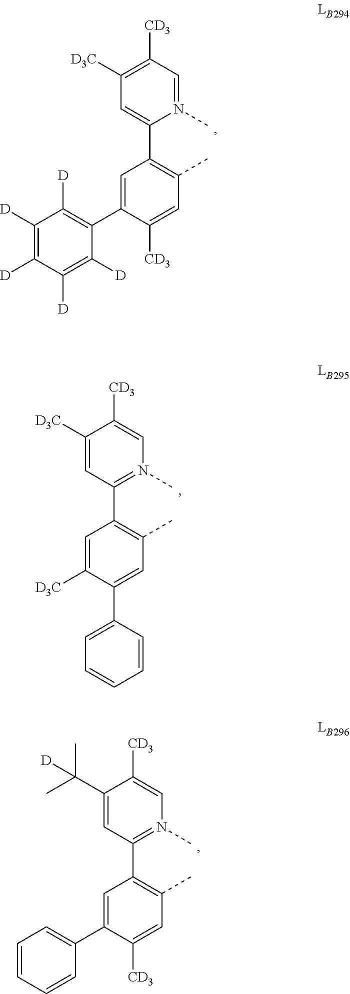

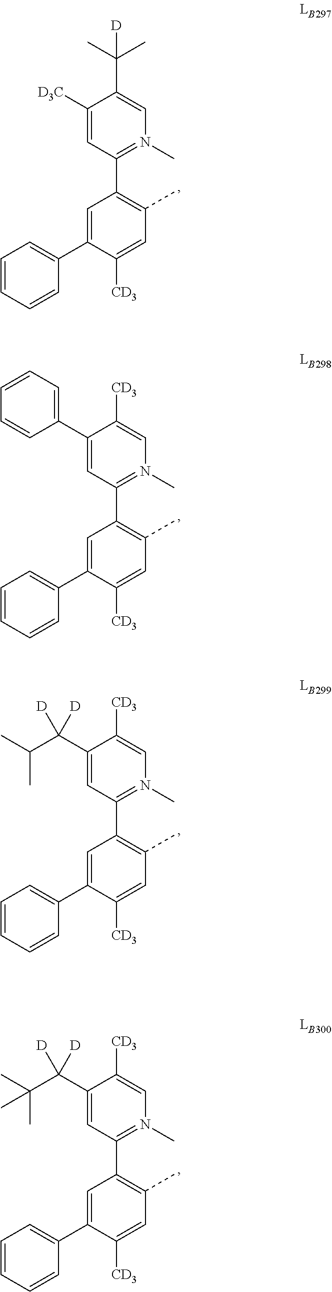

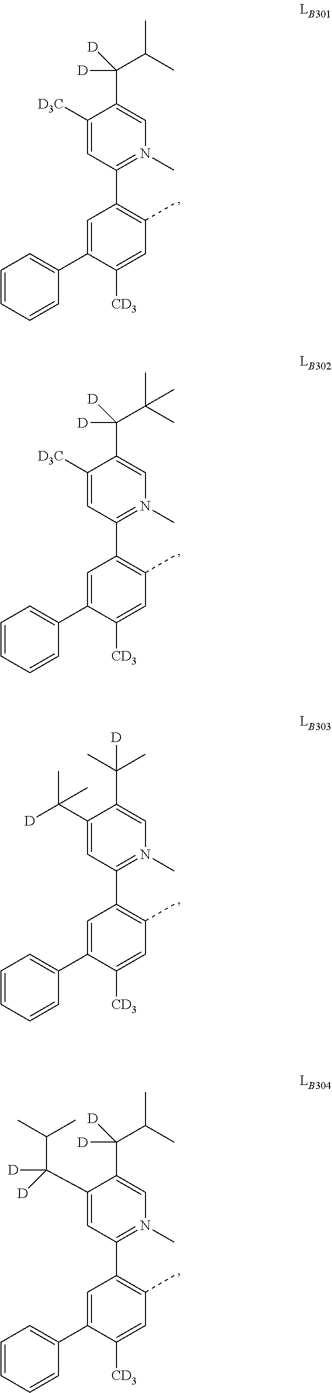

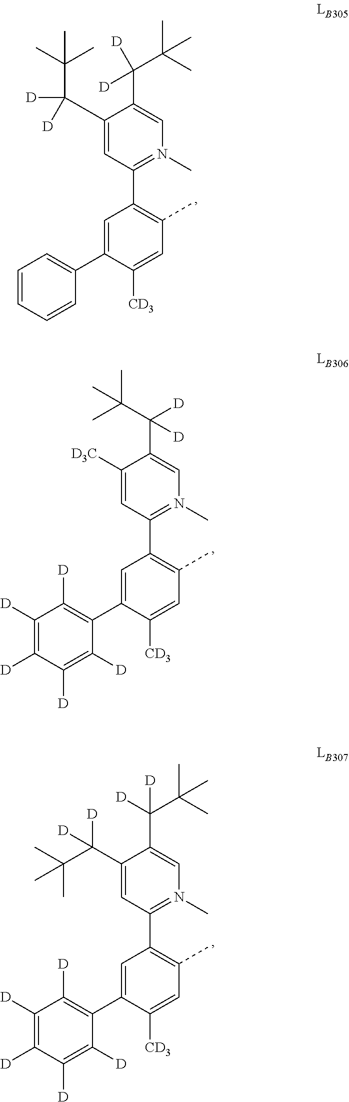

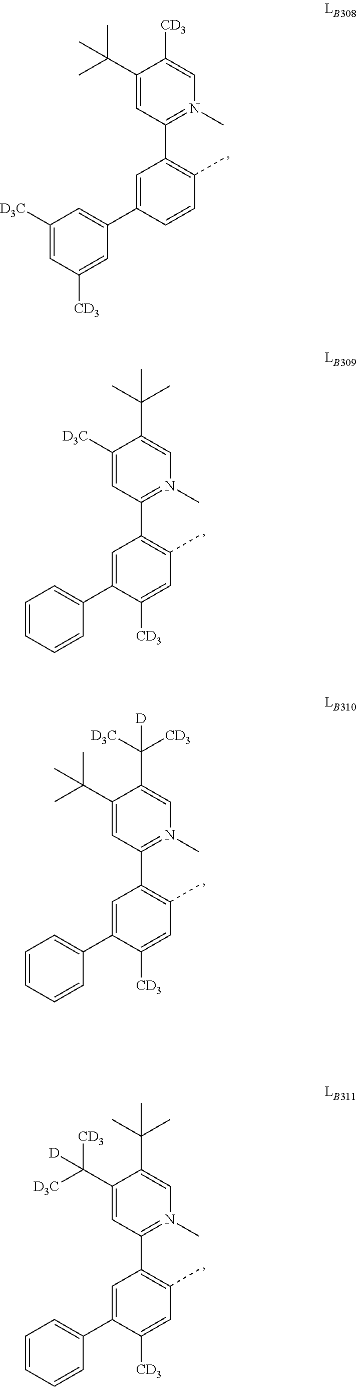

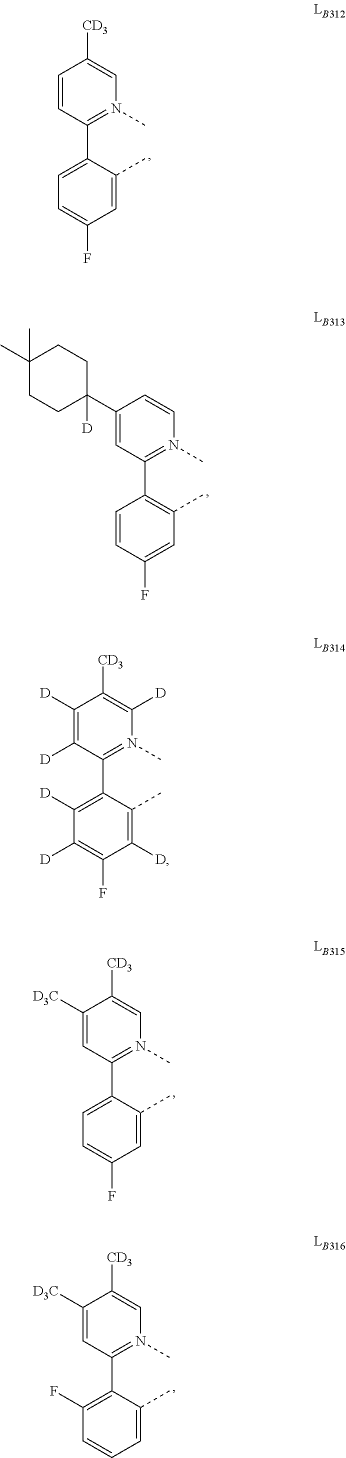

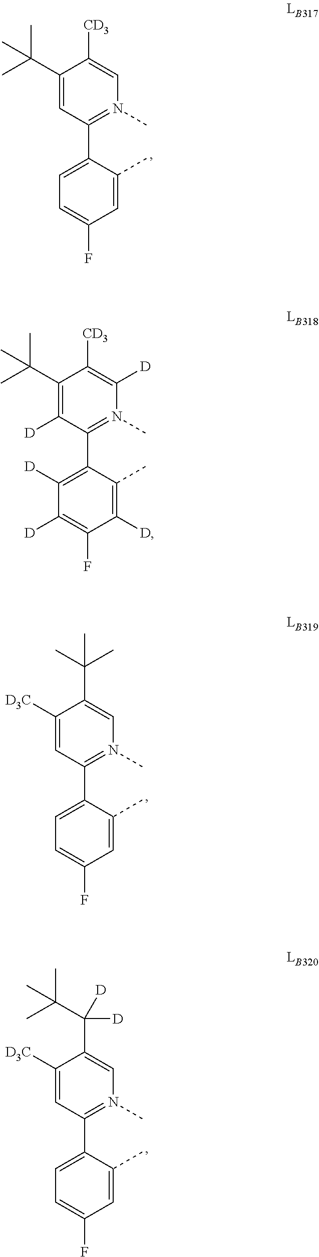

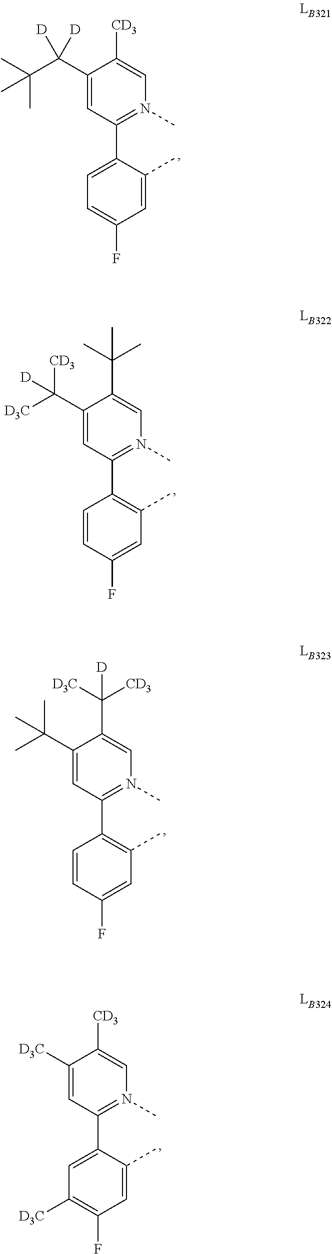

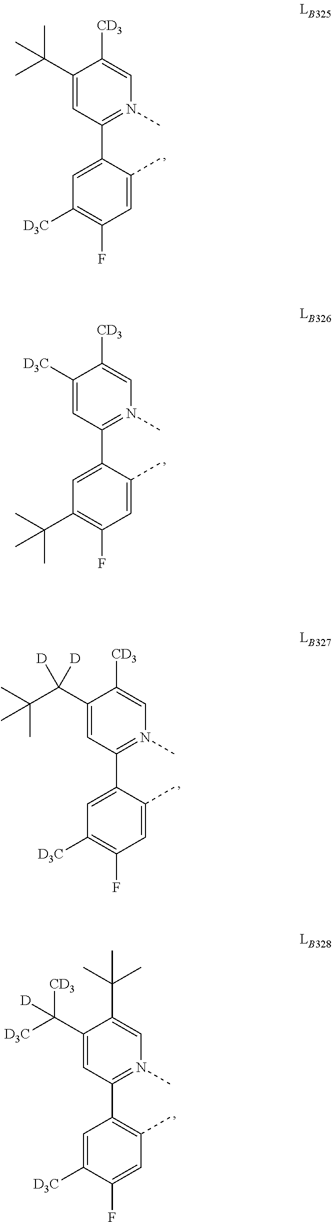

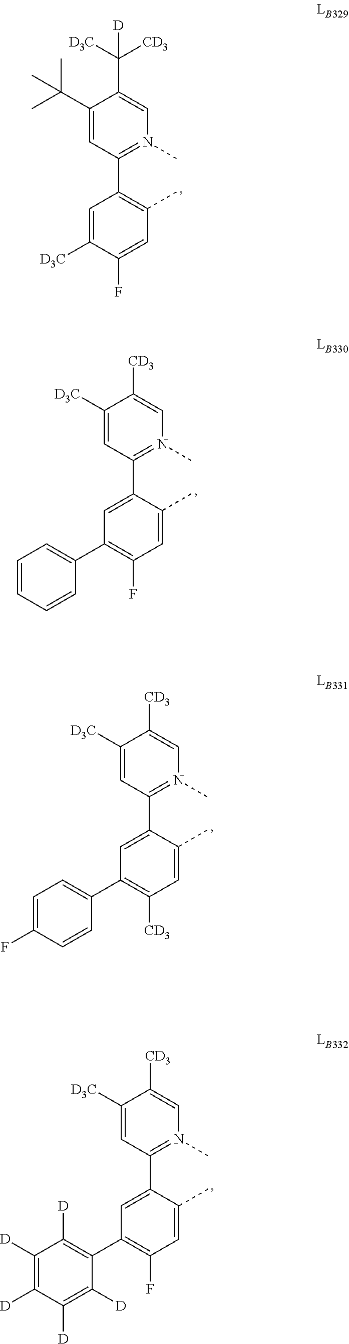

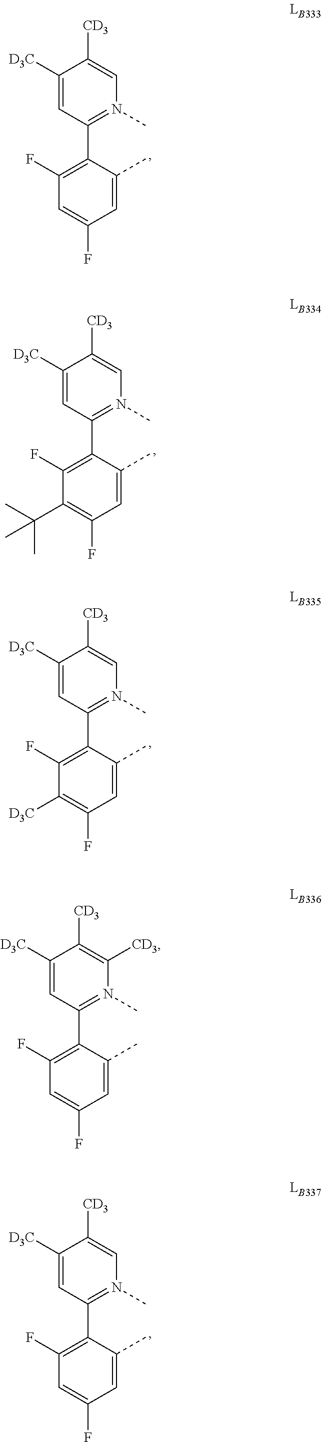

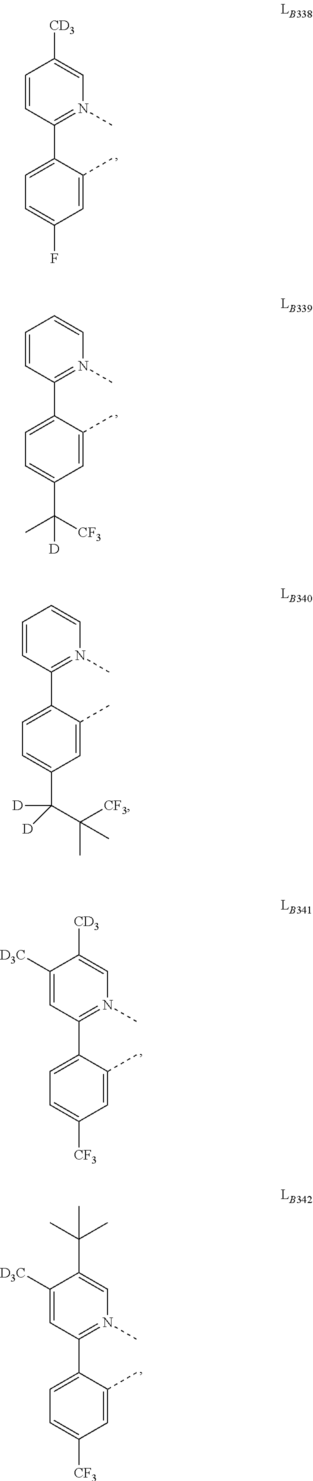

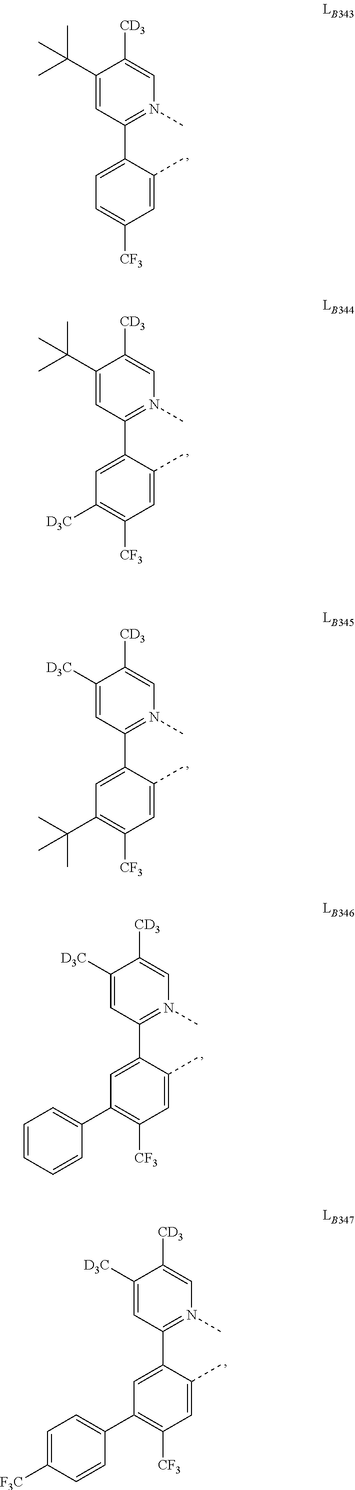

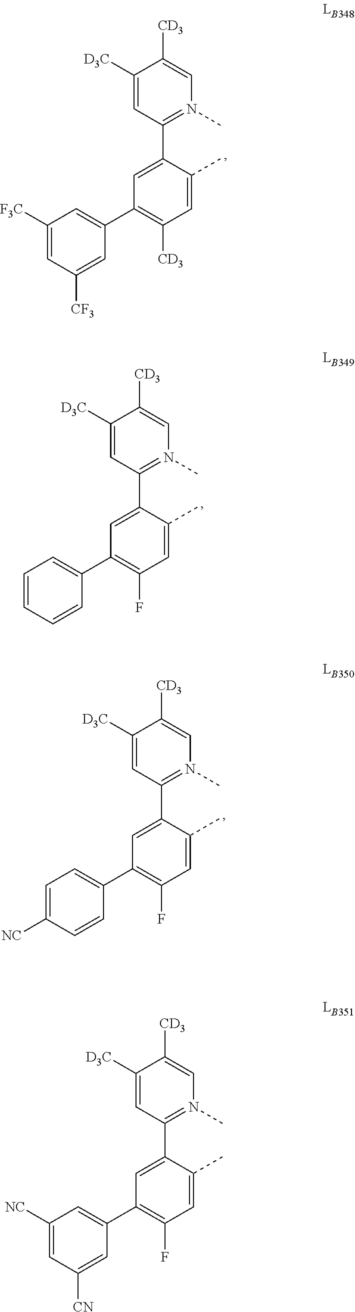

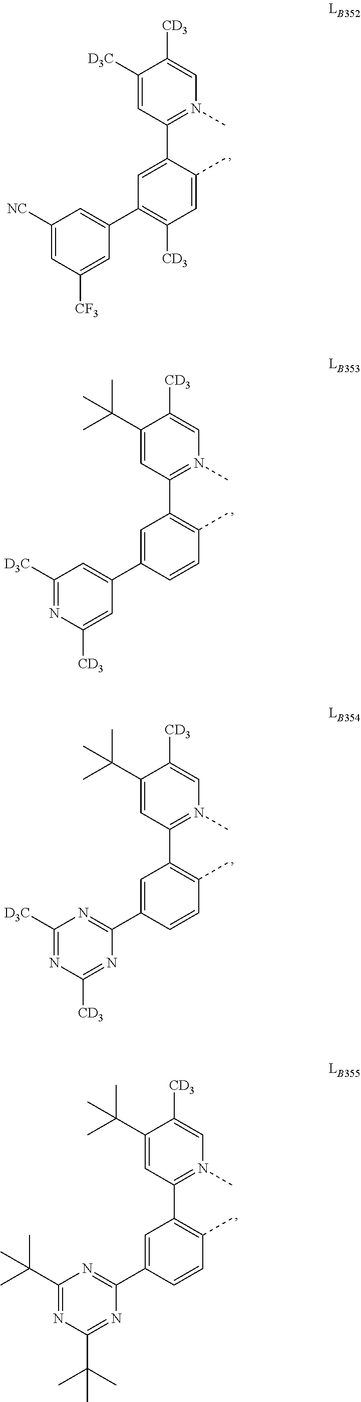

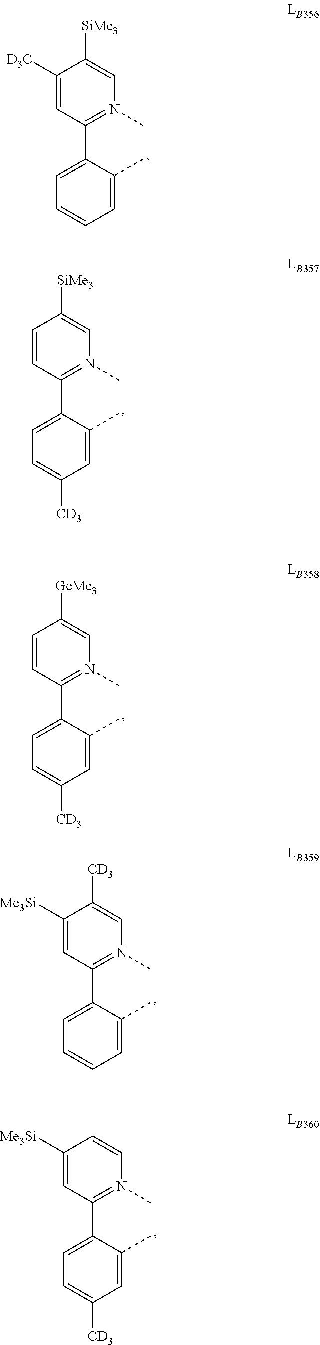

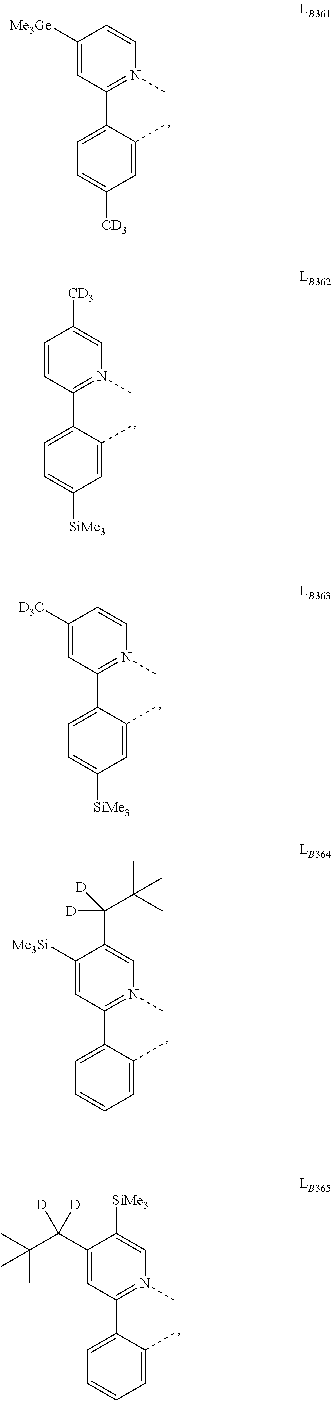

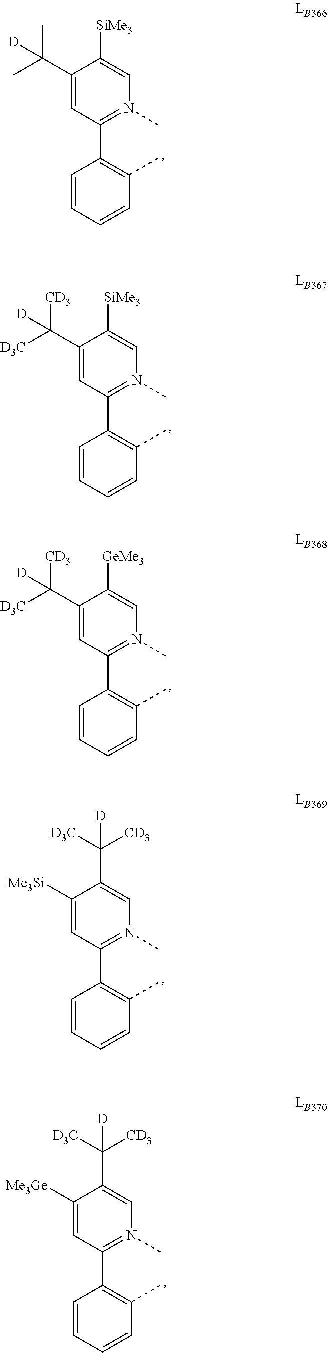

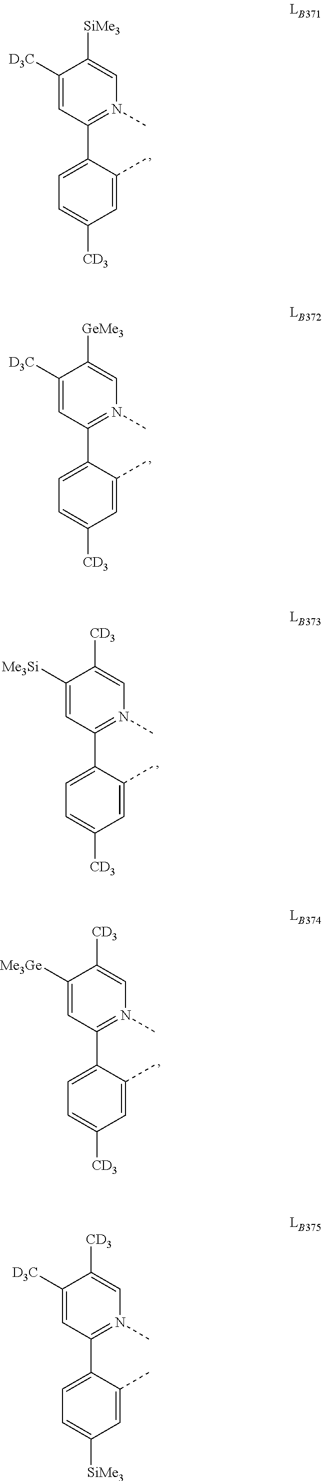

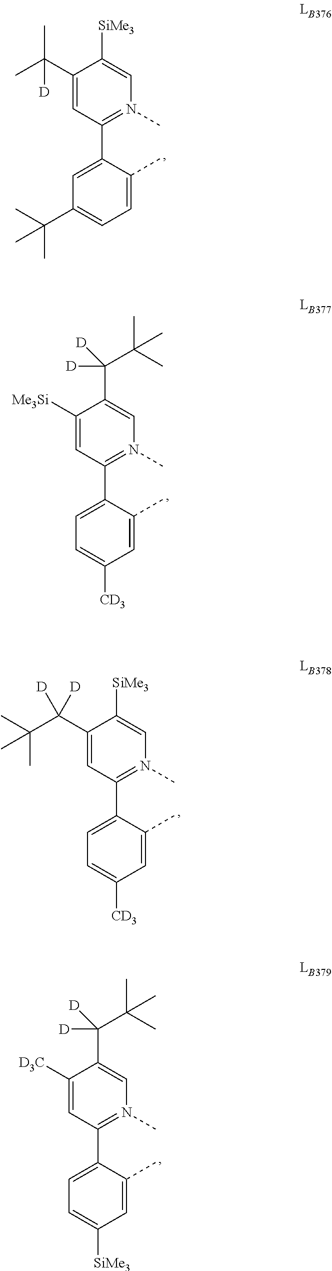

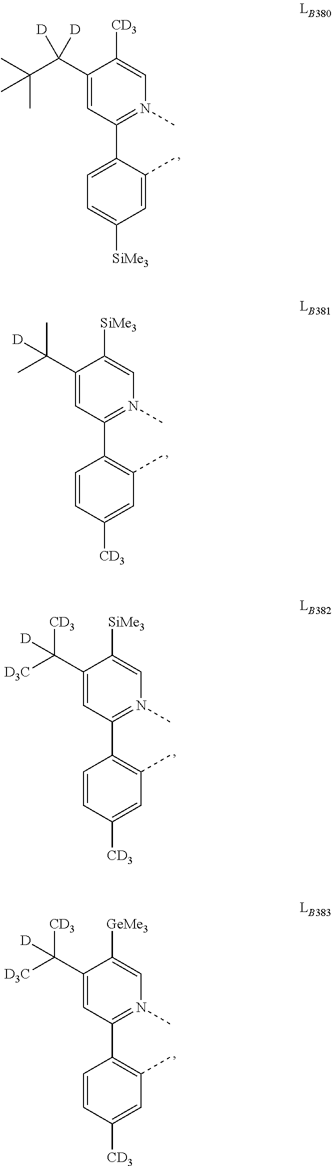

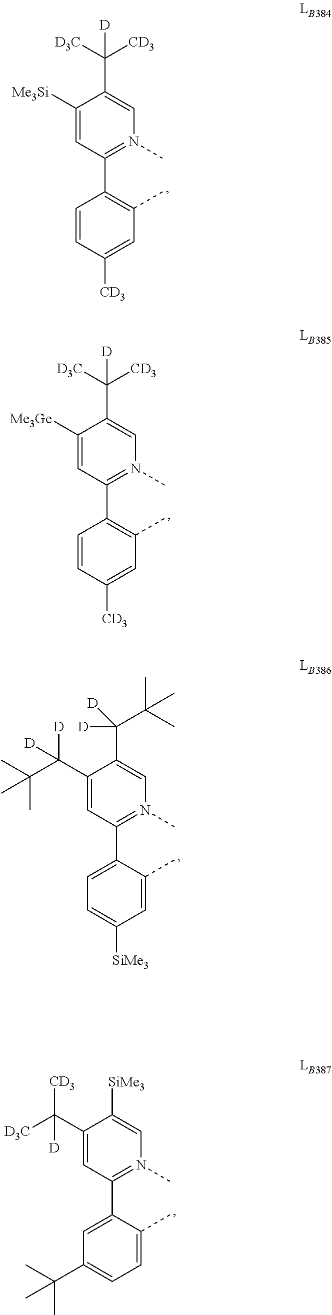

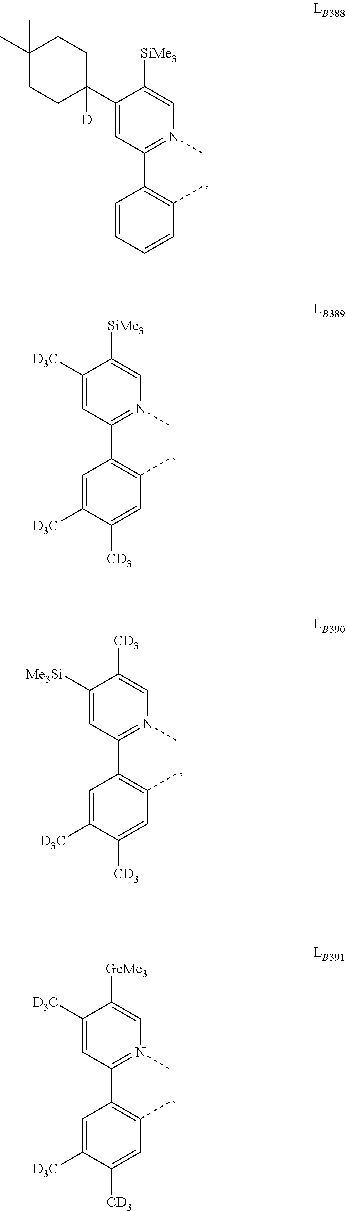

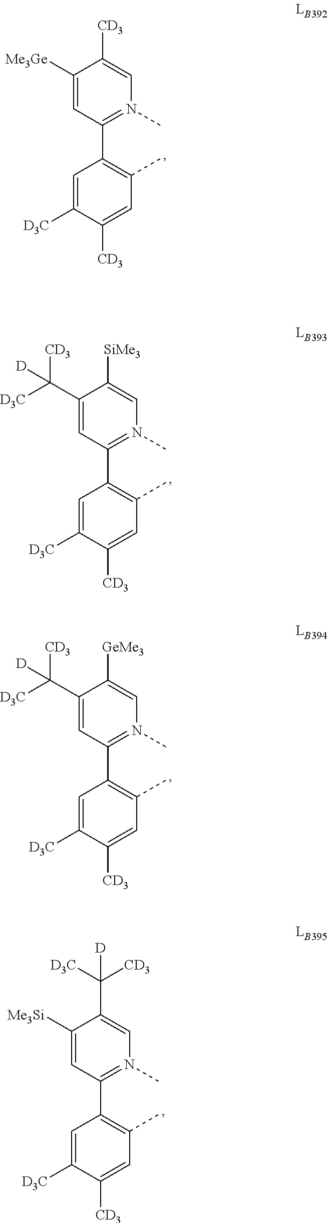

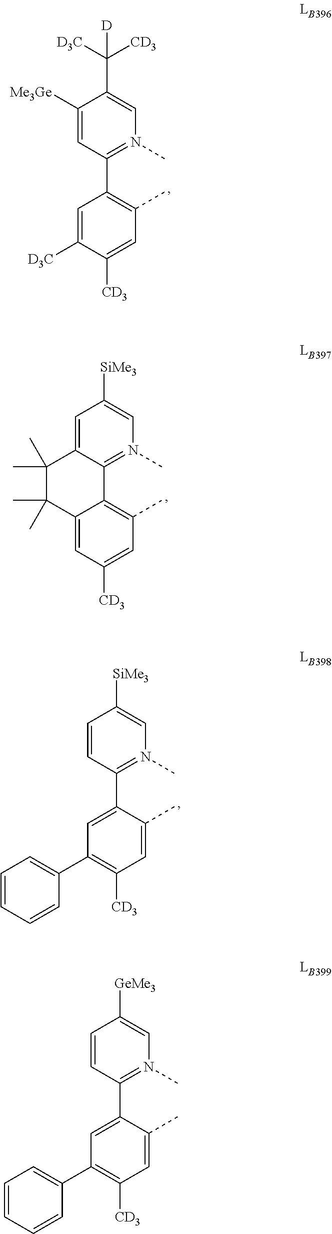

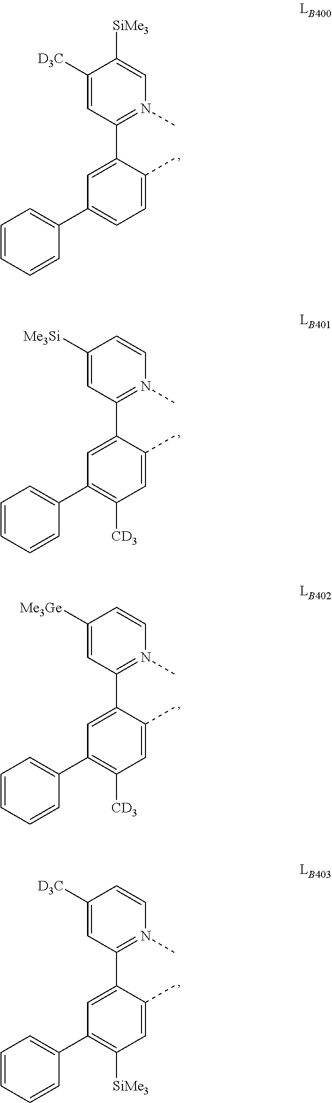

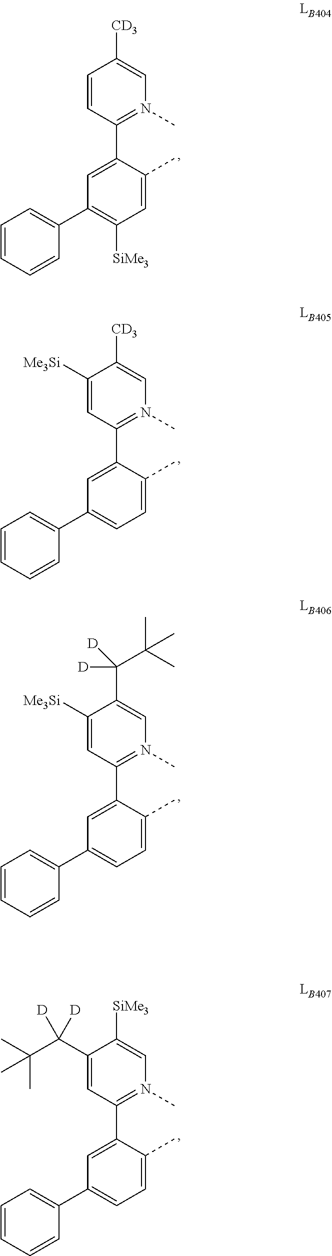

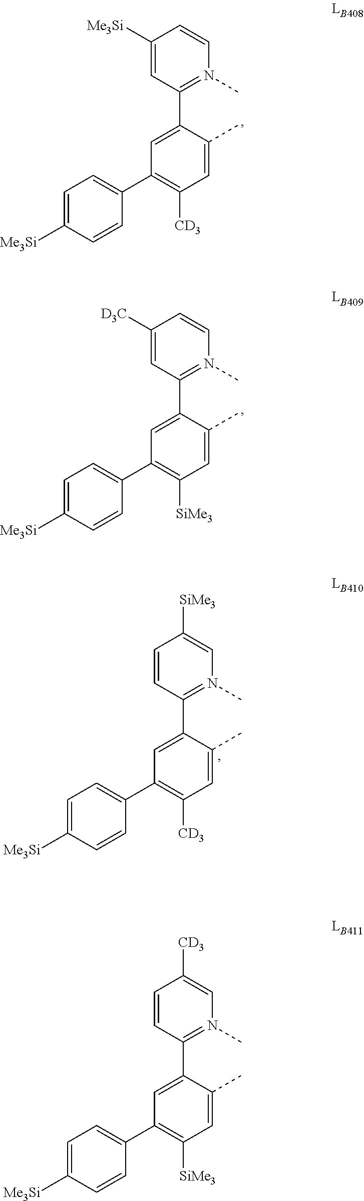

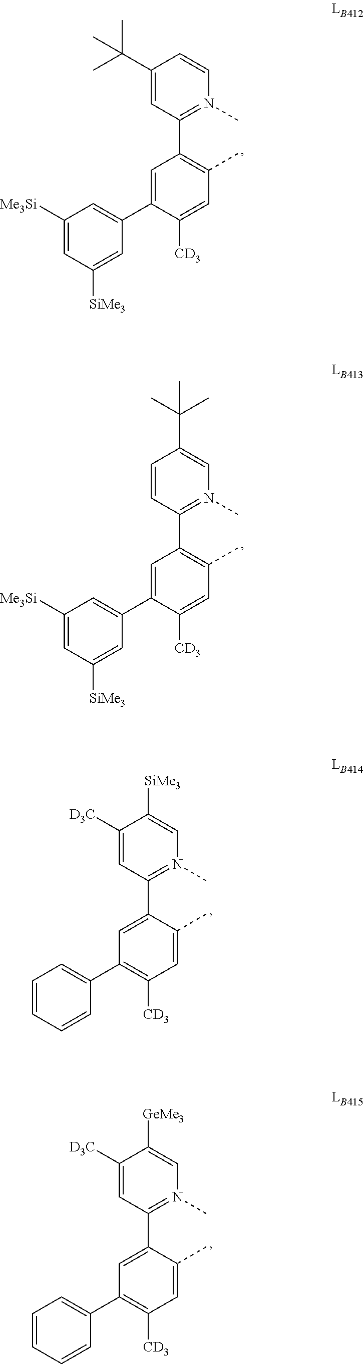

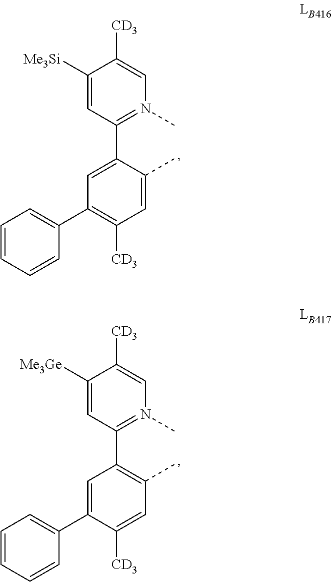

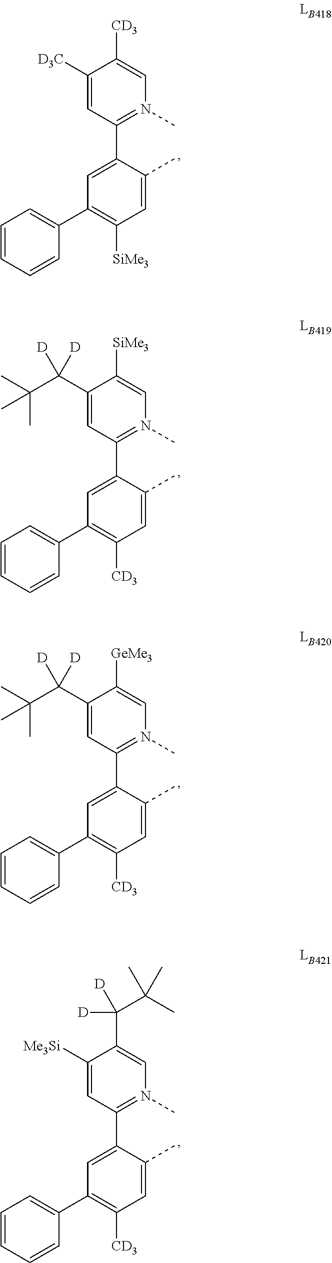

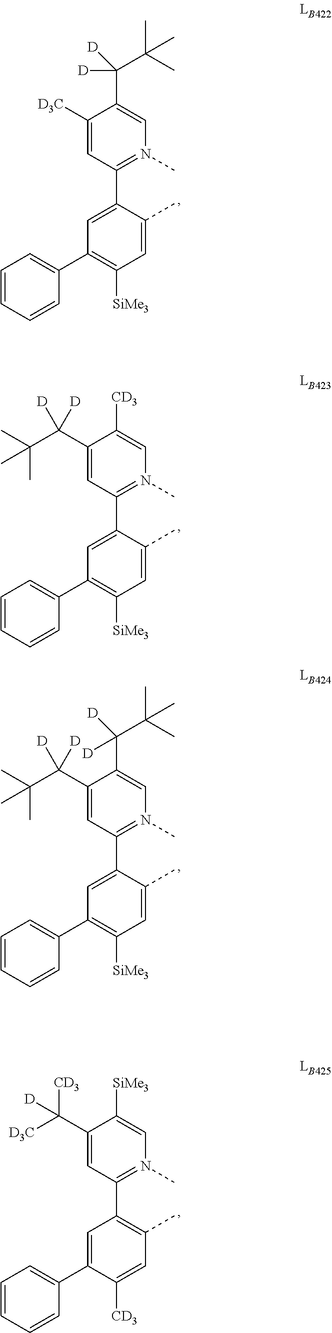

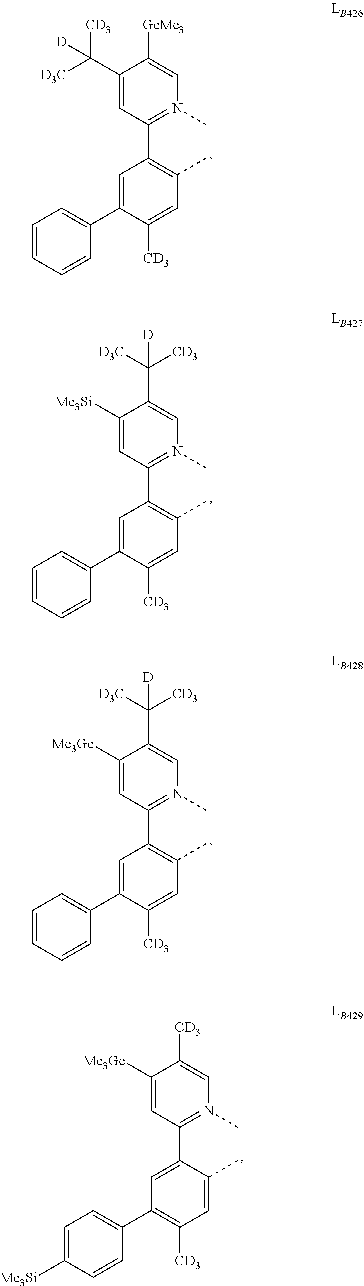

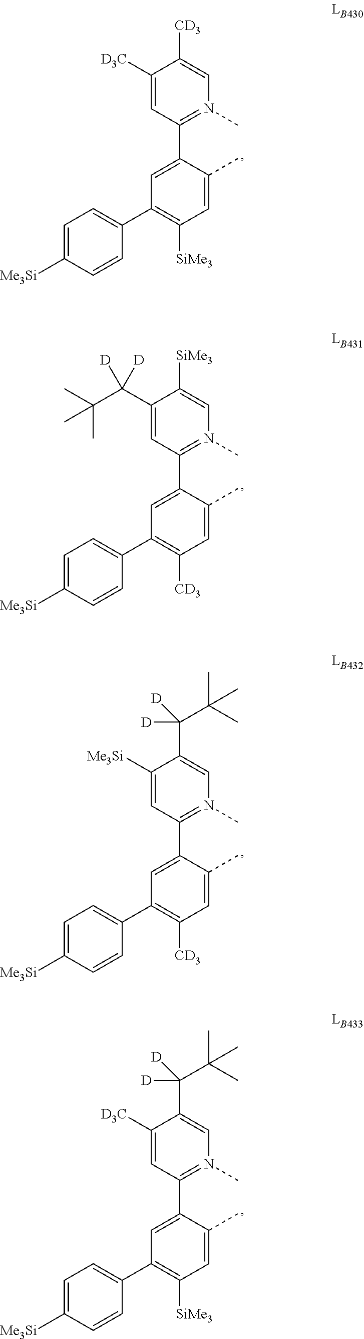

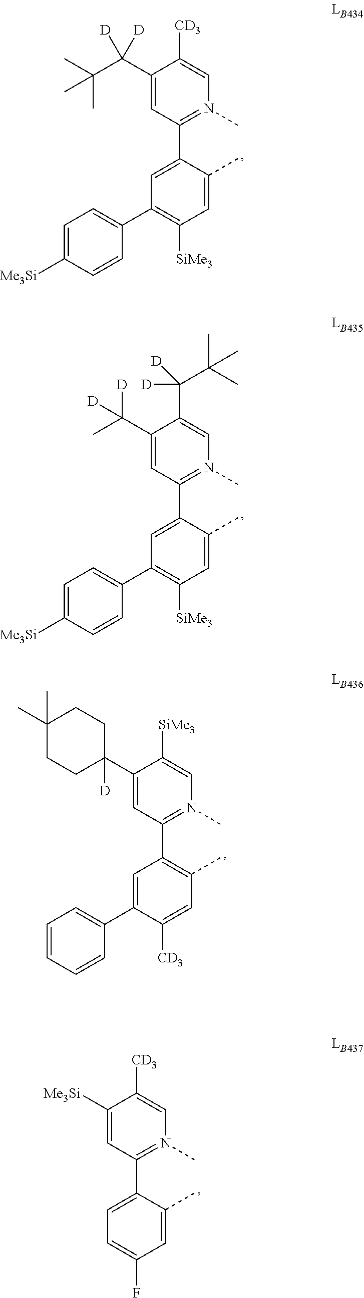

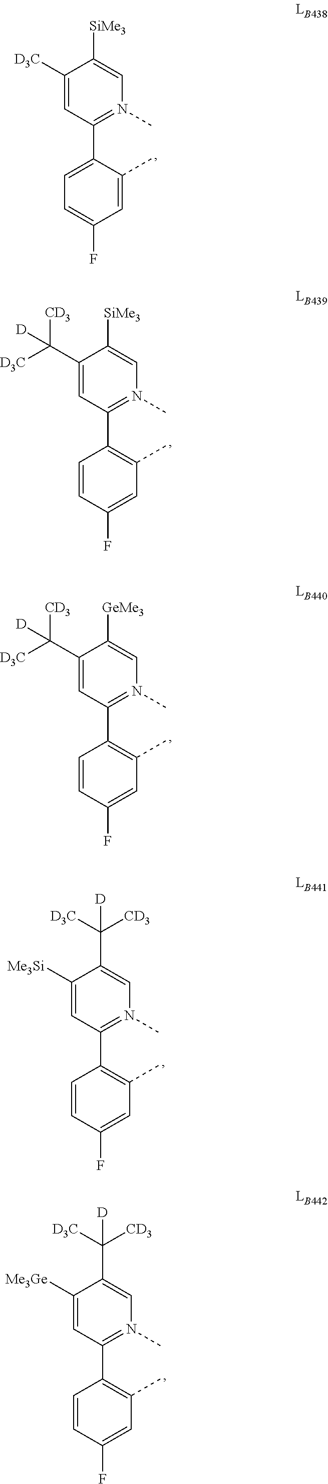

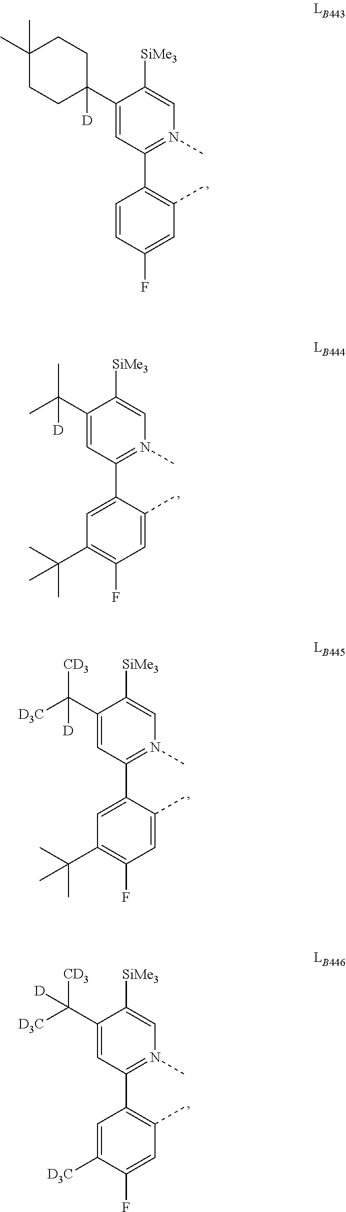

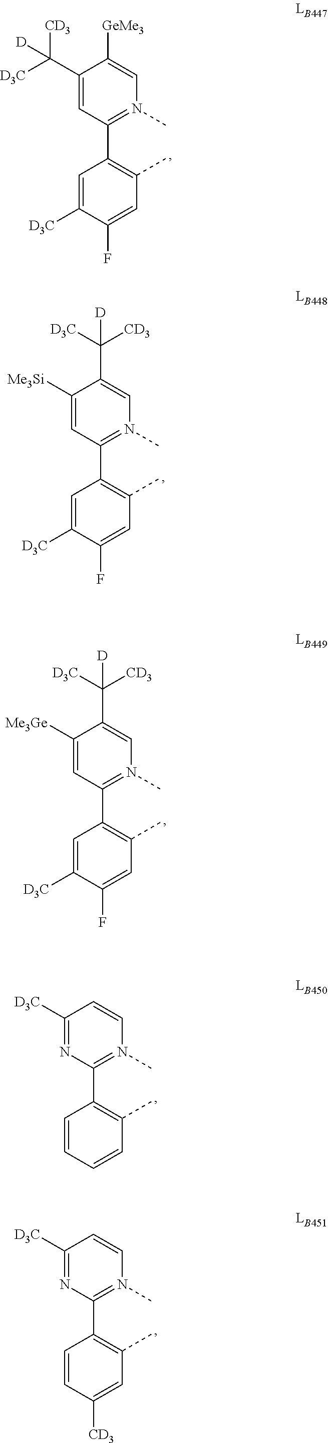

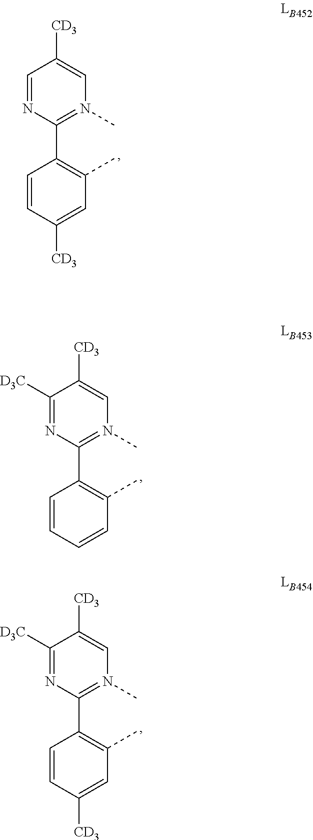

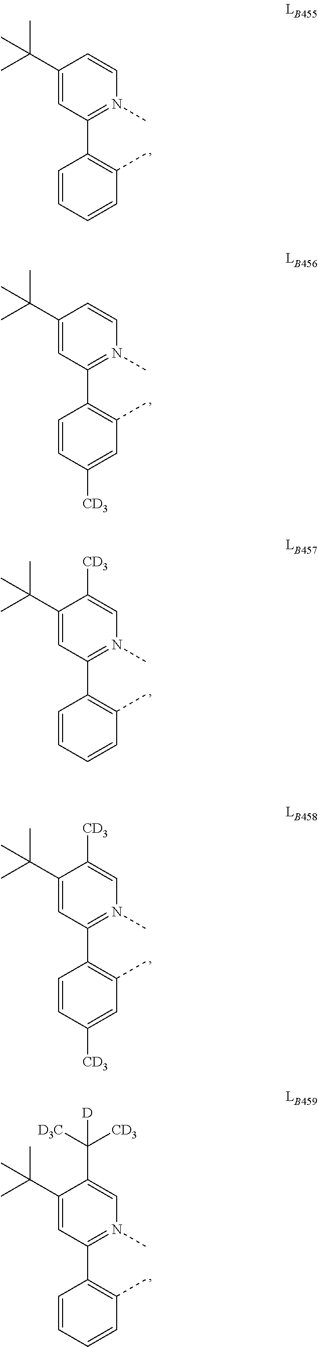

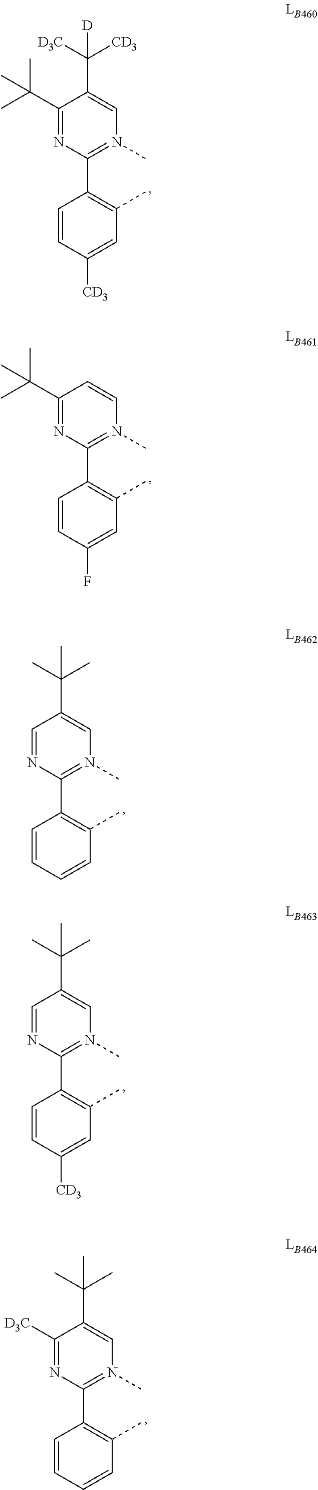

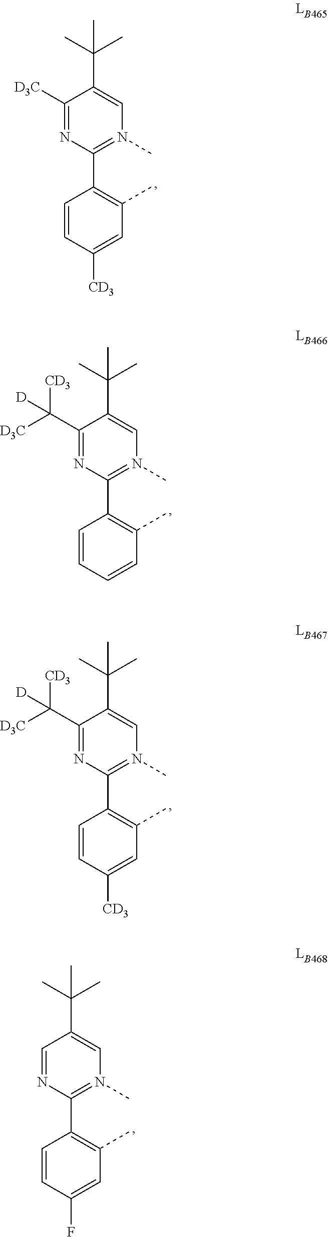

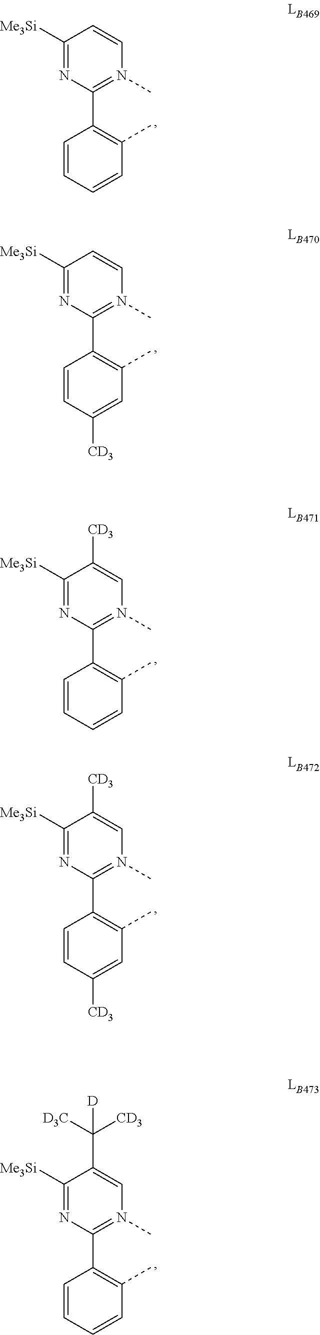

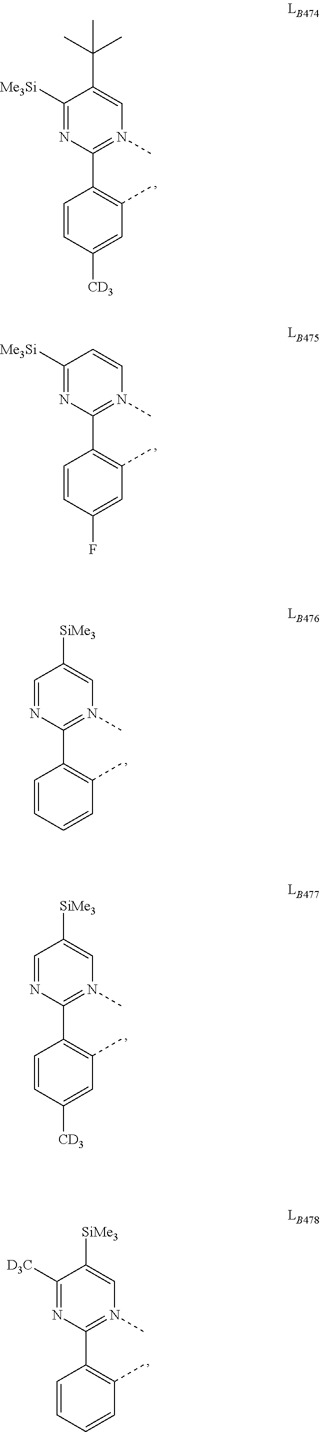

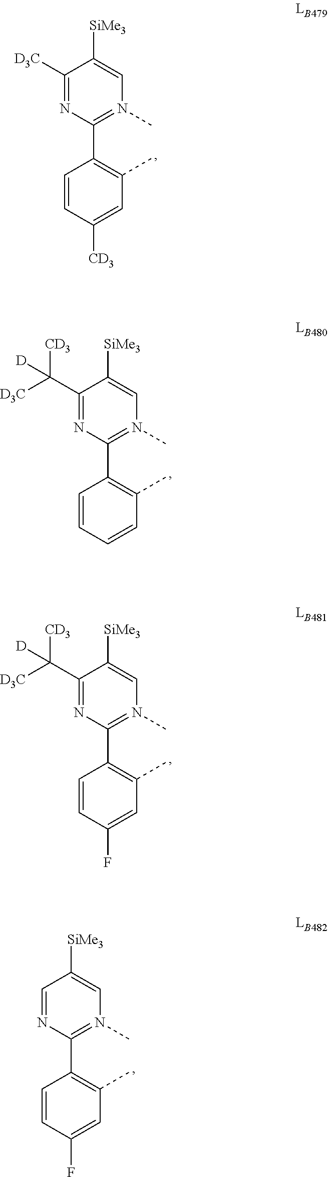

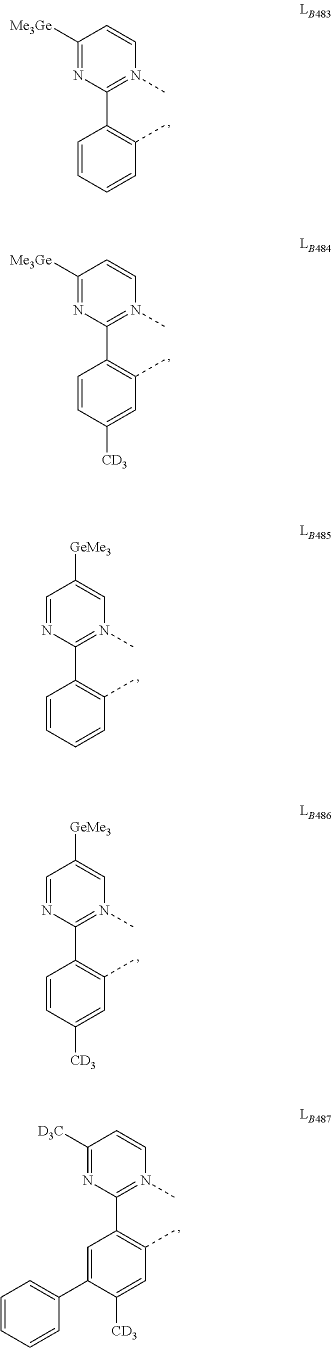

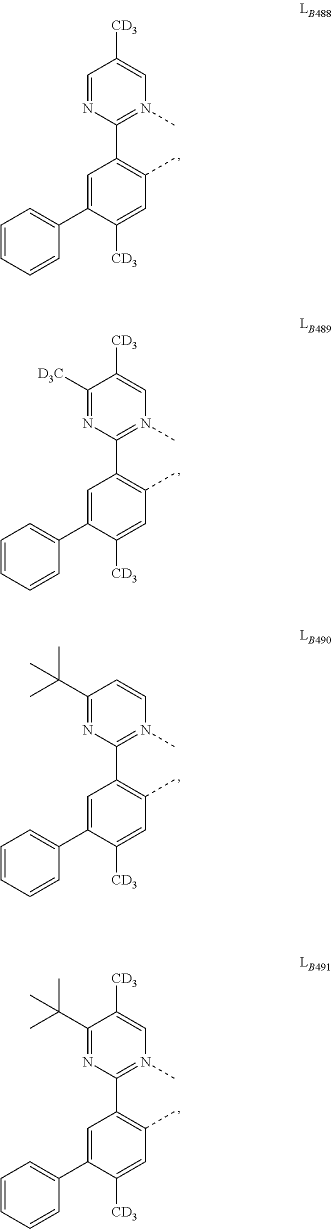

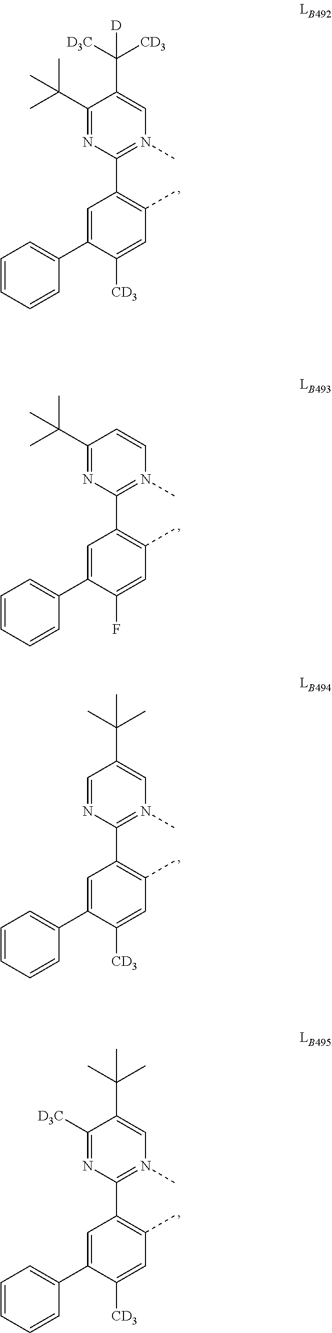

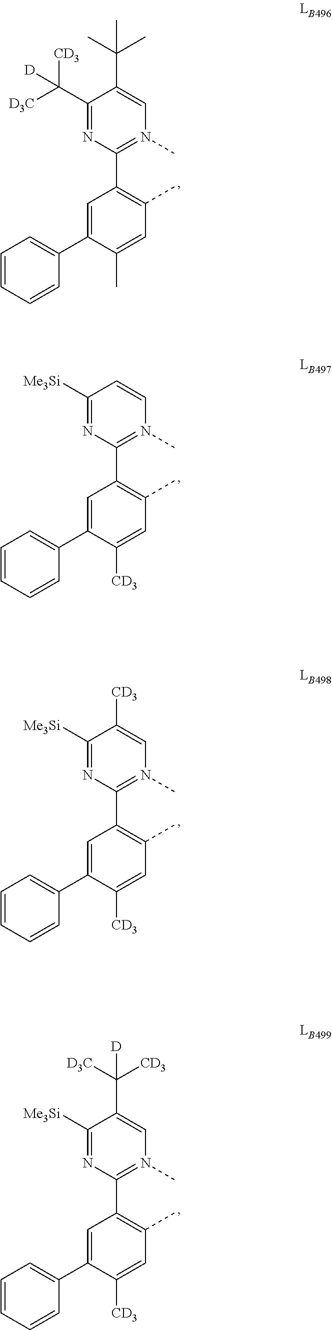

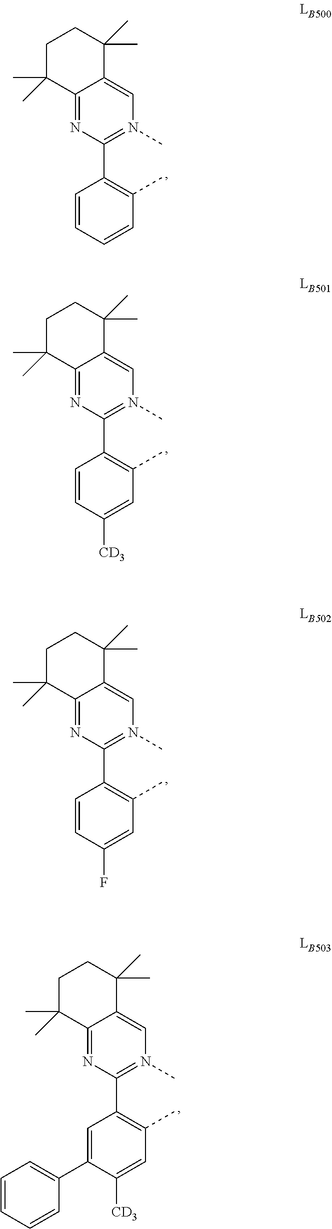

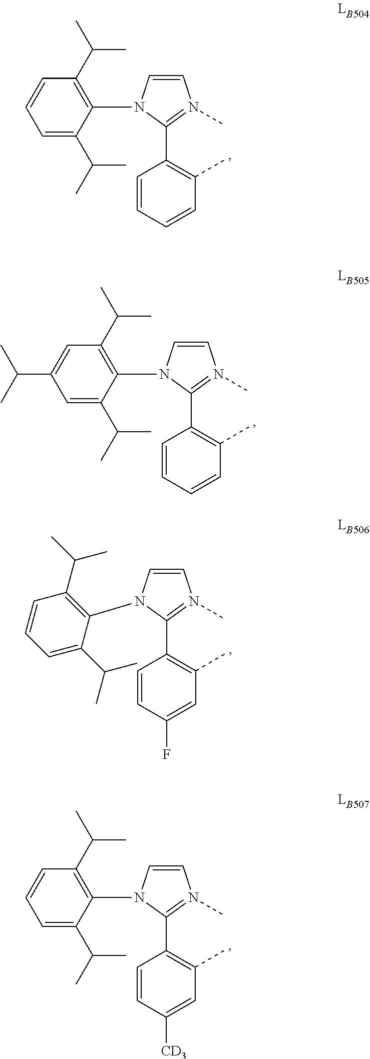

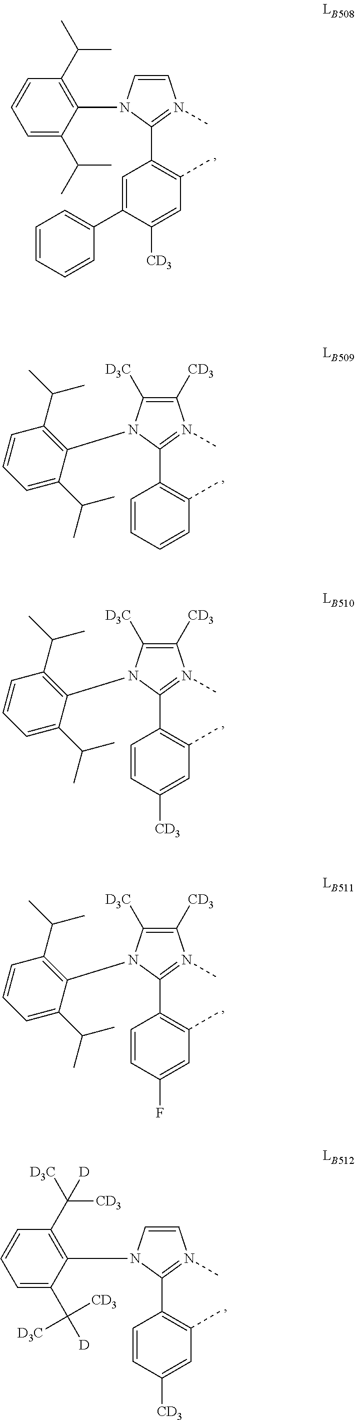

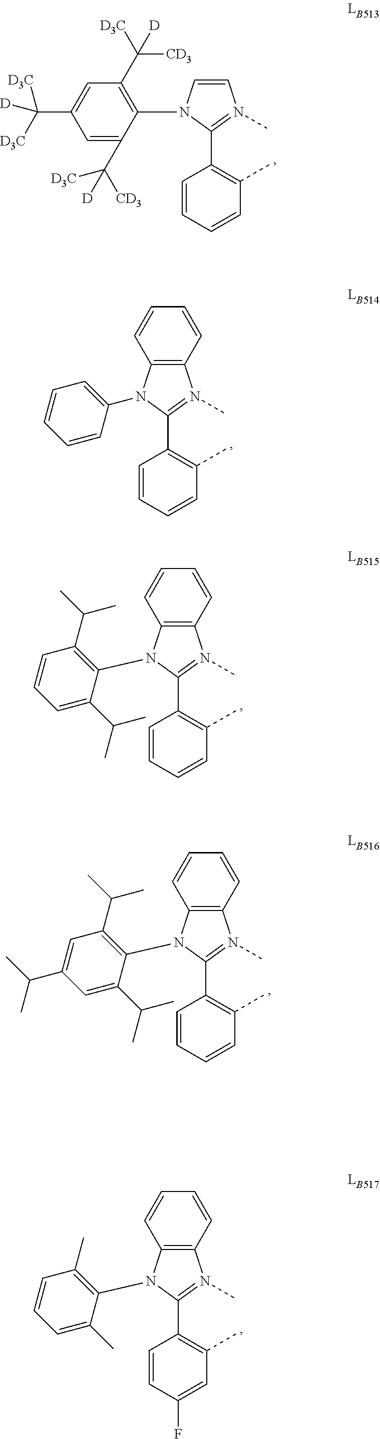

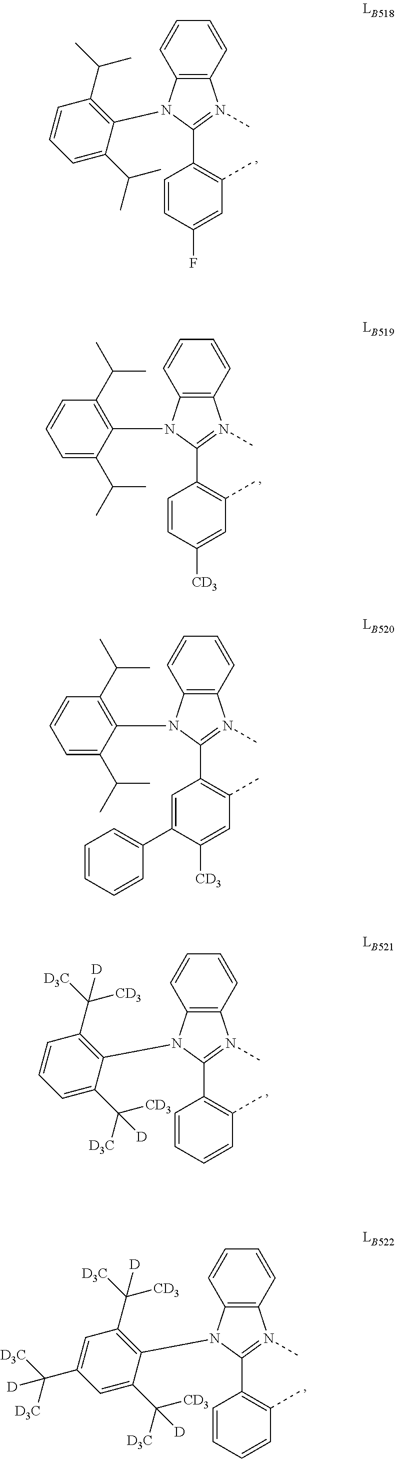

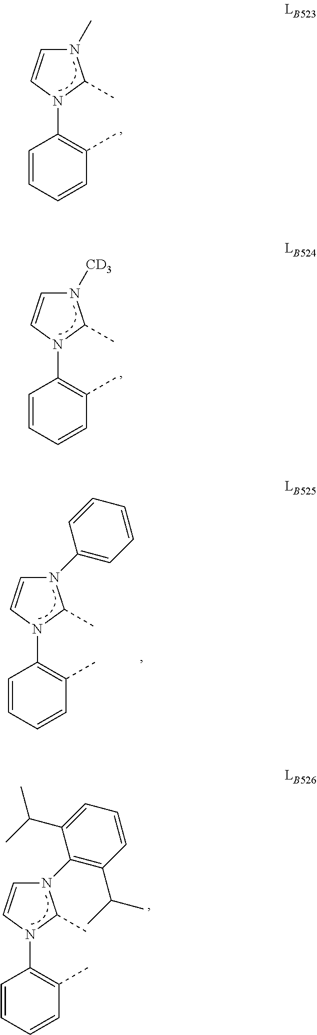

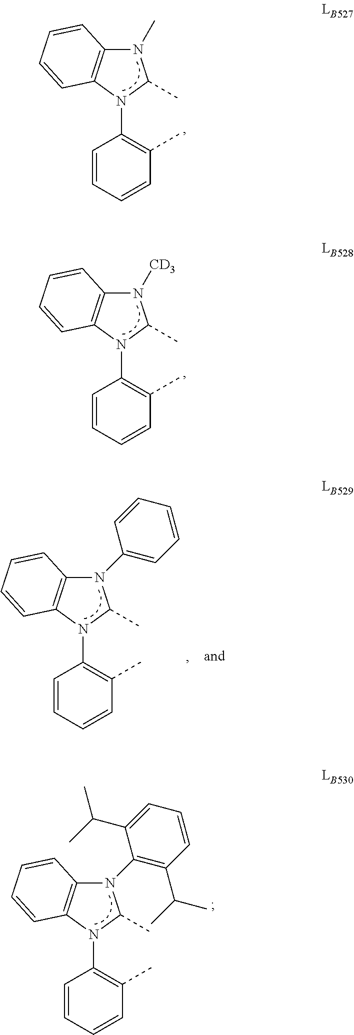

wherein each L_{Cj-I} has a structure based on formula

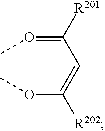

and
each L_{Cj-II} has a structure based on formula

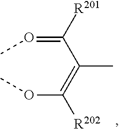

wherein for each L_{Cj} in L_{Cj-I} and L_{Cj-II}, R²⁰¹ and R²⁰² are defined in the following LIST 8:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

wherein R^{D1} to R^{D246} have the structures defined in the following LIST 9:

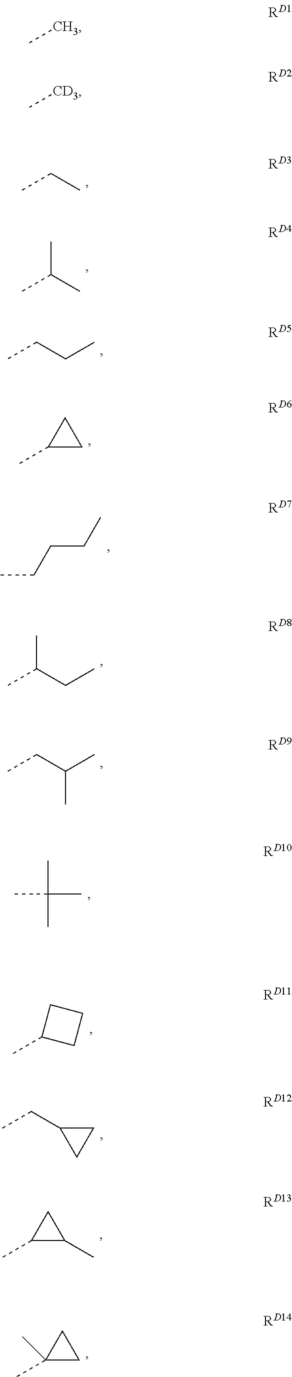

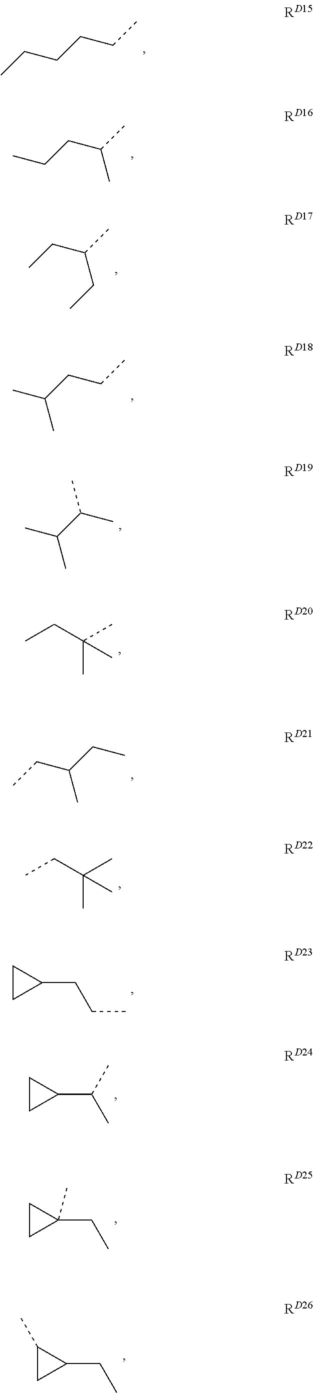

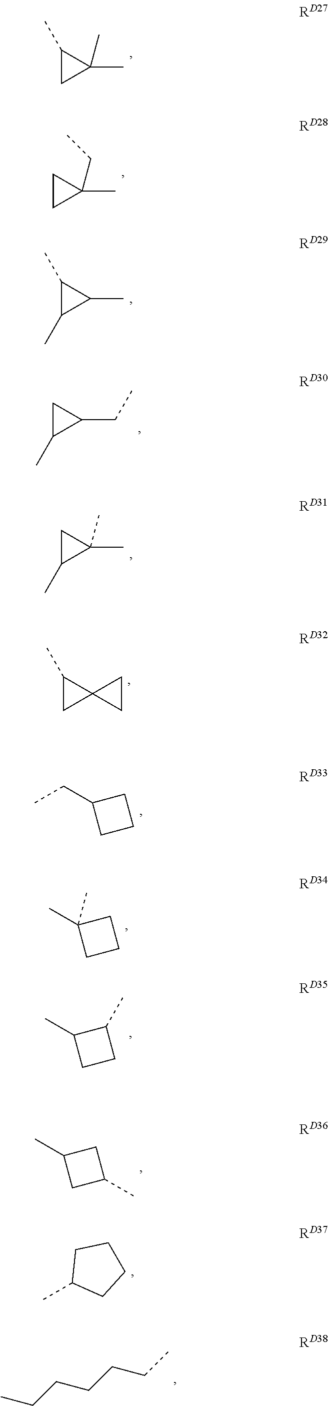

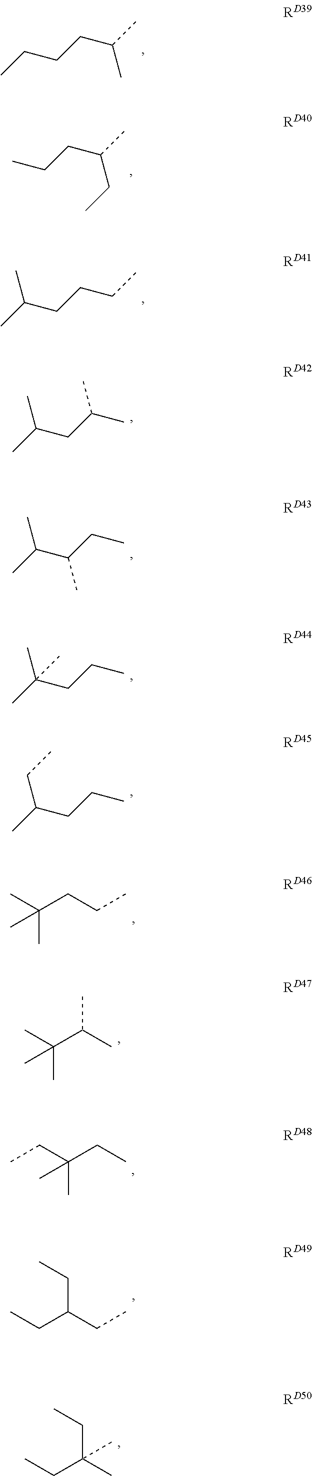

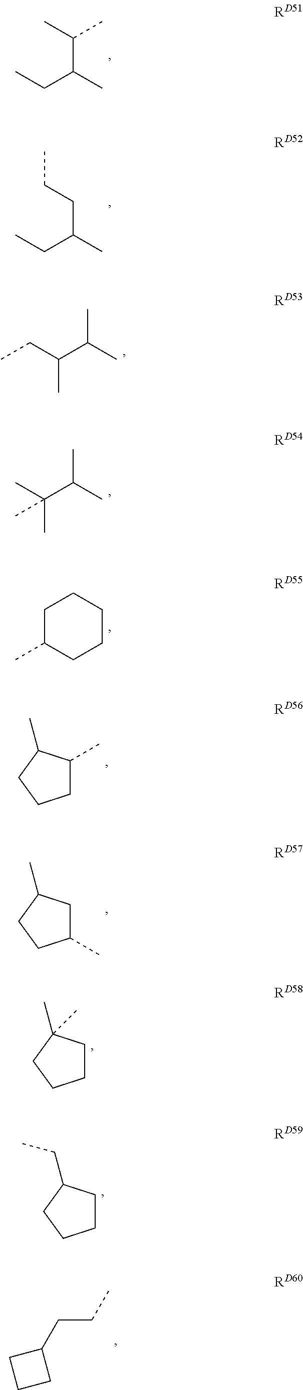

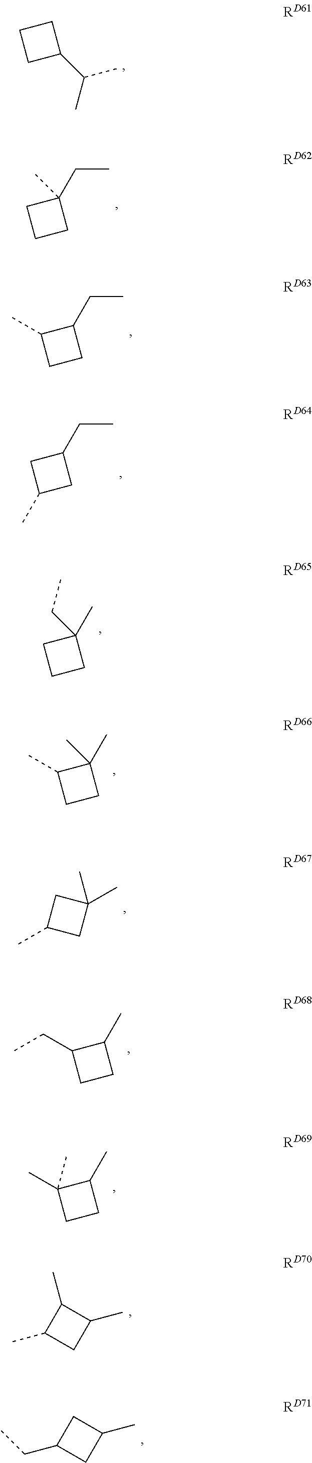

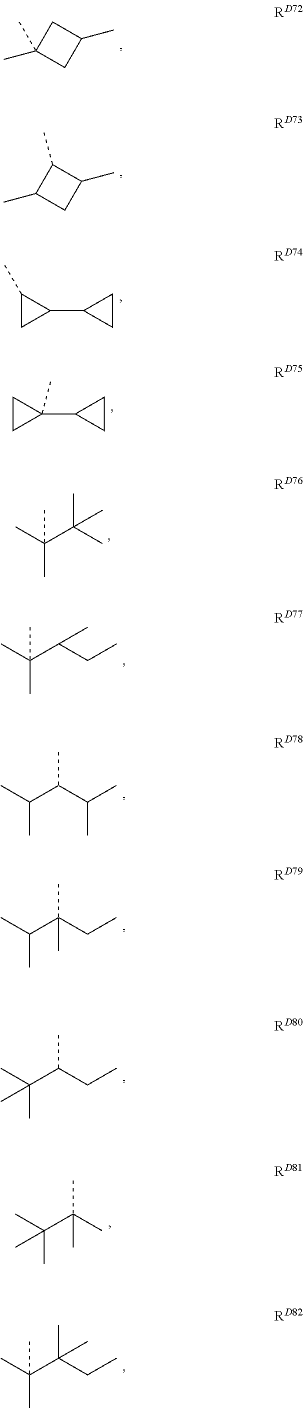

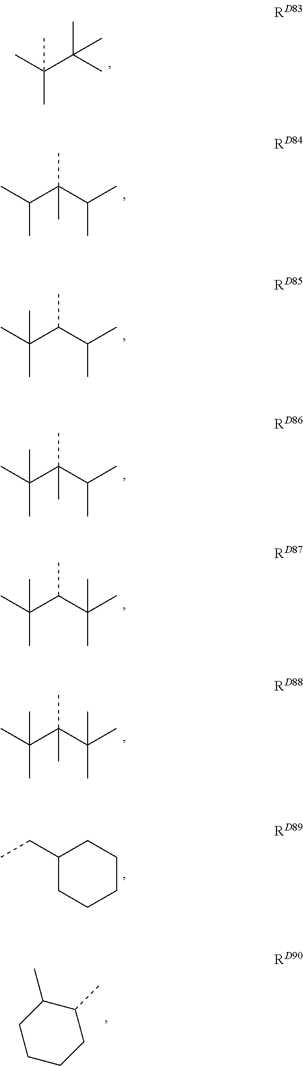

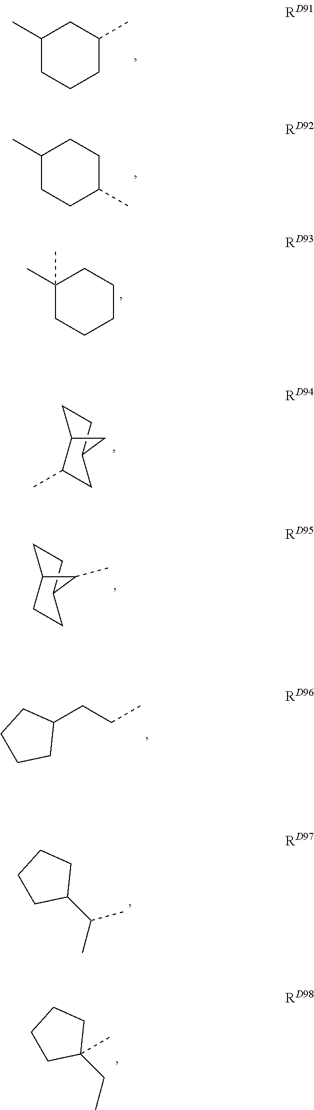

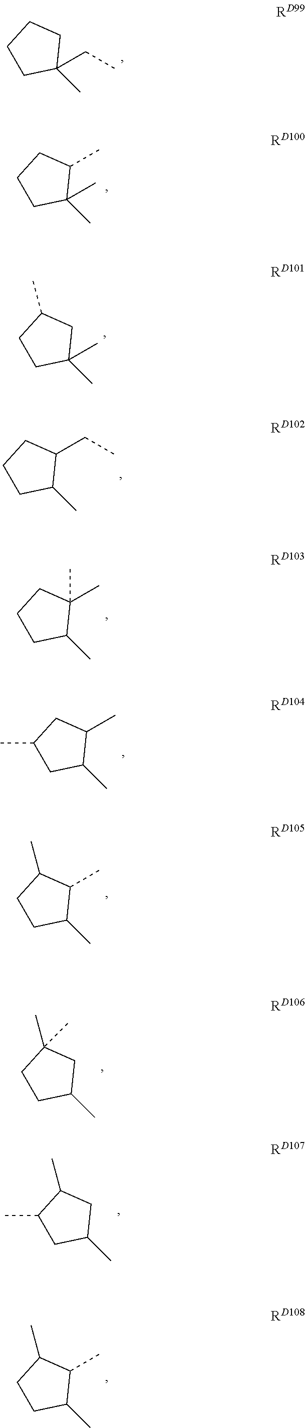

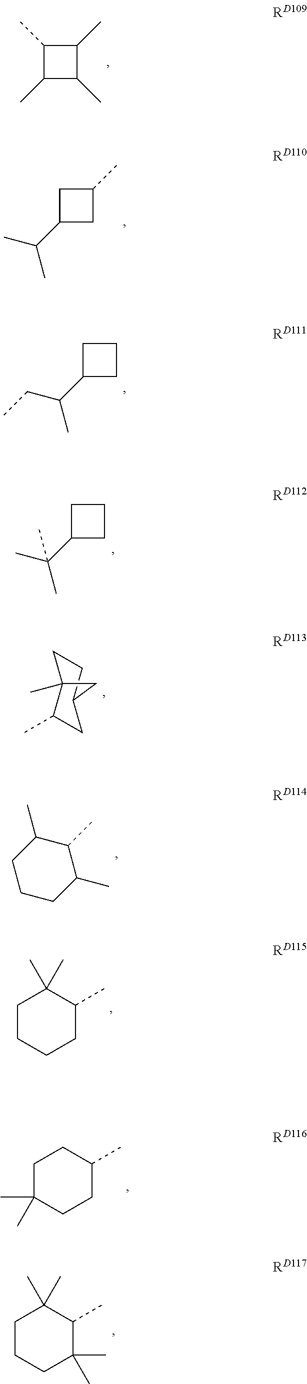

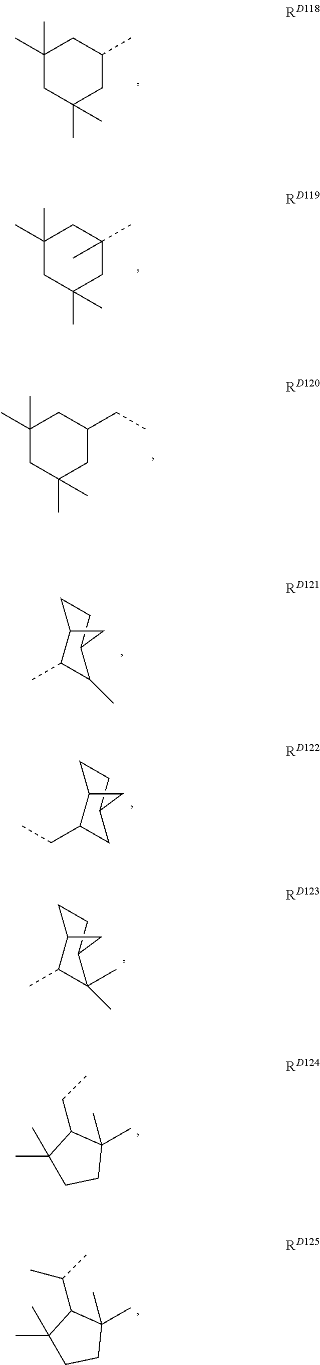

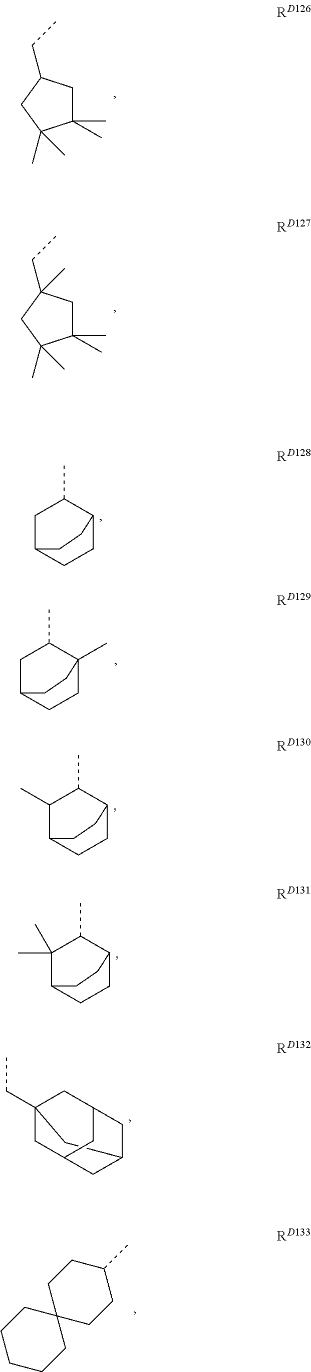

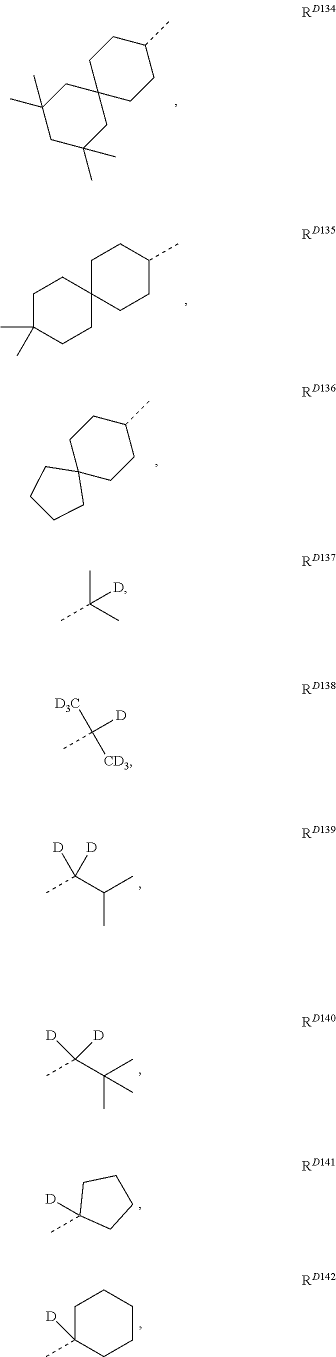

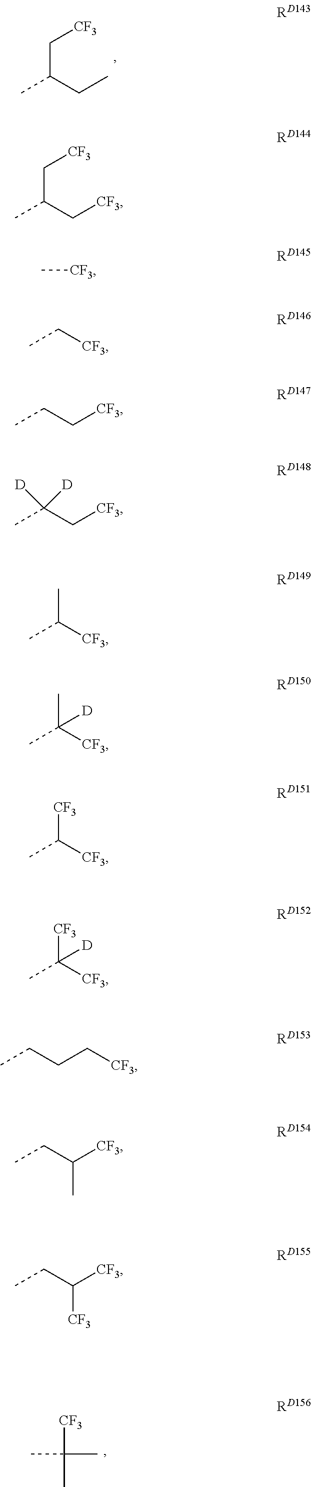

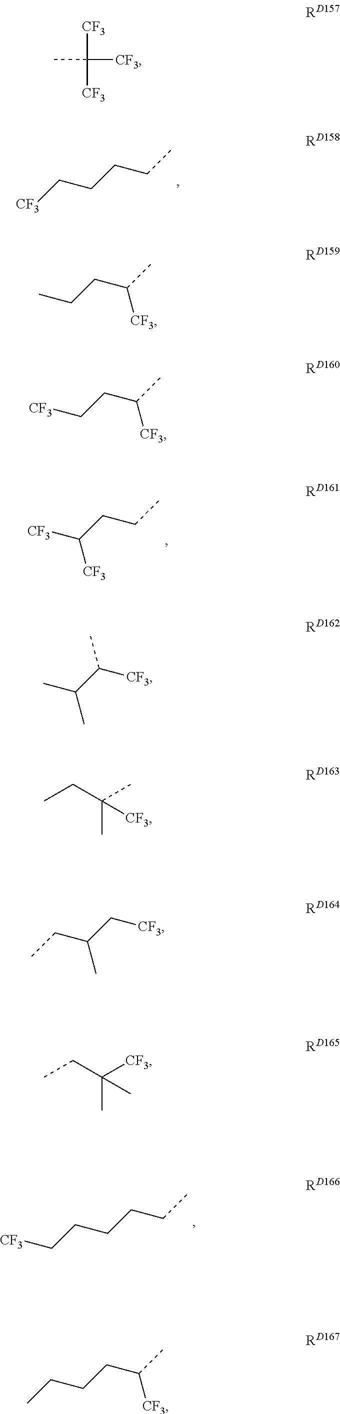

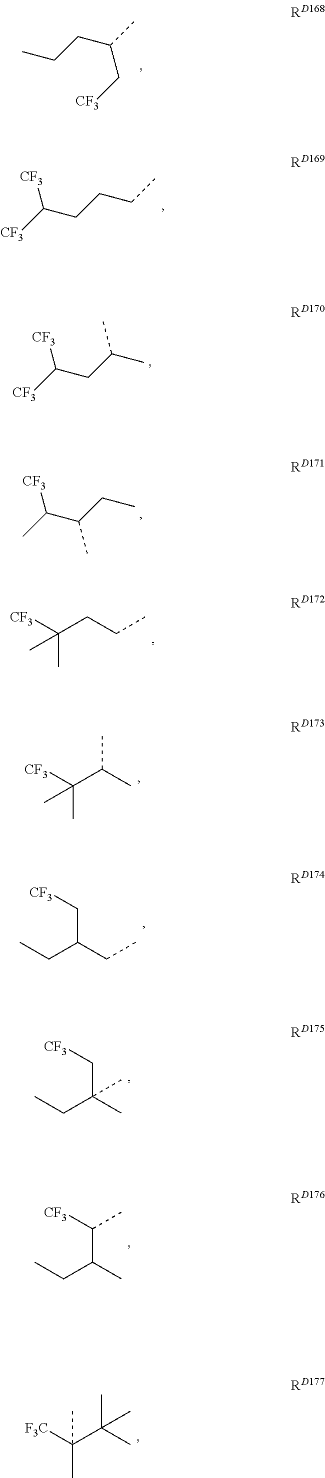

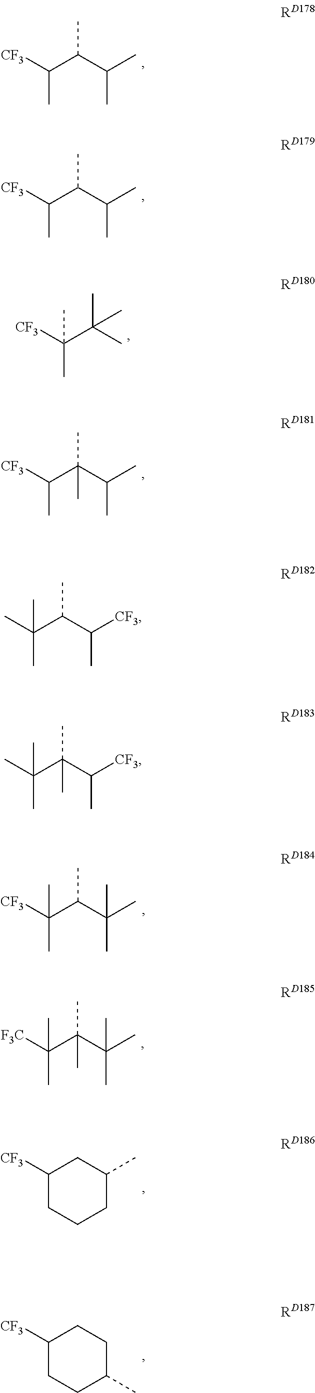

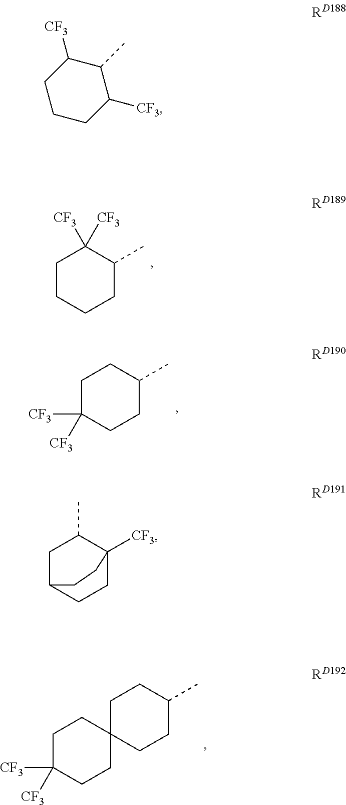

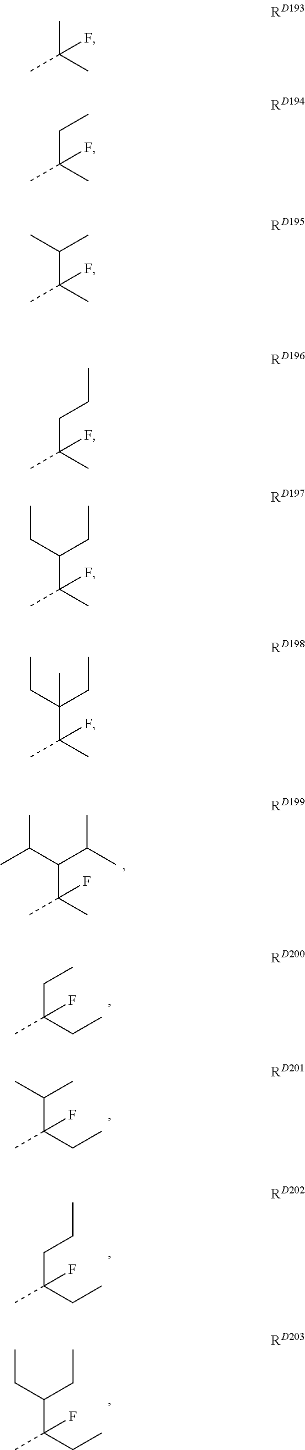

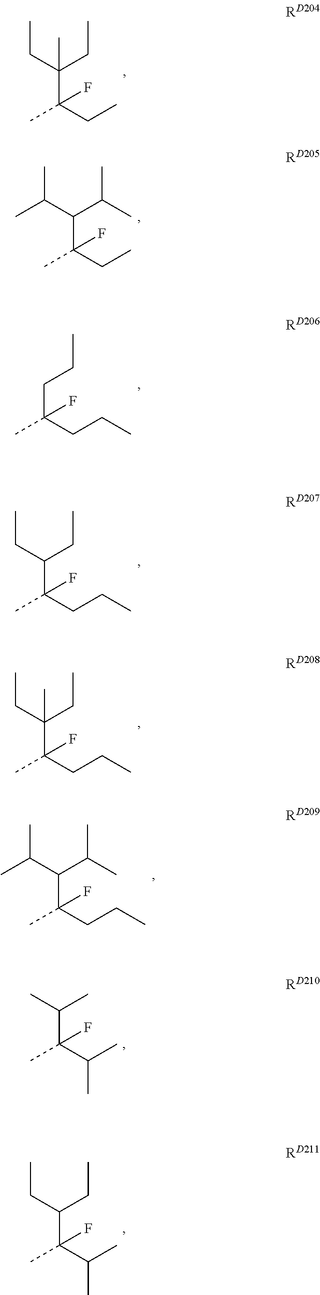

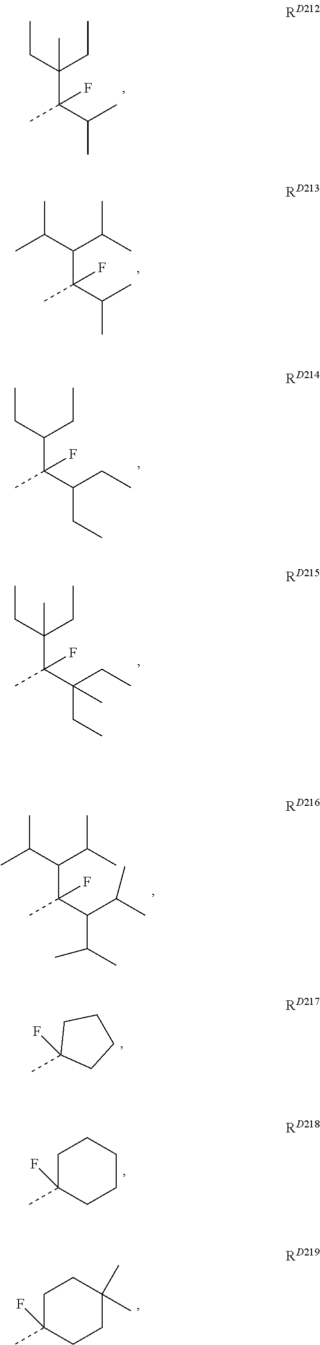

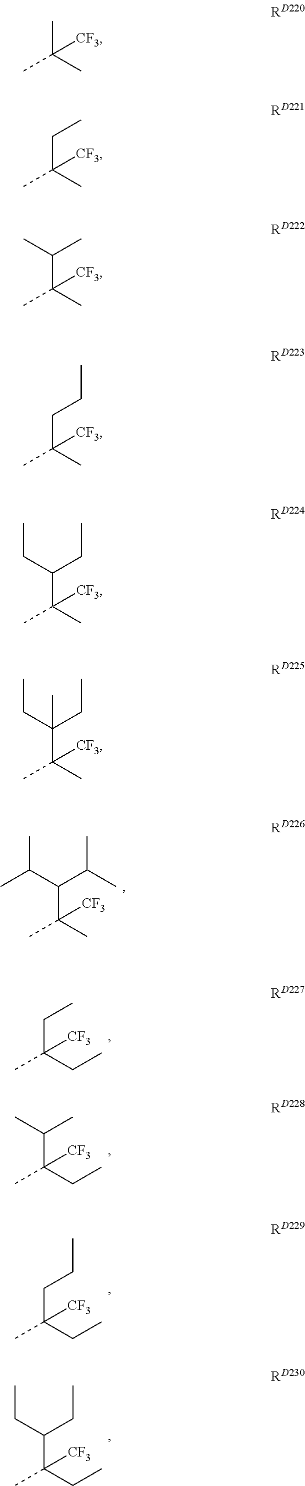

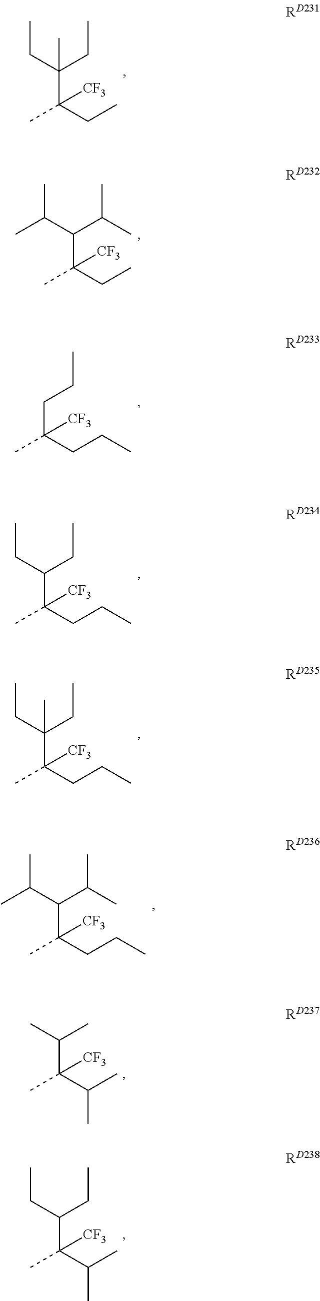

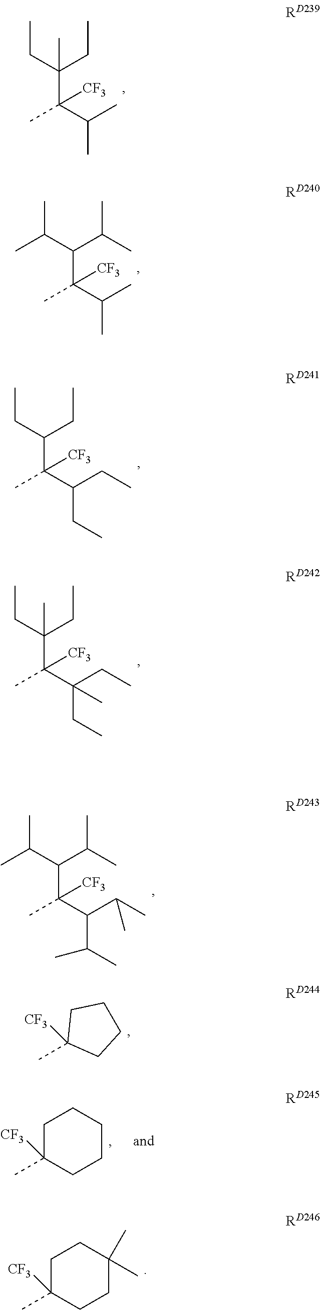

In some embodiments, the compound is selected from the group consisting of only those compounds whose L_{Bk} corresponds to one of the following: L_{B1}, L_{B30}, L_{B31}, L_{B109}, L_{B110}, L_{B112}, L_{B113}, L_{B114}, L_{B125}, L_{B127}, L_{B138}, L_{B140}, L_{B149}, L_{B150}, L_{B170}, L_{B171}, L_{B172}, L_{B174}, L_{B208}, L_{B241}, L_{B312}, L_{B315}, L_{B356}, L_{B36}, L_{B371}, L_{B382}, L_{B439}, L_{B440}, L_{B455}, L_{B456}, L_{B457}, L_{B458}, L_{B461}, L_{B462}, L_{B463}, L_{B469}, and L_{B476}.

In some embodiments, the compound is selected from the group consisting of only those compounds whose L_{Bk} corresponds to one of the following: L_{B1}, L_{B30}, L_{B31}, L_{B125}, L_{B138}, L_{B171}, L_{B172}, L_{B356}, L_{B357}, L_{B367}, L_{B371}, L_{B382}, L_{B455}, and L_{B456}.

In some embodiments, the compound is selected from the group consisting of only those compounds having L_{Cj-I} or L_{Cj-II} ligand whose corresponding R²⁰¹ and R²⁰² are defined to be one of the following structures: R^{D1}, R^{D3}, R^{D4}, R^{D5}, R^{D9}, R^{D10}, R^{D17}, R^{D18}, R^{D20}, R^{D22}, R^{D37}, R^{D40}, R^{D41}, R^{D42}, R^{D43}, R^{D48}, R^{D49}, R^{D50}, R^{D54}, R^{D55}, R^{D58}, R^{D59}, R^{D78}, R^{D79}, R^{D81}, R^{D87}, R^{D88}, R^{D89}, R^{D93}, R^{D116}, R^{D117}, R^{D118}, R^{D119}, R^{D120}, R^{D133}, R^{D134}, R^{D135}, R^{D136}, R^{D143}, R^{D144}, R^{D145}, R^{D146}, R^{D147}, R^{D149}, R^{D151}, R^{D154}, R^{D155}, R^{D161}, R^{D175}, R^{D190}, R^{D193}, R^{D200}, R^{D201}, R^{D206}, R^{D210}, R^{D214}, R^{D25}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having L_{Cj-I} or L_{Cj-II} ligand whose corresponding R²⁰¹ and R²⁰² are defined to be one of selected from the following structures: R^{D1}, R^{D3}, R^{D4}, R^{D5}, R^{D9}, R^{D10}, R^{D17}, R^{D22}, R^{D43}, R^{D50}, R^{D78}, R^{D116}, R^{D118}, R^{D133}, R^{D134}, R^{D135}, R^{D136}, R^{D143}, R^{D144}, R^{D145}, R^{D146}, R^{D149}, R^{D151}, R^{D154}, R^{D155}, R^{D190}, R^{D193}, R^{D200}, R^{D201}, R^{D206}, R^{D210}, R^{D214}, R^{D25}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having one of the structures of the following LIST 10 for the L_{Cj-I} ligand:

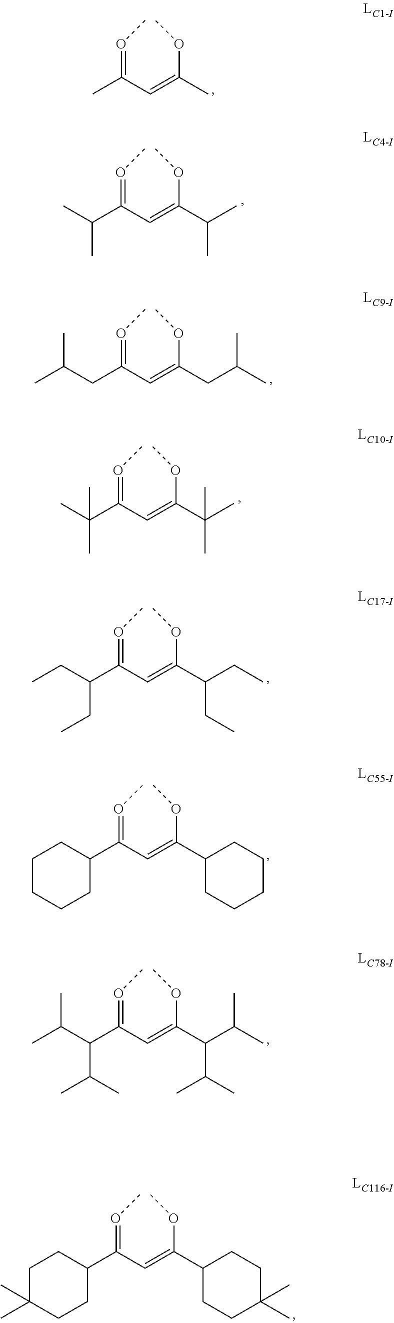

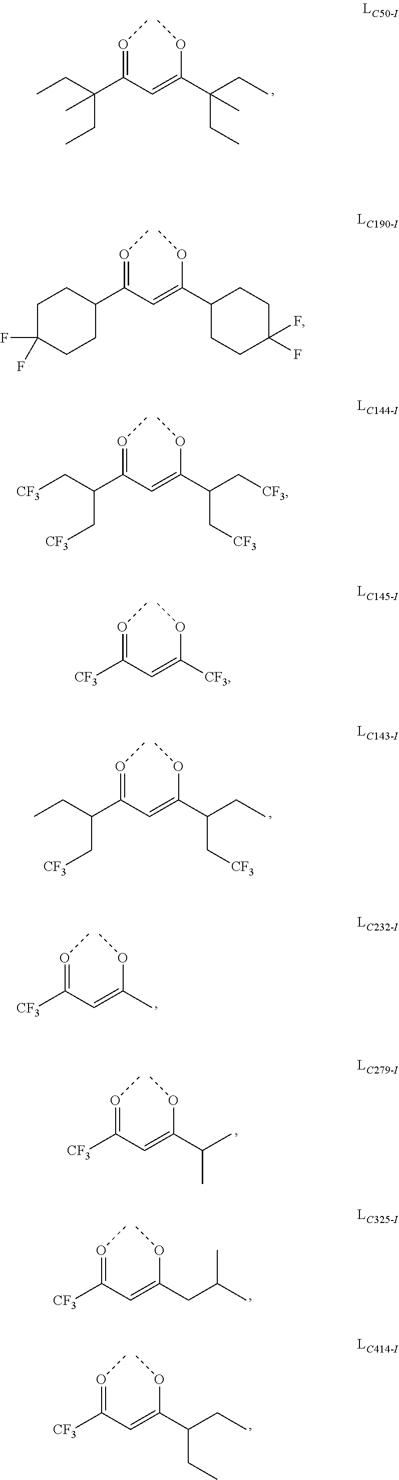

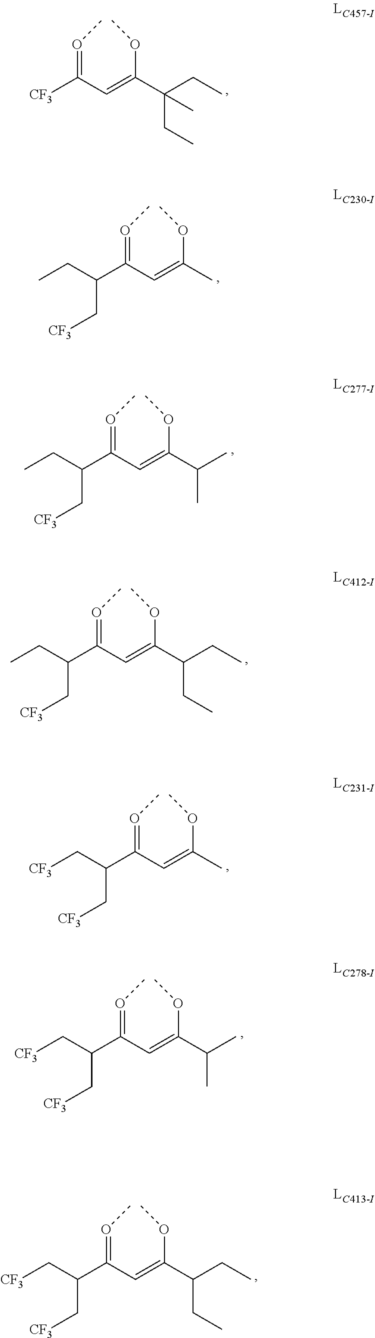

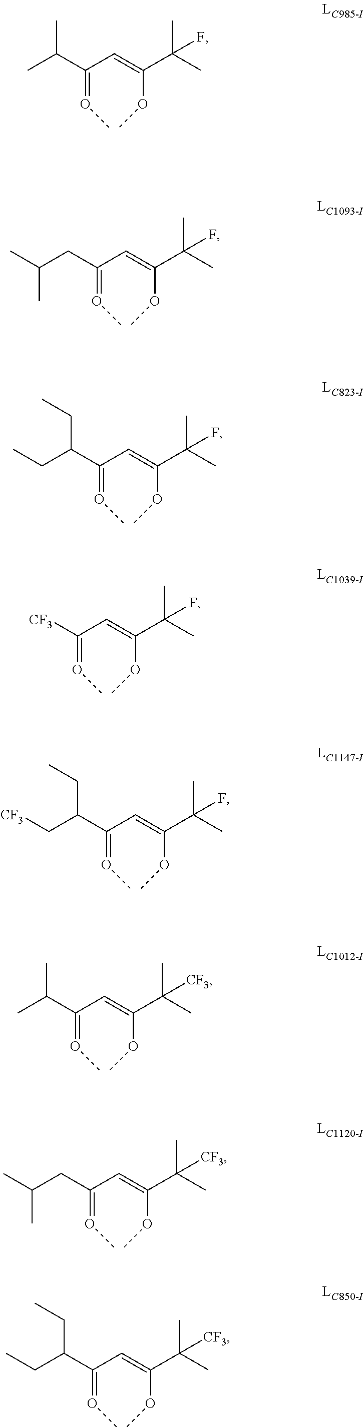

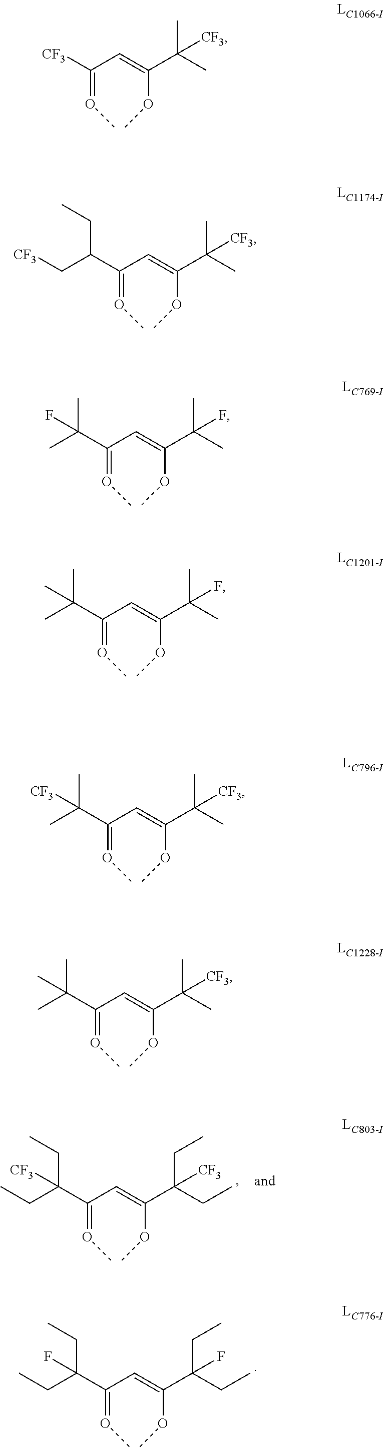

In some embodiments, L_{A} is selected from the group consisting of the structures of LIST 1, LIST 2, and LIST 3. In some embodiments, L_{B} is selected from the group consisting of the structures of LIST 5, LIST 6, and LIST 7. In some embodiments, L_{A} is selected from the group consisting of the structures of LIST 3 of L_{A1}(R^{EA})(R^{EB})(R^{EC})(R^{ED})(R^{EE}) consisting of L_{A1}(R¹)(R¹)(R¹)(R¹)(R¹) to L_{A148}(R¹⁵⁰)(R¹⁵⁰)(R¹⁵⁰)(R¹⁵⁰)(R¹⁵⁰) defined herein and L_{B} is selected from the group consisting of LIST 7 of L_{Bk} consisting of L_{B1} to L_{B530} as defined herein.

In some embodiments, the compound can be Ir(L_{A})₃, Ir(L_{A})₂(L_{B}), Ir(L_{A})(L_{B})₂, Ir(L_{A})₂(L_{C}), Ir(L_{A})(LC)₂, or Ir(L_{A})(L_{B})(L_{C}). In some of these embodiments, the compound can be Ir(L_{Ai}(R^{EA})(R^{EB})(R^{EC})(R^{ED})(R^{EE}))₃ consisting of the compounds of Ir(L_{Ai}(R¹)(R¹)(R¹)(R¹)(R¹))₃ to Ir(L_{A148}(R¹⁵⁰)(R¹⁵⁰)(R¹⁵⁰)(R¹⁵⁰)(R¹⁵⁰))₃, Ir(L_{Ai}(R^{EA})(R^{EB})(R^{EC})(R^{ED})(R^{EE}))₂(L_{B}), Ir(L_{Ai}(R^{EA})(R^{EB})(R^{EC})(R^{ED})(R^{EE}))(L_{B})₂, Ir(L_{A})₂(L_{Bk}), Ir(L_{A})(L_{Bk})₂, Ir(L_{Ai}(R^{EA})(R^{EB})(R^{EC})(R^{ED})(R^{EE}))))₂(L_{Bk}) consisting of the compounds from Ir(L_{Ai}(R¹)(R¹)(R¹)(R¹)(R¹))₂(L_{B1}) to Ir(L_{A148}(R¹⁵⁰)(R¹⁵⁰)(R¹⁵⁰)(R¹⁵⁰)(R¹⁵⁰))₂ (L_{B530}), Ir(L_{Ai}(R^{EA})(R^{EB})(R^{EC})(R^{ED})(R^{EE}))(L_{Bk})₂ consisting of the compounds from Ir(L_{Ai}(R¹)(R¹)(R¹)(R¹)(R¹))(L_{B1})₂ to Ir(L_{A148}(R¹⁵⁰)(R¹⁵⁰)(R¹⁵⁰)(R¹⁵⁰)(R¹⁵⁰))(L_{B530})₂, Ir(L_{Ai}(R^{EA})(R^{EB})(R^{EC})(R^{ED})(R^{EE}))₂(L_{Cj-I}), consisting of the compounds of Ir(L_{Ai}(R¹)(R¹)(R¹)(R¹)(R¹))₂(L_{Cj-II}) to Ir(L_{A148}(R¹⁵⁰)(R¹⁵⁰)(R¹⁵⁰)(R¹⁵⁰)(R¹⁵⁰))₂(L_{C1416-I}), Ir(L_{Ai}(R^{EA})(R^{EB})(R^{EC})(R^{ED})(R^{EE}))₂(L_{Cj-II}), consisting of the compounds of Ir(L_{Ai}(R¹)(R¹)(R¹)(R¹)(R¹))₂(L_{Cj-II}) to Ir(L_{A148}(R¹⁵⁰)(R¹⁵⁰)(R¹⁵⁰)(R¹⁵⁰)(R¹⁵⁰))₂(L_{C1416- II}), Ir(L_{Ai}(R^{EA})(R^{EB})(R^{EC})(R^{ED})(R^{EE}))(L_{Bk})(L_{Cj-I}) consisting of the compounds of Ir(L_{Ai}(R¹)(R¹)(R¹)(R¹)(R¹))(L_{B1})(L_{Cj-I}) to Ir(L_{A148}(R¹⁵⁰)(R¹⁵⁰)(R¹⁵⁰)(R¹⁵⁰)(R¹⁵⁰)(L_{B530})(L_{C1416-I}), Or Ir(L_{Ai}(R^{EA})(R^{EB})(R^{EC})(R^{ED})(R^{EE}))(L_{Bk})(L_{Cj-II}) consisting of the compounds of Ir(L_{Ai}(R¹)(R¹)(R¹)(R¹)(R¹))(L_{B1})(L_{Cj-II}) to Ir(L_{A148}(R¹⁵⁰)(R¹⁵⁰)(R¹⁵⁰)(R¹⁵⁰)(R¹⁵⁰))(L_{B530})(L_{C1416-II}), wherein L_{Ai}(R^{EA})(R^{EB})(R^{EC})(R^{ED})(R^{EE}), L_{Bk}, L_{Cj-II} and L_{Cj-I} are all defined herein.

In some embodiments, the compound is selected from the group consisting of the structures of the following LIST 11:

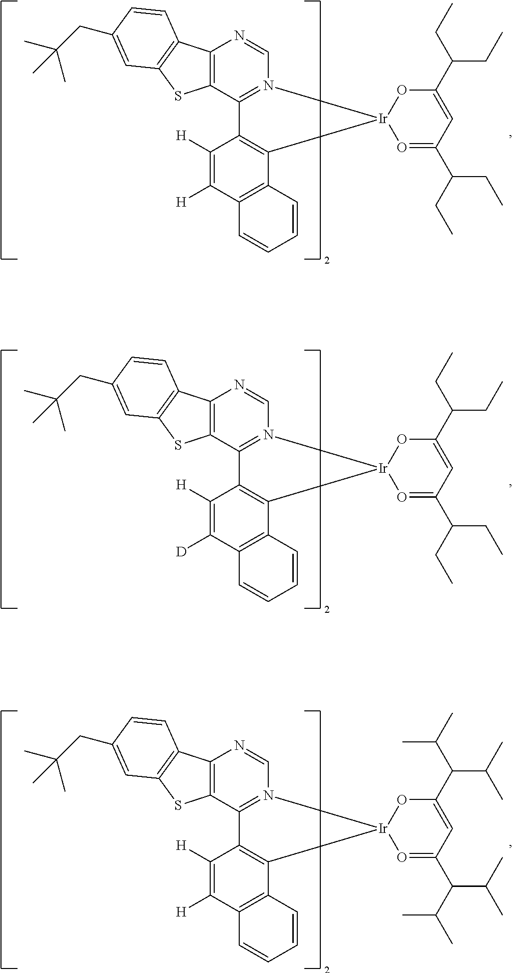

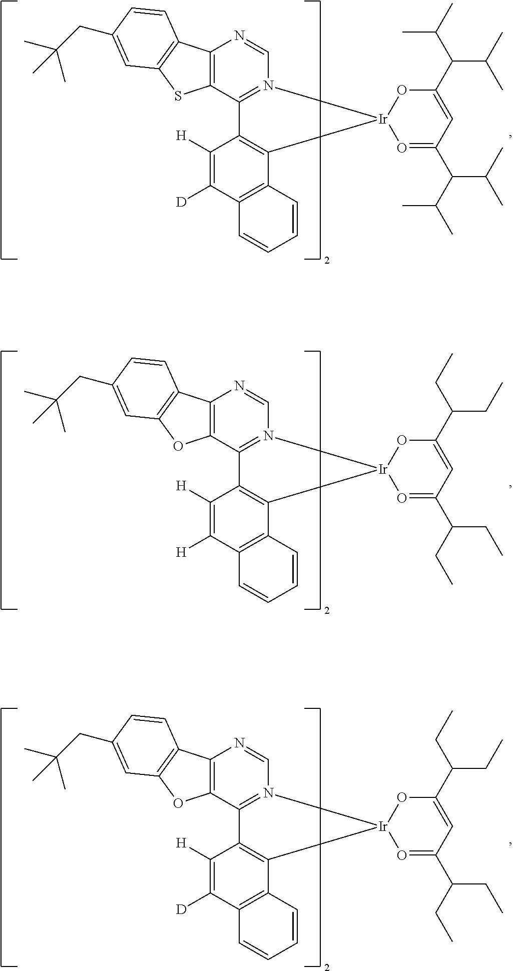

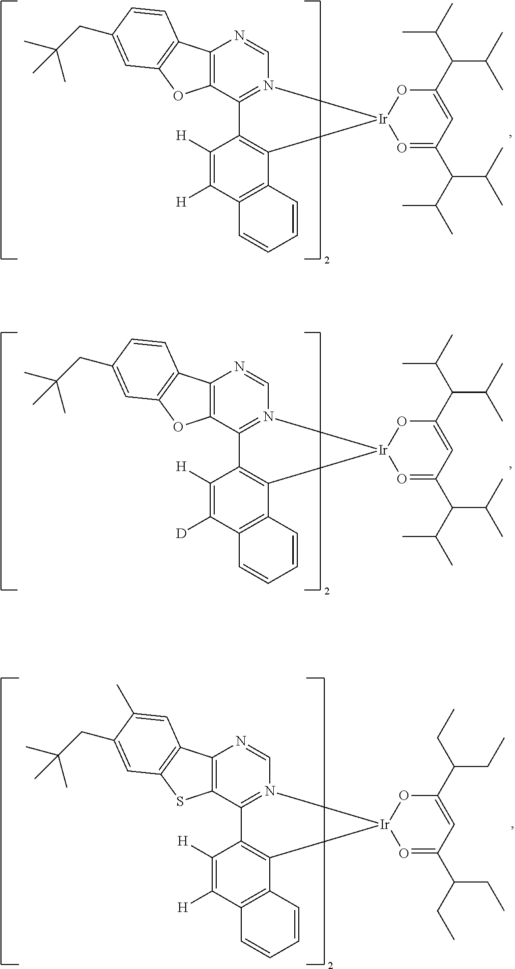

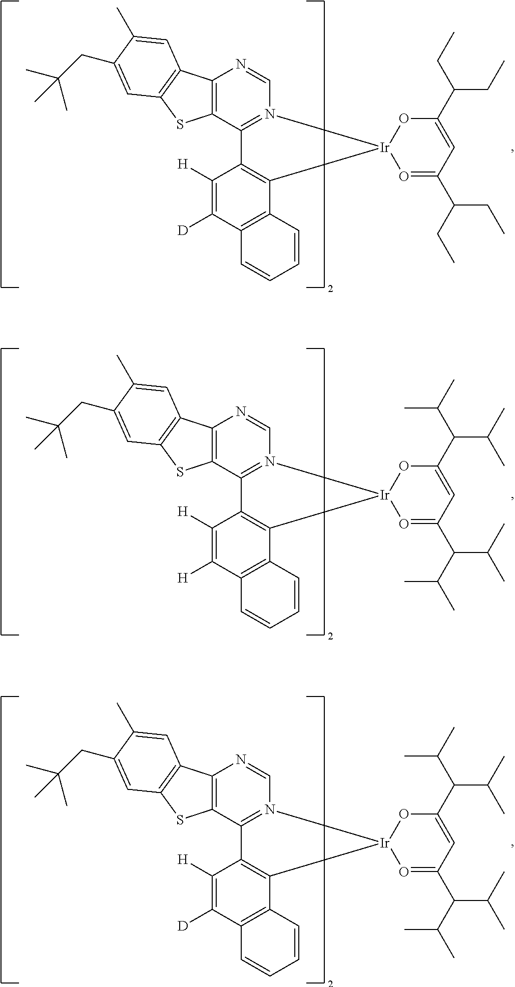

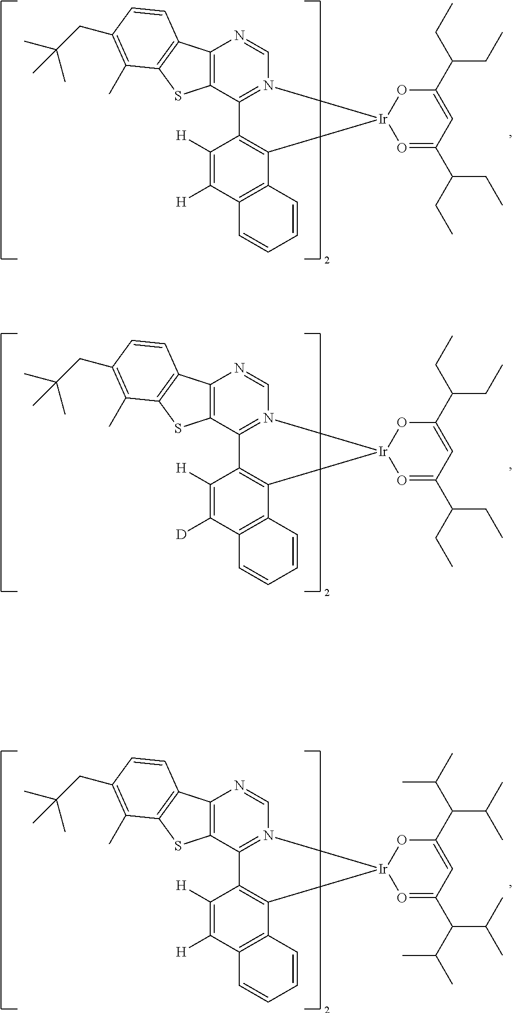

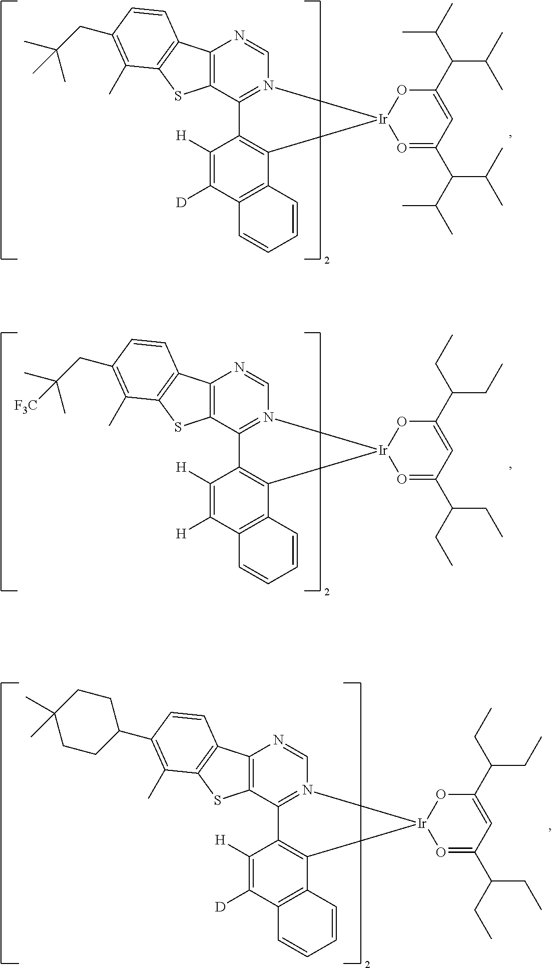

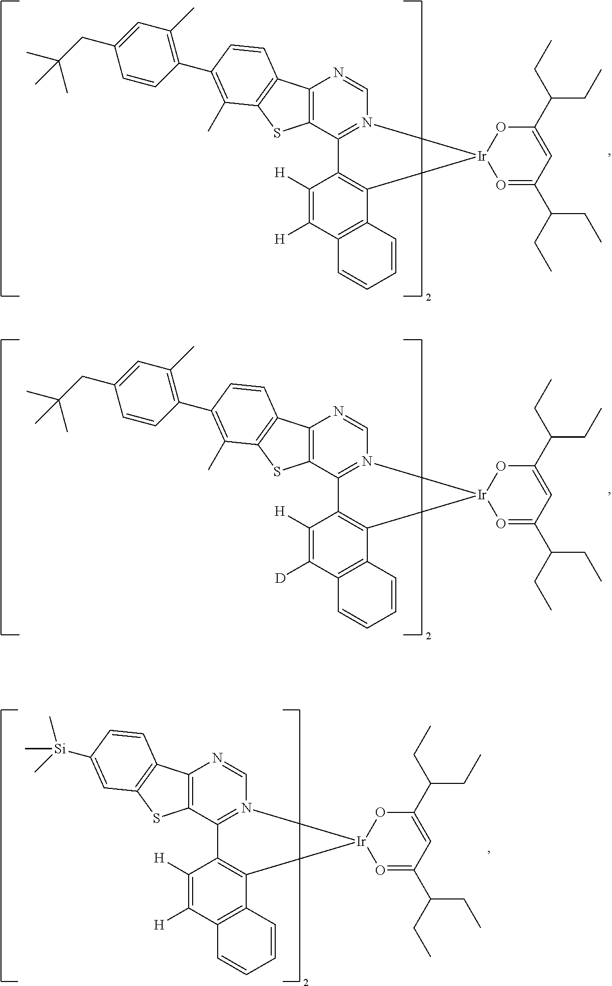

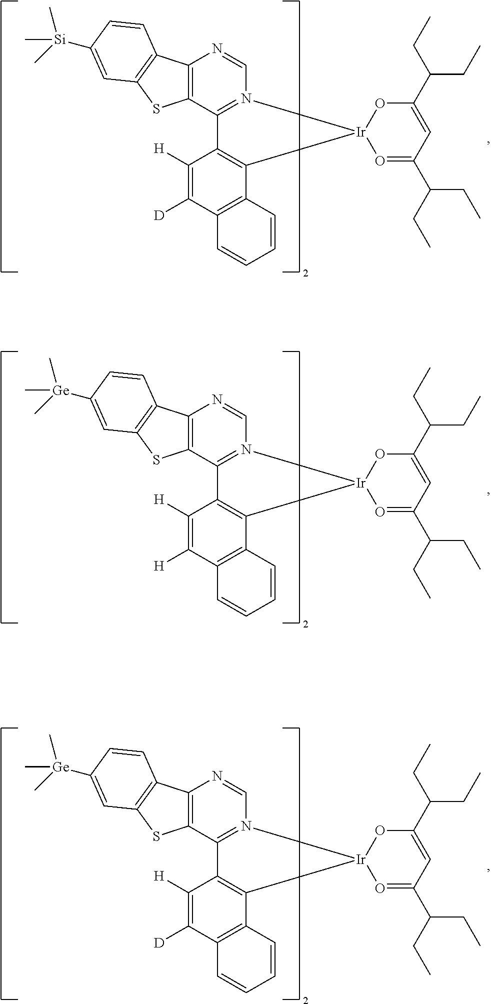

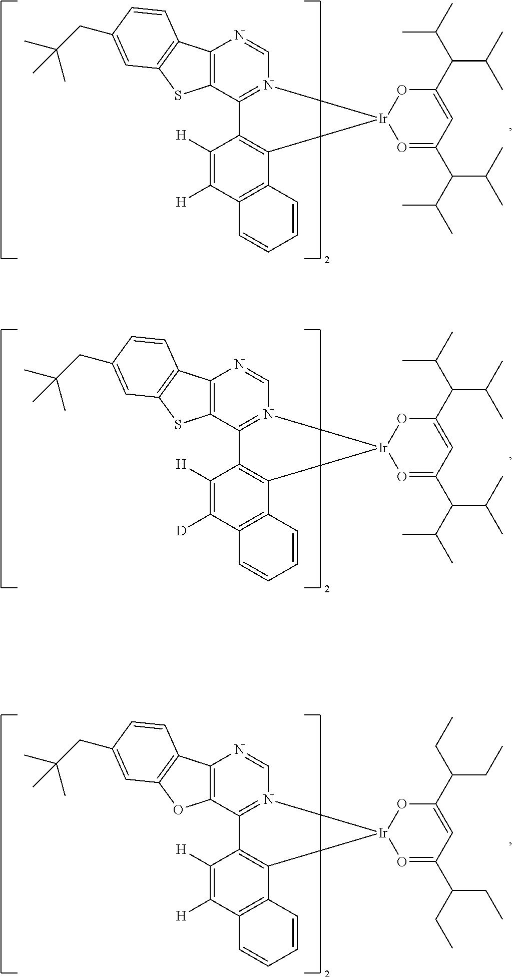

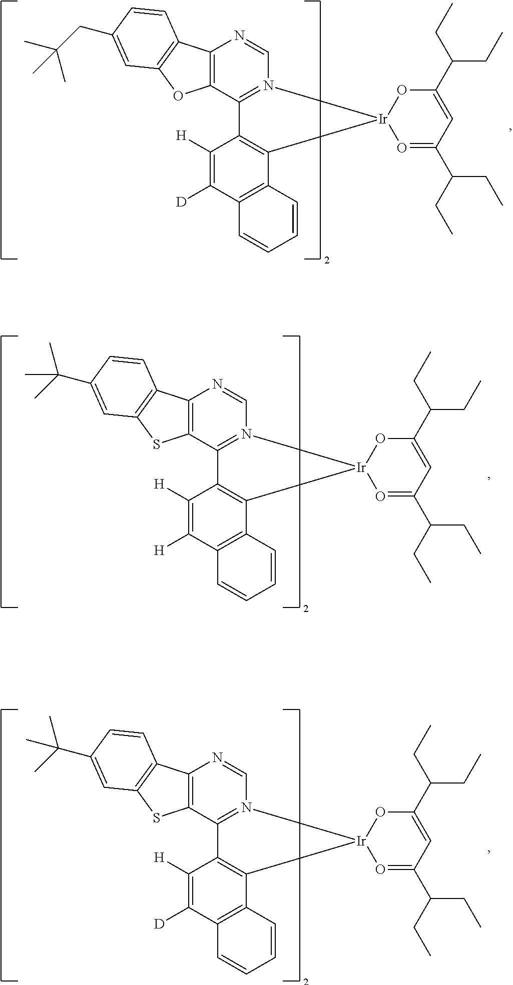

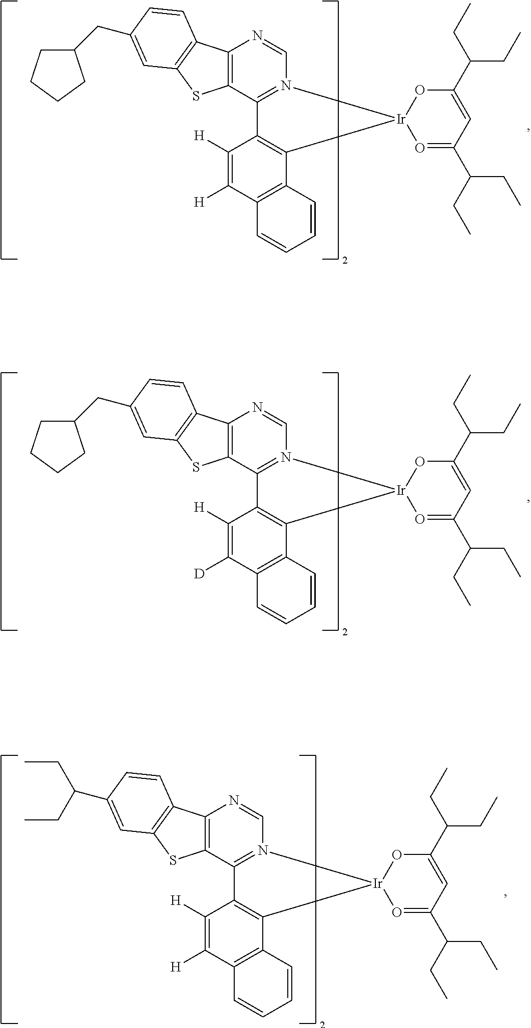

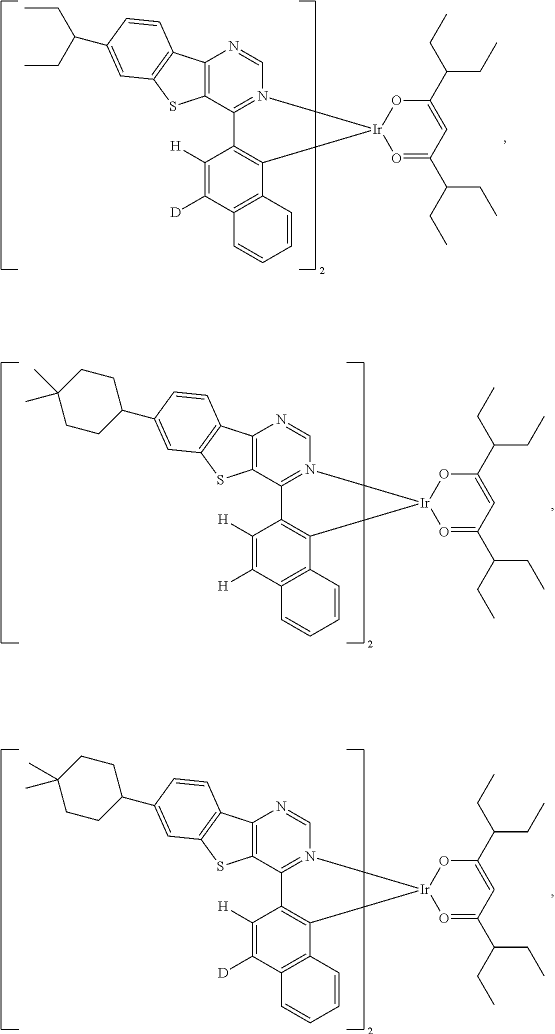

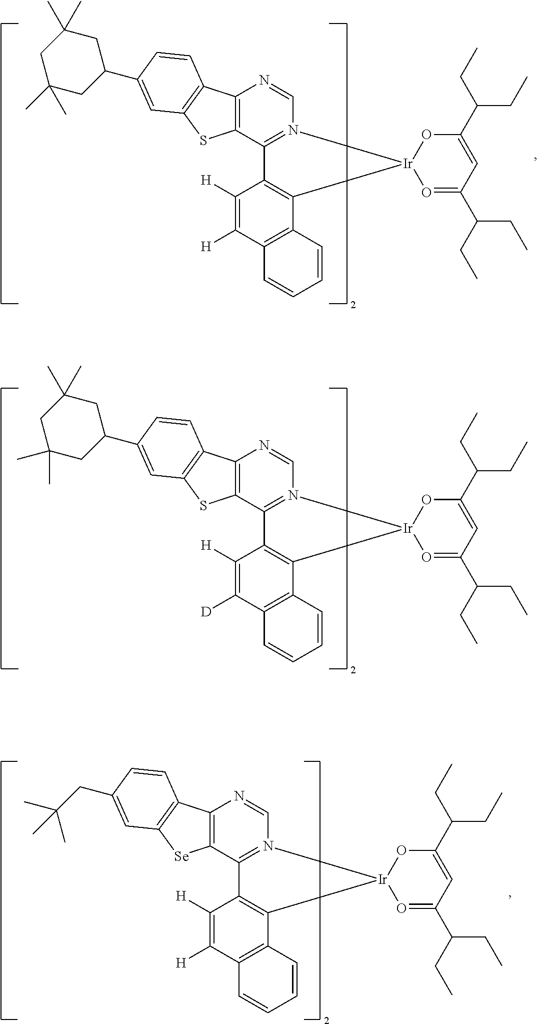

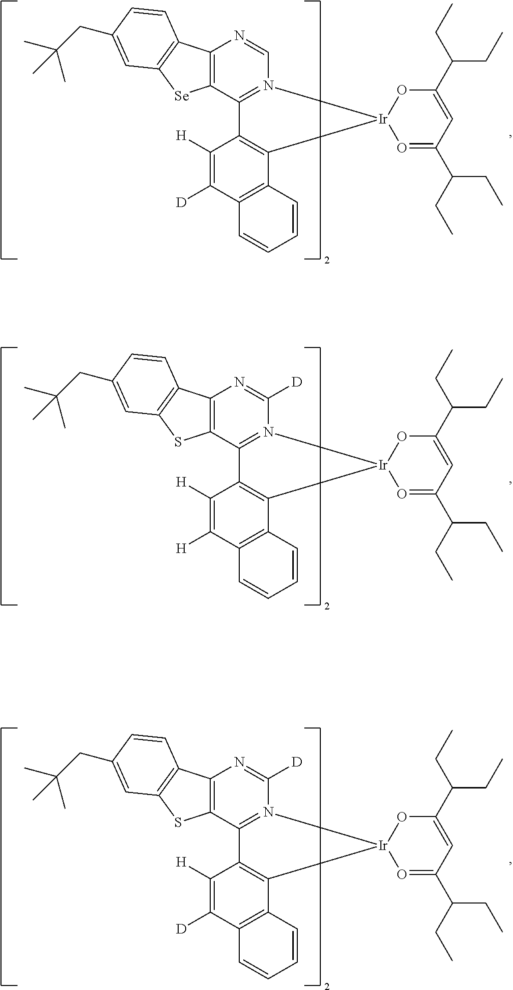

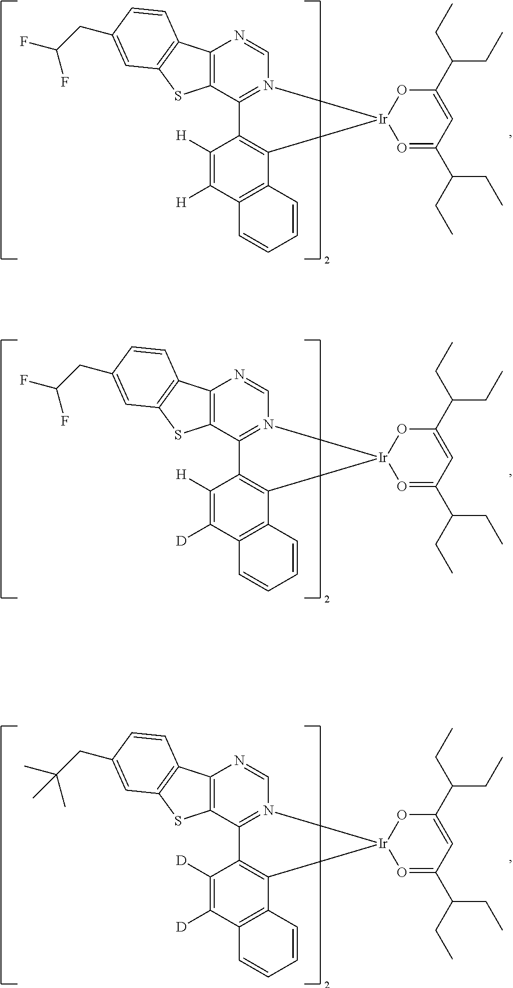

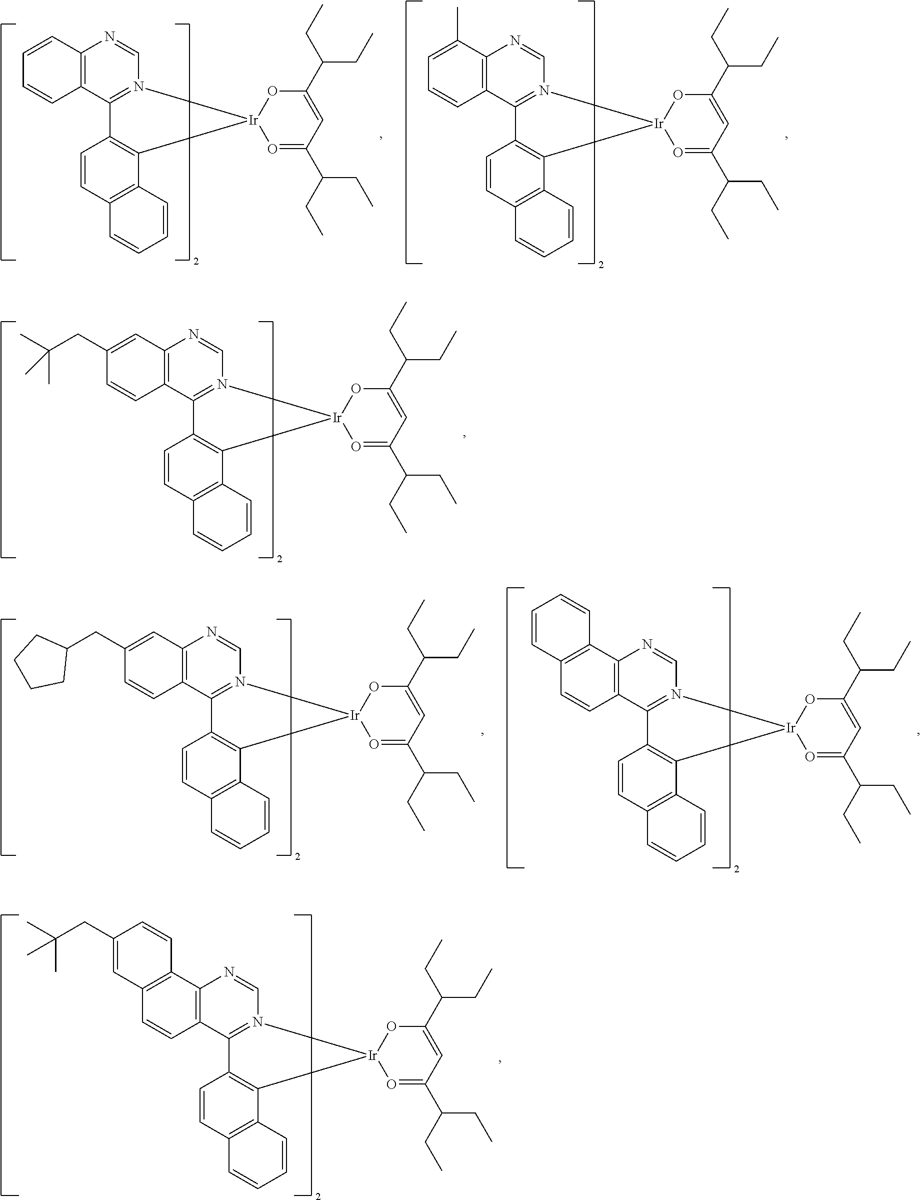

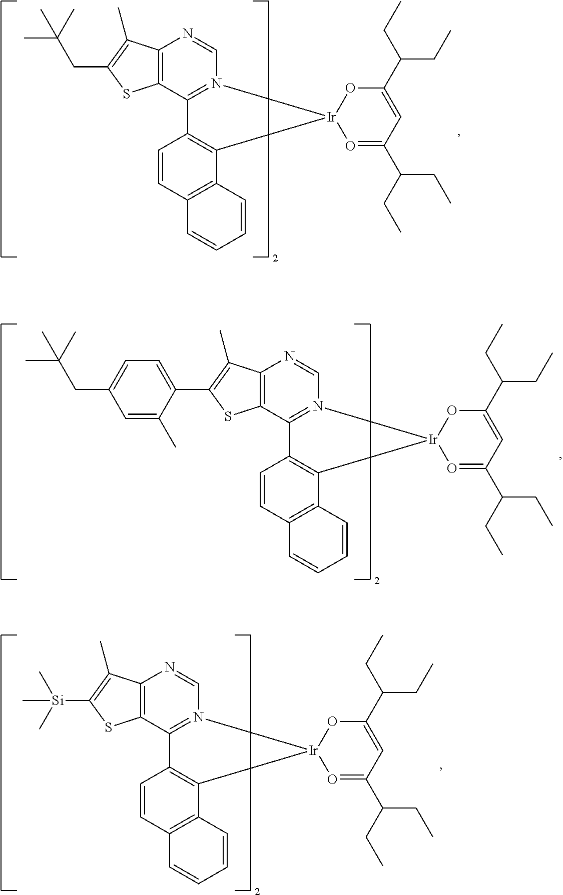

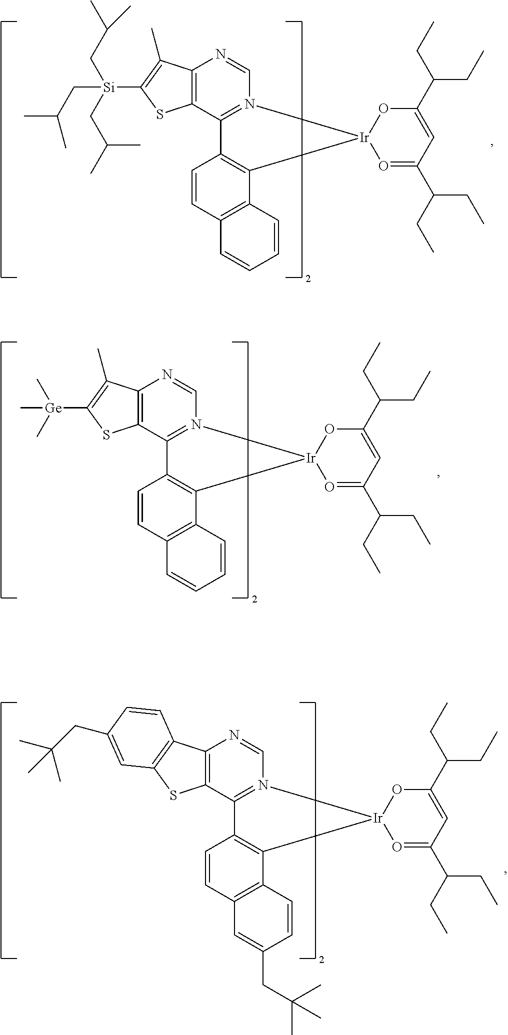

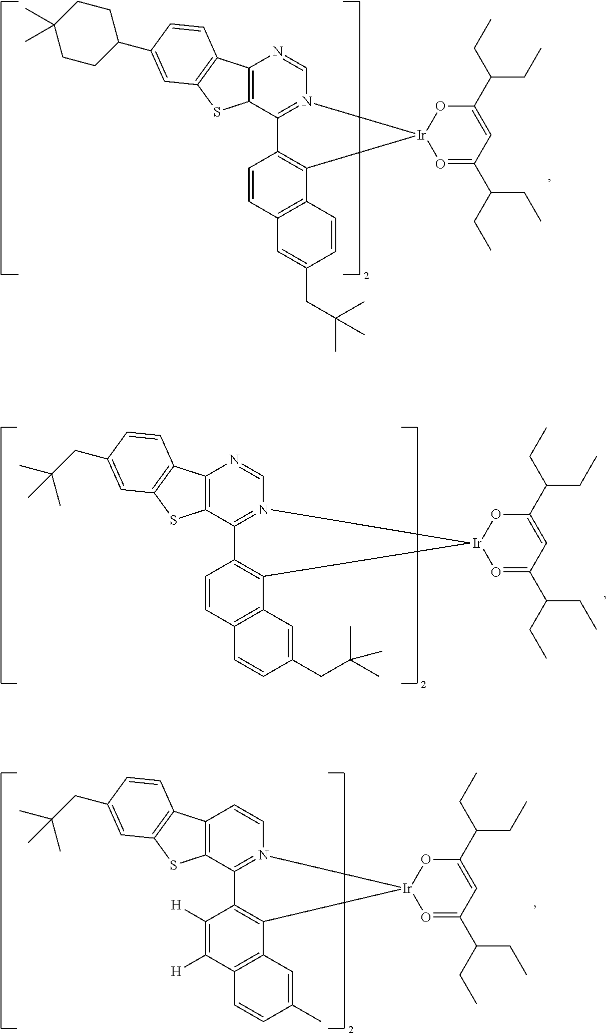

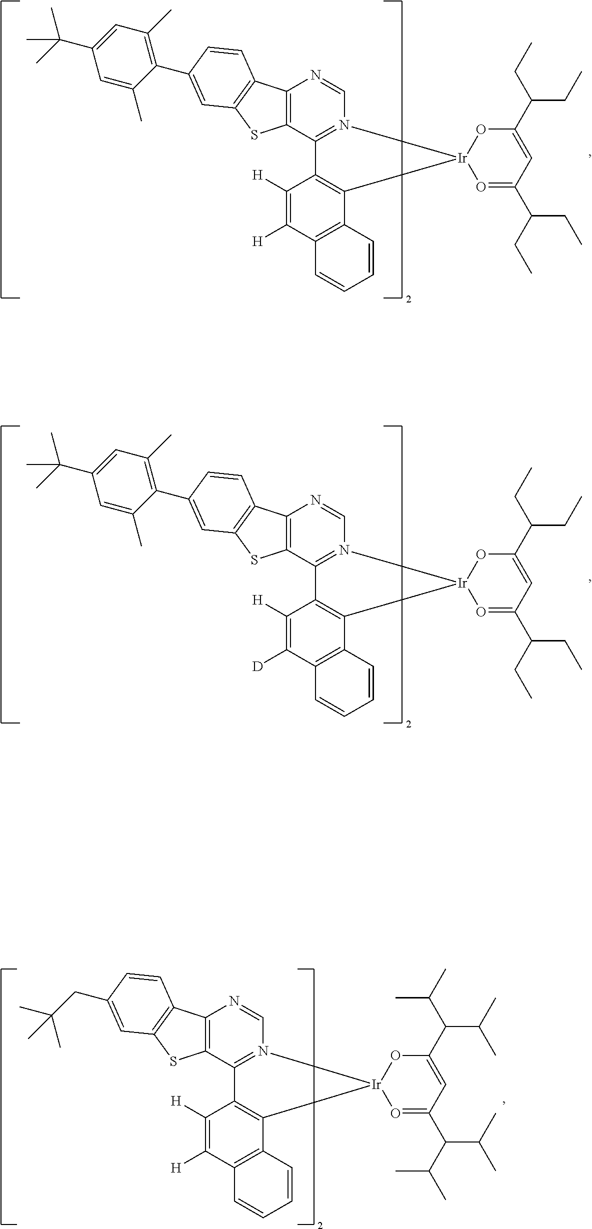

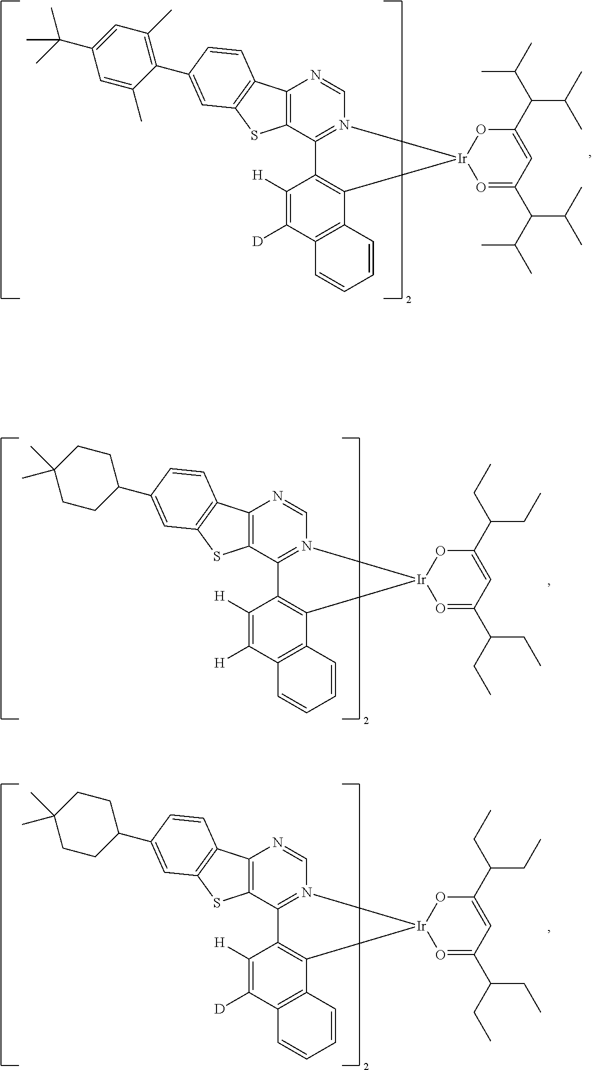

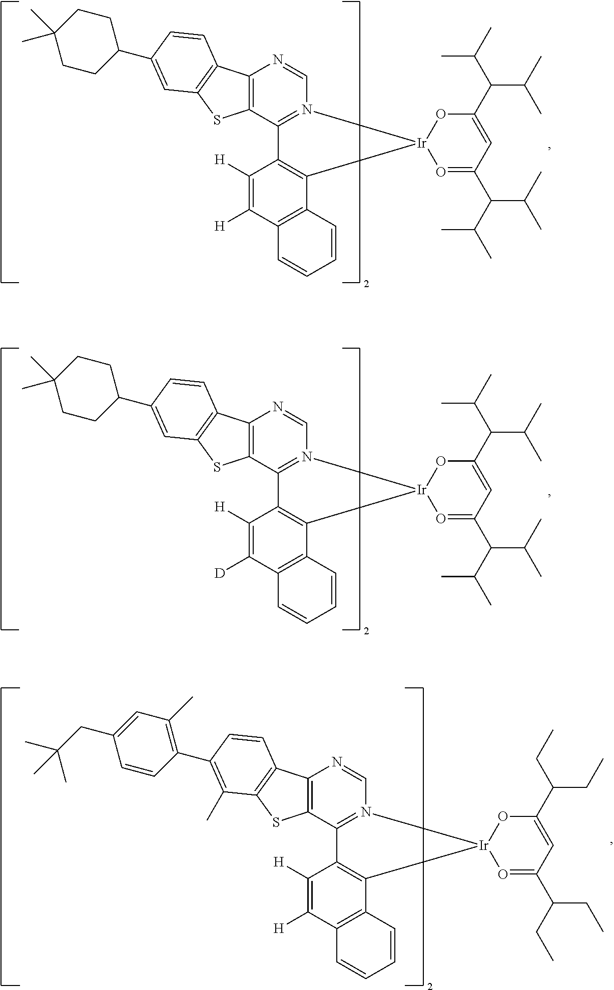

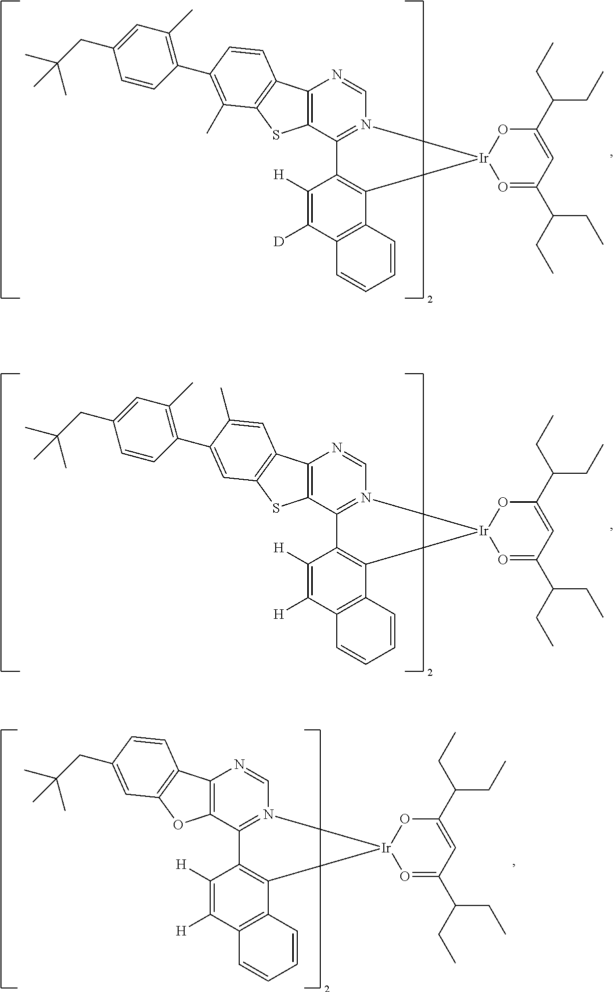

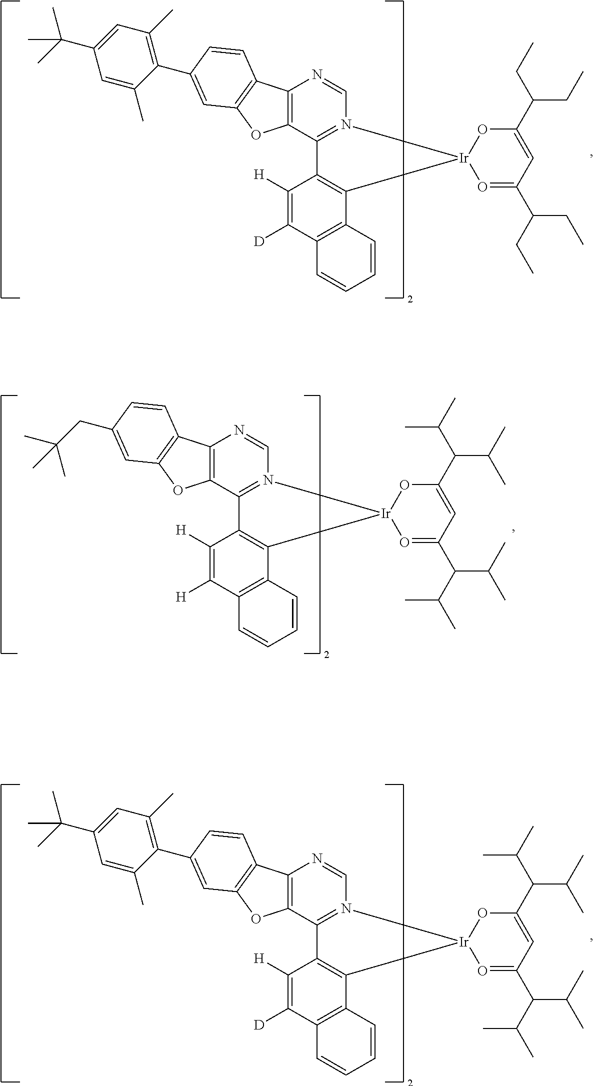

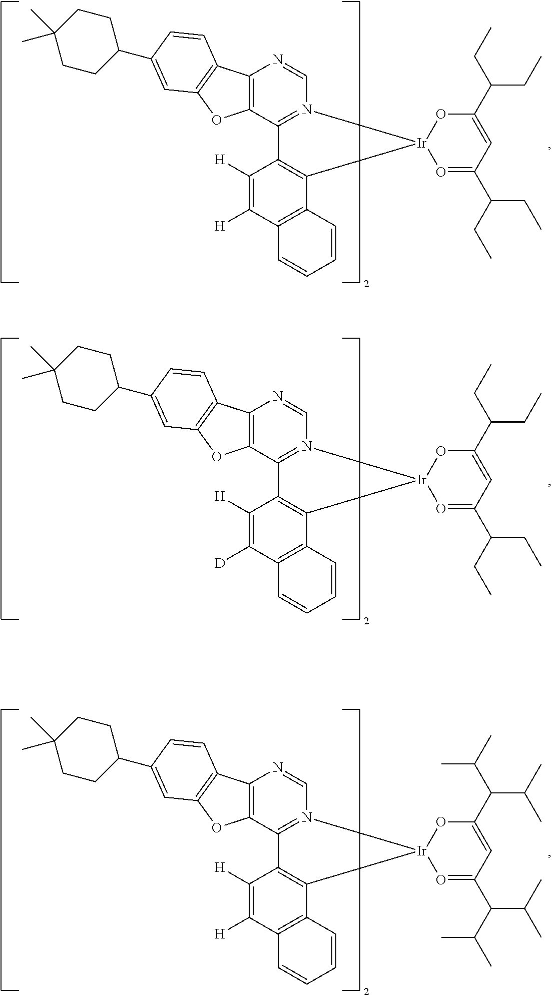

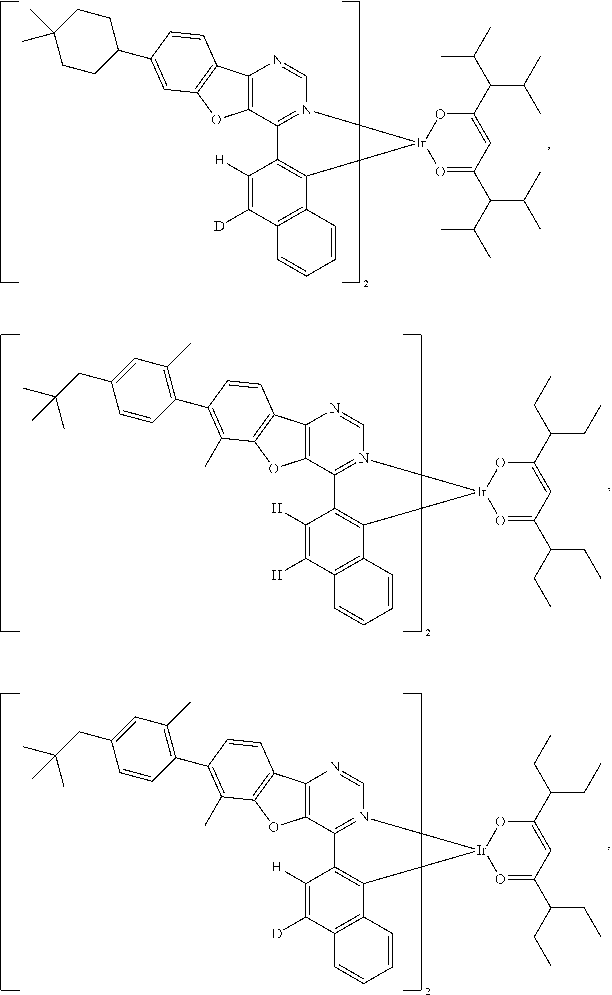

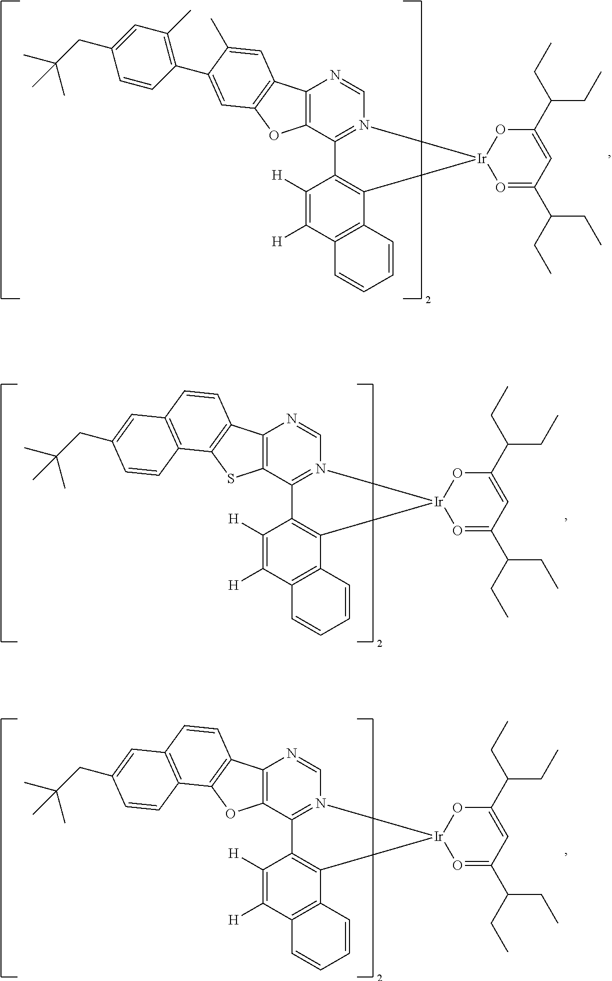

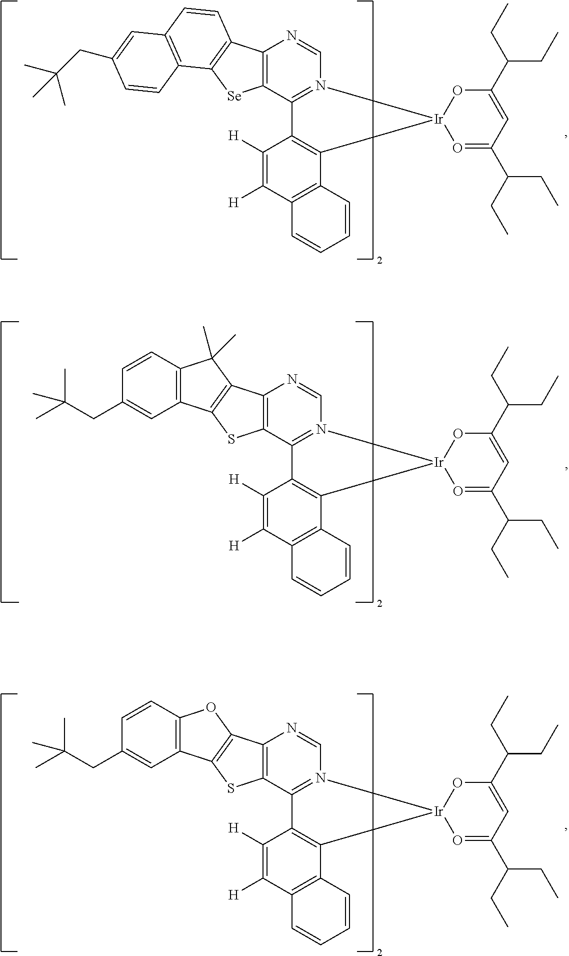

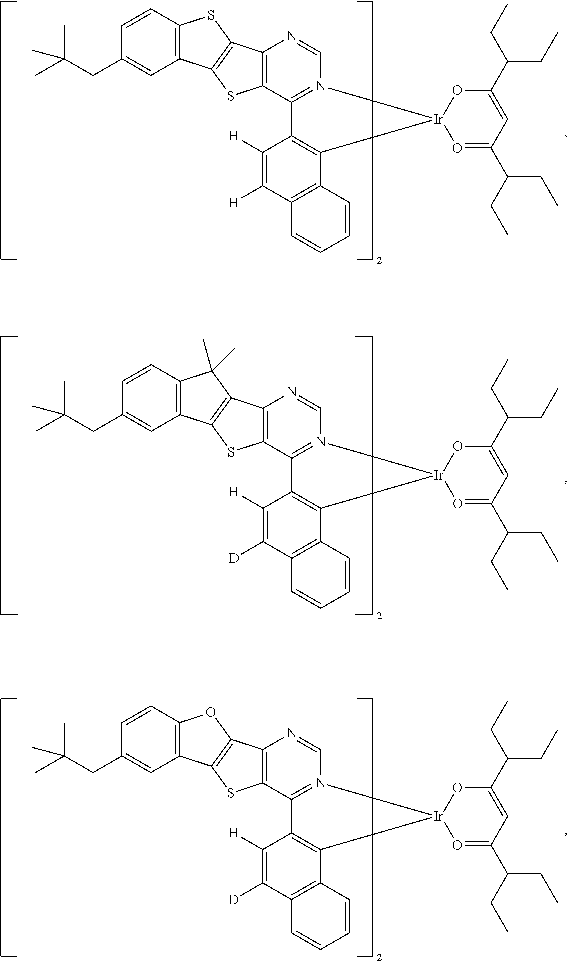

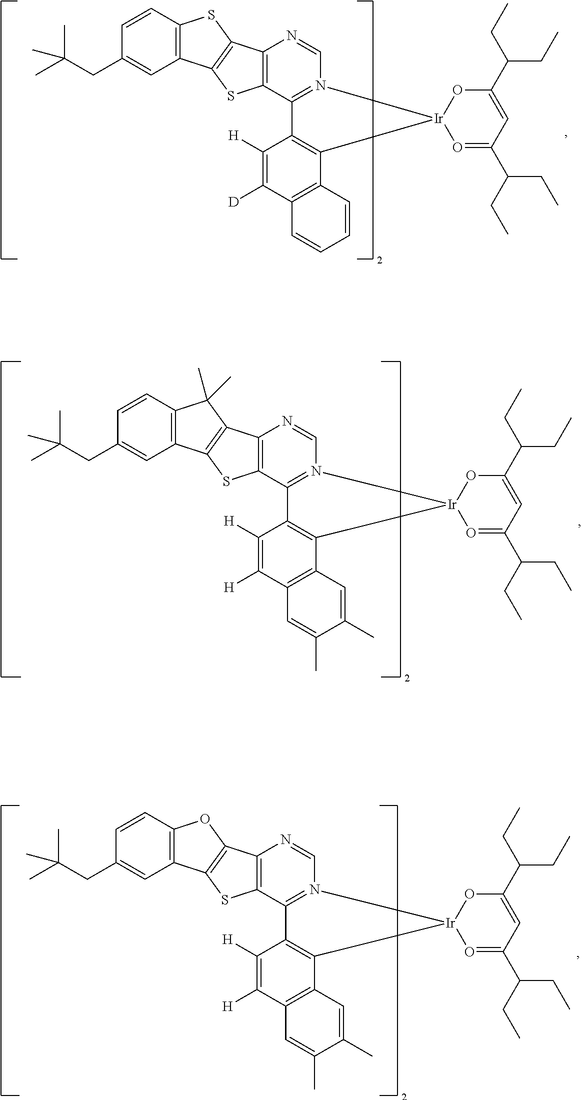

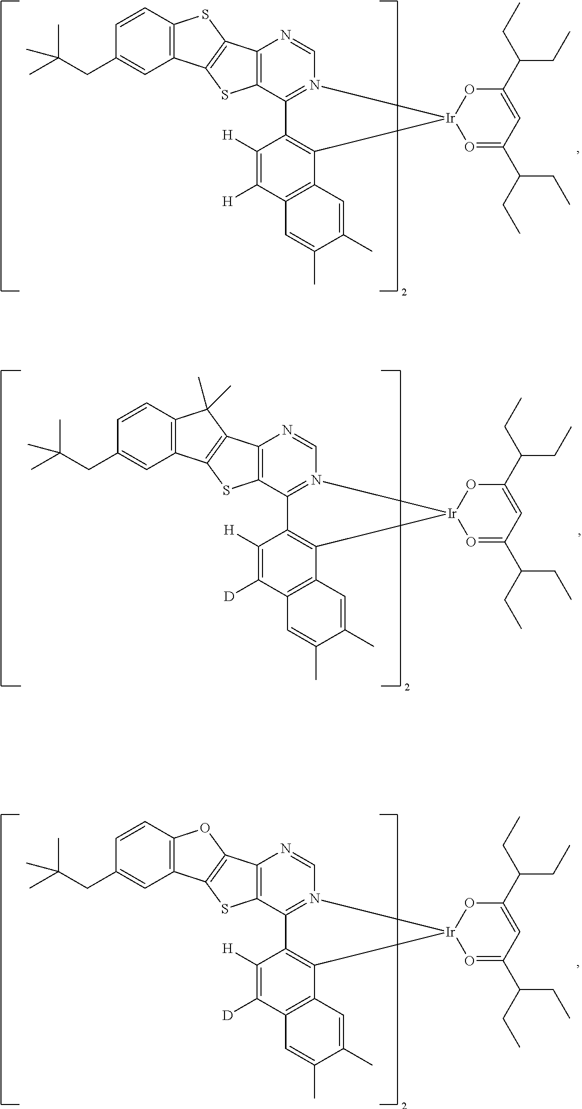

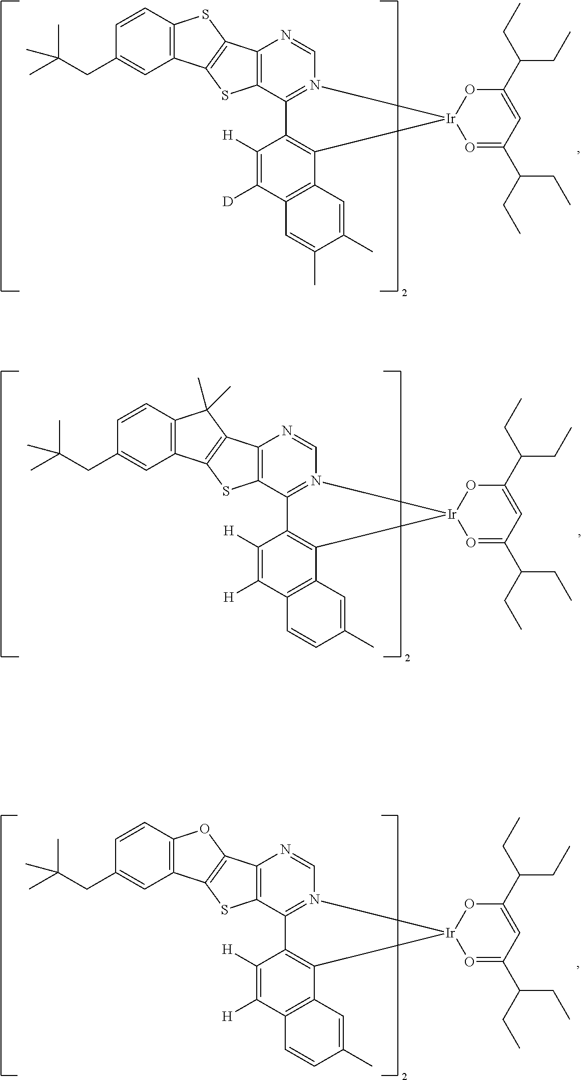

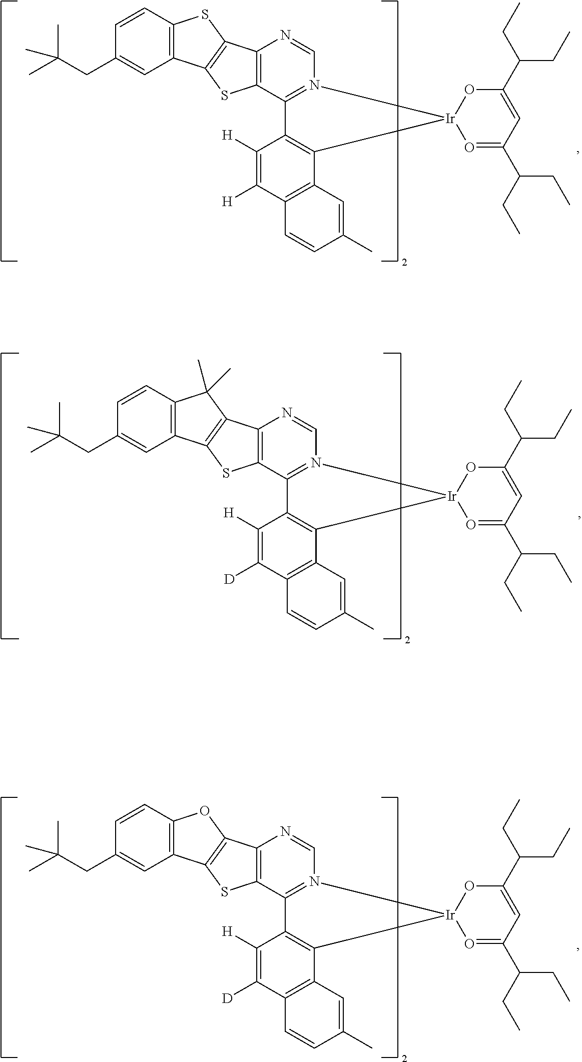

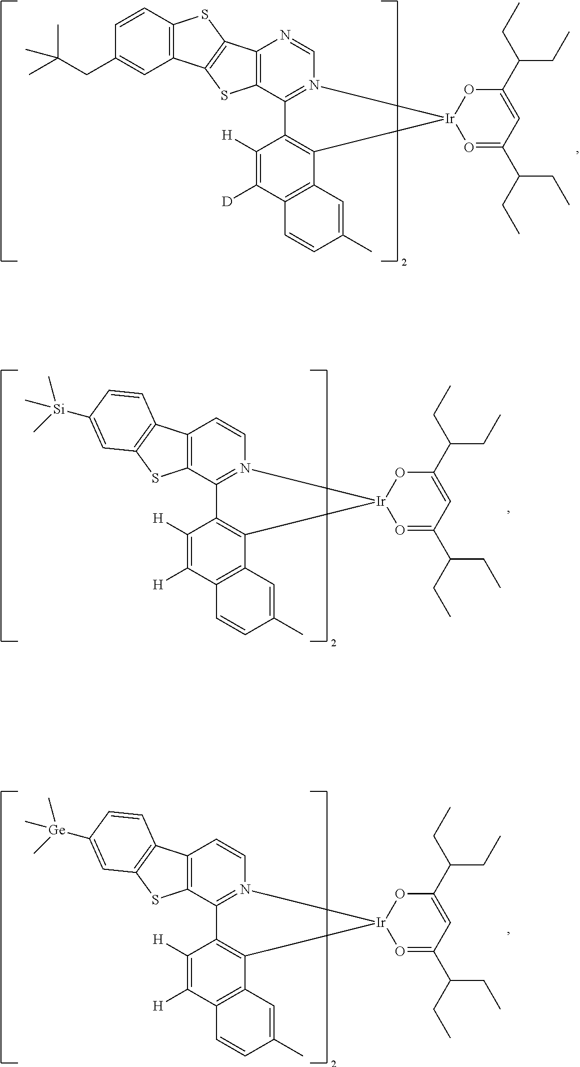

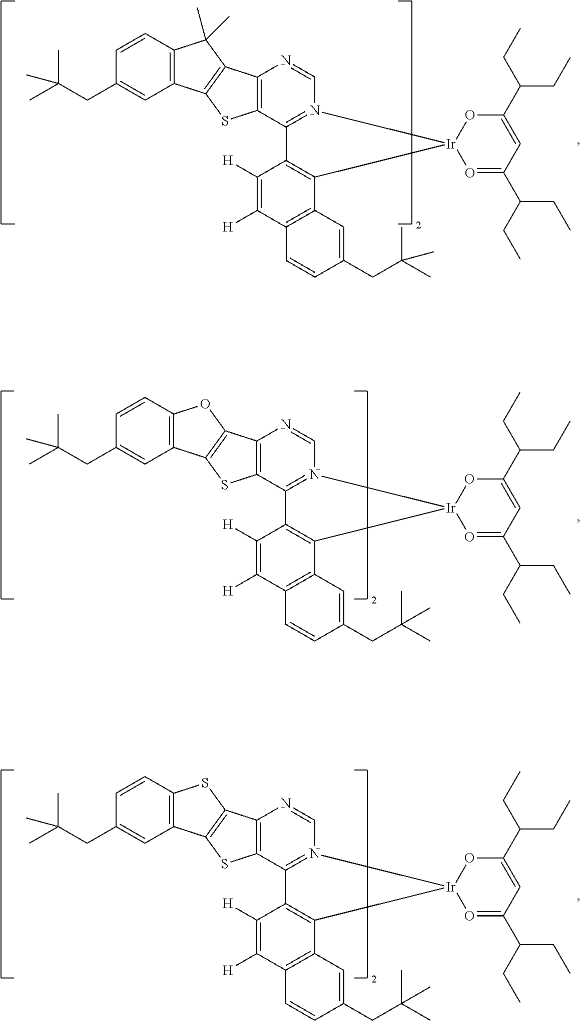

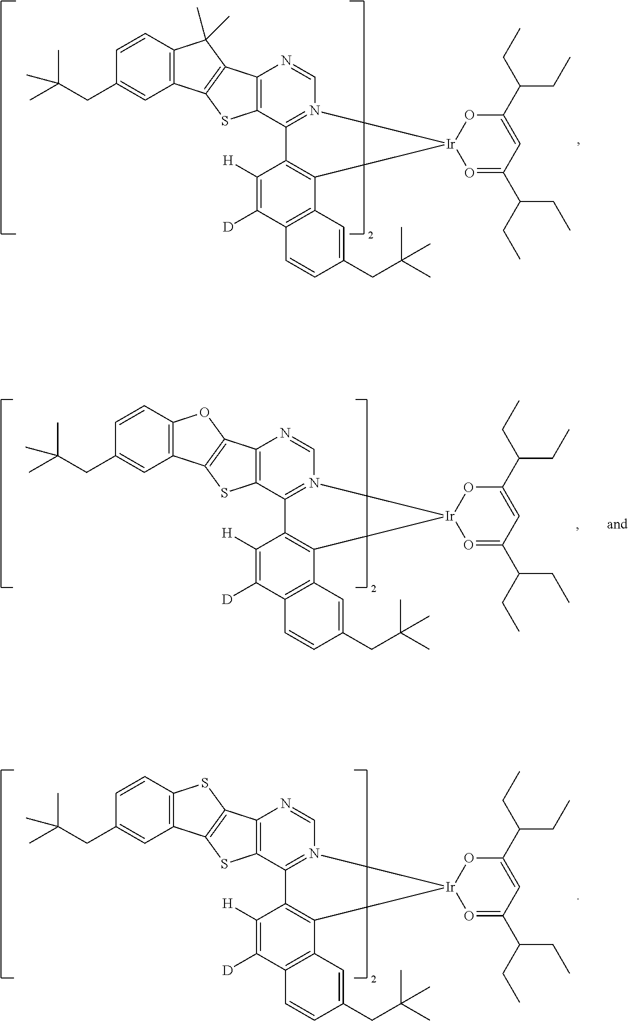

In some embodiments, the compound has the Formula II:

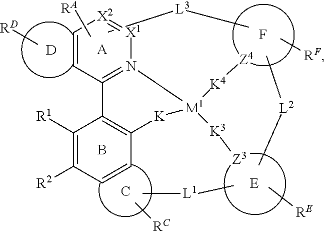

wherein:
M¹ is Pd or Pt;
moieties E and F are each independently monocyclic or polycyclic ring structure, wherein the monocyclic ring or each ring of the polycyclic fused ring system is independently a 5-membered to 10-membered carbocyclic or heterocyclic ring;
Z³ and Z⁴ are each independently C or N;
K, K³ and K⁴ are each independently selected from the group consisting of a direct bond, O, and S, wherein at least two of them are direct bonds;
L¹, L², and L³ are each independently absent or selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof, wherein at least one of L¹ and L² is present;
R^{E} and R^{F} each independently represents zero, mono, or up to a maximum allowed number of substitutions;
each of R, R′, R^{E}, and R^{F} is independently a hydrogen or a substituent selected from the group consisting of the General Substituents; and
two adjacent R^{A}, R^{B}, R^{C}, R^{E}, and R^{F} can be joined or fused together to form a ring.

In some embodiments of Formula II, each of R, R′, R^{A}, R^{C}, R^{D}, R^{E}, and R^{F} is independently a hydrogen or a substituent selected from the group consisting of the Preferred General Substituents.

In some embodiments, moieties E and F are each independently monocyclic or polycyclic ring structures, wherein the monocyclic ring or each ring of the polycyclic fused ring system is independently a 5-membered or 6-membered carbocyclic or heterocyclic rings.

In some embodiments of Formula II, at least one of R, R′, R¹, R², R^{A}, R^{C}, R^{D}, R^{E}, or R^{F} is partially or fully deuterated. In some embodiments, R¹ is D. In some embodiments, R² is D. In some embodiments, at least one of R^{A} is partially or fully deuterated. In some embodiments, at least one of R^{C} is partially or fully deuterated. In some embodiments, at least one of R^{D} is partially or fully deuterated. In some embodiments, at least one of R^{E} is partially or fully deuterated. In some embodiments, at least one of R^{F} is partially or fully deuterated. In some embodiments, at least one of R or R′ is partially or fully deuterated.

In some embodiments of Formula II, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments of Formula II, at least one R¹ or R² is or comprises an electron-withdrawing group from the EWG1 LIST as defined herein. In some embodiments, at least one R¹ or R² is or comprises an electron-withdrawing group from the EWG2 LIST as defined herein. In some embodiments, at least one R¹ or R² is or comprises an electron-withdrawing group from the EWG3 LIST as defined herein. In some embodiments, at least one R¹ or R² is or comprises an electron-withdrawing group from the EWG4 LIST as defined herein. In some embodiments, at least one R¹ or R² is or comprises an electron-withdrawing group from the Pi-EWG LIST as defined herein.

In some embodiments of Formula II, at least one R^{C} is or comprises an electron-withdrawing group from the EWG1 LIST as defined herein. In some embodiments, at least one R^{C} is or comprises an electron-withdrawing group from the EWG2 LIST as defined herein. In some embodiments, at least one R^{C} is or comprises an electron-withdrawing group from the EWG3 LIST as defined herein. In some embodiments, at least one R^{C} is or comprises an electron-withdrawing group from the EWG4 LIST as defined herein. In some embodiments, at least one R^{C} is or comprises an electron-withdrawing group from the Pi-EWG LIST as defined herein.

In some embodiments of Formula II, at least one R^{D} is or comprises an electron-withdrawing group from the EWG1 LIST as defined herein. In some embodiments, at least one R^{D} is or comprises an electron-withdrawing group from the EWG2 LIST as defined herein. In some embodiments, at least one R^{D} is or comprises an electron-withdrawing group from the EWG3 LIST as defined herein. In some embodiments, at least one R^{D} is or comprises an electron-withdrawing group from the EWG4 LIST as defined herein. In some embodiments, at least one R^{D} is or comprises an electron-withdrawing group from the Pi-EWG LIST as defined herein.

In some embodiments of Formula II, at least one R^{E} is or comprises an electron-withdrawing group from the EWG1 LIST as defined herein. In some embodiments, at least one R^{E} is or comprises an electron-withdrawing group from the EWG2 LIST as defined herein. In some embodiments, at least one R^{E} is or comprises an electron-withdrawing group from the EWG3 LIST as defined herein. In some embodiments, at least one R^{E} is or comprises an electron-withdrawing group from the EWG4 LIST as defined herein. In some embodiments, at least one R^{E} is or comprises an electron-withdrawing group from the Pi-EWG LIST as defined herein.

In some embodiments of Formula II, at least one R^{F} is or comprises an electron-withdrawing group from the EWG1 LIST as defined herein. In some embodiments, at least one R^{F} is or comprises an electron-withdrawing group from the EWG2 LIST as defined herein. In some embodiments, at least one R^{F} is or comprises an electron-withdrawing group from the EWG3 LIST as defined herein. In some embodiments, at least one R^{F} is or comprises an electron-withdrawing group from the EWG4 LIST as defined herein. In some embodiments, at least one R^{F} is or comprises an electron-withdrawing group from the Pi-EWG LIST as defined herein.

In some embodiments of Formula II, at least one R or R′ is or comprises an electron-withdrawing group from the EWG1 LIST as defined herein. In some embodiments, at least one R or R′ is or comprises an electron-withdrawing group from the EWG2 LIST as defined herein. In some embodiments, at least one R or R′ is or comprises an electron-withdrawing group from the EWG3 LIST as defined herein. In some embodiments, at least one R or R′ is or comprises an electron-withdrawing group from the EWG4 LIST as defined herein. In some embodiments, at least one R or R′ is or comprises an electron-withdrawing group from the Pi-EWG LIST as defined herein.

In some embodiments, Formula II comprises an electron-withdrawing group from the EWG1 LIST as defined herein. In some embodiments, Formula II comprises an electron-withdrawing group from the EWG2 LIST as defined herein. In some embodiments, Formula II comprises an electron-withdrawing group from the EWG3 LIST as defined herein. In some embodiments, Formula II comprises an electron-withdrawing group from the EWG4 LIST as defined herein. In some embodiments, Formula II comprises an electron-withdrawing group from the Pi-EWG LIST as defined herein.]

In some embodiments, moiety E and moiety F are both 6-membered aromatic rings. In some embodiments, moiety F is a 5-membered or 6-membered heteroaromatic ring.

In some embodiments, L¹ is O or CRR′.

In some embodiments, Z⁴ is N and Z³ is C. In some embodiments, Z⁴ is C and Z³ is N.

In some embodiments, L² is a direct bond. In some embodiments, L² is NR.

In some embodiments, K, K³, and K⁴ are all direct bonds. In some embodiments, one of K, K³, and K⁴ is O.

In some embodiments, the compound is selected from the group consisting of compounds having the formula of Pt(L_{A′})(Ly):

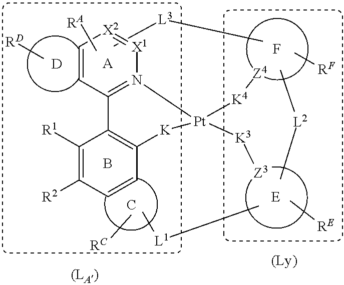

wherein L_{A′} is selected from the group consisting of the structures shown in the following LIST 12:

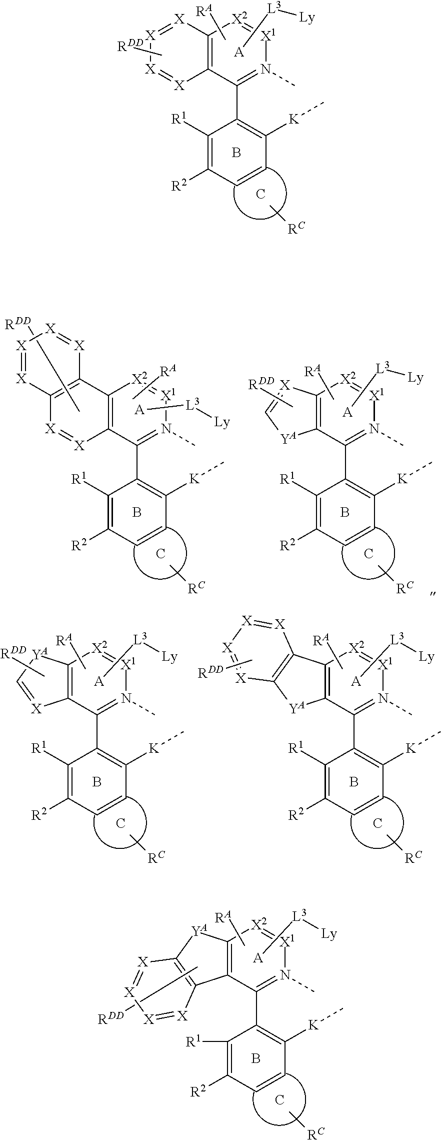

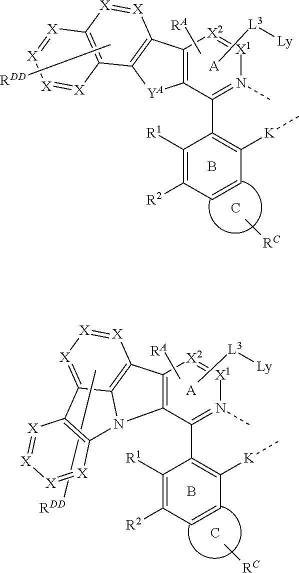

wherein L_{y} is selected from the group consisting of the structures of the following LIST 13:

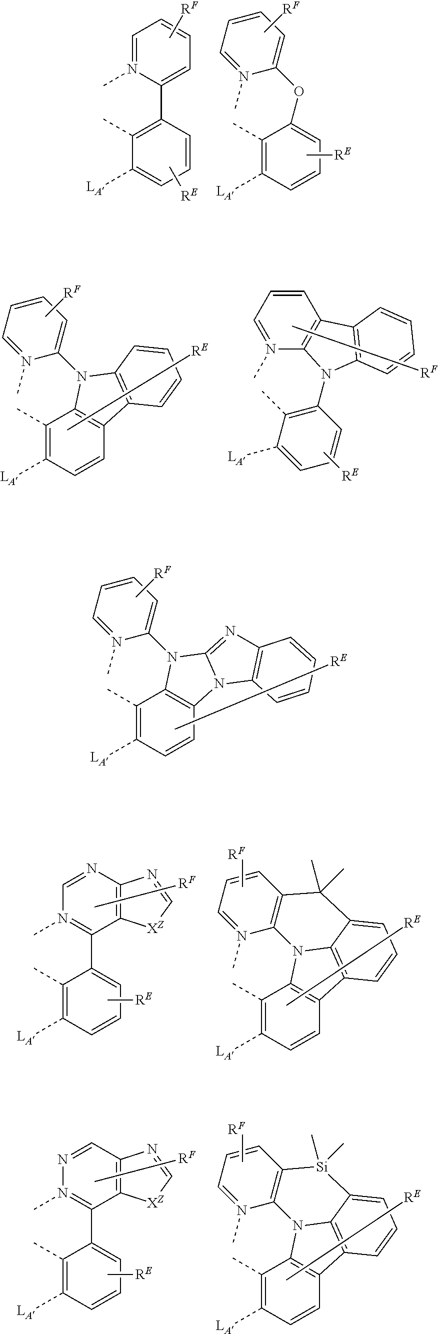

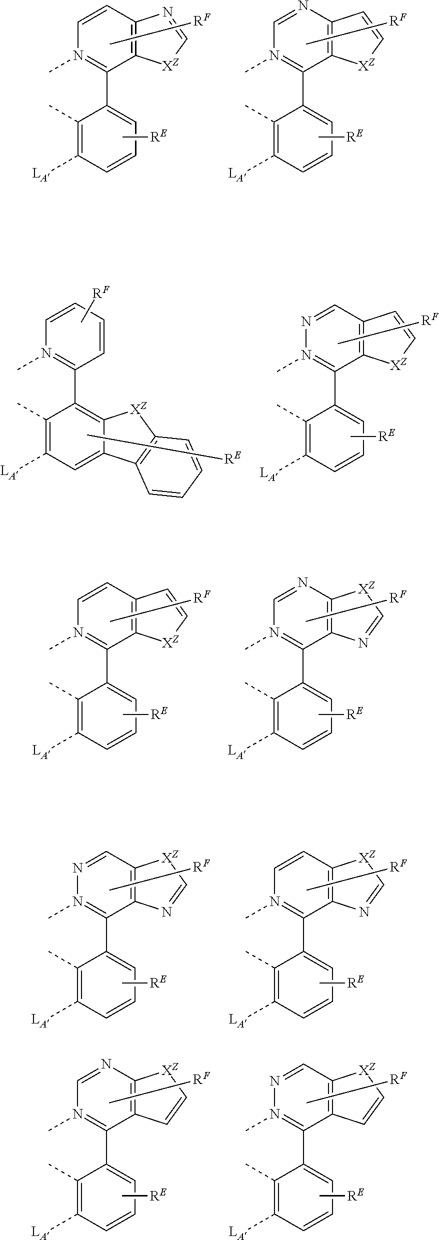

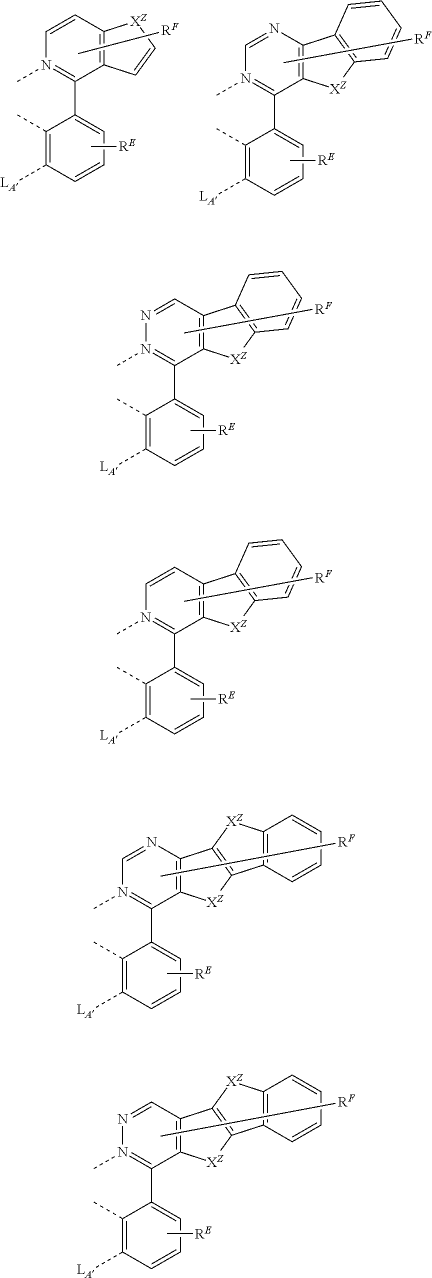

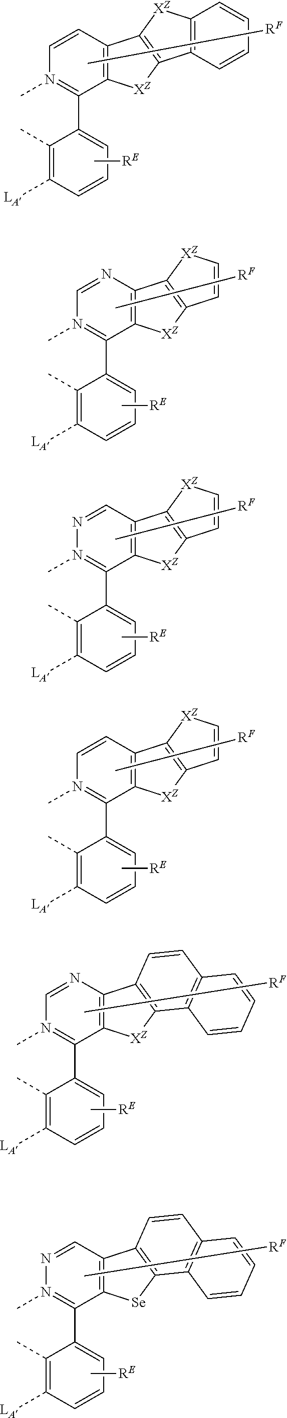

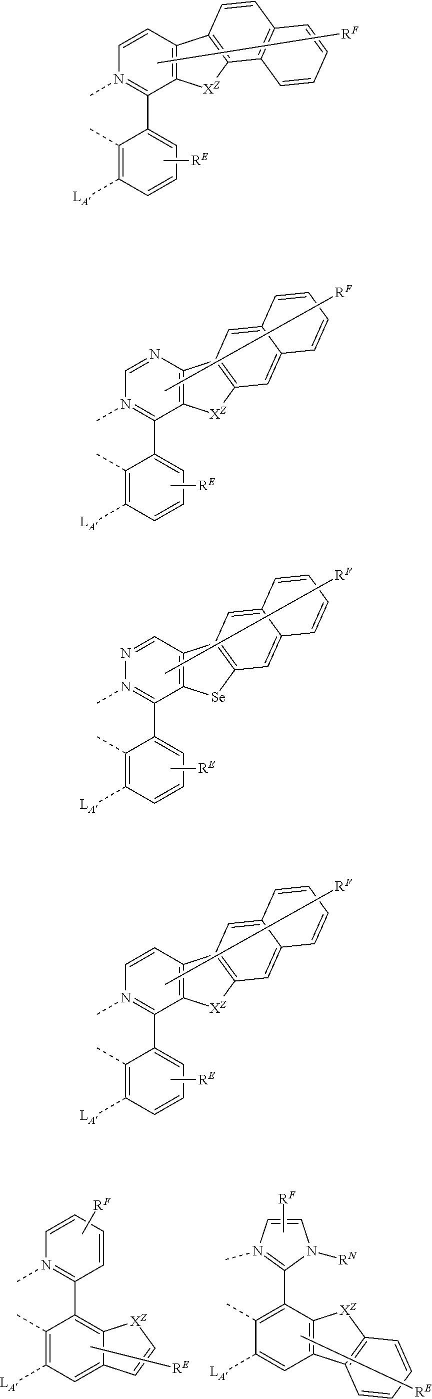

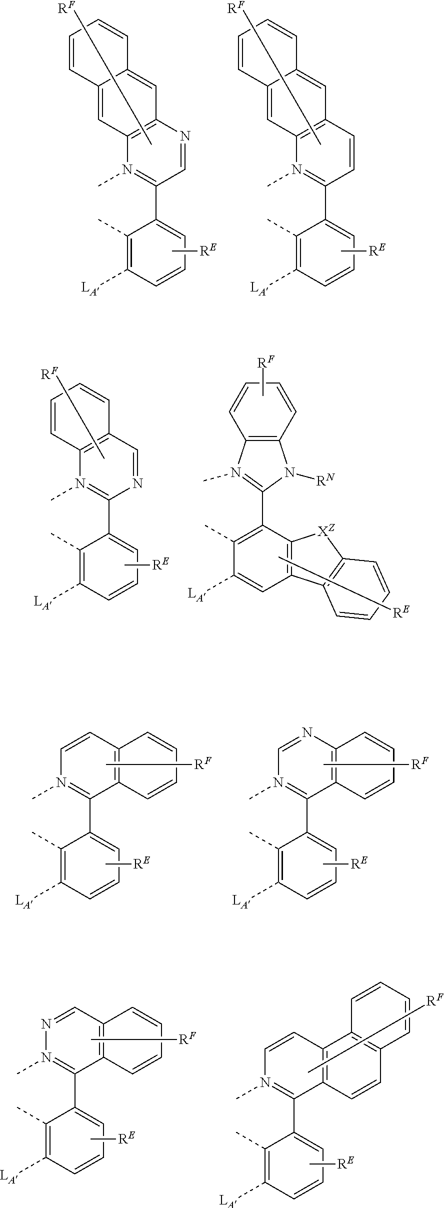

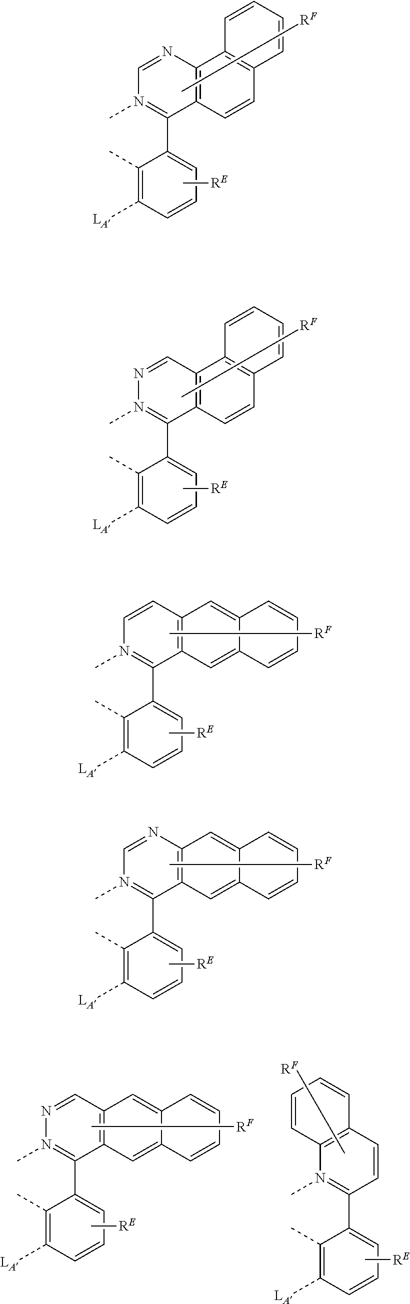

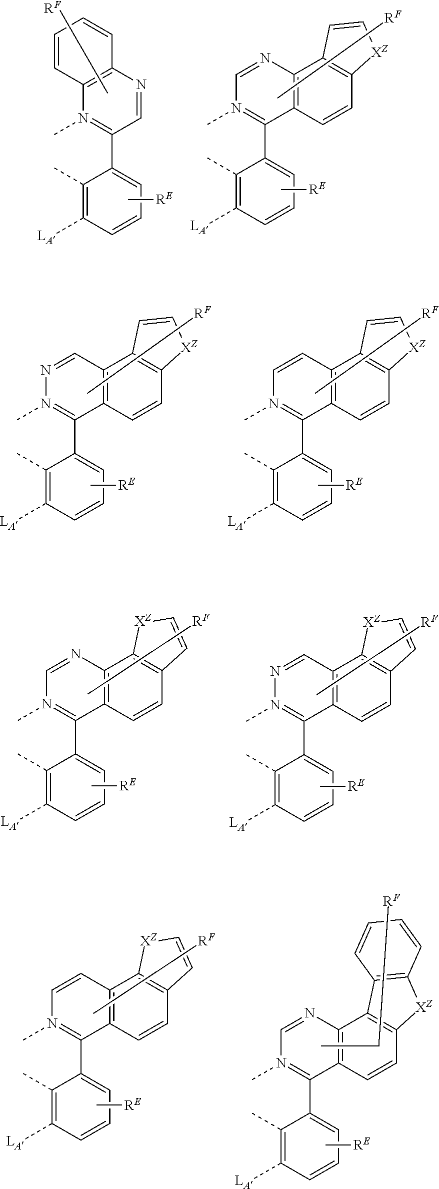

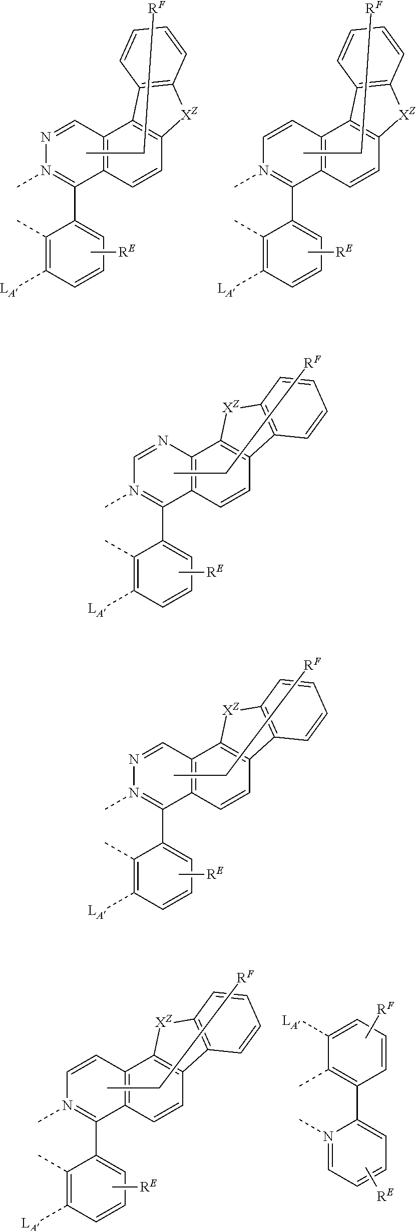

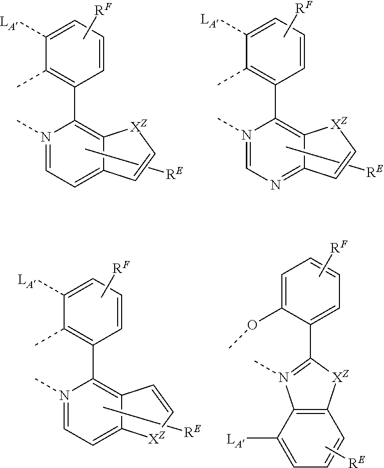

wherein:
for each occurrence, X is independently C or N;
Y^{A} and each occurrence of X^{Z} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
R^{DD} represents mono to the maximum allowable substitution, or no substitution;
each R, R′, R^{N}, and R^{DD} is independently hydrogen or a substituent selected from the group consisting of the General Substituents; and
any two substituents may be optionally joined or fused to form a ring.

In some embodiments, the compound is selected from the group consisting of the compounds having the formula of Pt(L_{A′})(LY):

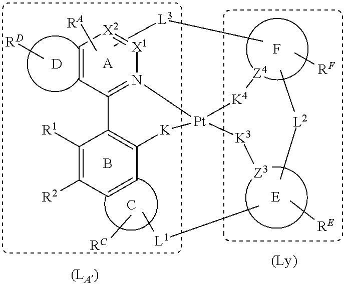

wherein L_{A′} is selected from the group consisting of L_{A′i′}(R^{EA})(R^{EB})(R^{EC})(R^{ED})(R^{EE})(P), wherein i′ is an integer from 1 to 4, each of R^{EA}, R^{EB}, R^{EC}, R^{ED}, and R^{EE} is independently selected from the group consisting of R¹ to R¹⁵⁰, and P is an integer from 1 to 5; wherein L_{A′1}(R¹)(R¹)(R¹)(R¹)(R¹)(1) to L_{A′4}(R¹⁵⁰)(R¹⁵⁰)(R¹⁵⁰)(R¹⁵⁰)(R¹⁵⁰)(5) have the structures defined in the following LIST 14:

| L_{A′} | Structure of L_{A′} |
|---|---|
| L_{A′1}(R^{EA})(R^{EB})(R^{EC}) (R^{ED})(R^{EE})(P), wherein L_{A′1}(R¹)(R¹)(R¹) (R¹)(R¹)(1) to L_{A′1}(R¹⁵⁰)(R¹⁵⁰)(R¹⁵⁰) (R¹⁵⁰)(R¹⁵⁰)(5) have the structure | 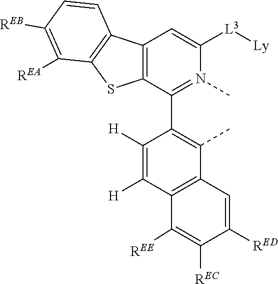 |
| L_{A′2}(R^{EA})(R^{EB})(R^{EC}) (R^{ED})(R^{EE})(P), wherein L_{A′2}(R¹)(R¹)(R¹) (R¹)(R¹)(1) to L_{A′2}(R¹⁵⁰)(R¹⁵⁰)(R¹⁵⁰) (R¹⁵⁰)(R¹⁵⁰)(5) have the structure | 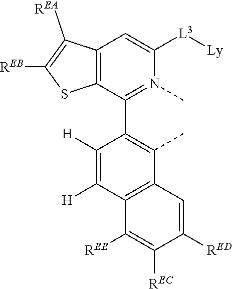 |
| L_{A′3}(R^{EA})(R^{EB})(R^{EC}) (R^{ED})(R^{EE})(P), wherein L_{A′3}(R¹)(R¹)(R¹) (R¹)(R¹)(1) to L_{A′3}(R¹⁵⁰)(R¹⁵⁰)(R¹⁵⁰) (R¹⁵⁰)(R¹⁵⁰)(5) have the structure | 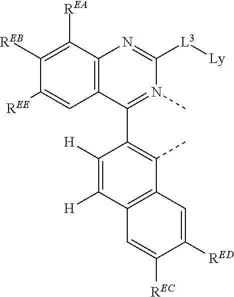 |
| L_{A′4}(R^{EA})(R^{EB})(R^{EC}) (R^{ED})(R^{EE})(P), wherein L_{A′4}(R¹)(R¹)(R¹) (R¹)(R¹)(1) to L_{A′4}(R¹⁵⁰)(R¹⁵⁰)(R¹⁵⁰) (R¹⁵⁰)(R¹⁵⁰)(5) have the structure | 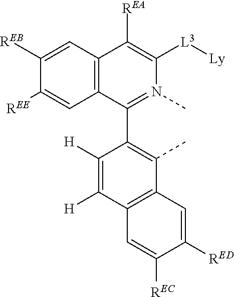 |

wherein Ly is selected from the group consisting of L_{Yw}(R^{FA})(R^{FB}), wherein w is an integer from 1 to 4, and each of R^{FA} and R^{FB} is independently selected from the group consisting of R1 to R150, wherein L_{Y1}(R¹)(R¹) to L_{Y4}(R¹⁵⁰)(R¹⁵⁰) have the structure defined in the following LIST 15:

| L_{Y} | Structure of L_{Y} |
|---|---|
| for L_{Y1}(R^{FA})(R^{FB}), L_{Y1}(R¹)(R¹) to L_{Y1}(R¹⁵⁰)(R¹⁵⁰) have the structure | 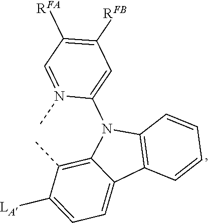 |
| for L_{Y2}(R^{FA})(R^{FB}), L_{Y2}(R¹)(R¹) to L_{Y2}(R¹⁵⁰)(R¹⁵⁰) have the structure | 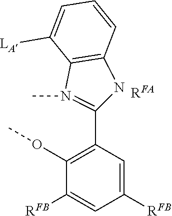 |
| for L_{Y3}(R^{FA})(R^{FB}), L_{Y3}(R¹)(R¹) to L_{Y3}(R¹⁵⁰)(R¹⁵⁰) have the structure | 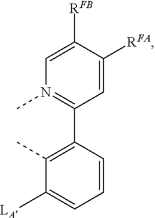 |
| for L_{Y4}(R^{FA})(R^{FB}), L_{Y4}(R¹)(R¹) to L_{Y4}(R¹⁵⁰)(R¹⁵⁰) have the structure | 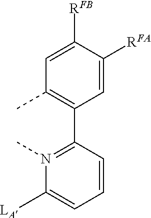 |

wherein each of R¹ to R¹⁵⁰ has the structure defined in LIST 4 defined herein; and
wherein, for each of P=1 to P=5, L³ has the meaning defined as follows:

| P = 1 | P = 2 | P = 3 | P = 4 | P = 5 |
|---|---|---|---|---|
| L³ = direct bond | L³ = O | L³ = S | L³ = Se | L³ = N(CH₃) |

In some embodiments, the compound is selected from the group consisting of the structures of the following LIST 16:

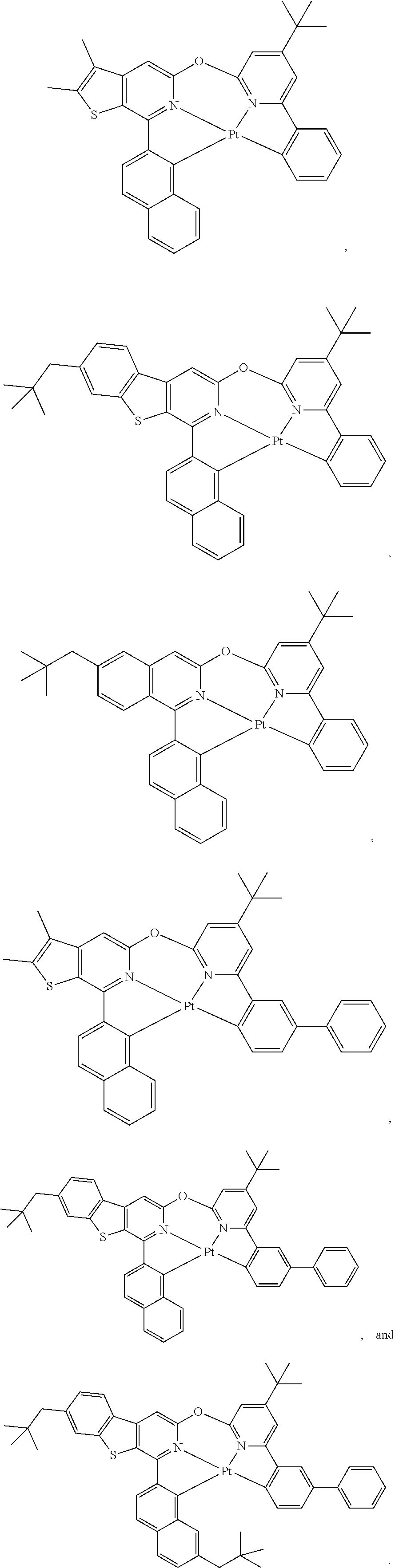

In some embodiments, the compound having a first ligand L_{A} of Formula I described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of all possible hydrogen atoms in the compound (e.g., positions that are hydrogen or deuterium) that are occupied by deuterium atoms. In some embodiments, carbon atoms comprised the ring coordinated to the metal M are fully or partially deuterated. In some embodiments, carbon atoms comprised by a polycyclic ring system coordinated to the metal M are fully or partially deuterated. In some embodiments, a substituent attached to a monocyclic or fused polycyclic ring system coordinated to the metal M is fully or partially deuterated.

In some embodiments, the compound of formula I has an emission at room temperature with a full width at half maximum (FWHM) of equal to or less than 50, 45, 40, 35, 30, 25, 20, 15, 10, or 5 nm. Narrower FWHM means better color purity for the OLED display application.

In some embodiments of heteroleptic compound having the formula of M(L_{A})ₚ(L_{B})_{q}(L_{C})ᵣ as defined above, the ligand L_{A} has a first substituent R^{I}, where the first substituent R^{I} has a first atom a-I that is the farthest away from the metal M among all atoms in the ligand L_{A}. Additionally, the ligand L_{B}, if present, has a second substituent R^{II}, where the second substituent R^{II} has a first atom a-II that is the farthest away from the metal M among all atoms in the ligand L_{B}. Furthermore, the ligand L_{C}, if present, has a third substituent R^{III}, where the third substituent R^{III} has a first atom a-III that is the farthest away from the metal M among all atoms in the ligand L_{C}.

In such heteroleptic compounds, vectors V_{D1}, V_{D2}, and V_{D3} can be defined as follows. V_{D1} represents the direction from the metal M to the first atom a-I and the vector V_{D1} has a value D¹ that represents the straight line distance between the metal M and the first atom a-I in the first substituent R^{I}. V_{D2} represents the direction from the metal M to the first atom a-II and the vector V_{D2} has a value D² that represents the straight line distance between the metal M and the first atom a-II in the second substituent R^{II}. V_{D3} represents the direction from the metal M to the first atom a-III and the vector V_{D3} has a value D³ that represents the straight line distance between the metal M and the first atom a-III in the third substituent R^{III}.

In such heteroleptic compounds, a sphere having a radius r is defined whose center is the metal M and the radius r is the smallest radius that will allow the sphere to enclose all atoms in the compound that are not part of the substituents R^{I}, R^{II} and R^{III}; and where at least one of D¹, D², and D³ is greater than the radius r by at least 1.5 Å. In some embodiments, at least one of D¹, D², and D³ is greater than the radius r by at least 2.9, 3.0, 4.3, 4.4, 5.2, 5.9, 7.3, 8.8, 10.3, 13.1, 17.6, or 19.1 Å. In some embodiments, at least two of D¹, D², and D³ is greater than the radius r by at least 1.5, 2.9, 3.0, 4.3, 4.4, 5.2, 5.9, 7.3, 8.8, 10.3, 13.1, 17.6, or 19.1 Å.

In some embodiments of such heteroleptic compound, the compound has a transition dipole moment axis and angles are defined between the transition dipole moment axis and the vectors V_{D1}, V_{D2}, and V_{D3}, where at least one of the angles between the transition dipole moment axis and the vectors V_{D1}, V_{D2}, and V_{D3} is less than 40°. In some embodiments, at least one of the angles between the transition dipole moment axis and the vectors V_{D1}, V_{D2}, and V_{D3} is less than 30°, 20°, 15°, or 10°. In some embodiments, at least two of the angles between the transition dipole moment axis and the vectors V_{D1}, V_{D2}, and V_{D3} are less than 20°. In some embodiments, at least two of the angles between the transition dipole moment axis and the vectors V_{D1}, V_{D2}, and V_{D3} are less than 150 or 10°.

In some embodiments, all three angles between the transition dipole moment axis and the vectors V_{D1}, V_{D2}, and V_{D3} are less than 20°. In some embodiments, all three angles between the transition dipole moment axis and the vectors V_{D1}, V_{D2}, and V_{D3} are less than 150 or 10°.

In some embodiments of such heteroleptic compounds, the compound has a vertical dipole ratio (VDR) of 0.33 or less. In some embodiments of such heteroleptic compounds, the compound has a VDR of 0.30, 0.25, 0.20, or 0.15 or less.

One of ordinary skill in the art would readily understand the meaning of the terms transition dipole moment axis of a compound and vertical dipole ratio of a compound. Nevertheless, the meaning of these terms can be found in U.S. Pat. No. 10,672,997 whose disclosure is incorporated herein by reference in its entirety. In U.S. Pat. No. 10,672,997, horizontal dipole ratio (HDR) of a compound, rather than VDR, is discussed. However, one skilled in the art readily understands that VDR=1−HDR.

In some embodiments, the compound can be an emissive dopant. In some embodiments, the compound can produce emissions via phosphorescence, fluorescence, thermally activated delayed fluorescence, triplet-triplet annihilation, or combinations of these processes. In some embodiments, the emissive dopant can be a racemic mixture, or can be enriched in one enantiomer. In some embodiments, the present compounds can have different stereoisomers, such as fac and mer. The current compound relates both to individual isomers and to mixtures of various isomers in any mixing ratio. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from every other ligand. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In yet another aspect of the present disclosure, a formulation that comprises the novel compound disclosed herein is described. The formulation can include one or more components selected from the group consisting of a solvent, an emitter, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds. As used in this context, the description that a structure A comprises a moiety B means that the structure A includes the structure of moiety B not including the H or D atoms that can be attached to the moiety B. This is because at least one H or D on a given moiety structure has to be replaced to become a substituent so that the moiety B can be part of the structure A, and one or more of the H or D on a given moiety B structure can be further substituted once it becomes a part of structure A.

### C. The OLEDs and the Devices of the Present Disclosure

In another aspect, the present disclosure also provides an OLED device comprising a first organic layer that contains a compound as disclosed in the above compounds section of the present disclosure.

In some embodiments, the OLED comprises: an anode; a cathode; and an organic layer disposed between the anode and the cathode, where the organic layer comprises a compound having a first ligand L_{A} comprising a structure of Formula I as described herein.

In some embodiments, the organic layer is selected from the group consisting of HIL, HTL, EBL, EML, HBL, ETL, and EIL. In some embodiments, the organic layer may be an emissive layer and the compound as described herein may be an emissive dopant or a non-emissive dopant.

What is claimed is:

1. A compound having a first ligand L_{A} comprising a structure of Formula I: 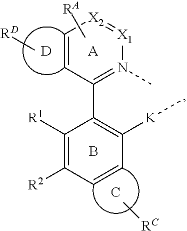
wherein:
moiety C is a monocyclic ring or a polycyclic fused ring system, wherein the monocyclic ring or each ring of the polycyclic fused ring system is independently a 5-membered to 10-membered carbocyclic or heterocyclic ring;
ring D is a 5-membered to 10-membered carbocyclic or heterocyclic ring;
each of X¹ and X² is independently C or N;
K is selected from the group consisting of a direct bond, O, S, N(R^{α}), P(R^{α}), B(R^{α}), C(R^{α})(R^{β}), and Si(R^{α})(R^{β});
R¹ and R² are each independently H, D, or T;
each R^{A}, R^{C}, and R^{D} independently represents mono to the maximum allowable substitution, or no substitution;
each R^{α}, R^{β}, R^{A}, R^{C}, and R^{D} are each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof;
L_{A} is coordinated to a metal M;
metal M is selected from the group consisting of Os, Ir, Rh, Re, Ru, Pd, Pt, Cu, Ag, and Au;
metal M can be coordinated to other ligands;
L_{A} can join with other ligands to form a tridentate, tetradentate, pentadentate, or hexadentate ligand; and
any two substituents can be joined or fused to form a ring;
with the proviso that if M is Ir, R¹ and R² are each H, and moiety C is a benzene ring, then one of the following conditions is true:
(1) X¹ and X² are C, ring D is a 5-membered monocyclic ring, and no two R^{A} substituents are joined or fused to form a ring; or
(2) X² is N and (a) moiety D is a 6-membered monocyclic ring, and no two R^{D} substituents are joined or fused to form a 5-membered ring; or (b) moiety D is a 5-membered monocyclic ring, and the 5-membered ring comprises at least four carbon ring atoms.

2. The compound of claim 1, wherein each R^{α}, R^{β}, R^{A}, R^{C}, and R^{D} are each independently hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

3. The compound of claim 1, wherein moiety C is selected from the group consisting of: benzene, pyridine, pyrimidine, pyridazine, pyrazine, triazine, imidazole, pyrazole, pyrrole, oxazole, furan, thiophene, thiazole, triazole, naphthalene, quinoline, isoquinoline, quinazoline, quinoxaline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, aza-benzimidazole, carbazole, aza-carbazole, dibenzofuran, aza-dibenzofuran, dibenzothiophene, aza-dibenzothiophene, quinoxaline, phthalazine, phenanthrene, aza-phenanathrene, anthracene, aza-anthracene, phenanthridine, fluorene, and aza-fluorene; and/or wherein moiety D is selected from the group consisting of benzene, pyridine, pyrimidine, pyridazine, pyrazine, triazine, imidazole, pyrazole, pyrrole, oxazole, furan, thiophene, thiazole, and triazole; and/or wherein two R^{A} are joined or fused to form a moiety A1; and/or wherein two R^{D} are joined or fused to form a moiety D1; and/or wherein metal M is Ir or Pt.

4. The compound of claim 1, wherein X¹ and X² are C or wherein one of X¹ and X² is N; and/or wherein K is a direct bond or O.

5. The compound of claim 1, wherein at least one R^{A} comprises a substituent selected from the group consisting of alkyl, cycloalkyl, aryl, heteroaryl, and combinations thereof; and/or wherein at least one R^{C} comprises a substituent selected from the group consisting of alkyl, cycloalkyl, aryl, heteroaryl, and combinations thereof; and/or wherein at least one R^{D} comprises a substituent selected from the group consisting of alkyl, cycloalkyl, silyl, germyl, aryl, heteroaryl, and combinations thereof.

6. The compound of claim 1, wherein the ligand L_{A} is selected from the group consisting of the structures of: 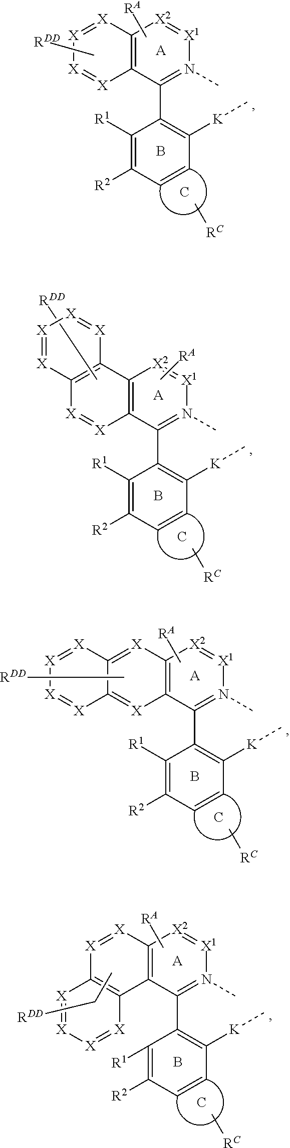 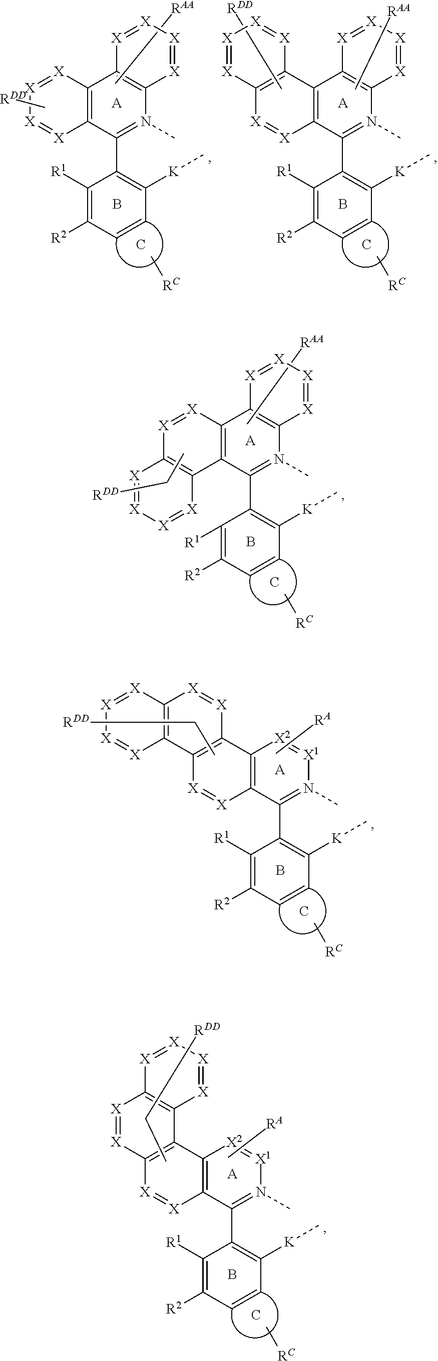 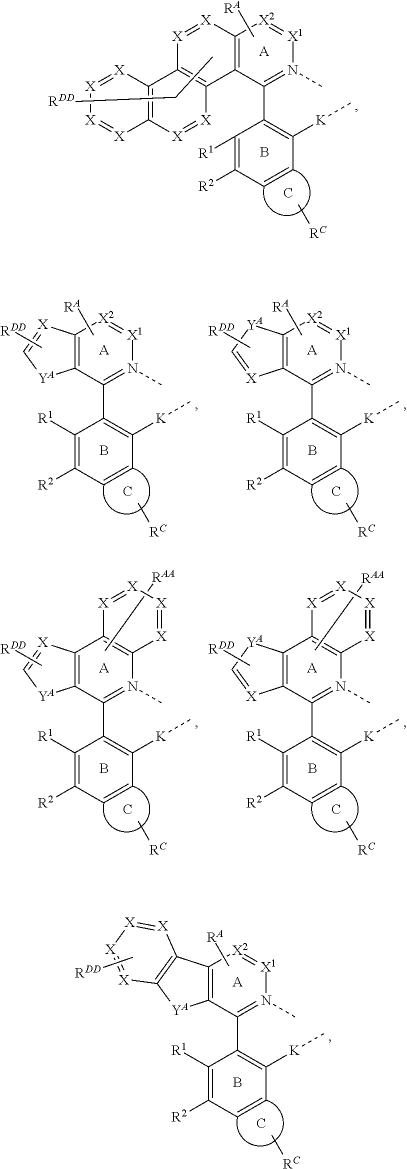 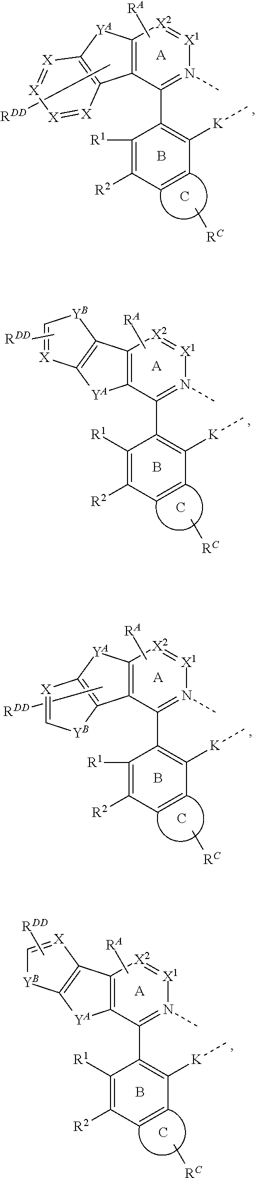 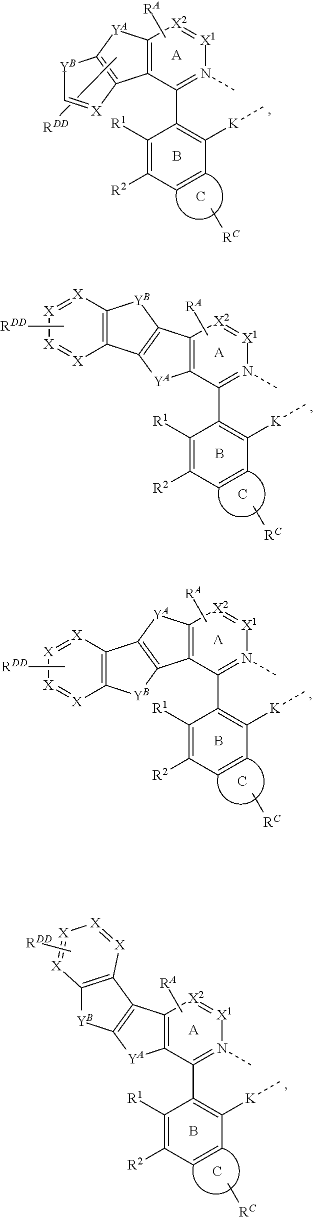 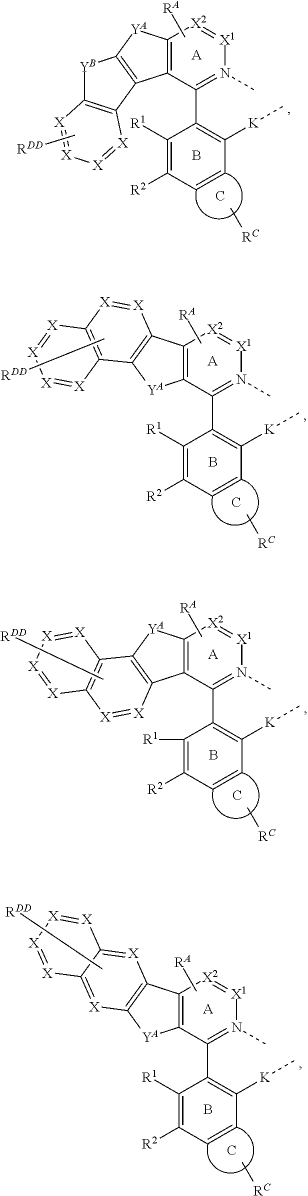 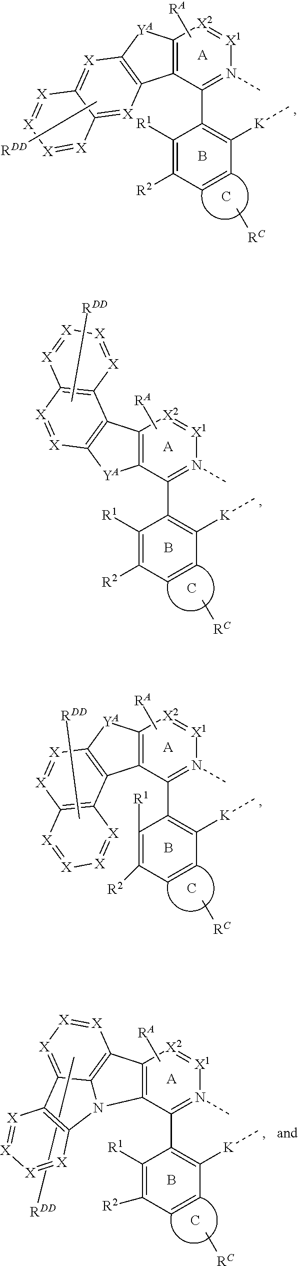 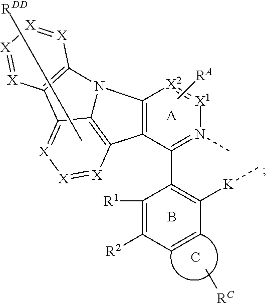
wherein:
for each occurrence, X is independently C or N;
each of Y^{A} and Y^{B} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
each of R^{AA} and R^{DD} independently represents mono to the maximum allowable substitution, or no substitution;
each R, R′, R^{A}, and R^{DD} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents can be joined or fused to form a ring.

7. The compound of claim 1, wherein the ligand L_{A} is selected from the group consisting of: 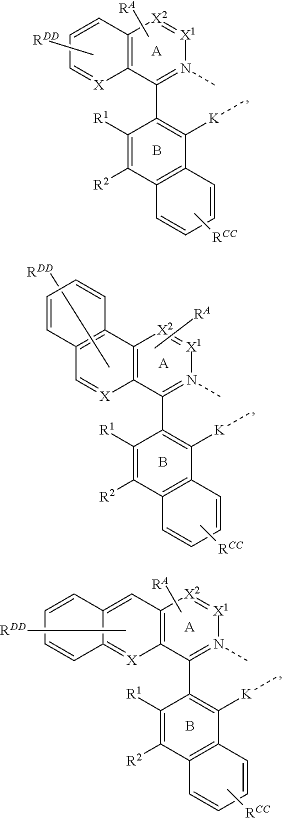 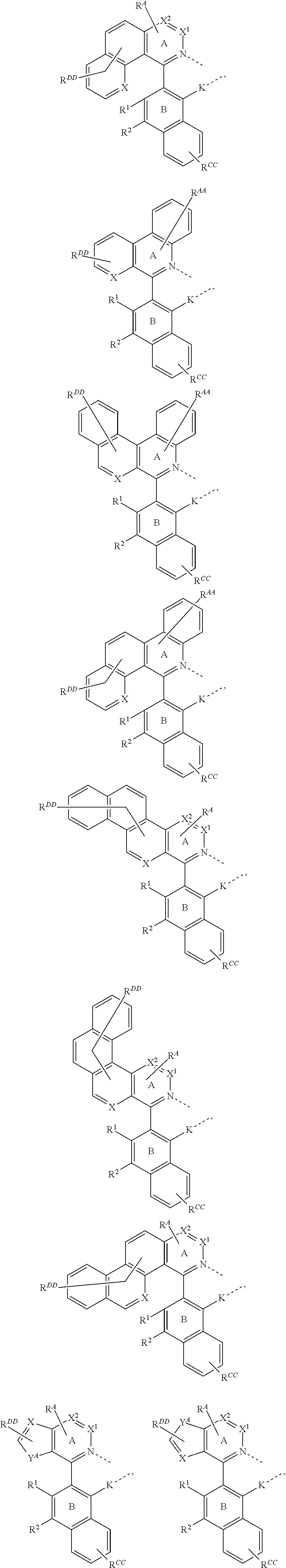 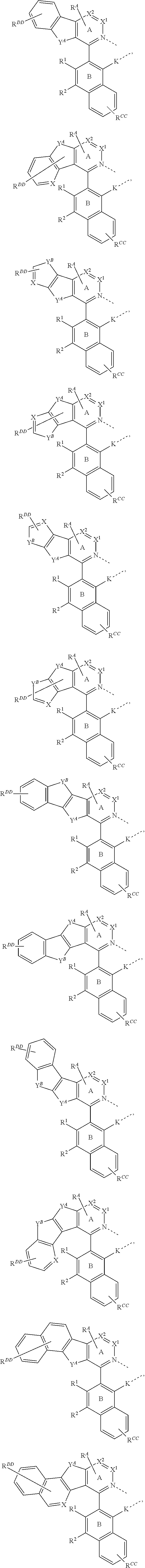 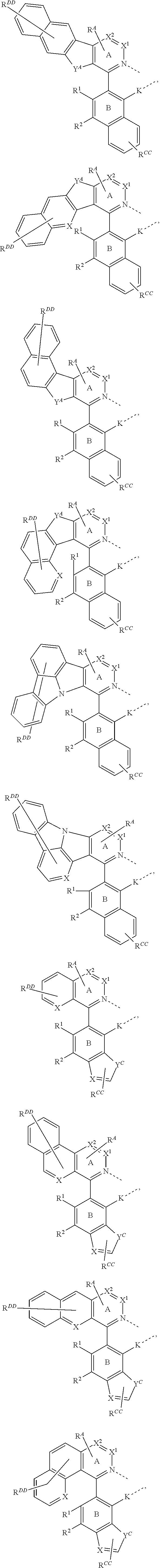 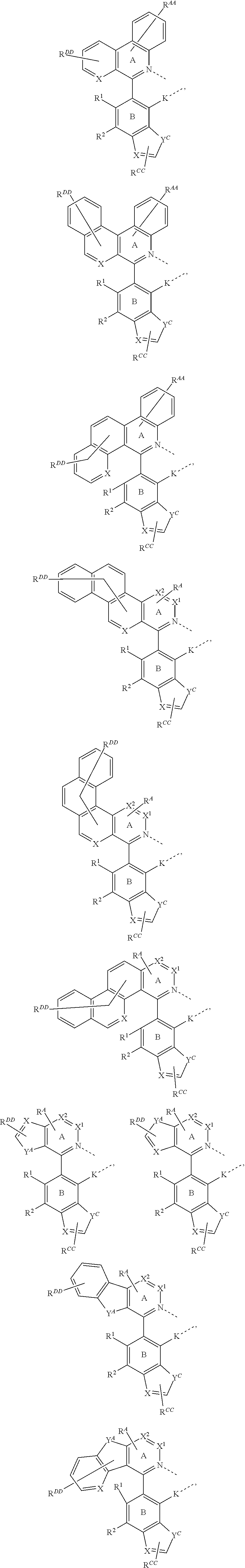 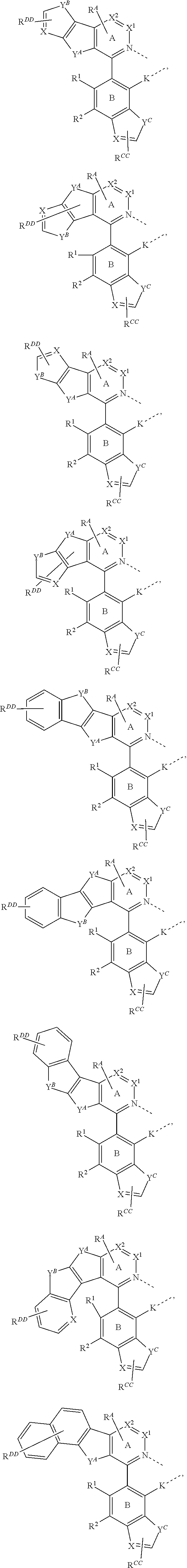 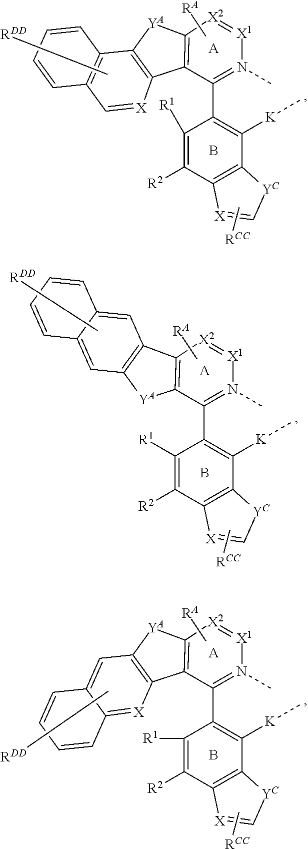 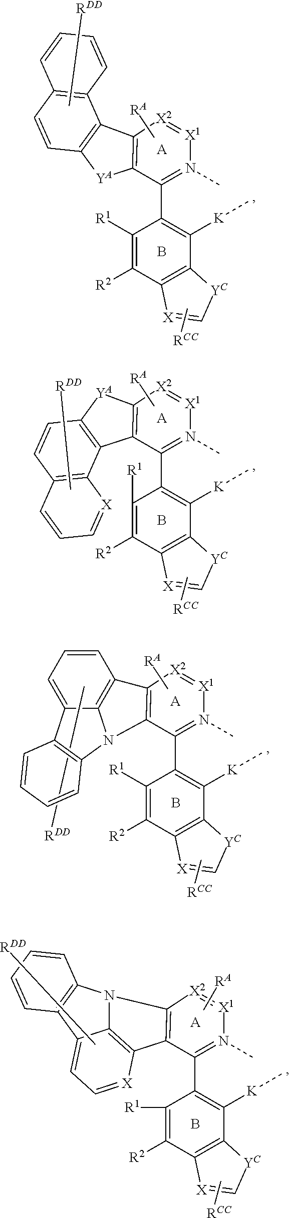 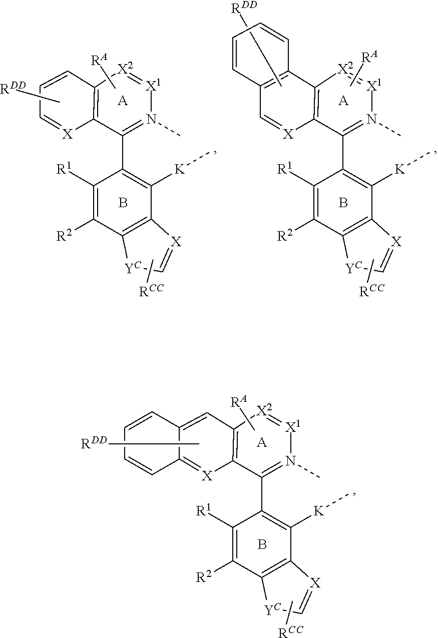 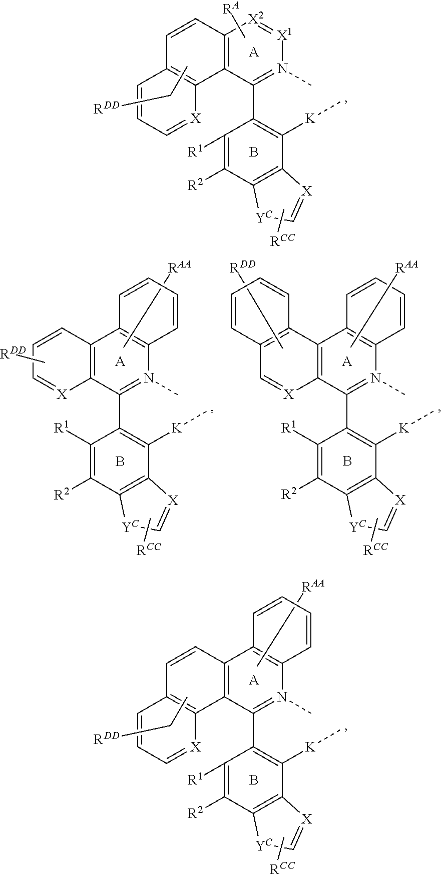 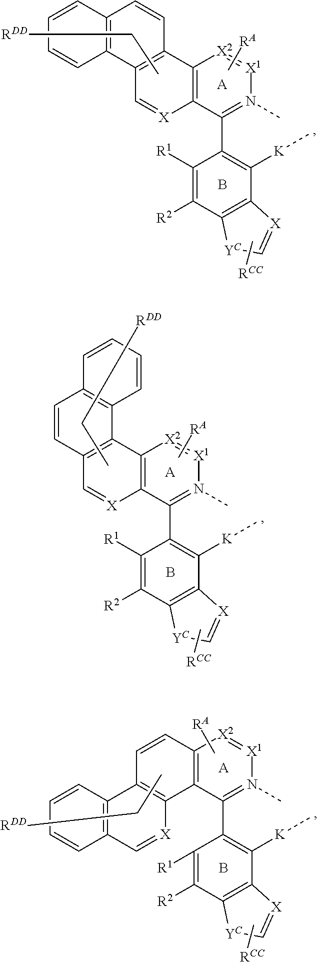 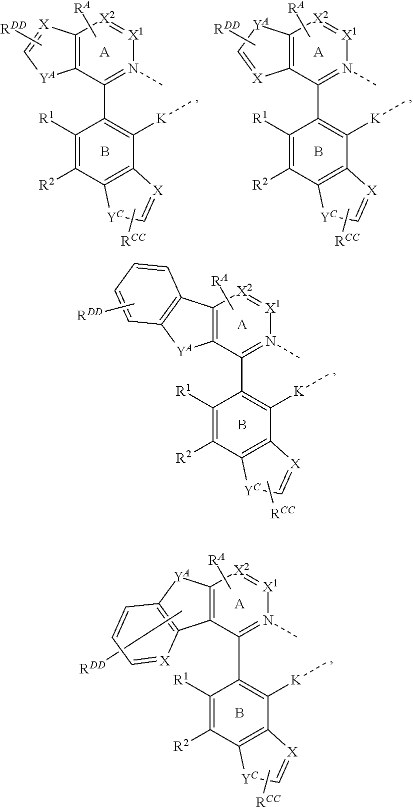 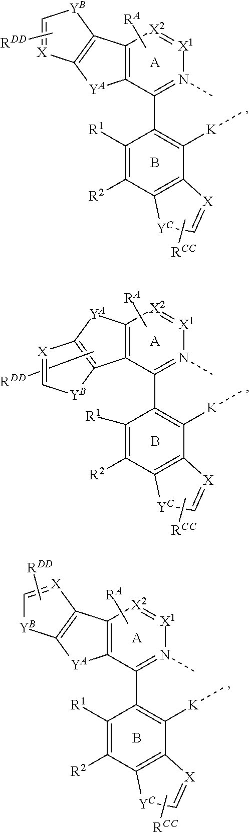 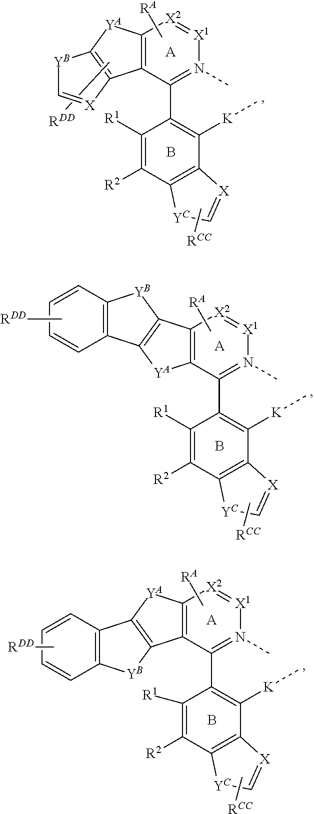 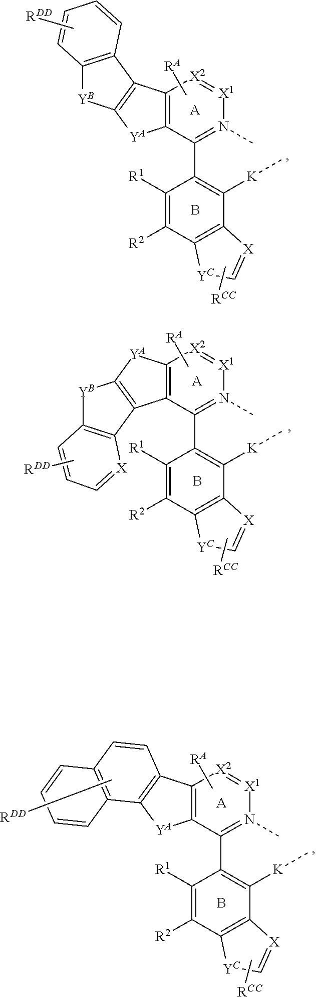 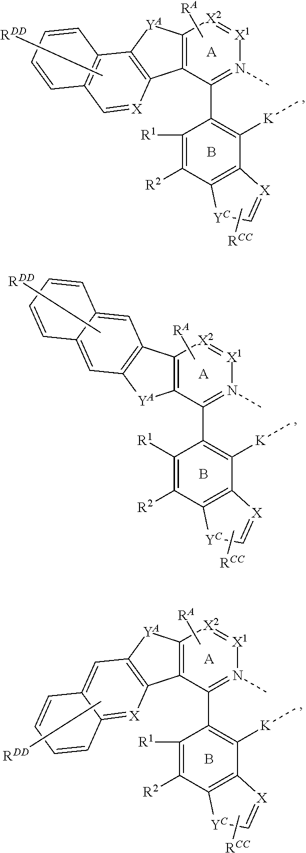 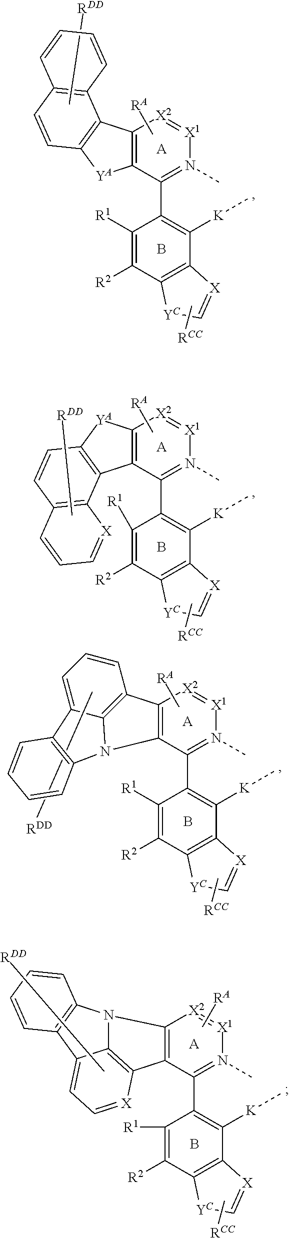 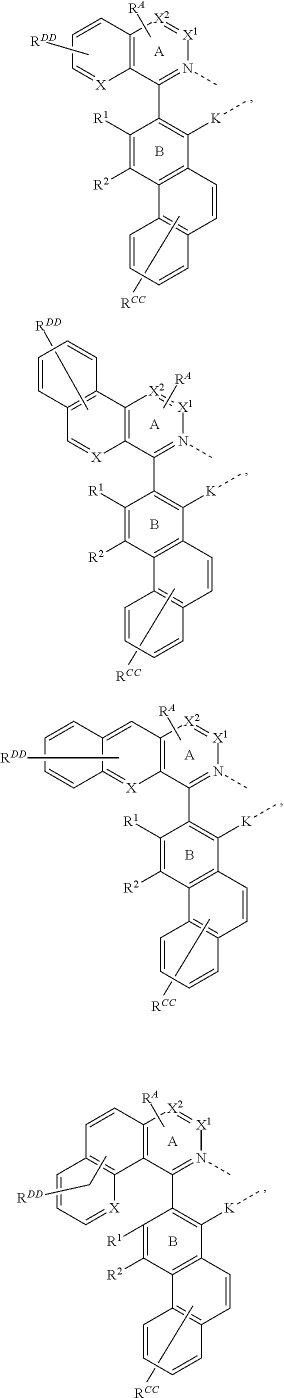 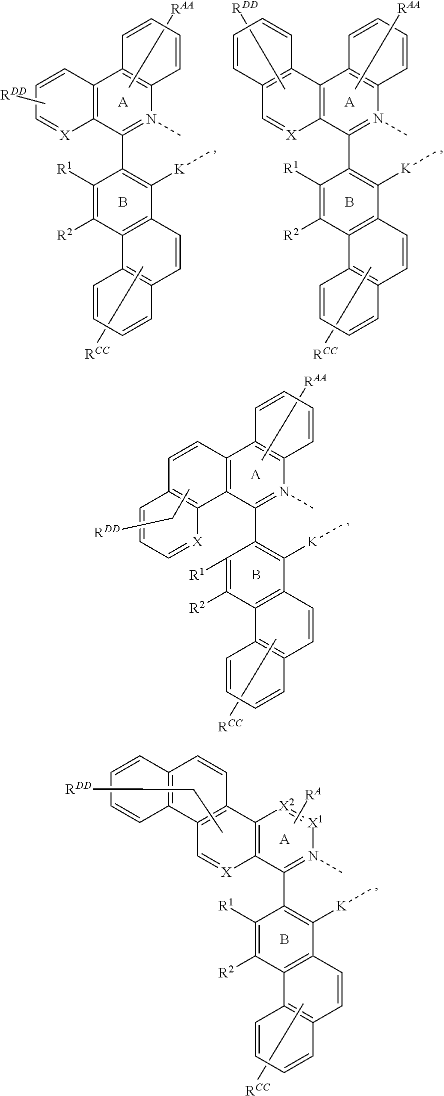 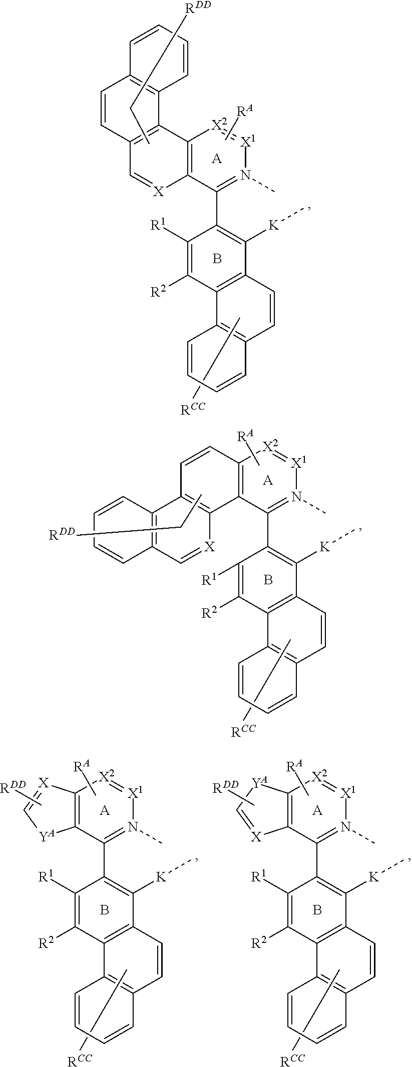 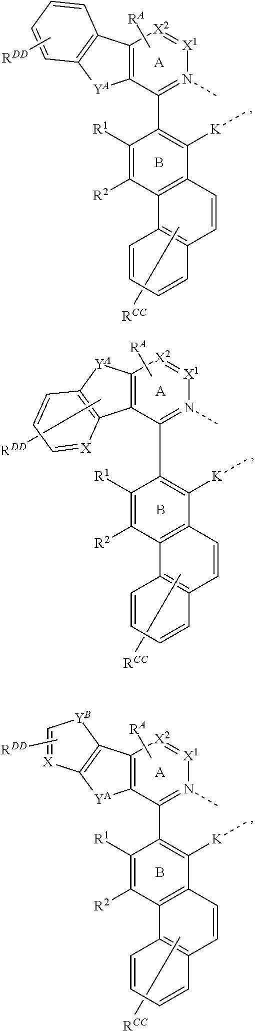 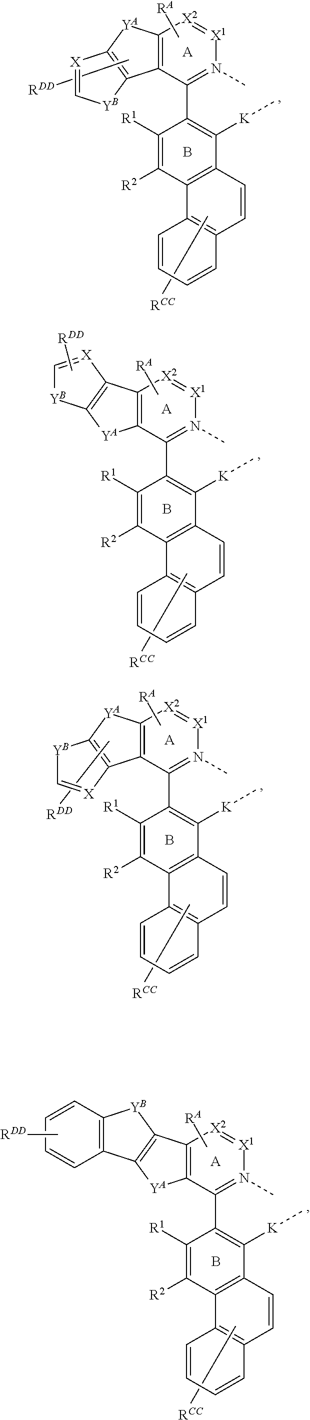 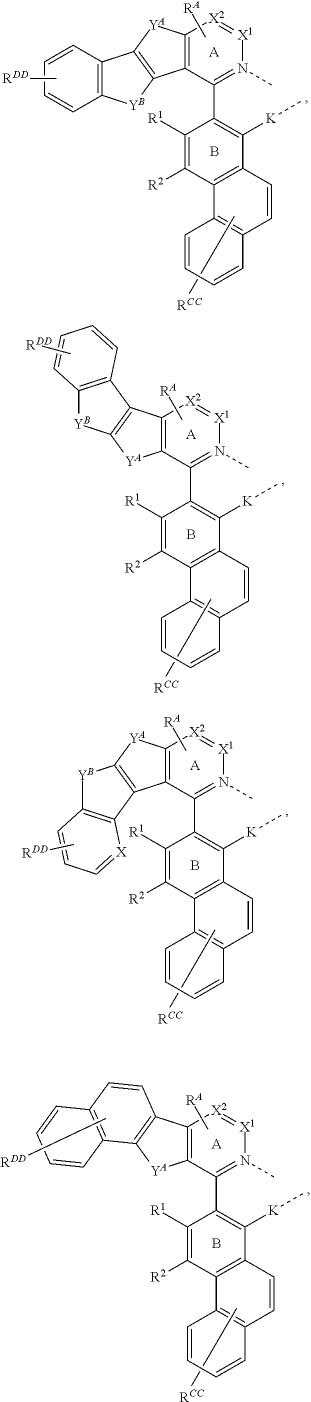 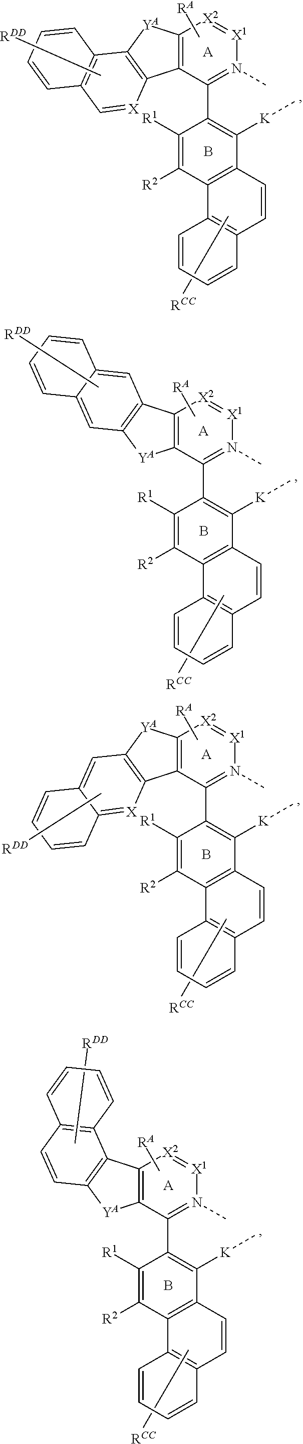 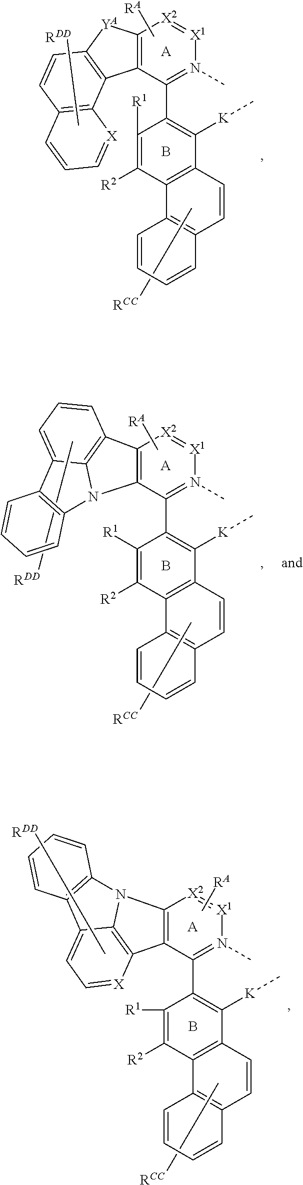
wherein:
each of Y^{A}, Y^{B}, and Y^{C} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
each of R^{AA}, R^{CC}, and R^{DD} independently represents mono to the maximum allowable substitution, or no substitution;
each R, R′, R^{A}, R^{AA}, R^{CC}, and R^{DD} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents can be joined or fused to form a ring.

8. The compound of claim 1, wherein the ligand L_{A} is selected from L_{A1}(R^{EA})(R^{EB})(R^{EC})(R^{ED})(R^{EE}); wherein i is an integer from 1 to 148, and each of R^{EA}, R^{EB}, R^{EC}, R^{ED}, and R^{EE}, is independently selected from the group consisting of R¹ to R¹⁵⁰; wherein each of L_{A1}(R¹)(R¹)(R¹)(R¹)(R¹) to L_{A148}(R¹⁵⁰)(R¹⁵⁰)(R¹⁵⁰)(R¹⁵⁰)(R¹⁵⁰) is defined as follows:

| L_{A} | Structure of L_{A} |
|---|---|
| L_{A1}(R^{EA})(R^{EB})(R^{EC})(R^{ED})(R^{EE}), wherein L_{A1}(R¹)(R¹)(R¹)(R¹)(R¹) to L_{A1}(R¹⁵⁰)(R¹⁵⁰)(R¹⁵⁰)(R¹⁵⁰)(R¹⁵⁰) have the structure | 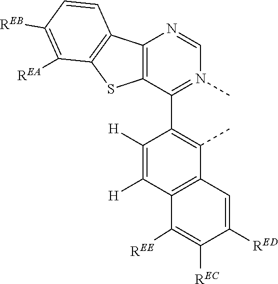 |
| L_{A2}(R^{EA})(R^{EB})(R^{EC})(R^{ED})(R^{EE}), wherein L_{A2}(R¹)(R¹)(R¹)(R¹)(R¹) to L_{A2}(R¹⁵⁰)(R¹⁵⁰)(R¹⁵⁰)(R¹⁵⁰)(R¹⁵⁰) have the structure | 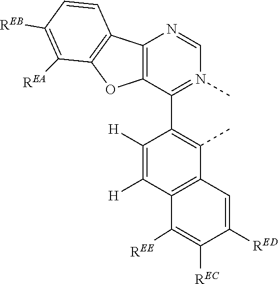 |
| L_{A3}(R^{EA})(R^{EB})(R^{EC})(R^{ED})(R^{EE}), wherein L_{A3}(R¹)(R¹)(R¹)(R¹)(R¹) to L_{A3}(R¹⁵⁰)(R¹⁵⁰)(R¹⁵⁰)(R¹⁵⁰)(R¹⁵⁰) have the structure | 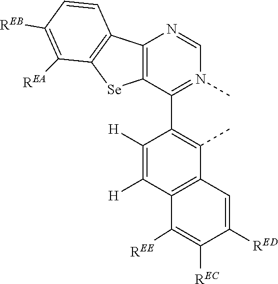 |
| L_{A4}(R^{EA})(R^{EB})(R^{EC})(R^{ED})(R^{EE}), wherein L_{A4}(R¹)(R¹)(R¹)(R¹)(R¹) to L_{A4}(R¹⁵⁰)(R¹⁵⁰)(R¹⁵⁰)(R¹⁵⁰)(R¹⁵⁰) have the structure | 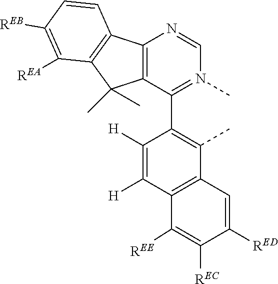 |
| L_{A5}(R^{EA})(R^{EB})(R^{EC})(R^{ED})(R^{EE}), wherein L_{A5}(R¹)(R¹)(R¹)(R¹)(R¹) to L_{A5}(R¹⁵⁰)(R¹⁵⁰)(R¹⁵⁰)(R¹⁵⁰)(R¹⁵⁰) have the structure | 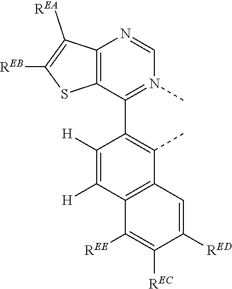 |
| L_{A6}(R^{EA})(R^{EB})(R^{EC})(R^{ED})(R^{EE}), wherein L_{A6}(R¹)(R¹)(R¹)(R¹)(R¹) to L_{A6}(R¹⁵⁰)(R¹⁵⁰)(R¹⁵⁰)(R¹⁵⁰)(R¹⁵⁰) have the structure | 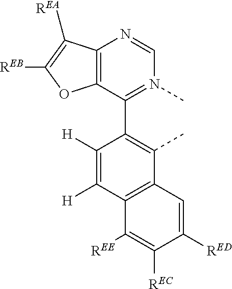 |
| L_{A7}(R^{EA})(R^{EB})(R^{EC})(R^{ED})(R^{EE}), wherein L_{A7}(R¹)(R¹)(R¹)(R¹)(R¹) to L_{A7}(R¹⁵⁰)(R¹⁵⁰)(R¹⁵⁰)(R¹⁵⁰)(R¹⁵⁰) have the structure | 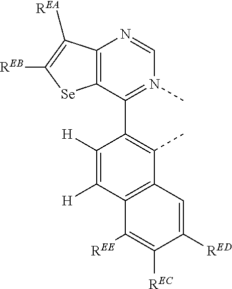 |
| L_{A8}(R^{EA})(R^{EB})(R^{EC})(R^{ED})(R^{EE}), wherein L_{A8}(R¹)(R¹)(R¹)(R¹)(R¹) to L_{A8}(R¹⁵⁰)(R¹⁵⁰)(R¹⁵⁰)(R¹⁵⁰)(R¹⁵⁰) have the structure | 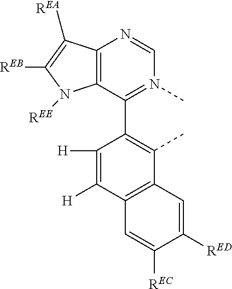 |
| L_{A9}(R^{EA})(R^{EB})(R^{EC})(R^{ED})(R^{EE}), wherein L_{A9}(R¹)(R¹)(R¹)(R¹)(R¹) to L_{A9}(R¹⁵⁰)(R¹⁵⁰)(R¹⁵⁰)(R¹⁵⁰)(R¹⁵⁰) have the structure | 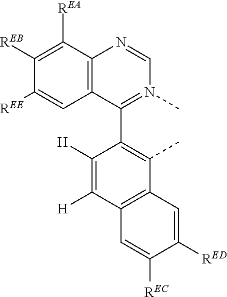 |
| L_{A10}(R^{EA})(R^{EB})(R^{EC})(R^{ED})(R^{EE}), wherein L_{A10}(R¹)(R¹)(R¹)(R¹)(R¹) to L_{A10}(R¹⁵⁰)(R¹⁵⁰)(R¹⁵⁰)(R¹⁵⁰)(R¹⁵⁰) have the structure | 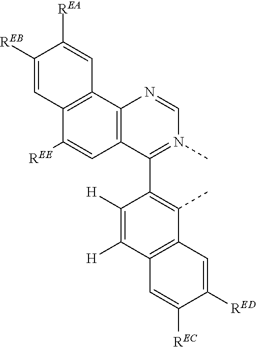 |
| L_{A11}(R^{EA})(R^{EB})(R^{EC})(R^{ED})(R^{EE}), wherein L_{A11}(R¹)(R¹)(R¹)(R¹)(R¹) to L_{A11}(R¹⁵⁰)(R¹⁵⁰)(R¹⁵⁰)(R¹⁵⁰)(R¹⁵⁰) have the structure | 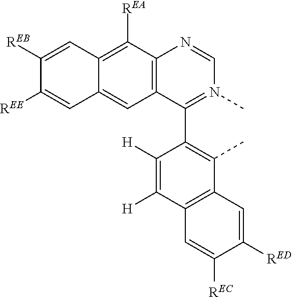 |
| L_{A12}(R^{EA})(R^{EB})(R^{EC})(R^{ED})(R^{EE}), wherein L_{A12}(R¹)(R¹)(R¹)(R¹)(R¹) to L_{A12}(R¹⁵⁰)(R¹⁵⁰)(R¹⁵⁰)(R¹⁵⁰)(R¹⁵⁰) have the structure | 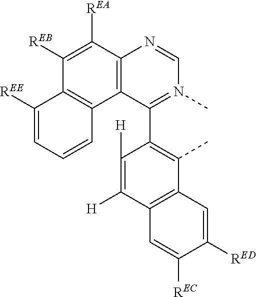 |
| L_{A13}(R^{EA})(R^{EB})(R^{EC})(R^{ED})(R^{EE}), wherein L_{A13}(R¹)(R¹)(R¹)(R¹)(R¹) to L_{A13}(R¹⁵⁰)(R¹⁵⁰)(R¹⁵⁰)(R¹⁵⁰)(R¹⁵⁰) have the structure | 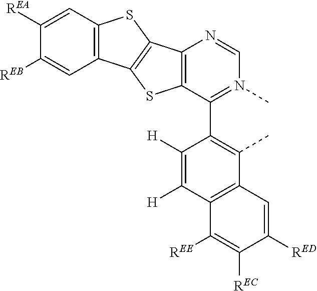 |
| L_{A14}(R^{EA})(R^{EB})(R^{EC})(R^{ED})(R^{EE}), wherein L_{A14}(R¹)(R¹)(R¹)(R¹)(R¹) to L_{A14}(R¹⁵⁰)(R¹⁵⁰)(R¹⁵⁰)(R¹⁵⁰)(R¹⁵⁰) have the structure | 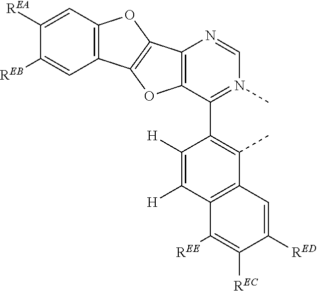 |
| L_{A15}(R^{EA})(R^{EB})(R^{EC})(R^{ED})(R^{EE}), wherein L_{A15}(R¹)(R¹)(R¹)(R¹)(R¹) to L_{A15}(R¹⁵⁰)(R¹⁵⁰)(R¹⁵⁰)(R¹⁵⁰)(R¹⁵⁰) have the structure | 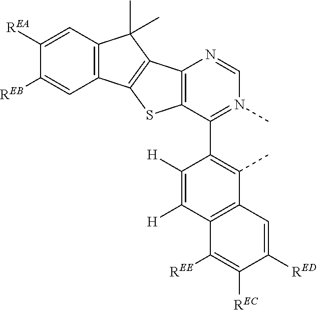 |
| L_{A16}(R^{EA})(R^{EB})(R^{EC})(R^{ED})(R^{EE}), wherein L_{A16}(R¹)(R¹)(R¹)(R¹)(R¹) to L_{A16}(R¹⁵⁰)(R¹⁵⁰)(R¹⁵⁰)(R¹⁵⁰)(R¹⁵⁰) have the structure | 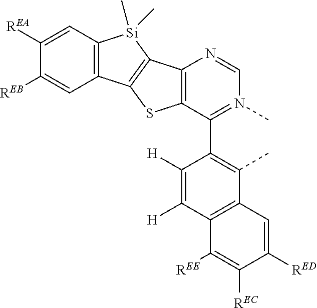 |
| L_{A17}(R^{EA})(R^{EB})(R^{EC})(R^{ED})(R^{EE}), wherein L_{A17}(R¹)(R¹)(R¹)(R¹)(R¹) to L_{A17}(R¹⁵⁰)(R¹⁵⁰)(R¹⁵⁰)(R¹⁵⁰)(R¹⁵⁰) have the structure | 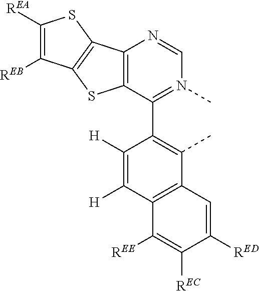 |
| L_{A18}(R^{EA})(R^{EB})(R^{EC})(R^{ED})(R^{EE}), wherein L_{A18}(R¹)(R¹)(R¹)(R¹)(R¹) to L_{A18}(R¹⁵⁰)(R¹⁵⁰)(R¹⁵⁰)(R¹⁵⁰)(R¹⁵⁰) have the structure | 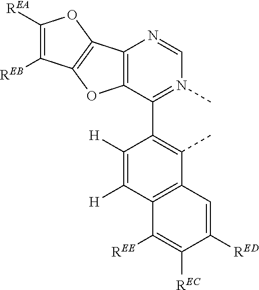 |
| L_{A19}(R^{EA})(R^{EB})(R^{EC})(R^{ED})(R^{EE}), wherein L_{A19}(R¹)(R¹)(R¹)(R¹)(R¹) to L_{A19}(R¹⁵⁰)(R¹⁵⁰)(R¹⁵⁰)(R¹⁵⁰)(R¹⁵⁰) have the structure | 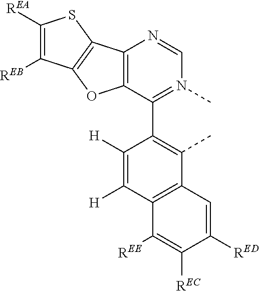 |
| L_{A20}(R^{EA})(R^{EB})(R^{EC})(R^{ED})(R^{EE}), wherein L_{A20}(R¹)(R¹)(R¹)(R¹)(R¹) to L_{A20}(R¹⁵⁰)(R¹⁵⁰)(R¹⁵⁰)(R¹⁵⁰)(R¹⁵⁰) have the structure | 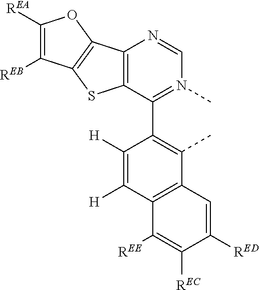 |
| L_{A21}(R^{EA})(R^{EB})(R^{EC})(R^{ED})(R^{EE}), wherein L_{A21}(R¹)(R¹)(R¹)(R¹)(R¹) to L_{A21}(R¹⁵⁰)(R¹⁵⁰)(R¹⁵⁰)(R¹⁵⁰)(R¹⁵⁰) have the structure | 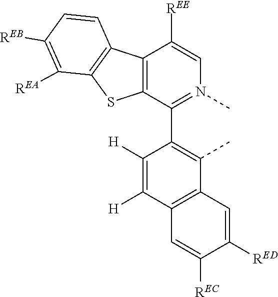 |
| L_{A22}(R^{EA})(R^{EB})(R^{EC})(R^{ED})(R^{EE}), wherein L_{A22}(R¹)(R¹)(R¹)(R¹)(R¹) to L_{A22}(R¹⁵⁰)(R¹⁵⁰)(R¹⁵⁰)(R¹⁵⁰)(R¹⁵⁰) have the structure | 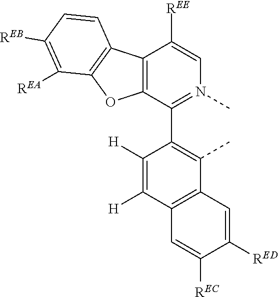 |
| L_{A23}(R^{EA})(R^{EB})(R^{EC})(R^{ED})(R^{EE}), wherein L_{A23}(R¹)(R¹)(R¹)(R¹)(R¹) to L_{A23}(R¹⁵⁰)(R¹⁵⁰)(R¹⁵⁰)(R¹⁵⁰)(R¹⁵⁰) have the structure | 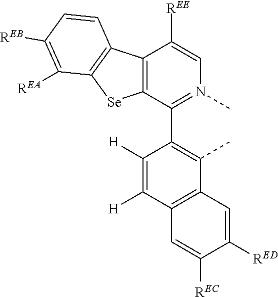 |
| L_{A24}(R^{EA})(R^{EB})(R^{EC})(R^{ED})(R^{EE}), wherein L_{A24}(R¹)(R¹)(R¹)(R¹)(R¹) to L_{A24}(R¹⁵⁰)(R¹⁵⁰)(R¹⁵⁰)(R¹⁵⁰)(R¹⁵⁰) have the structure | 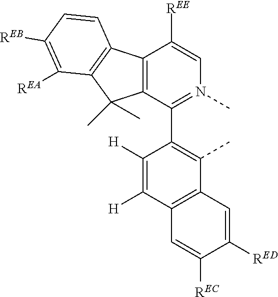 |
| L_{A25}(R^{EA})(R^{EB})(R^{EC})(R^{ED})(R^{EE}), wherein L_{A25}(R¹)(R¹)(R¹)(R¹)(R¹) to L_{A25}(R¹⁵⁰)(R¹⁵⁰)(R¹⁵⁰)(R¹⁵⁰)(R¹⁵⁰) have the structure | 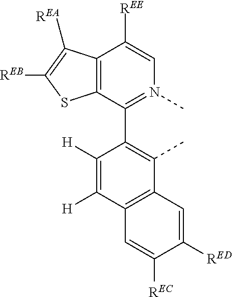 |
| L_{A26}(R^{EA})(R^{EB})(R^{EC})(R^{ED})(R^{EE}), wherein L_{A26}(R¹)(R¹)(R¹)(R¹)(R¹) to L_{A26}(R¹⁵⁰)(R¹⁵⁰)(R¹⁵⁰)(R¹⁵⁰)(R¹⁵⁰) have the structure | 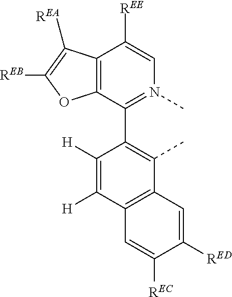 |
| L_{A27}(R^{EA})(R^{EB})(R^{EC})(R^{ED})(R^{EE}), wherein L_{A27}(R¹)(R¹)(R¹)(R¹)(R¹) to L_{A27}(R¹⁵⁰)(R¹⁵⁰)(R¹⁵⁰)(R¹⁵⁰)(R¹⁵⁰) have the structure | 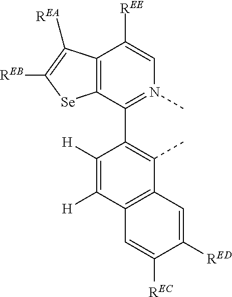 |
| L_{A28}(R^{EA})(R^{EB})(R^{EC})(R^{ED})(R^{EE}), wherein L_{A28}(R¹)(R¹)(R¹)(R¹)(R¹) to L_{A28}(R¹⁵⁰)(R¹⁵⁰)(R¹⁵⁰)(R¹⁵⁰)(R¹⁵⁰) have the structure | 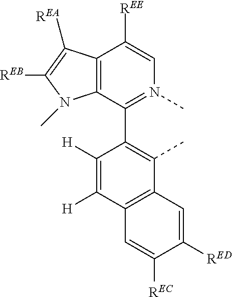 |
| L_{A29}(R^{EA})(R^{EB})(R^{EC})(R^{ED})(R^{EE}), wherein L_{A29}(R¹)(R¹)(R¹)(R¹)(R¹) to L_{A29}(R¹⁵⁰)(R¹⁵⁰)(R¹⁵⁰)(R¹⁵⁰)(R¹⁵⁰) have the structure | 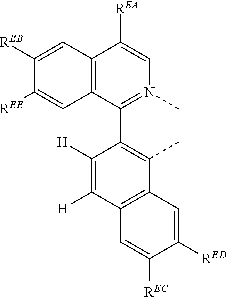 |
| L_{A30}(R^{EA})(R^{EB})(R^{EC})(R^{ED})(R^{EE}), wherein L_{A30}(R¹)(R¹)(R¹)(R¹)(R¹) to L_{A30}(R¹⁵⁰)(R¹⁵⁰)(R¹⁵⁰)(R¹⁵⁰)(R¹⁵⁰) have the structure | 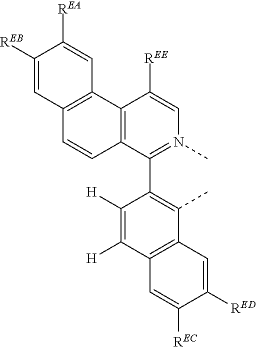 |
| L_{A31}(R^{EA})(R^{EB})(R^{EC})(R^{ED})(R^{EE}), wherein L_{A31}(R¹)(R¹)(R¹)(R¹)(R¹) to L_{A31}(R¹⁵⁰)(R¹⁵⁰)(R¹⁵⁰)(R¹⁵⁰)(R¹⁵⁰) have the structure | 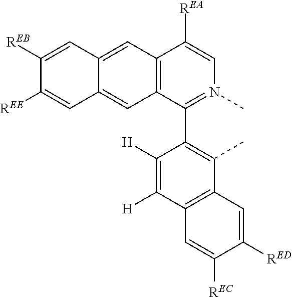 |
| L_{A32}(R^{EA})(R^{EB})(R^{EC})(R^{ED})(R^{EE}), wherein L_{A32}(R¹)(R¹)(R¹)(R¹)(R¹) to L_{A32}(R¹⁵⁰)(R¹⁵⁰)(R¹⁵⁰)(R¹⁵⁰)(R¹⁵⁰) have the structure | 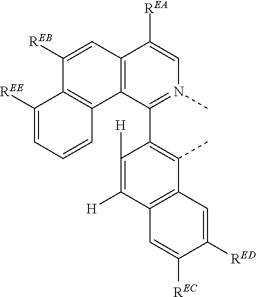 |
| L_{A33}(R^{EA})(R^{EB})(R^{EC})(R^{ED})(R^{EE}), wherein L_{A33}(R¹)(R¹)(R¹)(R¹)(R¹) to L_{A33}(R¹⁵⁰)(R¹⁵⁰)(R¹⁵⁰)(R¹⁵⁰)(R¹⁵⁰) have the structure | 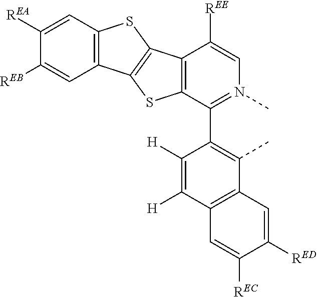 |
| L_{A34}(R^{EA})(R^{EB})(R^{EC})(R^{ED})(R^{EE}), wherein L_{A34}(R¹)(R¹)(R¹)(R¹)(R¹) to L_{A34}(R¹⁵⁰)(R¹⁵⁰)(R¹⁵⁰)(R¹⁵⁰)(R¹⁵⁰) have the structure | 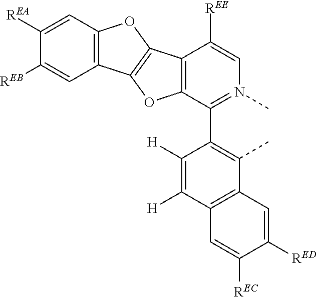 |
| L_{A35}(R^{EA})(R^{EB})(R^{EC})(R^{ED})(R^{EE}), wherein L_{A35}(R¹)(R¹)(R¹)(R¹)(R¹) to L_{A35}(R¹⁵⁰)(R¹⁵⁰)(R¹⁵⁰)(R¹⁵⁰)(R¹⁵⁰) have the structure | 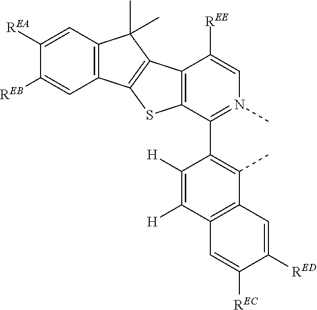 |
| L_{A36}(R^{EA})(R^{EB})(R^{EC})(R^{ED})(R^{EE}), wherein L_{A36}(R¹)(R¹)(R¹)(R¹)(R¹) to L_{A36}(R¹⁵⁰)(R¹⁵⁰)(R¹⁵⁰)(R¹⁵⁰)(R¹⁵⁰) have the structure | 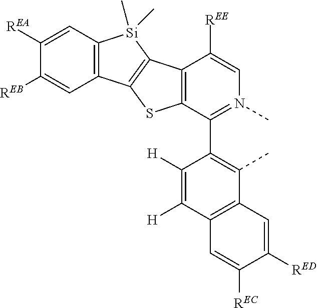 |
| L_{A37}(R^{EA})(R^{EB})(R^{EC})(R^{ED})(R^{EE}), wherein L_{A37}(R¹)(R¹)(R¹)(R¹)(R¹) to L_{A37}(R¹⁵⁰)(R¹⁵⁰)(R¹⁵⁰)(R¹⁵⁰)(R¹⁵⁰) have the structure | 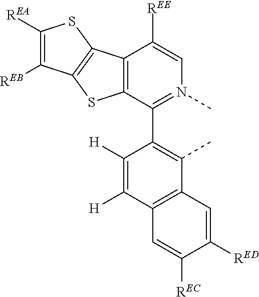 |
| L_{A38}(R^{EA})(R^{EB})(R^{EC})(R^{ED})(R^{EE}), wherein L_{A38}(R¹)(R¹)(R¹)(R¹)(R¹) to L_{A38}(R¹⁵⁰)(R¹⁵⁰)(R¹⁵⁰)(R¹⁵⁰)(R¹⁵⁰) have the structure | 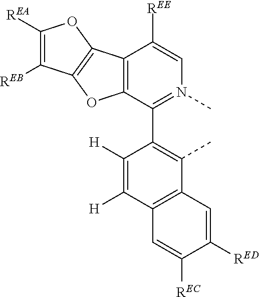 |
| L_{A39}(R^{EA})(R^{EB})(R^{EC})(R^{ED})(R^{EE}), wherein L_{A39}(R¹)(R¹)(R¹)(R¹)(R¹) to L_{A39}(R¹⁵⁰)(R¹⁵⁰)(R¹⁵⁰)(R¹⁵⁰)(R¹⁵⁰) have the structure | 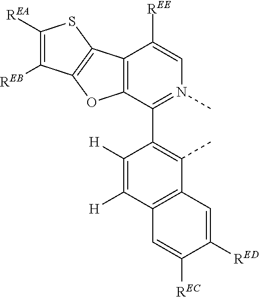 |
| L_{A40}(R^{EA})(R^{EB})(R^{EC})(R^{ED})(R^{EE}), wherein L_{A40}(R¹)(R¹)(R¹)(R¹)(R¹) to L_{A40}(R¹⁵⁰)(R¹⁵⁰)(R¹⁵⁰)(R¹⁵⁰)(R¹⁵⁰) have the structure | 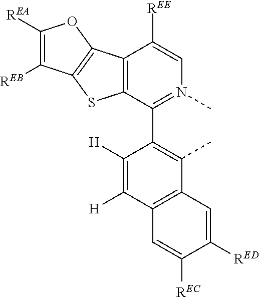 |
| L_{A41}(R^{EA})(R^{EB})(R^{EC})(R^{ED})(R^{EE}), wherein L_{A41}(R¹)(R¹)(R¹)(R¹)(R¹) to L_{A41}(R¹⁵⁰)(R¹⁵⁰)(R¹⁵⁰)(R¹⁵⁰)(R¹⁵⁰) have the structure | 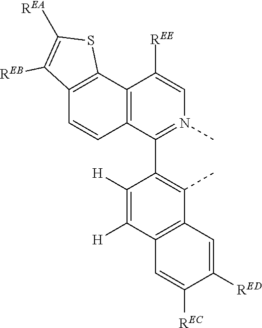 |
| L_{A42}(R^{EA})(R^{EB})(R^{EC})(R^{ED})(R^{EE}), wherein L_{A42}(R¹)(R¹)(R¹)(R¹)(R¹) to L_{A42}(R¹⁵⁰)(R¹⁵⁰)(R¹⁵⁰)(R¹⁵⁰)(R¹⁵⁰) have the structure | 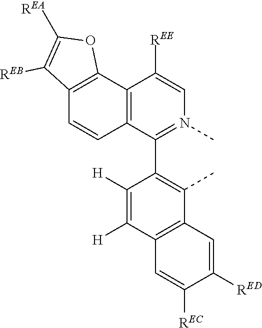 |
| L_{A43}(R^{EA})(R^{EB})(R^{EC})(R^{ED})(R^{EE}), wherein L_{A43}(R¹)(R¹)(R¹)(R¹)(R¹) to L_{A43}(R¹⁵⁰)(R¹⁵⁰)(R¹⁵⁰)(R¹⁵⁰)(R¹⁵⁰) have the structure | 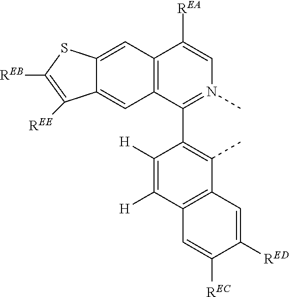 |
| L_{A44}(R^{EA})(R^{EB})(R^{EC})(R^{ED})(R^{EE}), wherein L_{A44}(R¹)(R¹)(R¹)(R¹)(R¹) to L_{A44}(R¹⁵⁰)(R¹⁵⁰)(R¹⁵⁰)(R¹⁵⁰)(R¹⁵⁰) have the structure | 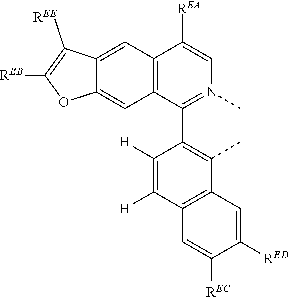 |
| L_{A45}(R^{EA})(R^{EB})(R^{EC})(R^{ED})(R^{EE}), wherein L_{A45}(R¹)(R¹)(R¹)(R¹)(R¹) to L_{A45}(R¹⁵⁰)(R¹⁵⁰)(R¹⁵⁰)(R¹⁵⁰)(R¹⁵⁰) have the structure | 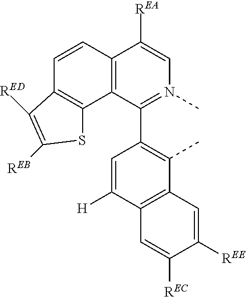 |
| L_{A46}(R^{EA})(R^{EB})(R^{EC})(R^{ED})(R^{EE}), wherein L_{A46}(R¹)(R¹)(R¹)(R¹)(R¹) to L_{A46}(R¹⁵⁰)(R¹⁵⁰)(R¹⁵⁰)(R¹⁵⁰)(R¹⁵⁰) have the structure | 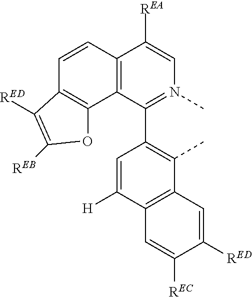 |
| L_{A47}(R^{EA})(R^{EB})(R^{EC})(R^{ED})(R^{EE}), wherein L_{A47}(R¹)(R¹)(R¹)(R¹)(R¹) to L_{A47}(R¹⁵⁰)(R¹⁵⁰)(R¹⁵⁰)(R¹⁵⁰)(R¹⁵⁰) have the structure | 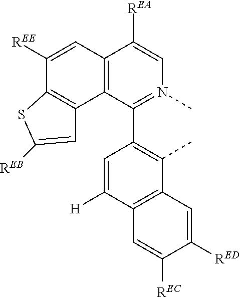 |
| L_{A48}(R^{EA})(R^{EB})(R^{EC})(R^{ED})(R^{EE}), wherein L_{A48}(R¹)(R¹)(R¹)(R¹)(R¹) to L_{A48}(R¹⁵⁰)(R¹⁵⁰)(R¹⁵⁰)(R¹⁵⁰)(R¹⁵⁰) have the structure | 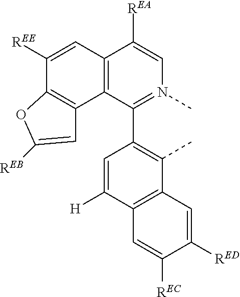 |
| L_{A49}(R^{EA})(R^{EB})(R^{EC})(R^{ED})(R^{EE}), wherein L_{A49}(R¹)(R¹)(R¹)(R¹)(R¹) to L_{A49}(R¹⁵⁰)(R¹⁵⁰)(R¹⁵⁰)(R¹⁵⁰)(R¹⁵⁰) have the structure | 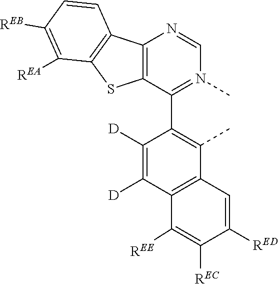 |
| L_{A50}(R^{EA})(R^{EB})(R^{EC})(R^{ED})(R^{EE}), wherein L_{A50}(R¹)(R¹)(R¹)(R¹)(R¹) to L_{A50}(R¹⁵⁰)(R¹⁵⁰)(R¹⁵⁰)(R¹⁵⁰)(R¹⁵⁰) have the structure | 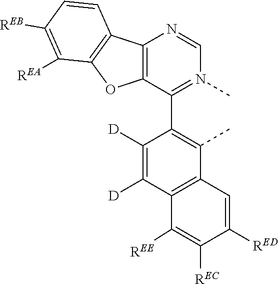 |
| L_{A51}(R^{EA})(R^{EB})(R^{EC})(R^{ED})(R^{EE}), wherein L_{A51}(R¹)(R¹)(R¹)(R¹)(R¹) to L_{A51}(R¹⁵⁰)(R¹⁵⁰)(R¹⁵⁰)(R¹⁵⁰)(R¹⁵⁰) have the structure | 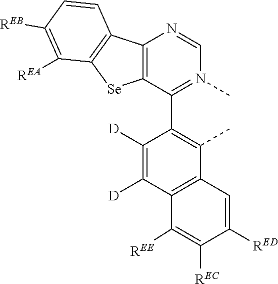 |
| L_{A52}(R^{EA})(R^{EB})(R^{EC})(R^{ED})(R^{EE}), wherein L_{A52}(R¹)(R¹)(R¹)(R¹)(R¹) to L_{A52}(R¹⁵⁰)(R¹⁵⁰)(R¹⁵⁰)(R¹⁵⁰)(R¹⁵⁰) have the structure | 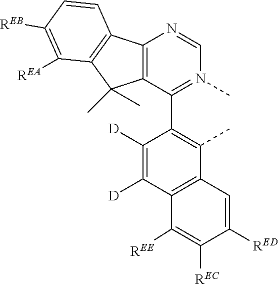 |
| L_{A53}(R^{EA})(R^{EB})(R^{EC})(R^{ED})(R^{EE}), wherein L_{A53}(R¹)(R¹)(R¹)(R¹)(R¹) to L_{A53}(R¹⁵⁰)(R¹⁵⁰)(R¹⁵⁰)(R¹⁵⁰)(R¹⁵⁰) have the structure | 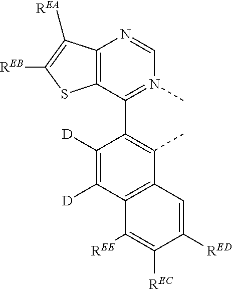 |
| L_{A54}(R^{EA})(R^{EB})(R^{EC})(R^{ED})(R^{EE}), wherein L_{A54}(R¹)(R¹)(R¹)(R¹)(R¹) to L_{A54}(R¹⁵⁰)(R¹⁵⁰)(R¹⁵⁰)(R¹⁵⁰)(R¹⁵⁰) have the structure | 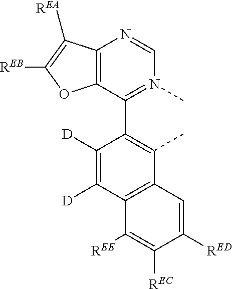 |
| L_{A55}(R^{EA})(R^{EB})(R^{EC})(R^{ED})(R^{EE}), wherein L_{A55}(R¹)(R¹)(R¹)(R¹)(R¹) to L_{A55}(R¹⁵⁰)(R¹⁵⁰)(R¹⁵⁰)(R¹⁵⁰)(R¹⁵⁰) have the structure | 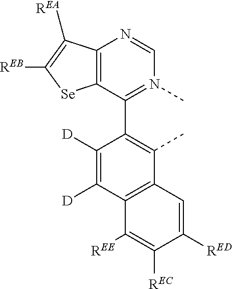 |
| L_{A56}(R^{EA})(R^{EB})(R^{EC})(R^{ED})(R^{EE}), wherein L_{A56}(R¹)(R¹)(R¹)(R¹)(R¹) to L_{A56}(R¹⁵⁰)(R¹⁵⁰)(R¹⁵⁰)(R¹⁵⁰)(R¹⁵⁰) have the structure | 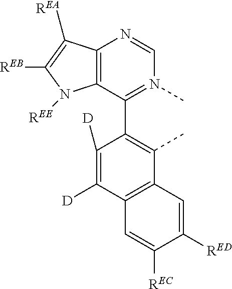 |
| L_{A57}(R^{EA})(R^{EB})(R^{EC})(R^{ED})(R^{EE}), wherein L_{A57}(R¹)(R¹)(R¹)(R¹)(R¹) to L_{A57}(R¹⁵⁰)(R¹⁵⁰)(R¹⁵⁰)(R¹⁵⁰)(R¹⁵⁰) have the structure | 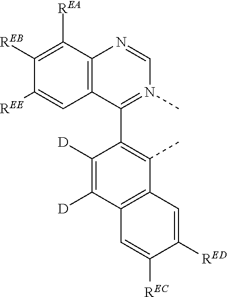 |
| L_{A58}(R^{EA})(R^{EB})(R^{EC})(R^{ED})(R^{EE}), wherein L_{A58}(R¹)(R¹)(R¹)(R¹)(R¹) to L_{A58}(R¹⁵⁰)(R¹⁵⁰)(R¹⁵⁰)(R¹⁵⁰)(R¹⁵⁰) have the structure | 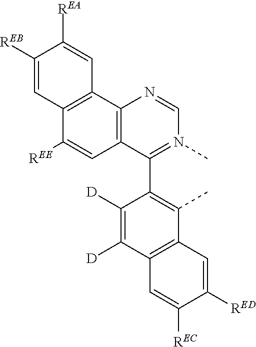 |
| L_{A59}(R^{EA})(R^{EB})(R^{EC})(R^{ED})(R^{EE}), wherein L_{A59}(R¹)(R¹)(R¹)(R¹)(R¹) to L_{A59}(R¹⁵⁰)(R¹⁵⁰)(R¹⁵⁰)(R¹⁵⁰)(R¹⁵⁰) have the structure | 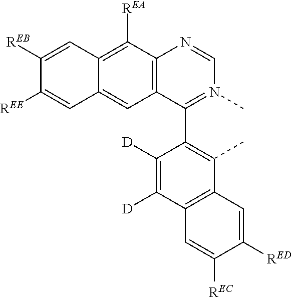 |
| L_{A60}(R^{EA})(R^{EB})(R^{EC})(R^{ED})(R^{EE}), wherein L_{A60}(R¹)(R¹)(R¹)(R¹)(R¹) to L_{A60}(R¹⁵⁰)(R¹⁵⁰)(R¹⁵⁰)(R¹⁵⁰)(R¹⁵⁰) have the structure | 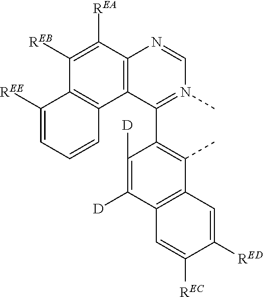 |
| L_{A61}(R^{EA})(R^{EB})(R^{EC})(R^{ED})(R^{EE}), wherein L_{A61}(R¹)(R¹)(R¹)(R¹)(R¹) to L_{A61}(R¹⁵⁰)(R¹⁵⁰)(R¹⁵⁰)(R¹⁵⁰)(R¹⁵⁰) have the structure | 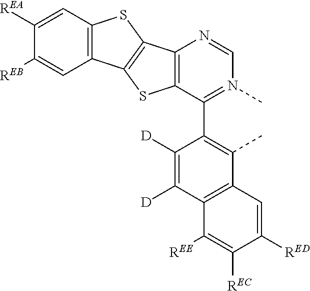 |
| L_{A62}(R^{EA})(R^{EB})(R^{EC})(R^{ED})(R^{EE}), wherein L_{A62}(R¹)(R¹)(R¹)(R¹)(R¹) to L_{A62}(R¹⁵⁰)(R¹⁵⁰)(R¹⁵⁰)(R¹⁵⁰)(R¹⁵⁰) have the structure | 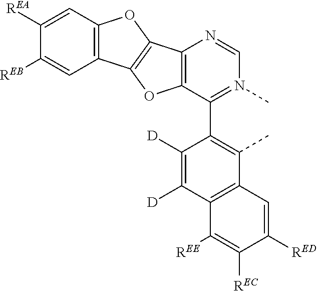 |
| L_{A63}(R^{EA})(R^{EB})(R^{EC})(R^{ED})(R^{EE}), wherein L_{A63}(R¹)(R¹)(R¹)(R¹)(R¹) to L_{A63}(R¹⁵⁰)(R¹⁵⁰)(R¹⁵⁰)(R¹⁵⁰)(R¹⁵⁰) have the structure | 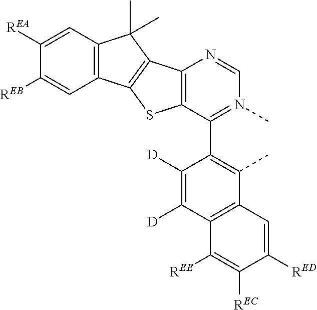 |
| L_{A64}(R^{EA})(R^{EB})(R^{EC})(R^{ED})(R^{EE}), wherein L_{A64}(R¹)(R¹)(R¹)(R¹)(R¹) to L_{A64}(R¹⁵⁰)(R¹⁵⁰)(R¹⁵⁰)(R¹⁵⁰)(R¹⁵⁰) have the structure | 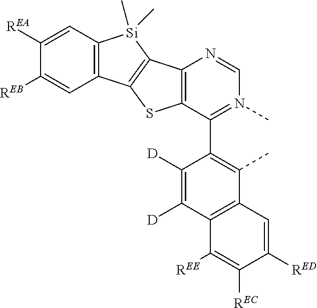 |
| L_{A65}(R^{EA})(R^{EB})(R^{EC})(R^{ED})(R^{EE}), wherein L_{A65}(R¹)(R¹)(R¹)(R¹)(R¹) to L_{A65}(R¹⁵⁰)(R¹⁵⁰)(R¹⁵⁰)(R¹⁵⁰)(R¹⁵⁰) have the structure | 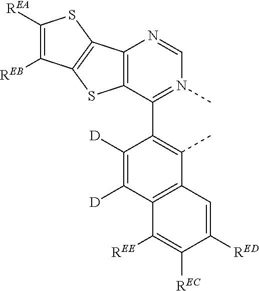 |
| L_{A66}(R^{EA})(R^{EB})(R^{EC})(R^{ED})(R^{EE}), wherein L_{A66}(R¹)(R¹)(R¹)(R¹)(R¹) to L_{A66}(R¹⁵⁰)(R¹⁵⁰)(R¹⁵⁰)(R¹⁵⁰)(R¹⁵⁰) have the structure | 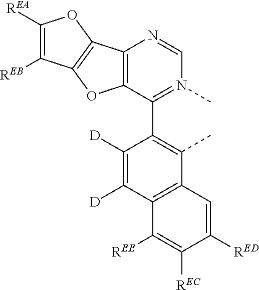 |
| L_{A67}(R^{EA})(R^{EB})(R^{EC})(R^{ED})(R^{EE}), wherein L_{A67}(R¹)(R¹)(R¹)(R¹)(R¹) to L_{A67}(R¹⁵⁰)(R¹⁵⁰)(R¹⁵⁰)(R¹⁵⁰)(R¹⁵⁰) have the structure | 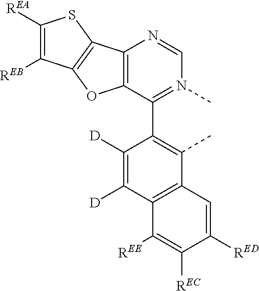 |
| L_{A68}(R^{EA})(R^{EB})(R^{EC})(R^{ED})(R^{EE}), wherein L_{A68}(R¹)(R¹)(R¹)(R¹)(R¹) to L_{A68}(R¹⁵⁰)(R¹⁵⁰)(R¹⁵⁰)(R¹⁵⁰)(R¹⁵⁰) have the structure | 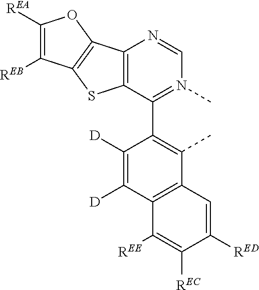 |
| L_{A69}(R^{EA})(R^{EB})(R^{EC})(R^{ED})(R^{EE}), wherein L_{A69}(R¹)(R¹)(R¹)(R¹)(R¹) to L_{A69}(R¹⁵⁰)(R¹⁵⁰)(R¹⁵⁰)(R¹⁵⁰)(R¹⁵⁰) have the structure | 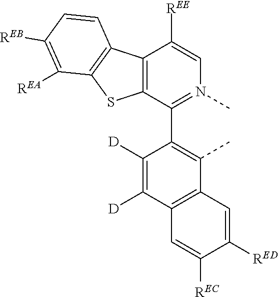 |
| L_{A70}(R^{EA})(R^{EB})(R^{EC})(R^{ED})(R^{EE}), wherein L_{A70}(R¹)(R¹)(R¹)(R¹)(R¹) to L_{A70}(R¹⁵⁰)(R¹⁵⁰)(R¹⁵⁰)(R¹⁵⁰)(R¹⁵⁰) have the structure | 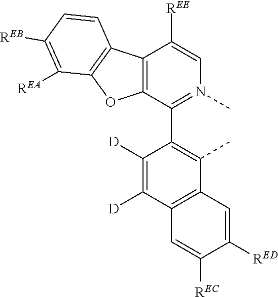 |
| L_{A71}(R^{EA})(R^{EB})(R^{EC})(R^{ED})(R^{EE}), wherein L_{A71}(R¹)(R¹)(R¹)(R¹)(R¹) to L_{A71}(R¹⁵⁰)(R¹⁵⁰)(R¹⁵⁰)(R¹⁵⁰)(R¹⁵⁰) have the structure | 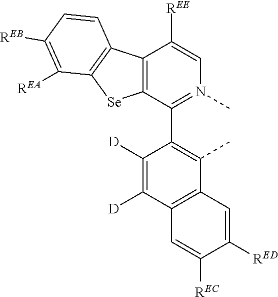 |
| L_{A72}(R^{EA})(R^{EB})(R^{EC})(R^{ED})(R^{EE}), wherein L_{A72}(R¹)(R¹)(R¹)(R¹)(R¹) to L_{A72}(R¹⁵⁰)(R¹⁵⁰)(R¹⁵⁰)(R¹⁵⁰)(R¹⁵⁰) have the structure | 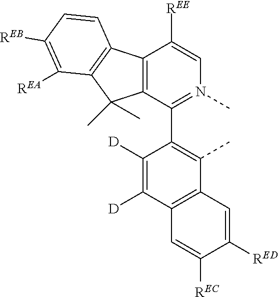 |
| L_{A73}(R^{EA})(R^{EB})(R^{EC})(R^{ED})(R^{EE}), wherein L_{A73}(R¹)(R¹)(R¹)(R¹)(R¹) to L_{A73}(R¹⁵⁰)(R¹⁵⁰)(R¹⁵⁰)(R¹⁵⁰)(R¹⁵⁰) have the structure | 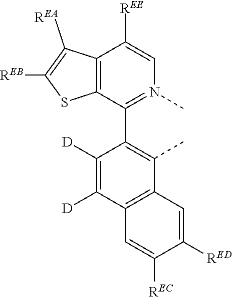 |
| L_{A74}(R^{EA})(R^{EB})(R^{EC})(R^{ED})(R^{EE}), wherein L_{A74}(R¹)(R¹)(R¹)(R¹)(R¹) to L_{A74}(R¹⁵⁰)(R¹⁵⁰)(R¹⁵⁰)(R¹⁵⁰)(R¹⁵⁰) have the structure | 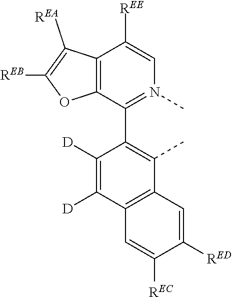 |
| L_{A75}(R^{EA})(R^{EB})(R^{EC})(R^{ED})(R^{EE}), wherein L_{A75}(R¹)(R¹)(R¹)(R¹)(R¹) to L_{A75}(R¹⁵⁰)(R¹⁵⁰)(R¹⁵⁰)(R¹⁵⁰)(R¹⁵⁰) have the structure | 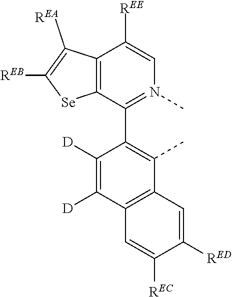 |
| L_{A76}(R^{EA})(R^{EB})(R^{EC})(R^{ED})(R^{EE}), wherein L_{A76}(R¹)(R¹)(R¹)(R¹)(R¹) to L_{A76}(R¹⁵⁰)(R¹⁵⁰)(R¹⁵⁰)(R¹⁵⁰)(R¹⁵⁰) have the structure | 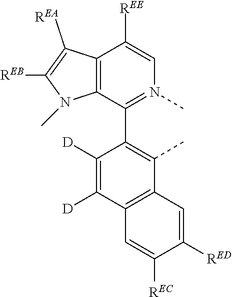 |
| L_{A77}(R^{EA})(R^{EB})(R^{EC})(R^{ED})(R^{EE}), wherein L_{A77}(R¹)(R¹)(R¹)(R¹)(R¹) to L_{A77}(R¹⁵⁰)(R¹⁵⁰)(R¹⁵⁰)(R¹⁵⁰)(R¹⁵⁰) have the structure | 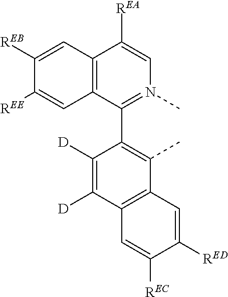 |
| L_{A78}(R^{EA})(R^{EB})(R^{EC})(R^{ED})(R^{EE}), wherein L_{A78}(R¹)(R¹)(R¹)(R¹)(R¹) to L_{A78}(R¹⁵⁰)(R¹⁵⁰)(R¹⁵⁰)(R¹⁵⁰)(R¹⁵⁰) have the structure | 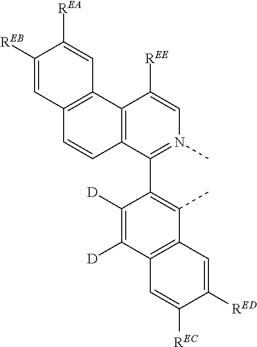 |
| L_{A79}(R^{EA})(R^{EB})(R^{EC})(R^{ED})(R^{EE}), wherein L_{A79}(R¹)(R¹)(R¹)(R¹)(R¹) to L_{A79}(R¹⁵⁰)(R¹⁵⁰)(R¹⁵⁰)(R¹⁵⁰)(R¹⁵⁰) have the structure | 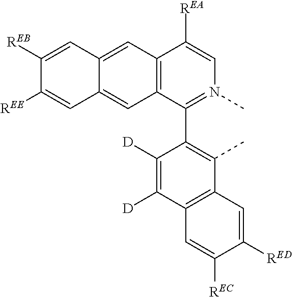 |
| L_{A80}(R^{EA})(R^{EB})(R^{EC})(R^{ED})(R^{EE}), wherein L_{A80}(R¹)(R¹)(R¹)(R¹)(R¹) to L_{A80}(R¹⁵⁰)(R¹⁵⁰)(R¹⁵⁰)(R¹⁵⁰)(R¹⁵⁰) have the structure | 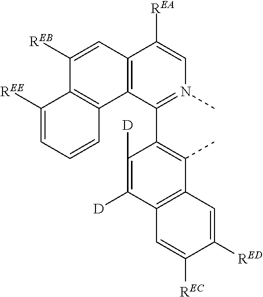 |
| L_{A81}(R^{EA})(R^{EB})(R^{EC})(R^{ED})(R^{EE}), wherein L_{A81}(R¹)(R¹)(R¹)(R¹)(R¹) to L_{A81}(R¹⁵⁰)(R¹⁵⁰)(R¹⁵⁰)(R¹⁵⁰)(R¹⁵⁰) have the structure | 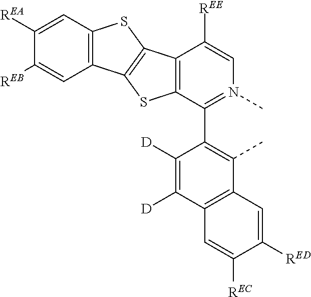 |
| L_{A82}(R^{EA})(R^{EB})(R^{EC})(R^{ED})(R^{EE}), wherein L_{A82}(R¹)(R¹)(R¹)(R¹)(R¹) to L_{A82}(R¹⁵⁰)(R¹⁵⁰)(R¹⁵⁰)(R¹⁵⁰)(R¹⁵⁰) have the structure | 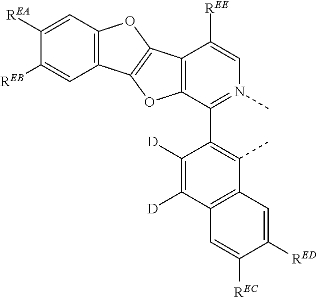 |
| L_{A83}(R^{EA})(R^{EB})(R^{EC})(R^{ED})(R^{EE}), wherein L_{A83}(R¹)(R¹)(R¹)(R¹)(R¹) to L_{A83}(R¹⁵⁰)(R¹⁵⁰)(R¹⁵⁰)(R¹⁵⁰)(R¹⁵⁰) have the structure | 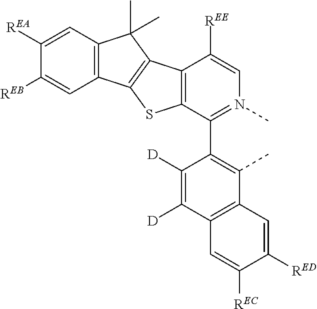 |
| L_{A84}(R^{EA})(R^{EB})(R^{EC})(R^{ED})(R^{EE}), wherein L_{A84}(R¹)(R¹)(R¹)(R¹)(R¹) to L_{A84}(R¹⁵⁰)(R¹⁵⁰)(R¹⁵⁰)(R¹⁵⁰)(R¹⁵⁰) have the structure | 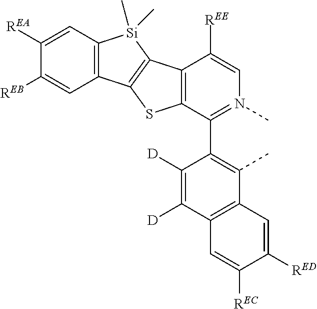 |
| L_{A85}(R^{EA})(R^{EB})(R^{EC})(R^{ED})(R^{EE}), wherein L_{A85}(R¹)(R¹)(R¹)(R¹)(R¹) to L_{A85}(R¹⁵⁰)(R¹⁵⁰)(R¹⁵⁰)(R¹⁵⁰)(R¹⁵⁰) have the structure | 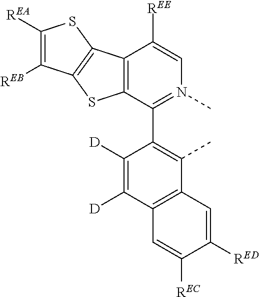 |
| L_{A86}(R^{EA})(R^{EB})(R^{EC})(R^{ED})(R^{EE}), wherein L_{A86}(R¹)(R¹)(R¹)(R¹)(R¹) to L_{A86}(R¹⁵⁰)(R¹⁵⁰)(R¹⁵⁰)(R¹⁵⁰)(R¹⁵⁰) have the structure | 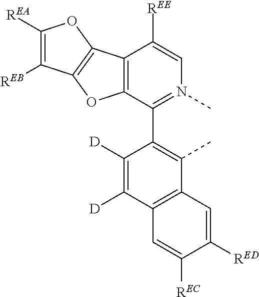 |
| L_{A87}(R^{EA})(R^{EB})(R^{EC})(R^{ED})(R^{EE}), wherein L_{A87}(R¹)(R¹)(R¹)(R¹)(R¹) to L_{A87}(R¹⁵⁰)(R¹⁵⁰)(R¹⁵⁰)(R¹⁵⁰)(R¹⁵⁰) have the structure | 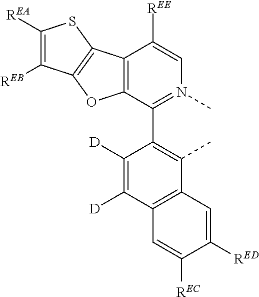 |
| L_{A88}(R^{EA})(R^{EB})(R^{EC})(R^{ED})(R^{EE}), wherein L_{A88}(R¹)(R¹)(R¹)(R¹)(R¹) to L_{A88}(R¹⁵⁰)(R¹⁵⁰)(R¹⁵⁰)(R¹⁵⁰)(R¹⁵⁰) have the structure | 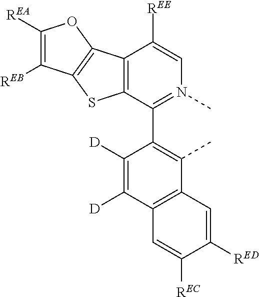 |
| L_{A89}(R^{EA})(R^{EB})(R^{EC})(R^{ED})(R^{EE}), wherein L_{A89}(R¹)(R¹)(R¹)(R¹)(R¹) to L_{A89}(R¹⁵⁰)(R¹⁵⁰)(R¹⁵⁰)(R¹⁵⁰)(R¹⁵⁰) have the structure | 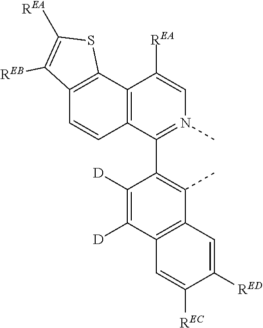 |
| L_{A90}(R^{EA})(R^{EB})(R^{EC})(R^{ED})(R^{EE}), wherein L_{A90}(R¹)(R¹)(R¹)(R¹)(R¹) to L_{A90}(R¹⁵⁰)(R¹⁵⁰)(R¹⁵⁰)(R¹⁵⁰)(R¹⁵⁰) have the structure | 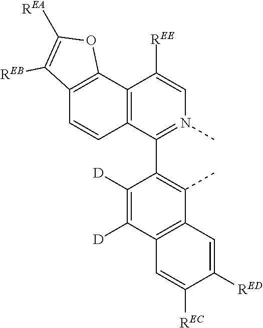 |
| L_{A91}(R^{EA})(R^{EB})(R^{EC})(R^{ED})(R^{EE}), wherein L_{A91}(R¹)(R¹)(R¹)(R¹)(R¹) to L_{A91}(R¹⁵⁰)(R¹⁵⁰)(R¹⁵⁰)(R¹⁵⁰)(R¹⁵⁰) have the structure | 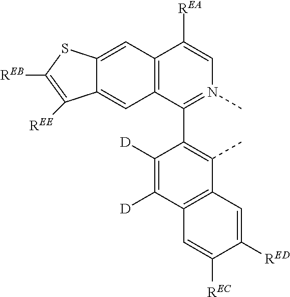 |
| L_{A92}(R^{EA})(R^{EB})(R^{EC})(R^{ED})(R^{EE}), wherein L_{A92}(R¹)(R¹)(R¹)(R¹)(R¹) to L_{A92}(R¹⁵⁰)(R¹⁵⁰)(R¹⁵⁰)(R¹⁵⁰)(R¹⁵⁰) have the structure | 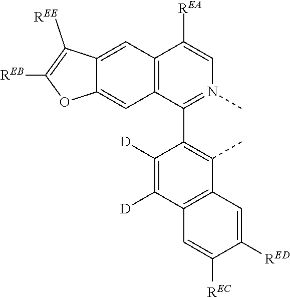 |
| L_{A93}(R^{EA})(R^{EB})(R^{EC})(R^{ED})(R^{EE}), wherein L_{A93}(R¹)(R¹)(R¹)(R¹)(R¹) to L_{A93}(R¹⁵⁰)(R¹⁵⁰)(R¹⁵⁰)(R¹⁵⁰)(R¹⁵⁰) have the structure | 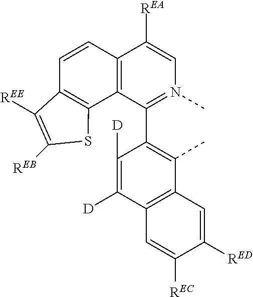 |
| L_{A94}(R^{EA})(R^{EB})(R^{EC})(R^{ED})(R^{EE}), wherein L_{A94}(R¹)(R¹)(R¹)(R¹)(R¹) to L_{A94}(R¹⁵⁰)(R¹⁵⁰)(R¹⁵⁰)(R¹⁵⁰)(R¹⁵⁰) have the structure | 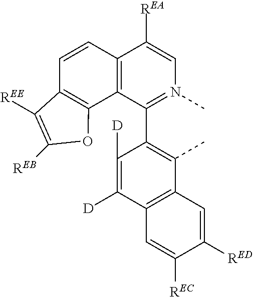 |
| L_{A95}(R^{EA})(R^{EB})(R^{EC})(R^{ED})(R^{EE}), wherein L_{A95}(R¹)(R¹)(R¹)(R¹)(R¹) to L_{A95}(R¹⁵⁰)(R¹⁵⁰)(R¹⁵⁰)(R¹⁵⁰)(R¹⁵⁰) have the structure | 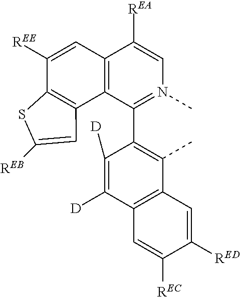 |
| L_{A96}(R^{EA})(R^{EB})(R^{EC})(R^{ED})(R^{EE}), wherein L_{A96}(R¹)(R¹)(R¹)(R¹)(R¹) to L_{A96}(R¹⁵⁰)(R¹⁵⁰)(R¹⁵⁰)(R¹⁵⁰)(R¹⁵⁰) have the structure | 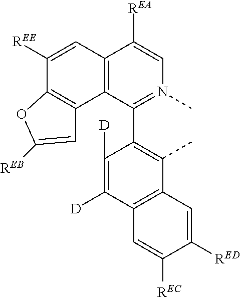 |
| L_{A97}(R^{EA})(R^{EB})(R^{EC})(R^{ED})(R^{EE}), wherein L_{A97}(R¹)(R¹)(R¹)(R¹)(R¹) to L_{A97}(R¹⁵⁰)(R¹⁵⁰)(R¹⁵⁰)(R¹⁵⁰)(R¹⁵⁰) have the structure | 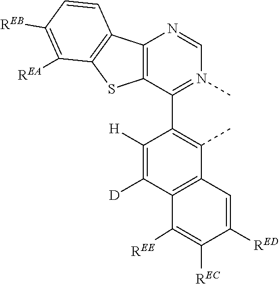 |
| L_{A98}(R^{EA})(R^{EB})(R^{EC})(R^{ED})(R^{EE}), wherein L_{A98}(R¹)(R¹)(R¹)(R¹)(R¹) to L_{A98}(R¹⁵⁰)(R¹⁵⁰)(R¹⁵⁰)(R¹⁵⁰)(R¹⁵⁰) have the structure | 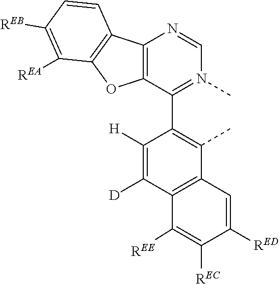 |
| L_{A99}(R^{EA})(R^{EB})(R^{EC})(R^{ED})(R^{EE}), wherein L_{A99}(R¹)(R¹)(R¹)(R¹)(R¹) to L_{A99}(R¹⁵⁰)(R¹⁵⁰)(R¹⁵⁰)(R¹⁵⁰)(R¹⁵⁰) have the structure | 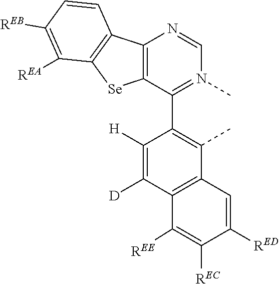 |
| L_{A100}(R^{EA})(R^{EB})(R^{EC})(R^{ED})(R^{EE}), wherein L_{A100}(R¹)(R¹)(R¹)(R¹)(R¹) to L_{A100}(R¹⁵⁰)(R¹⁵⁰)(R¹⁵⁰)(R¹⁵⁰)(R¹⁵⁰) have the structure | 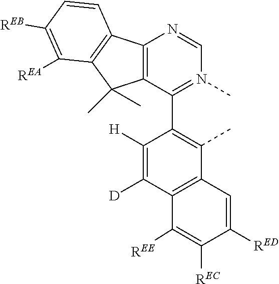 |
| L_{A101}(R^{EA})(R^{EB})(R^{EC})(R^{ED})(R^{EE}), wherein L_{A101}(R¹)(R¹)(R¹)(R¹)(R¹) to L_{A101}(R¹⁵⁰)(R¹⁵⁰)(R¹⁵⁰)(R¹⁵⁰)(R¹⁵⁰) have the structure | 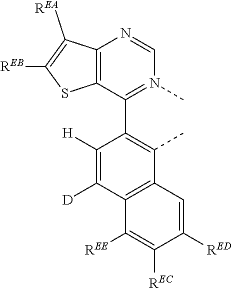 |
| L_{A102}(R^{EA})(R^{EB})(R^{EC})(R^{ED})(R^{EE}), wherein L_{A102}(R¹)(R¹)(R¹)(R¹)(R¹) to L_{A102}(R¹⁵⁰)(R¹⁵⁰)(R¹⁵⁰)(R¹⁵⁰)(R¹⁵⁰) have the structure | 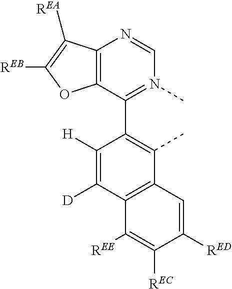 |
| L_{A103}(R^{EA})(R^{EB})(R^{EC})(R^{ED})(R^{EE}), wherein L_{A103}(R¹)(R¹)(R¹)(R¹)(R¹) to L_{A103}(R¹⁵⁰)(R¹⁵⁰)(R¹⁵⁰)(R¹⁵⁰)(R¹⁵⁰) have the structure | 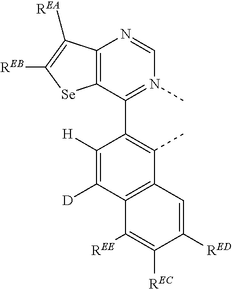 |
| L_{A104}(R^{EA})(R^{EB})(R^{EC})(R^{ED})(R^{EE}), wherein L_{A104}(R¹)(R¹)(R¹)(R¹)(R¹) to L_{A104}(R¹⁵⁰)(R¹⁵⁰)(R¹⁵⁰)(R¹⁵⁰)(R¹⁵⁰) have the structure | 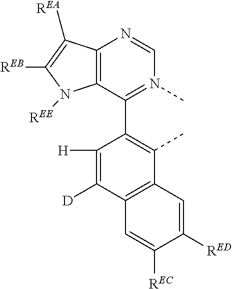 |
| L_{A105}(R^{EA})(R^{EB})(R^{EC})(R^{ED})(R^{EE}), wherein L_{A105}(R¹)(R¹)(R¹)(R¹)(R¹) to L_{A105}(R¹⁵⁰)(R¹⁵⁰)(R¹⁵⁰)(R¹⁵⁰)(R¹⁵⁰) have the structure | 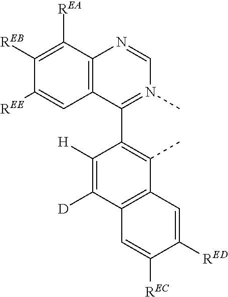 |
| L_{A106}(R^{EA})(R^{EB})(R^{EC})(R^{ED})(R^{EE}), wherein L_{A106}(R¹)(R¹)(R¹)(R¹)(R¹) to L_{A106}(R¹⁵⁰)(R¹⁵⁰)(R¹⁵⁰)(R¹⁵⁰)(R¹⁵⁰) have the structure | 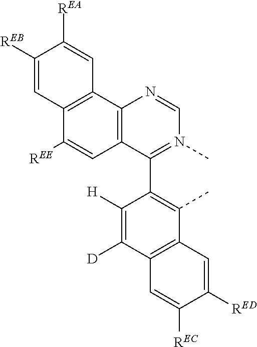 |
| L_{A107}(R^{EA})(R^{EB})(R^{EC})(R^{ED})(R^{EE}), wherein L_{A107}(R¹)(R¹)(R¹)(R¹)(R¹) to L_{A107}(R¹⁵⁰)(R¹⁵⁰)(R¹⁵⁰)(R¹⁵⁰)(R¹⁵⁰) have the structure | 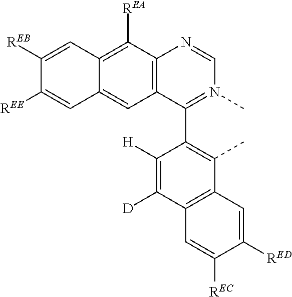 |
| L_{A108}(R^{EA})(R^{EB})(R^{EC})(R^{ED})(R^{EE}), wherein L_{A108}(R¹)(R¹)(R¹)(R¹)(R¹) to L_{A108}(R¹⁵⁰)(R¹⁵⁰)(R¹⁵⁰)(R¹⁵⁰)(R¹⁵⁰) have the structure | 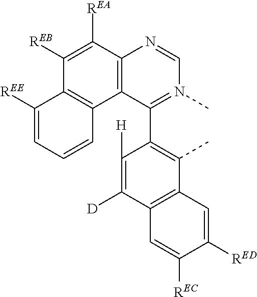 |
| L_{A109}(R^{EA})(R^{EB})(R^{EC})(R^{ED})(R^{EE}), wherein L_{A109}(R¹)(R¹)(R¹)(R¹)(R¹) to L_{A109}(R¹⁵⁰)(R¹⁵⁰)(R¹⁵⁰)(R¹⁵⁰)(R¹⁵⁰) have the structure | 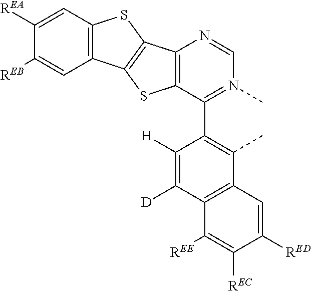 |
| L_{A110}(R^{EA})(R^{EB})(R^{EC})(R^{ED})(R^{EE}), wherein L_{A110}(R¹)(R¹)(R¹)(R¹)(R¹) to L_{A110}(R¹⁵⁰)(R¹⁵⁰)(R¹⁵⁰)(R¹⁵⁰)(R¹⁵⁰) have the structure | 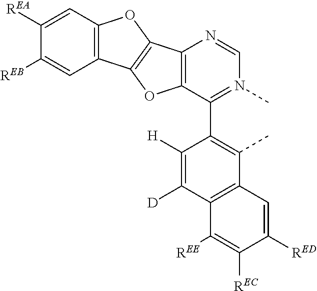 |
| L_{A111}(R^{EA})(R^{EB})(R^{EC})(R^{ED})(R^{EE}), wherein L_{A111}(R¹)(R¹)(R¹)(R¹)(R¹) to L_{A111}(R¹⁵⁰)(R¹⁵⁰)(R¹⁵⁰)(R¹⁵⁰)(R¹⁵⁰) have the structure | 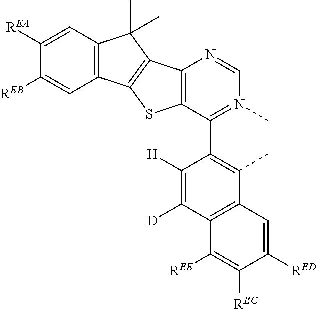 |
| L_{A112}(R^{EA})(R^{EB})(R^{EC})(R^{ED})(R^{EE}), wherein L_{A112}(R¹)(R¹)(R¹)(R¹)(R¹) to L_{A112}(R¹⁵⁰)(R¹⁵⁰)(R¹⁵⁰)(R¹⁵⁰)(R¹⁵⁰) have the structure | 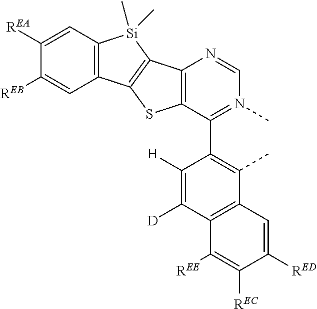 |
| L_{A113}(R^{EA})(R^{EB})(R^{EC})(R^{ED})(R^{EE}), wherein L_{A113}(R¹)(R¹)(R¹)(R¹)(R¹) to L_{A113}(R¹⁵⁰)(R¹⁵⁰)(R¹⁵⁰)(R¹⁵⁰)(R¹⁵⁰) have the structure | 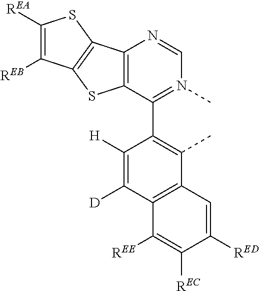 |
| L_{A114}(R^{EA})(R^{EB})(R^{EC})(R^{ED})(R^{EE}), wherein L_{A114}(R¹)(R¹)(R¹)(R¹)(R¹) to L_{A114}(R¹⁵⁰)(R¹⁵⁰)(R¹⁵⁰)(R¹⁵⁰)(R¹⁵⁰) have the structure | 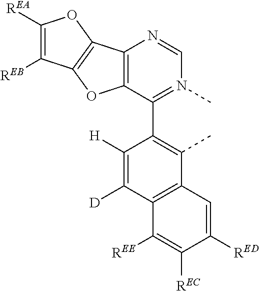 |
| L_{A115}(R^{EA})(R^{EB})(R^{EC})(R^{ED})(R^{EE}), wherein L_{A115}(R¹)(R¹)(R¹)(R¹)(R¹) to L_{A115}(R¹⁵⁰)(R¹⁵⁰)(R¹⁵⁰)(R¹⁵⁰)(R¹⁵⁰) have the structure | 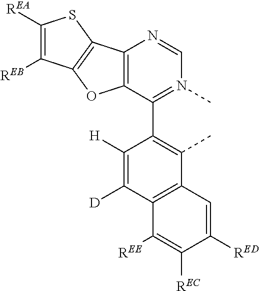 |
| L_{A116}(R^{EA})(R^{EB})(R^{EC})(R^{ED})(R^{EE}), wherein L_{A116}(R¹)(R¹)(R¹)(R¹)(R¹) to L_{A116}(R¹⁵⁰)(R¹⁵⁰)(R¹⁵⁰)(R¹⁵⁰)(R¹⁵⁰) have the structure | 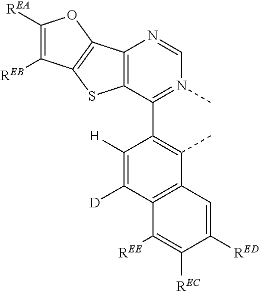 |
| L_{A117}(R^{EA})(R^{EB})(R^{EC})(R^{ED})(R^{EE}), wherein L_{A117}(R¹)(R¹)(R¹)(R¹)(R¹) to L_{A117}(R¹⁵⁰)(R¹⁵⁰)(R¹⁵⁰)(R¹⁵⁰)(R¹⁵⁰) have the structure | 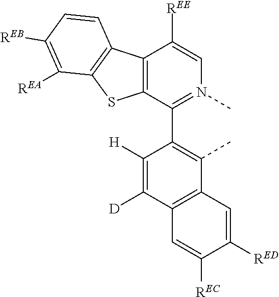 |
| L_{A118}(R^{EA})(R^{EB})(R^{EC})(R^{ED})(R^{EE}), wherein L_{A118}(R¹)(R¹)(R¹)(R¹)(R¹) to L_{A118}(R¹⁵⁰)(R¹⁵⁰)(R¹⁵⁰)(R¹⁵⁰)(R¹⁵⁰) have the structure | 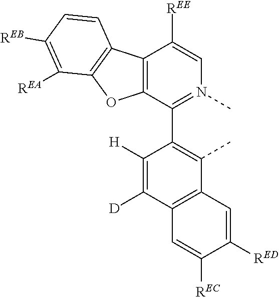 |
| L_{A119}(R^{EA})(R^{EB})(R^{EC})(R^{ED})(R^{EE}), wherein L_{A119}(R¹)(R¹)(R¹)(R¹)(R¹) to L_{A119}(R¹⁵⁰)(R¹⁵⁰)(R¹⁵⁰)(R¹⁵⁰)(R¹⁵⁰) have the structure | 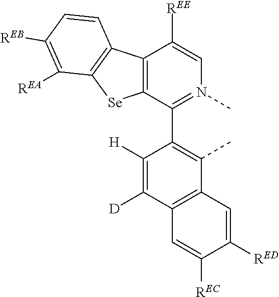 |
| L_{A120}(R^{EA})(R^{EB})(R^{EC})(R^{ED})(R^{EE}), wherein L_{A120}(R¹)(R¹)(R¹)(R¹)(R¹) to L_{A120}(R¹⁵⁰)(R¹⁵⁰)(R¹⁵⁰)(R¹⁵⁰)(R¹⁵⁰) have the structure | 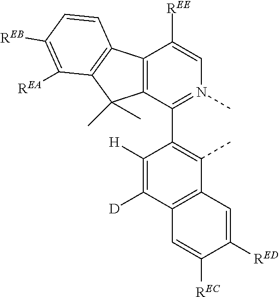 |
| L_{A121}(R^{EA})(R^{EB})(R^{EC})(R^{ED})(R^{EE}), wherein L_{A121}(R¹)(R¹)(R¹)(R¹)(R¹) to L_{A121}(R¹⁵⁰)(R¹⁵⁰)(R¹⁵⁰)(R¹⁵⁰)(R¹⁵⁰) have the structure | 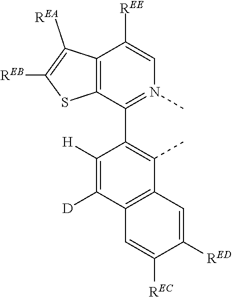 |
| L_{A122}(R^{EA})(R^{EB})(R^{EC})(R^{ED})(R^{EE}), wherein L_{A122}(R¹)(R¹)(R¹)(R¹)(R¹) to L_{A122}(R¹⁵⁰)(R¹⁵⁰)(R¹⁵⁰)(R¹⁵⁰)(R¹⁵⁰) have the structure | 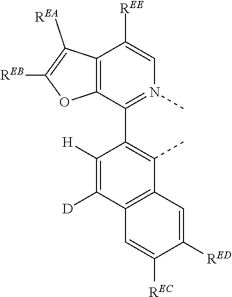 |
| L_{A123}(R^{EA})(R^{EB})(R^{EC})(R^{ED})(R^{EE}), wherein L_{A123}(R¹)(R¹)(R¹)(R¹)(R¹) to L_{A123}(R¹⁵⁰)(R¹⁵⁰)(R¹⁵⁰)(R¹⁵⁰)(R¹⁵⁰) have the structure | 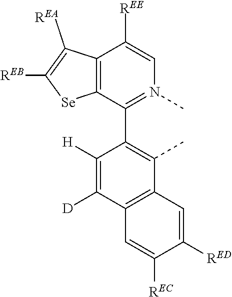 |
| L_{A124}(R^{EA})(R^{EB})(R^{EC})(R^{ED})(R^{EE}), wherein L_{A124}(R¹)(R¹)(R¹)(R¹)(R¹) to L_{A124}(R¹⁵⁰)(R¹⁵⁰)(R¹⁵⁰)(R¹⁵⁰)(R¹⁵⁰) have the structure | 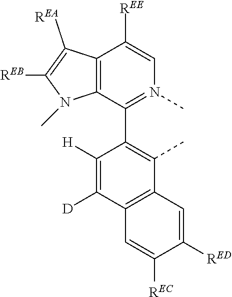 |
| L_{A125}(R^{EA})(R^{EB})(R^{EC})(R^{ED})(R^{EE}), wherein L_{A125}(R¹)(R¹)(R¹)(R¹)(R¹) to L_{A125}(R¹⁵⁰)(R¹⁵⁰)(R¹⁵⁰)(R¹⁵⁰)(R¹⁵⁰) have the structure | 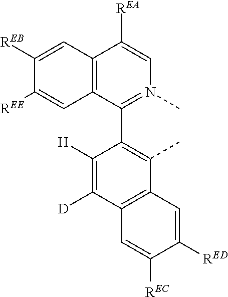 |
| L_{A126}(R^{EA})(R^{EB})(R^{EC})(R^{ED})(R^{EE}), wherein L_{A126}(R¹)(R¹)(R¹)(R¹)(R¹) to L_{A126}(R¹⁵⁰)(R¹⁵⁰)(R¹⁵⁰)(R¹⁵⁰)(R¹⁵⁰) have the structure | 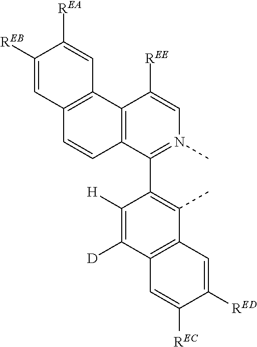 |
| L_{A127}(R^{EA})(R^{EB})(R^{EC})(R^{ED})(R^{EE}), wherein L_{A127}(R¹)(R¹)(R¹)(R¹)(R¹) to L_{A127}(R¹⁵⁰)(R¹⁵⁰)(R¹⁵⁰)(R¹⁵⁰)(R¹⁵⁰) have the structure | 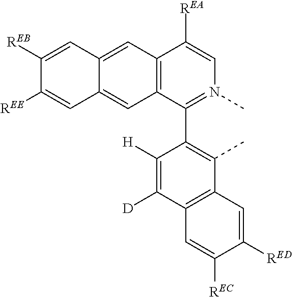 |
| L_{A128}(R^{EA})(R^{EB})(R^{EC})(R^{ED})(R^{EE}), wherein L_{A128}(R¹)(R¹)(R¹)(R¹)(R¹) to L_{A128}(R¹⁵⁰)(R¹⁵⁰)(R¹⁵⁰)(R¹⁵⁰)(R¹⁵⁰) have the structure | 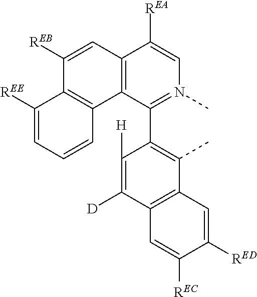 |
| L_{A129}(R^{EA})(R^{EB})(R^{EC})(R^{ED})(R^{EE}), wherein L_{A129}(R¹)(R¹)(R¹)(R¹)(R¹) to L_{A129}(R¹⁵⁰)(R¹⁵⁰)(R¹⁵⁰)(R¹⁵⁰)(R¹⁵⁰) have the structure | 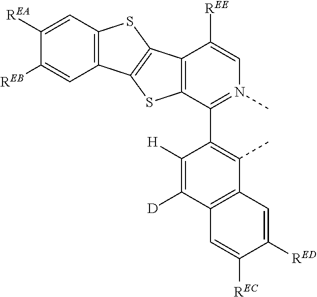 |
| L_{A130}(R^{EA})(R^{EB})(R^{EC})(R^{ED})(R^{EE}), wherein L_{A130}(R¹)(R¹)(R¹)(R¹)(R¹) to L_{A130}(R¹⁵⁰)(R¹⁵⁰)(R¹⁵⁰)(R¹⁵⁰)(R¹⁵⁰) have the structure | 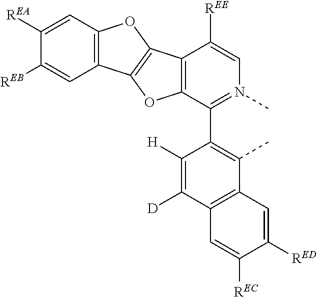 |
| L_{A131}(R^{EA})(R^{EB})(R^{EC})(R^{ED})(R^{EE}), wherein L_{A131}(R¹)(R¹)(R¹)(R¹)(R¹) to L_{A131}(R¹⁵⁰)(R¹⁵⁰)(R¹⁵⁰)(R¹⁵⁰)(R¹⁵⁰) have the structure | 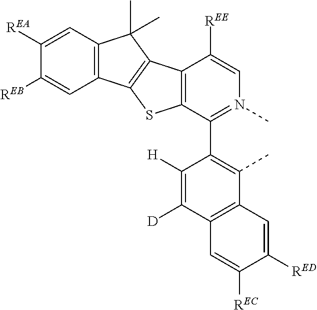 |
| L_{A132}(R^{EA})(R^{EB})(R^{EC})(R^{ED})(R^{EE}), wherein L_{A132}(R¹)(R¹)(R¹)(R¹)(R¹) to L_{A132}(R¹⁵⁰)(R¹⁵⁰)(R¹⁵⁰)(R¹⁵⁰)(R¹⁵⁰) have the structure | 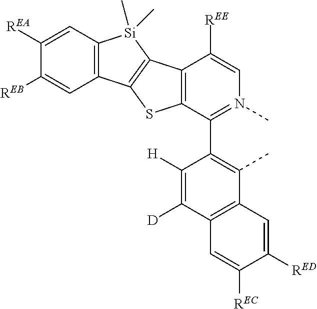 |
| L_{A133}(R^{EA})(R^{EB})(R^{EC})(R^{ED})(R^{EE}), wherein L_{A133}(R¹)(R¹)(R¹)(R¹)(R¹) to L_{A133}(R¹⁵⁰)(R¹⁵⁰)(R¹⁵⁰)(R¹⁵⁰)(R¹⁵⁰) have the structure | 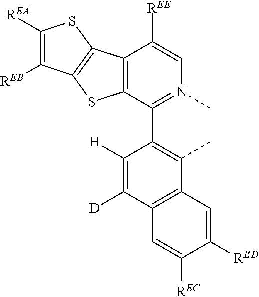 |
| L_{A134}(R^{EA})(R^{EB})(R^{EC})(R^{ED})(R^{EE}), wherein L_{A134}(R¹)(R¹)(R¹)(R¹)(R¹) to L_{A134}(R¹⁵⁰)(R¹⁵⁰)(R¹⁵⁰)(R¹⁵⁰)(R¹⁵⁰) have the structure | 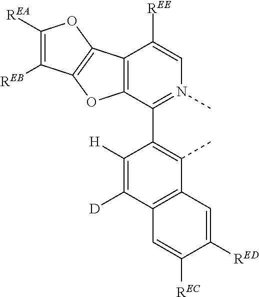 |
| L_{A135}(R^{EA})(R^{EB})(R^{EC})(R^{ED})(R^{EE}), wherein L_{A135}(R¹)(R¹)(R¹)(R¹)(R¹) to L_{A135}(R¹⁵⁰)(R¹⁵⁰)(R¹⁵⁰)(R¹⁵⁰)(R¹⁵⁰) have the structure | 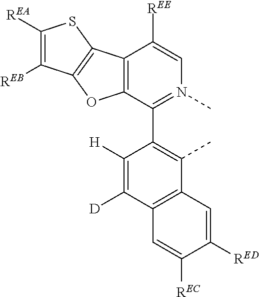 |
| L_{A136}(R^{EA})(R^{EB})(R^{EC})(R^{ED})(R^{EE}), wherein L_{A136}(R¹)(R¹)(R¹)(R¹)(R¹) to L_{A136}(R¹⁵⁰)(R¹⁵⁰)(R¹⁵⁰)(R¹⁵⁰)(R¹⁵⁰) have the structure | 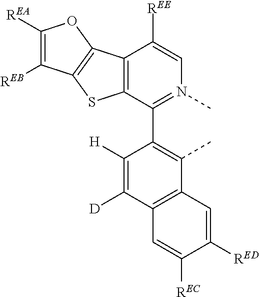 |
| L_{A137}(R^{EA})(R^{EB})(R^{EC})(R^{ED})(R^{EE}), wherein L_{A137}(R¹)(R¹)(R¹)(R¹)(R¹) to L_{A137}(R¹⁵⁰)(R¹⁵⁰)(R¹⁵⁰)(R¹⁵⁰)(R¹⁵⁰) have the structure | 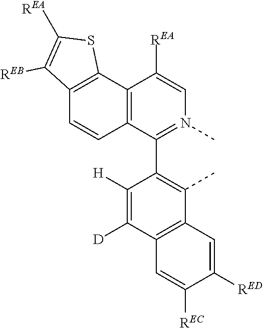 |
| L_{A138}(R^{EA})(R^{EB})(R^{EC})(R^{ED})(R^{EE}), wherein L_{A138}(R¹)(R¹)(R¹)(R¹)(R¹) to L_{A138}(R¹⁵⁰)(R¹⁵⁰)(R¹⁵⁰)(R¹⁵⁰)(R¹⁵⁰) have the structure | 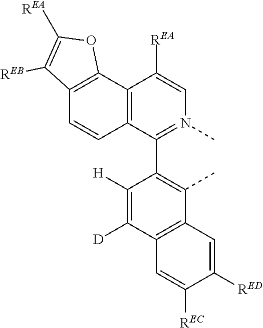 |
| L_{A139}(R^{EA})(R^{EB})(R^{EC})(R^{ED})(R^{EE}), wherein L_{A139}(R¹)(R¹)(R¹)(R¹)(R¹) to L_{A139}(R¹⁵⁰)(R¹⁵⁰)(R¹⁵⁰)(R¹⁵⁰)(R¹⁵⁰) have the structure | 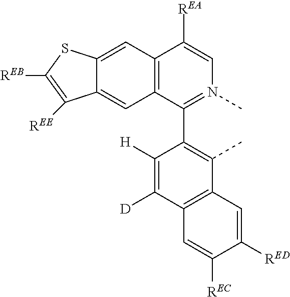 |
| L_{A140}(R^{EA})(R^{EB})(R^{EC})(R^{ED})(R^{EE}), wherein L_{A140}(R¹)(R¹)(R¹)(R¹)(R¹) to L_{A140}(R¹⁵⁰)(R¹⁵⁰)(R¹⁵⁰)(R¹⁵⁰)(R¹⁵⁰) have the structure | 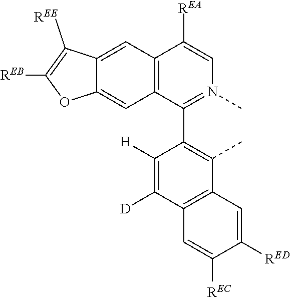 |
| L_{A141}(R^{EA})(R^{EB})(R^{EC})(R^{ED})(R^{EE}), wherein L_{A141}(R¹)(R¹)(R¹)(R¹)(R¹) to L_{A141}(R¹⁵⁰)(R¹⁵⁰)(R¹⁵⁰)(R¹⁵⁰)(R¹⁵⁰) have the structure | 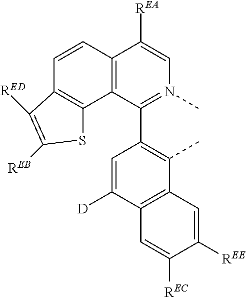 |
| L_{A142}(R^{EA})(R^{EB})(R^{EC})(R^{ED})(R^{EE}), wherein L_{A142}(R¹)(R¹)(R¹)(R¹)(R¹) to L_{A142}(R¹⁵⁰)(R¹⁵⁰)(R¹⁵⁰)(R¹⁵⁰)(R¹⁵⁰) have the structure | 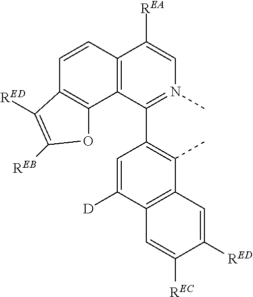 |
| L_{A143}(R^{EA})(R^{EB})(R^{EC})(R^{ED})(R^{EE}), wherein L_{A143}(R¹)(R¹)(R¹)(R¹)(R¹) to L_{A143}(R¹⁵⁰)(R¹⁵⁰)(R¹⁵⁰)(R¹⁵⁰)(R¹⁵⁰) have the structure | 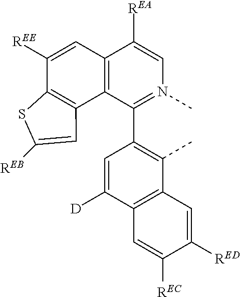 |
| L_{A144}(R^{EA})(R^{EB})(R^{EC})(R^{ED})(R^{EE}), wherein L_{A144}(R¹)(R¹)(R¹)(R¹)(R¹) to L_{A144}(R¹⁵⁰)(R¹⁵⁰)(R¹⁵⁰)(R¹⁵⁰)(R¹⁵⁰) have the structure | 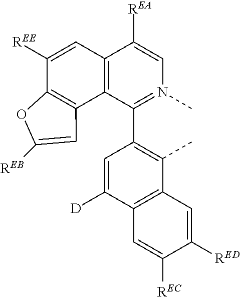 |
| L_{A145}(R^{EA})(R^{EB})(R^{EC})(R^{ED})(R^{EE}), wherein L_{A145}(R¹)(R¹)(R¹)(R¹)(R¹) to L_{A145}(R¹⁵⁰)(R¹⁵⁰)(R¹⁵⁰)(R¹⁵⁰)(R¹⁵⁰) have the structure | 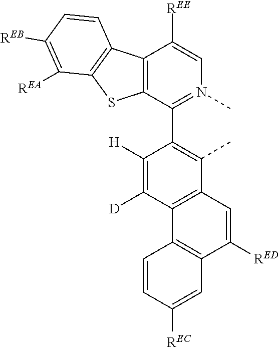 |
| L_{A146}(R^{EA})(R^{EB})(R^{EC})(R^{ED})(R^{EE}), wherein L_{A146}(R¹)(R¹)(R¹)(R¹)(R¹) to L_{A146}(R¹⁵⁰)(R¹⁵⁰)(R¹⁵⁰)(R¹⁵⁰)(R¹⁵⁰) have the structure | 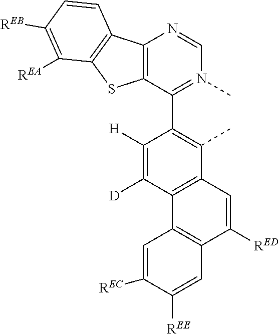 |
| L_{A147}(R^{EA})(R^{EB})(R^{EC})(R^{ED})(R^{EE}), wherein L_{A147}(R¹)(R¹)(R¹)(R¹)(R¹) to L_{A147}(R¹⁵⁰)(R¹⁵⁰)(R¹⁵⁰)(R¹⁵⁰)(R¹⁵⁰) have the structure | 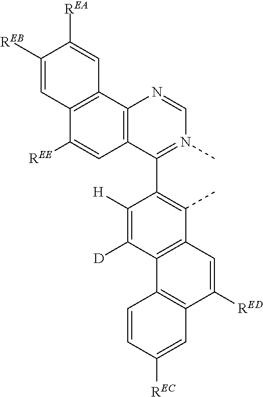 |
| L_{A148}(R^{EA})(R^{EB})(R^{EC})(R^{ED})(R^{EE}), wherein L_{A148}(R¹)(R¹)(R¹)(R¹)(R¹) to L_{A148}(R¹⁵⁰)(R¹⁵⁰)(R¹⁵⁰)(R¹⁵⁰)(R¹⁵⁰) have the structure | 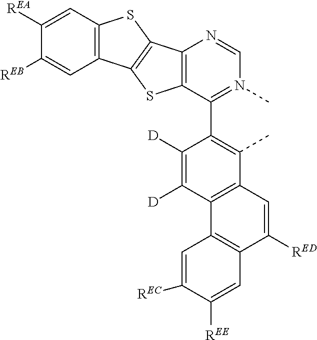 |

wherein R¹ to R¹⁵⁰ have the structures defined as follows:

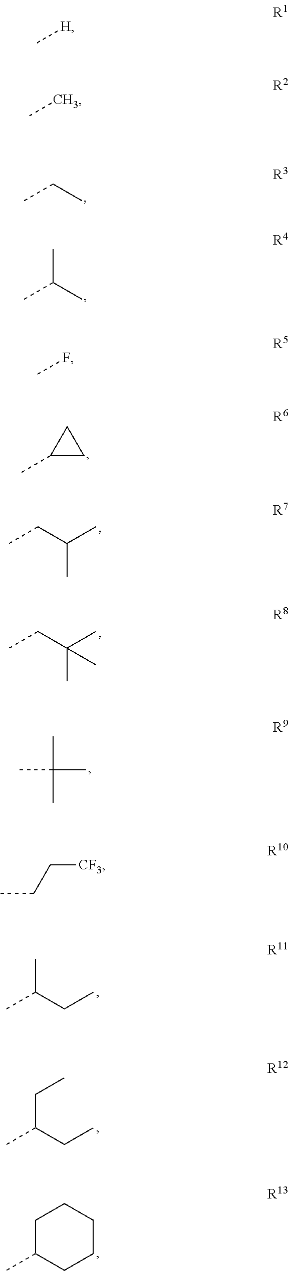

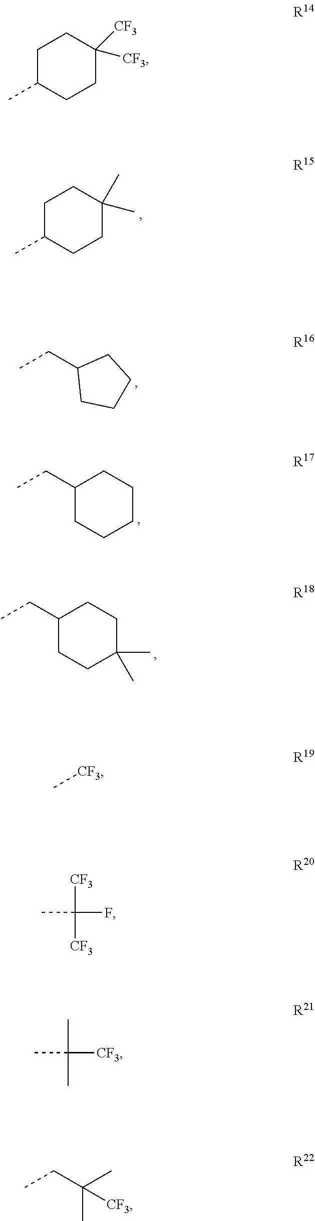

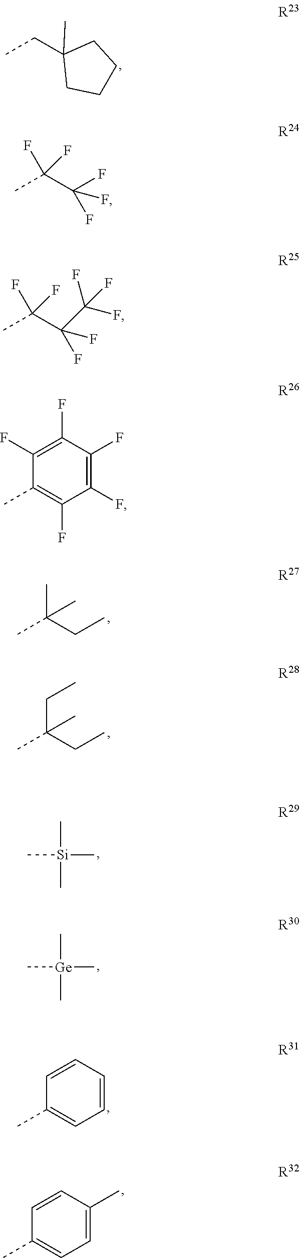

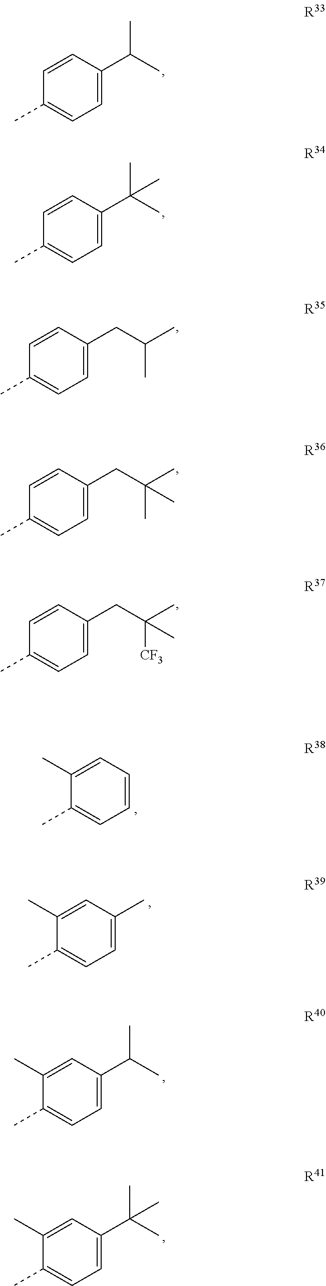

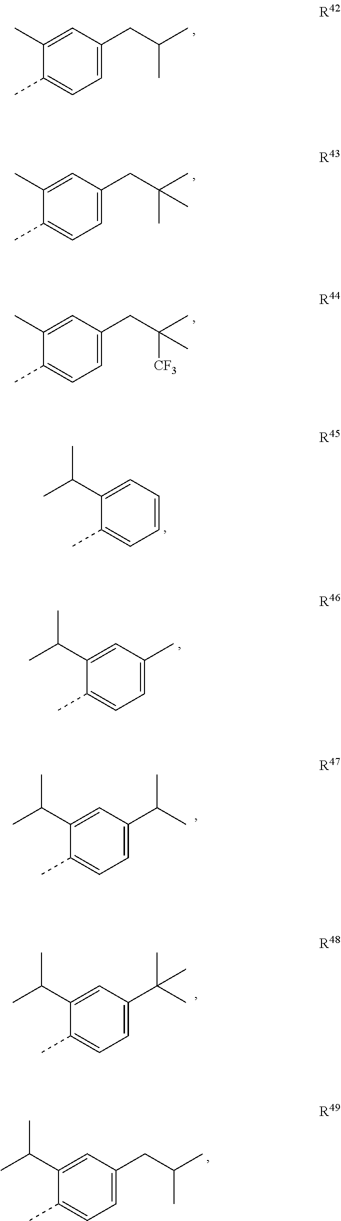

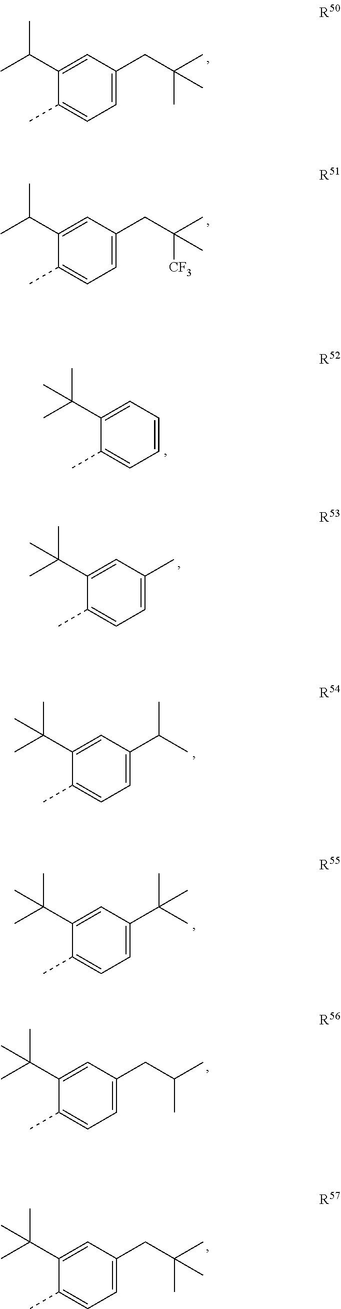

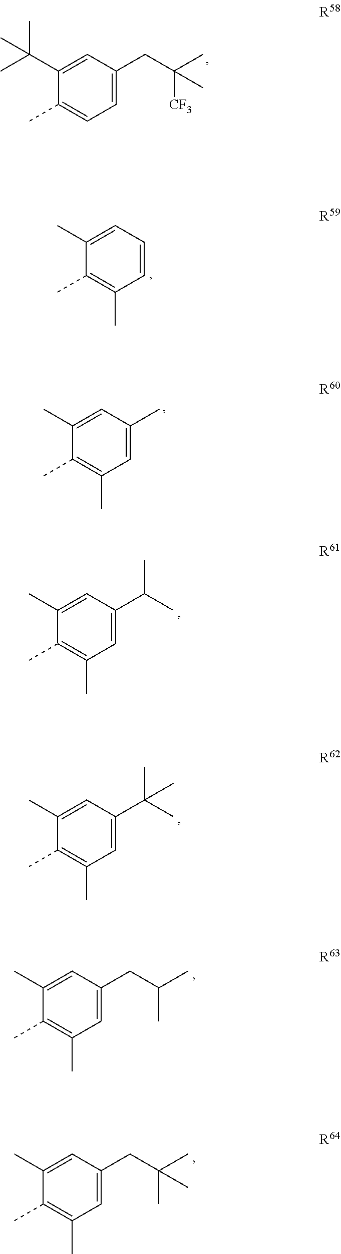

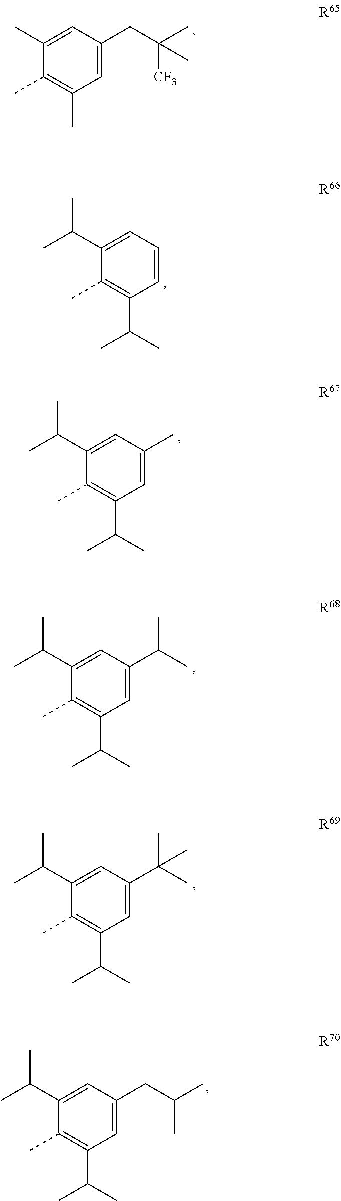

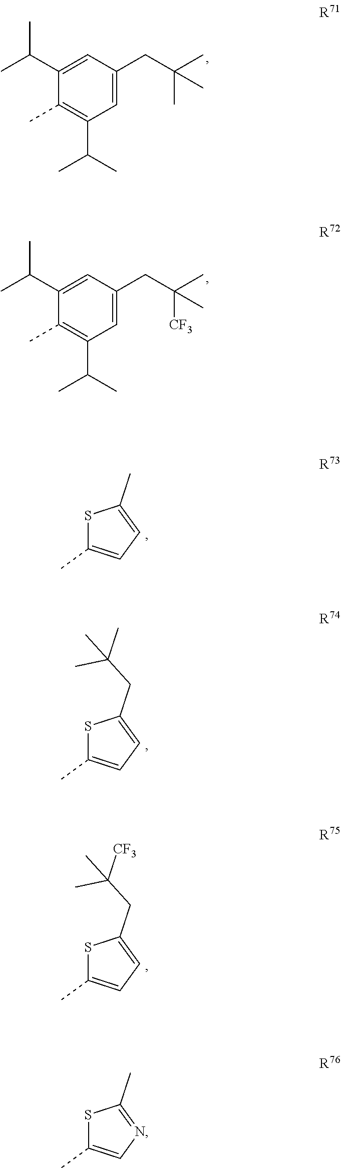

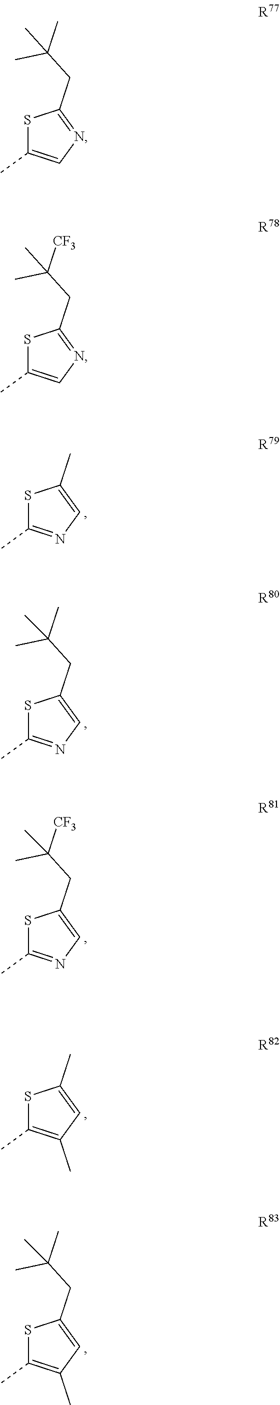

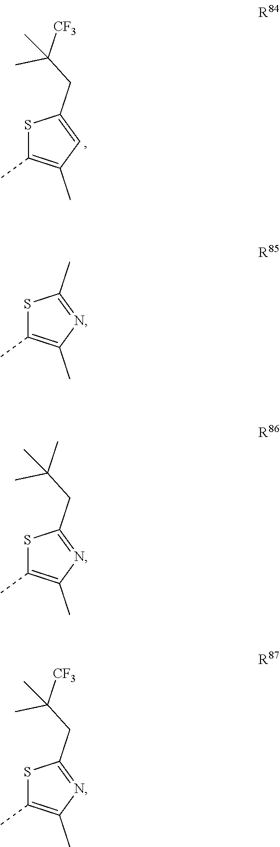

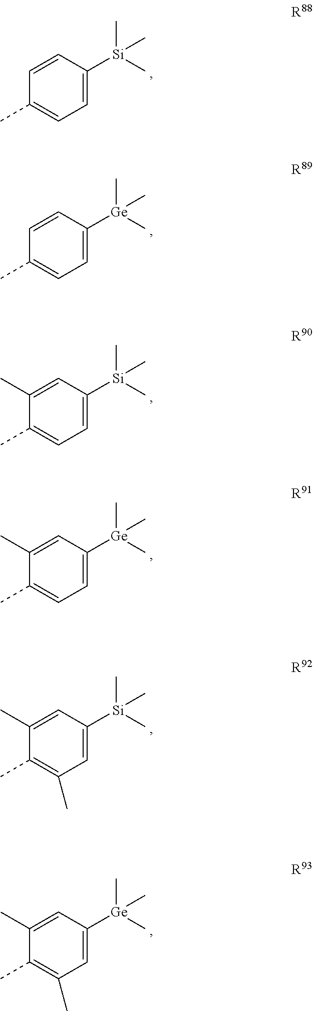

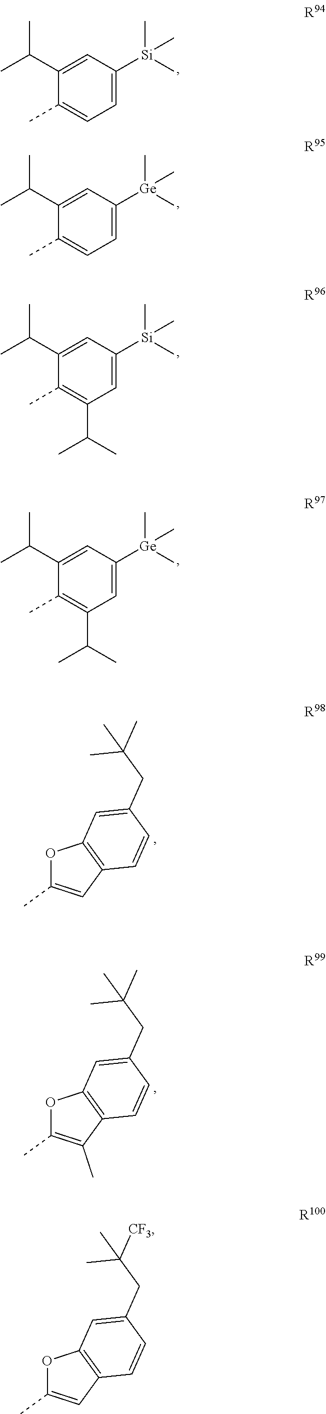

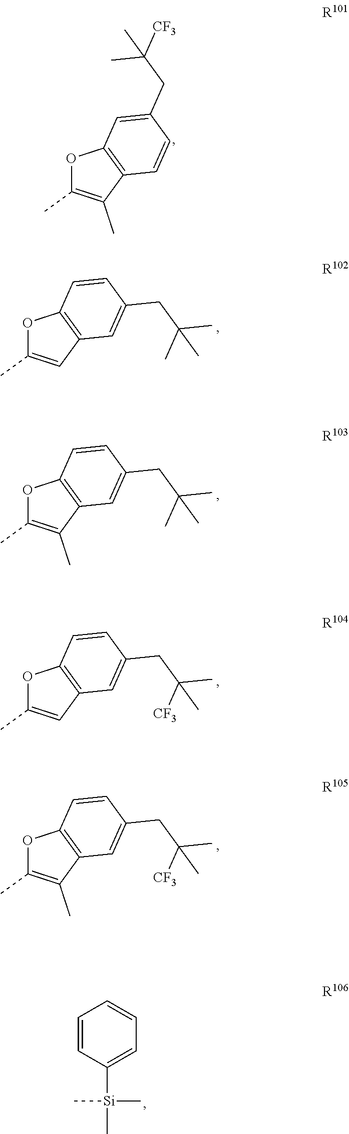

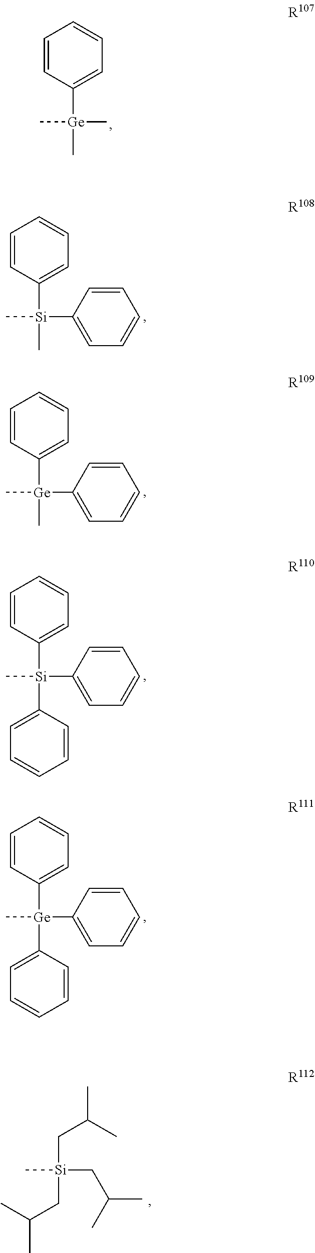

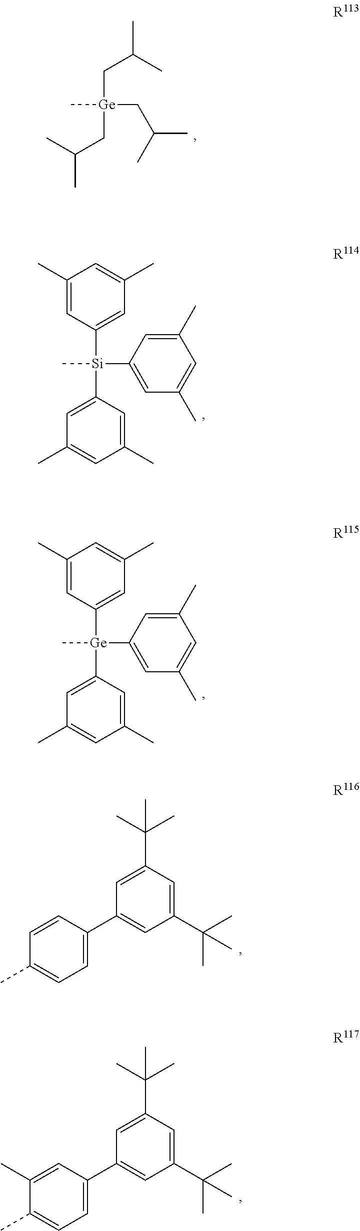

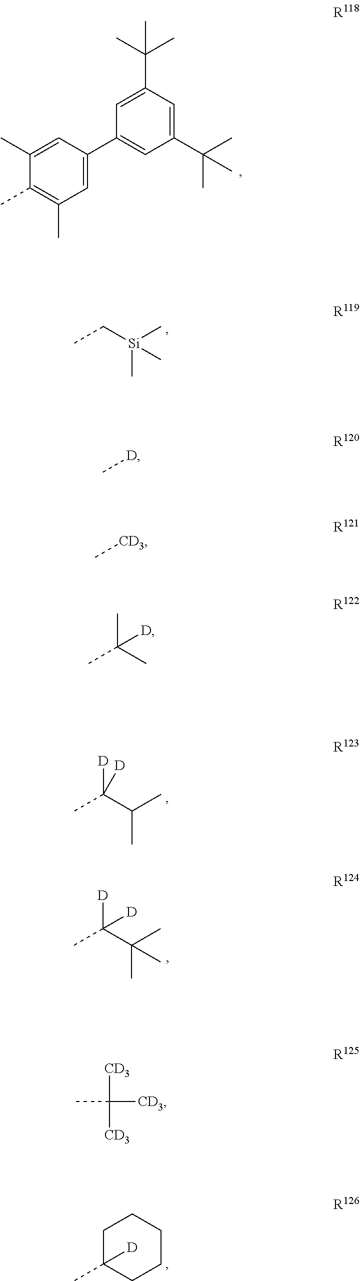

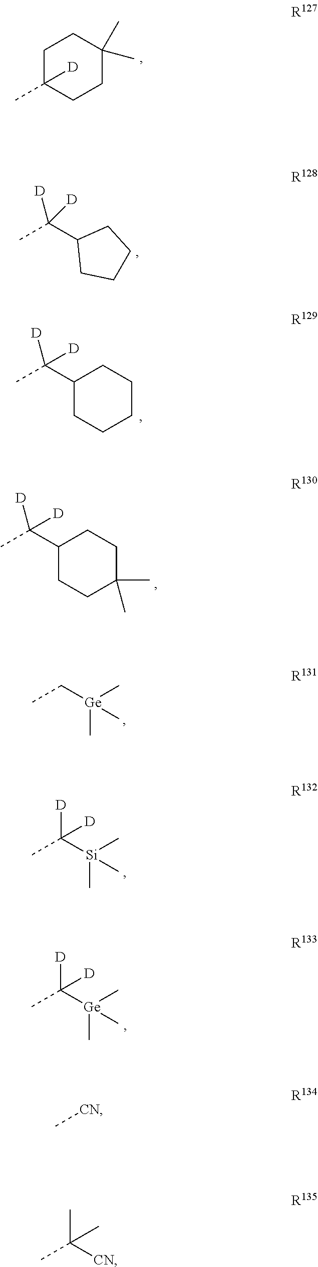

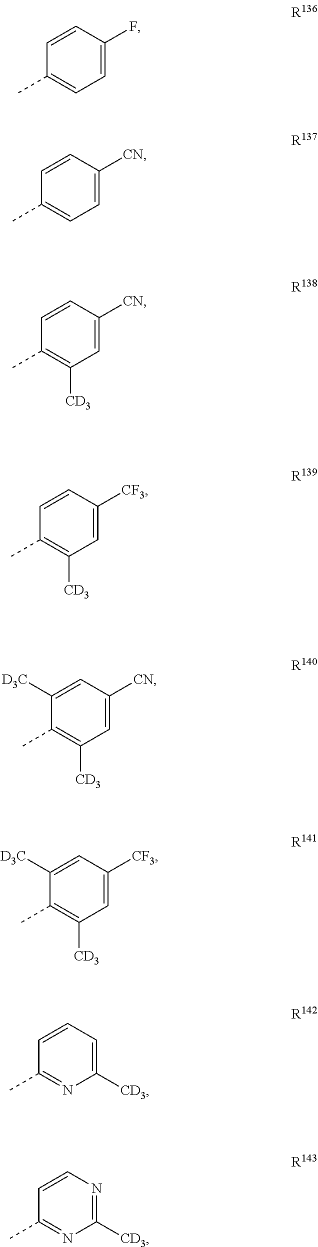

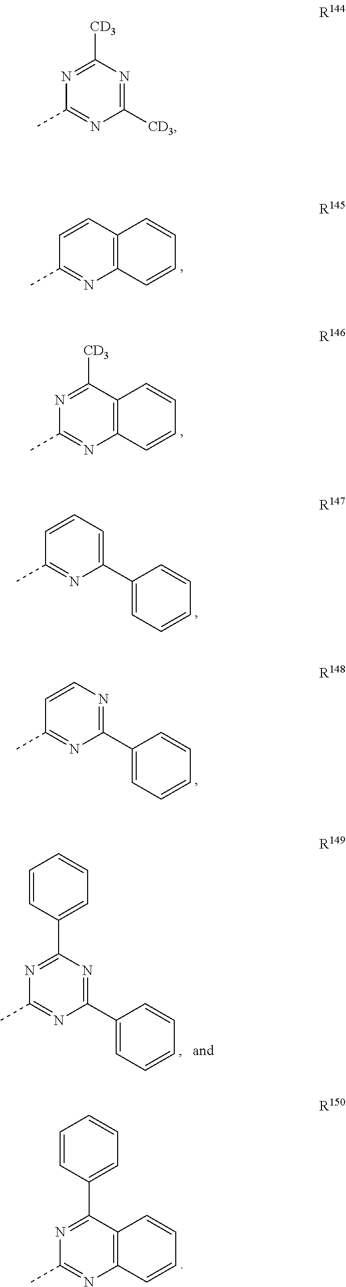

9. The compound of claim 1, wherein the compound has a formula of M(L_{A})ₚ(L_{B})_{q}(L_{C})ᵣ wherein L_{B} and L_{C} are each a bidentate ligand; and wherein p is 1, 2, or 3; q is 0, 1, or 2; r is 0, 1, or 2; and p+q+r is the oxidation state of the metal M.

10. The compound of claim 9, wherein the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other; or a formula of Pt(L_{A})(L_{B}); and wherein L_{A} and L_{B} can be same or different.

11. The compound of claim 9, wherein L_{B} and L_{C} are each independently selected from the group consisting of: 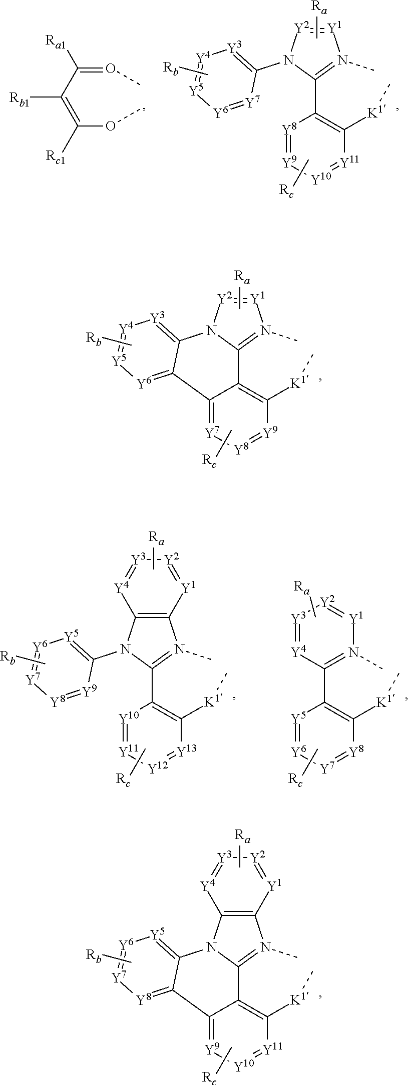 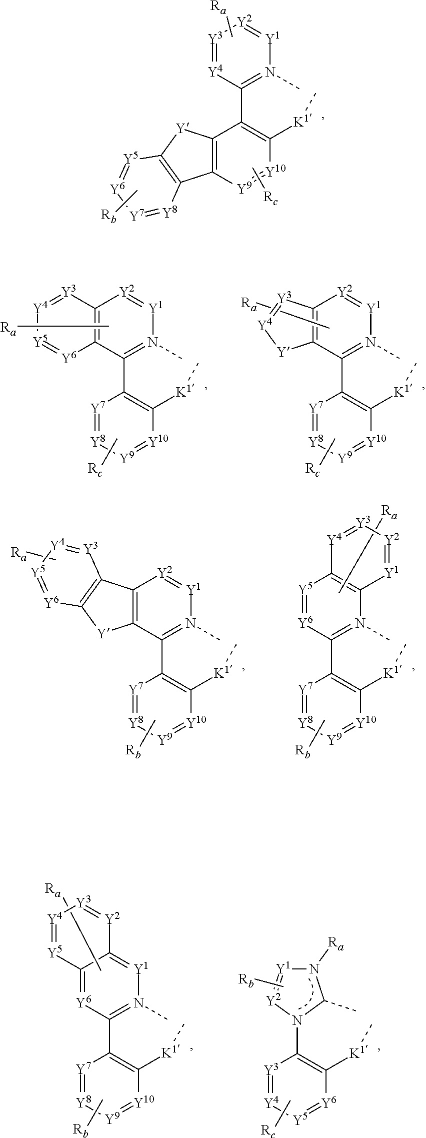 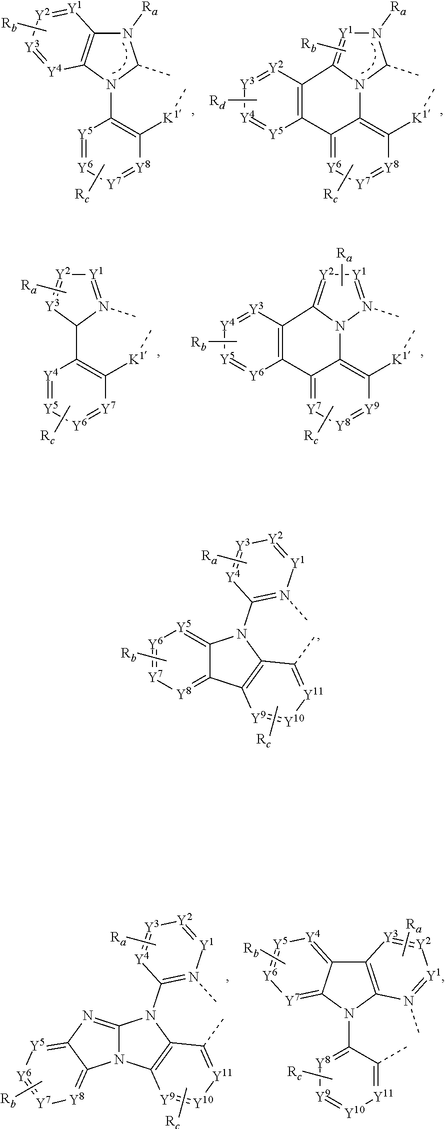 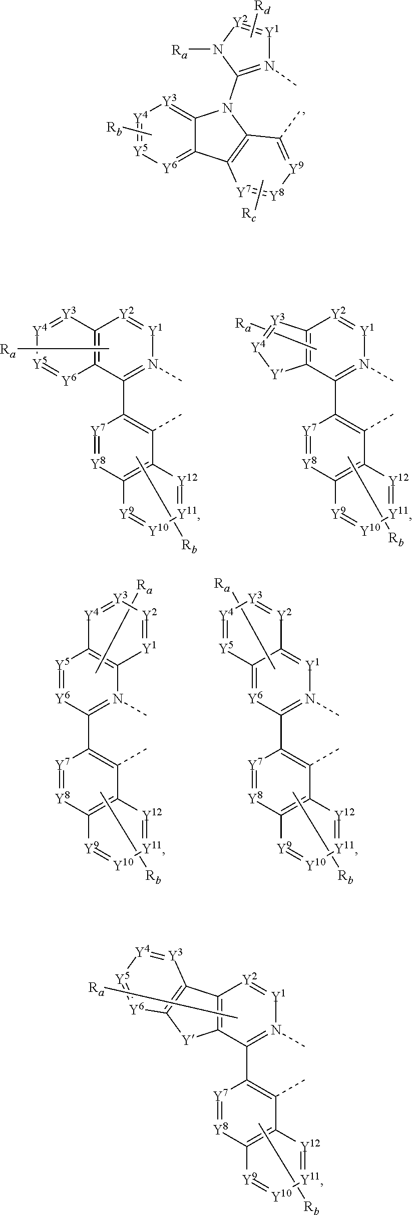 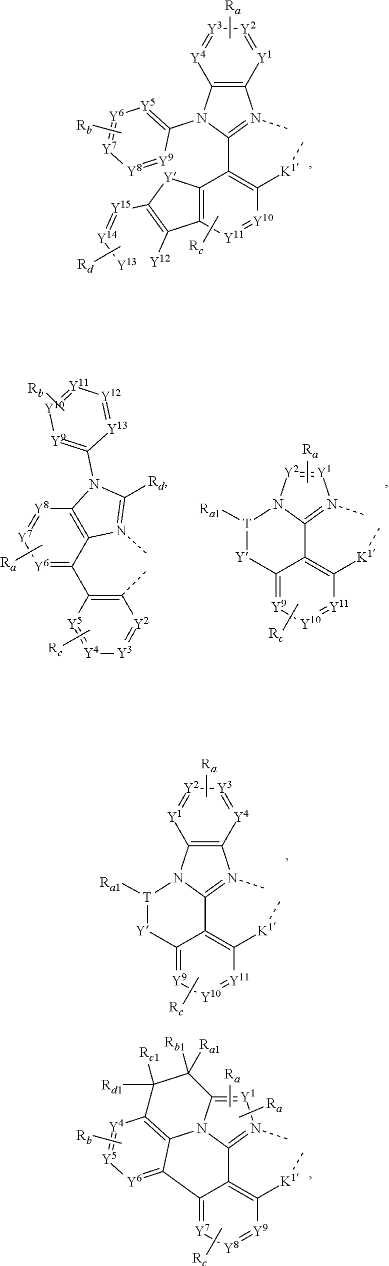 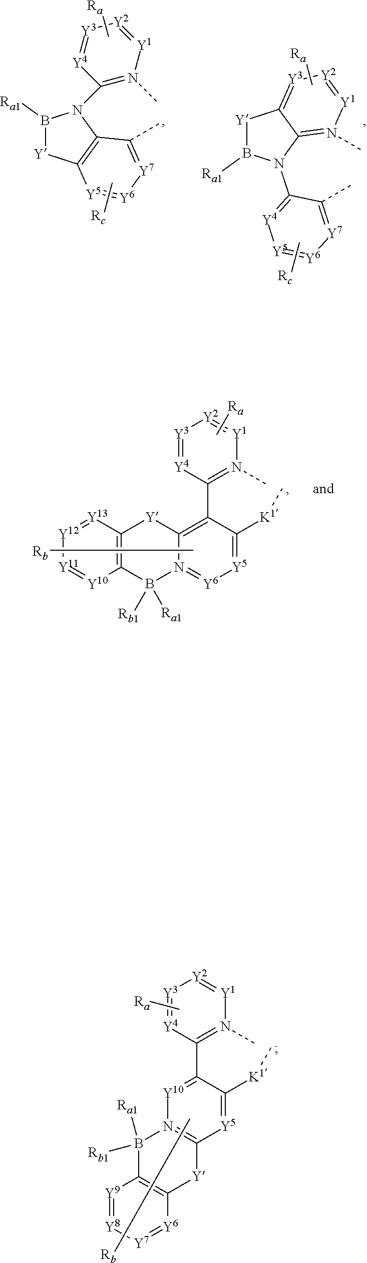
wherein:
T is selected from the group consisting of B, Al, Ga, and In;
K^{1′} is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C—O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

12. The compound of claim 9, wherein the compound has formula Ir(L_{A})₃, formula Ir(L_{A})(L_{Bk})₂, formula Ir(L_{A})₂(L_{Bk}), formula Ir(L_{A})₂(L_{Cj-I}), or Ir(L_{A})₂(L_{Cj-II}),
wherein L_{A} is according to Formula I;
wherein k is an integer from 1 to 530, and each L_{Bk} has the structure defined as follows: 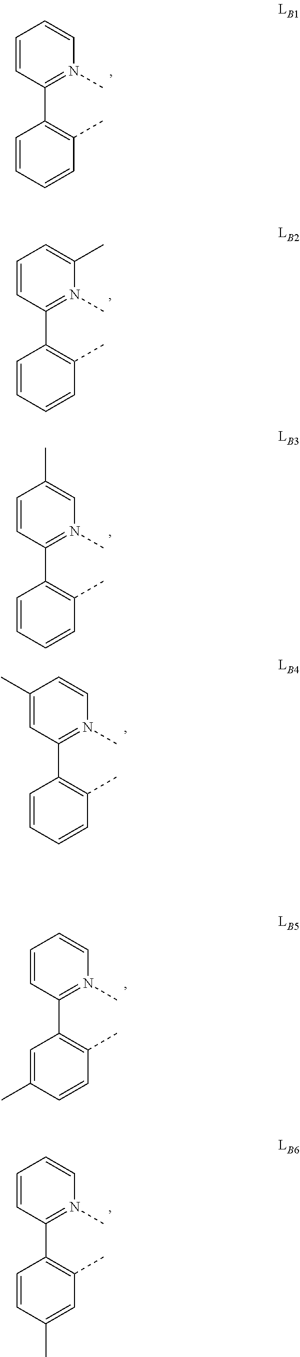 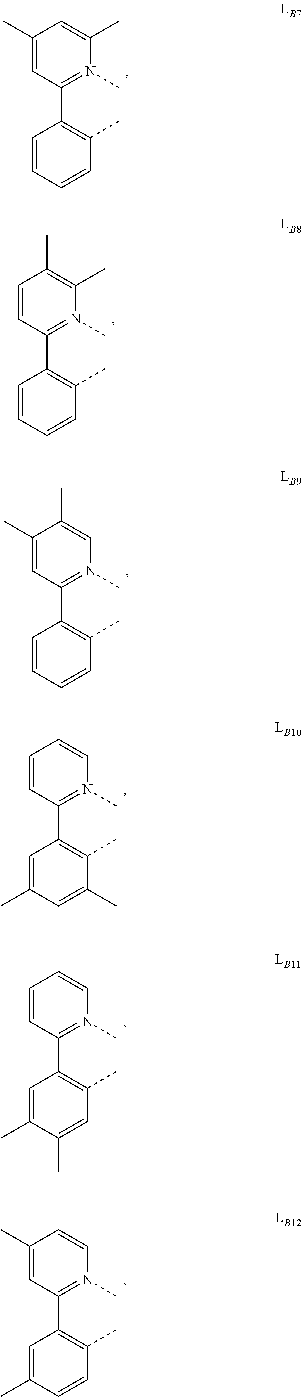 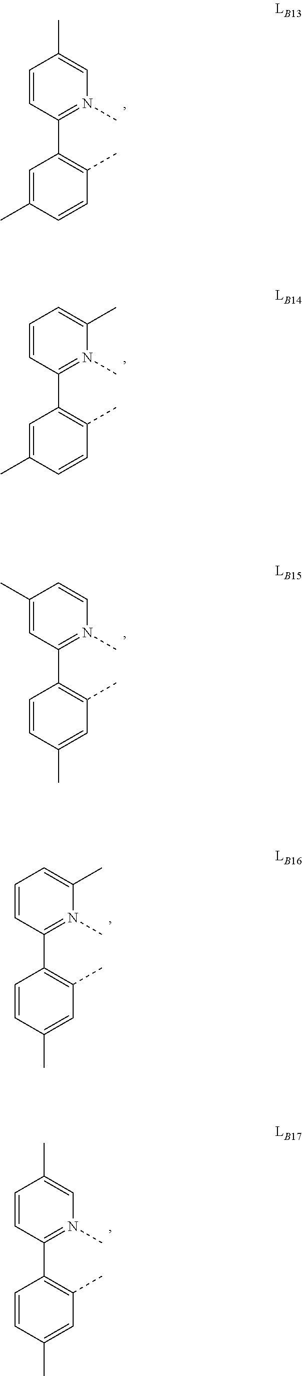 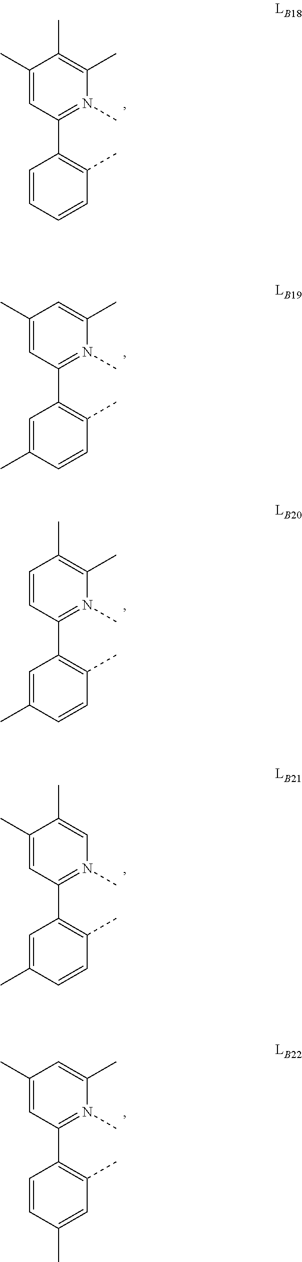 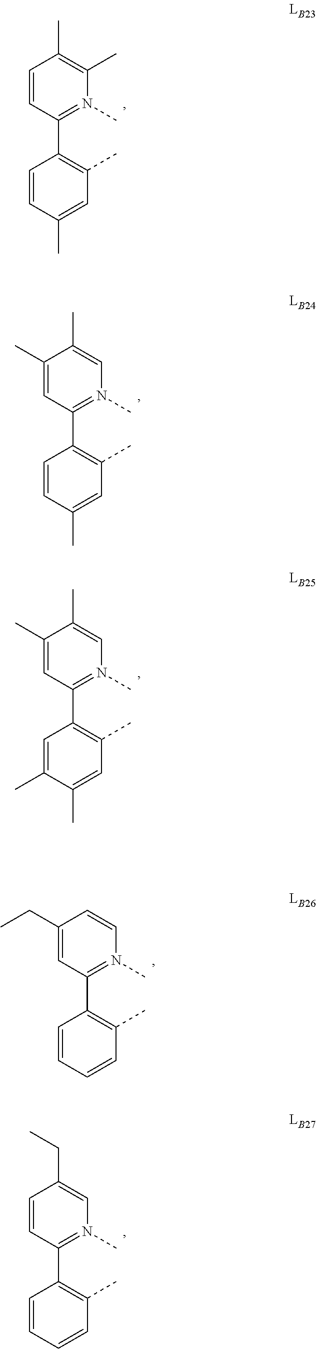 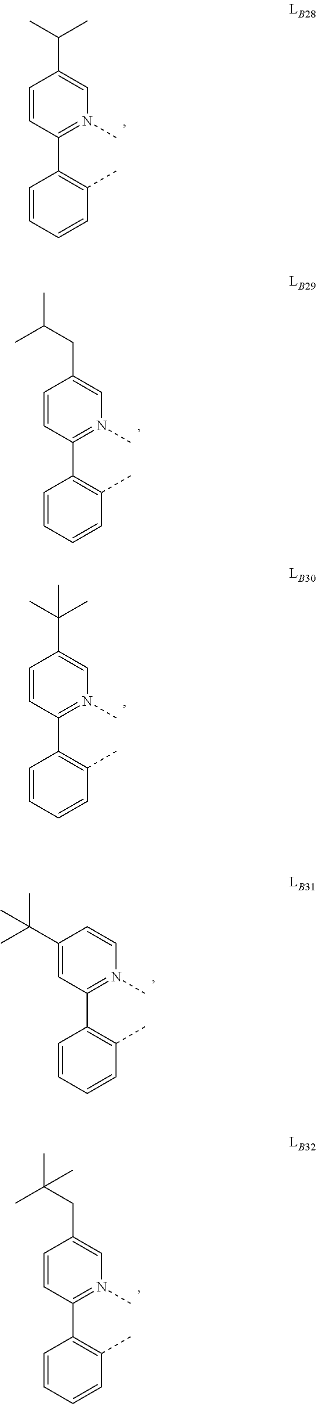 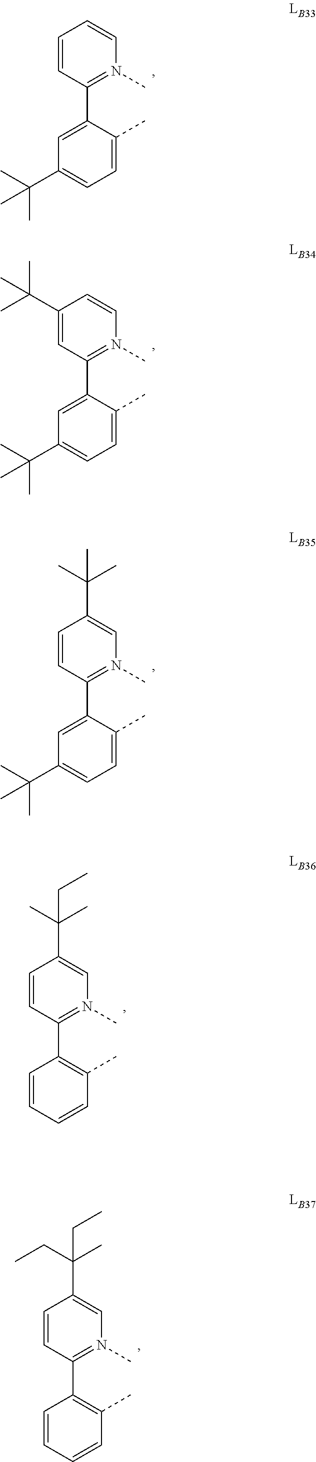 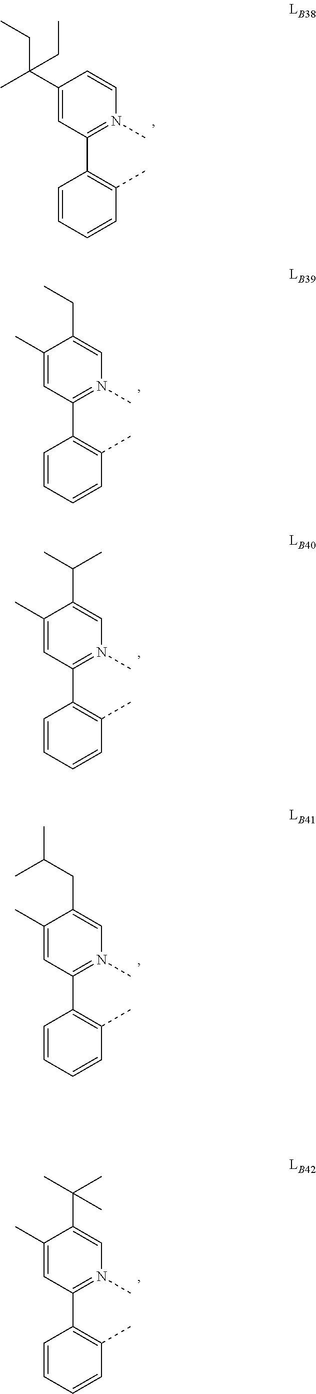 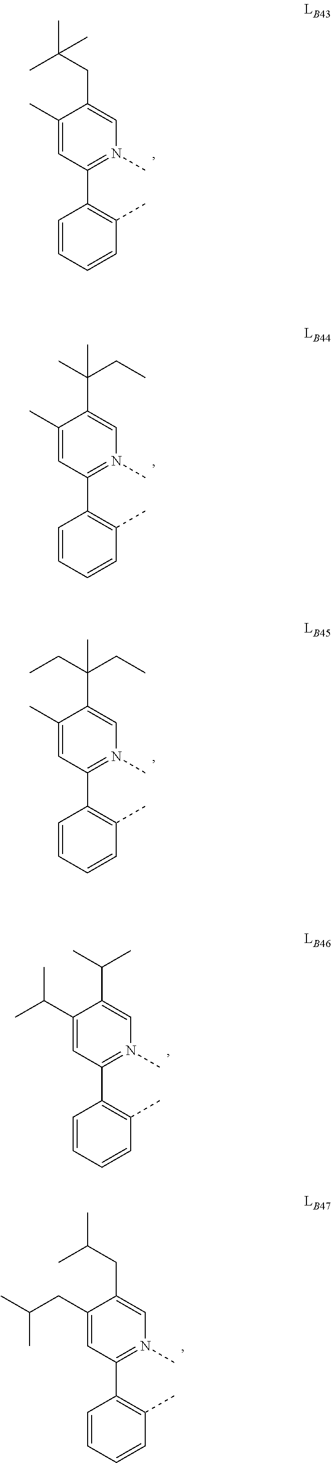 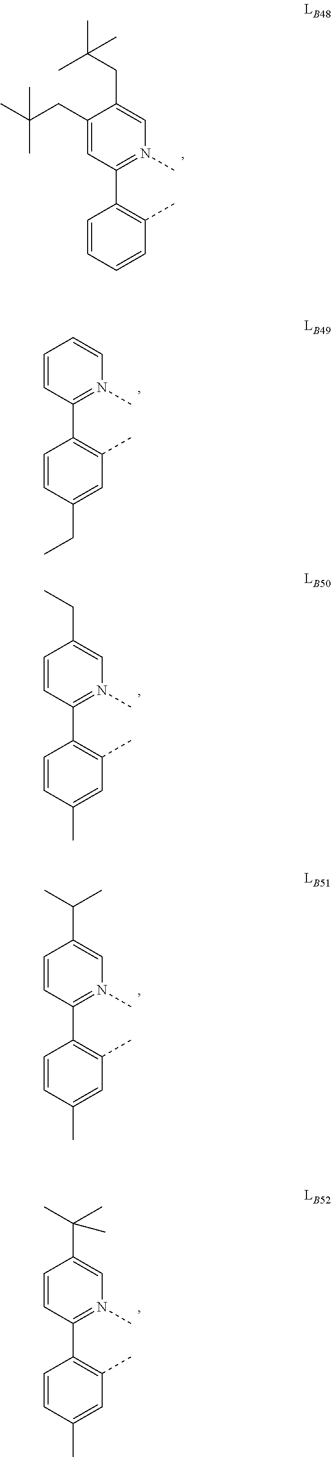 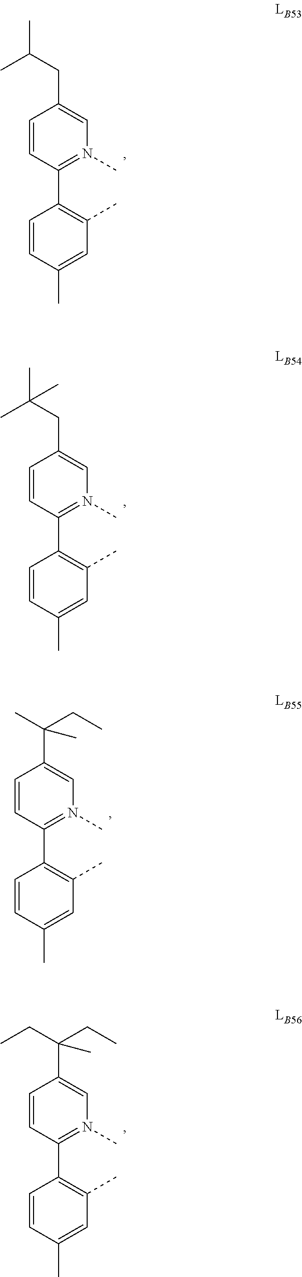 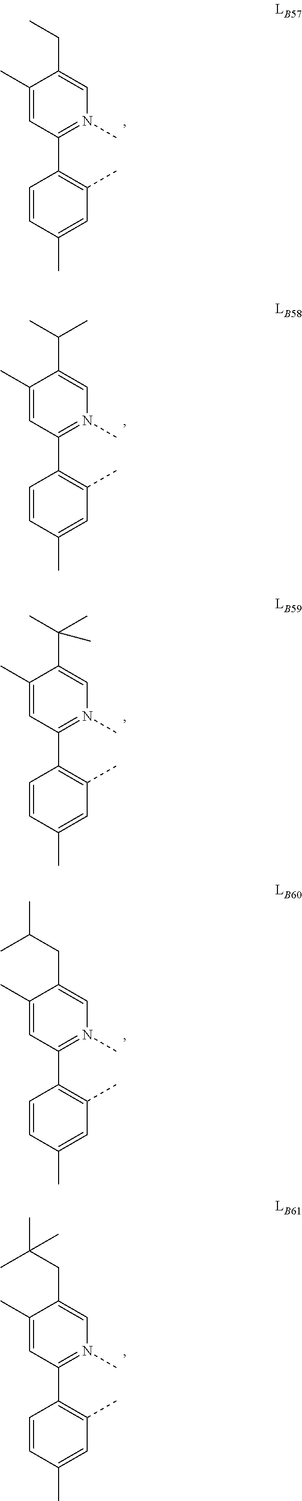 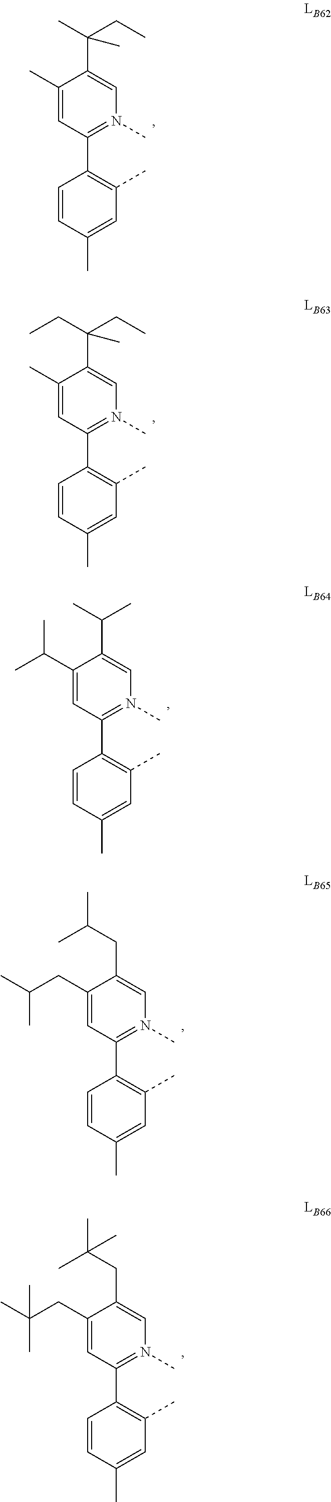 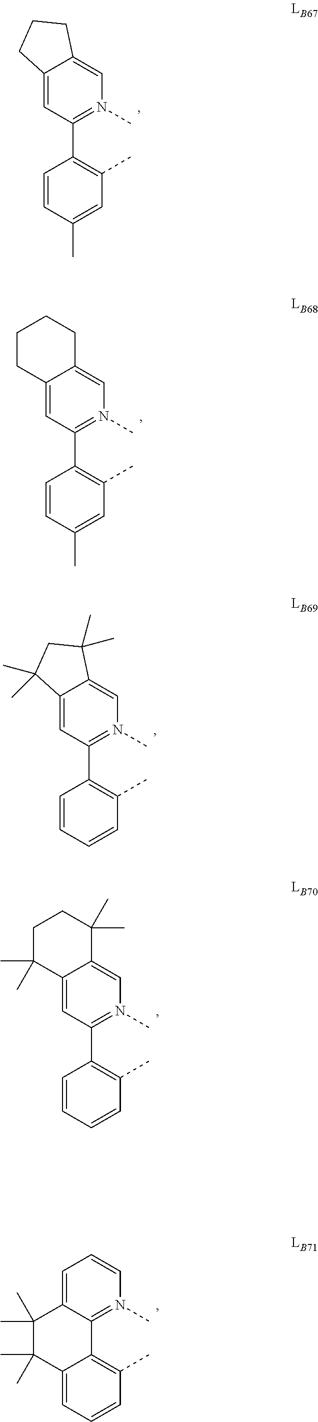 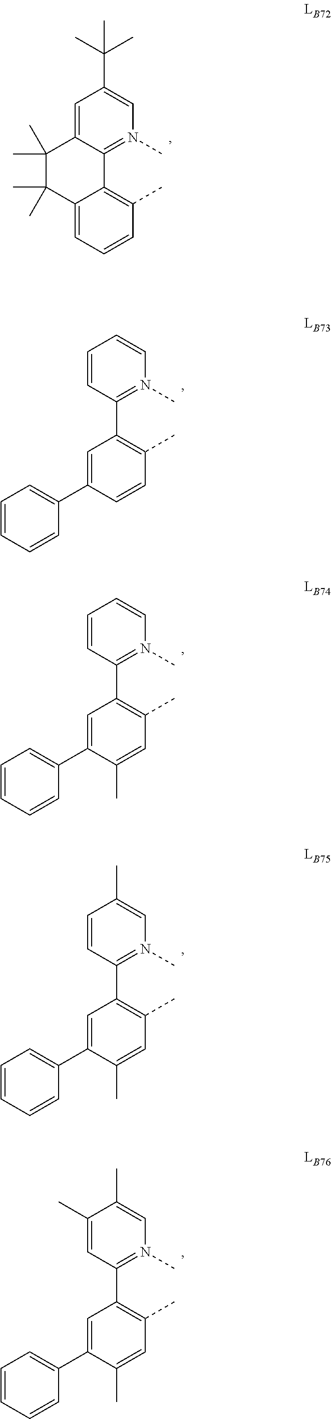 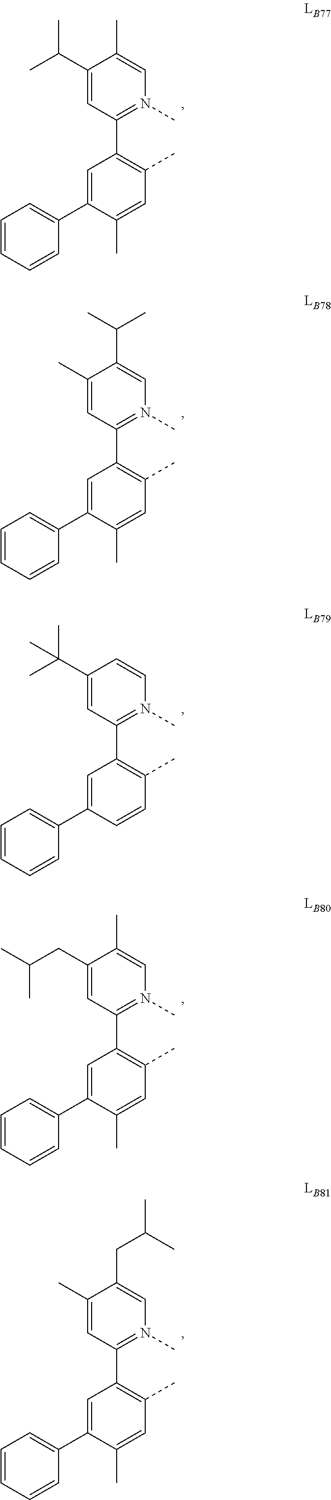 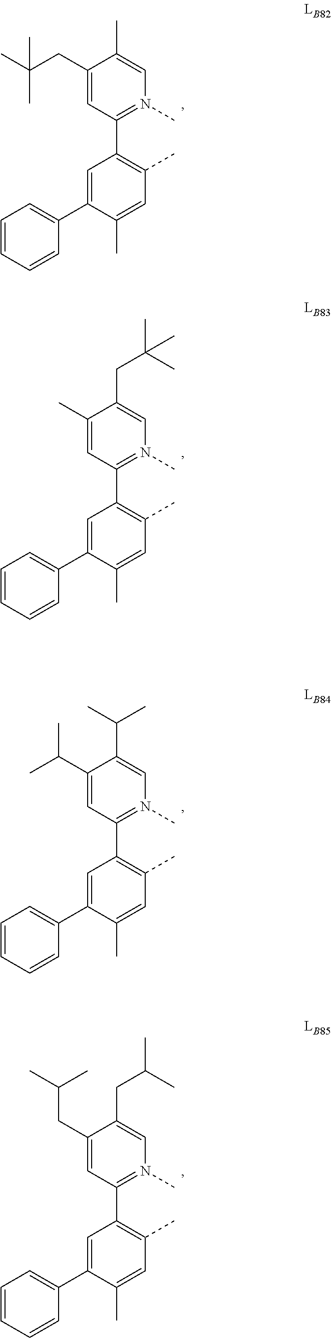 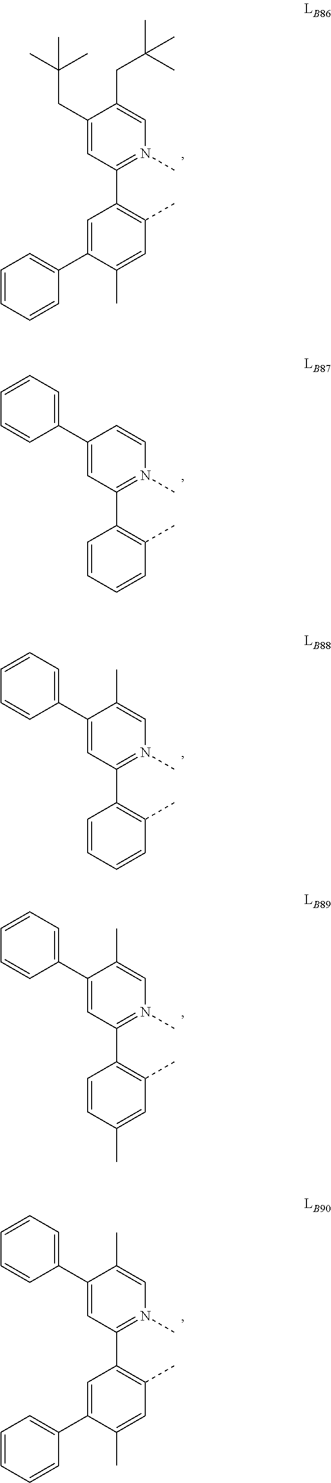 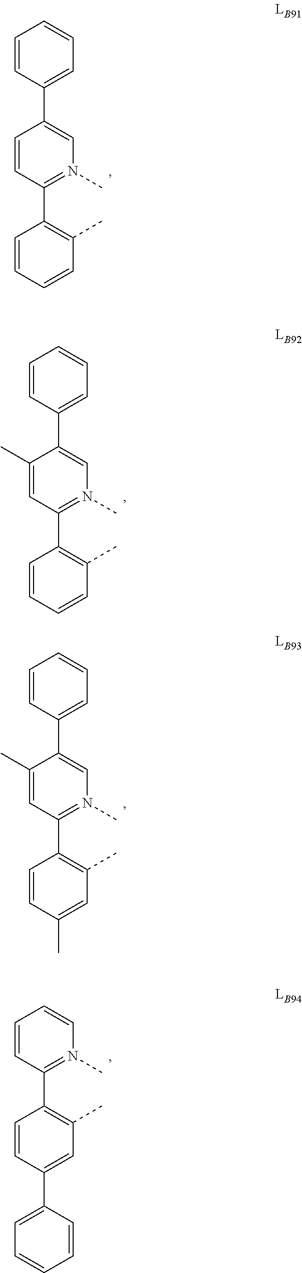 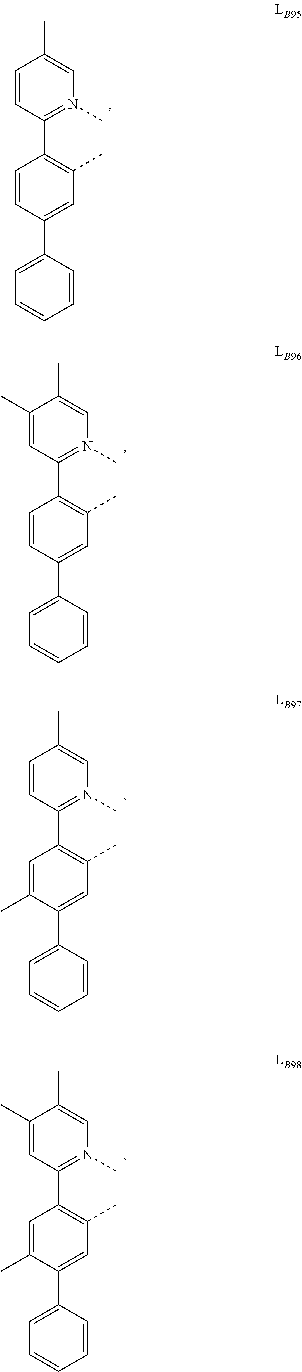 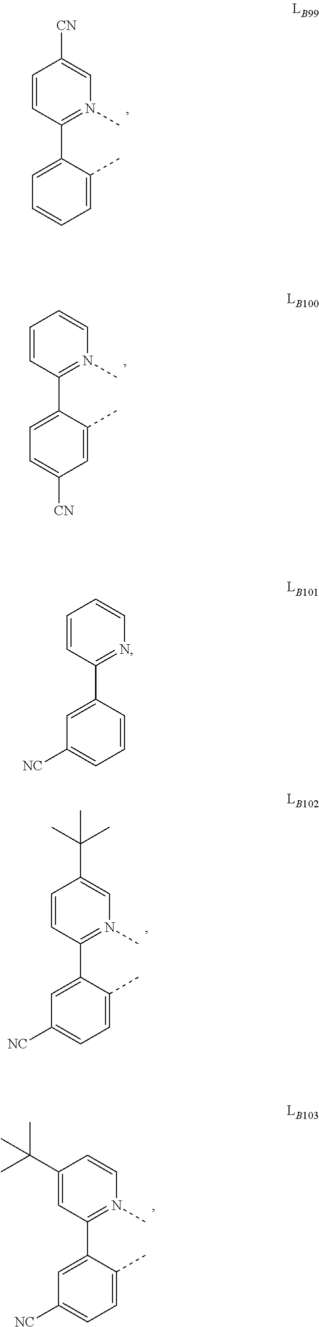 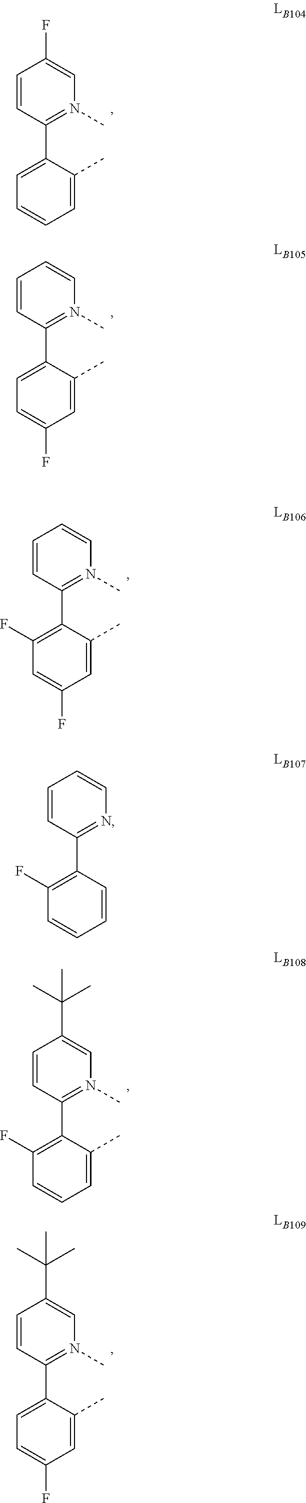 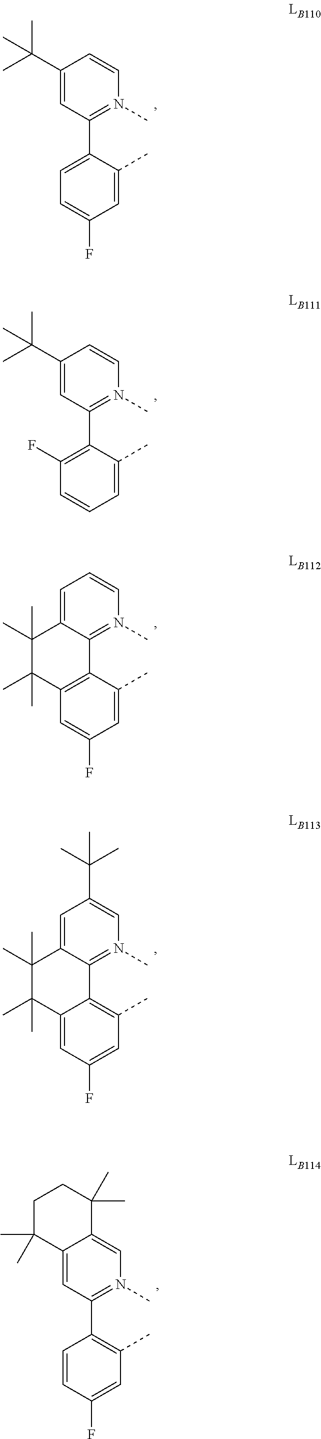 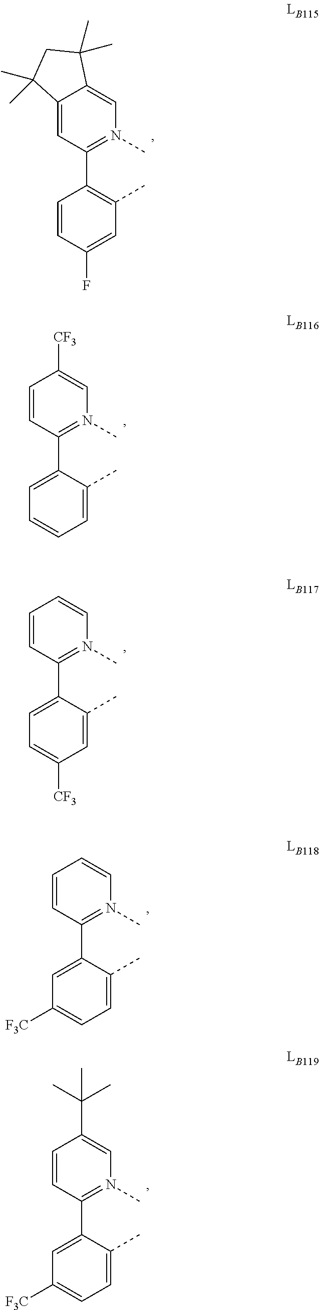 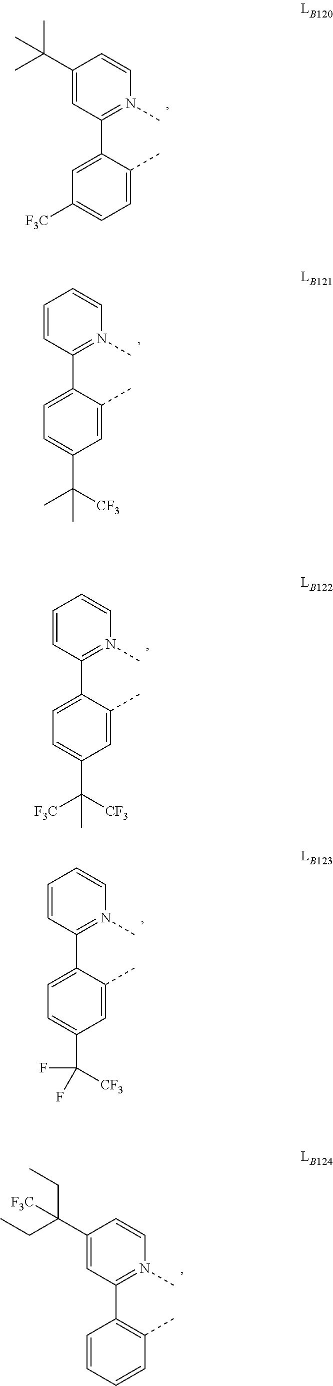 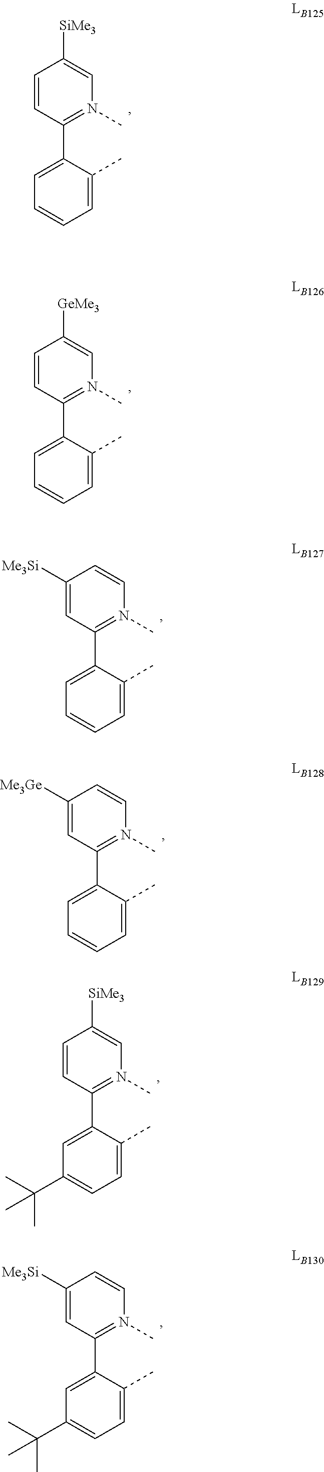 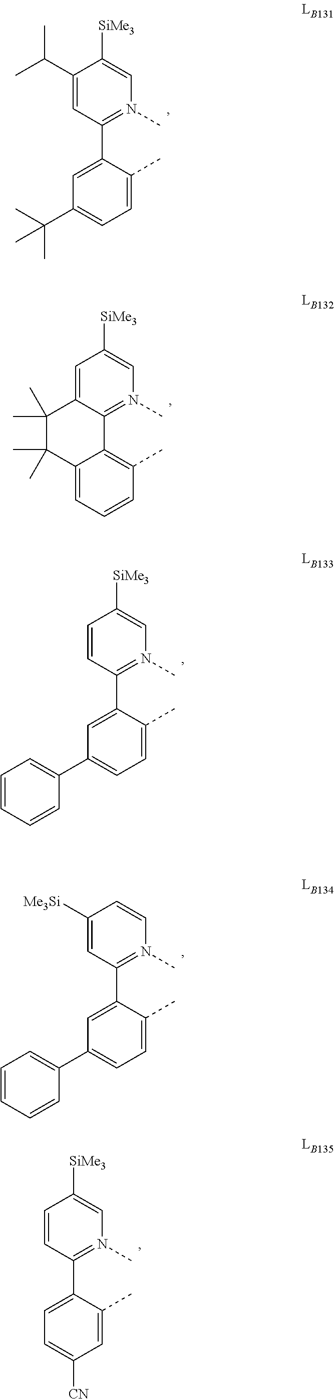 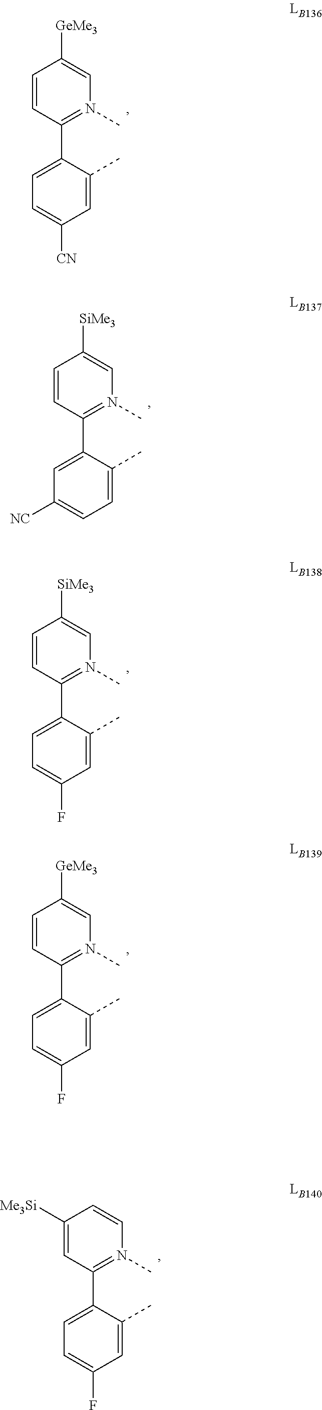 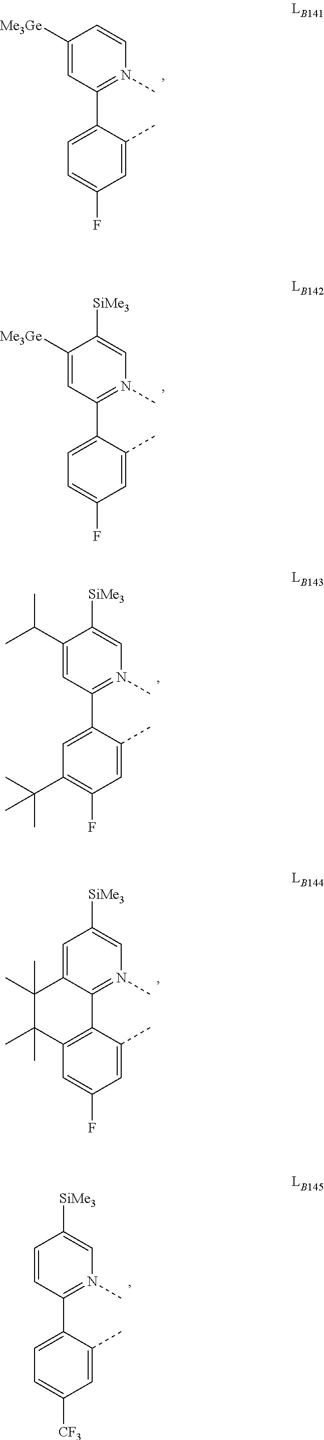 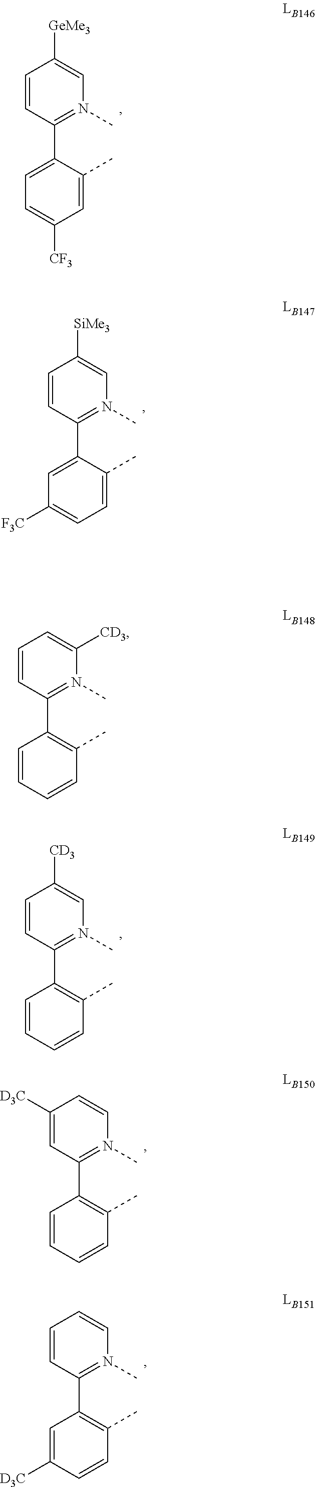 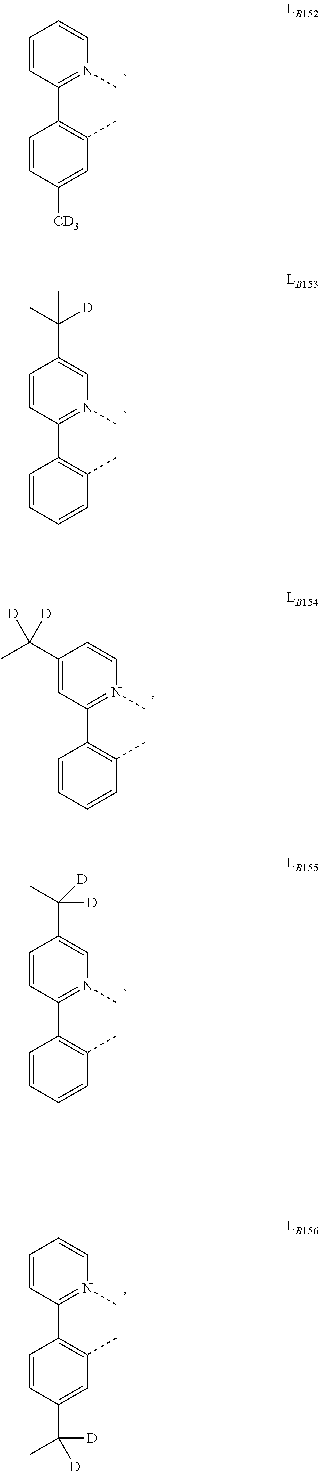 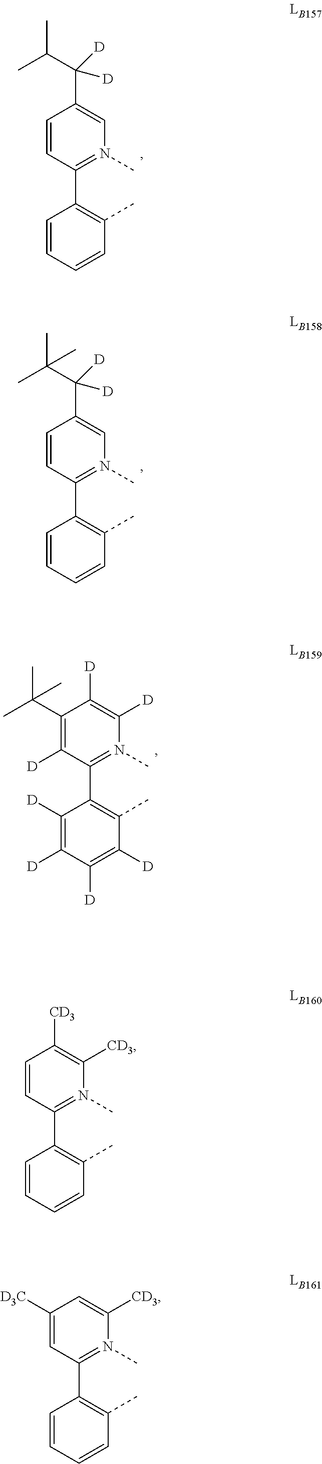 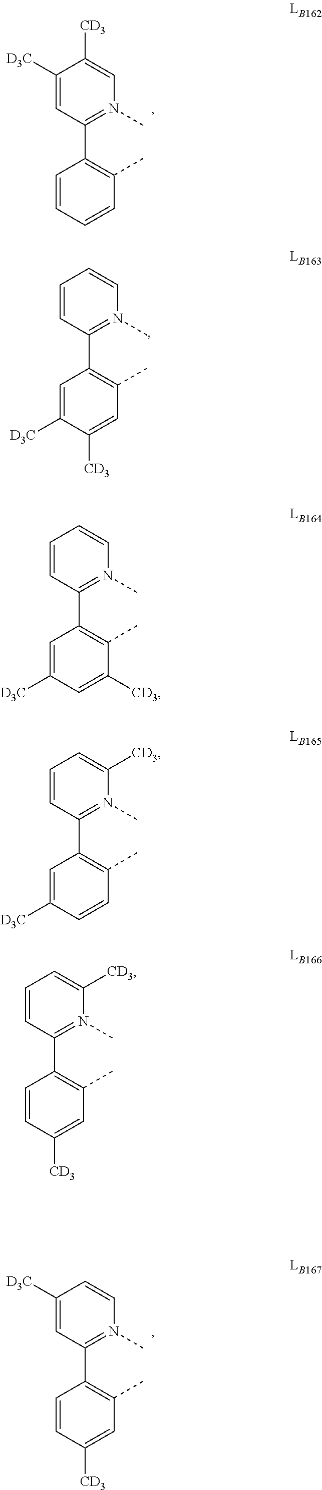 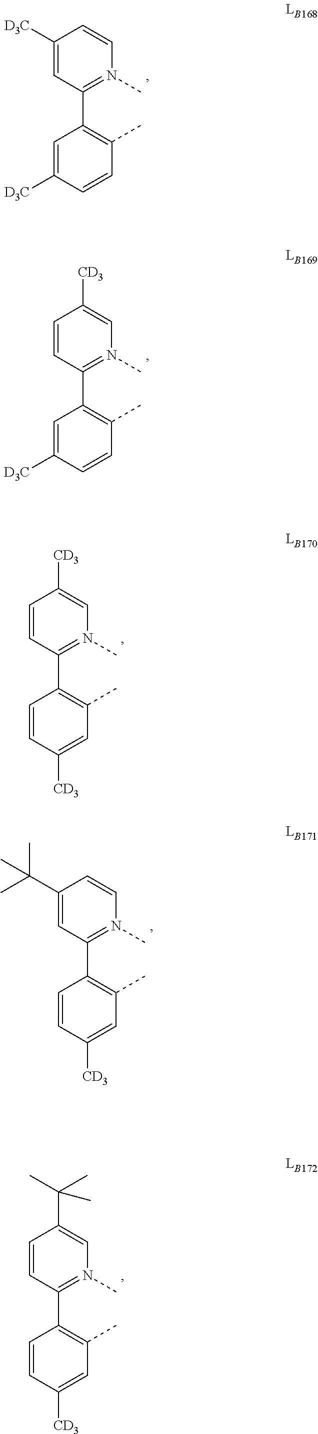 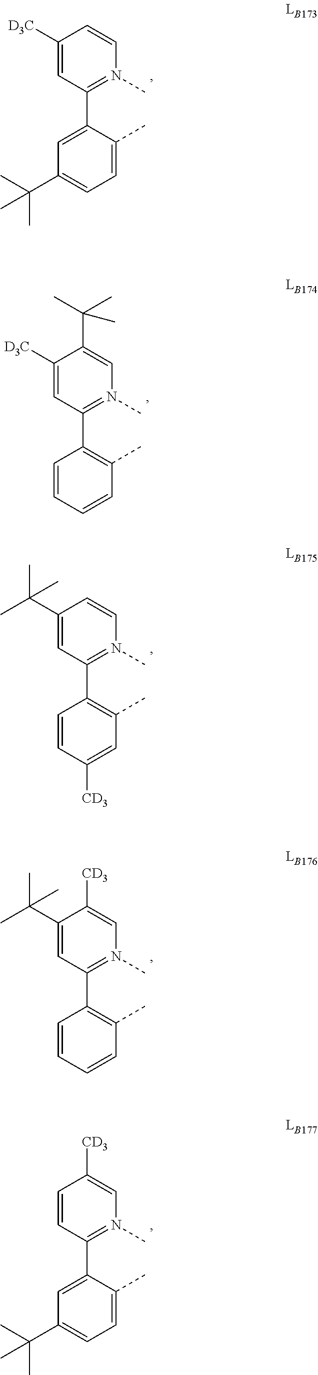 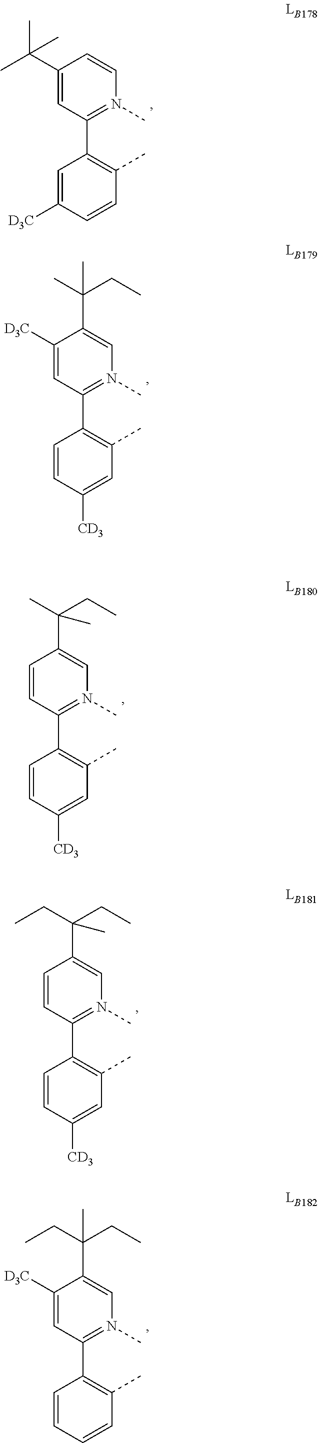 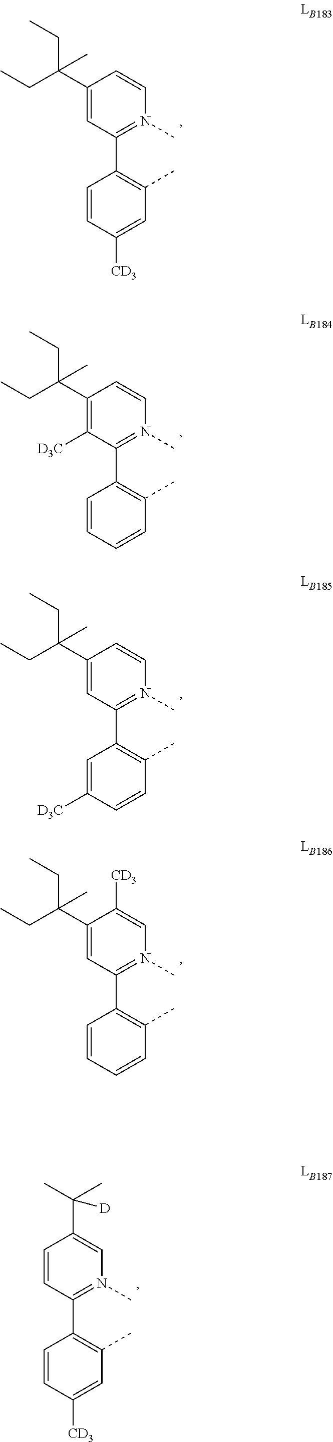 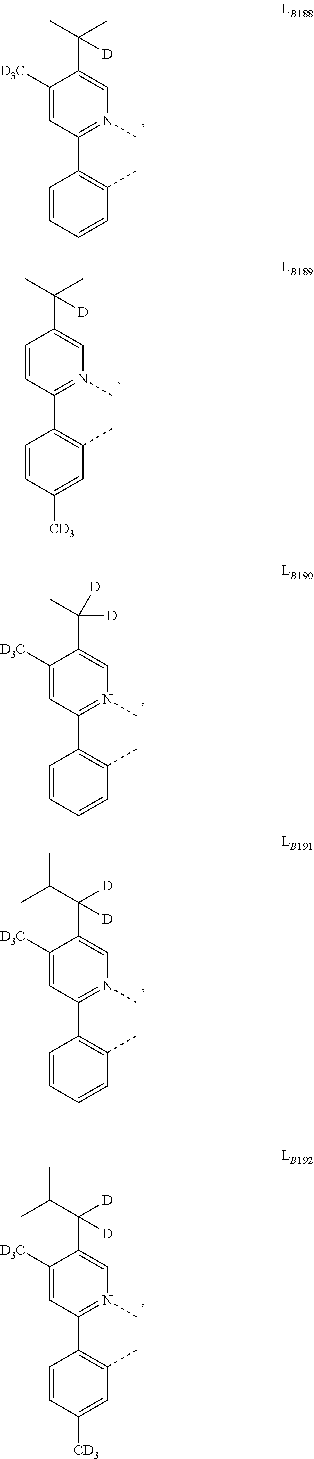 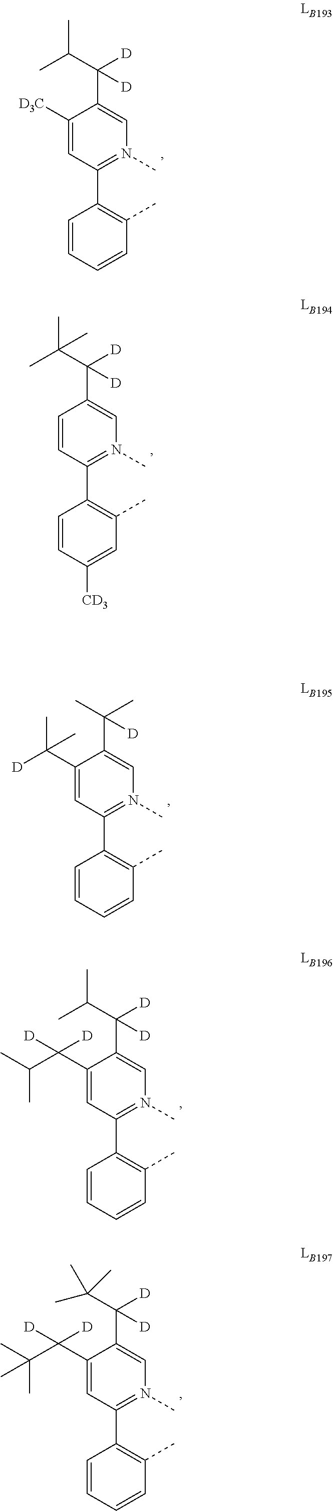 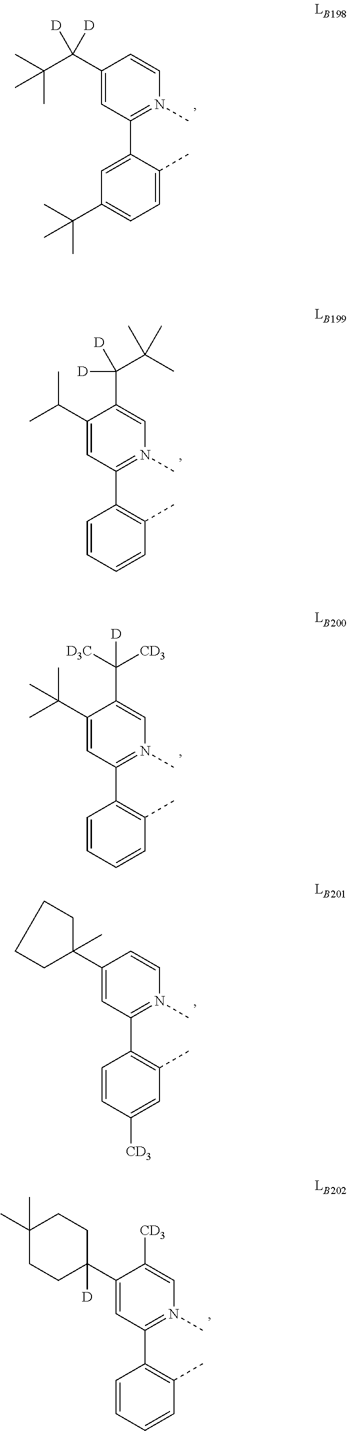 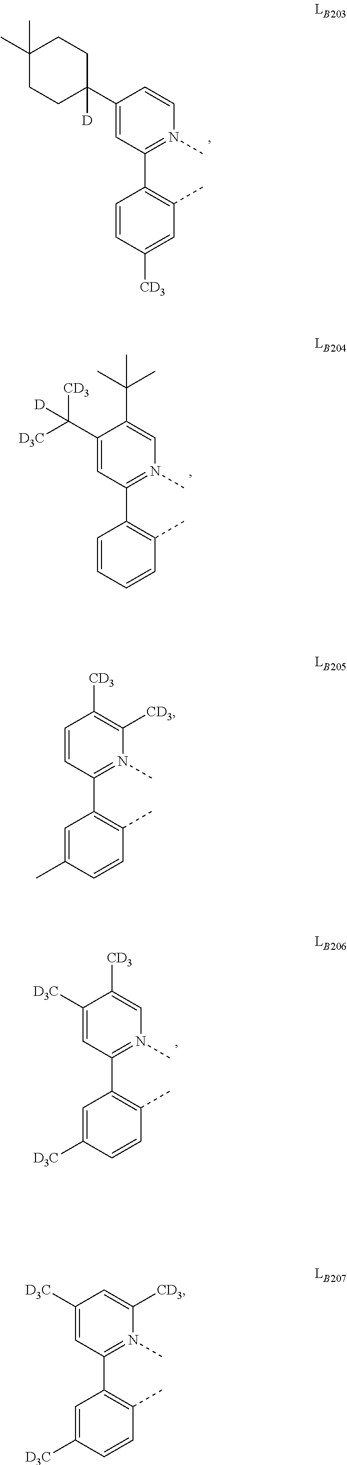 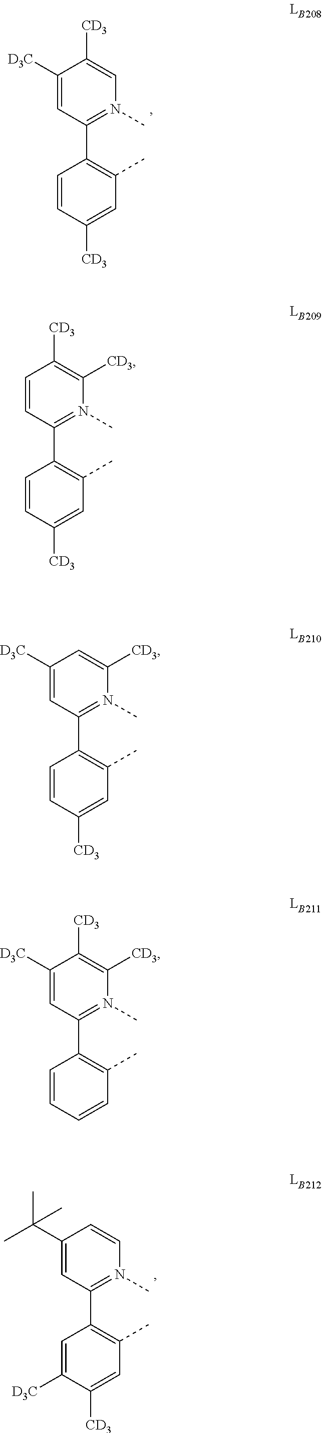 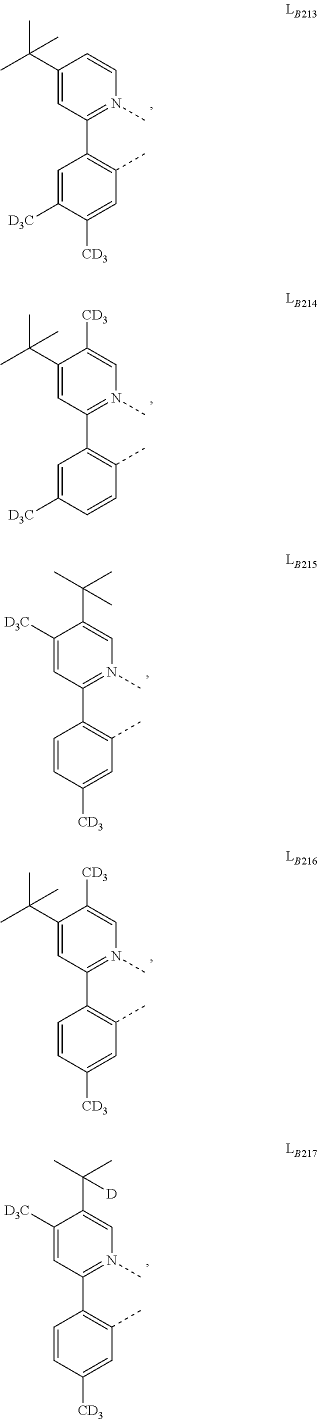 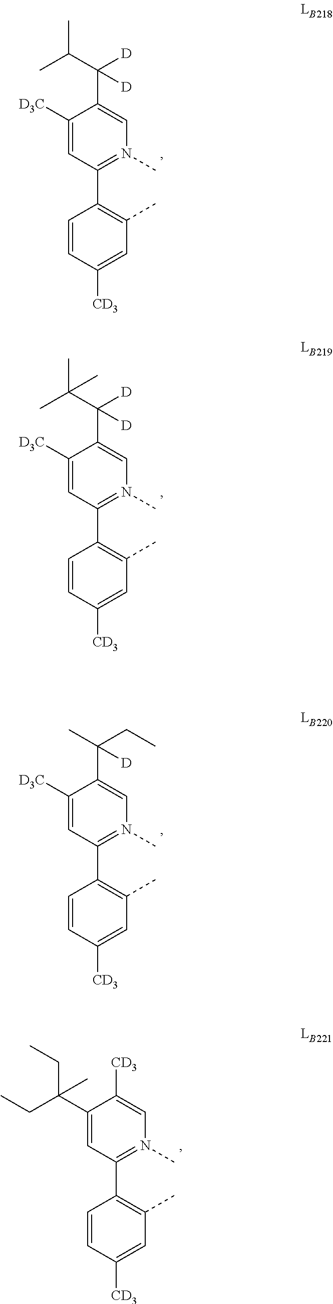 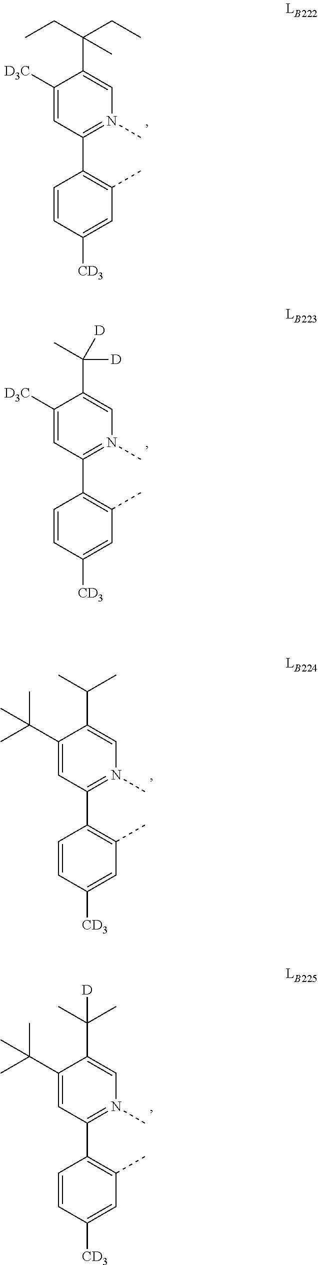 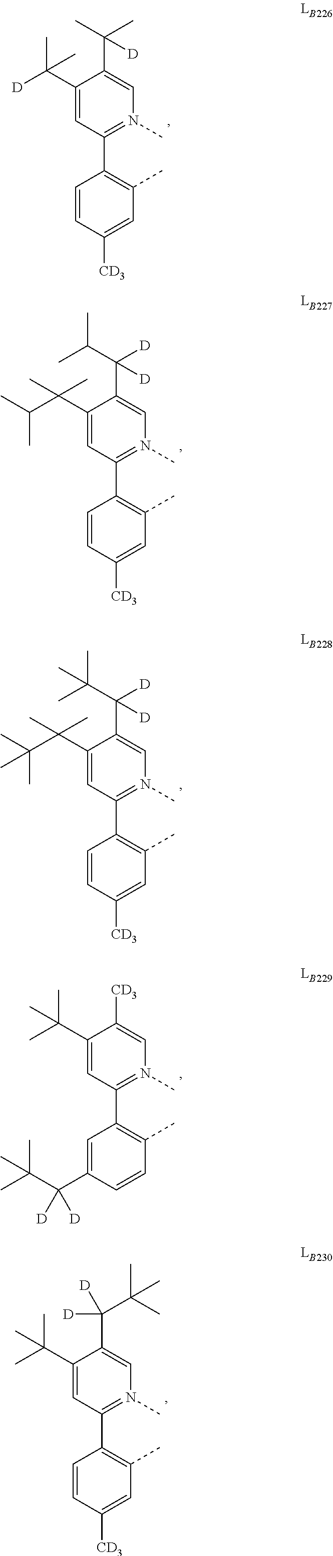 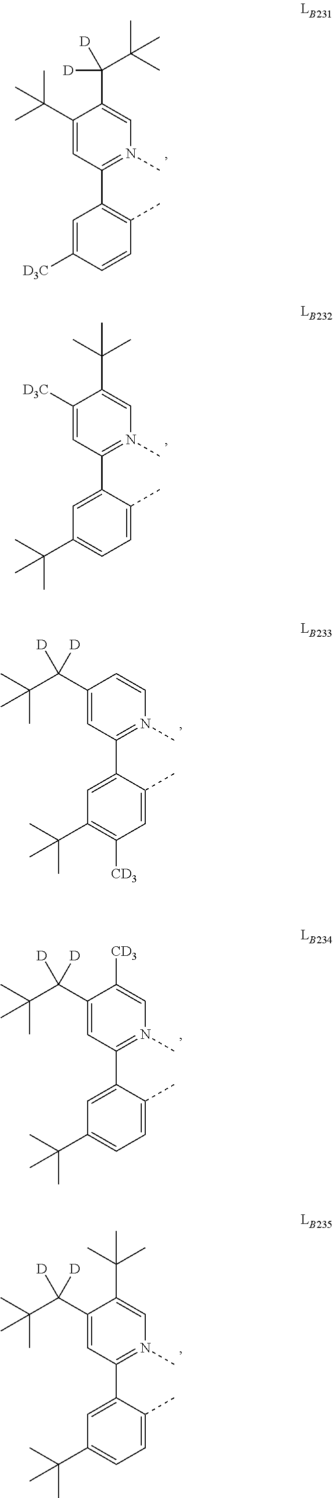 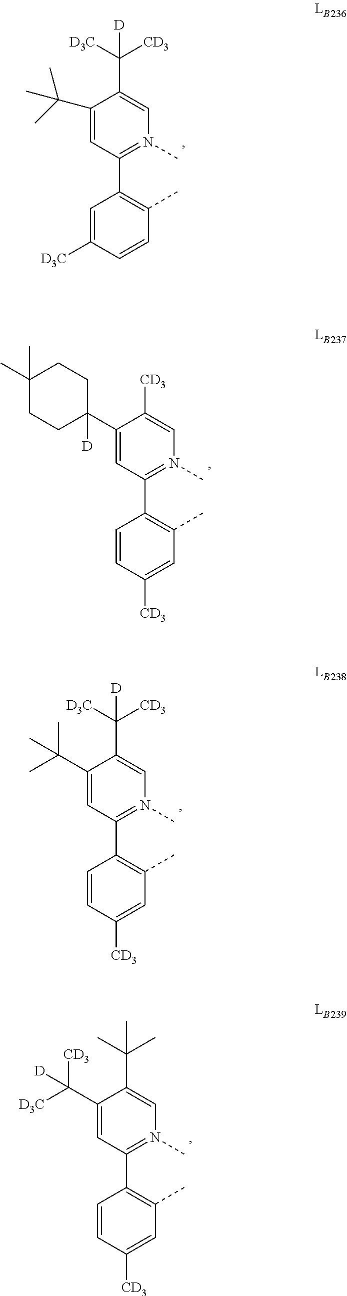 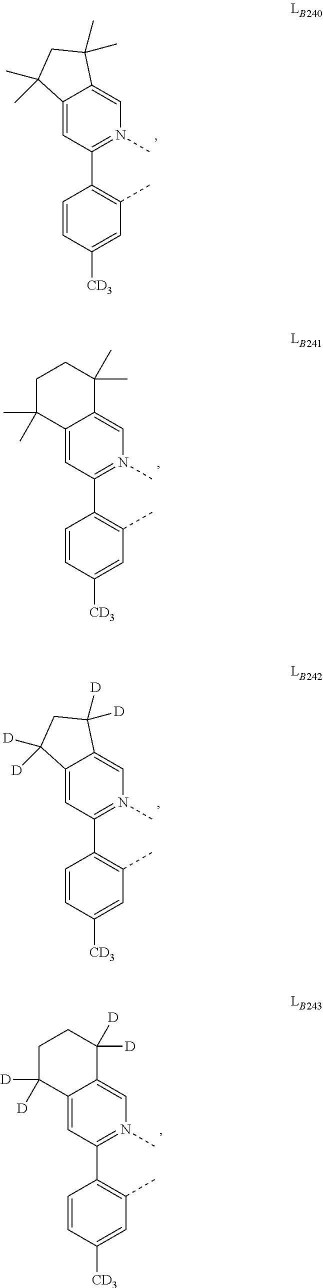 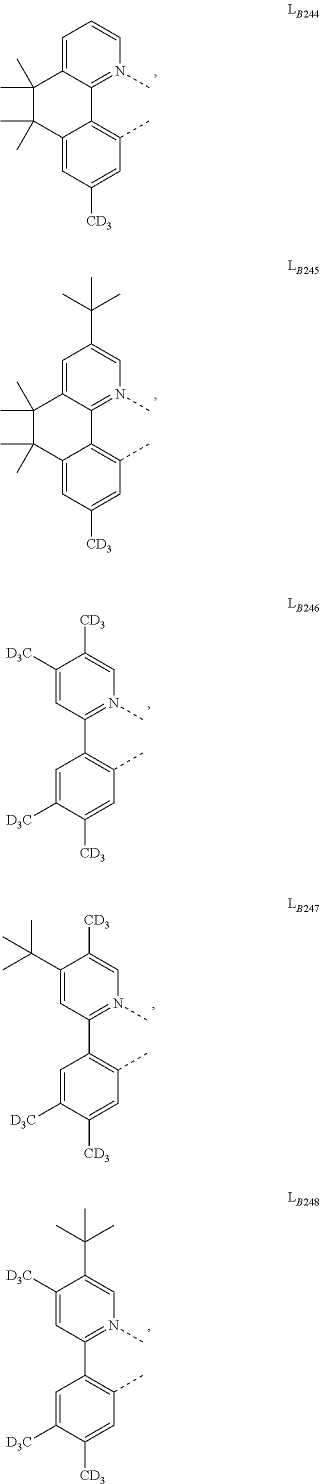 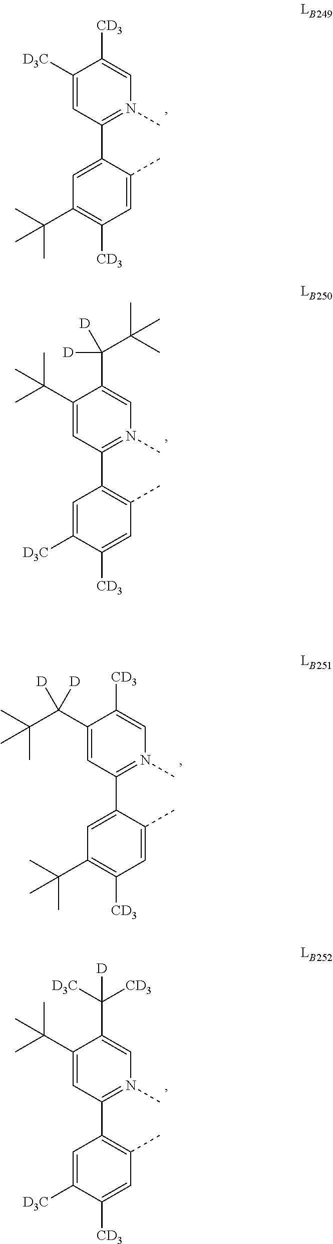 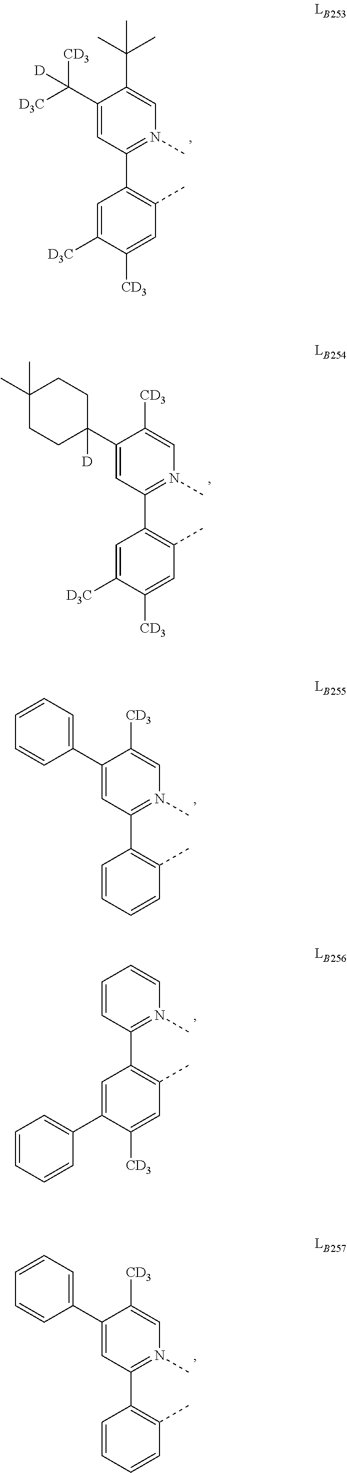 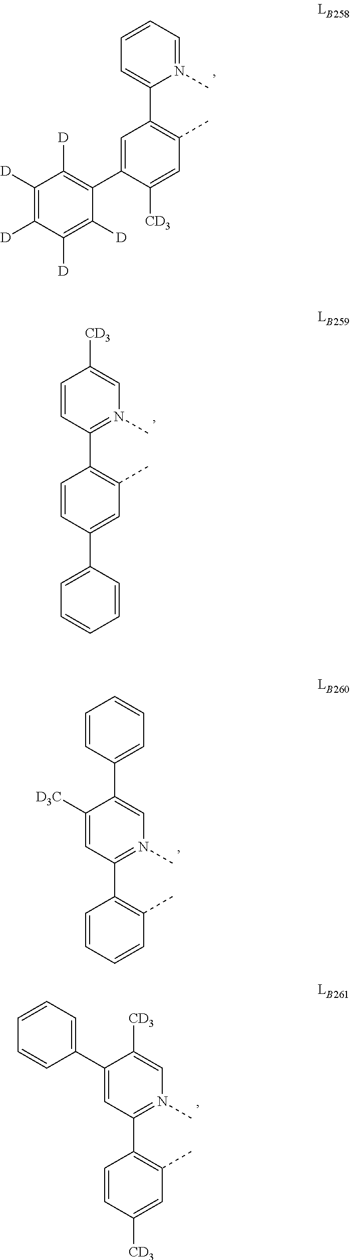 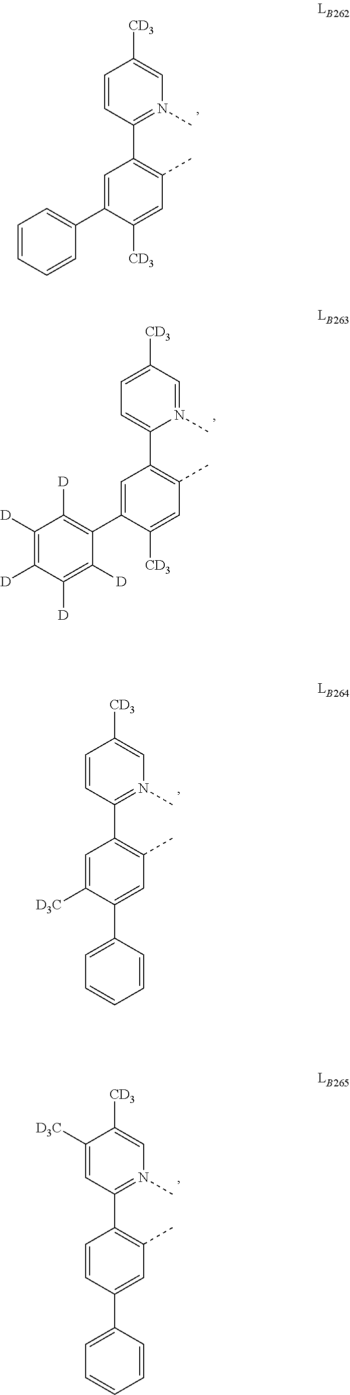 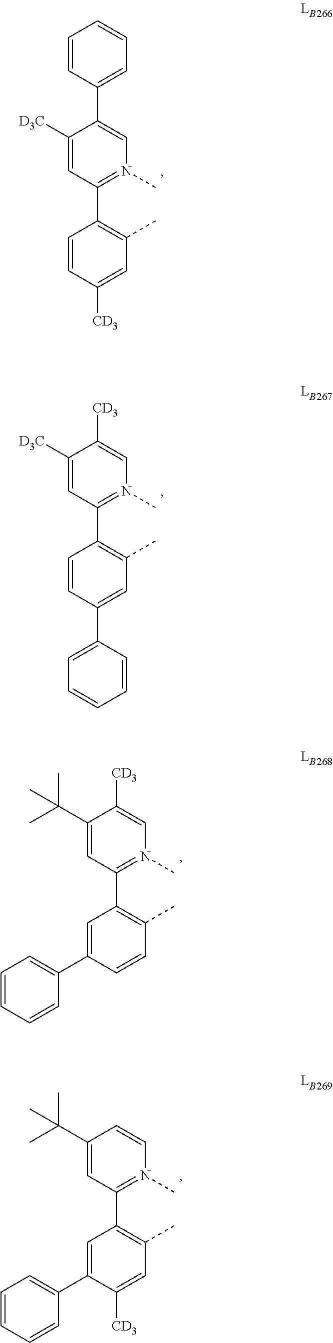 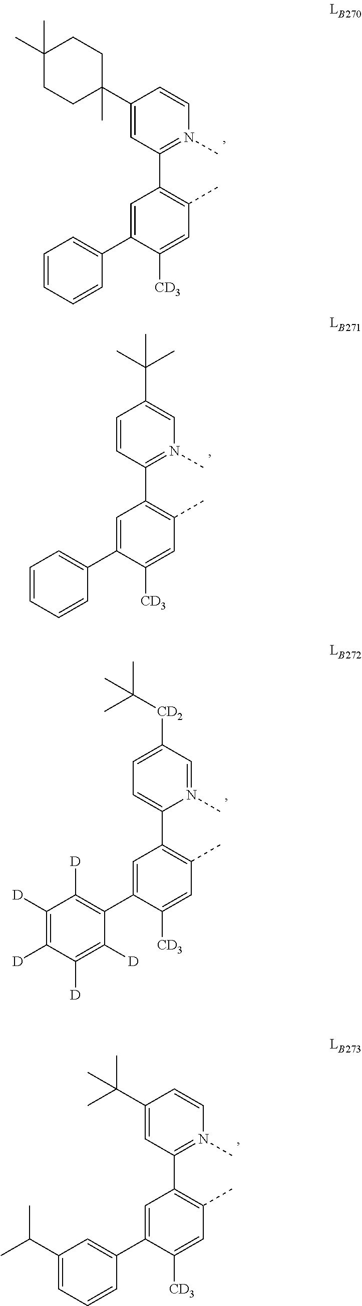 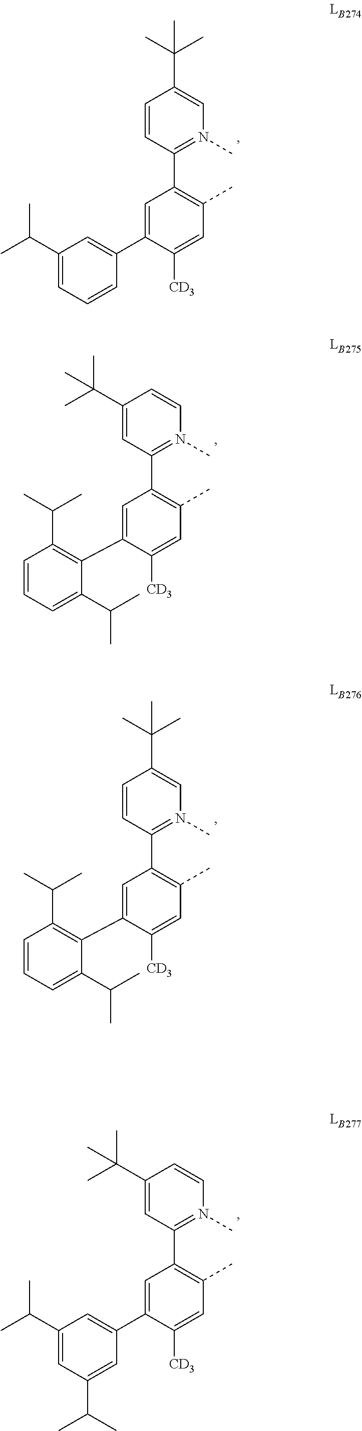 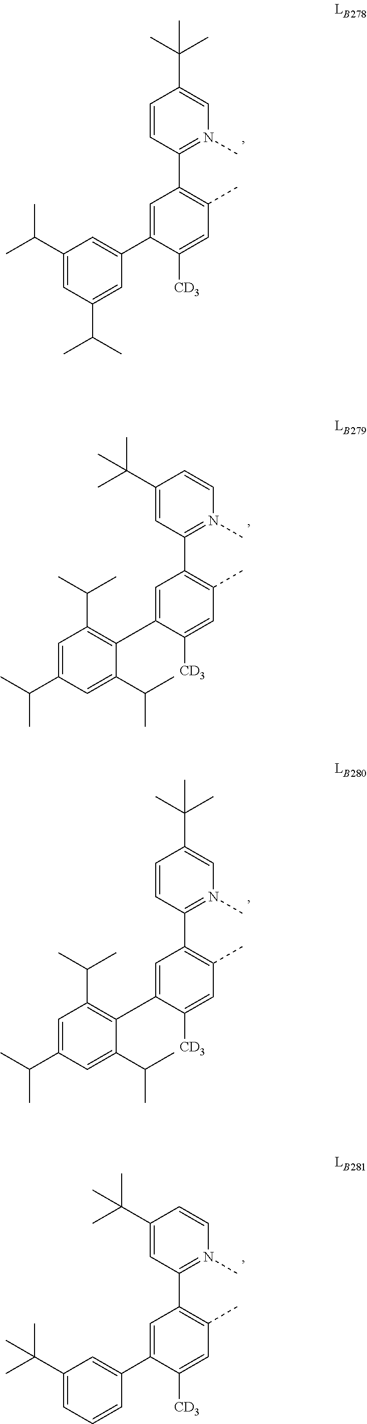 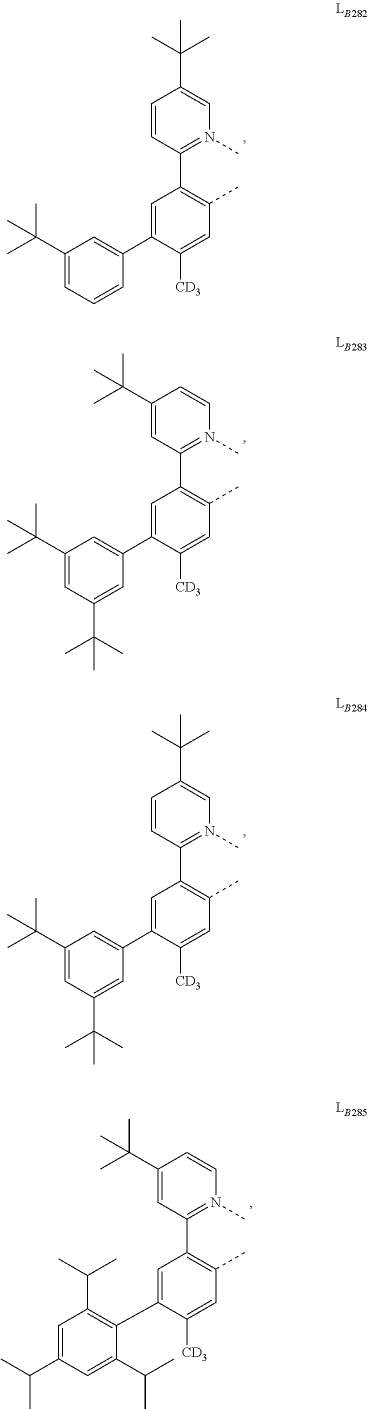 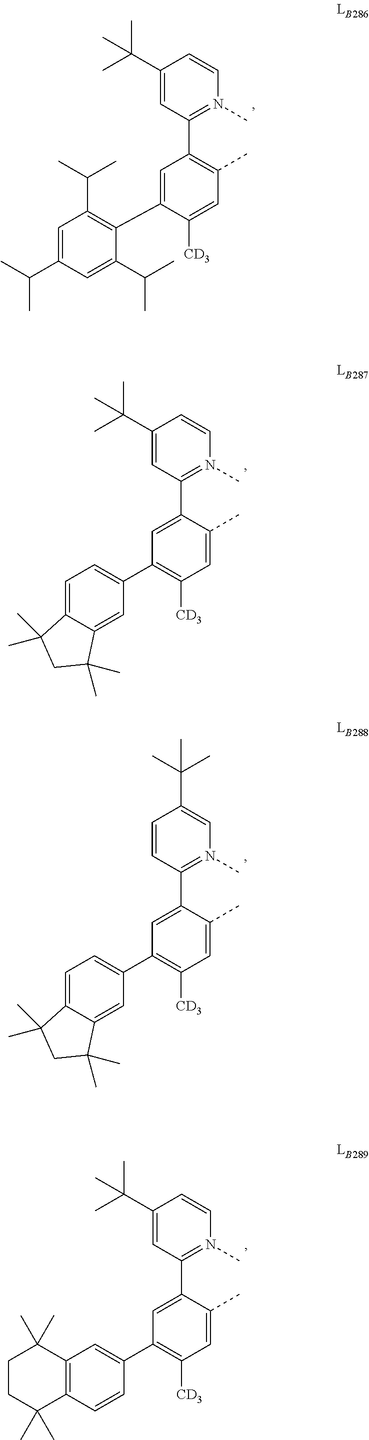 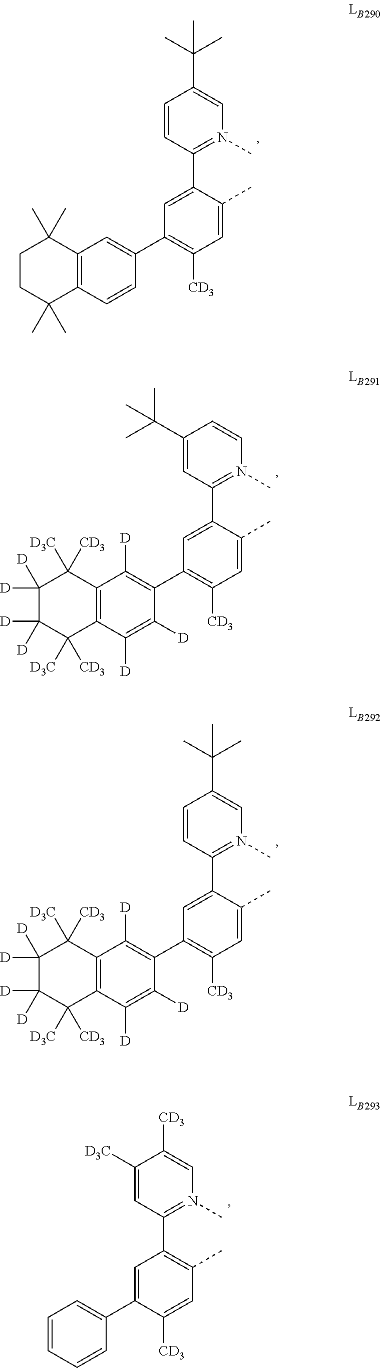 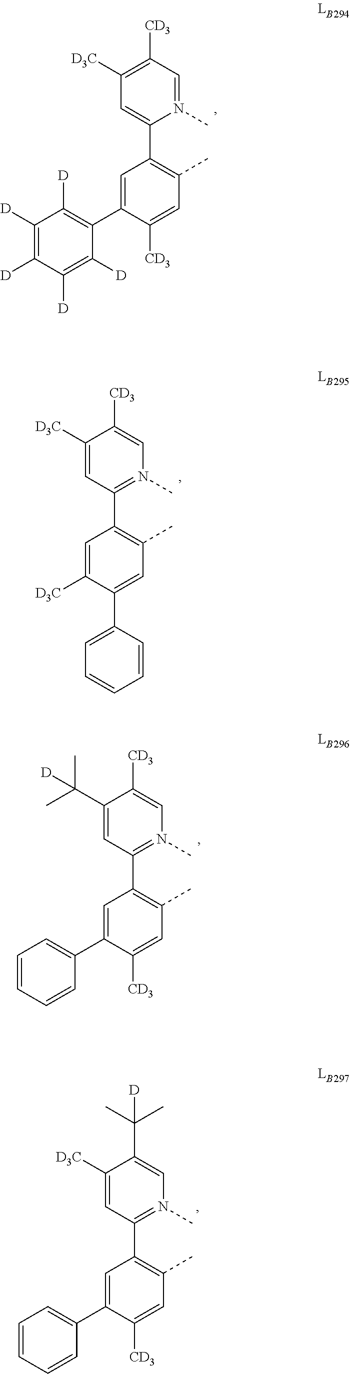 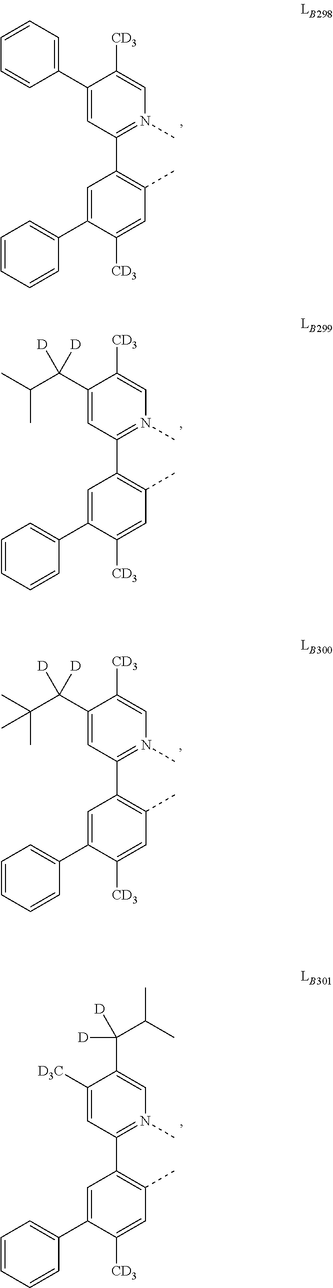 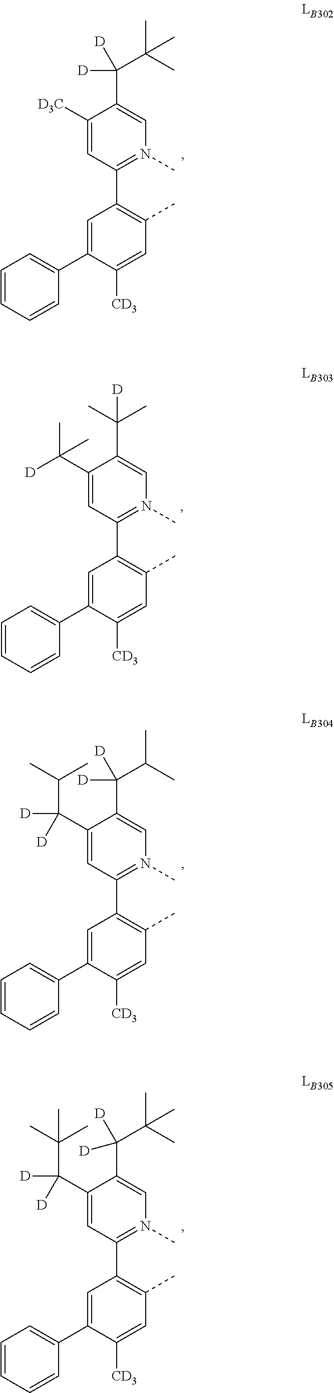 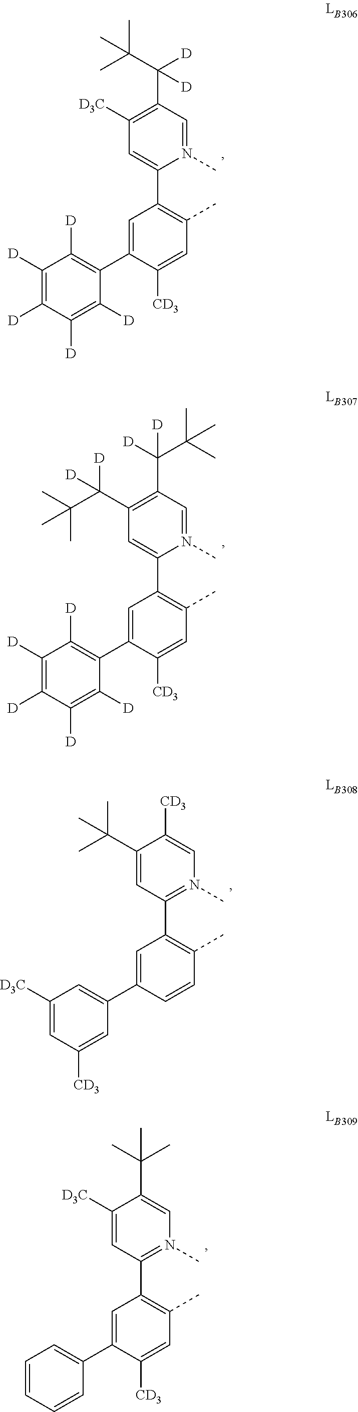 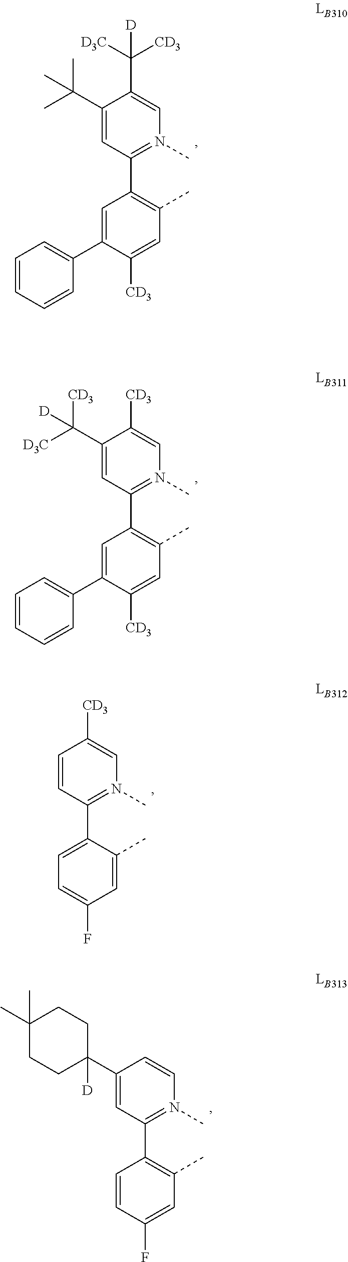 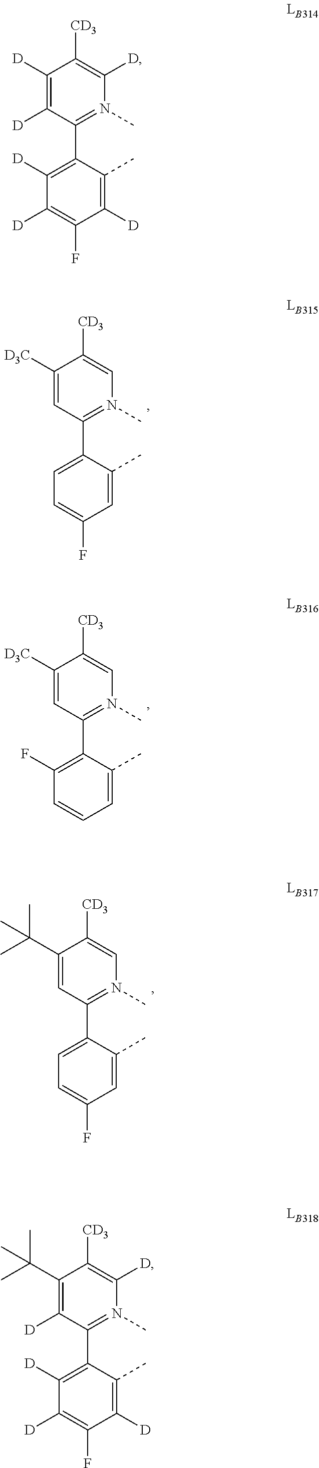 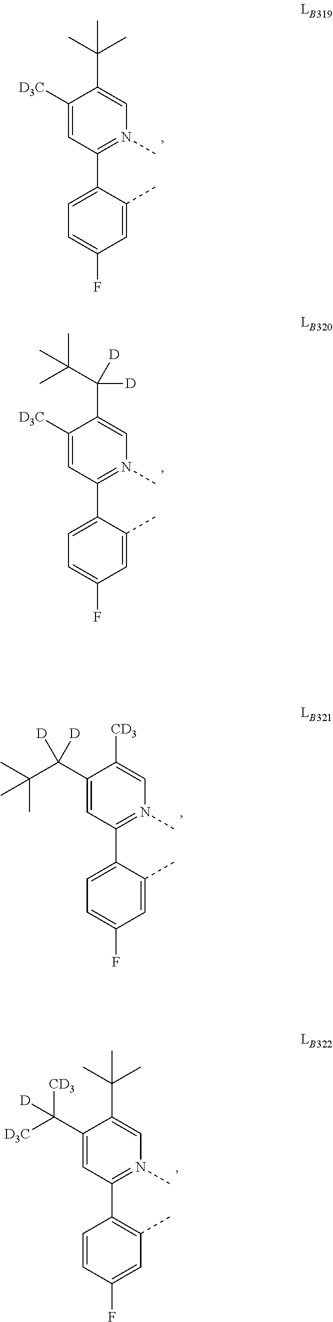 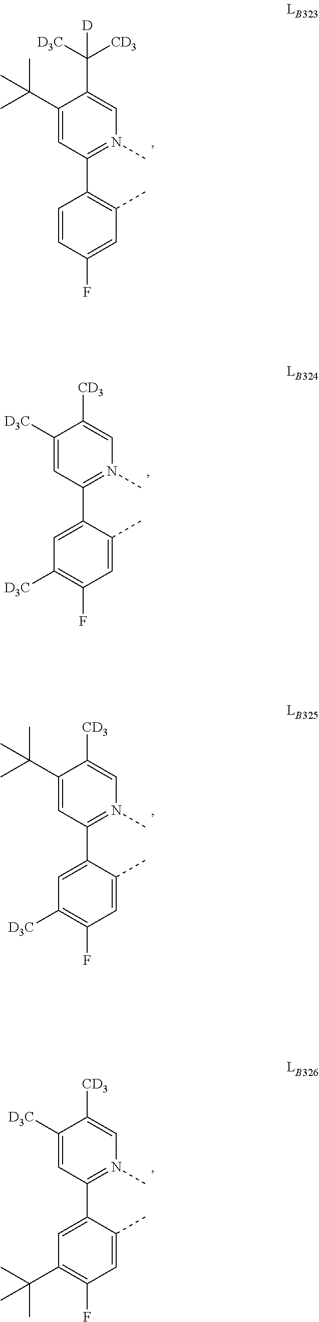 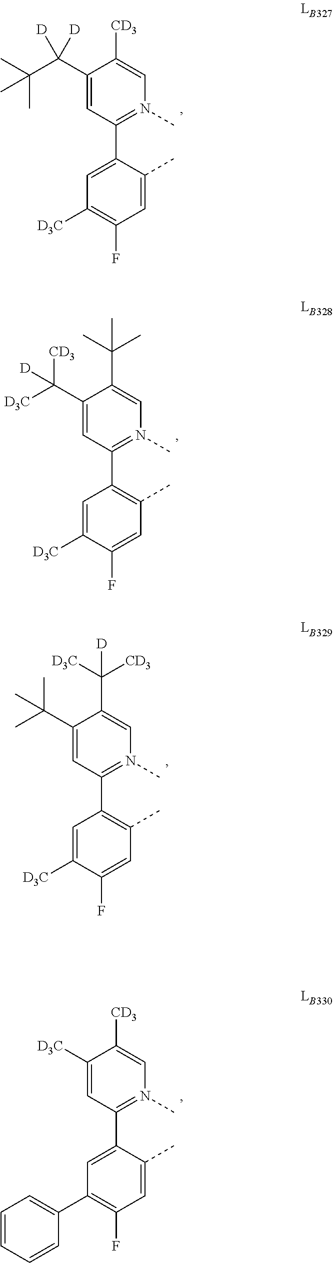 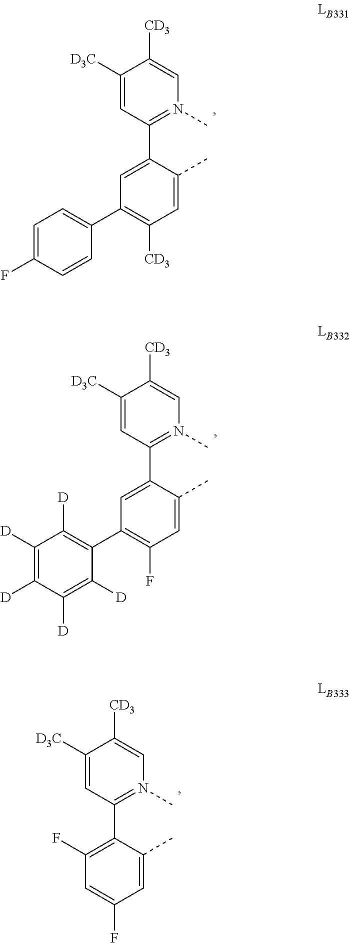 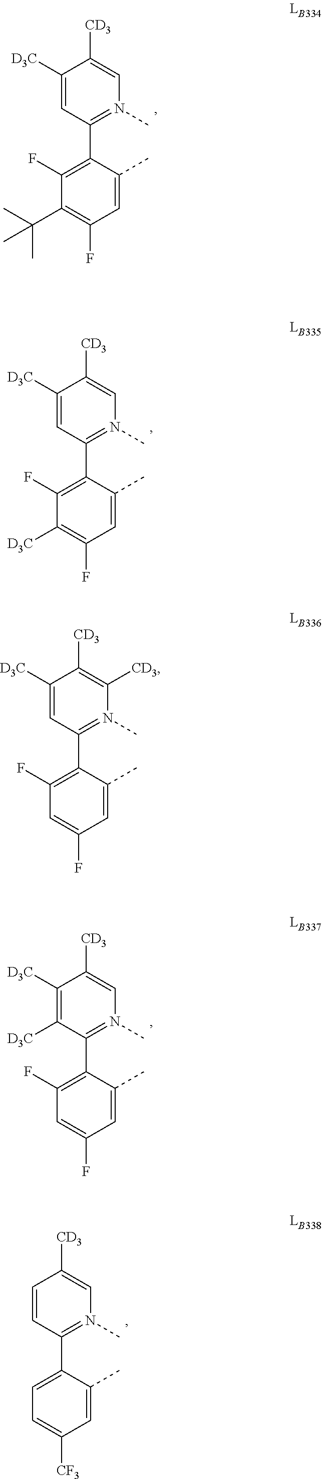 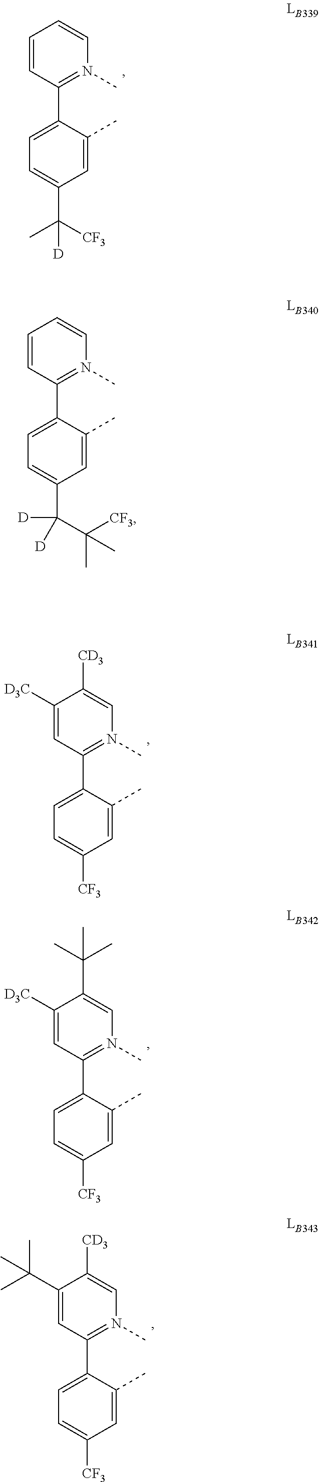 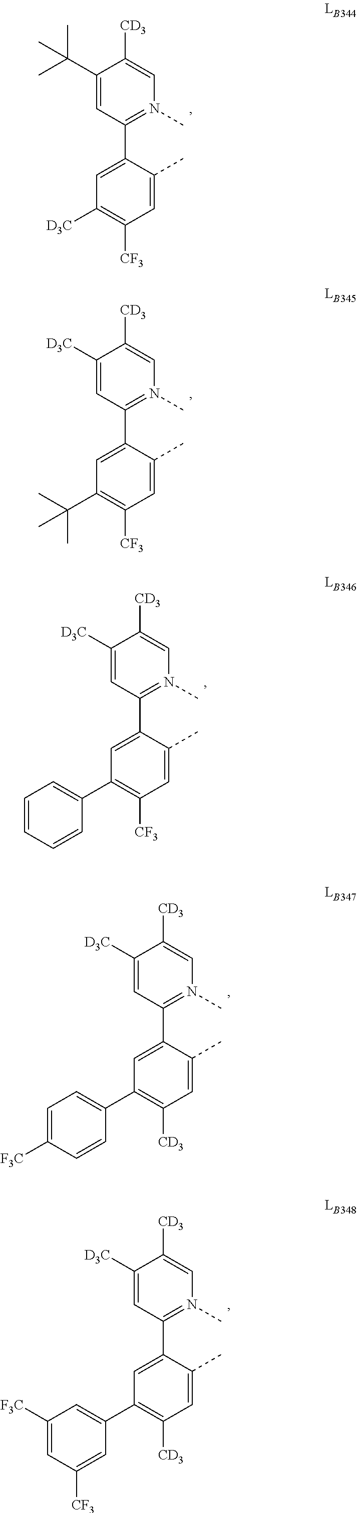 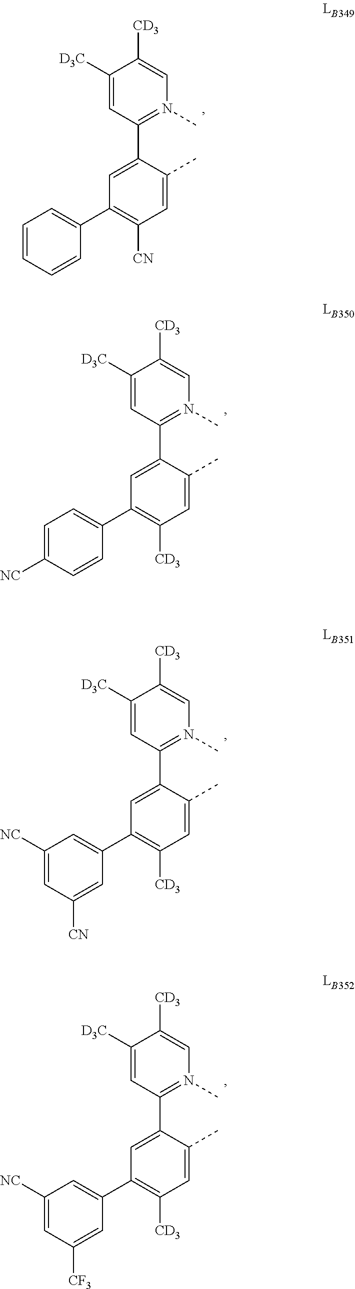 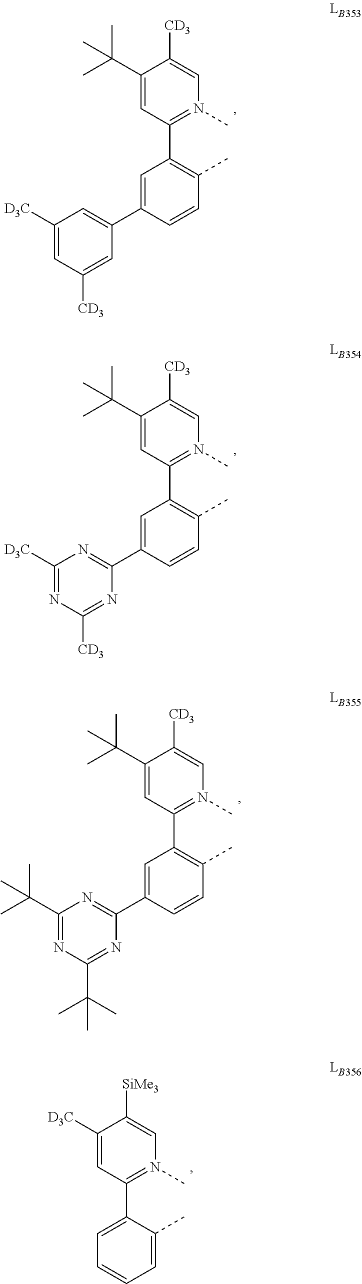 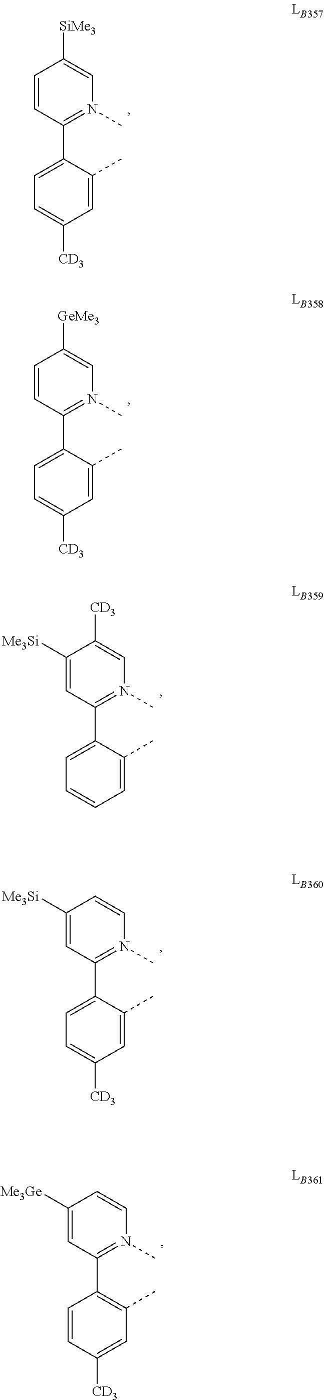 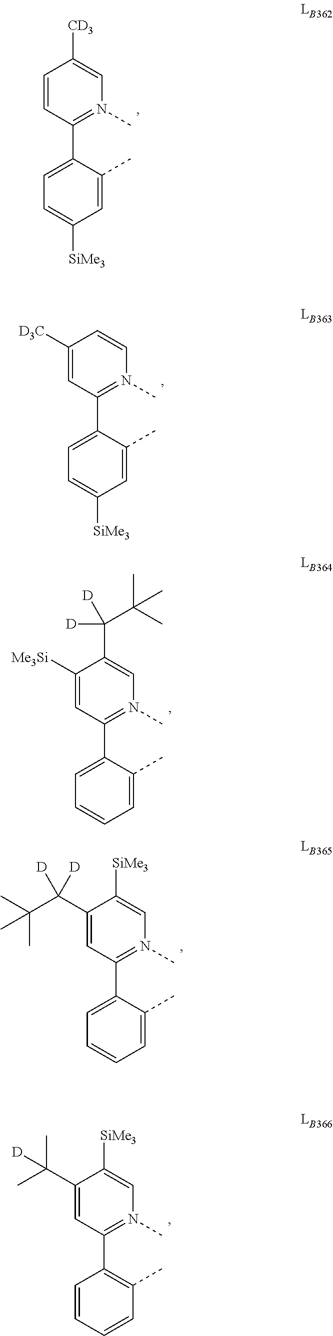 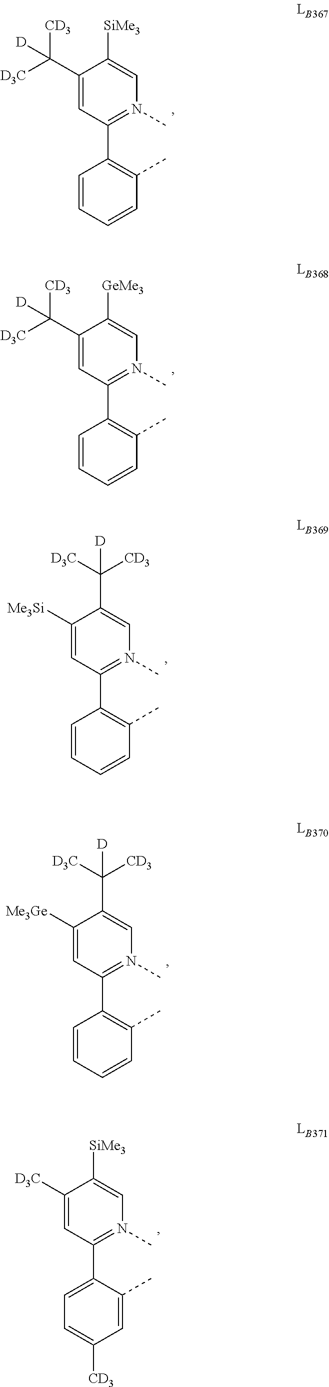 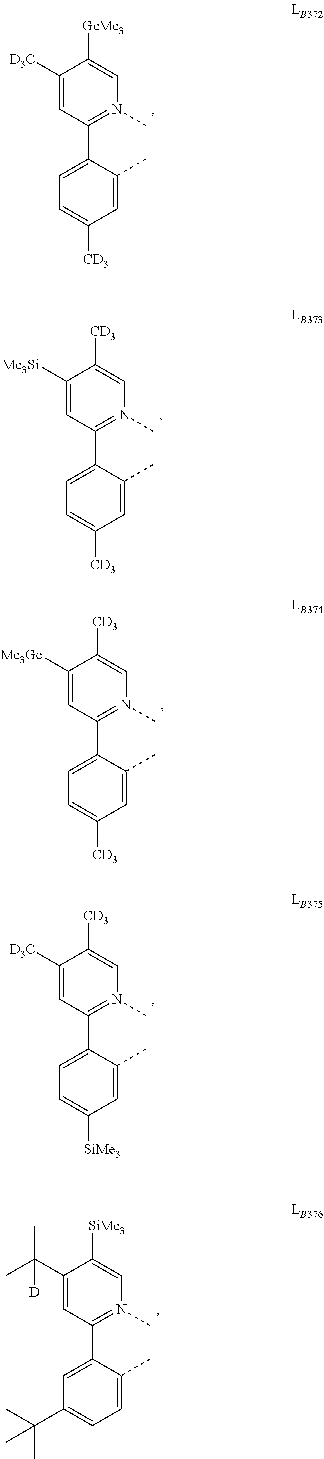 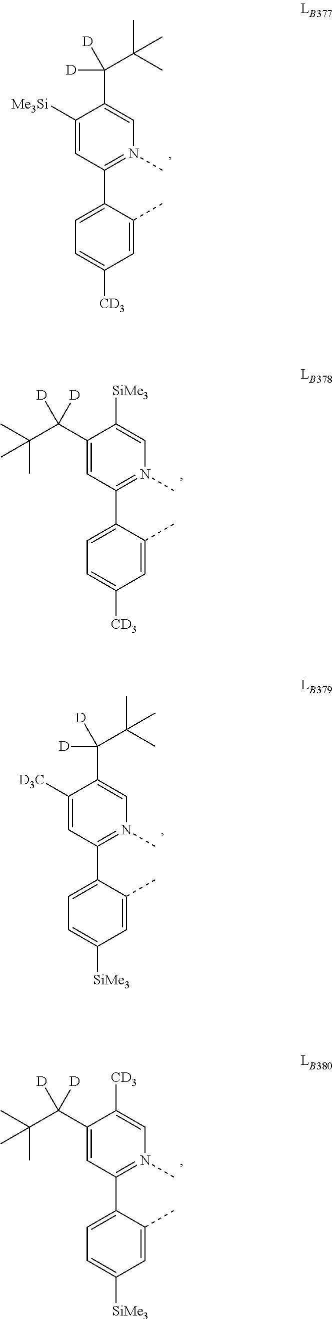 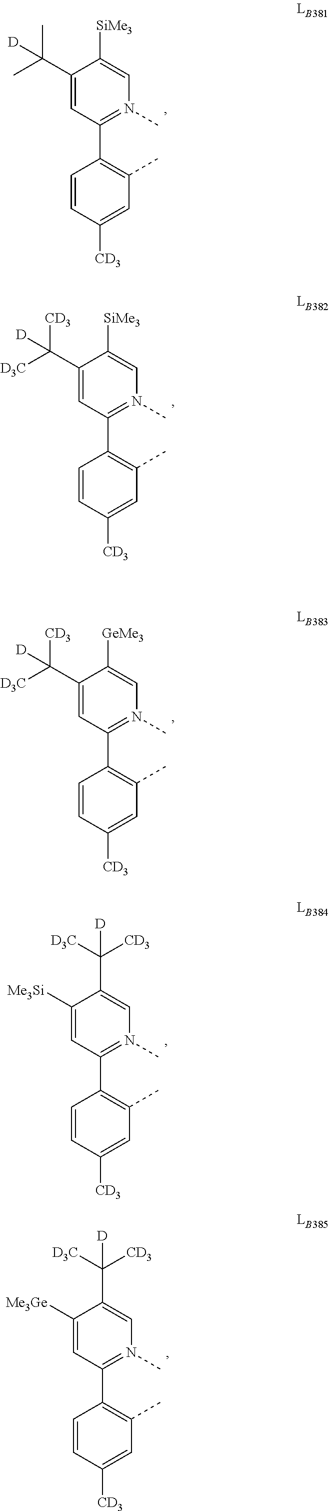 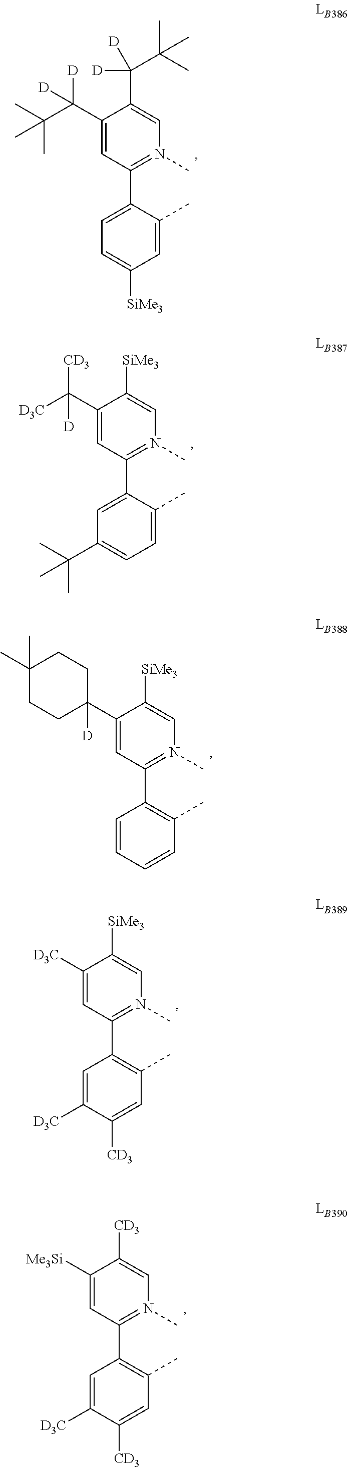 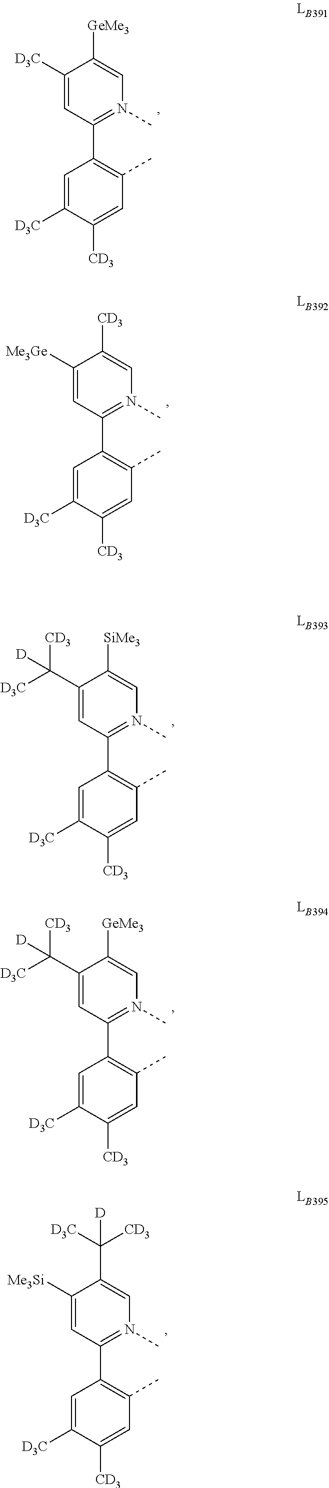 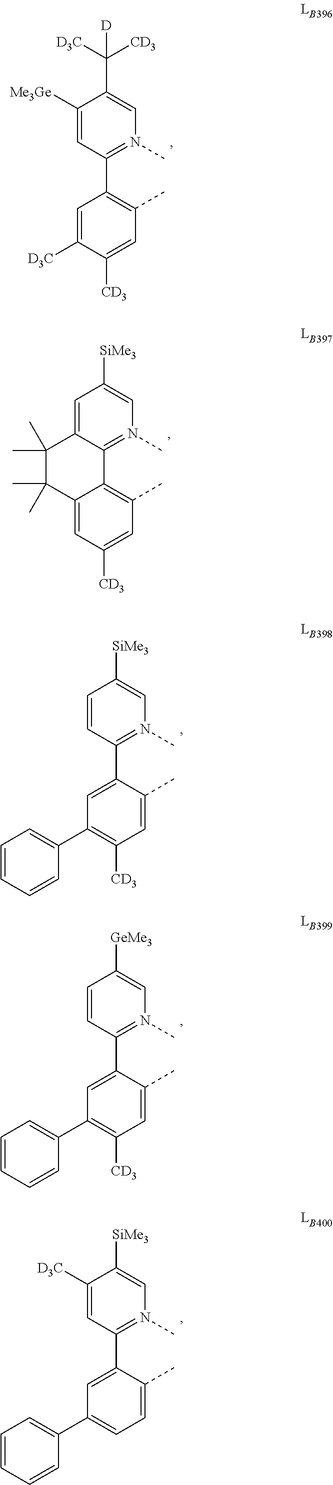 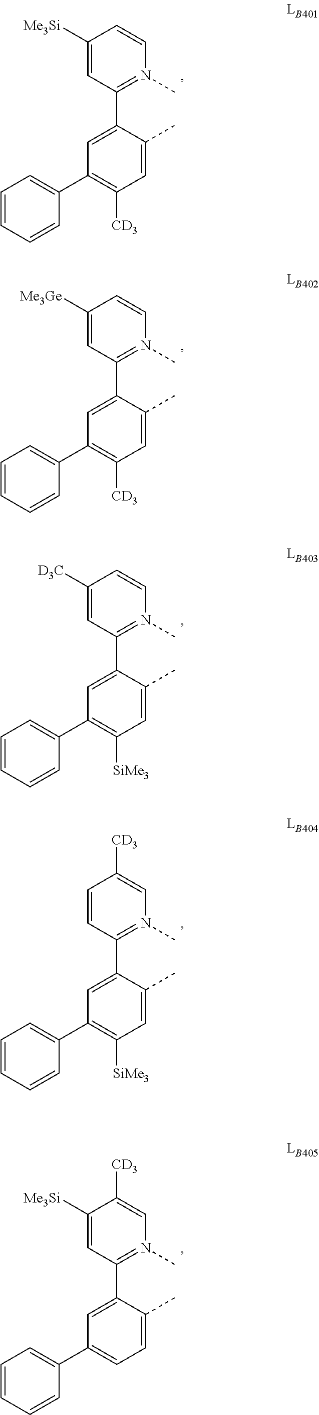 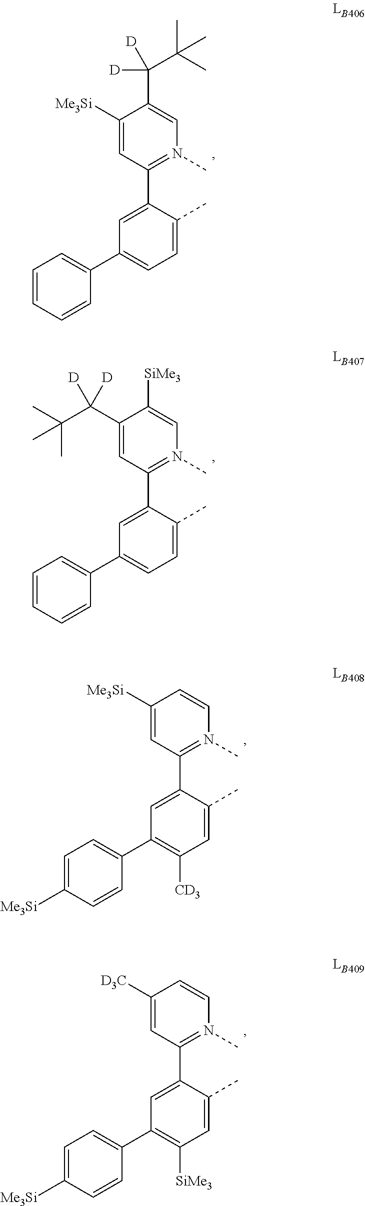 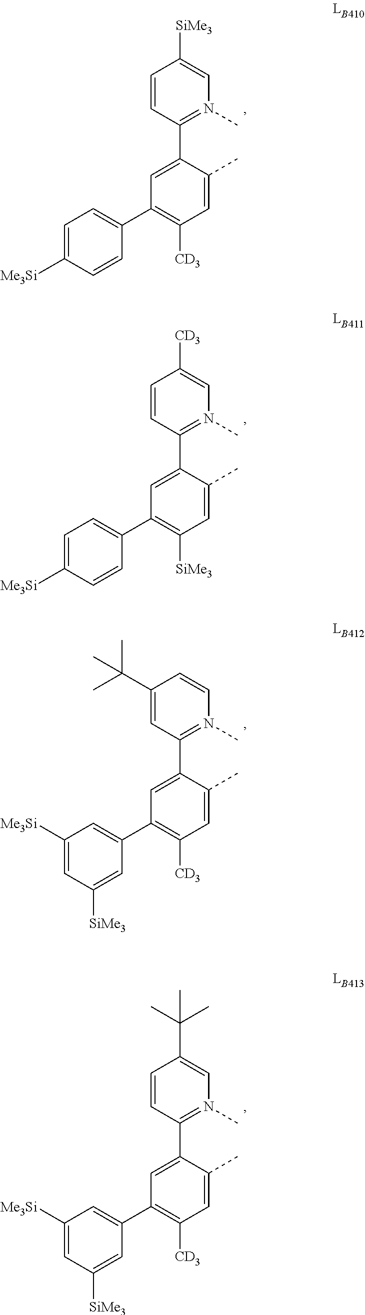 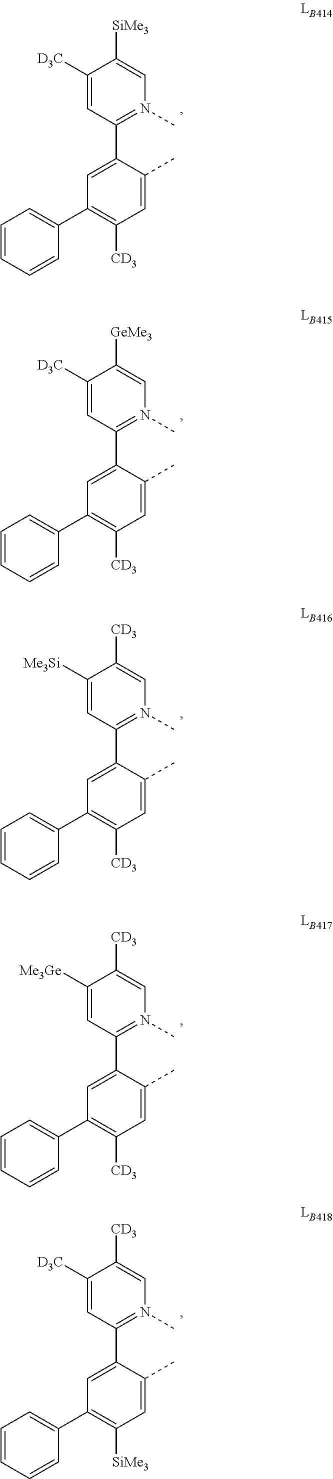 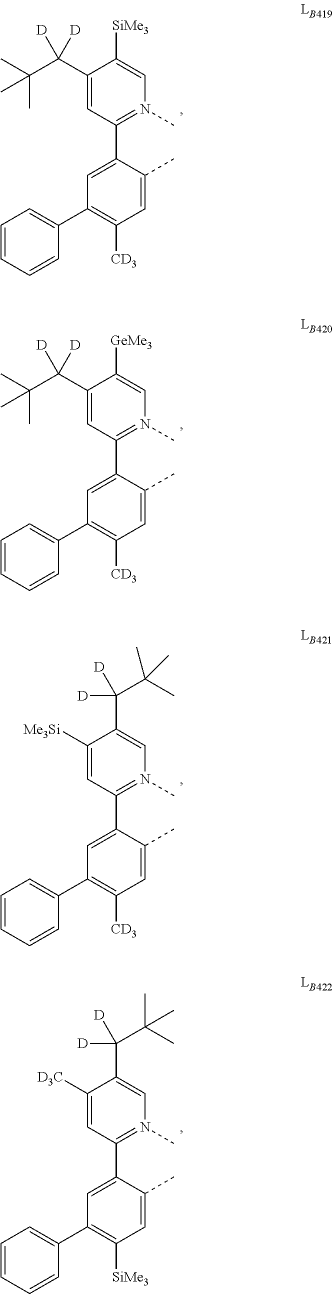 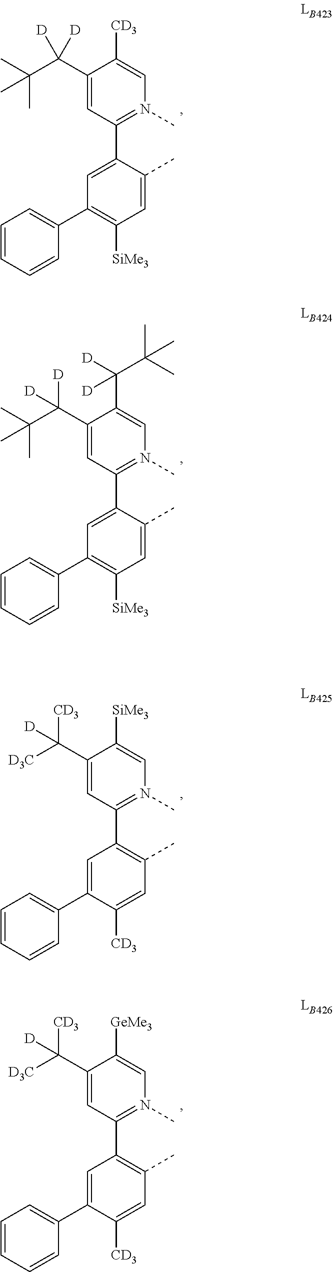 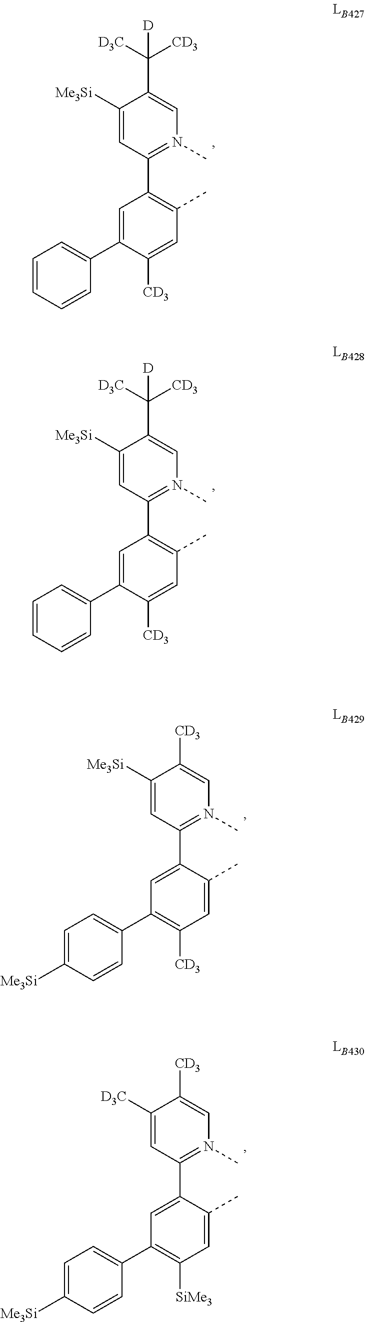 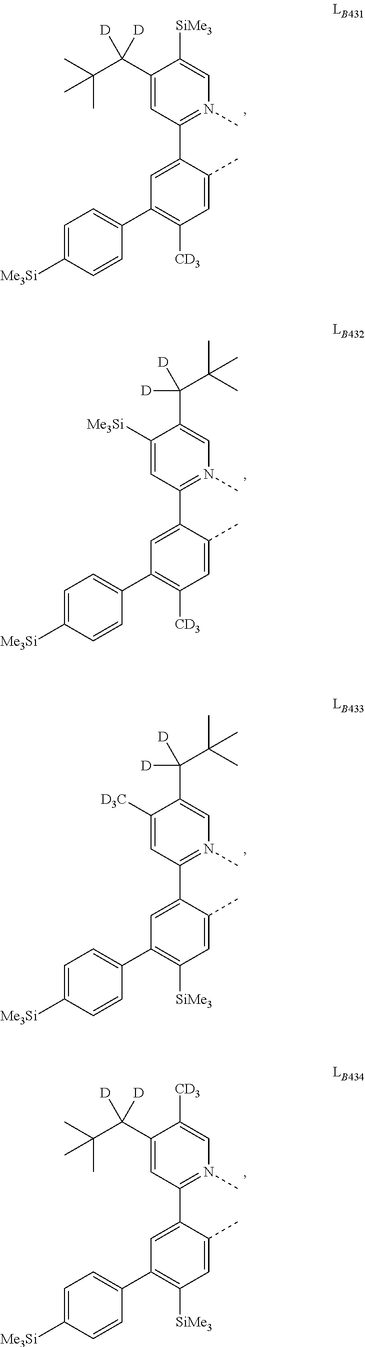 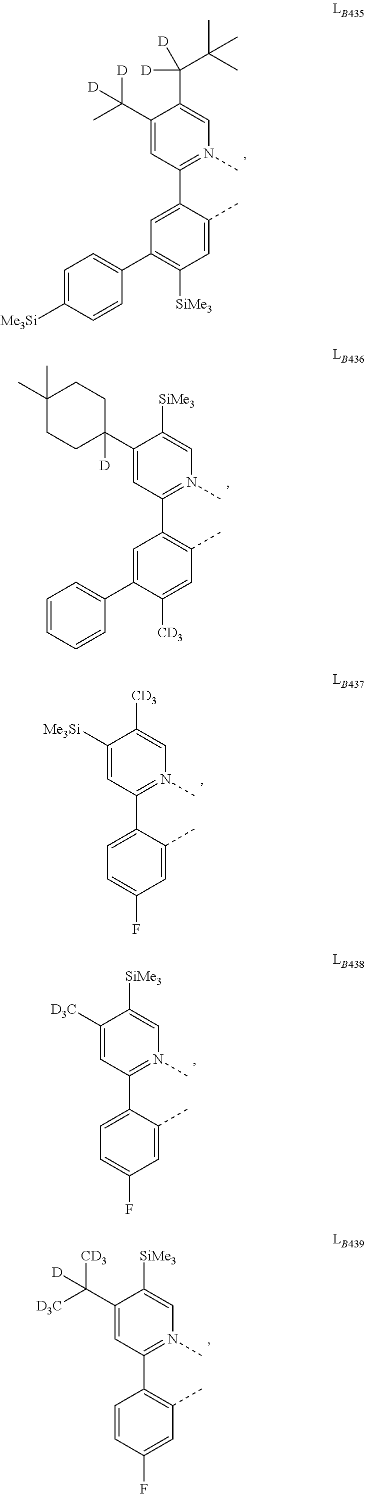 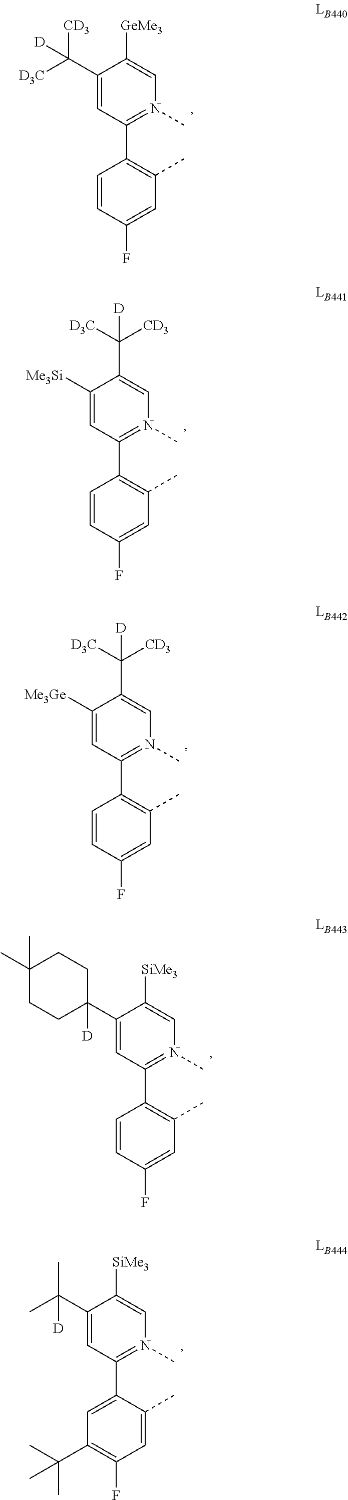 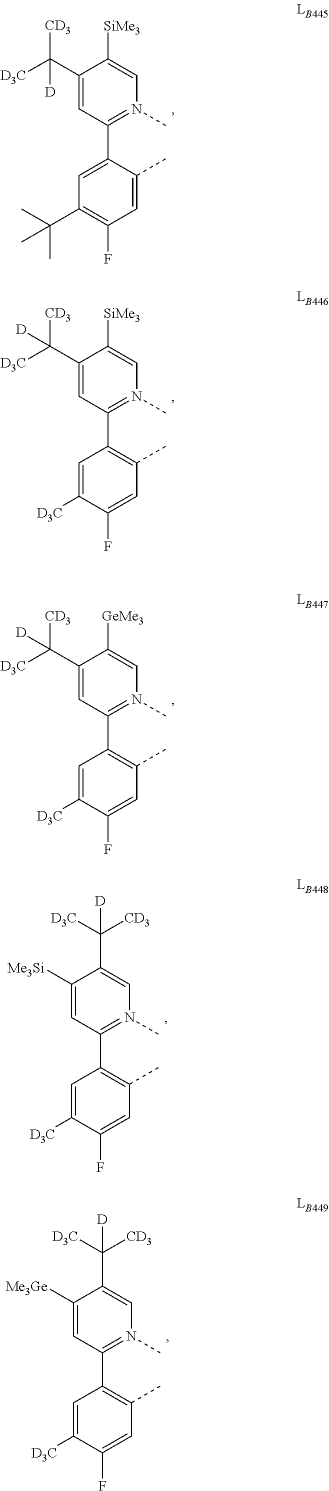 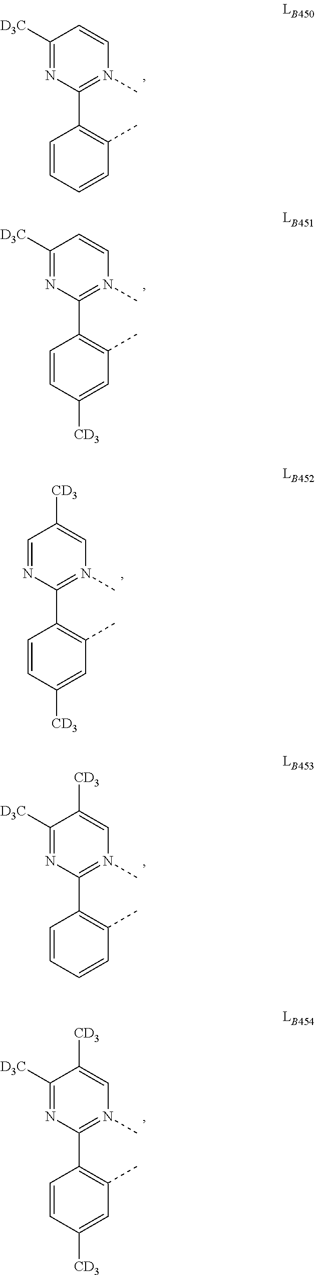 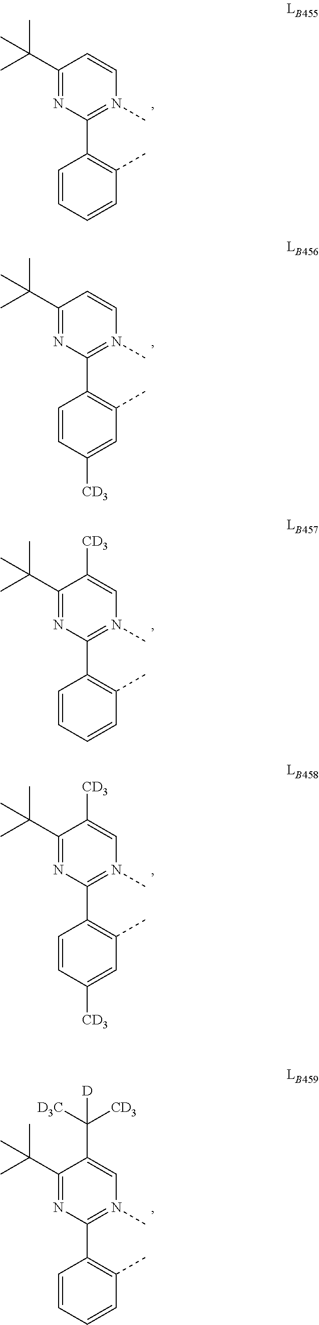 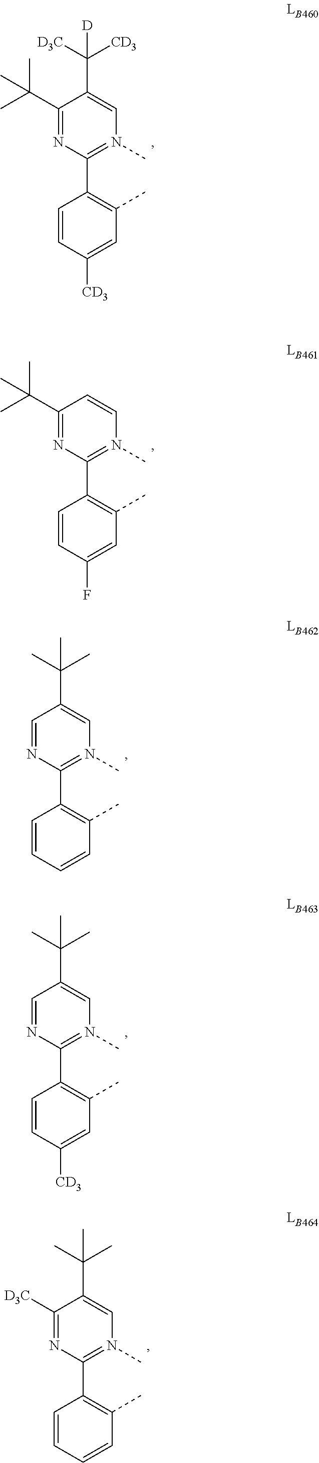 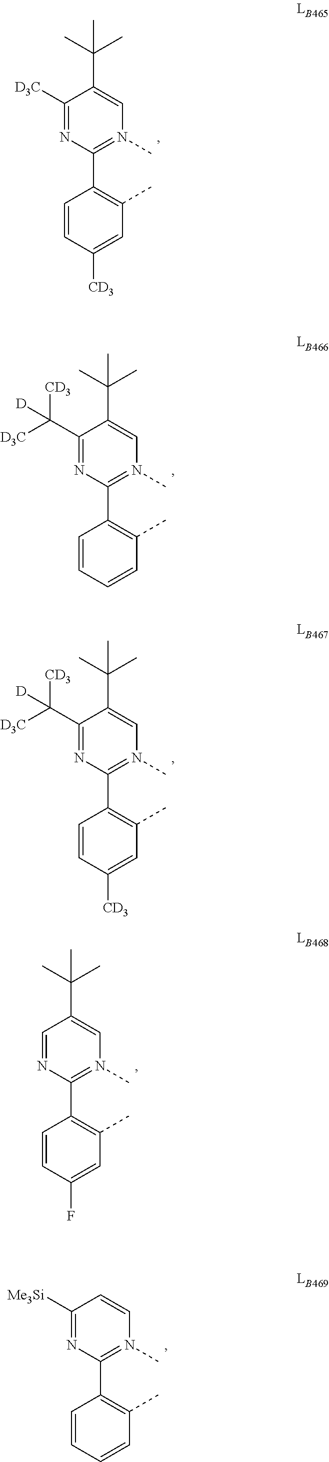 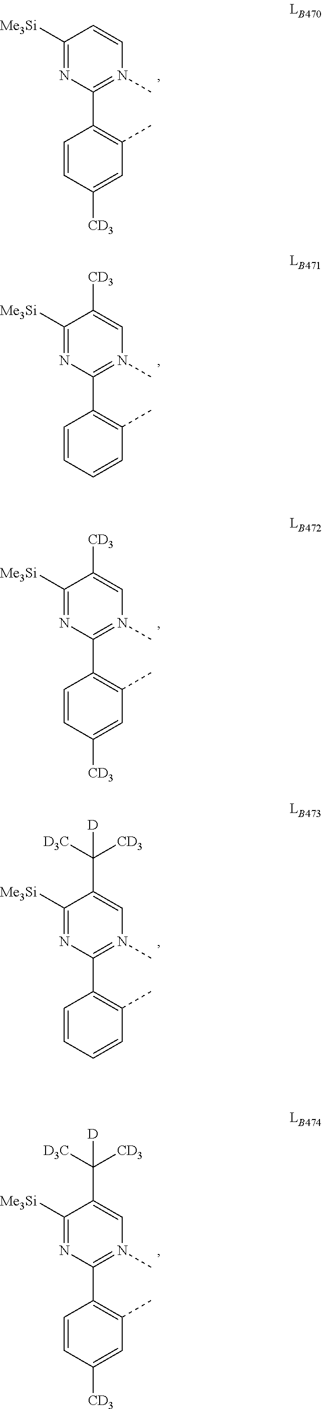 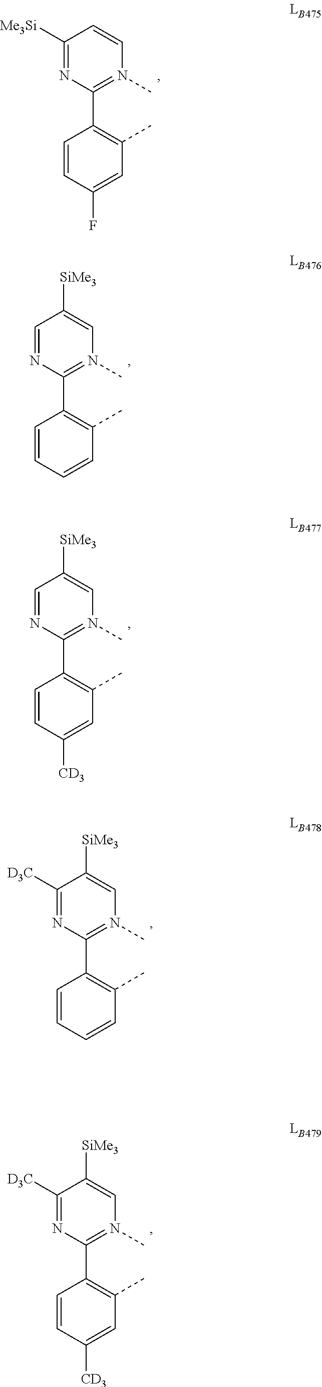 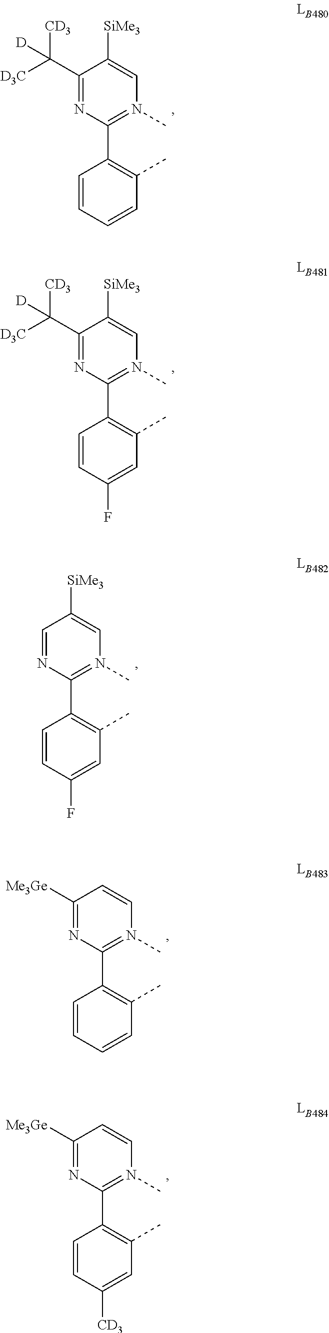 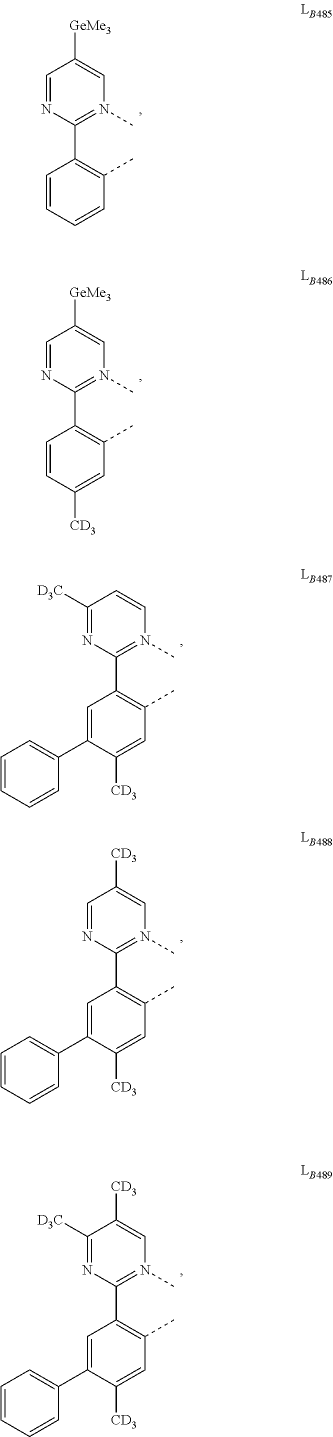 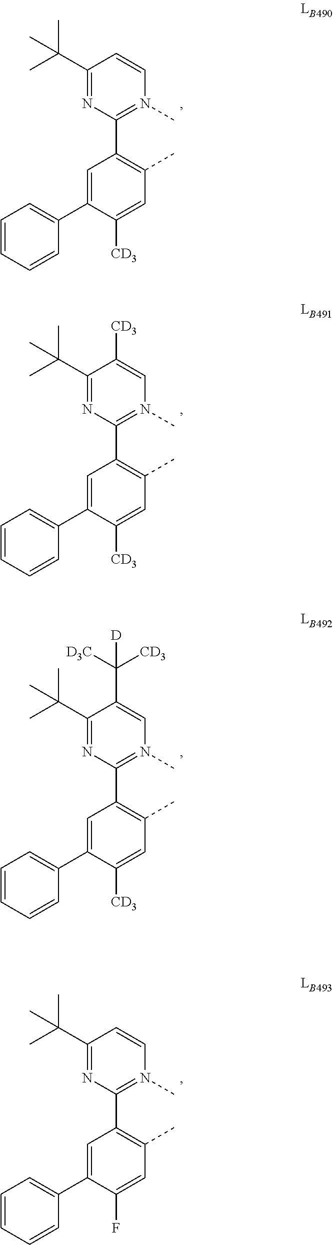 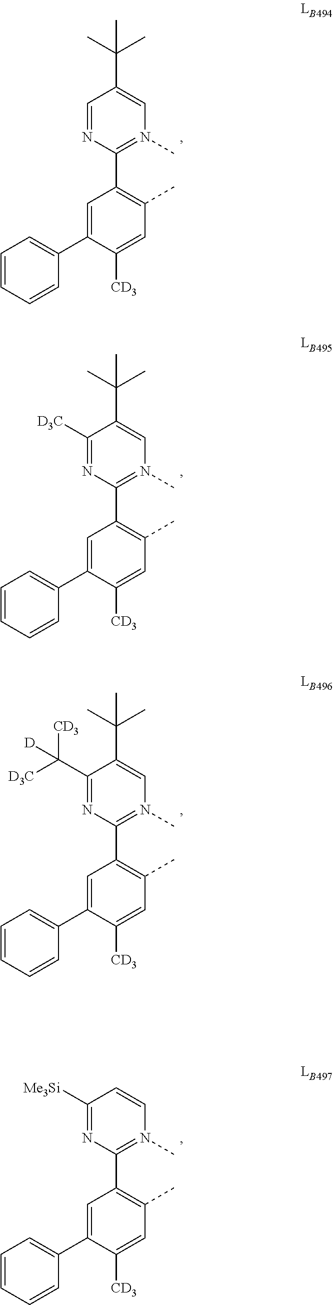 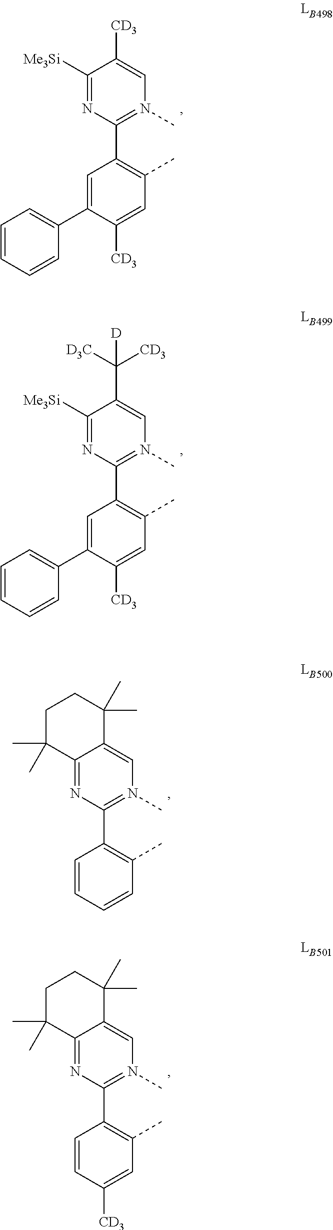 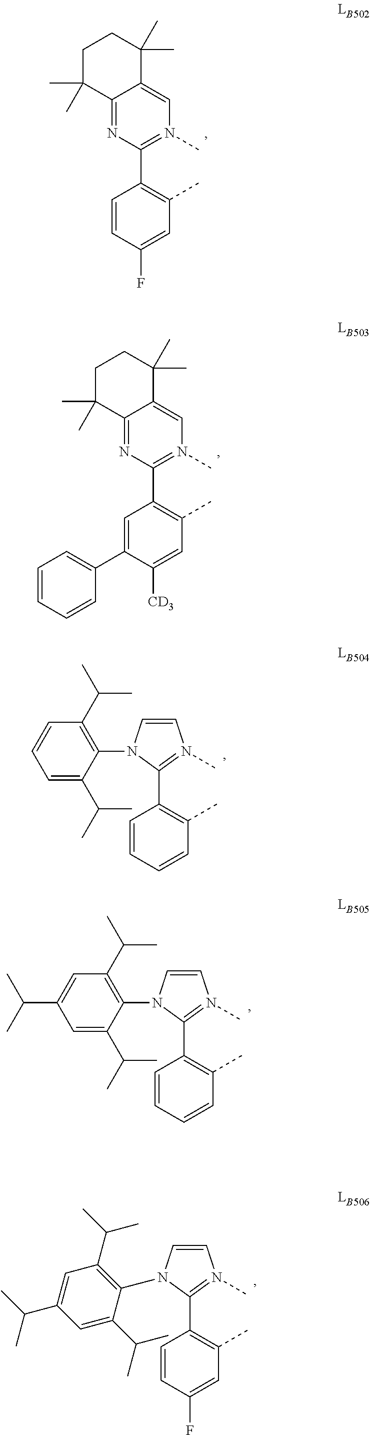 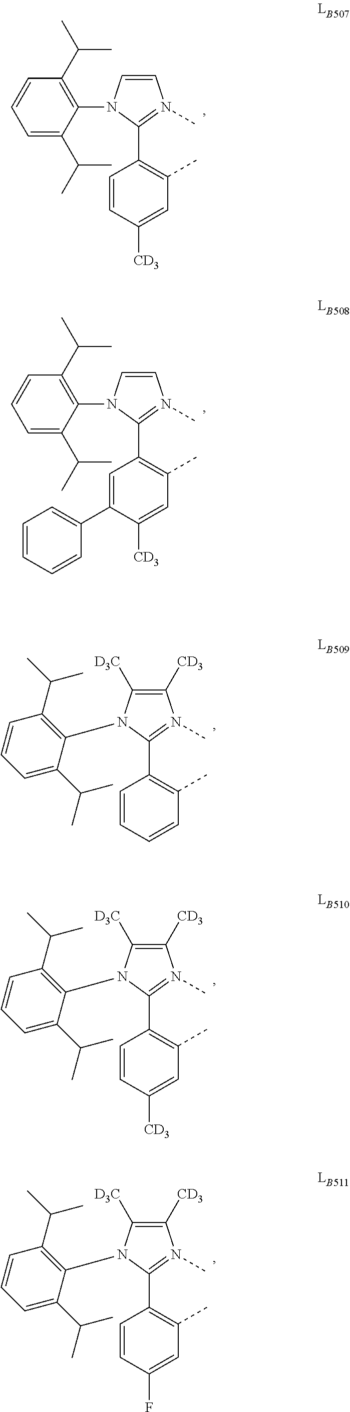 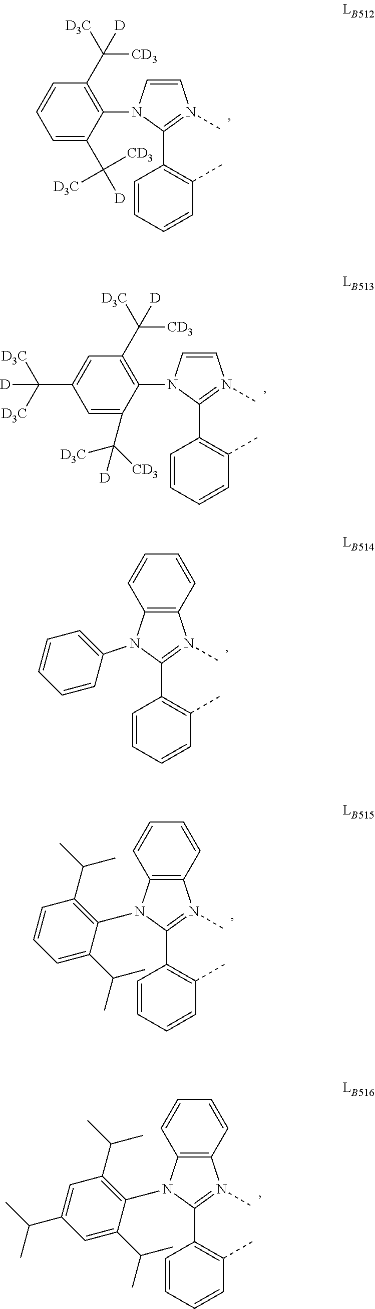 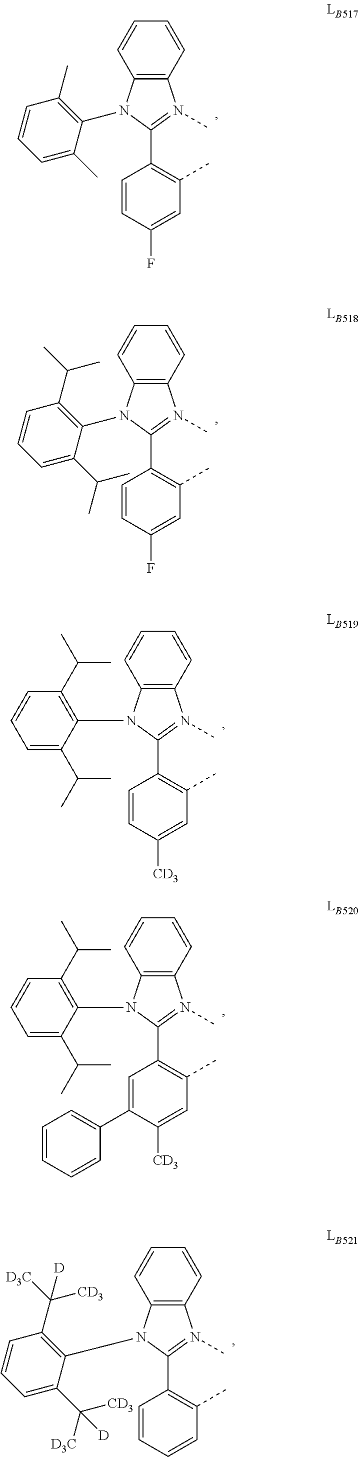 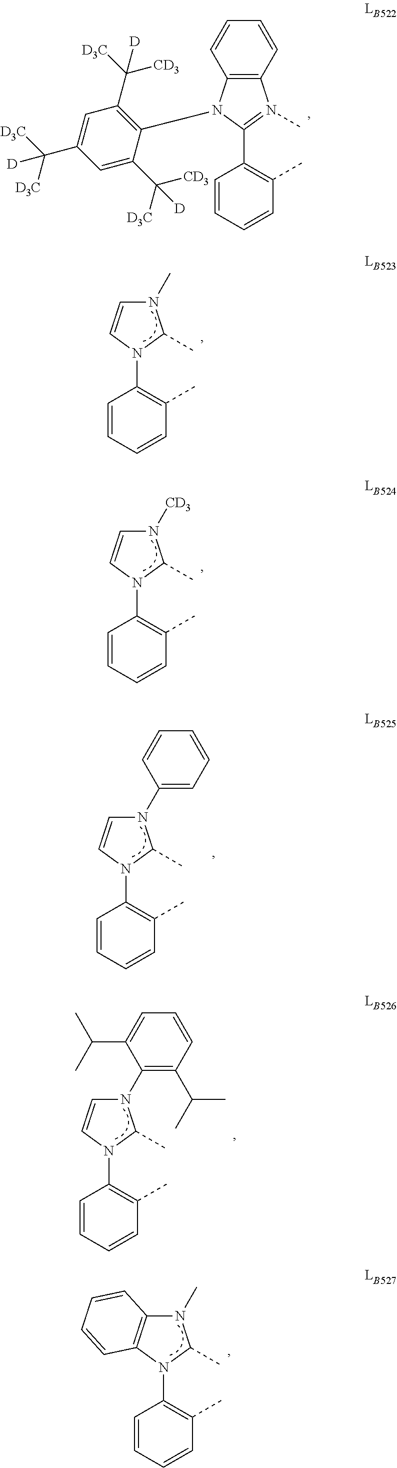 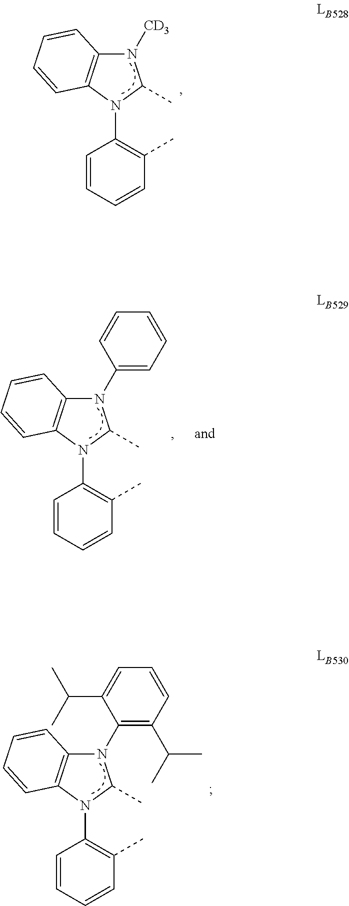
wherein each L_{Cj-I} has a structure based on formula 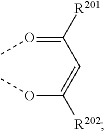
and
each L_{Cj-II} has a structure based on formula 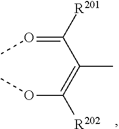
wherein for each L_{Cj} in L_{Cj-I} and L_{Cj-II}, R²⁰¹ and R²⁰² are defined as follows:

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{D6} | R^{D6} | L_{C198} | R^{D1} | R^{D17} | L_{C390} | R^{D17} | R^{D49} | L_{C582} | R^{D143} | R^{D144} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D1} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{D9} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C319} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D9} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C334} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C344} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D88} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{D9} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{D9} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D1} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D193} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C935} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | R^{D10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

wherein R^{D1} to R^{D246} have the following structures:

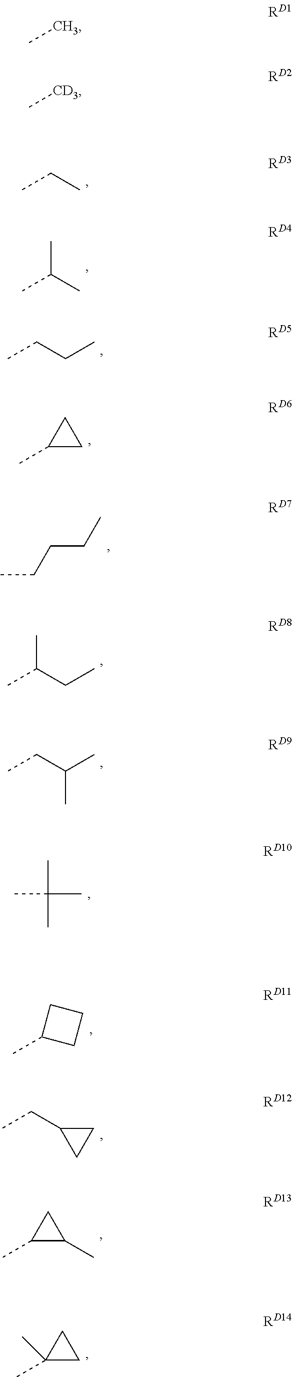

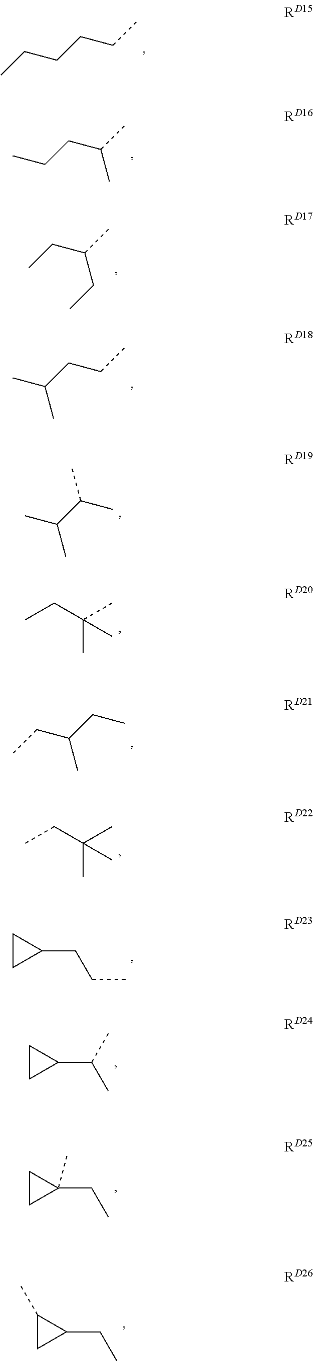

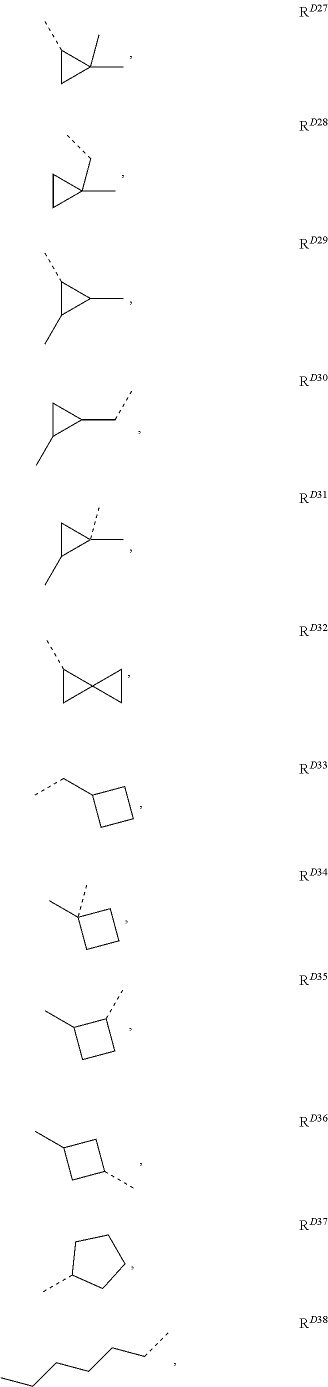

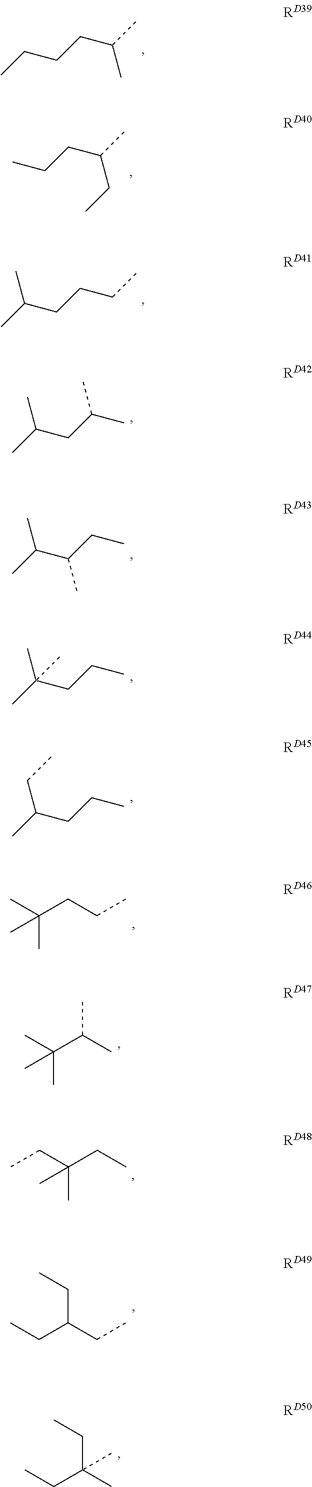

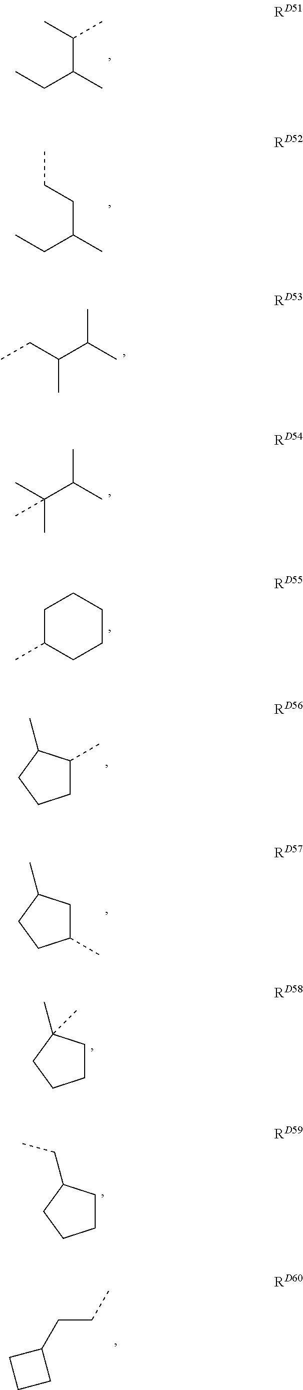

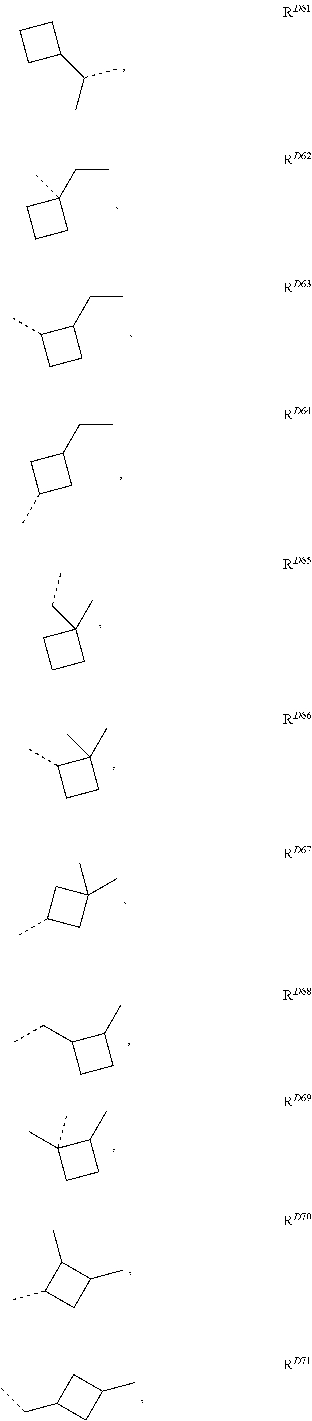

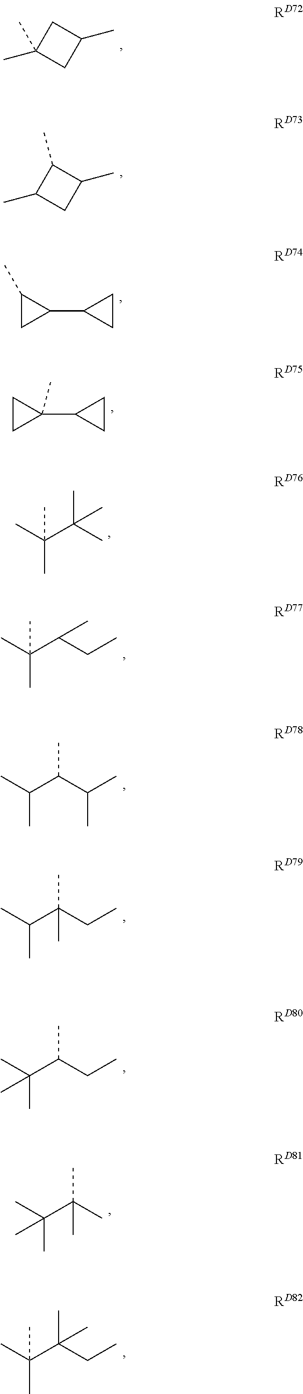

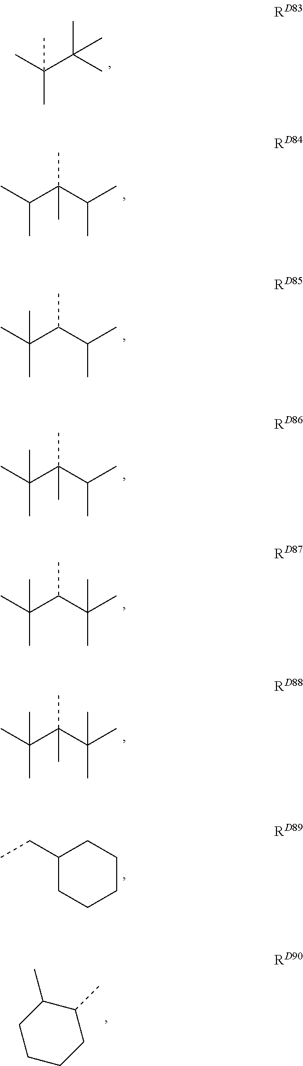

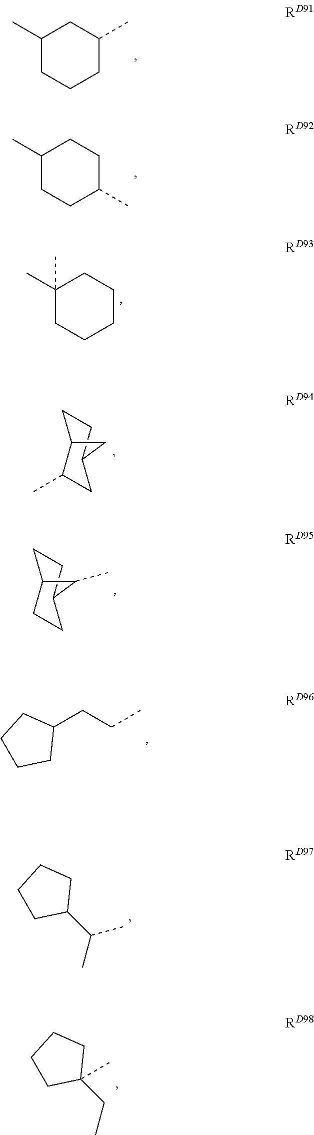

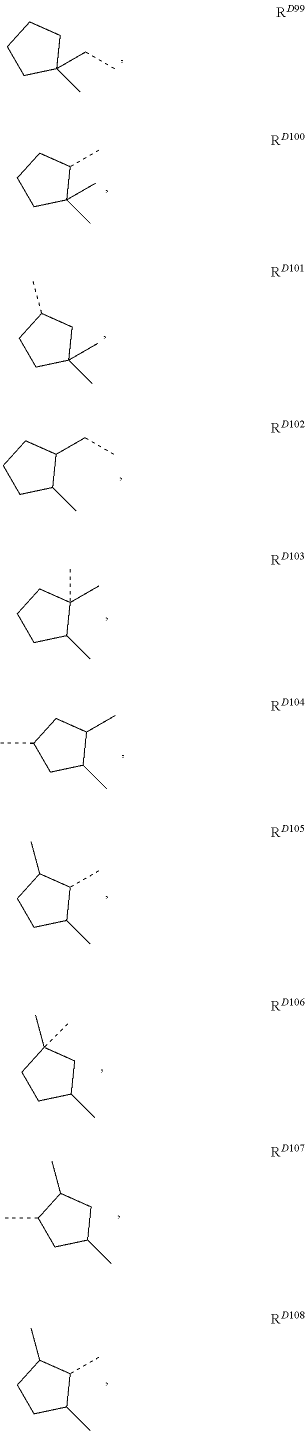

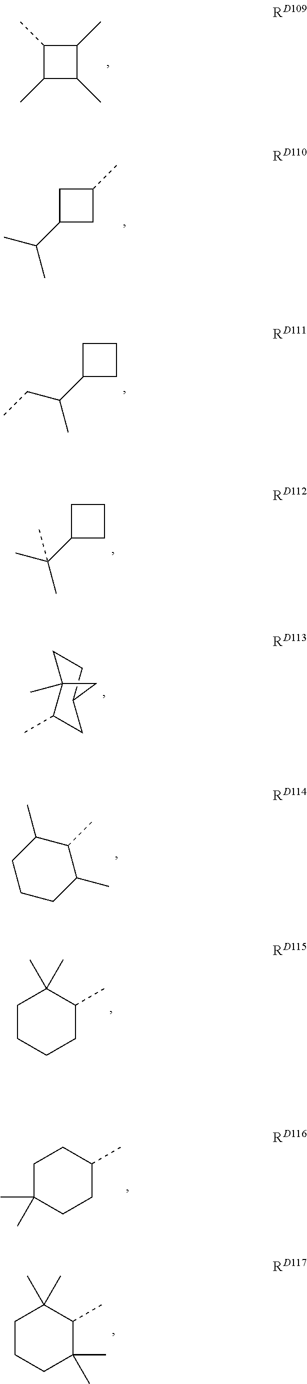

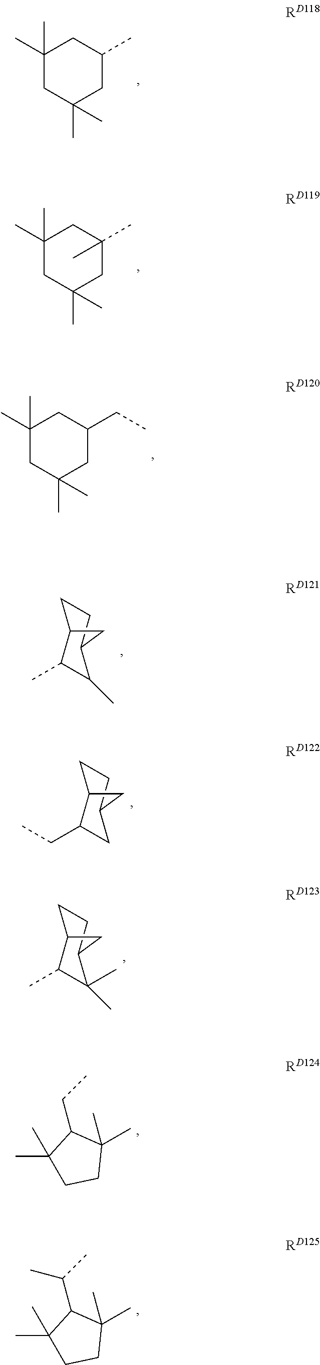

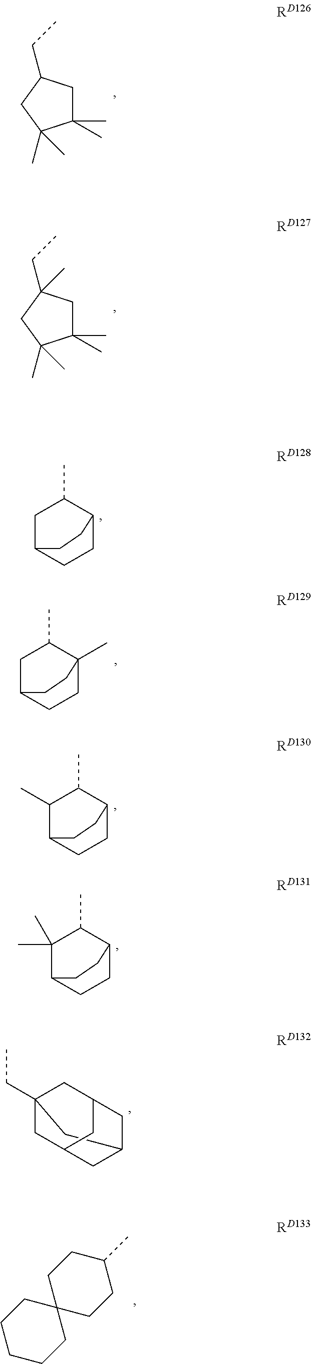

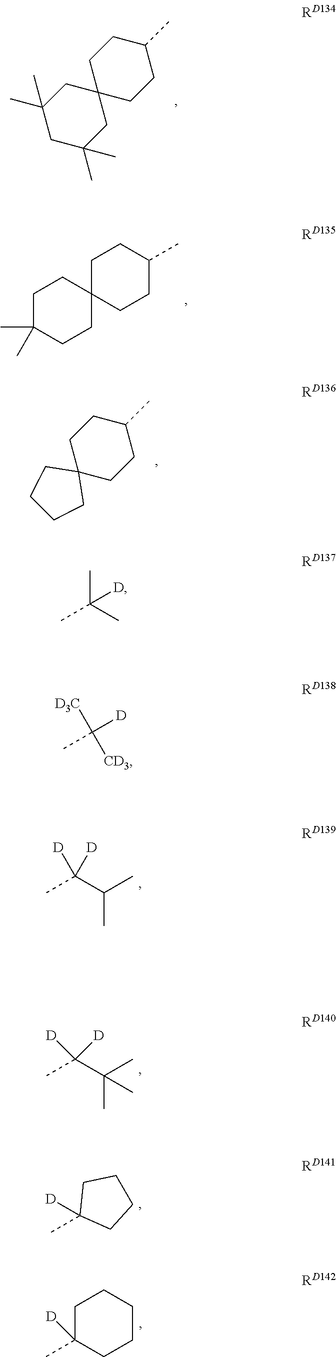

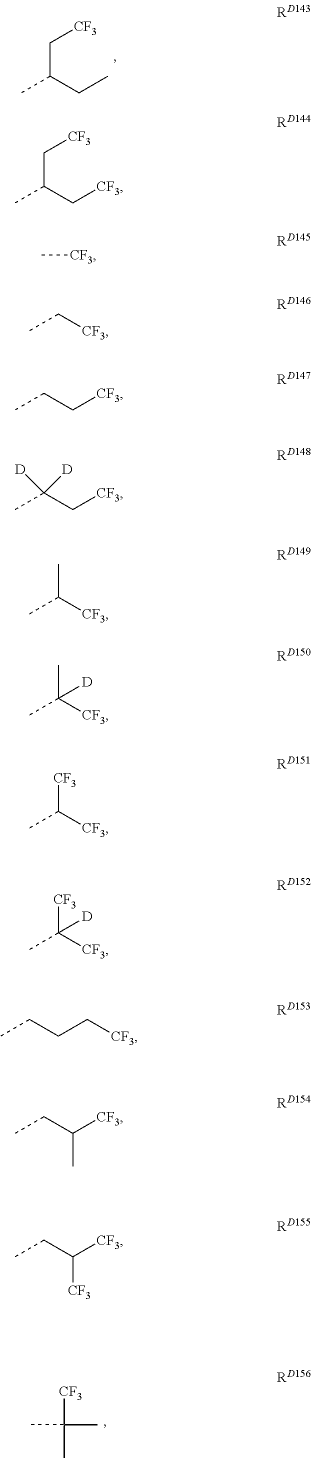

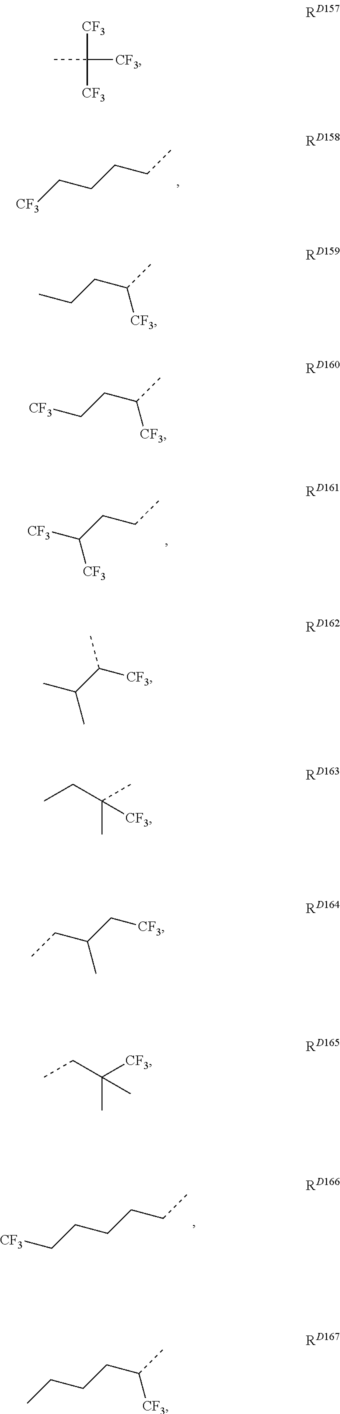

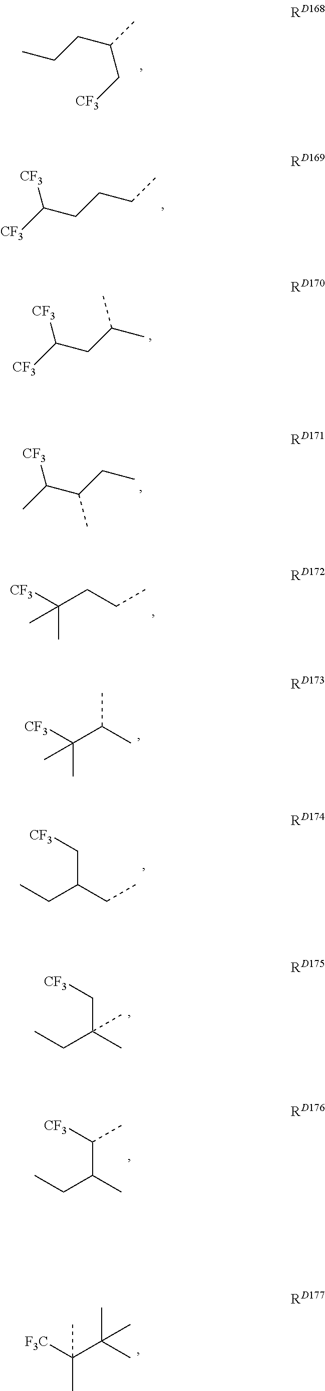

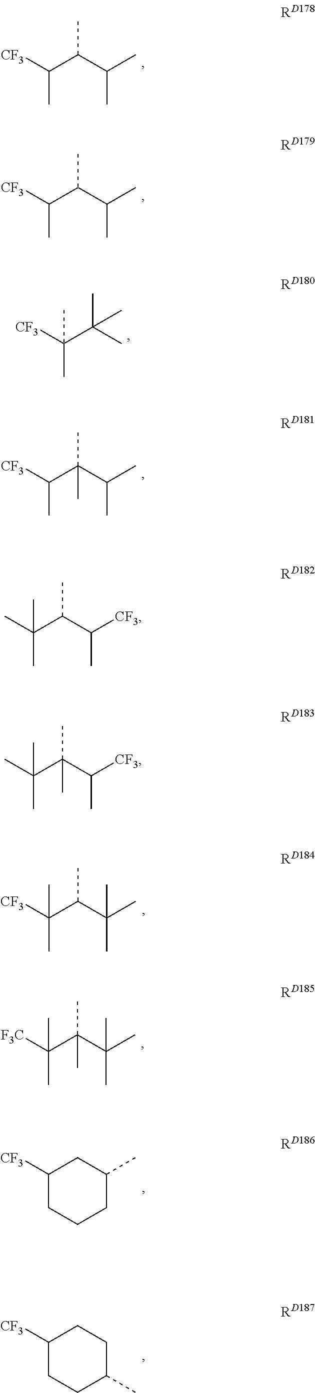

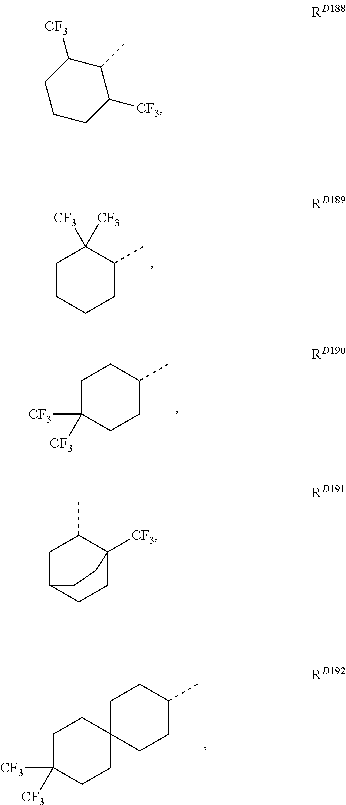

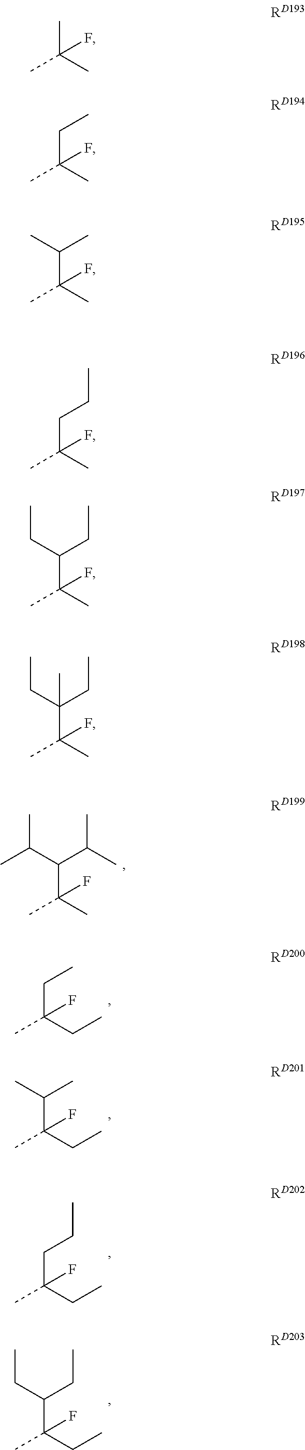

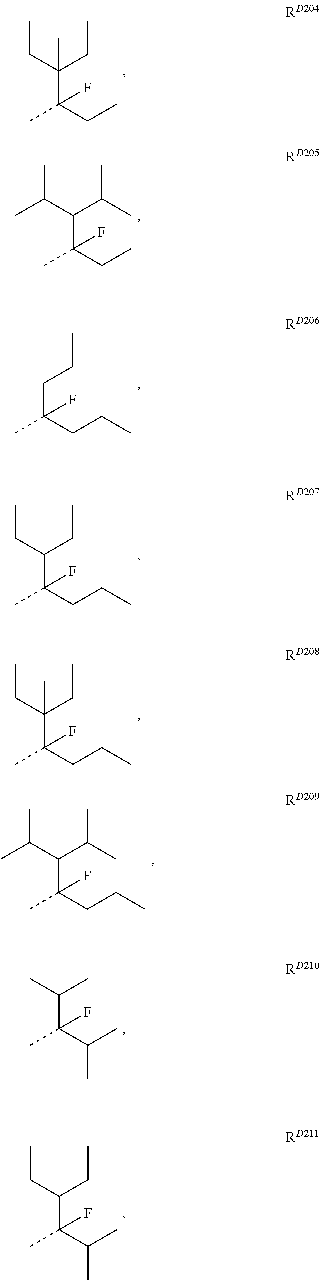

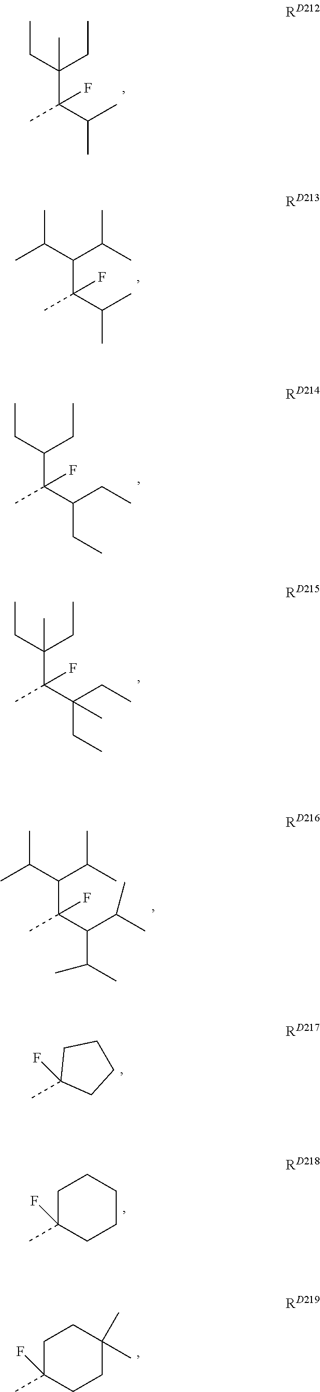

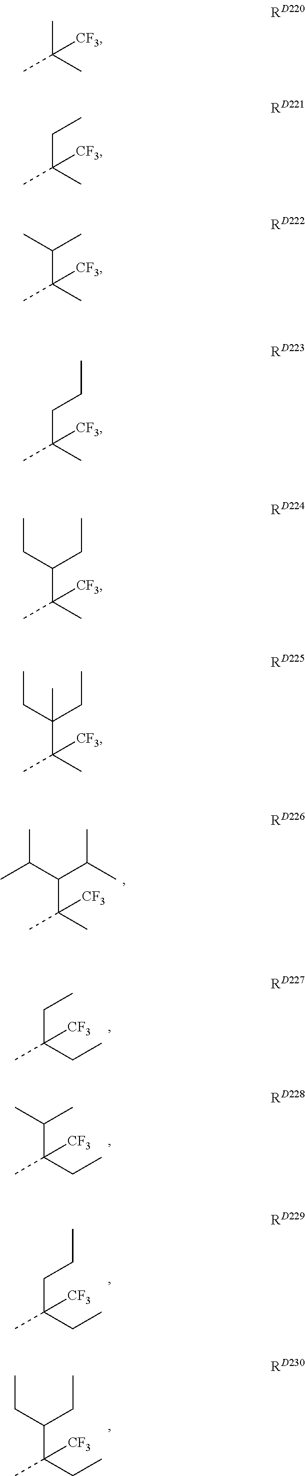

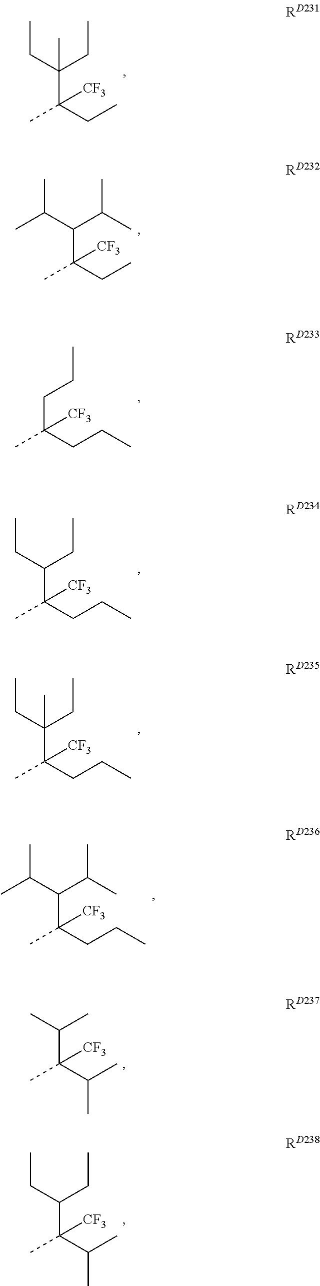

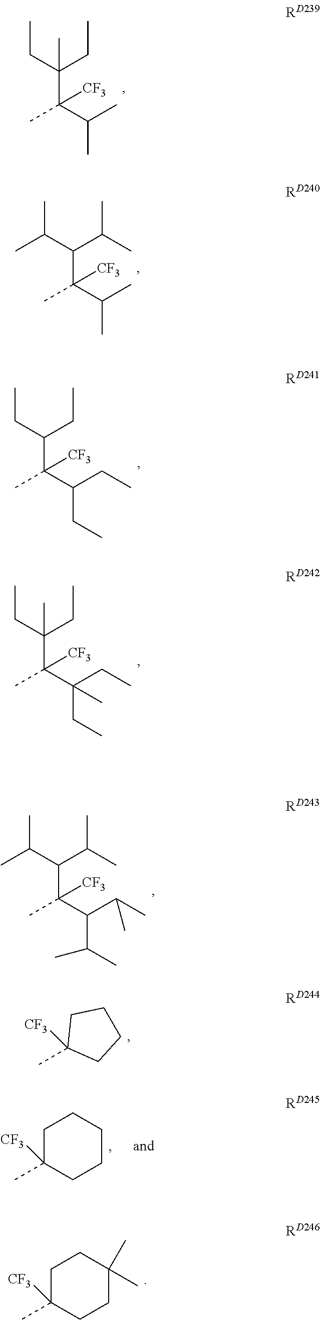

13. The compound of claim 1, wherein the compound is selected from the group consisting of:

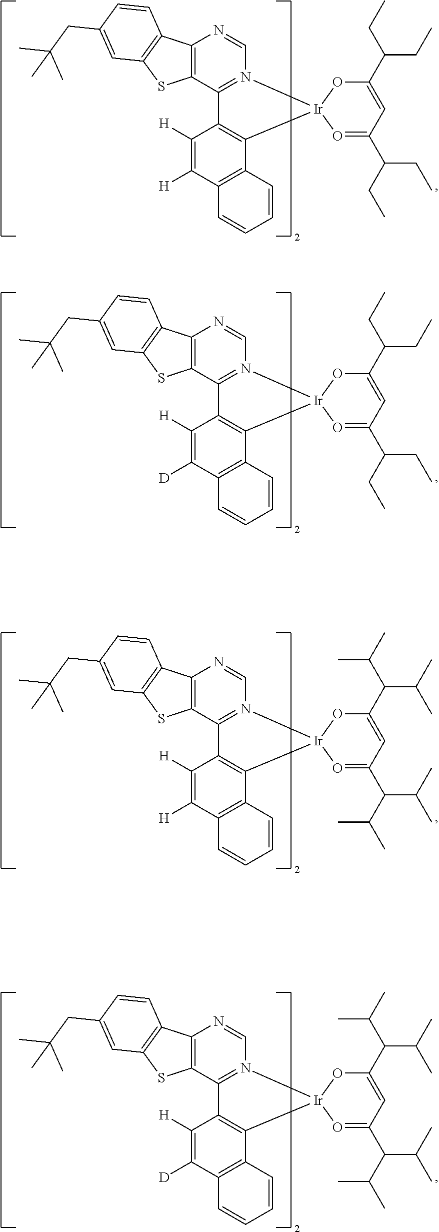

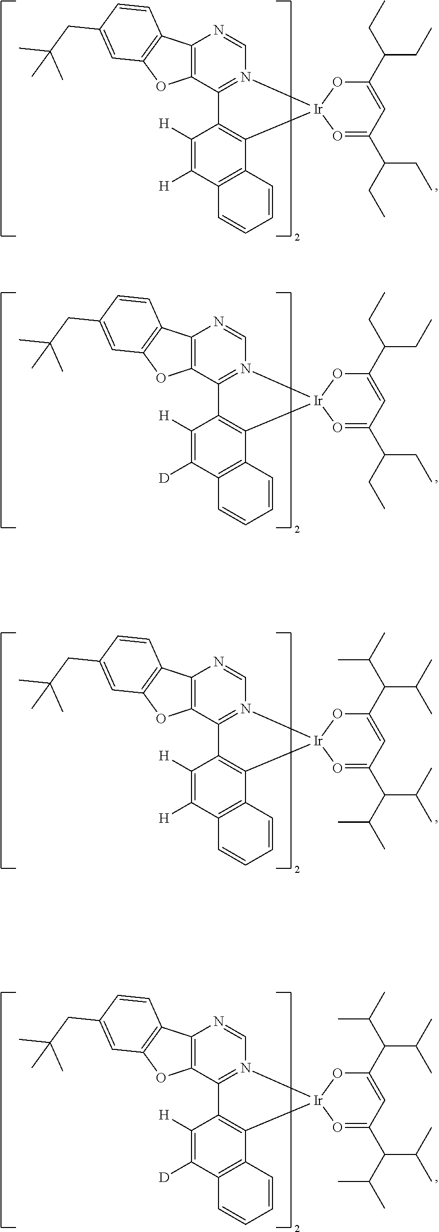

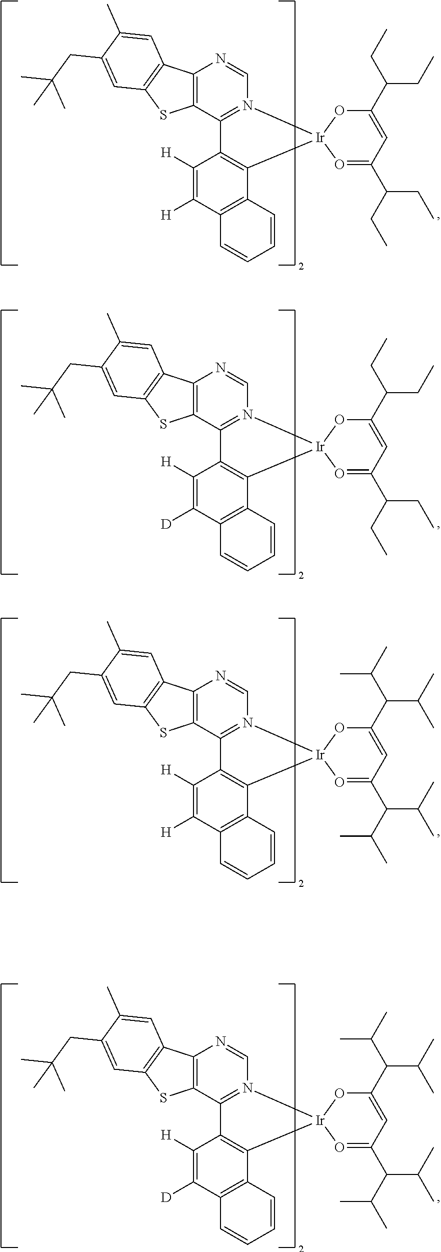

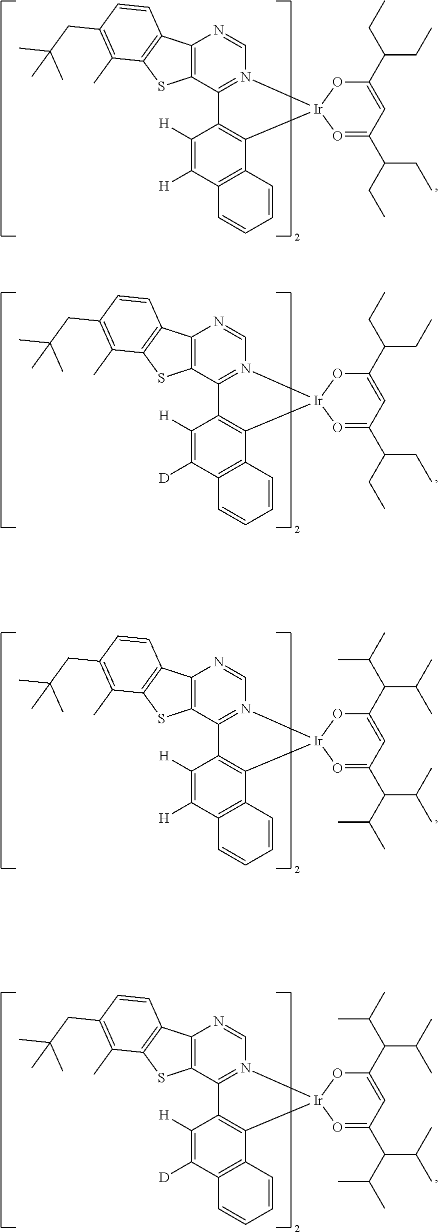

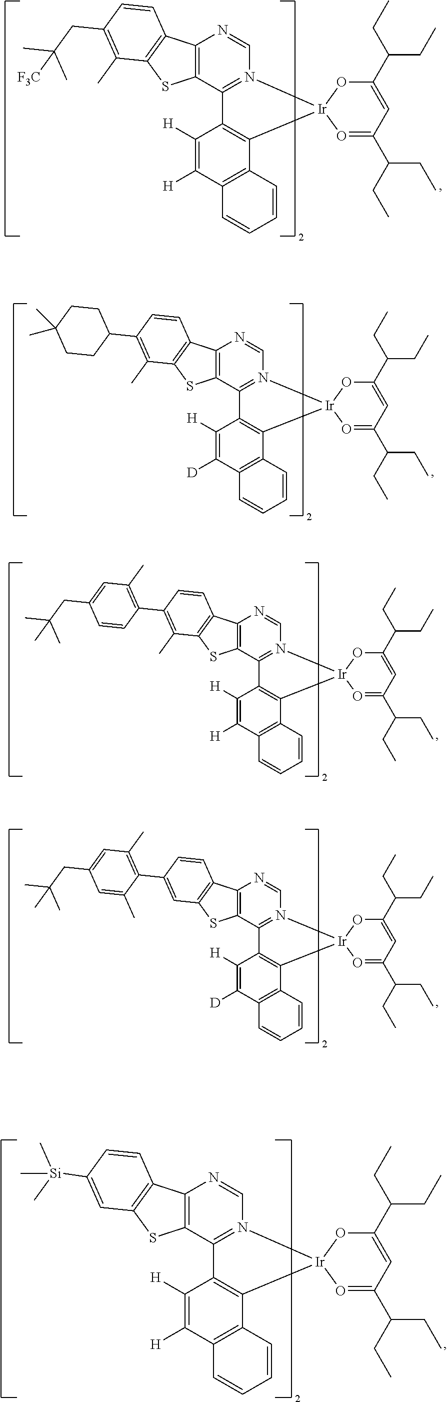

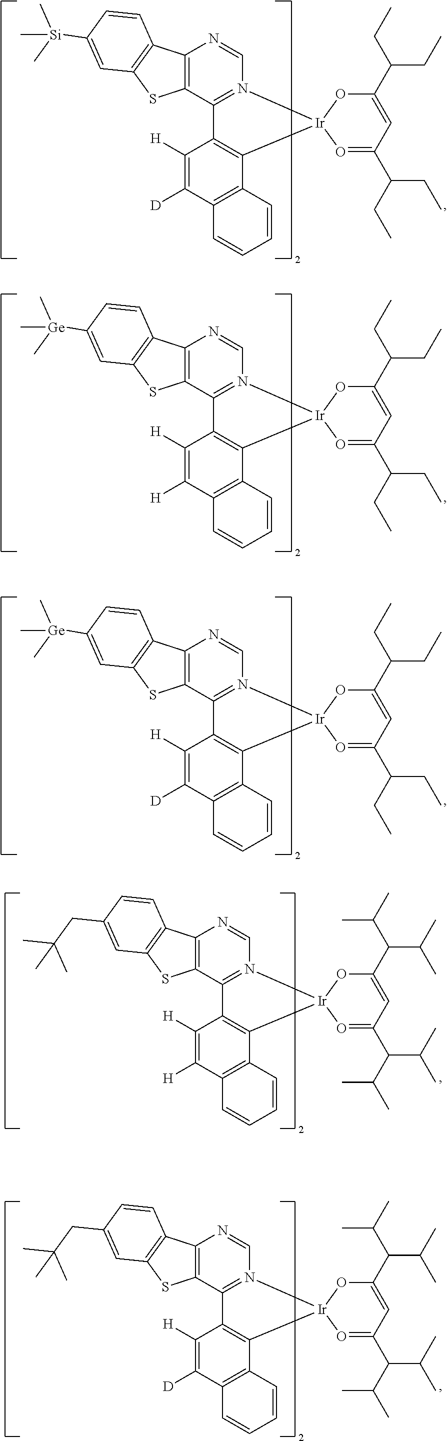

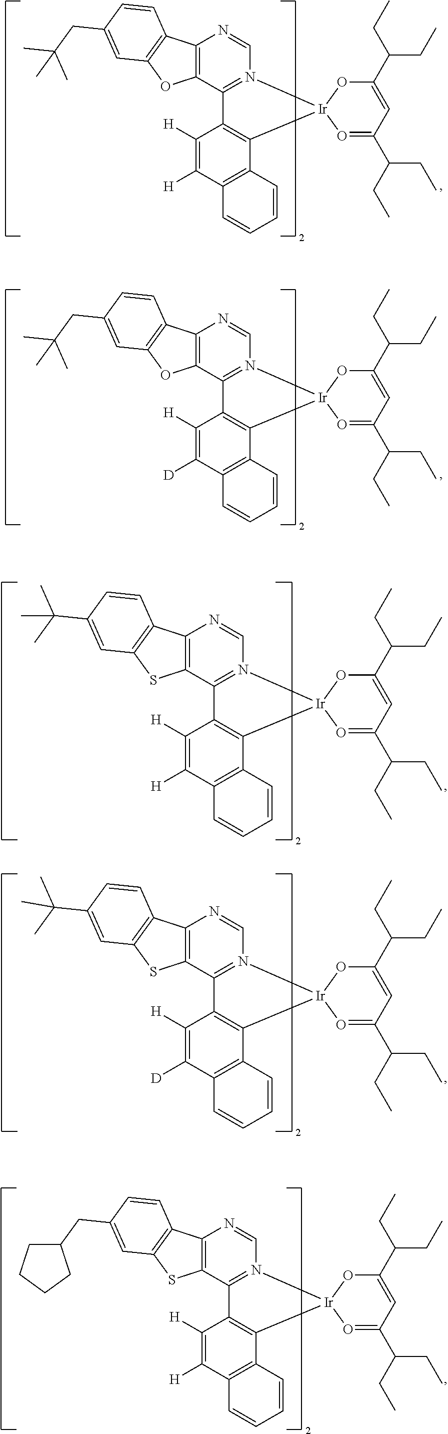

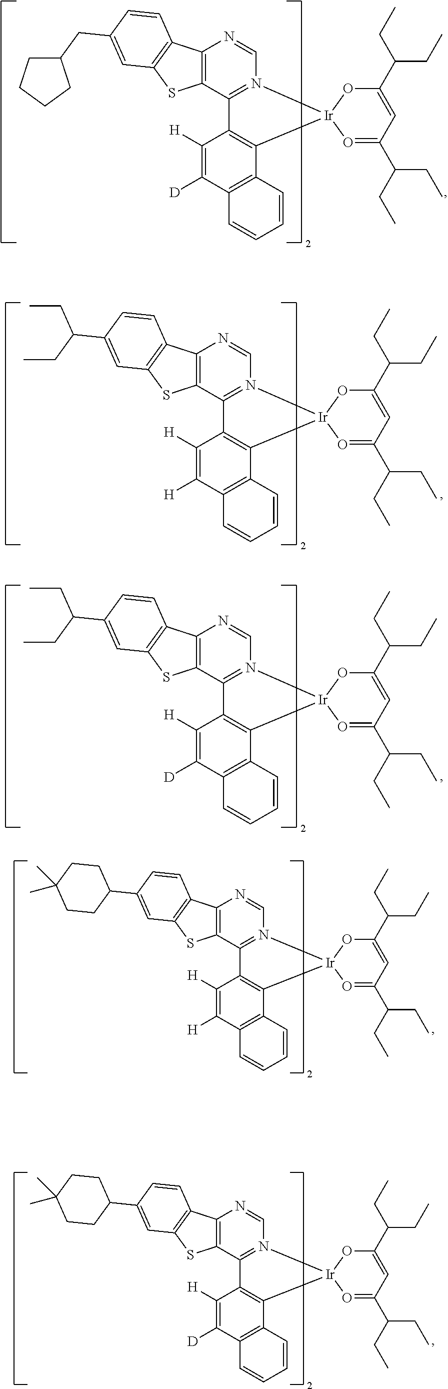

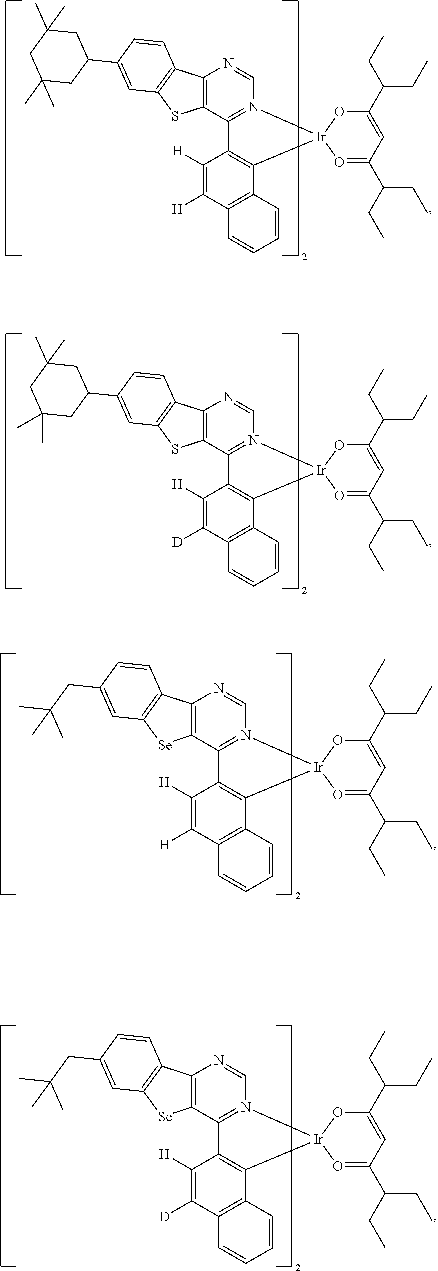

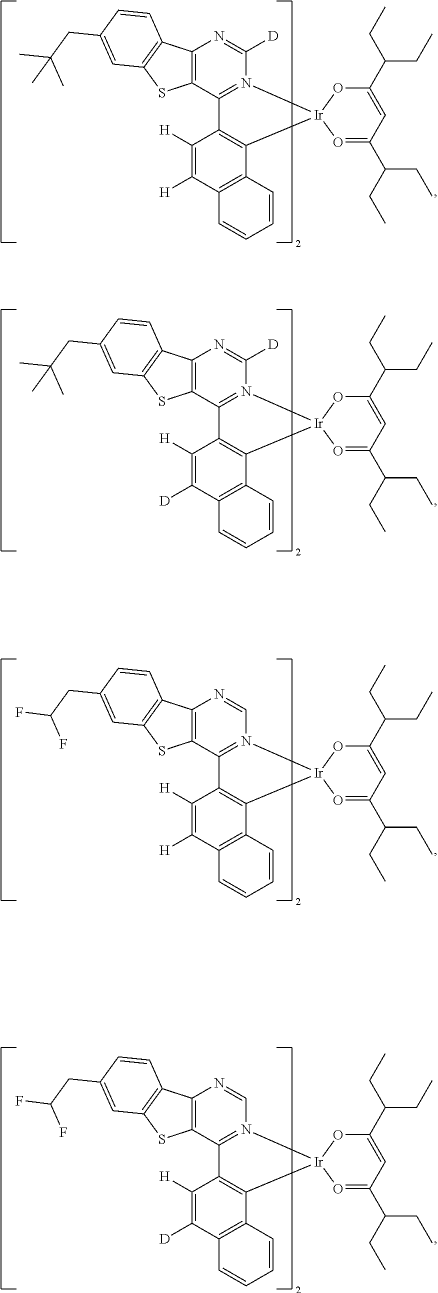

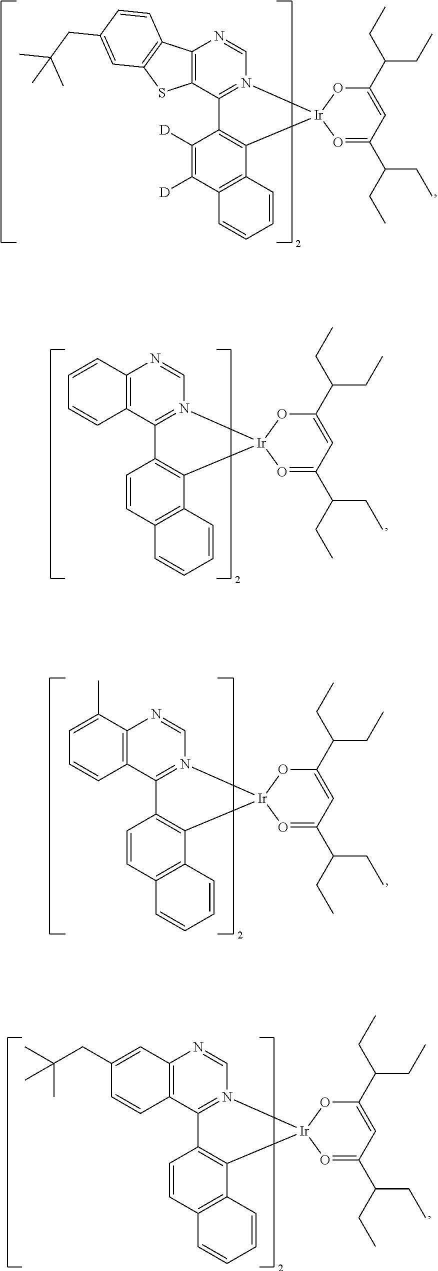

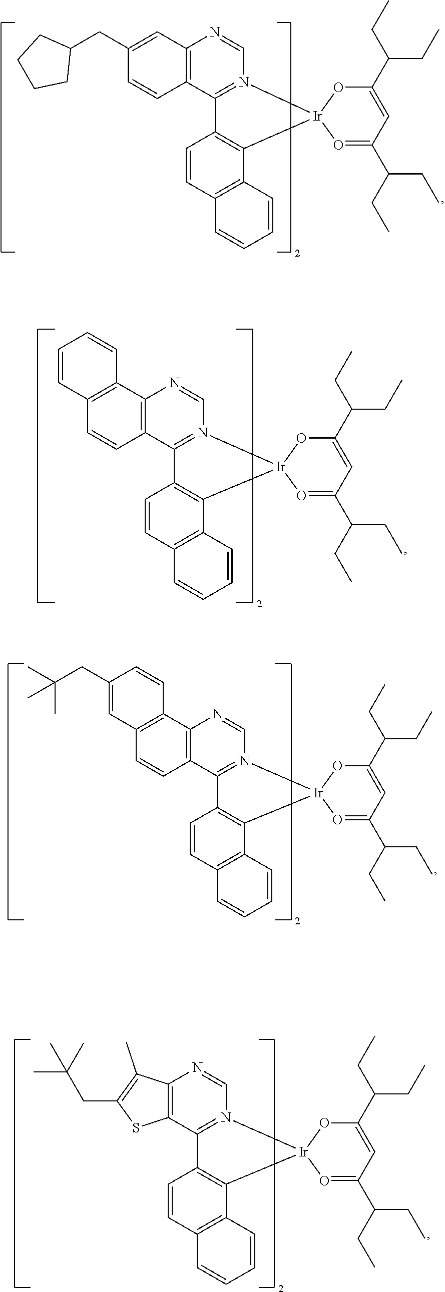

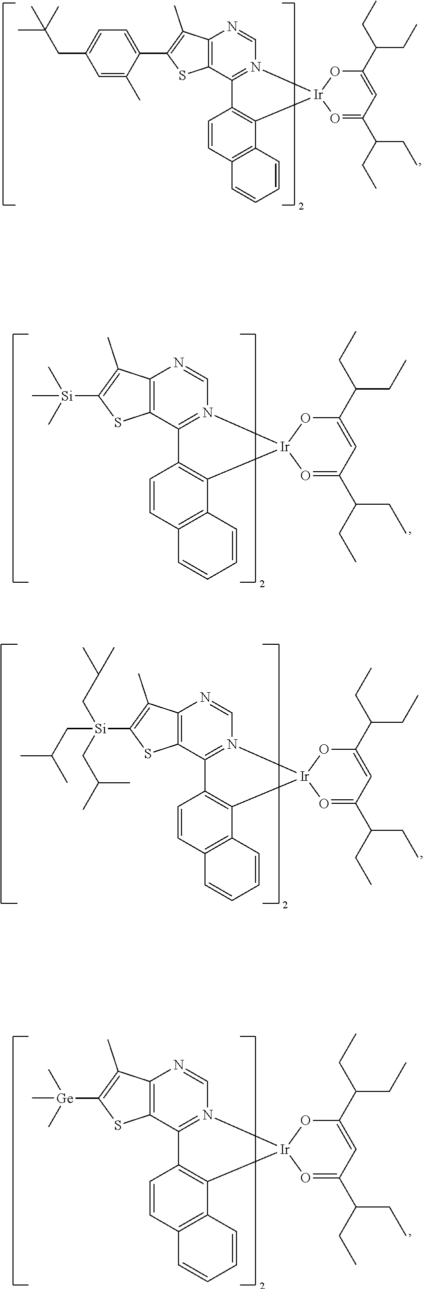

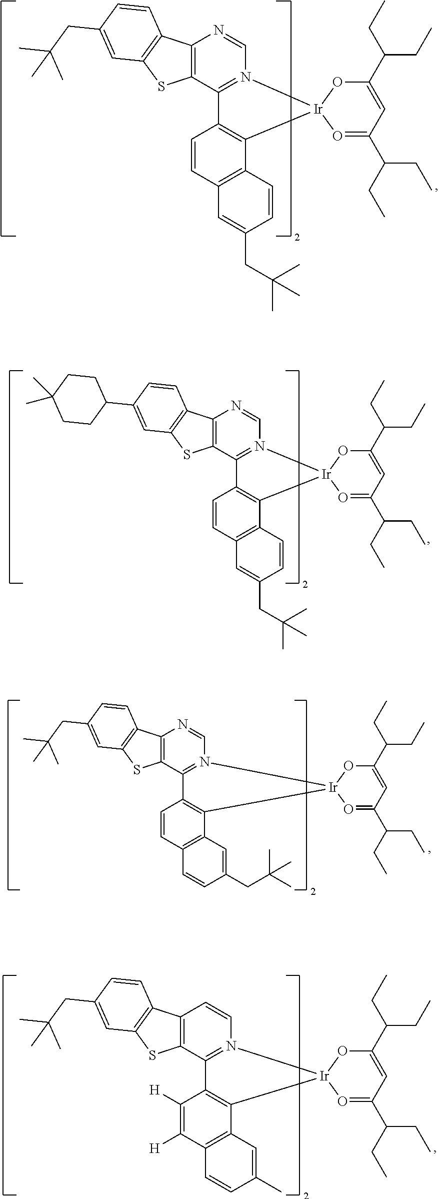

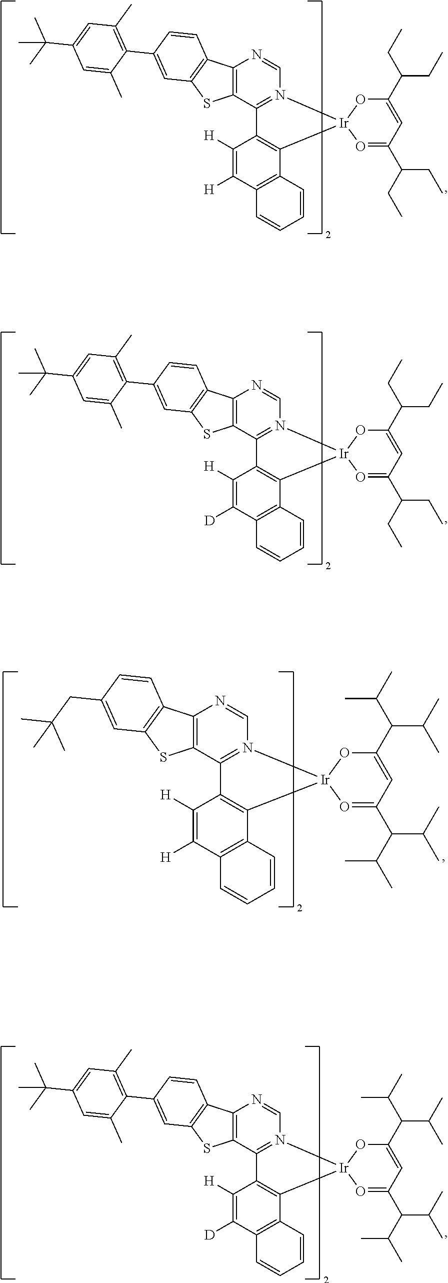

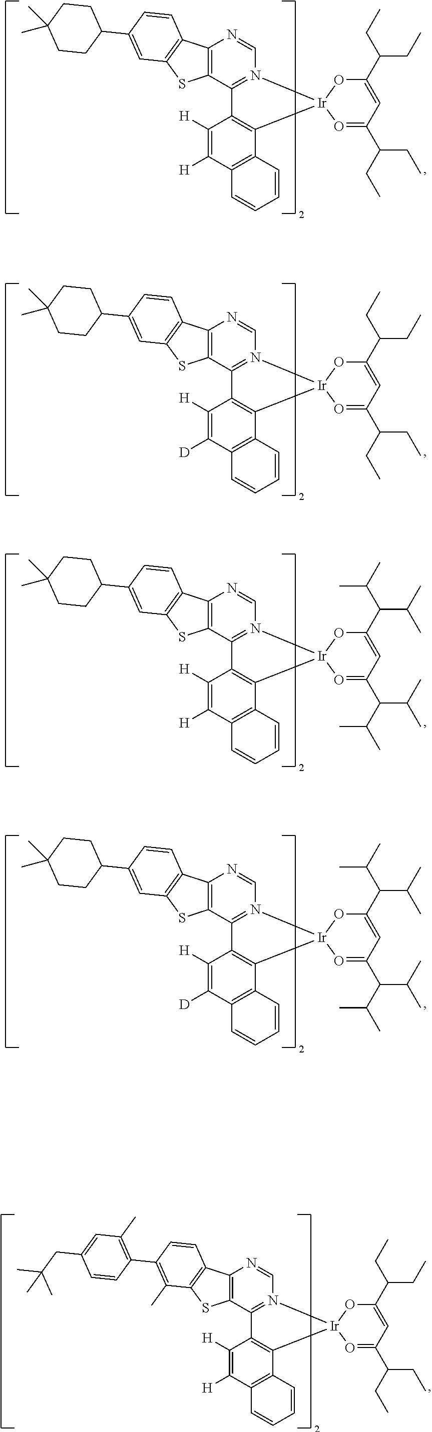

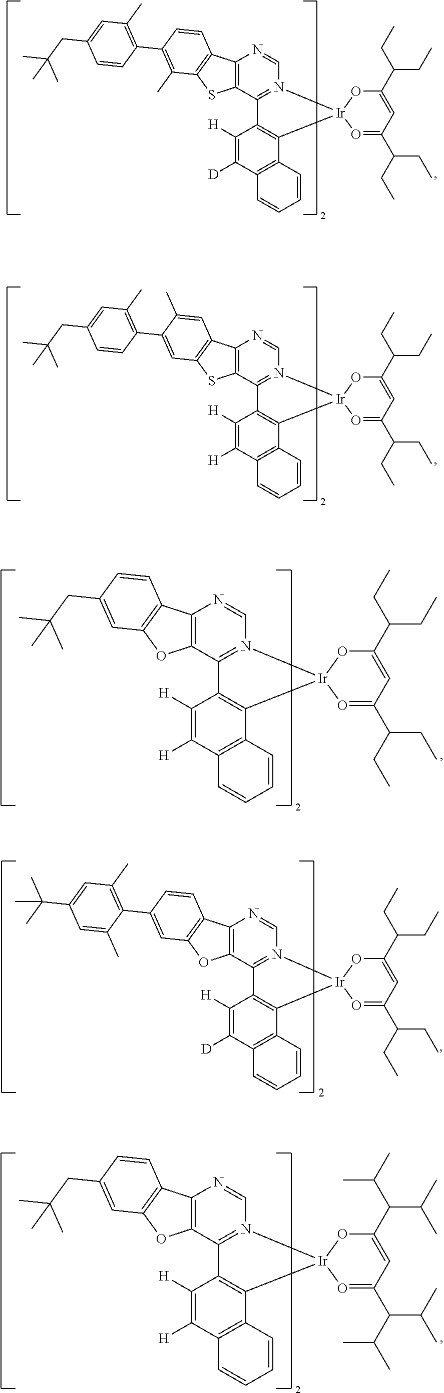

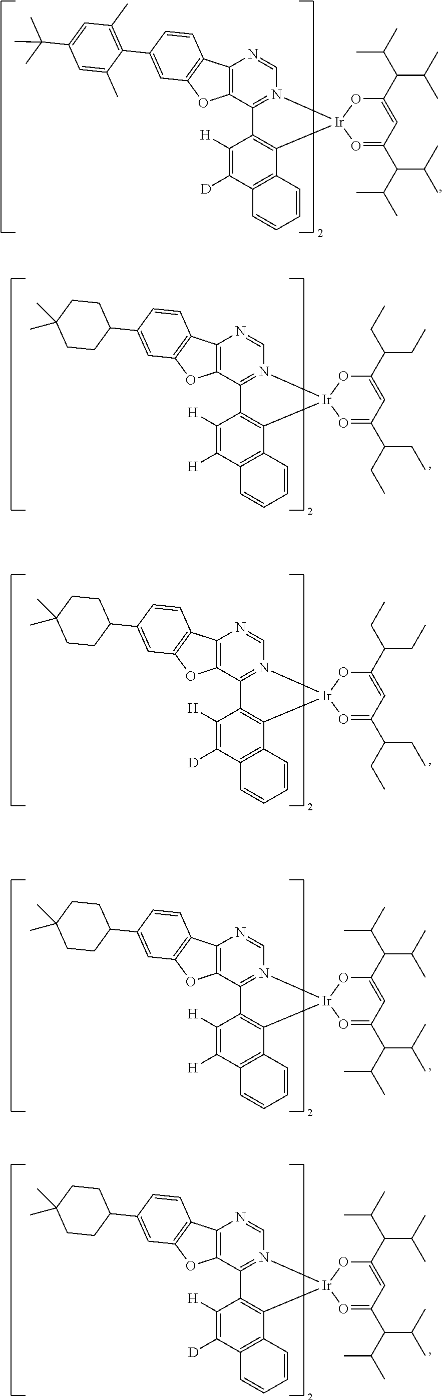

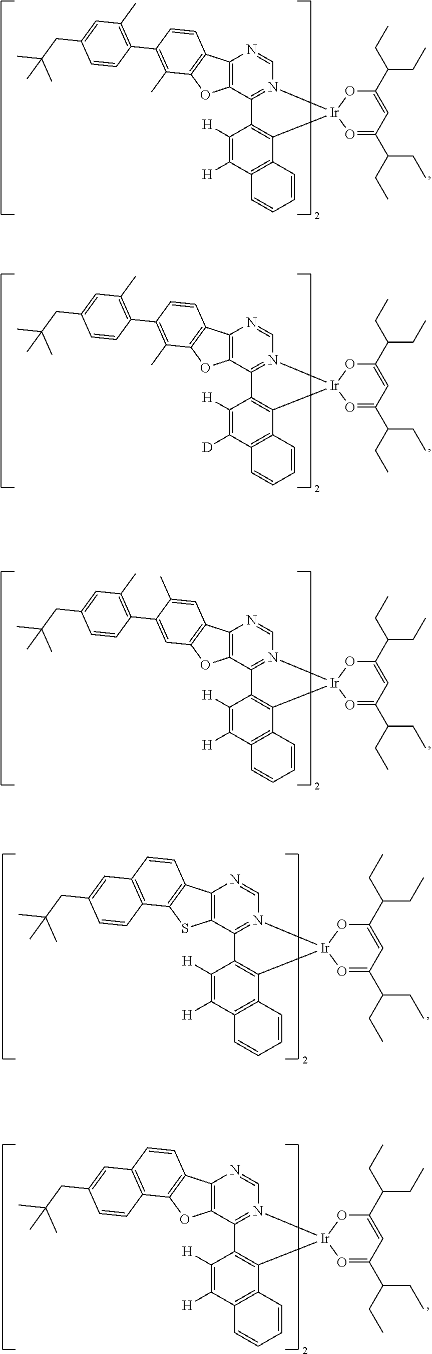

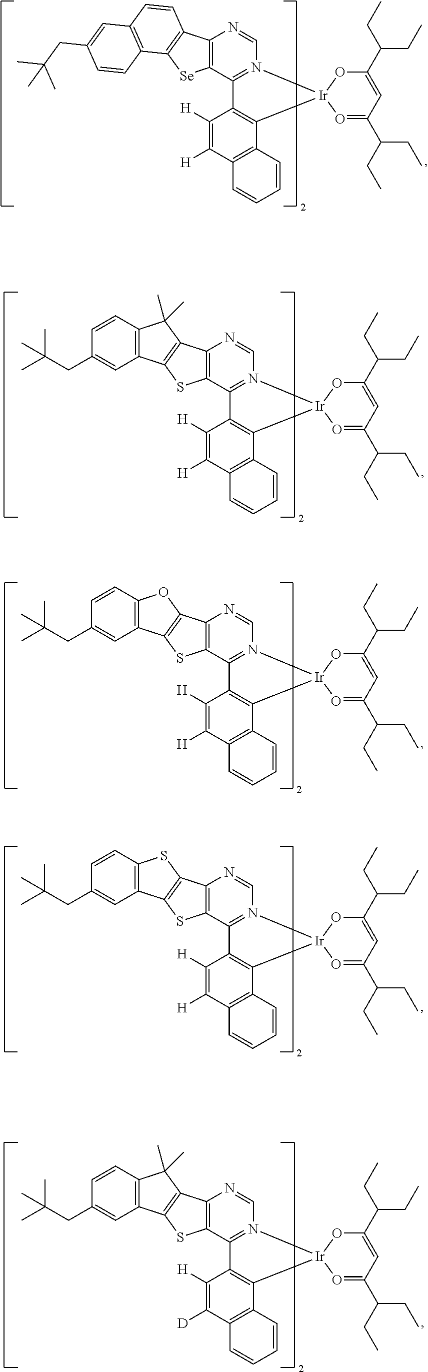

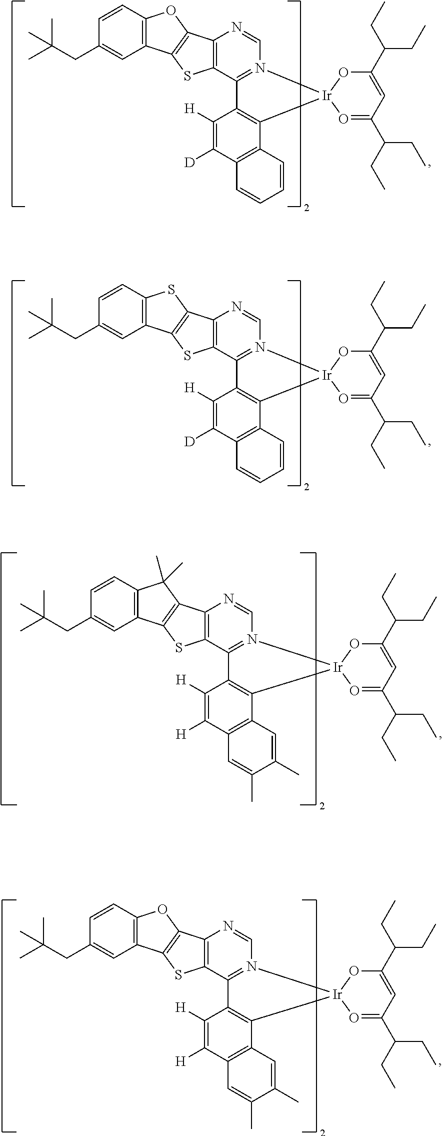

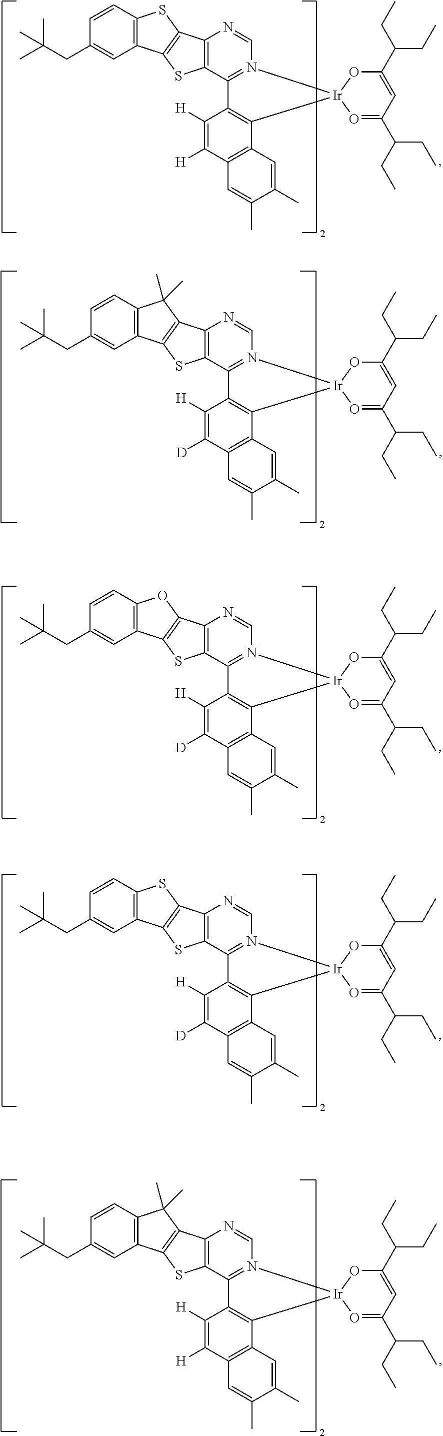

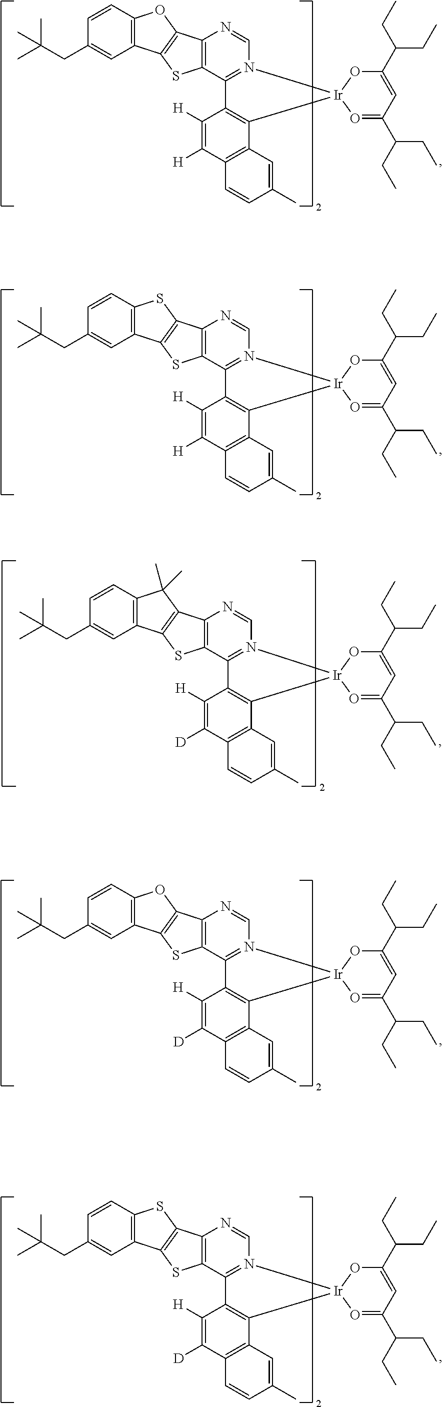

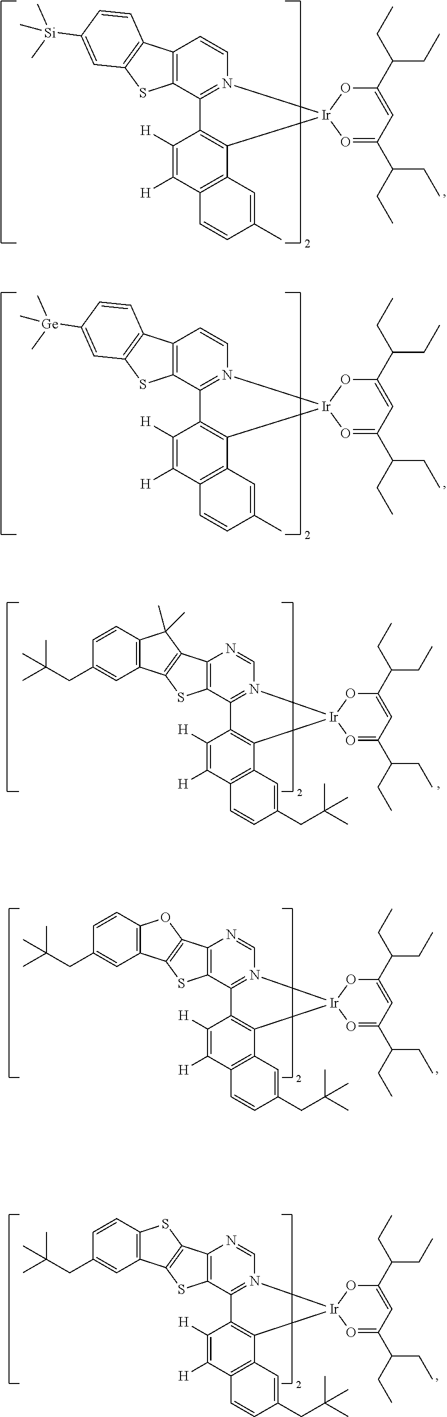

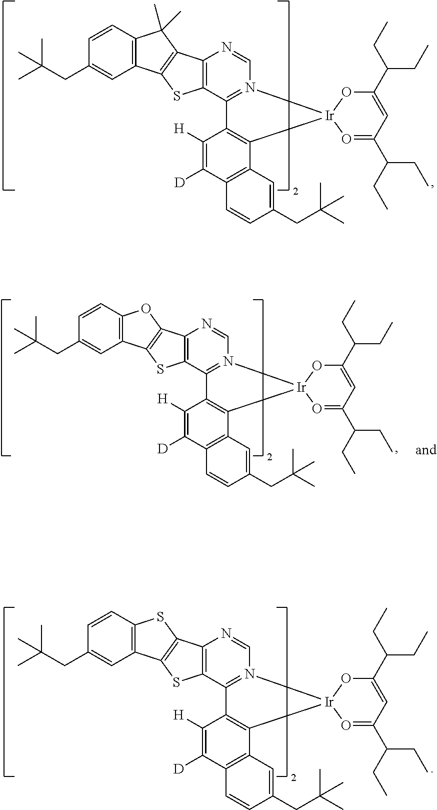

14. The compound of claim 9, wherein the compound has the Formula II: 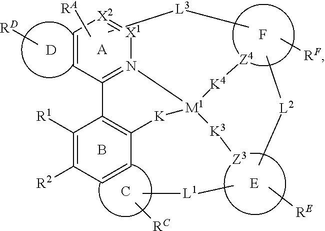
wherein:
M¹ is Pd or Pt;
moieties E and F are each independently monocyclic or polycyclic ring structure, wherein the monocyclic ring or each ring of the polycyclic fused ring system is independently a 5-membered to 10-membered carbocyclic or heterocyclic ring;
Z³ and Z⁴ are each independently C or N;
K, K³ and K⁴ are each independently selected from the group consisting of a direct bond, O, and S, wherein at least two of them are direct bonds;
L¹, L², and L³ are each independently absent or selected from the group consisting of a direct bond, BR, BRR′, NR, PR, P(O)R, O, S, Se, C═O, C═S, C═Se, C═NR, C═CRR′, S═O, SO₂, CR, CRR′, SiRR′, GeRR′, alkylene, cycloalkyl, aryl, cycloalkylene, arylene, heteroarylene, and combinations thereof, wherein at least one of L¹ and L² is present;
R^{E} and R^{F} each independently represents zero, mono, or up to a maximum allowed number of substitutions;
each of R, R′, R^{E}, and R^{F} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
two adjacent R^{A}, R^{B}, R^{C}, R^{E}, and R^{F} can be joined or fused together to form a ring.

15. The compound of claim 14, wherein the compound is selected from the group consisting of compounds having the formula of Pt(L_{A′})(Ly): 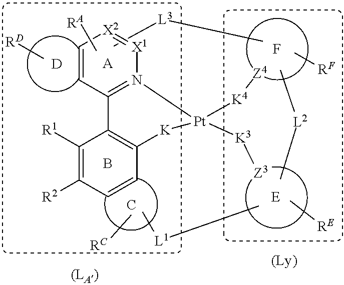
wherein L_{A′} is selected from the group consisting of: 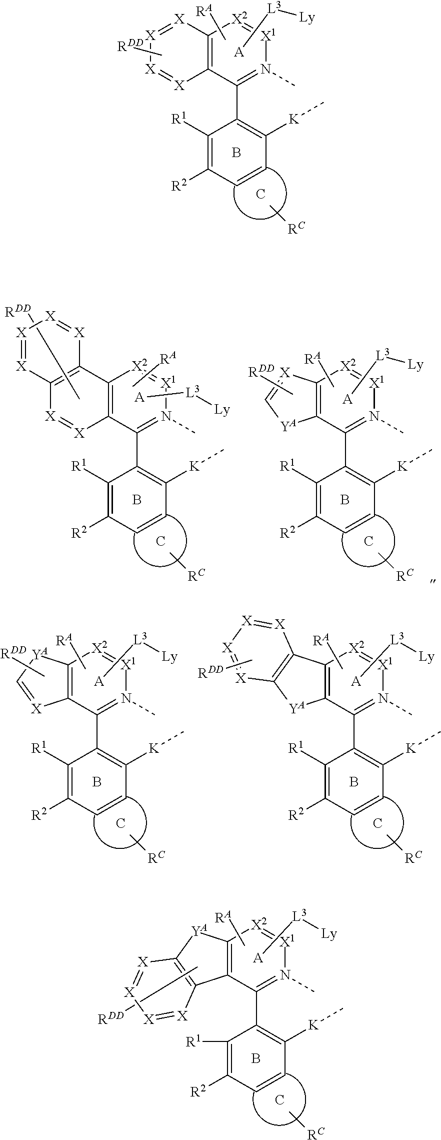 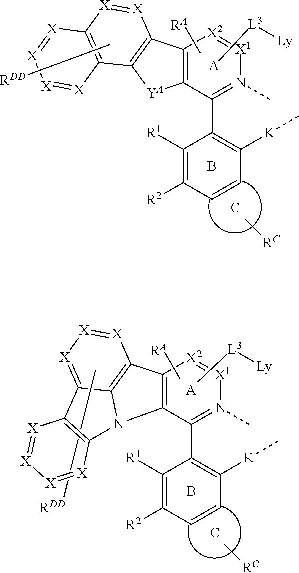
wherein L_{y} is selected from the group consisting of: 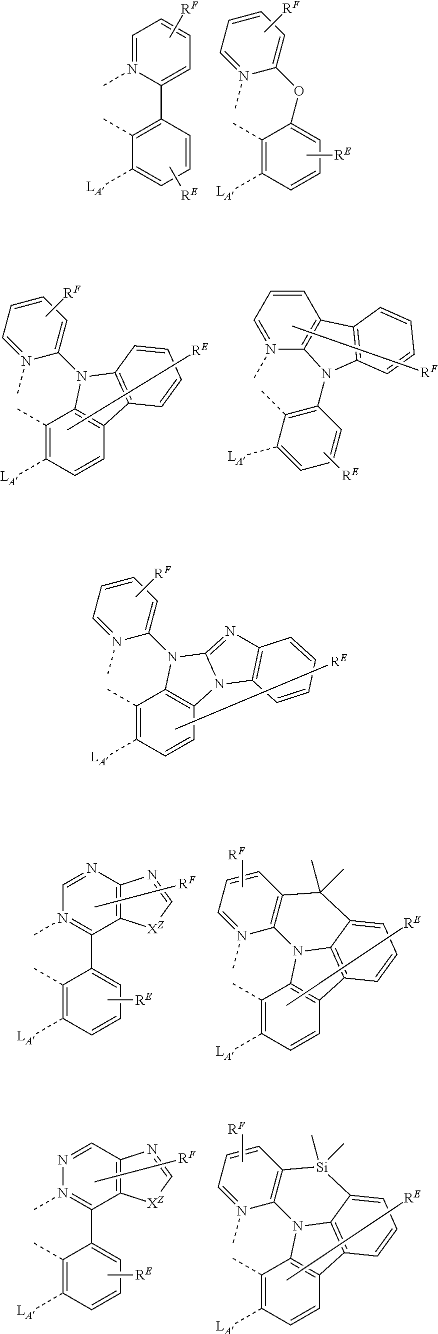 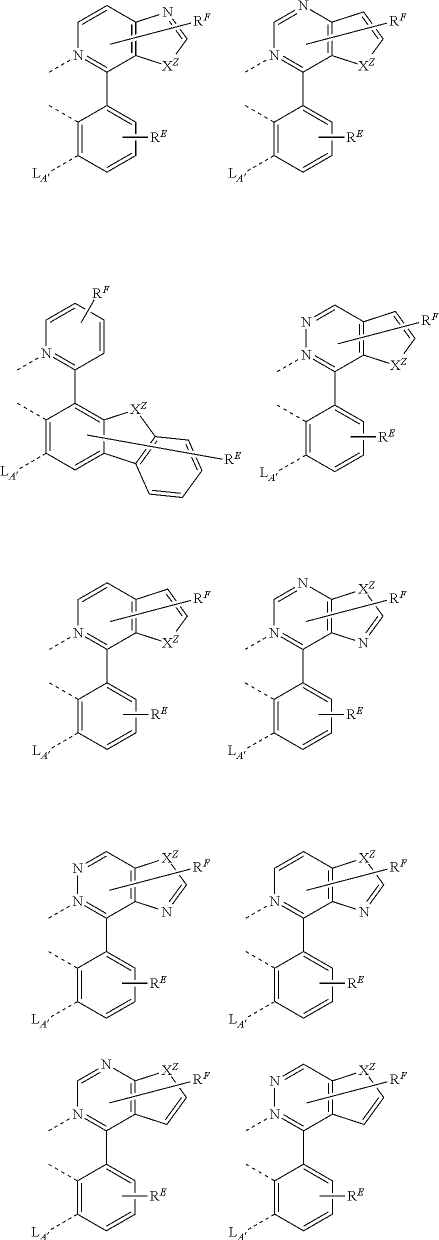 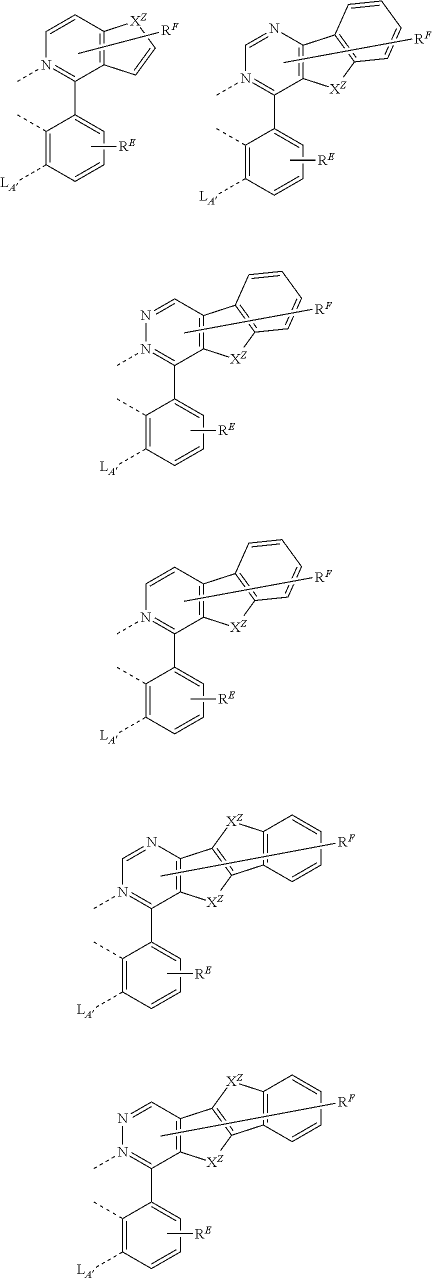 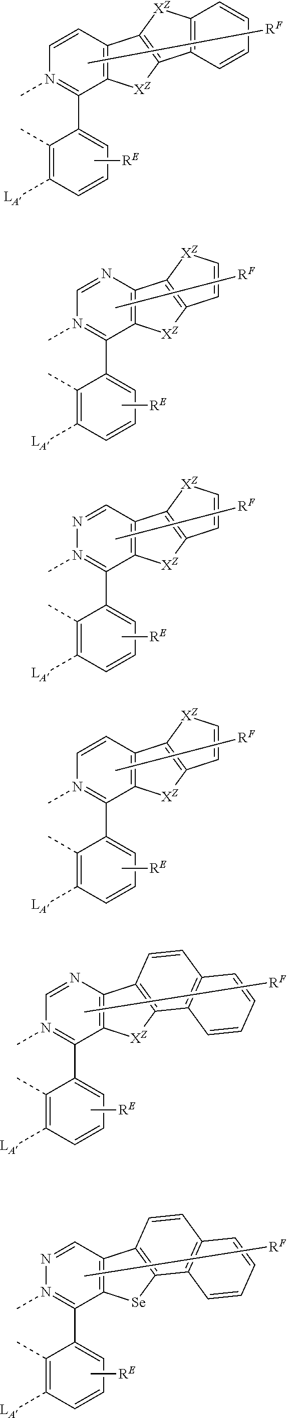 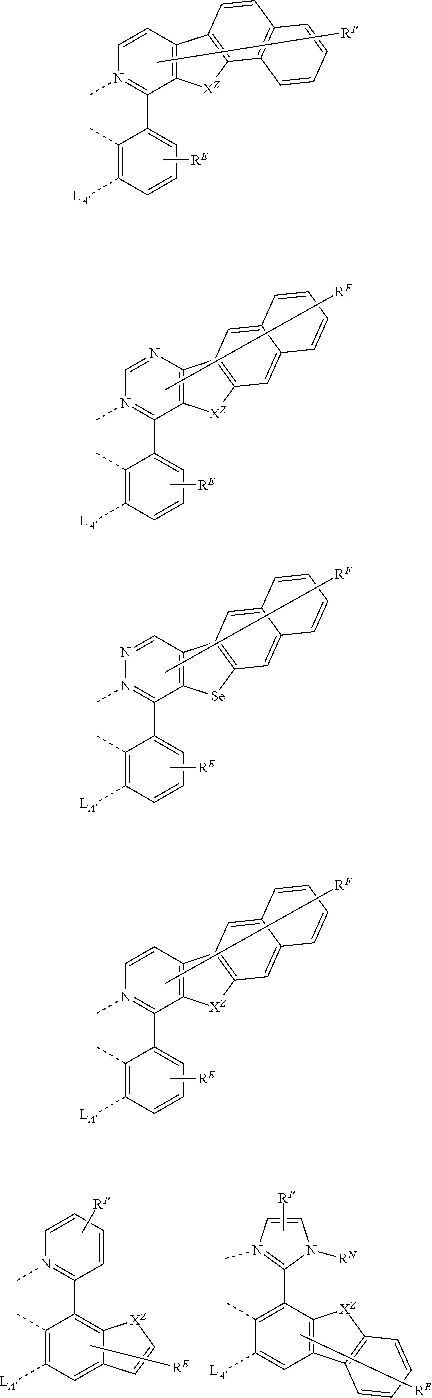 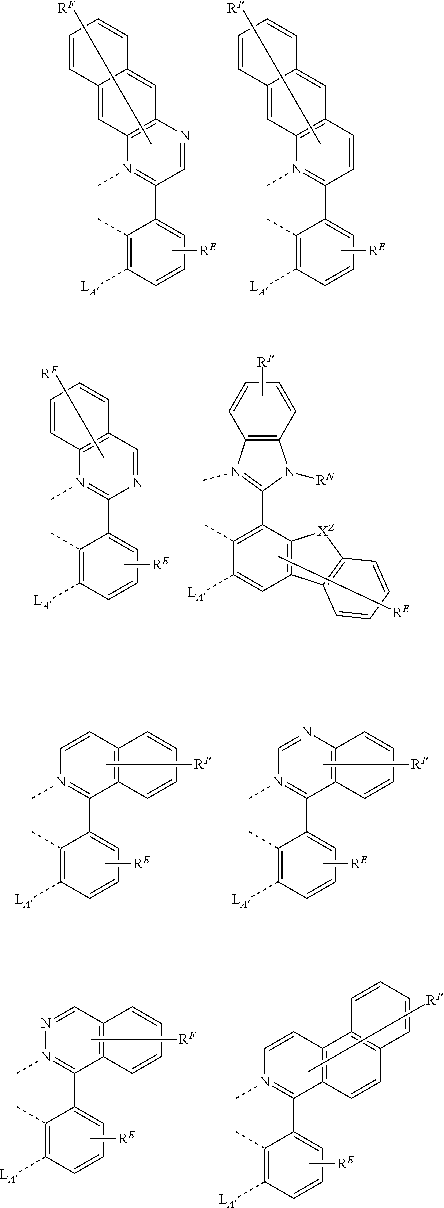 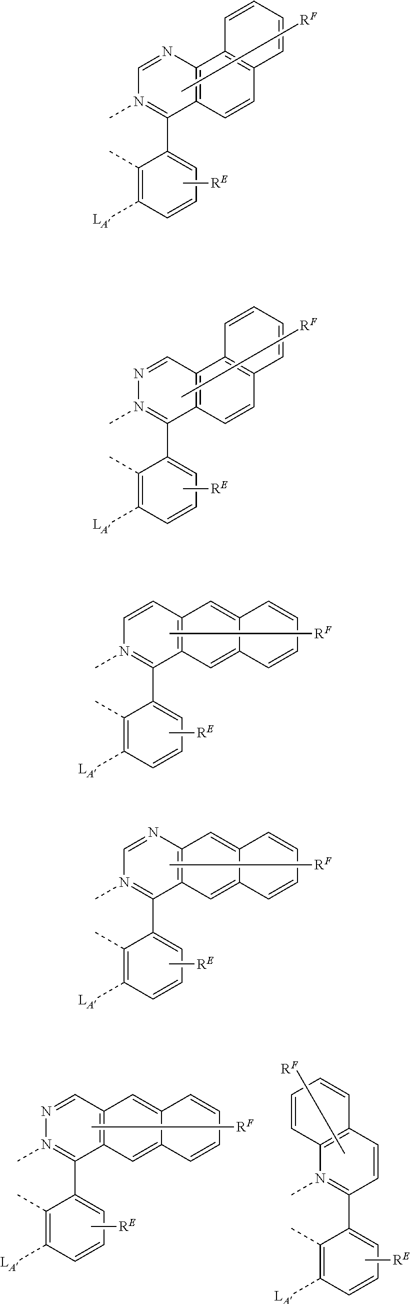 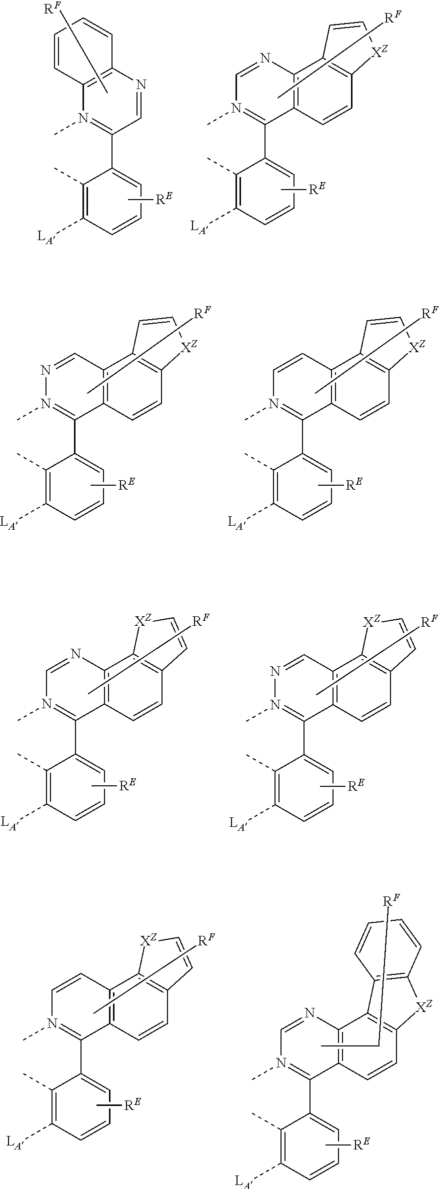 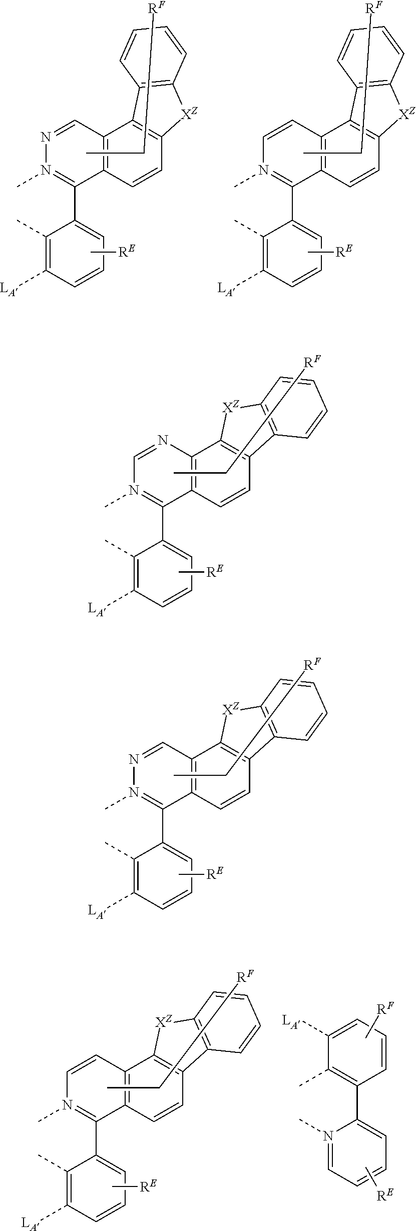 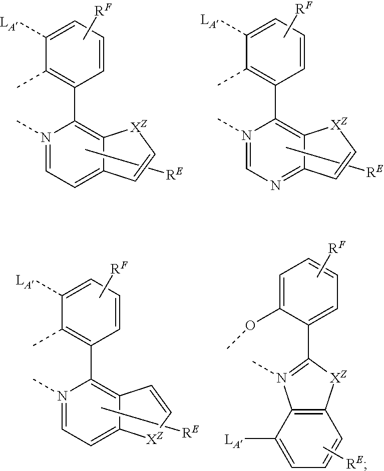
wherein:
for each occurrence, X is independently C or N;
Y^{A} and each occurrence of X^{Z} is independently selected from the group consisting of BR, BRR′, NR, PR, P(O)R, O, S, Se, C═O, C═S, C═Se, C═NR, C═CRR′, S═O, SO₂, CR, CRR′, SiRR′, and GeRR′;
R^{DD} represents mono to the maximum allowable substitution, or no substitution;
each R, R′, R^{N}, and R^{DD} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and
any two substituents may be optionally joined or fused to form a ring.

16. The compound of claim 14, wherein the compound is selected from the group consisting of the compounds having the formula of Pt(L_{A′})(Ly): 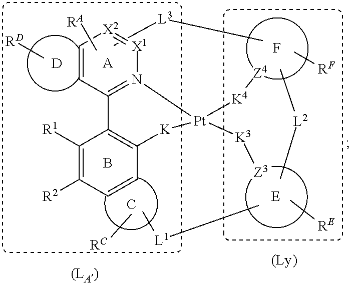
wherein L_{A′} is selected from the group consisting of L_{A′i′}(R^{EA})(R^{EB})(R^{EC})(R^{ED})(R^{EE})(P), wherein i′ is an integer from 1 to 4, each of R^{EA}, R^{EB}, R^{EC}, R^{ED}, and R^{EE} is independently selected from the group consisting of R¹ to R¹⁵⁰, and P is an integer from 1 to 5; wherein L_{A′1}(R¹)(R¹)(R¹)(R¹)(R¹)(1) to L_{A′4}(R¹⁵⁰)(R¹⁵⁰)(R¹⁵⁰)(R¹⁵⁰)(R¹⁵⁰)(5) have the structures defined in LIST 14 defined herein;
wherein Ly is selected from the group consisting of L_{Y1}(R^{FA})(R^{FB}), wherein w is an integer from 1 to 4, and each of R^{FA} and R^{FB} is independently selected from the group consisting of R¹ to R¹⁵⁰, wherein L_{Y1}(R¹)(R¹) to L_{Y4}(R¹⁵⁰)(R¹⁵⁰) have the structure defined in LIST 15 defined herein;
wherein each of R¹ to R¹⁵⁰ has the structure define as follows: 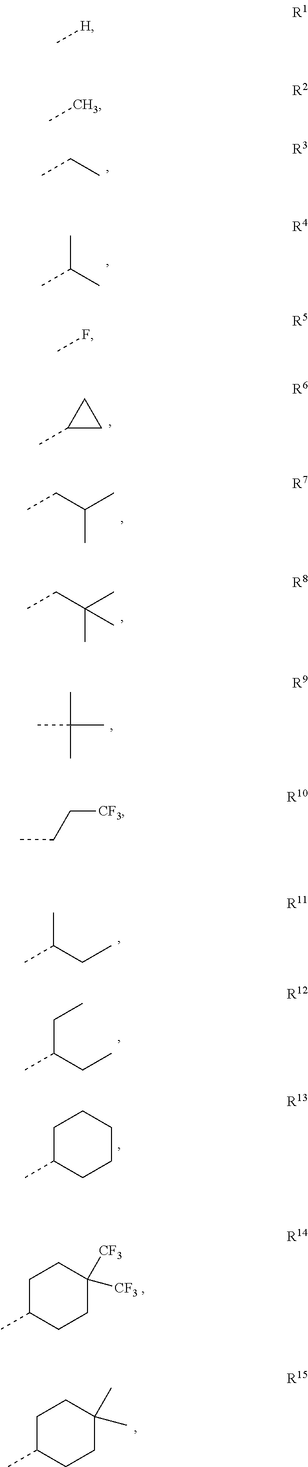 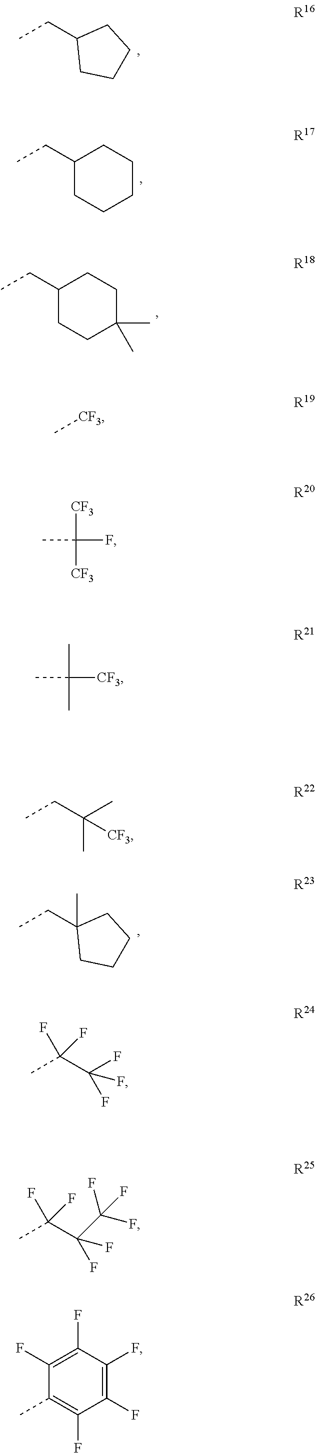 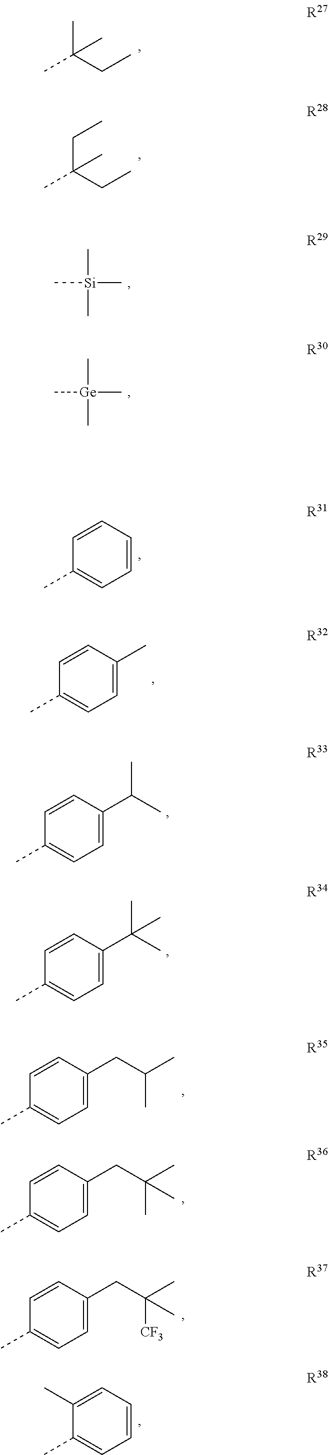 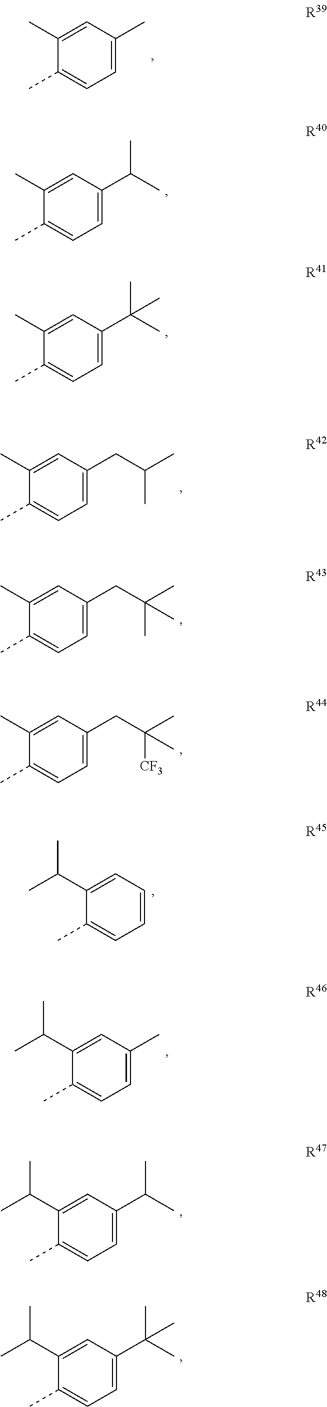 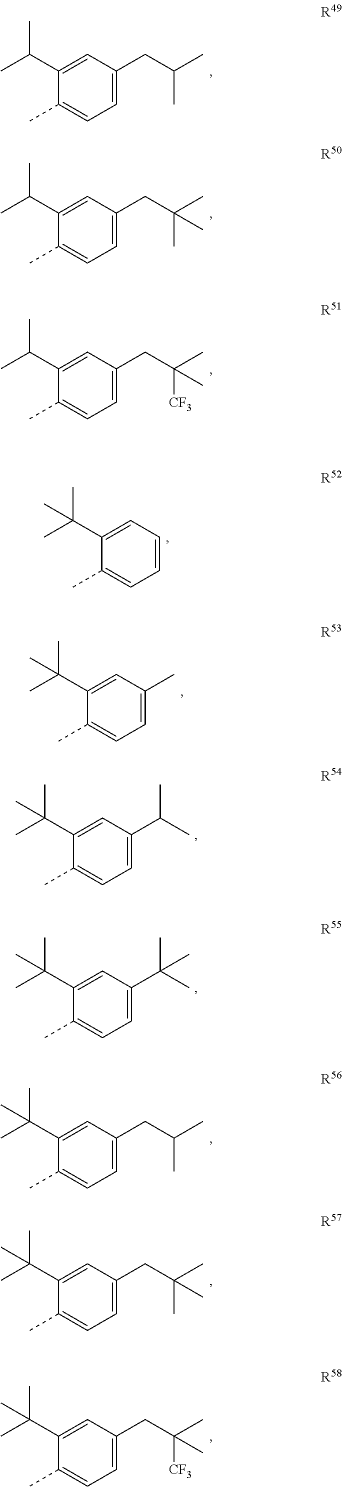 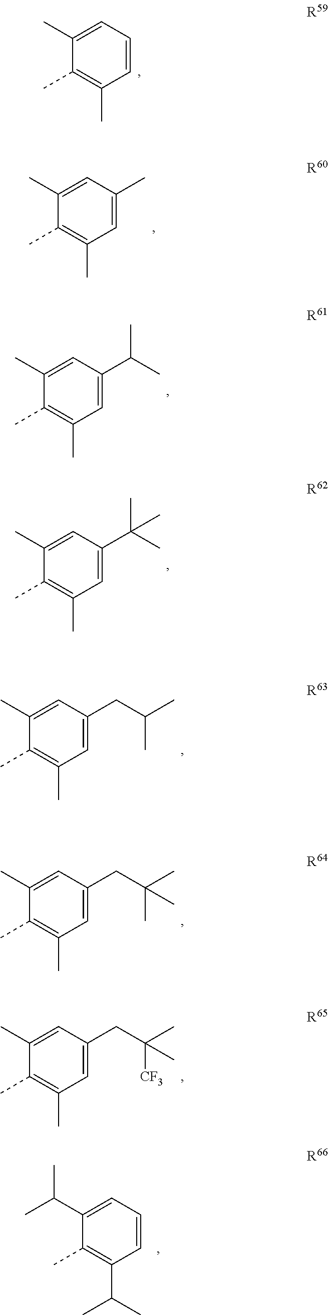 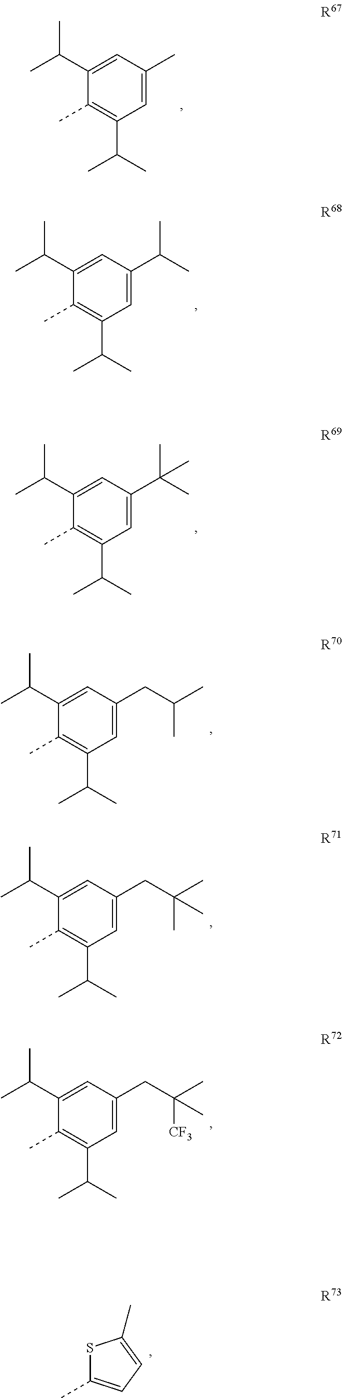 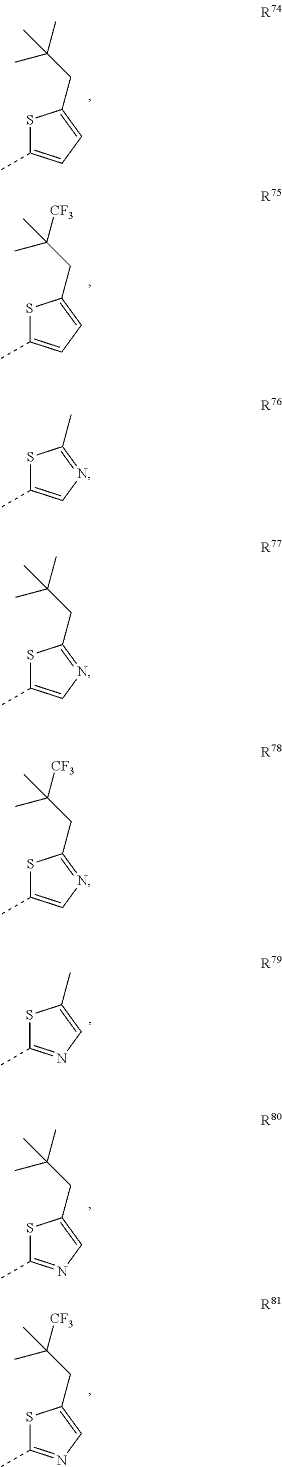 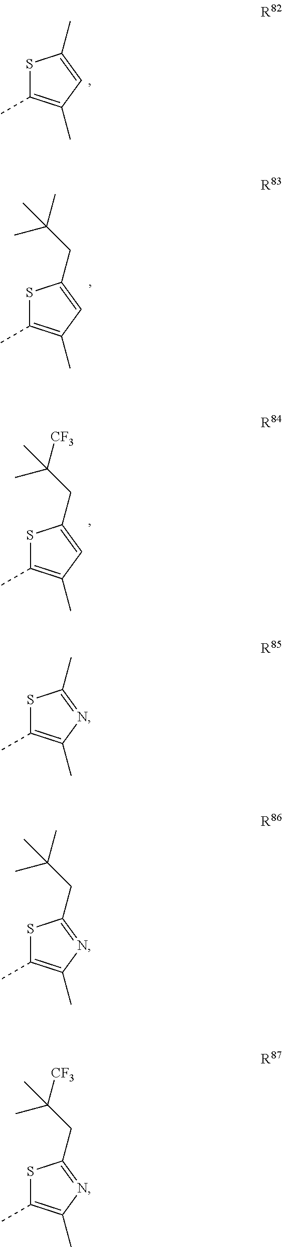 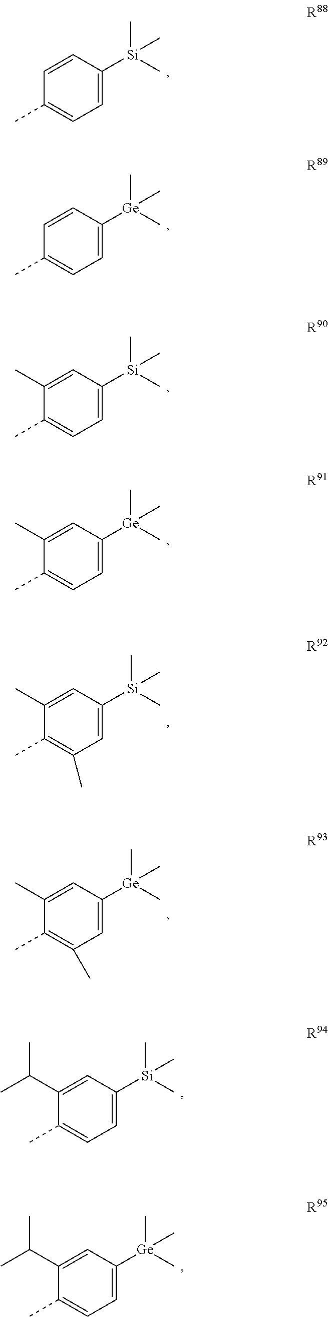 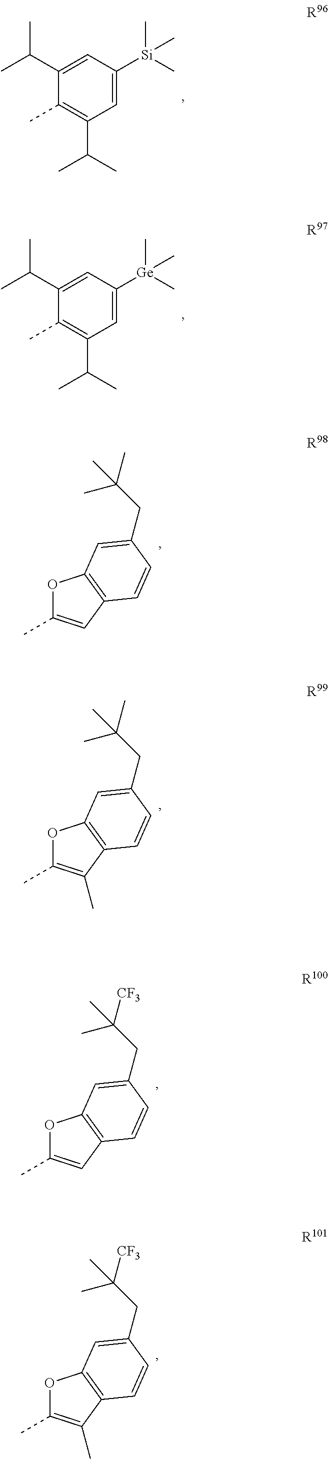 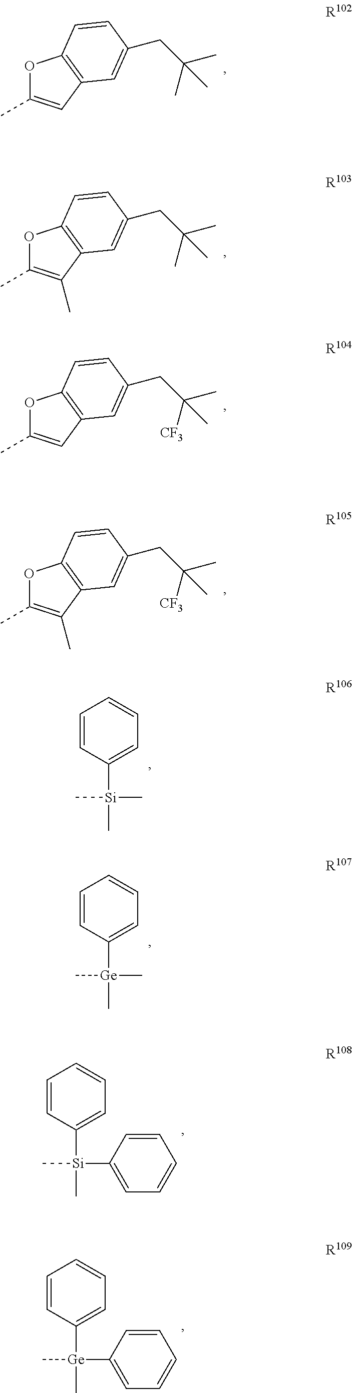 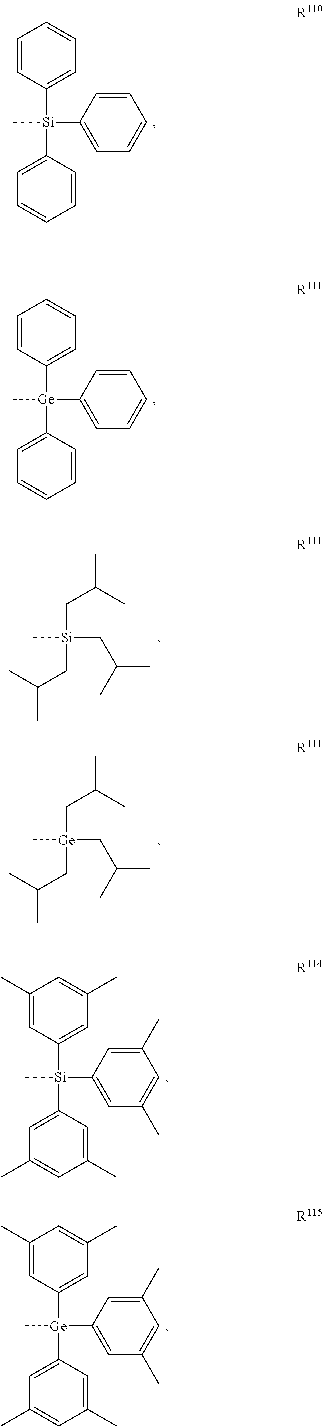 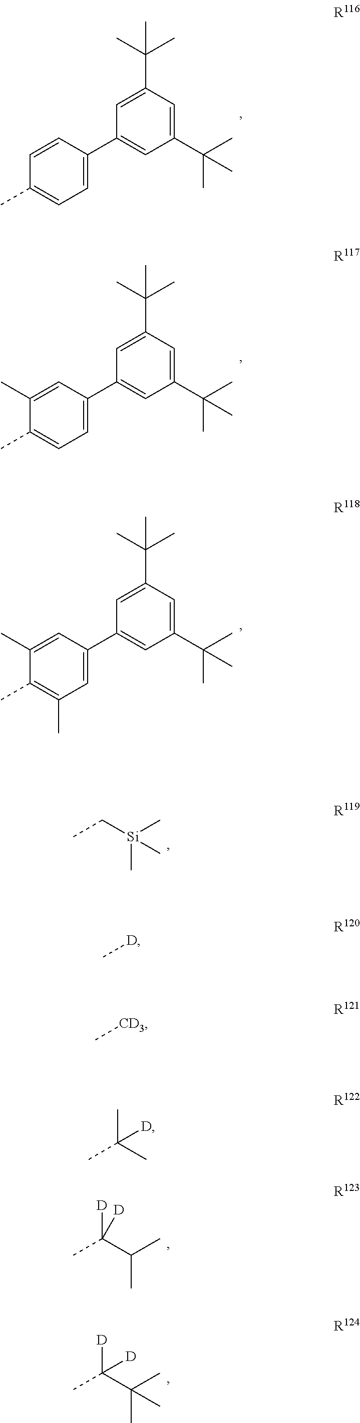 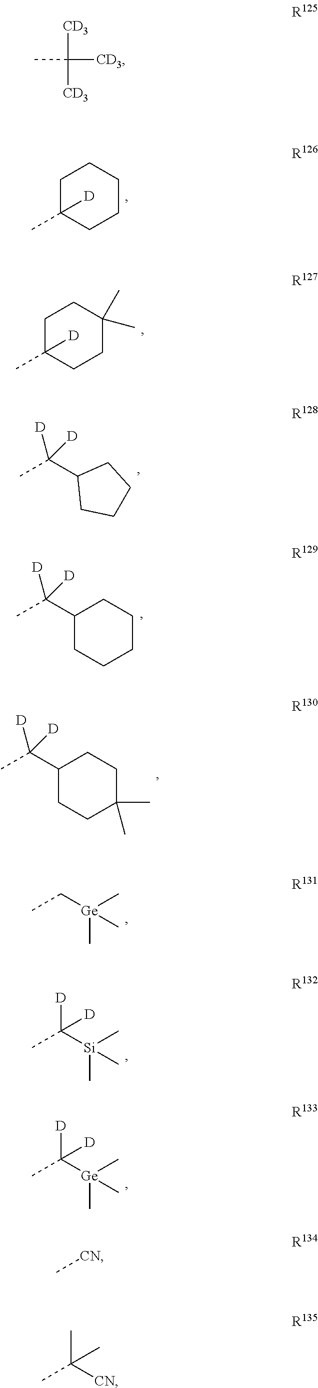 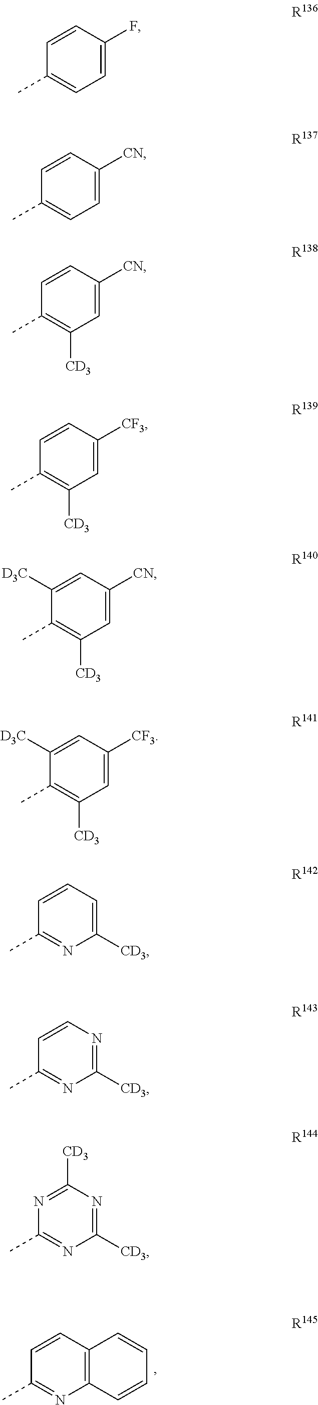 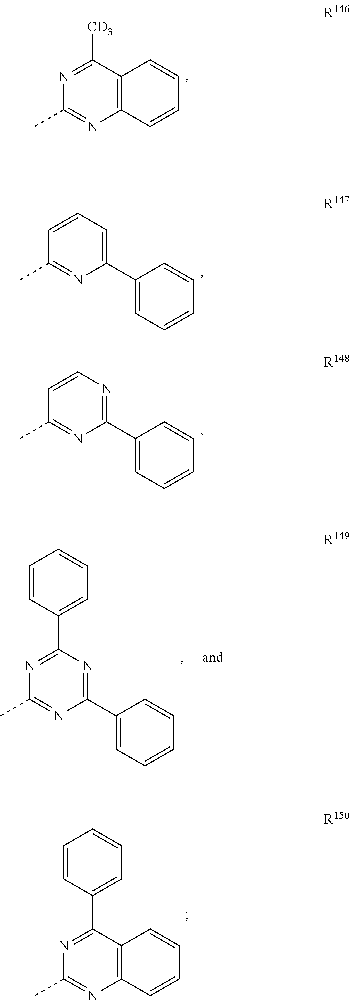
and
wherein, for each of P=1 to P=5, L³ has the meaning defined as follows:

| P = 1 | P = 2 | P = 3 | P = 4 | P = 5 |
|---|---|---|---|---|
| L³ = direct bond | L³ = O | L³ = S | L³ = Se | L³ = N(CH₃). |

17. An organic light emitting device (OLED) comprising:
an anode;
a cathode; and
an organic layer disposed between the anode and the cathode, wherein the organic layer comprises a compound according to claim 1.

18. The OLED of claim 17, wherein the host is selected from the group consisting of: 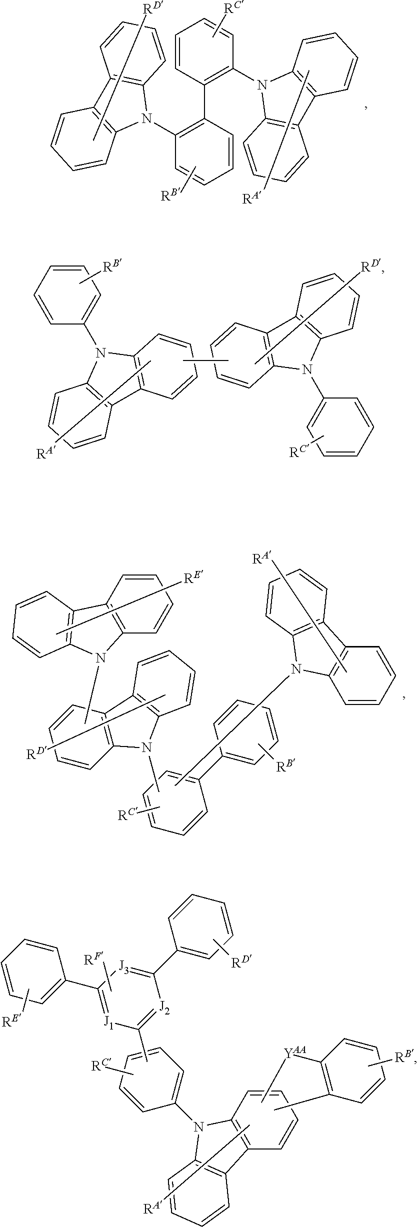 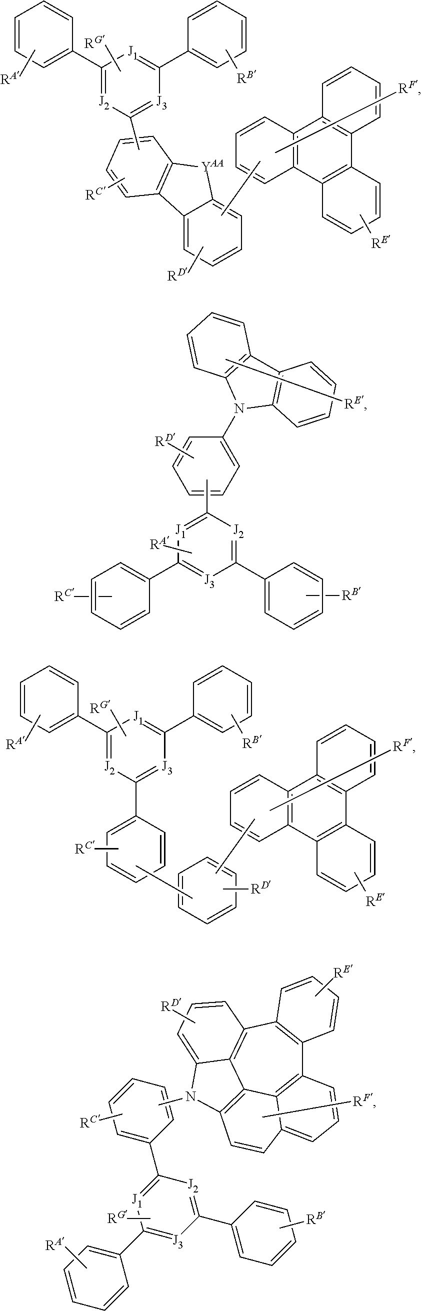 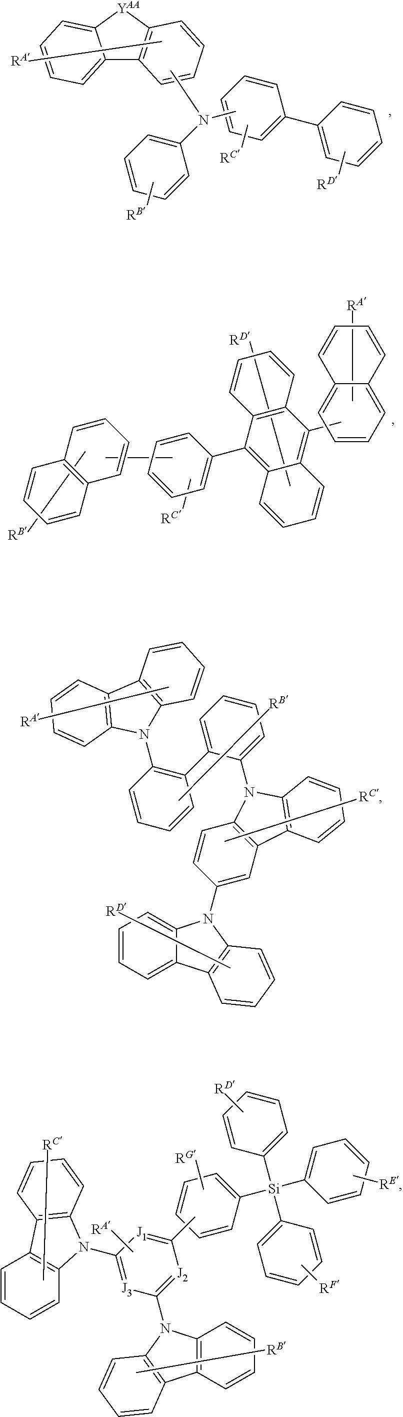 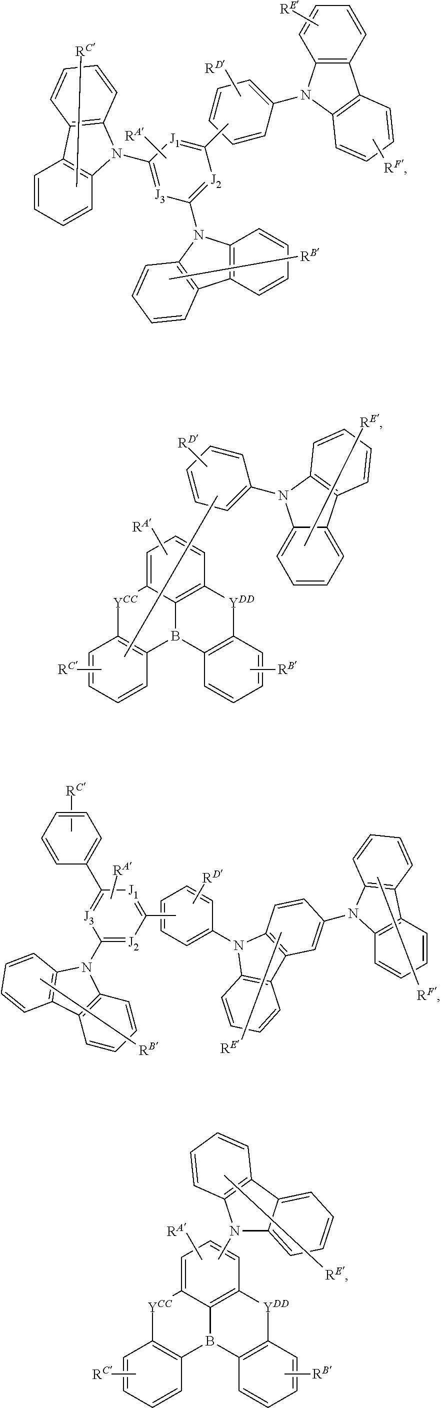 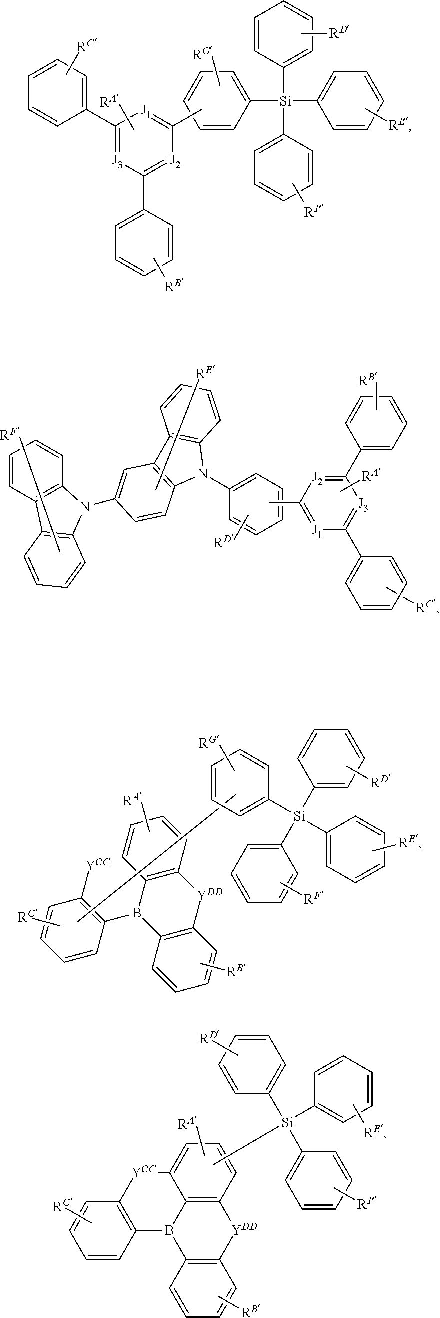 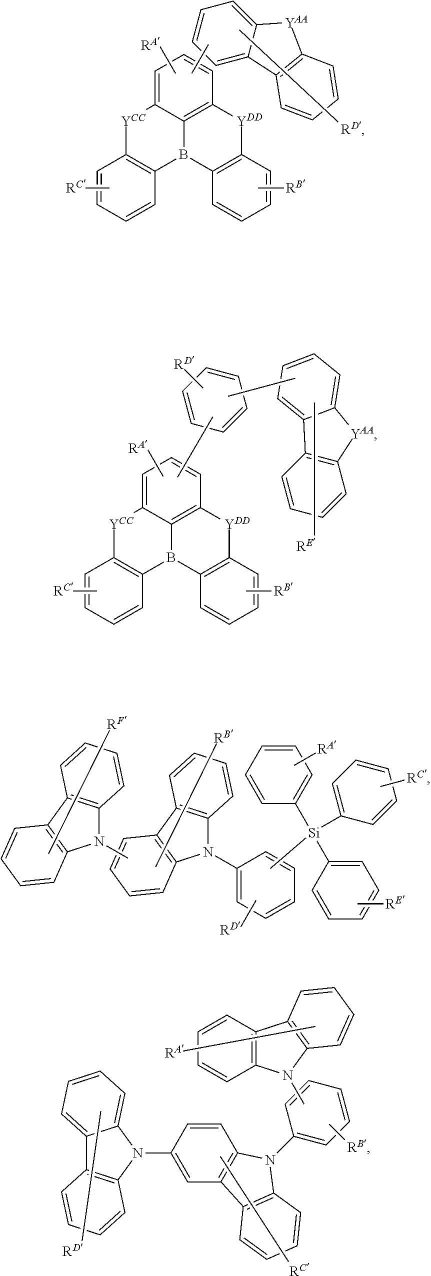 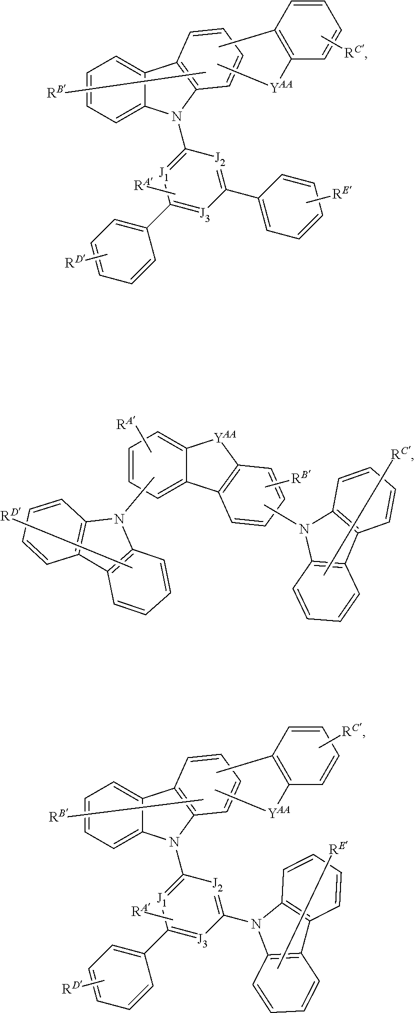 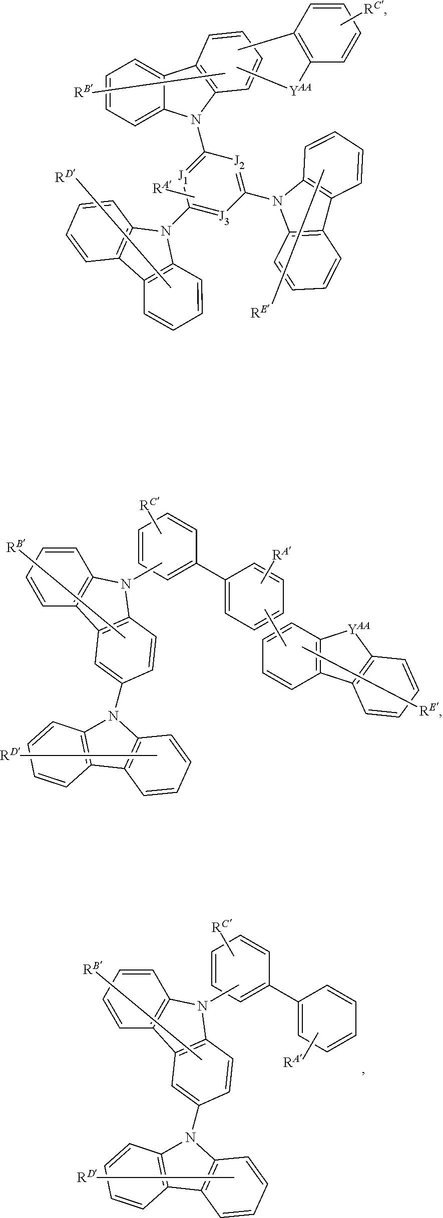 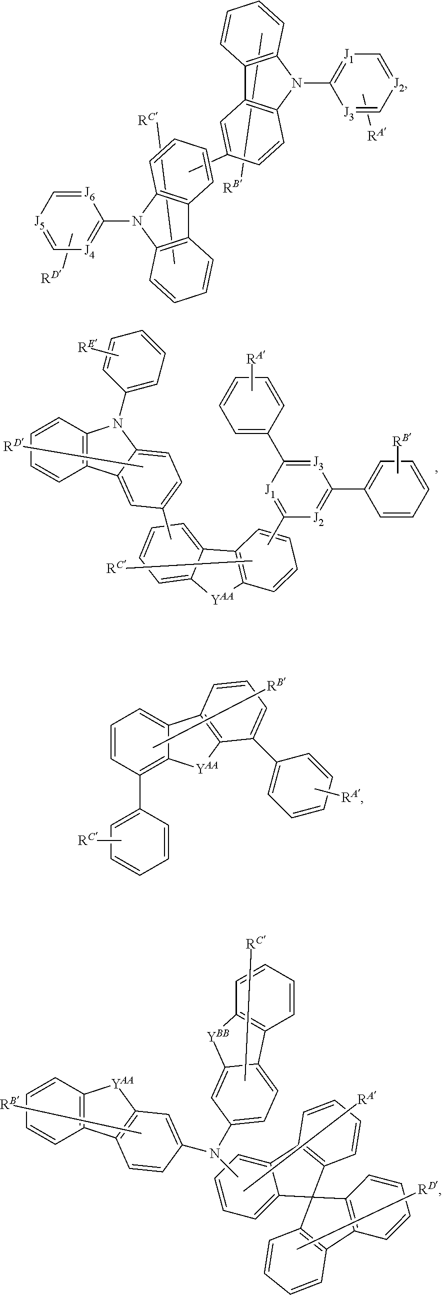 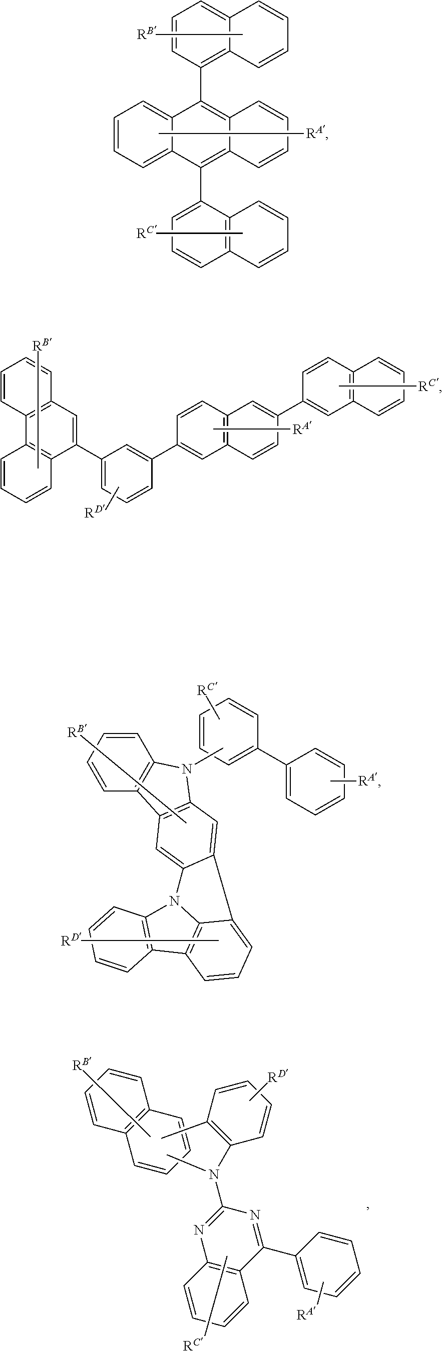 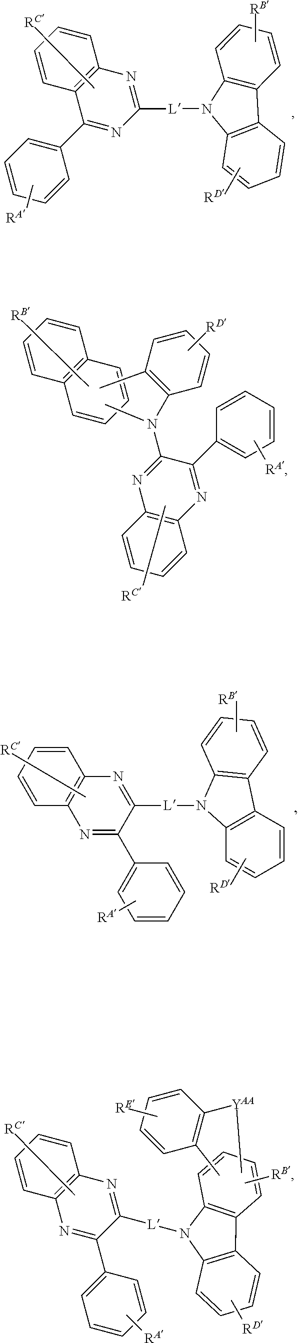 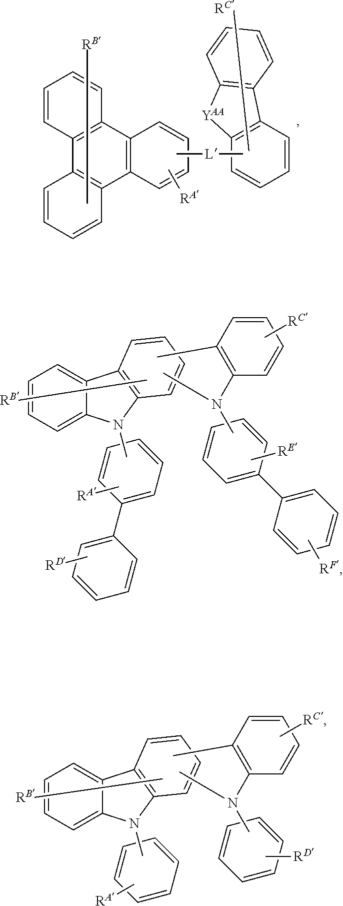 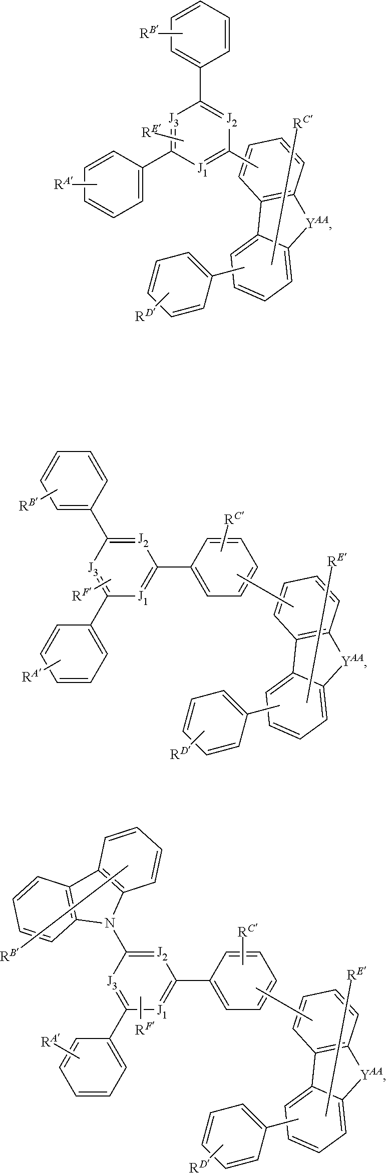 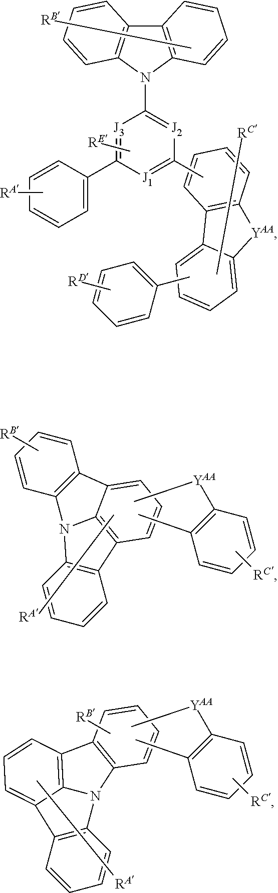 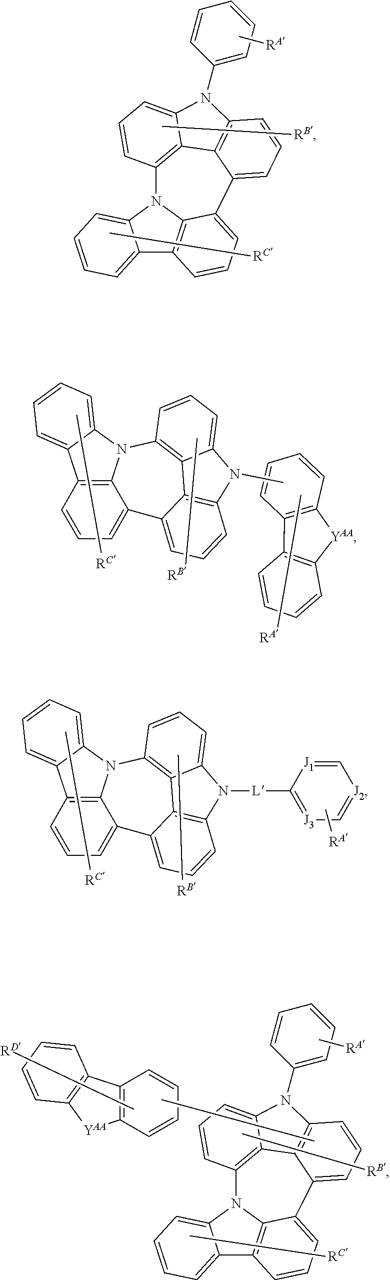 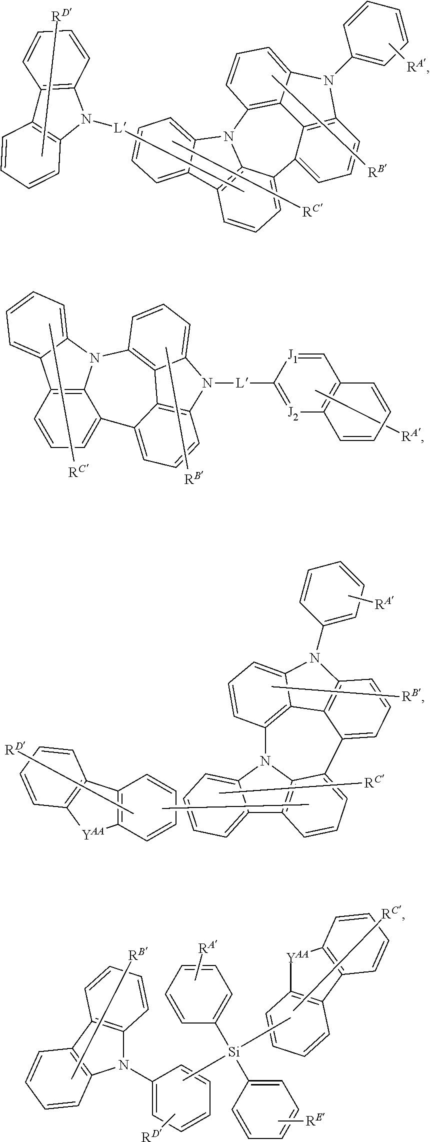 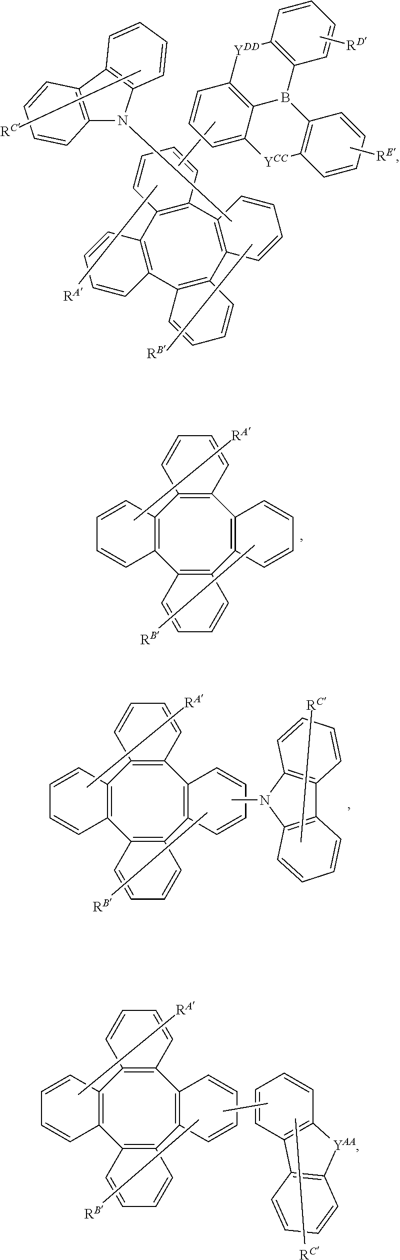 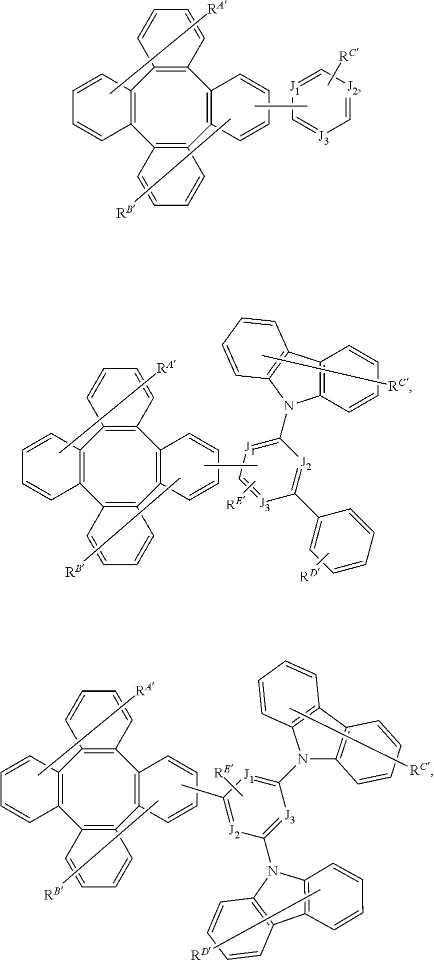 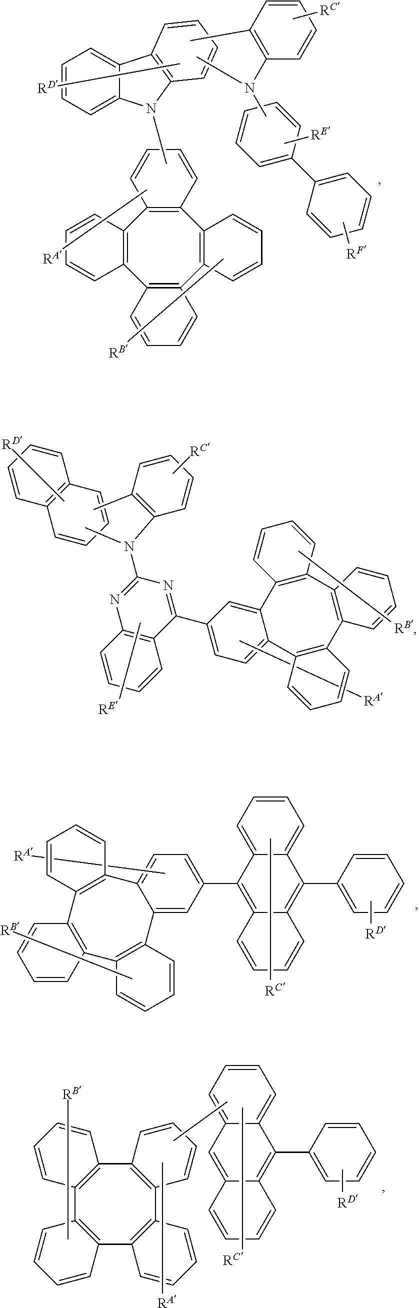 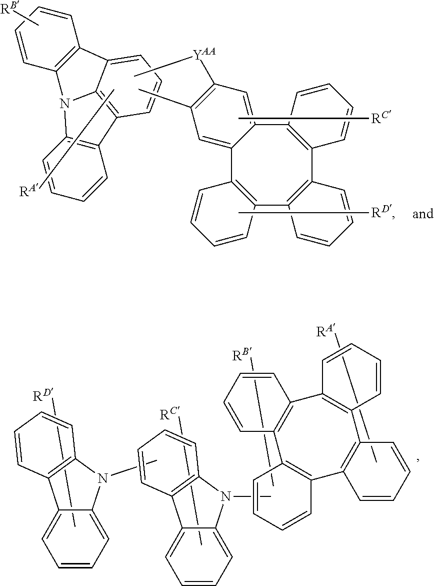
wherein:
each of J₁ to J₆ is independently C or N;
L′ is a direct bond or an organic linker;
each Y^{AA}, Y^{BB}, Y^{CC}, and Y^{DD} is independently selected from the group consisting of absent a bond, direct bond, O, S, Se, CRR′, SiRR′, GeRR′, NR, BR, BRR′;
each of R^{A′}, R^{B′}, R^{C′}, R^{D′}, R^{E′}, R^{F′}, and R^{G′} independently represents mono, up to the maximum substitutions, or no substitutions;
each R, R′, R^{A′}, R^{B′}, R^{C′}, R^{D′}, R^{E′}, R^{F′}, and R^{G′} is independently a hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof; any two substituents can be joined or fused to form a ring; and where possible, each unsubstituted aromatic carbon atom can be replaced with N to form an aza-substituted ring.

19. The OLED of claim 17, wherein the compound is a sensitizer, and the OLED further comprises an acceptor selected from the group consisting of a fluorescent emitter, a delayed fluorescence emitter, and combination thereof.

20. A consumer product comprising an organic light-emitting device comprising:
an anode;
a cathode; and
an organic layer disposed between the anode and the cathode, wherein the organic layer comprises a compound according to claim 1.
